(19) United States
(12) Patent Application Publication
(10) Pub. No.: US 2025/0031575 A1
(43) Pub. Date: Jan. 23, 2025

(54) LIGHT EMITTING ELEMENT AND POLYCYCLIC COMPOUND FOR THE SAME

(71) Applicant: Samsung Display Co., LTD., Yongin-si (KR)

(72) Inventors: MUN-KI SIM, Yongin-si (KR); TAEIL KIM, Yongin-si (KR); SUN YOUNG PAK, Yongin-si (KR); JUNHA PARK, Yongin-si (KR); MinJae SUNG, Yongin-si (KR); MINJUNG JUNG, Yongin-si (KR); Seonhyoung HUR, Yongin-si (KR)

(21) Appl. No.: 18/676,212

(22) Filed: May 28, 2024

(30) Foreign Application Priority Data
Jun. 8, 2023 (KR) 10-2023-0073847

(51) Int. Cl. H10K 85/60; C07F 5/02; C09K 11/06; H10K 50/12; H10K 101/00; H10K 101/20

(52) U.S. Cl. CPC H10K 85/658; C07F 5/027; C09K 11/06; C07B 2200/05; C09K 2211/1018; H10K 50/12; H10K 2101/20; H10K 2101/90

(57) ABSTRACT

A light emitting element of an embodiment includes a first electrode, a second electrode on the first electrode, and an emission layer between the first electrode and the second electrode. The emission layer includes a first compound represented by Formula 1 and may show excellent emission efficiency and long-life characteristics.

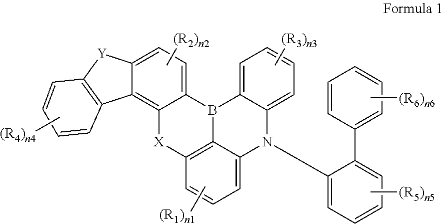

### CROSS-REFERENCE TO RELATED APPLICATIONS

The present application claims priority to and the benefit of Korean Patent Application No. 10-2023-0073847, filed on Jun. 8, 2023, in the Korean Intellectual Property Office, the entire disclosure of which is incorporated by reference herein.

### BACKGROUND

### 1. Field

Embodiments of the present disclosure herein relate to a light emitting element and a polycyclic compound used in the same.

### 2. Description of the Related Art

Recently, the development of an organic electroluminescence display device as an image display device, is being actively conducted. The organic electroluminescence display device, or the like is a display device including a self-luminescent light emitting element in which holes and electrons injected from a first electrode and a second electrode recombine in an emission layer so that a light emitting material in the emission layer emits light to achieve a display.

In the application of a light emitting element to a display device, the increase of the emission efficiency and the improvement of lifetime are beneficial, and development of materials for a light emitting element stably achieving the requirements is being continuously conducted.

Recently, in order to accomplish a light emitting element having high efficiency, techniques for phosphorescence emission which uses energy in a triplet state or delayed fluorescence emission which uses the generating phenomenon of singlet excitons by the collision of triplet excitons (triplet-triplet annihilation, TTA) are being developed, and development of a thermally activated delayed fluorescence (TADF) material using delayed fluorescence phenomenon is being conducted.

### SUMMARY

Embodiments of the present disclosure provide a light emitting element having improved emission efficiency and lifetime.

Embodiments of the present disclosure provide a polycyclic compound which is a material for a light emitting element, improving emission efficiency and lifetime.

Embodiments of the present disclosure provide a display device including a light emitting element having improved emission efficiency and element lifetime.

A light emitting element of an embodiment may include a first electrode, a second electrode on the first electrode, and an emission layer between the first electrode and the second electrode, wherein the emission layer includes a first compound represented by Formula 1.

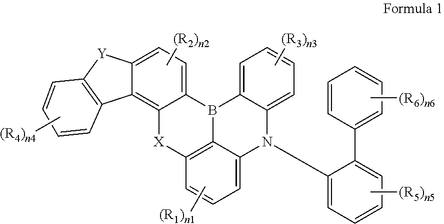

In Formula 1, X is S, O, or Se, Y is NR₇, S, O, or CR₈R₉. R₁ to R₆ are each independently a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, or R₃ is combined with an adjacent group to form a ring, R₇ to R₉ are each independently a substituted or unsubstituted aryl group of 6 to 30 ring-forming carbon atoms, or a substituted or unsubstituted heteroaryl group of 2 to 30 ring-forming carbon atoms, or R₈ and R₉ are combined with each other to form a ring. n1 is an integer of 0 to 3, n2 is an integer of 0 to 2, n3, n4 and n5 are each independently an integer of 0 to 4, and n6 is an integer of 0 to 5.

In an embodiment, the emission layer may further include at least one among a second compound represented by Formula HT-1, and a third compound represented by Formula ET-1.

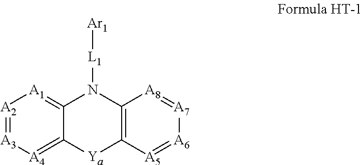

In Formula HT-1, A₁ to A₈ are each independently N or CR₅₁, L₁ is a direct linkage, a substituted or unsubstituted arylene group of 6 to 30 ring-forming carbon atoms, or a substituted or unsubstituted heteroarylene group of 2 to 30 ring-forming carbon atoms, and Yₐ is a direct linkage, CR₅₂R₅₃, or SiR₅₄R₅₅. Ar₁ is a substituted or unsubstituted aryl group of 6 to 30 ring-forming carbon atoms, or a substituted or unsubstituted heteroaryl group of 2 to 30 ring-forming carbon atoms. R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring.

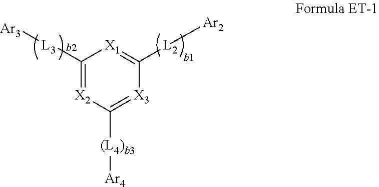

In Formula ET-1, at least one among X₁ to X₃ is N, and the remainder are CR₅₆, R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, and b1 to b3 are each independently an integer of 0 to 10. Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms.

In an embodiment, the emission layer may further include a fourth compound represented by Formula D-1.

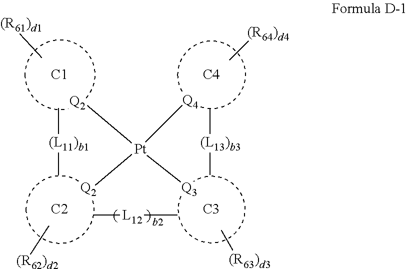

In Formula D-1, Q₁ to Q₄ are each independently C or N, and C1 to C4 are each independently a substituted or unsubstituted hydrocarbon ring of 5 to 30 ring-forming carbon atoms, or a substituted or unsubstituted heterocycle of 2 to 30 ring-forming carbon atoms. L₁₁ to L₁₃ are each independently a direct linkage, *—O—*, *—S—*,

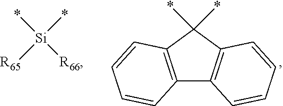

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. b11 to b13 are each independently 0 or 1, R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and d1 to d4 are each independently an integer of 0 to 4.

In an embodiment, the emission layer may include the first compound, the second compound, the third compound, and the fourth compound.

In an embodiment, the emission layer may emit delayed fluorescence.

In an embodiment, the first compound represented by Formula 1 may be represented by Formula 2 or Formula 3.

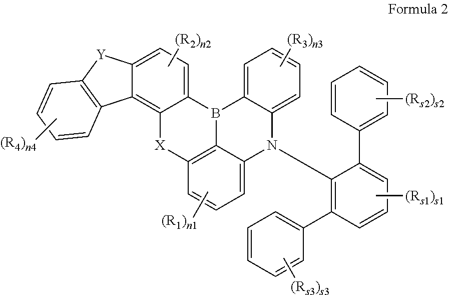

In Formula 2, Rₛ₁, Rₛ₂, and Rₛ₃ are each independently a hydrogen atom, a deuterium atom, a substituted or unsubstituted alkyl group of 1 to 30 carbon atoms, or a substituted or unsubstituted aryl group of 6 to 30 ring-forming carbon atoms, s1 is an integer of 0 to 3, and s2 and s3 are each independently an integer of 0 to 5. In Formula 2, X, Y, R₁ to R₄, and n1 to n4 are the same as defined with respect to Formula 1.

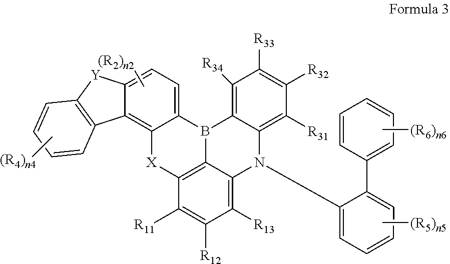

In Formula 3, R₁₁, R₁₃, R₃₁, and R₃₄ are each independently a hydrogen atom or a deuterium atom, R₁₂ is a substituted or unsubstituted amine group, a substituted or unsubstituted aryl group of 6 to 30 ring-forming carbon atoms, or a substituted or unsubstituted heteroaryl group of 2 to 30 ring-forming carbon atoms. R₃₂ and R₃₃ are each independently a substituted or unsubstituted amine group, a substituted or unsubstituted aryl group of 6 to 30 ring-forming carbon atoms, or a substituted or unsubstituted heteroaryl group of 2 to 30 ring-forming carbon atoms, or R₃₂ and R₃₃ are combined with each other to form a ring. In Formula 3, X, Y, R₂, R₄ to R₆, n2, and n4 to n6 are the same as defined with respect to Formula 1.

In an embodiment, the first compound represented by Formula 1 may be represented by Formula 4.

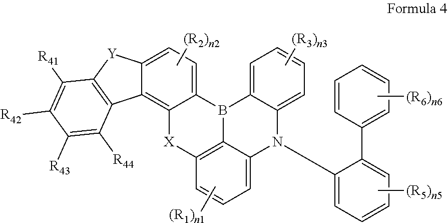

In Formula 4, R₄₁, R₄₂, and R₄₄ are each independently a hydrogen atom or a deuterium atom, R₄₃ is a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. In Formula 4, X, Y, R₁ to R₃, R₅, R₆, n1 to n3, n5 and n6 are the same as defined with respect to Formula 1.

In an embodiment, the first compound represented by Formula 1 may be represented by any one among Formula 5-1 to Formula 5-4.

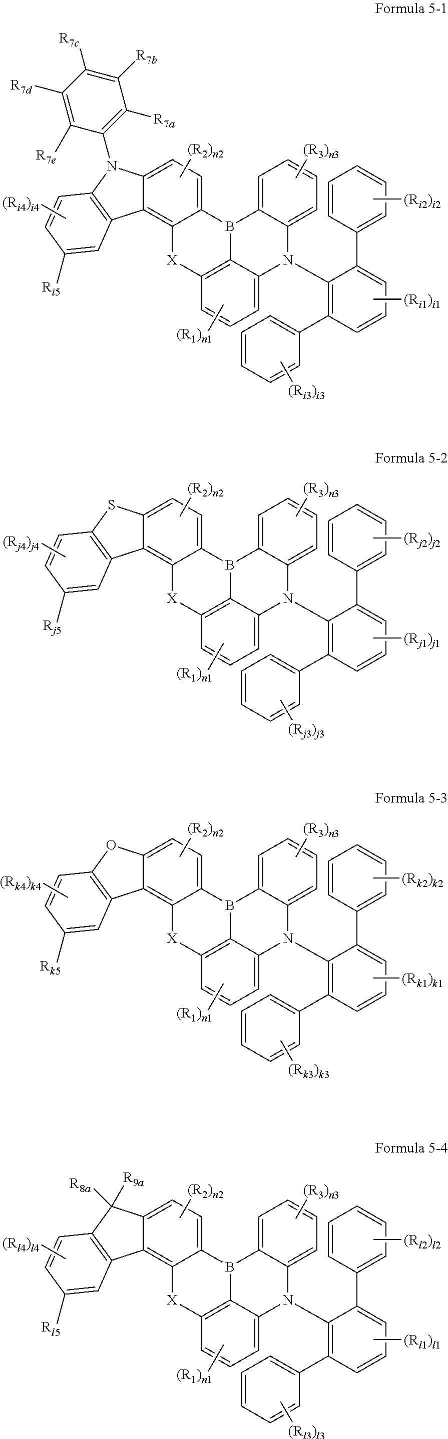

In Formula 5-1 to Formula 5-4, Rᵢ₁ to Rᵢ₃, Rⱼ₁ to Rⱼ₃, Rₖ₁ to Rₖ₃, and Rₗ₁ to Rₗ₃ are each independently a hydrogen atom, a deuterium atom, a substituted or unsubstituted alkyl group of 1 to 30 carbon atoms, or a substituted or unsubstituted aryl group of 6 to 30 ring-forming carbon atoms, and Rᵢ₄, Rⱼ₄, Rₖ₄, and Rₗ₄ are each independently a hydrogen atom or a deuterium atom. Rᵢ₅, Rⱼ₅, Rₖ₅, and Rₗ₅ are each independently a hydrogen atom, a deuterium atom, a substituted or unsubstituted aryl group of 6 to 30 ring-forming carbon atoms, or a substituted or unsubstituted heteroaryl group of 2 to 30 ring-forming carbon atoms, R₇ₐ to R₇ₑ are each independently a hydrogen atom, a deuterium atom, a substituted or unsubstituted alkyl group of 1 to 10 carbon atoms, or a substituted or unsubstituted aryl group of 6 to 15 ring-forming carbon atoms, R₈ₐ and R₉ₐ are each independently a substituted or unsubstituted aryl group of 6 to 30 ring-forming carbon atoms, or R₈ₐ and R₉ₐ are combined with each other to form a ring. i1, i4, j1, j4, k1, k4, l1, and l4 are each independently an integer of 0 to 3, i2, i3, j2, j3, k2, k3, l2, and l3 are each independently an integer of 0 to 5. In Formula 5-1 to Formula 5-4, X, R₁ to R₃, and n1 to n3 are the same as defined with respect to Formula 1.

In an embodiment, n1 of Formula 1 may be 1, and R₁ may be represented by any one among SG1-1 to SG1-24 in Substituent Group 1, which will be explained further herein below, and n3 of Formula 1 may be 1 or 2, and R₃ may be represented by any one among SG1-1 to SG1-25 in Substituent Group 1, which will be explained further herein below.

In an embodiment, R₄ of Formula 1 may be a hydrogen atom or a deuterium atom, or represented by any one among SG2-1 to SG2-10 in Substituent Group 2, which will be explained further herein below.

The first compound may be represented by any one among the compounds in Compound Group 1, which will be explained further herein below.

A polycyclic compound according to an embodiment of the present disclosure may be represented by Formula 1 above.

### BRIEF DESCRIPTION OF THE DRAWINGS

The accompanying drawings are included to provide a further understanding of the subject matter of the present disclosure and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view of a part corresponding to line I-I′ in FIG. 1;

FIG. 3 is a cross-sectional view schematically showing a light emitting element of an embodiment;

FIG. 4 is a cross-sectional view schematically showing a light emitting element of an embodiment;

FIG. 5 is a cross-sectional view schematically showing a light emitting element of an embodiment;

FIG. 6 is a cross-sectional view schematically showing a light emitting element of an embodiment;

FIG. 7 is a cross-sectional view schematically showing a light emitting element of an embodiment;

FIG. 8 is a cross-sectional view showing a display device according to an embodiment;

FIG. 9 is a cross-sectional view showing a display device according to an embodiment;

FIG. 10 is a cross-sectional view showing a display device according to an embodiment;

FIG. 11 is a cross-sectional view showing a display device according to an embodiment; and

FIG. 12 is a diagram showing the interior of a vehicle in which the display device of an embodiment is provided.

### DETAILED DESCRIPTION

The subject matter of the present disclosure may be modified in various suitable manners and have many forms, and thus example embodiments will be illustrated in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of the drawings, like reference numbers are used for referring to like elements. In the accompanying drawings, the dimensions of each structure may be exaggeratingly illustrated for clarity of the present disclosure. It will be understood that, although the terms “first,” “second,” etc., may be used herein to describe various components, these components should not be limited by these terms. These terms are only used to distinguish one component from another. For example, a first component could be termed a second component, and, similarly, a second component could be termed a first component, without departing from the scope of example embodiments of the present disclosure. As used herein, the singular forms, “a,” “an,” and “the” are intended to include the plural forms as well, unless the context clearly indicates otherwise.

In the present application, it will be understood that the terms “include,” “have” or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In addition, it will be understood that when a part is referred to as being “on” another part, it can be above the other part, or under the other part as well.

In the specification, the term “substituted or unsubstituted” may mean substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents described above may be substituted or unsubstituted. For example, a biphenyl group may be interpreted as an aryl group or a phenyl group substituted with a phenyl group.

In the specification, the phrase “bonded to an adjacent group to form a ring” may mean that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the specification, the term “adjacent group” may mean a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, and/or an iodine atom.

In the specification, the alkyl group may be linear or branched. The number of carbons in the alkyl group is 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the specification, a cycloalkyl group may mean a cyclic alkyl group. The number of carbons in the cycloalkyl group is 3 to 60, 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments of the present disclosure are not limited thereto.

In the specification, an alkenyl group means a hydrocarbon group including at least one carbon double bond at a main chain (e.g., in the middle) or a terminal end of an alkyl group having 2 or more carbon atoms. The alkenyl group may be linear or branched. The number of carbon atoms in the alkenyl group is not specifically limited, but is 2 to 60, 2 to 30, 2 to 20, or 2 to 10. Examples of the alkenyl group include a vinyl group, a 1-butenyl group, a 1-pentenyl group, a 1,3-butadienyl group, a styrenyl group, a styryl vinyl group, etc., but embodiments of the present disclosure are not limited thereto.

In the specification, an alkynyl group means a hydrocarbon group including at least one carbon triple bond at a main chain (e.g., in the middle) or a terminal end of an alkyl group having 2 or more carbon atoms. The alkynyl group may be linear or branched. Although the number of carbon atoms is not specifically limited, it is 2 to 30, 2 to 20, or 2 to 10. Examples of the alkynyl group may include an ethynyl group, a propynyl group, etc., but are not limited thereto.

In the specification, the hydrocarbon ring group means any suitable functional group or substituent derived from an aliphatic hydrocarbon ring. The hydrocarbon ring group may be a saturated hydrocarbon ring group having 5 to 20 ring-forming carbon atoms.

In the specification, an aryl group means any suitable functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the specification, the fluorenyl group may be substituted, and two substituents may be bonded to each other to form a spiro structure. Examples of the substituted fluorenyl group are as follows. However, embodiments of the present disclosure are not limited thereto.

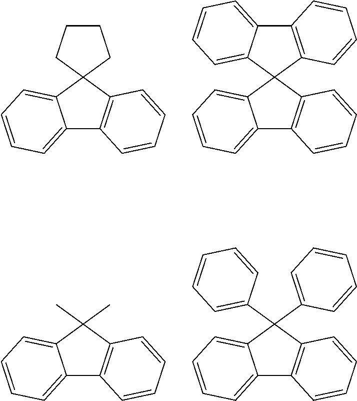

The heterocyclic group herein means any suitable functional group or substituent derived from a ring containing at least one of B, O, N, P, S, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, S, Si or Se as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 30, 2 to 20, or 2 to 10.

In the specification, the aliphatic heterocyclic group may include at least one of B, O, N, P, S, Si, or Se as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited thereto.

In the specification, the heteroaryl group may contain at least one of B, O, N, P, S, Si, or Se as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes, for example, an alkylsilyl group and/or an arylsilyl group. Examples of the silyl group may include a trimethylsilyl group, a triethylsilyl group, a t-butyldimethylsilyl group, a propyldimethylsilyl group, a triphenylsilyl group, a diphenylsilyl group, a phenylsilyl group, etc., but embodiments of the present disclosure are not limited thereto.

In the specification, the number of carbon atoms and/or ring-forming carbon atoms in the carbonyl group is not specifically limited, but may be 1 to 40, 1 to 30, or 1 to 20. For example, the carbonyl group may have the following structures, but embodiments of the present disclosure are not limited thereto.

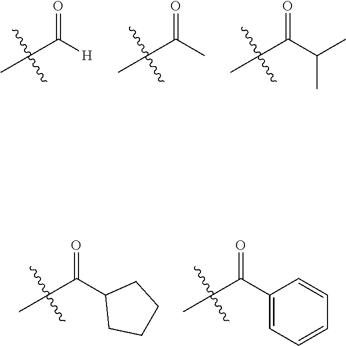

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include, for example, an alkylthio group and/or an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the specification, an oxy group may mean that an oxygen atom is bonded to the alkyl group and/or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

The boron group herein may mean that a boron atom is bonded to the alkyl group or the aryl group as defined above. The boron group includes an alkyl boron group and an aryl boron group. Examples of the boron group may include a dimethylboron group, a t-butyldimethylboron group, a diphenylboron group, a phenylboron group, etc., but embodiments of the present disclosure are not limited thereto.

In the specification, the number of carbon atoms in an amine group is not specifically limited, but may be 1 to 30. The amine group may include, for example, an alkyl amine group and/or an aryl amine group. Examples of the amine group may include a methylamine group, a dimethylamine group, a phenylamine group, a diphenylamine group, a naphthylamine group, a 9-methyl-anthracenylamine group, etc., but embodiments of the present disclosure are not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the specification, the aryl group among an aryloxy group, an arylthio group, an arylsulfoxy group, an arylamino group, an arylboron group, an arylsilyl group, an arylamine group is the same as the examples of the aryl group described above.

In the specification, a direct linkage may mean a single bond (e.g., a single covalent bond).

In the specification,

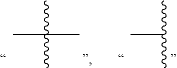

and “—*” mean a position to be connected.

Hereinafter, embodiments of the present disclosure will be described with reference to the accompanying drawings.

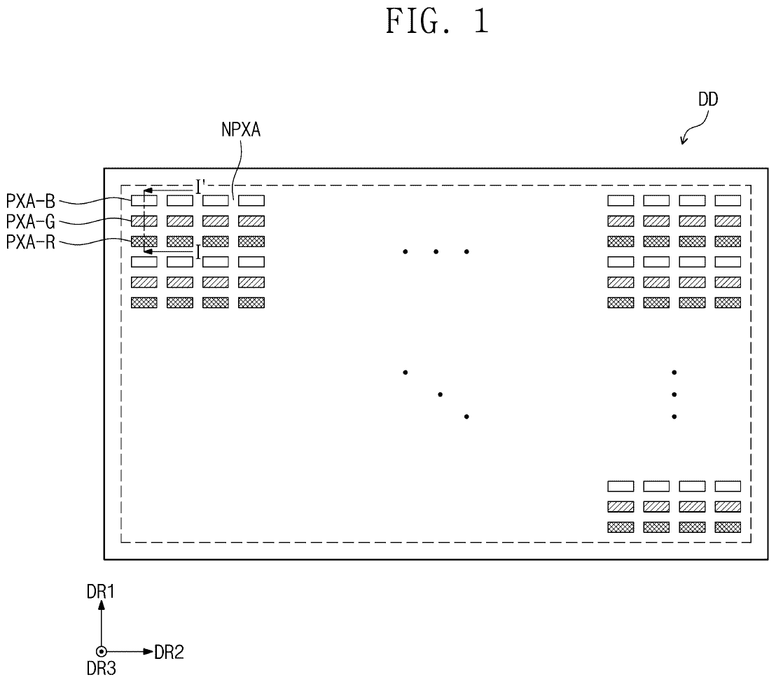

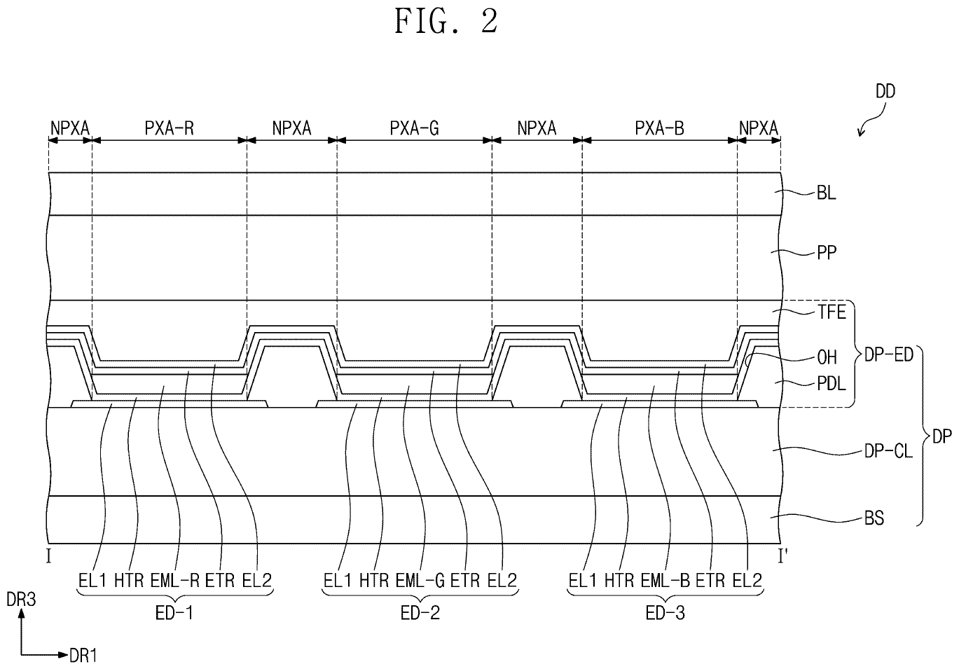

FIG. 1 is a plan view illustrating a display device DD of an embodiment. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP on the display panel DP. The display panel DP includes light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarization layer and/or a color filter layer. In some embodiments, the optical layer PP may be omitted from the display device DD of an embodiment.

A base substrate BL may be on the optical layer PP. The base substrate BL may be a member which provides a base surface on which the optical layer PP is provided. The base substrate BL may be a glass substrate, a metal substrate, a plastic substrate, etc. However, embodiments of the present disclosure are not limited thereto, and the base substrate BL may be an inorganic layer, an organic layer, or a composite material layer (e.g., including an inorganic layer and an organic layer). In some embodiments, the base substrate BL may be omitted.

The display device DD according to an embodiment may further include a filling layer. The filling layer may be between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 between portions of the pixel defining film PDL, and an encapsulation layer TFE on the light emitting elements ED-1, ED-2, and ED-3.

The base layer BS may be a member which provides a base surface on which the display device layer DP-ED is provided. The base layer BS may be a glass substrate, a metal substrate, a plastic substrate, etc. However, the embodiment is not limited thereto, and the base layer BS may be an inorganic layer, an organic layer, or a composite material layer (e.g., including an inorganic layer and an organic layer).

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display device layer DP-ED.

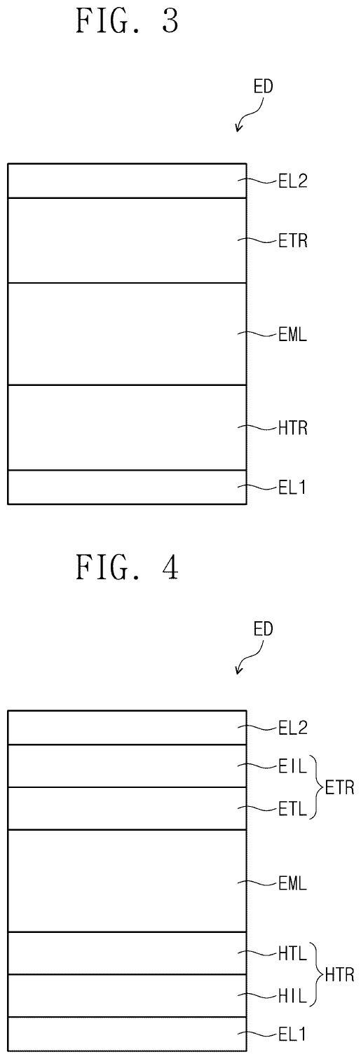

Each of the light emitting elements ED-1, ED-2, and ED-3 may have a structure of each light emitting element ED of embodiments according to FIGS. 3-6, which will be described further herein below. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are in openings OH defined in the pixel defining film PDL, and the hole transport region HTR, the electron transport region ETR, and the second electrode EL2 are provided as a common layer in the entire light emitting elements ED-1, ED-2, and ED-3. However, embodiments of the present disclosure are not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in an embodiment may be provided by being patterned in an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer (e.g., one electrically insulating layer). The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. The encapsulation-organic film may include a photopolymerizable organic material, but embodiments of the present disclosure are not particularly limited thereto.

The encapsulation layer TFE may be on the second electrode EL2 and may fill the opening OH.

Referring to FIGS. 1-2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In the specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be in openings OH defined in the pixel defining film PDL and separated (e.g., spaced apart) from each other.

The light emitting regions PXA-R, PXA-G, and PXA-B may be divided into a plurality of groups according to the color of light generated from the light emitting elements ED-1, ED-2, and ED-3. In the display device DD of an embodiment illustrated in FIGS. 1-2, three light emitting regions PXA-R, PXA-G, and PXA-B, which emit red light, green light, and blue light, respectively, are illustrated as examples. For example, the display device DD of an embodiment may include the red light emitting region PXA-R, the green light emitting region PXA-G, and the blue light emitting region PXA-B that are separated (e.g., spaced apart) from each other.

In the display device DD according to an embodiment, the plurality of light emitting elements ED-1, ED-2 and ED-3 may emit light beams having wavelengths different from each other. For example, in an embodiment, the display device DD may include a first light emitting element ED-1 that emits red light, a second light emitting element ED-2 that emits green light, and a third light emitting element ED-3 that emits blue light. In some embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may emit light beams in the same wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In some embodiments, the red light emitting region PXA-R, the green light emitting region PXA-G, and the blue light emitting region PXA-B may be alternately arranged in this order along a first directional axis DR1.

FIGS. 1-2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light.

In same embodiments, the areas of the light emitting regions PXA-R, PXA-G, and PXA-B may mean areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the characteristics of display quality required in the display device DD. For example, the arrangement form of the light emitting regions PXA-R, PXA-G, and PXA-B may be a pentile (PENTILE®) arrangement form (e.g., an RGBG matrix, RGBG structure, or RGBG matrix structure) or a diamond (Diamond Pixel™) arrangement form. PENTILE® is a duly registered trademark of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but embodiments of the present disclosure are not limited thereto.

Hereinafter, FIG. 3 to FIG. 7 are cross-sectional views schematically showing light emitting elements according to embodiments. The light emitting element ED of an embodiment may include a first electrode EL1, a hole transport region HTR, an emission layer EML, an electron transport region ETR, and a second electrode EL2 stacked in order.

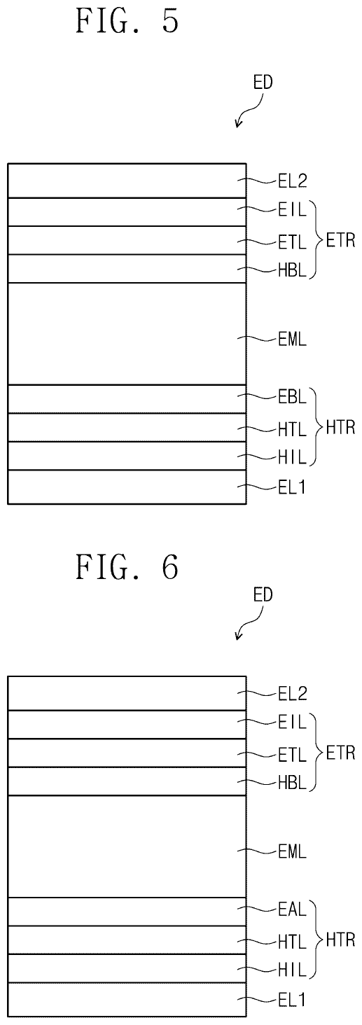

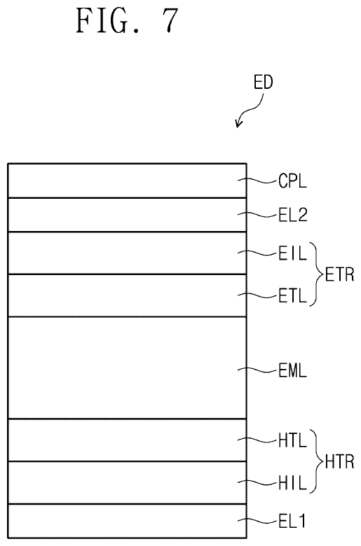

Compared with FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. Compared with FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared to FIG. 3, FIG. 6 shows the cross-sectional view of the light emitting element ED of an embodiment, in which a hole transport region HTR includes a hole injection layer HIL, a hole transport layer HTL, and an emission auxiliary layer EAL, and an electron transport region ETR includes an electron injection layer EIL, an electron transport layer ETL, and a hole blocking layer HBL. Compared with FIG. 4, FIG. 7 illustrates a cross-sectional view of a light emitting element ED of an embodiment including a capping layer CPL on a second electrode EL2.

The first electrode EL1 has conductivity (e.g., electrical conductivity). The first electrode EL1 may be formed of a metal material, a metal alloy, and/or a conductive compound (e.g., an electrically conductive compound). The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

If the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments of the present disclosure are not limited thereto. Embodiments of the present disclosure are not limited thereto, and the first electrode EL1 may include the above-described metal materials, combinations of at least two metal materials of the above-described metal materials, oxides of the above-described metal materials, or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, an emission auxiliary layer EAL, or an electron blocking layer EBL. The thickness of the hole transport region HTR may be, for example, from about 50 Å to about 15,000 Å. The emission auxiliary layer EAL may also be referred to as a buffer layer.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but embodiments of the present disclosure are not limited thereto.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below:

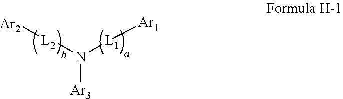

In Formula H-1 above, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. The subscripts a and b may be each independently an integer of 0 to 10. In some embodiments, when a or b is an integer of 2 or greater, a plurality of L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 above may be a monoamine compound. In some embodiments, the compound represented by Formula H-1 above may be a diamine compound in which at least one among Ar₁ to Ar₃ includes the amine group as a substituent. In some embodiments, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among the compounds in Compound Group H below. However, the compounds listed in Compound Group H below are examples, and the compounds represented by Formula H-1 are not limited to those represented by Compound Group H below:

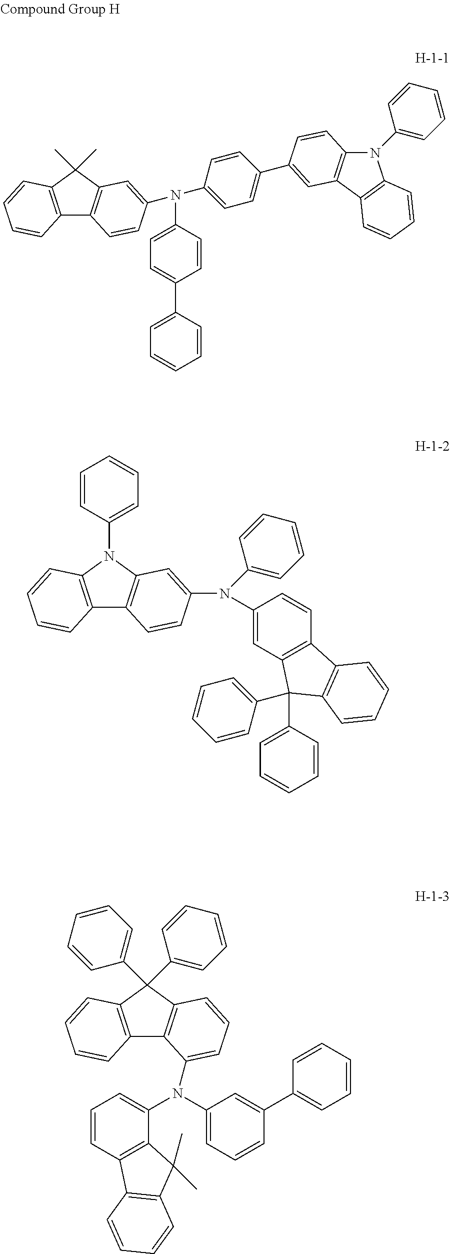 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

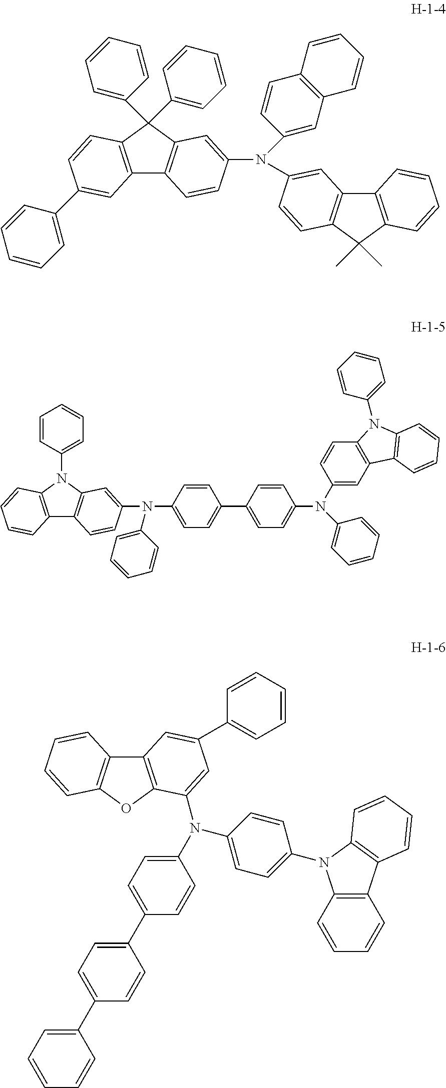 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

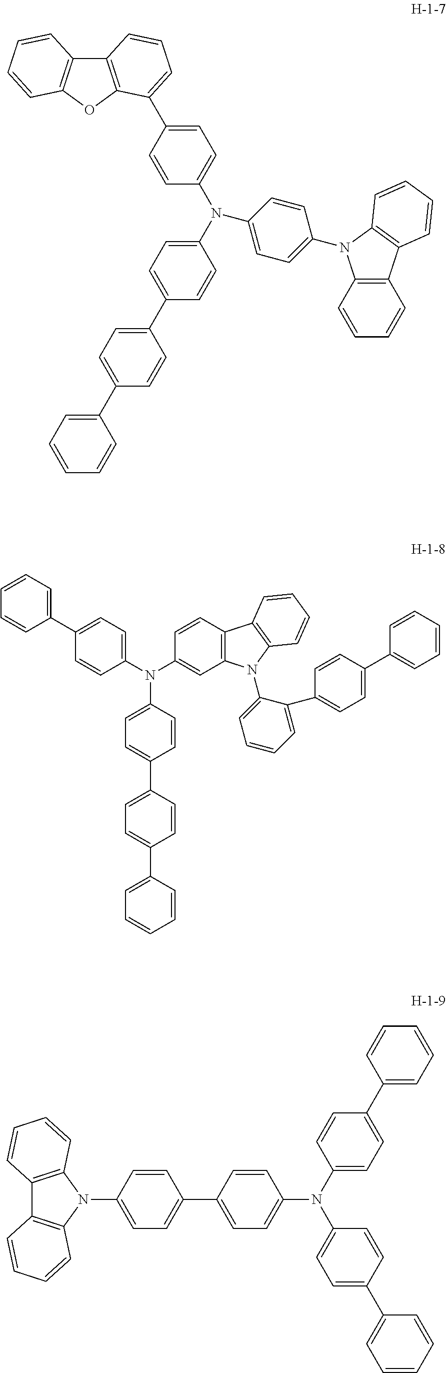 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

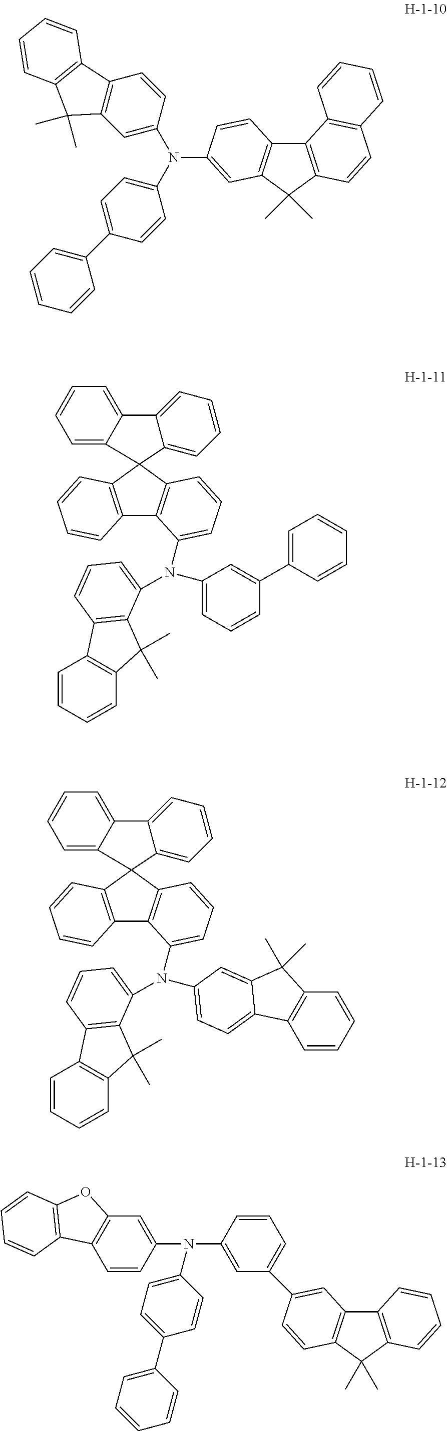 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

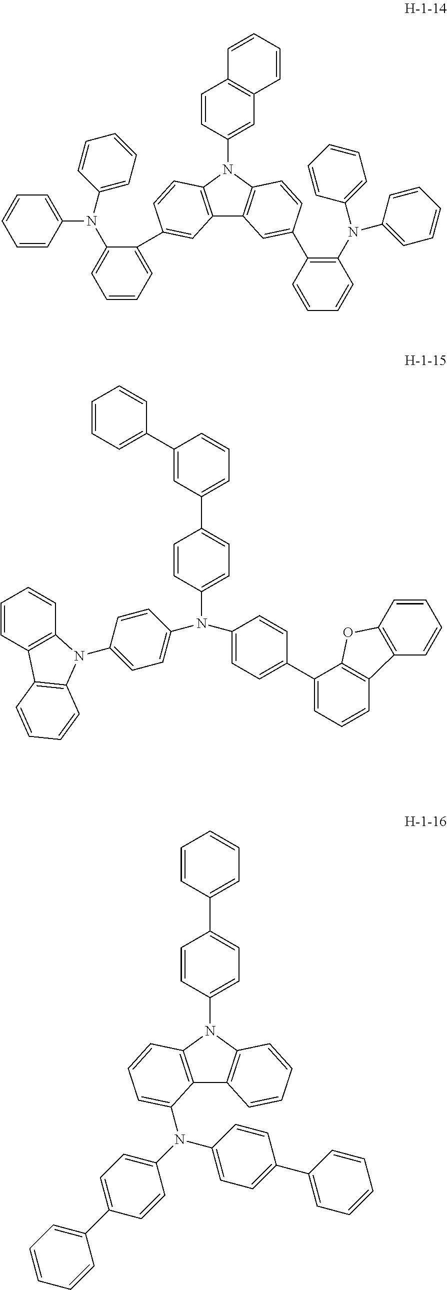 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

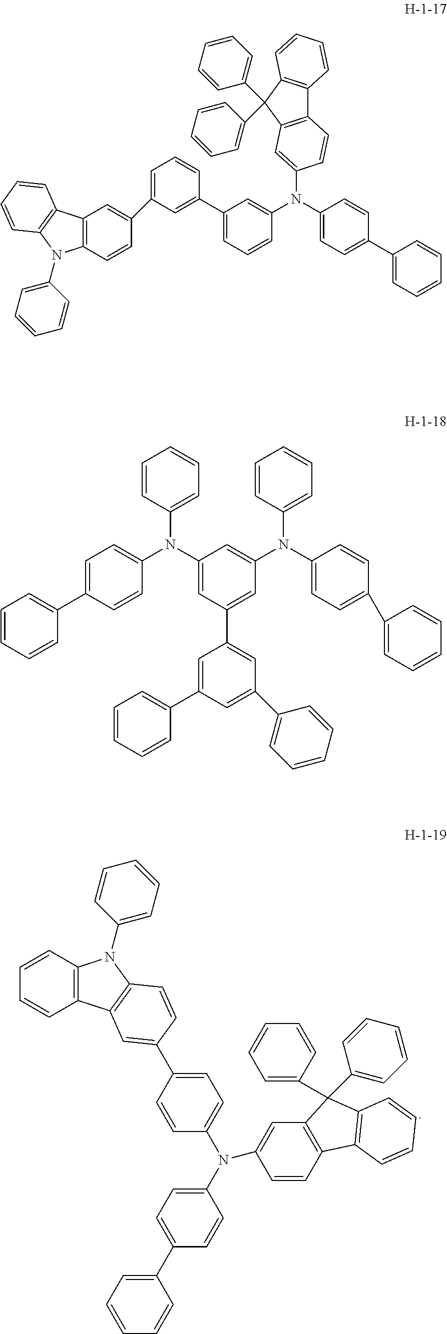 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an emission auxiliary layer EAL or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without a substantial increase in driving voltage.

The hole transport region HTR may further include a charge generating material to increase conductivity (e.g., electrical conductivity) in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the emission auxiliary layer EAL or the electron blocking layer EBL in addition to the hole injection layer HIL and the hole transport layer HTL. The emission auxiliary layer EAL may compensate for a resonance distance according to the wavelength of light emitted from the emission layer EML, and may improve light emission efficiency by controlling hole charge balance. In some embodiments, the emission auxiliary layer EAL may play the role of preventing or reducing electron injection to the hole transport region HTR. In the emission auxiliary layer EAL, a material that may be included in the hole transport region HTR, may be included. The electron blocking layer EBL is a layer that serves to prevent or reduce electron injection from the electron transport region ETR to the hole transport region HTR.

In the light emitting element ED of an embodiment, the emission layer EML may include the polycyclic compound according to an embodiment. In the light emitting element ED of an embodiment, the emission layer EML may include a first compound, which is the polycyclic compound of an embodiment, and at least one among a second compound and a third compound. In some embodiments, in the light emitting element ED of an embodiment, the emission layer EML may further include a fourth compound. The second compound may include a fused ring of three rings, including a nitrogen atom as a ring-forming atom. The third compound may include a hexagonal ring group including at least one nitrogen atom as a ring-forming atom. The fourth compound may include an organometallic complex. The second to fourth compounds will be explained in more detail herein below.

In the description, the first compound may be referred to as the polycyclic compound of an embodiment. The polycyclic compound of an embodiment includes a fused ring of five rings, including one heavy atom, one nitrogen (N) atom and one boron (B) atom as ring-forming atoms, as a central structure. The heavy atom included in the polycyclic compound of an embodiment may be a sulfur (S) atom, an oxygen (O) atom, and/or a selenium (Se) atom. The polycyclic compound of an embodiment may include a sulfur atom, an oxygen atom, and/or a selenium atom as a ring-forming atom in the central structure of the fused ring of five rings, and reverse inter-system crossing (RISC) may occur rapidly. Accordingly, the reduction properties of the deterioration of a material due to excitons may be shown. In the present description, the central structure of the fused ring of five rings may be referred to as a “core part”.

The polycyclic compound of an embodiment may include a fused structure of first to third aromatic rings via a heavy atom, a nitrogen atom, and a boron atom. The first aromatic ring may be connected with the second aromatic ring via the boron atom and the heavy atom. The second aromatic ring may be connected with the third aromatic ring via the boron atom and the nitrogen atom. The second aromatic ring may be connected with all of the heavy atom, boron atom and nitrogen atom. In some embodiments, the first to third aromatic rings may be connected with the boron atom. The polycyclic compound of an embodiment may include in the central structure of the fused ring of five rings, a fused structure of the first aromatic ring with any one first derivative among an indoline derivative, an indene derivative, a 2,3-dihydrobenzofuran derivative, and a 2,3-dihydrobenzothiophene derivative. The polycyclic compound of an embodiment includes a fused structure of the first aromatic ring with the first derivative, and may protect the periphery of the heavy atom included in the core part. In the polycyclic compound of an embodiment, the first derivative is fused with the core part, and the approach of another material (e.g., the interaction of another material with the polycyclic compound) is prevented or reduced, and so, improved properties of material stability may be shown.

For example, if the indoline derivative is fused with the first aromatic ring, the polycyclic compound of an embodiment may include a carbazole moiety, which shares a benzene ring with the first aromatic ring of the core part. The polycyclic compound of an embodiment may include a carbazole moiety, a fluorene moiety, a dibenzofuran moiety, and/or a dibenzothiophene moiety, derived from the first derivative. Each of the carbazole moiety, the fluorene moiety, the dibenzofuran moiety, and the dibenzothiophene moiety may have the highest occupied molecular orbital (HOMO) energy level and the lowest unoccupied molecular orbital (LUMO) energy level, which are similar to multi resonance, in which more and less parts of electron density between adjacent atoms are alternating (e.g., alternate with each other). Accordingly, the polycyclic compound including the carbazole moiety, the fluorene moiety, the dibenzofuran moiety, or the dibenzothiophene moiety in the core part, may reinforce the multi resonance properties of a whole molecule.

The polycyclic compound of an embodiment may further include a substituent having large steric hindrance effects, which is additionally substituted at the first derivative fused with the core part (hereinafter, first steric protection substituent), and accordingly, the protection effects of the core part may be increased to further increase material stability. In the polycyclic compound of an embodiment, if the first steric protection substituent is connected with the first derivative which is fused with the core part, the molecular orbital distribution of HOMO from the core part to a part connected with the first steric protection substituent is expanded, and an f-value may increase. In some embodiments, in the polycyclic compound of an embodiment, the molecular orbital distribution of LUMO is localized to the core part, and dexter energy transfer may be reduced. Accordingly, the increase of the concentration of the triplet excitons of the polycyclic compound of an embodiment may be suppressed or reduced, and the deterioration of a material may be suppressed or reduced.

In the polycyclic compound of an embodiment, a biphenyl derivative may be substituted at the nitrogen atom of the central structure of the fused ring of five rings. Because the polycyclic compound of an embodiment includes a bulky substituent like a biphenyl derivative (hereinafter, a second steric protection substituent) in the core part, intermolecular distance may increase, and dexter energy transfer may be reduced.

The light emitting element ED of an embodiment may include the polycyclic compound of an embodiment. The polycyclic compound of an embodiment may be represented by Formula 1.

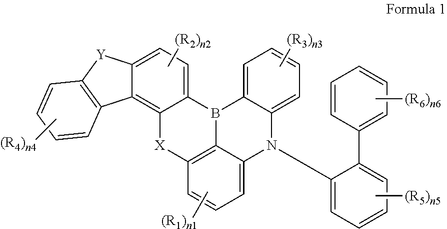

In Formula 1, X may be S, O, or Se. Y may be NR₇, S, O, or CR₈R₉. In the polycyclic compound represented by Formula 1, a benzene ring fused with a heterocycle including Y as a ring-forming atom may correspond to the above-described first aromatic ring.

In Formula 1, R₁ to R₆ may be each independently a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. In some embodiments, R₃ may be combined with an adjacent group to form a ring.

For example, R₁ and R₃ may be each independently a hydrogen atom, a deuterium atom, a substituted or unsubstituted amine group, a substituted or unsubstituted aryl group of 6 to 30 ring-forming carbon atoms, or a substituted or unsubstituted heteroaryl group of 2 to 30 ring-forming carbon atoms. In the polycyclic compound of an embodiment, R₁ and R₃ may be each independently a substituted or unsubstituted carbazole group, a substituted or unsubstituted diphenylamine group, a substituted or unsubstituted phenyl group, a substituted or unsubstituted acridine group, a substituted or unsubstituted phenoxazine group, a substituted or unsubstituted dibenzofuranyl group, or a substituted or unsubstituted fluorenyl group. In some embodiments, if a plurality of R₃ are provided, adjacent two R₃ may be combined with each other to form a heterocycle. In some embodiment, if R₁ and R₃ are substituted with different substituents, the substituent may be a deuterium atom, a cyano group, an unsubstituted t-butyl group, an unsubstituted phenyl group, a phenyl group substituted with a t-butyl group, an unsubstituted biphenyl group, an unsubstituted carbazole group, and/or the like. However, embodiments of the present disclosure are not limited thereto.

In the polycyclic compound of an embodiment, represented by Formula 1, R₁ may be a hydrogen atom or a deuterium atom, or may be represented by any one among SG1-1 to SG1-24 in Substituent Group 1. R₃ may be a hydrogen atom or a deuterium atom or may be represented by any one among SG1-1 to SG1-25 in Substituent Group 1.

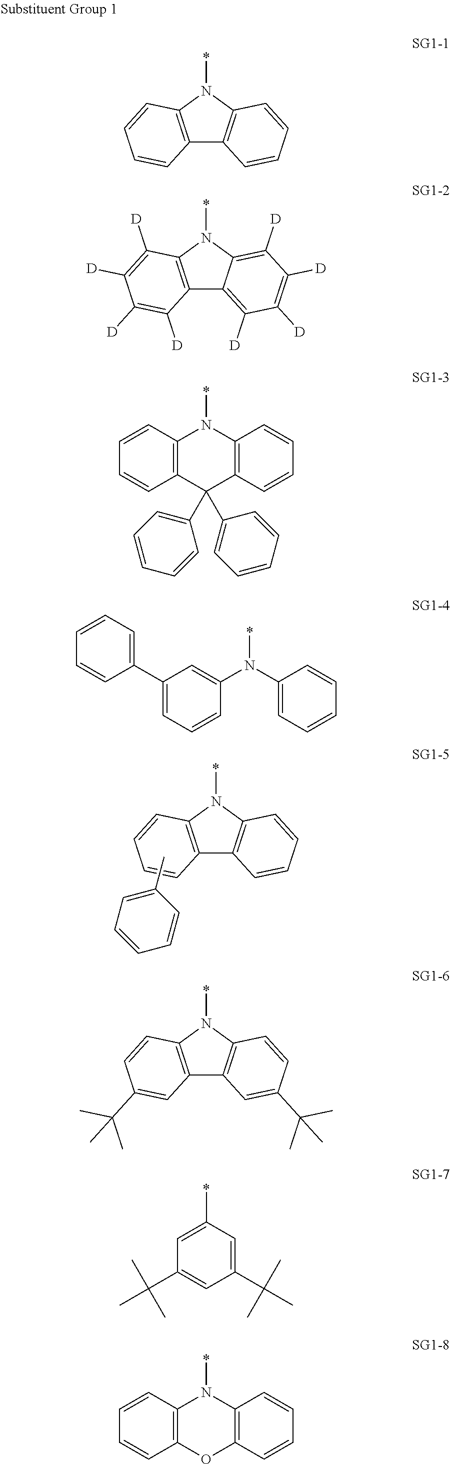

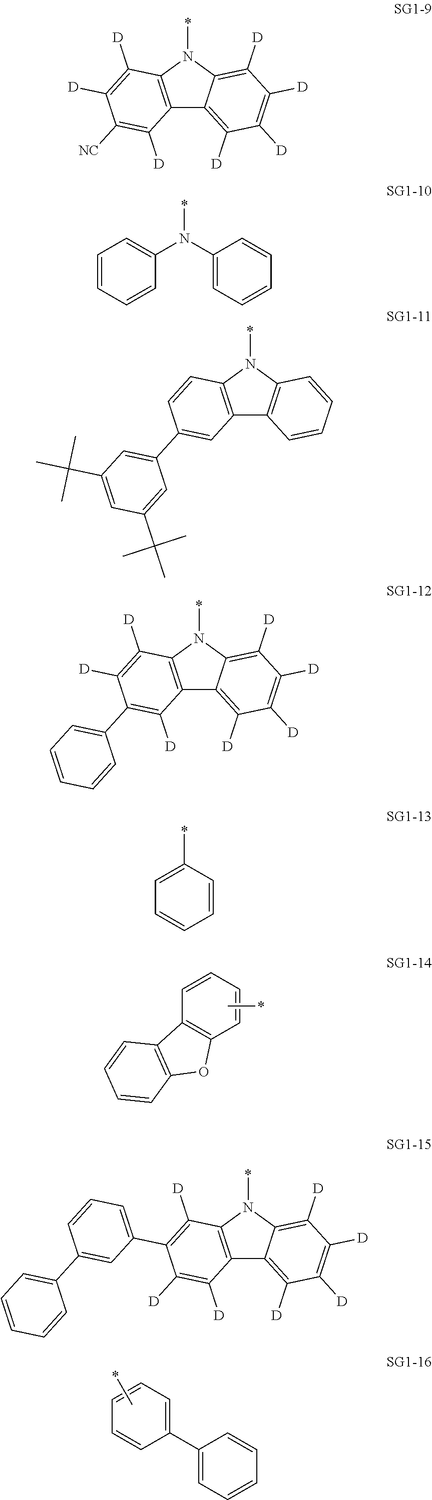

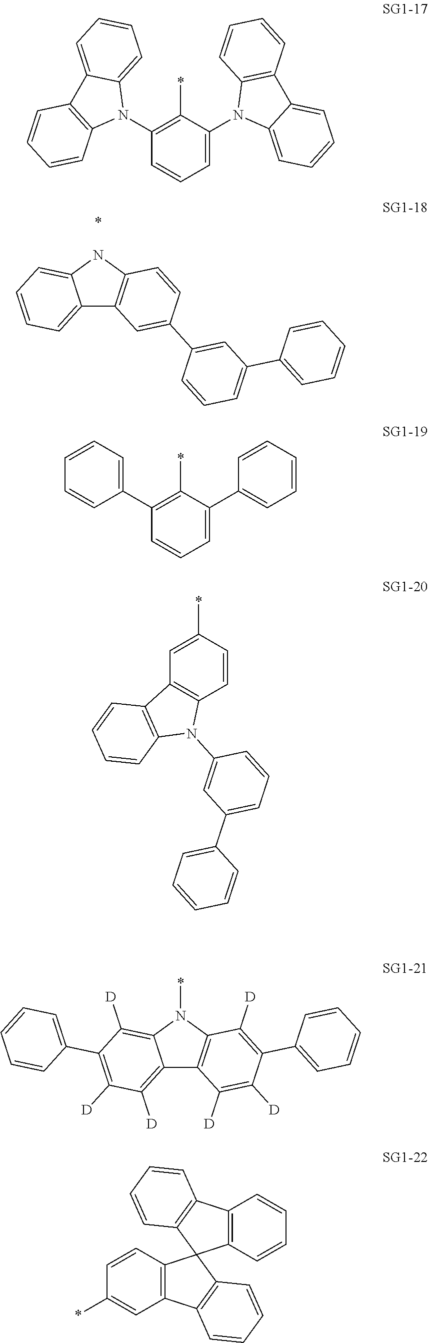

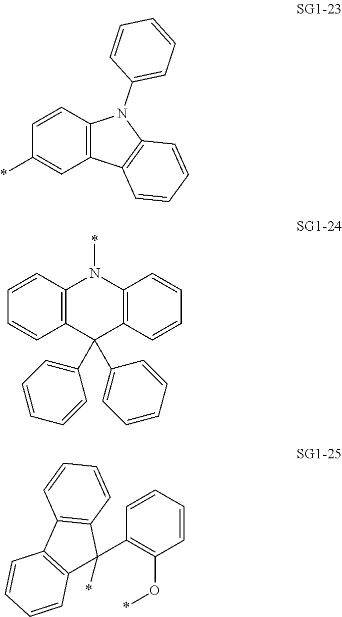

In Substituent Group 1, “*—” is a position connected with Formula 1, and “D” is a deuterium atom.

For example, R₂ may be a hydrogen atom or a deuterium atom. R₄ may be a hydrogen atom, a deuterium atom, a substituted or unsubstituted aryl group of 6 to 30 ring-forming carbon atoms, or a substituted or unsubstituted heteroaryl group of 2 to 30 ring-forming carbon atoms. In the polycyclic compound of an embodiment, R₄ may be a hydrogen atom, a deuterium atom, a substituted or unsubstituted phenyl group, a substituted or unsubstituted carbazole group, a substituted or unsubstituted fluorenyl group or a substituted or unsubstituted xanthene group. If R₄ is substituted with another substituent, the substituent may be a deuterium atom, an unsubstituted t-butyl group, an unsubstituted phenyl group, or the like. However, embodiments of the present disclosure are not limited thereto.

In the polycyclic compound of an embodiment, represented by Formula 1, R₄ may be a hydrogen atom or a deuterium atom, or represented by any one among SG2-1 to SG2-10 in Substituent Group 2. However, embodiments of the present disclosure are not limited thereto.

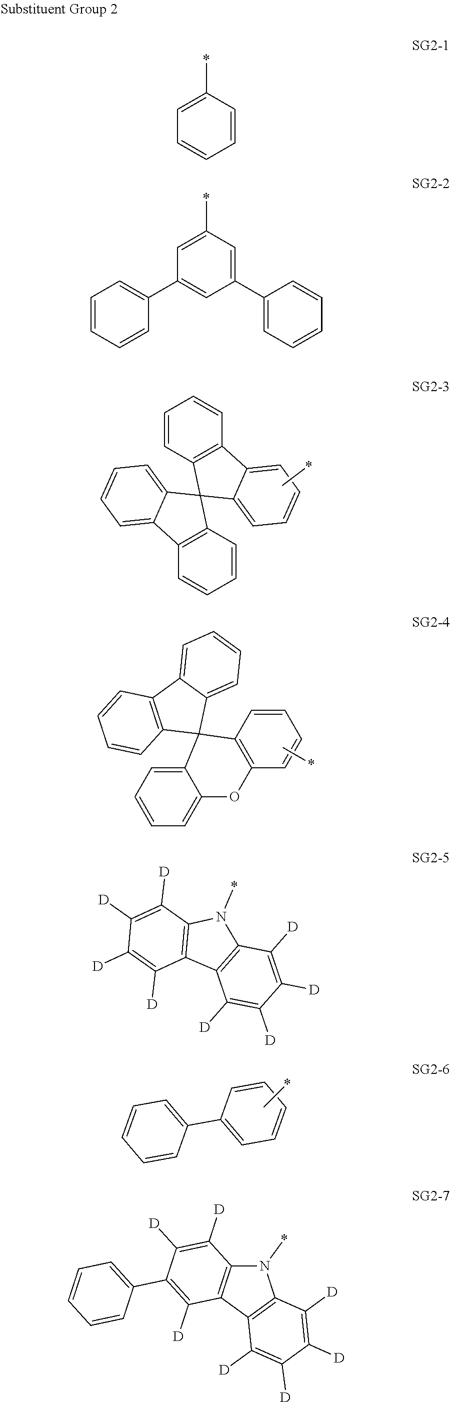

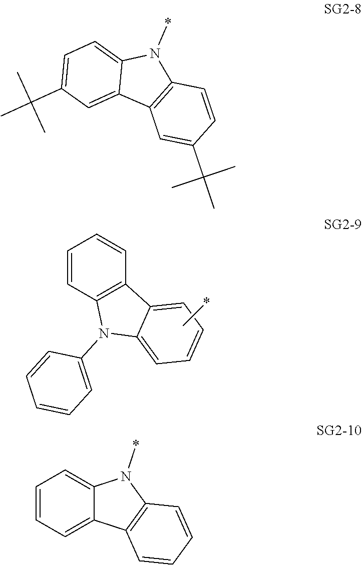

In Substituent Group 2, “*—” is a position connected with Formula 1, and “D” is a deuterium atom.

For example, R₅ and R₆ may be each independently a hydrogen atom, a deuterium atom, a substituted or unsubstituted alkyl group of 1 to 30 carbon atoms, or a substituted or unsubstituted aryl group of 6 to 30 ring-forming carbon atoms. In some embodiments, R₅ and R₆ may be each independently a hydrogen atom, a deuterium atom, a substituted or unsubstituted t-butyl group, a substituted or unsubstituted phenyl group, or a substituted or unsubstituted biphenyl group. If R₅ and R₆ are substituted with different substituents, the substituent may be a deuterium atom. However, embodiments of the present disclosure are not limited thereto.

In Formula 1, R₇ to R₉ may be each independently a substituted or unsubstituted aryl group of 6 to 30 ring-forming carbon atoms, or a substituted or unsubstituted heteroaryl group of 2 to 30 ring-forming carbon atoms. For example, R₇ to R₉ may be each independently a substituted or unsubstituted phenyl group, a substituted or unsubstituted biphenyl group, or a substituted or unsubstituted terphenyl group. In some embodiments, R₈ and R₉ may be combined with each other to form a ring. The ring through the combination of R₈ and R₉ may form a spiro structure.

In Formula 1, n1 may be an integer of 0 to 3, and n2 may be an integer of 0 to 2. n3, n4 and n5 may be each independently an integer of 0 to 4, and n6 may be an integer of 0 to 5.

If n1 is an integer of 2 or more, a plurality of R₁ may be all the same, or at least one thereof may be different from the remainder. For example, if n1 is 3, R₁ bonded to the second aromatic ring in the para relation with respect to the boron atom of the core part may be a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and the remaining two R₁ bonded to the second aromatic ring may be all hydrogen atoms or deuterium atoms. However, embodiments of the present disclosure are not limited thereto, and the number and type (or kind) of the substituted R₁ may be changed according to the embodiment of the polycyclic compound.

In some embodiments, if n2 to n6 are integers of 2 or more, each of a plurality of R₂ to R₆ may be all the same, or at least one thereof may be different from the remainder.

In the polycyclic compound of an embodiment, represented by Formula 1, at least one hydrogen atom may be substituted with a deuterium atom. In an embodiment, at least one hydrogen atom of R₁ to R₆ in Formula 1 may be substituted with a deuterium atom. For example, R₁ to R₆ may be deuterium atoms or substituents including a deuterium atom.

The polycyclic compound of an embodiment, represented by Formula 1 may be represented by Formula 2. Formula 2 represents an embodiment where substituted or unsubstituted phenyl groups are connected with a phenyl group connected with the nitrogen atom of the core part at the ortho positions with respect to the nitrogen atom of the core part. In the polycyclic compound of an embodiment, represented by Formula 2, a second steric protection substituent such as a substituted or unsubstituted terphenyl group is connected with the nitrogen atom of the core part, and steric hindrance effects by which another material is difficult to approach the core part (e.g., which makes it more difficult for another material to interact with the polycyclic compound) may be achieved. In some embodiments, at least one substituent among an alkyl group and an aryl group may be additionally introduced to the substituted or unsubstituted terphenyl group which is connected with the nitrogen atom of the core part. Accordingly, the polycyclic compound of an embodiment may maximize or increase the protecting effects of the core part.

In some embodiments, the boron atom included in the core part has electron-deficient characteristics due to a vacant p-orbital and may be easily combined with another nucleophile and/or deteriorate (for example, radical, and/or the like) in an element. If the boron atom makes a bond with another nucleophile and/or deteriorate, the boron atom having a trigonal planar bonding structure at the core part of the polycyclic compound may be deformed into a tetrahedral bonding structure, and this may become a factor of deteriorating an element. In the polycyclic compound of an embodiment, the first derivative may be fused with the first aromatic ring, and a substituent which may provide steric hindrance effects to the nitrogen atom of the core part may be connected, and accordingly, the vacant p-orbital of the boron atom may be effectively protected, and the deterioration phenomenon due to the structural deformation of a material may be prevented or reduced.

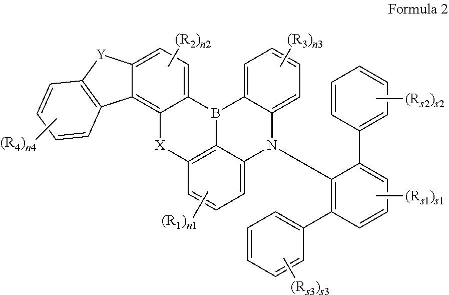

In Formula 2, Rₛ₁, Rₛ₂, and Rₛ₃ may be each independently a hydrogen atom, a deuterium atom, a substituted or unsubstituted alkyl group of 1 to 30 carbon atoms, or a substituted or unsubstituted aryl group of 6 to 30 ring-forming carbon atoms. For example, Rₛ₁, Rₛ₂, and Rₛ₃ may be each independently a hydrogen atom, a deuterium atom, an unsubstituted t-butyl group, or an unsubstituted phenyl group. In some embodiments, the polycyclic compound of an embodiment, represented by Formula 2 may include a substituted or unsubstituted terphenyl group or an unsubstituted quinquephenyl group as a substituent that may provide the nitrogen atom of the core part with steric hindrance effects.

In Formula 2, s1 may be an integer of 0 to 3, and s2 and s3 may be each independently an integer of 0 to 5. In Formula 2, if s1 to s3 are 0, the polycyclic compound of an embodiment may be unsubstituted with Rₛ₁, Rₛ₂, and Rₛ₃, respectively.

If s1 to s3 are 2 or more, each of a plurality of Rₛ₁, a plurality of Rₛ₂, and a plurality of Rₛ₃ may be all the same, or at least one thereof may be different from the remainder.

In Formula 2, for X, Y, R₁ to R₄, and n1 to n4, the same contents explained with respect to Formula 1 may be applied.

In an embodiment, the polycyclic compound represented by Formula 1 may be represented by Formula 3. The polycyclic compound of an embodiment, represented by Formula 3 may include a structure in which a first substituent and a second substituent are connected with the second aromatic ring and the third aromatic ring of the core part, respectively. For example, each of the first substituent and the second substituent may be an amine group, an aryl group, or a heteroaryl group. In the polycyclic compound of an embodiment, the first substituent may be connected with the second aromatic ring at the para position with respect to the boron atom of the core part. In some embodiments, the second substituent may be connected with the third aromatic ring in at least one position among the meta position and the para position with respect to the boron atom of the core part.

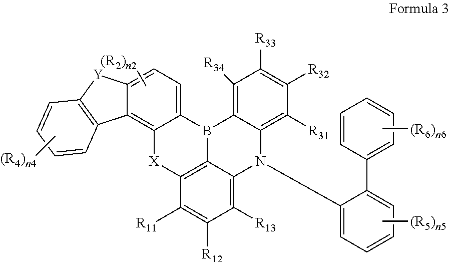

In Formula 3, R₁₁, R₁₃, R₃₁, and R₃₄ may be each independently a hydrogen atom or a deuterium atom. In some embodiments, R₁₂ may be a substituted or unsubstituted amine group, a substituted or unsubstituted aryl group of 6 to 30 ring-forming carbon atoms, or a substituted or unsubstituted heteroaryl group of 2 to 30 ring-forming carbon atoms. R₁₂ of Formula 3 may correspond to the above-described first substituent.

For example, R₁₂ may be a substituted or unsubstituted carbazole group, a substituted or unsubstituted diphenylamine group, a substituted or unsubstituted phenyl group, a substituted or unsubstituted acridine group, a substituted or unsubstituted phenoxazine group, a substituted or unsubstituted dibenzofuranyl group, or a substituted or unsubstituted fluorenyl group. In the polycyclic compound of an embodiment, represented by Formula 3, R₁₂ may be represented by any one among SG1-1 to SG1-24 in Substituent Group 1.

In Formula 3, R₃₂ and R₃₃ may be each independently a substituted or unsubstituted amine group, a substituted or unsubstituted aryl group of 6 to 30 ring-forming carbon atoms, or a substituted or unsubstituted heteroaryl group of 2 to 30 ring-forming carbon atoms. For example, R₃₂ and R₃₃ may be each independently a substituted or unsubstituted carbazole group, a substituted or unsubstituted diphenylamine group, a substituted or unsubstituted phenyl group, a substituted or unsubstituted acridine group, a substituted or unsubstituted phenoxazine group, a substituted or unsubstituted dibenzofuranyl group, or a substituted or unsubstituted fluorenyl group. In the polycyclic compound of an embodiment, represented by Formula 3, R₃₂ and R₃₃ may be each independently represented by any one among SG1-1 to SG1-24 in Substituent Group 1. R₃₂ and R₃₃ of Formula 3 may correspond to the above-described second substituent.

In some embodiments, R₃₂ and R₃₃ may be combined with each other to form a ring. For example, R₃₂ and R₃₃ may be combined with each other to form a heterocycle including N, O or S as a ring-forming atom. In the polycyclic compound of an embodiment, represented by Formula 3, the substituent represented by SG1-25 in Substituent Group 1 may be connected at the positions of R₃₂ and R₃₃.

In the polycyclic compound of an embodiment, represented by Formula 3, the same contents as explained with respect to Formula 1 may be applied for X, Y, R₂, R₄ to R₆, n2, and n4 to n6.

The polycyclic compound of an embodiment includes a structure in which the first derivative is fused with the first aromatic ring around the heavy atom in order to protect the vacant p-orbital of the boron atom included in the core part, and may include a structure in which a first steric protection substituent is additionally introduced into the fused first derivative. The first steric protection substituent may be a bulky substituent of an amine group, an alkyl group, an aryl group, and/or a heteroaryl group. For example, the polycyclic compound of an embodiment, represented by Formula 1 may be represented by Formula 4.

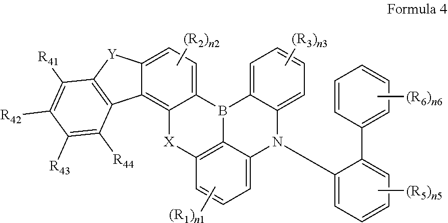

In Formula 4, R₄₁, R₄₂, and R₄₄ may be each independently a hydrogen atom or a deuterium atom. R₄₃ may be a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms.

For example, R₄₃ may be a hydrogen atom, a deuterium atom, a substituted or unsubstituted phenyl group, a substituted or unsubstituted carbazole group, a substituted or unsubstituted fluorenyl group, or a substituted or unsubstituted xanthene group. In some embodiments, R₄₃ in Formula 4 may be represented by any one among SG2-1 to SG2-10 in Substituent Group 2.

In the polycyclic compound of an embodiment, represented by Formula 4, the same contents explained with respect to Formula 1 may be applied for X, Y, R₁ to R₃, R₅, R₆, n1 to n3, n5 and n6.

The polycyclic compound of an embodiment, represented by Formula 1 may be represented by any one among Formula 5-1 to Formula 5-4. Formula 5-1 to Formula 5-4 are embodiments in which the type (or kind) of the first derivative fused with the first aromatic ring, the type (or kind) of the substituent substituted at the first derivative, and the substituent connected with the nitrogen atom of the core part, are embodied.

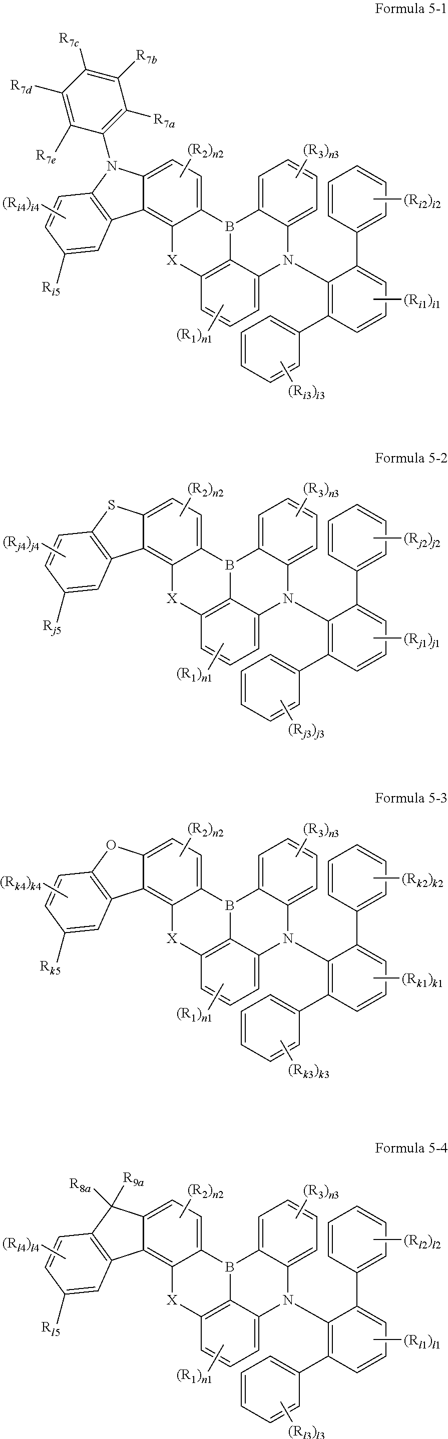

In Formula 5-1 to Formula 5-4, Rᵢ₁ to Rᵢ₃, Rⱼ₁ to Rⱼ₃, Rₖ₁ to Rₖ₃, and Rₗ₁ to Rₗ₃ may be each independently a hydrogen atom, a deuterium atom, a substituted or unsubstituted alkyl group of 1 to 30 carbon atoms, or a substituted or unsubstituted aryl group of 6 to 30 ring-forming carbon atoms. For example, Rᵢ₁ to Rᵢ₃, Rⱼ₁ to Rⱼ₃, Rₖ₁ to Rₖ₃, and Rₗ₁ to Rₗ₃ may be each independently a hydrogen atom, a deuterium atom, a substituted or unsubstituted t-butyl group, or a substituted or unsubstituted phenyl group. If Rᵢ₁ to Rᵢ₃, Rⱼ₁ to Rⱼ₃, Rₖ₁ to Rₖ₃, and Rₗ₁ to Rₗ₃ are substituted with different substituents, the substituent may be a deuterium atom. In some embodiments, the polycyclic compound of an embodiment may include a structure in which a substituted or unsubstituted terphenyl group, or a substituted or unsubstituted quinquephenyl group is connected with the nitrogen atom of the core part.

In Formula 5-1 to Formula 5-4, i1, j1, k1, and 11 may be each independently an integer of 0 to 3, and i2, i3, j2, j3, k2, k3, l2, and l3 may be each independently an integer of 0 to 5. If i1, j1, k1, l1, i2, i3, j2, j3, k2, k3, l2, and l3 are integers of 2 or more, each of a plurality of Rᵢ₁ to Rᵢ₃, Rⱼ₁ to Rⱼ₃, Rₖ₁ to Rₖ₃, and Rₗ₁ to Rₗ₃ may be all the same, or at least one thereof may be different from the remainder.

In Formula 5-1 to Formula 5-4, i4, j4, k4, and l4 may be each independently an integer of 0 to 3. Rᵢ₄, Rⱼ₄, Rₖ₄, and Rₗ₄ may be each independently a hydrogen atom or a deuterium atom. If i4, j4, k4, and l4 are integers of 2 or more, a plurality of Rᵢ₄, Rⱼ₄, Rₖ₄, and Rₗ₄ may be all the same, or at least one thereof may be different from the remainder.

In some embodiments, in Formula 5-1 to Formula 5-4, Rᵢ₅, Rⱼ₅, Rₖ₅, and Rₗ₅ may be each independently a hydrogen atom, a deuterium atom, a substituted or unsubstituted aryl group of 6 to 30 ring-forming carbon atoms, or a substituted or unsubstituted heteroaryl group of 2 to 30 ring-forming carbon atoms. For example, Rᵢ₅, Rⱼ₅, Rₖ₅, and Rₗ₅ may be each independently a hydrogen atom, a deuterium atom, a substituted or unsubstituted phenyl group, a substituted or unsubstituted biphenyl group, a substituted or unsubstituted terphenyl group, a substituted or unsubstituted fluorenyl group, or a substituted or unsubstituted carbazole group. If each of Rᵢ₅, Rⱼ₅, Rₖ₅, and Rₗ₅ is substituted, the substituent may be a deuterium atom, an unsubstituted t-butyl group, an unsubstituted phenyl group, and/or the like. However, embodiments of the present disclosure are not limited thereto.

In the polycyclic compounds represented by Formula 5-1 to Formula 5-4, Rᵢ₅, Rⱼ₅, Rₖ₅, and Rₗ₅ may be each independently a hydrogen atom or a deuterium atom, or represented by any one among SG2-1 to SG2-10 in Substituent Group 2. However, embodiments of the present disclosure are not limited thereto.

In the polycyclic compound represented by Formula 5-1, R₇ₐ to R₇ₑ may be each independently a hydrogen atom, a deuterium atom, a substituted or unsubstituted alkyl group of 1 to 10 carbon atoms, or a substituted or unsubstituted aryl group of 6 to 15 ring-forming carbon atoms. For example, R₇ₐ to R₇ₑ may be each independently a hydrogen atom, a deuterium atom, a substituted or unsubstituted t-butyl group, or a substituted or unsubstituted phenyl group.

In the polycyclic compound represented by Formula 5-4, R₈ₐ and R₉ₐ may be each independently a substituted or unsubstituted aryl group of 6 to 30 ring-forming carbon atoms. For example, R₈ₐ and R₉ₐ may be each independently a substituted or unsubstituted phenyl group. Otherwise, R₈ₐ and R₉ₐ may be combined with each other to form a ring. In Formula 5-4, the ring formed by the combination of R₈ₐ and R₉ₐ from each other may form a spiro structure.

The polycyclic compound of an embodiment may be represented by any one among the compounds in Compound Group 1. The light emitting element ED according to an embodiment may include at least one among the compounds in Compound Group 1. In Compound Group 1, D is a deuterium atom.

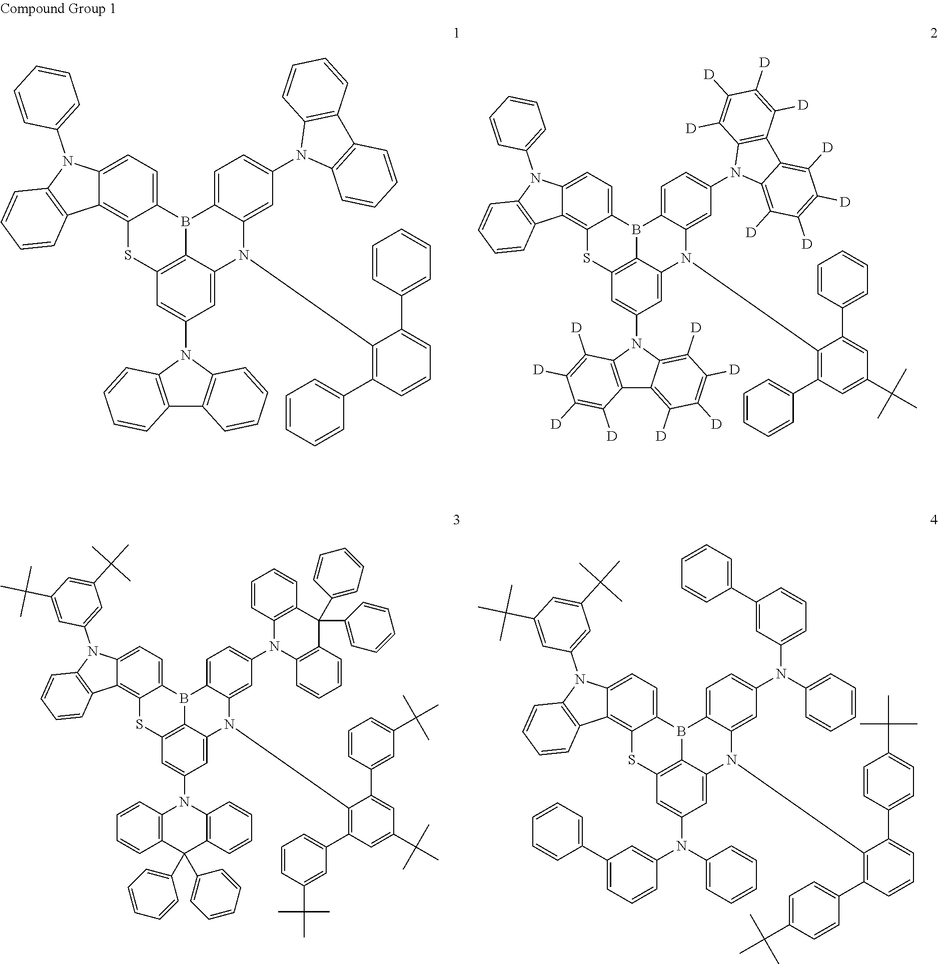

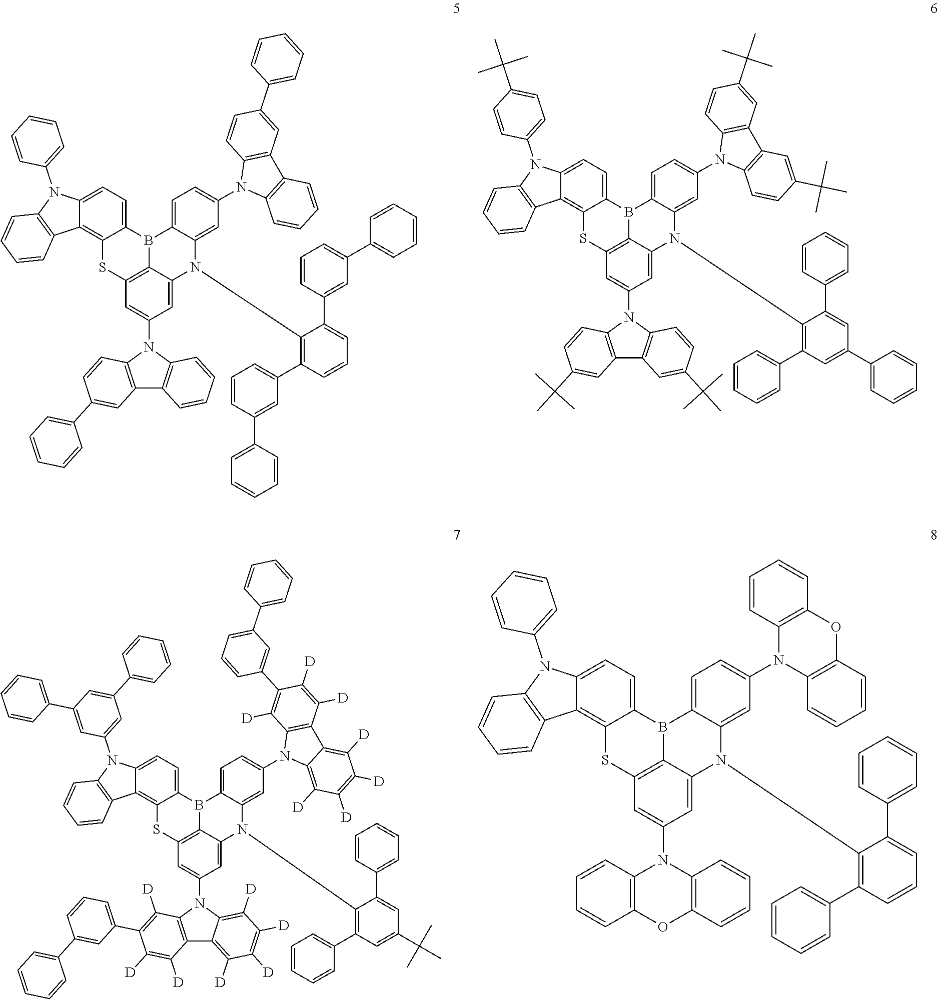

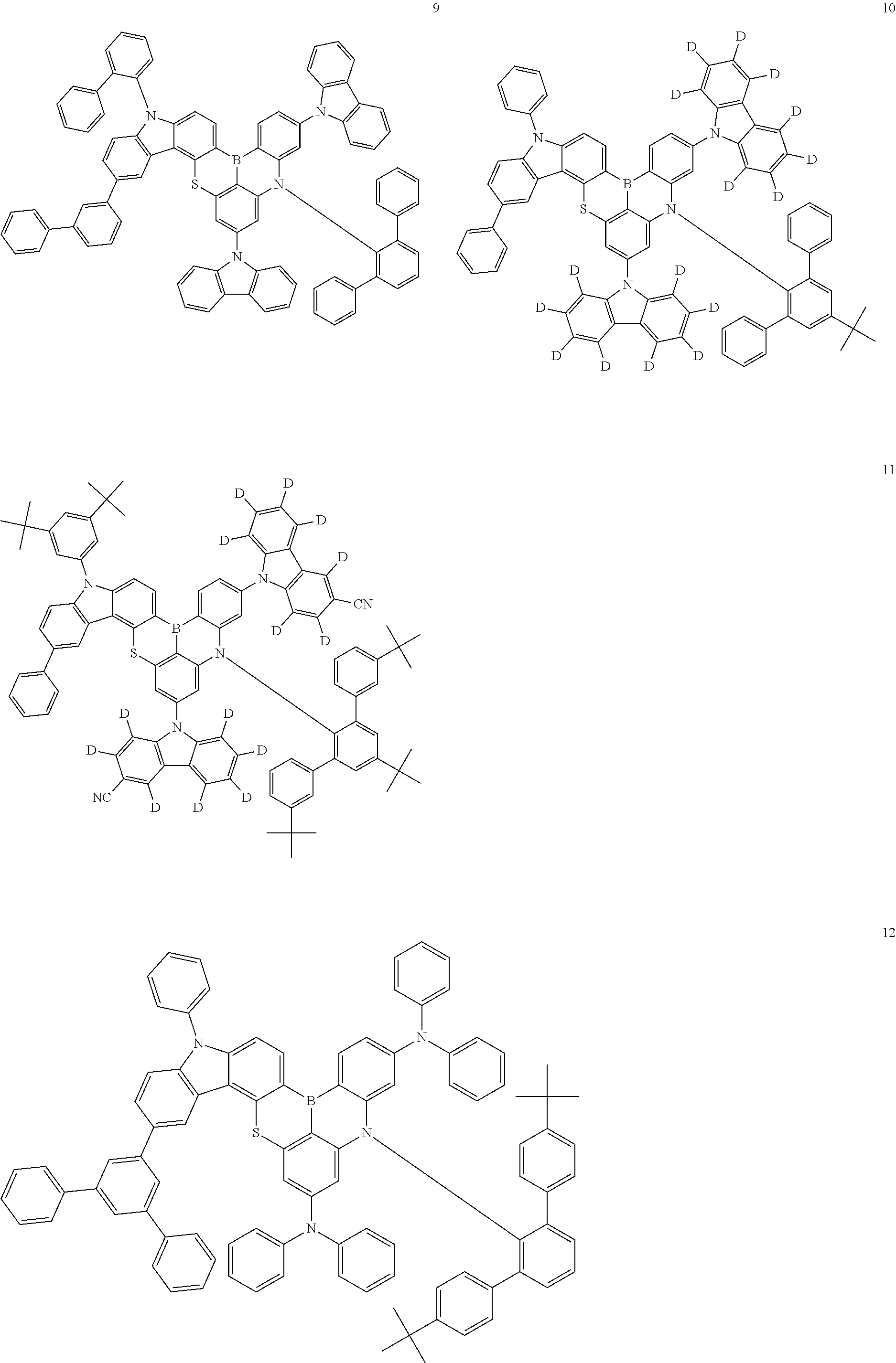

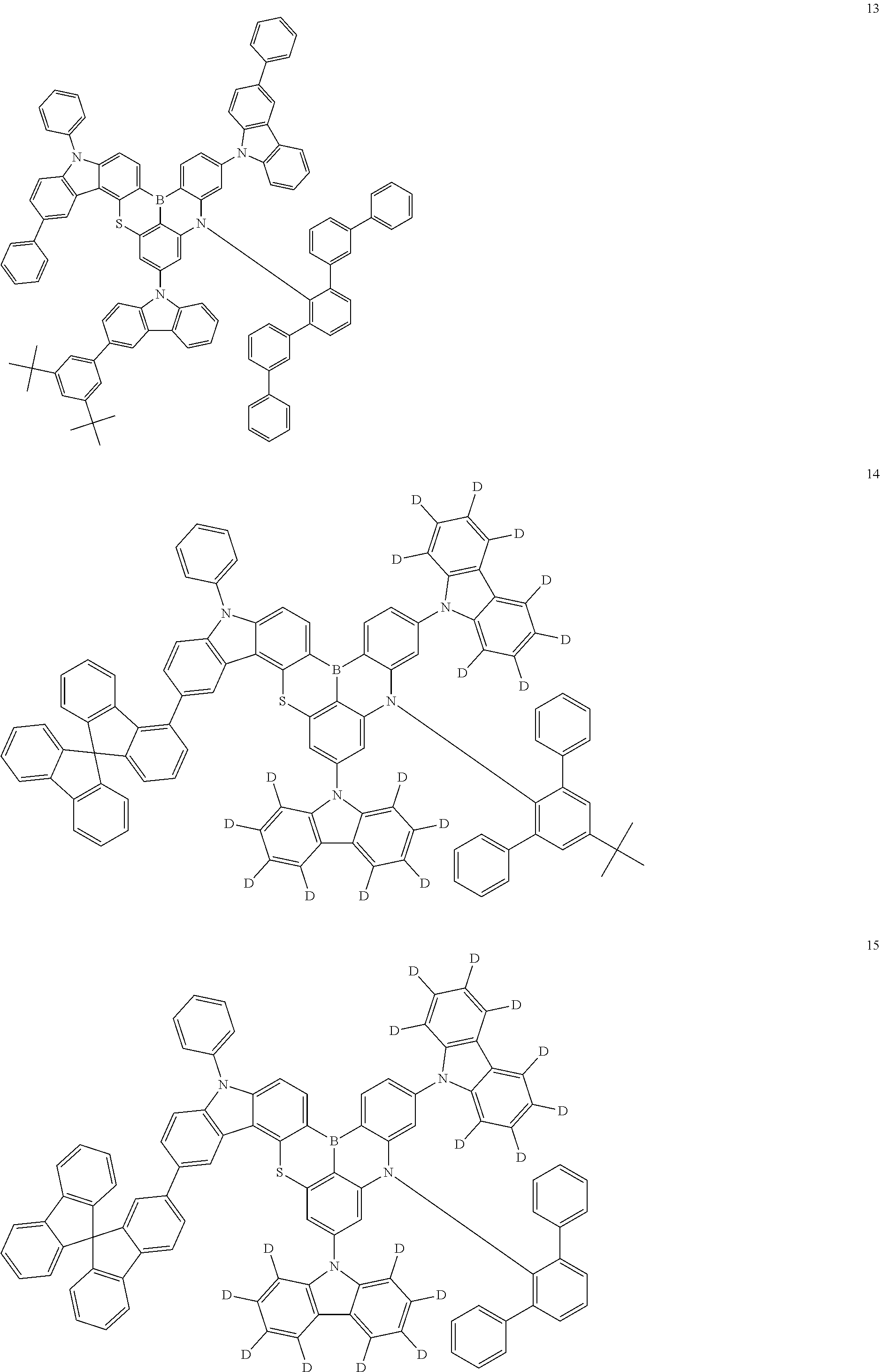

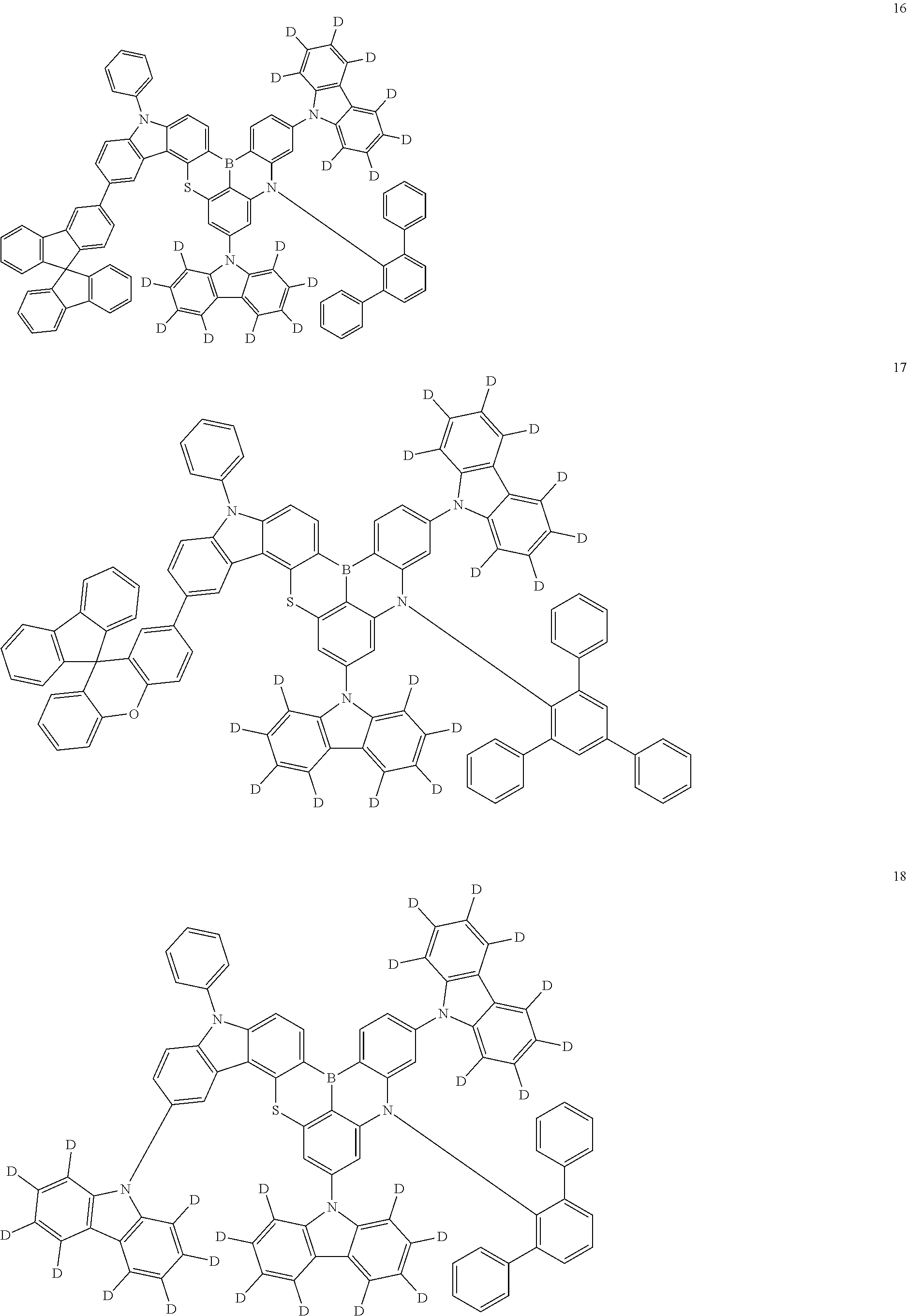

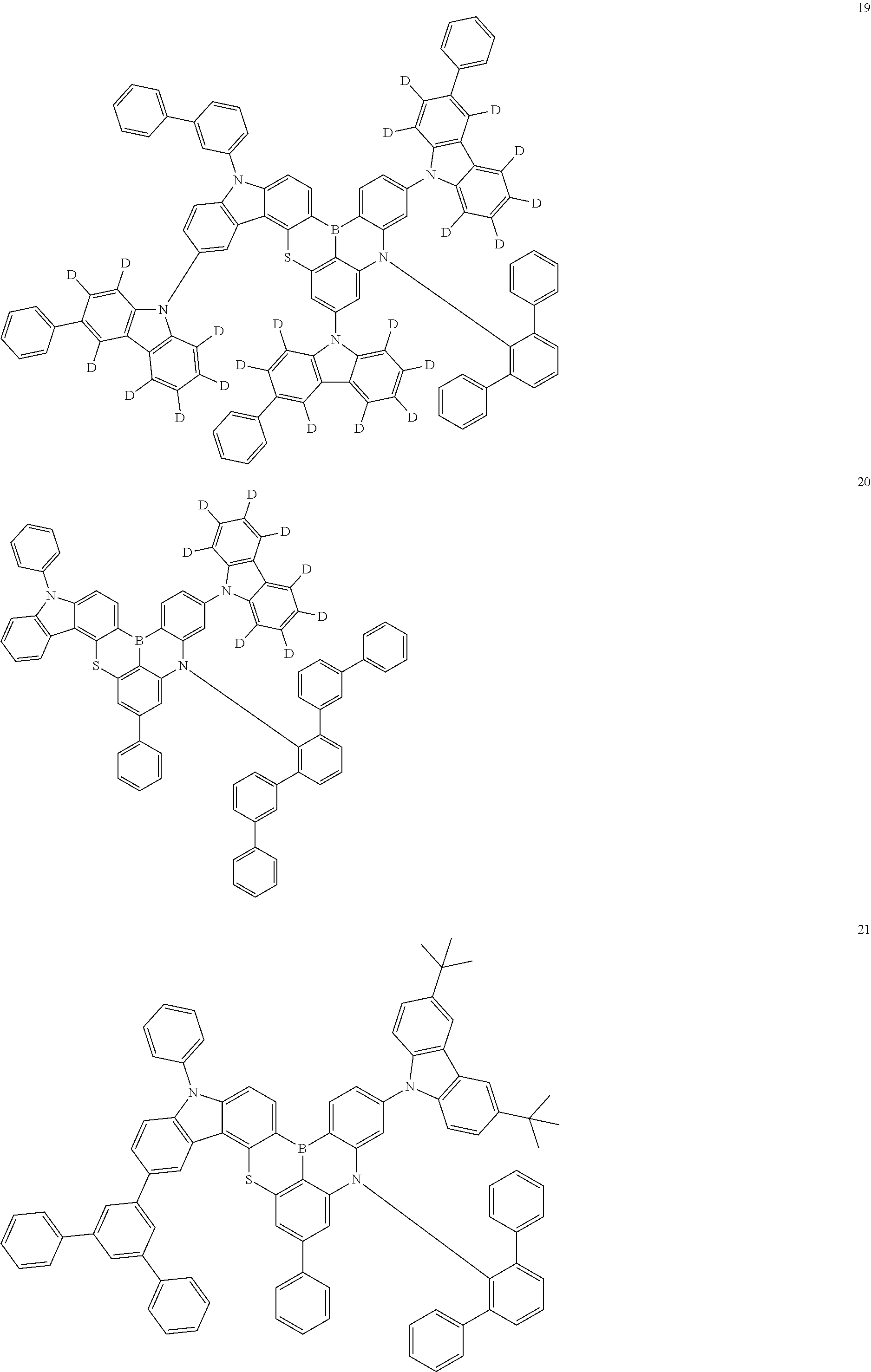

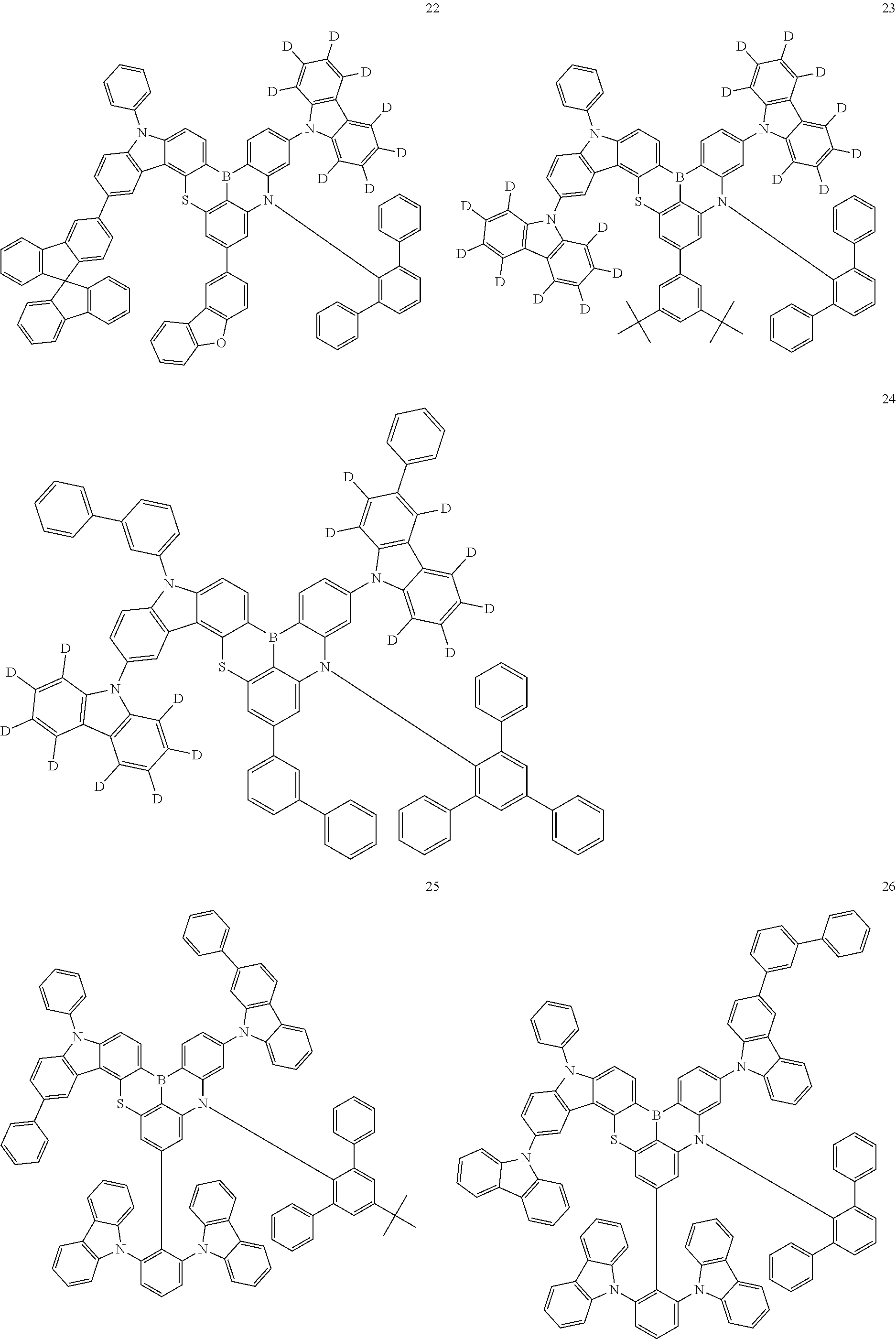

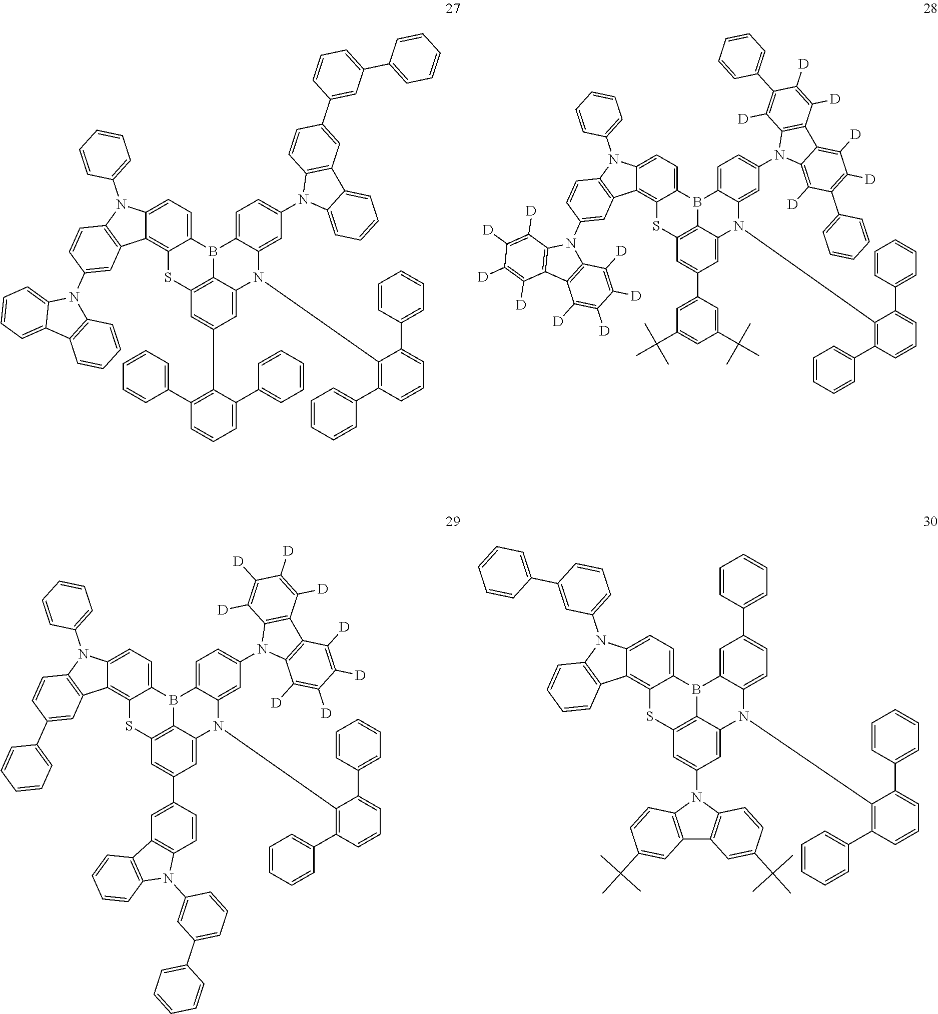

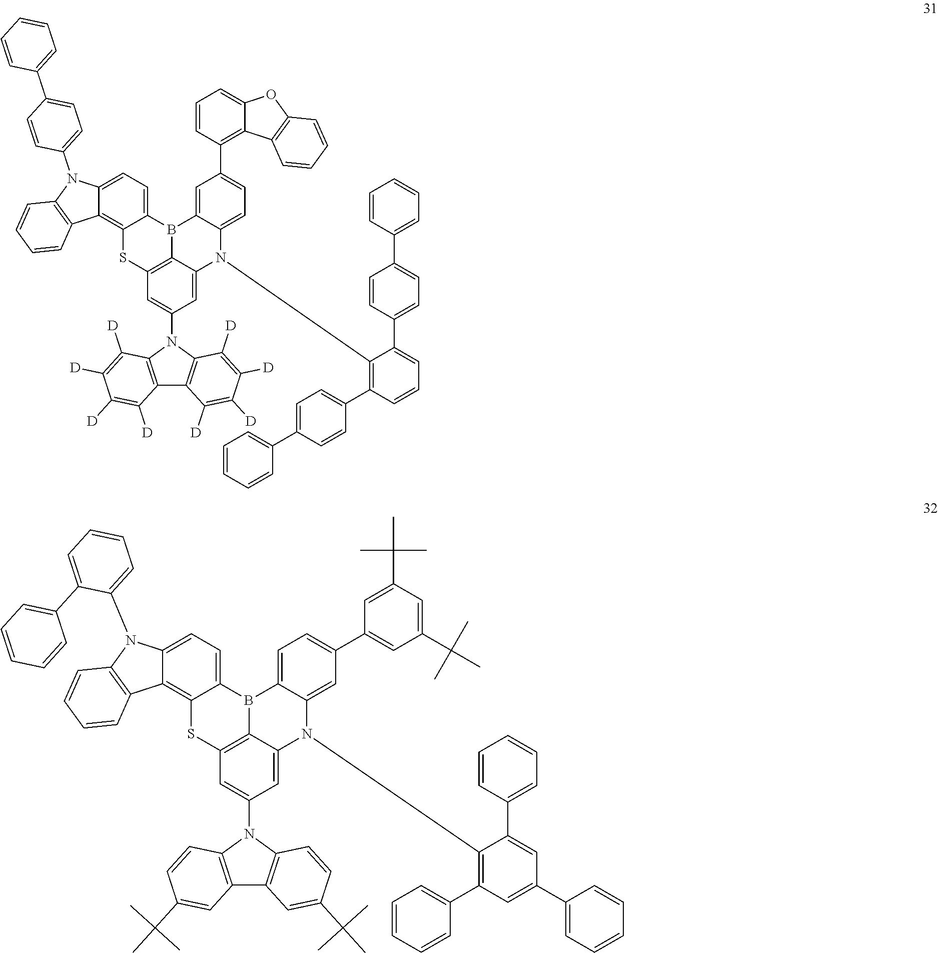 [SMILES: [2H]c1c([2H])c([2H])c2c(c1[2H])c1c([2H])c([2H])c([2H])c([2H])c1n2-c1cc2c3c(c1)N(c1c(-c4ccc(-c5ccccc5)cc4)cccc1-c1ccc(-c4ccccc4)cc1)c1ccc(-c4cccc5oc6ccccc6c45)cc1B3c1ccc3c(c1S2)c1ccccc1n3-c1ccc(-c2ccccc2)cc1 ; CC(C)(C)c1cc(-c2ccc3c(c2)N(c2c(-c4ccccc4)cc(-c4ccccc4)cc2-c2ccccc2)c2cc(-n4c5ccc(C(C)(C)C)cc5c5cc(C(C)(C)C)ccc54)cc4c2B3c2ccc3c(c2S4)c2ccccc2n3-c2ccccc2-c2ccccc2)cc(C(C)(C)C)c1]

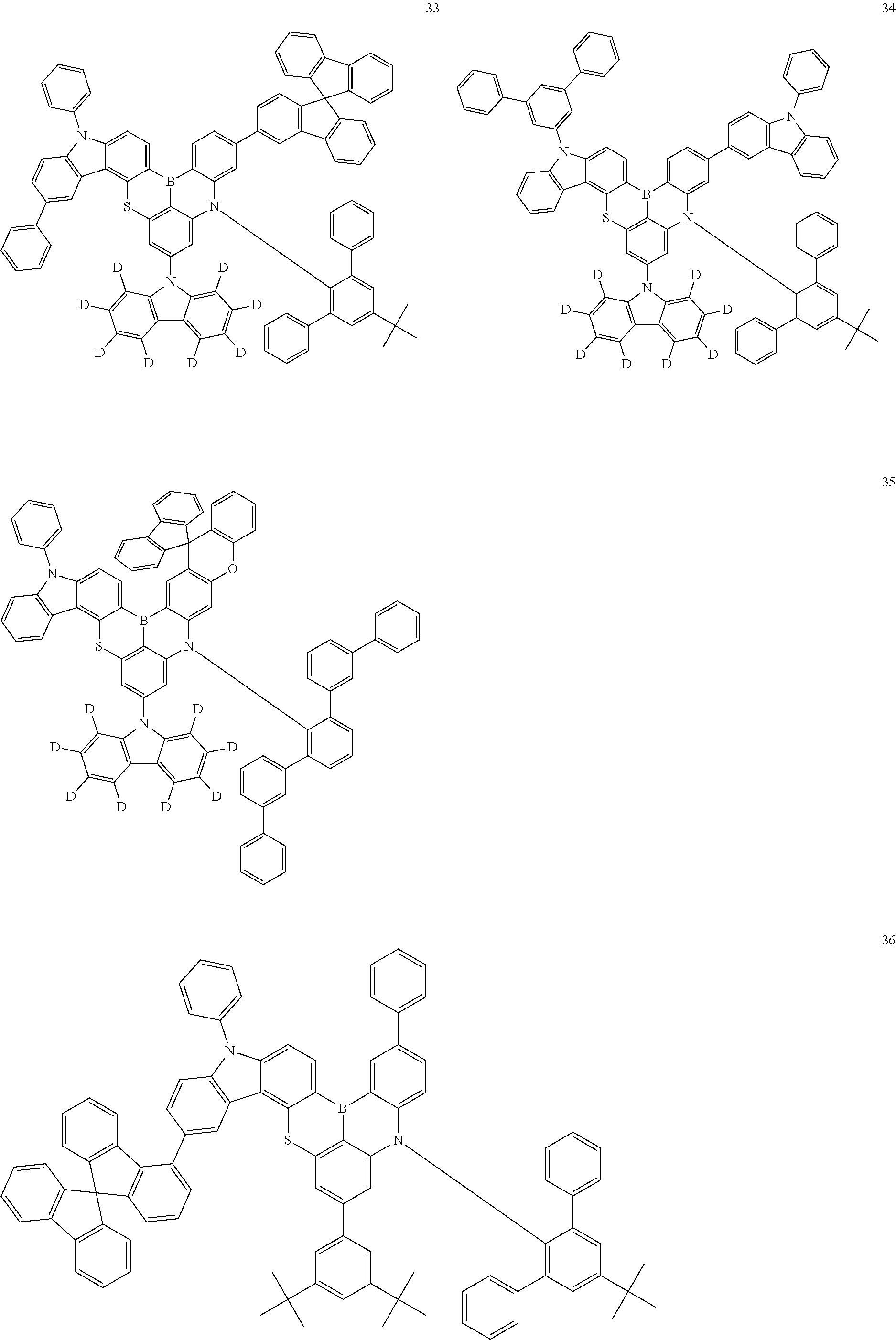

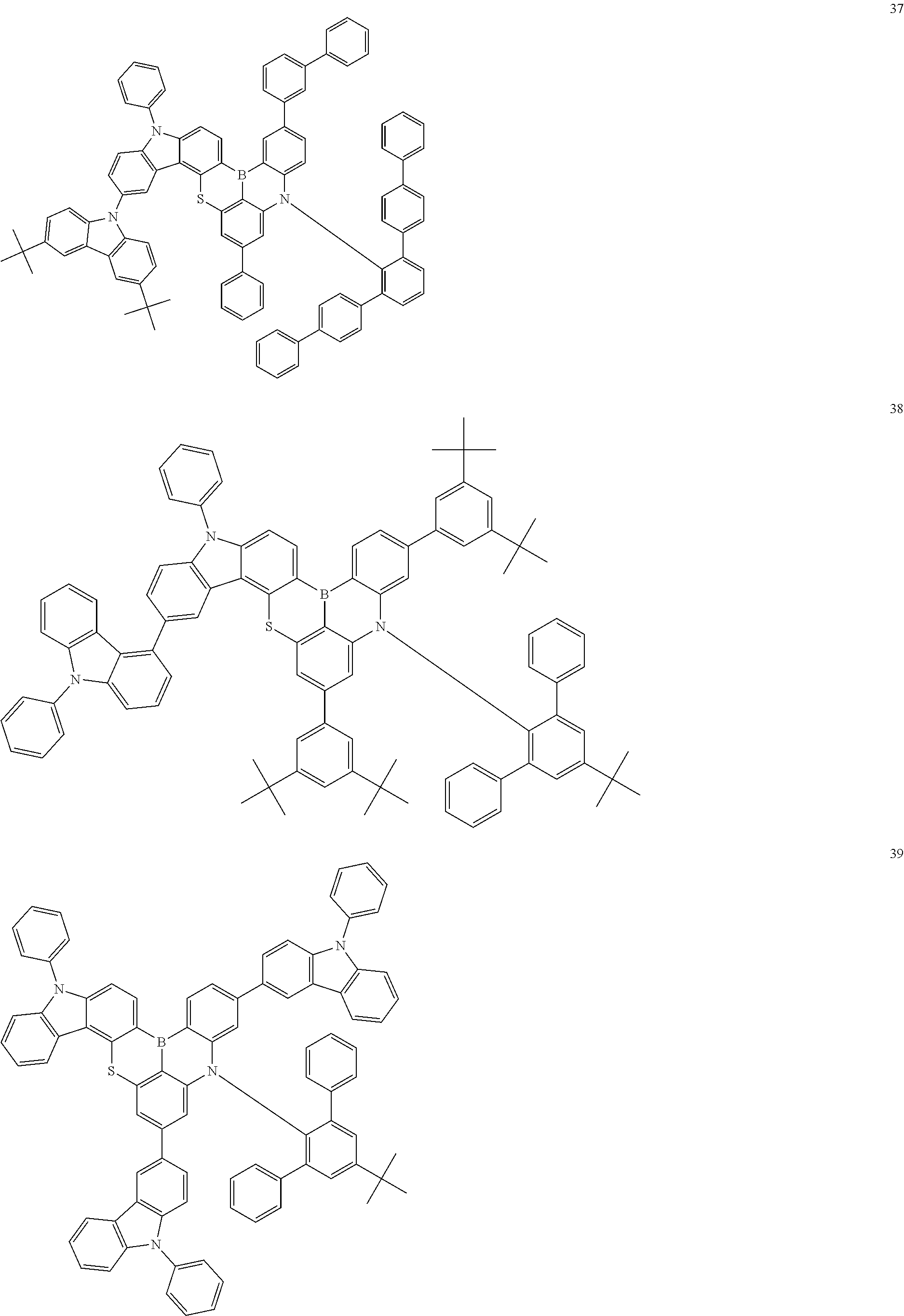

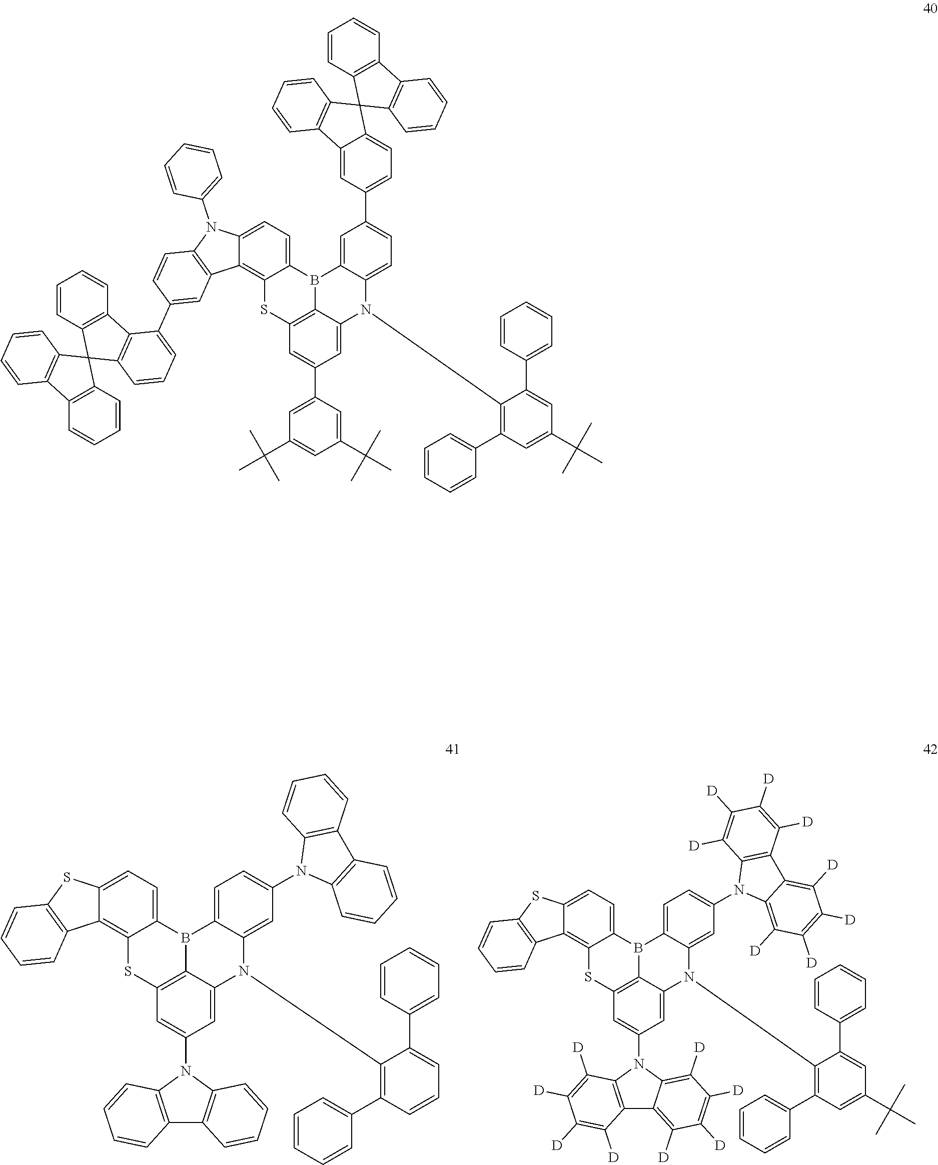

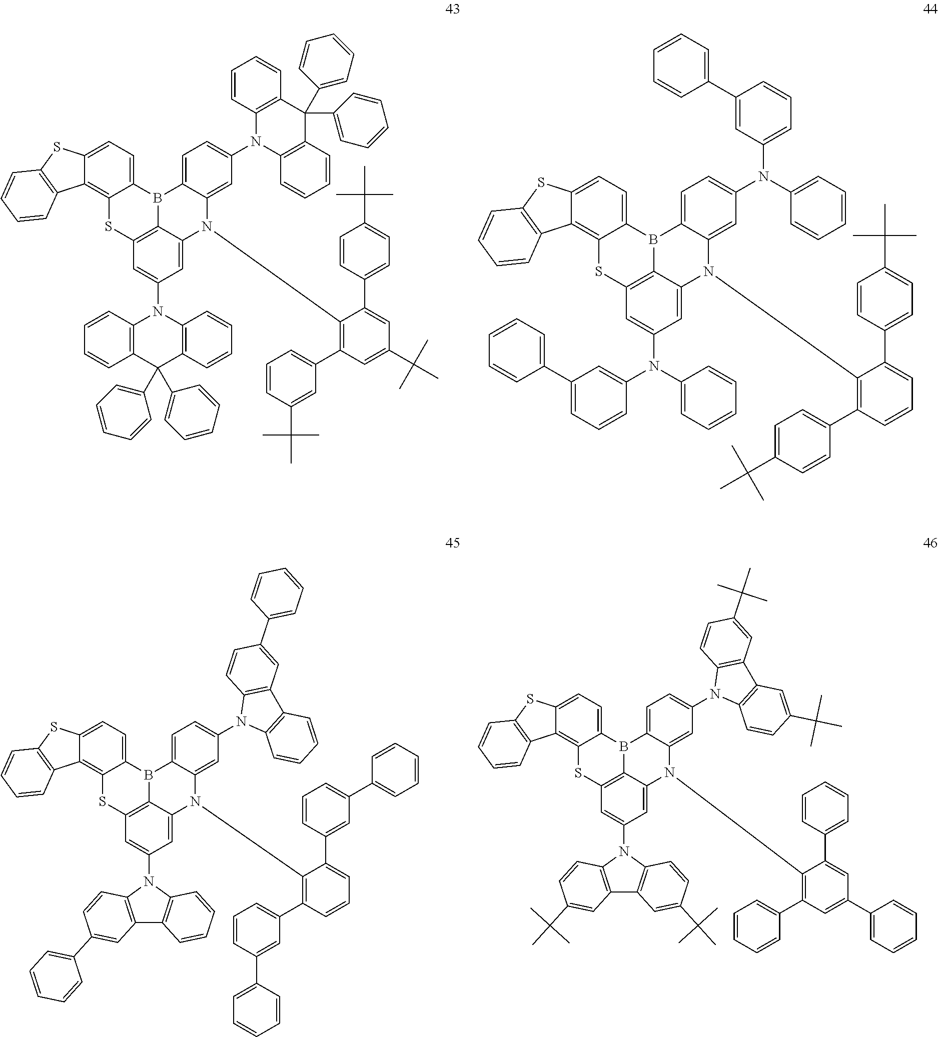

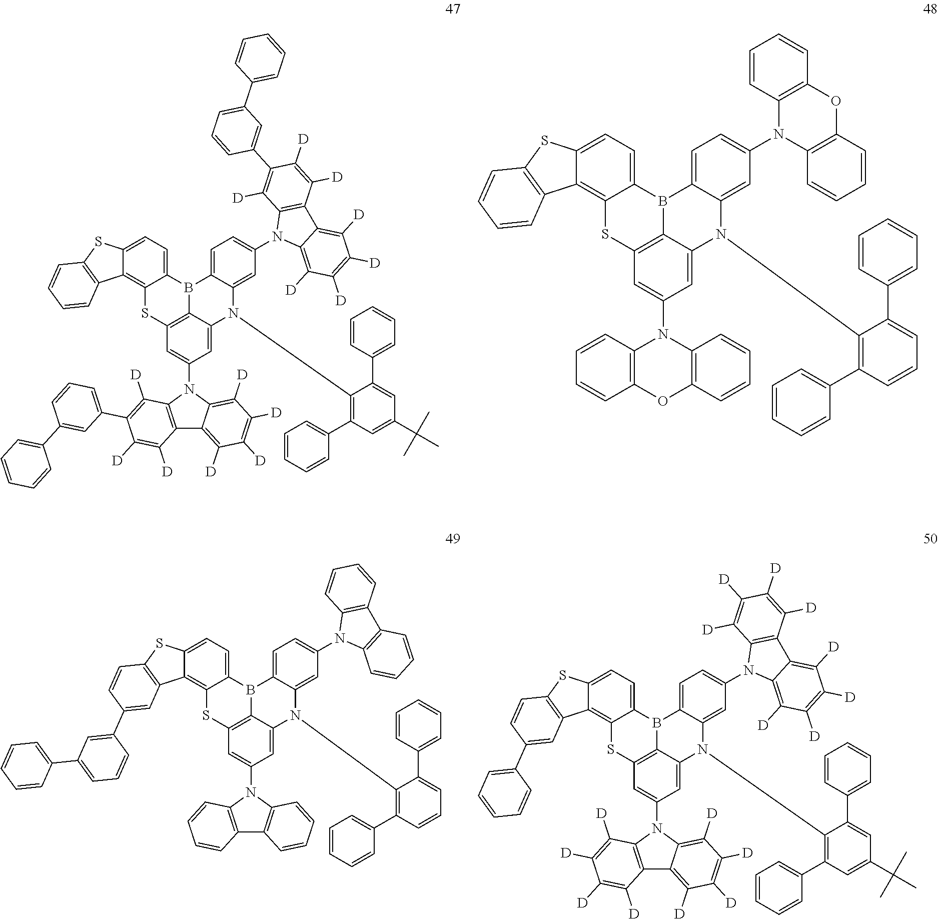

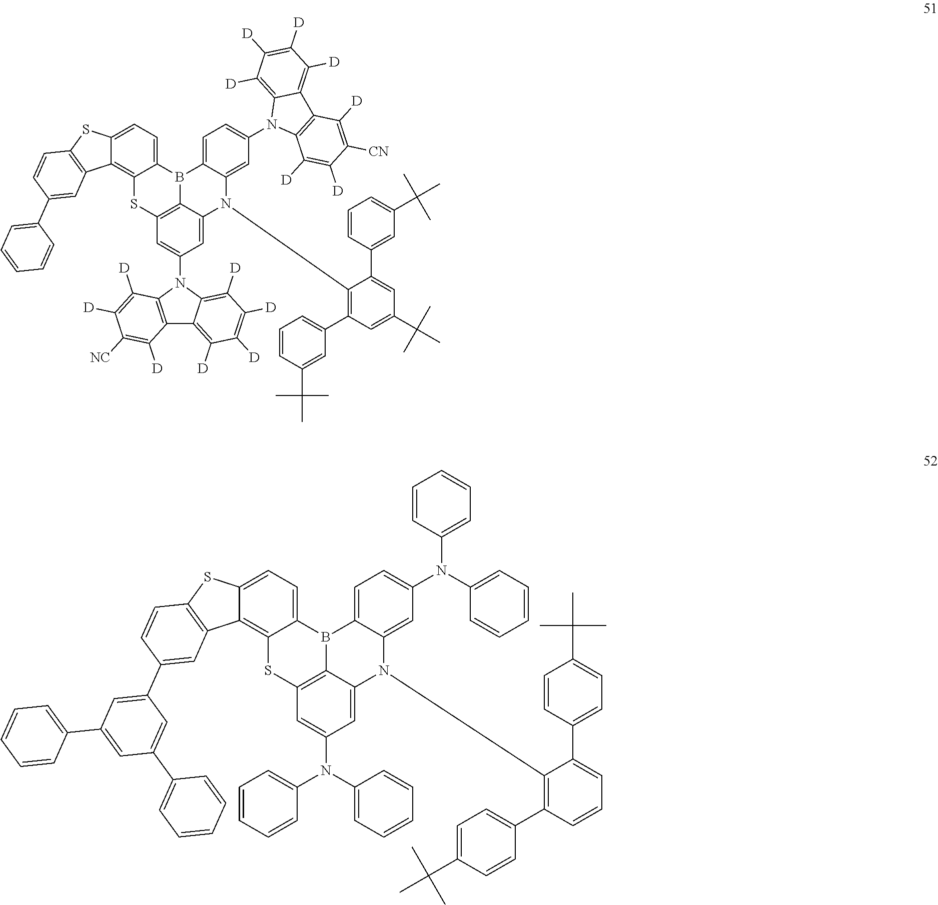 [SMILES: [2H]c1c([2H])c([2H])c2c(c1[2H])c1c([2H])c(C#N)c([2H])c([2H])c1n2-c1ccc2c(c1)N(c1c(-c3cccc(C(C)(C)C)c3)cc(C(C)(C)C)cc1-c1cccc(C(C)(C)C)c1)c1cc(-n3c4c([2H])c([2H])c([2H])c([2H])c4c4c([2H])c(C#N)c([2H])c([2H])c43)cc3c1B2c1ccc2sc4ccc(-c5ccccc5)cc4c2c1S3 ; CC(C)(C)c1ccc(-c2cccc(-c3ccc(C(C)(C)C)cc3)c2N2c3cc(N(c4ccccc4)c4ccccc4)ccc3B3c4ccc5sc6ccc(-c7cc(-c8ccccc8)cc(-c8ccccc8)c7)cc6c5c4Sc4cc(N(c5ccccc5)c5ccccc5)cc2c43)cc1]

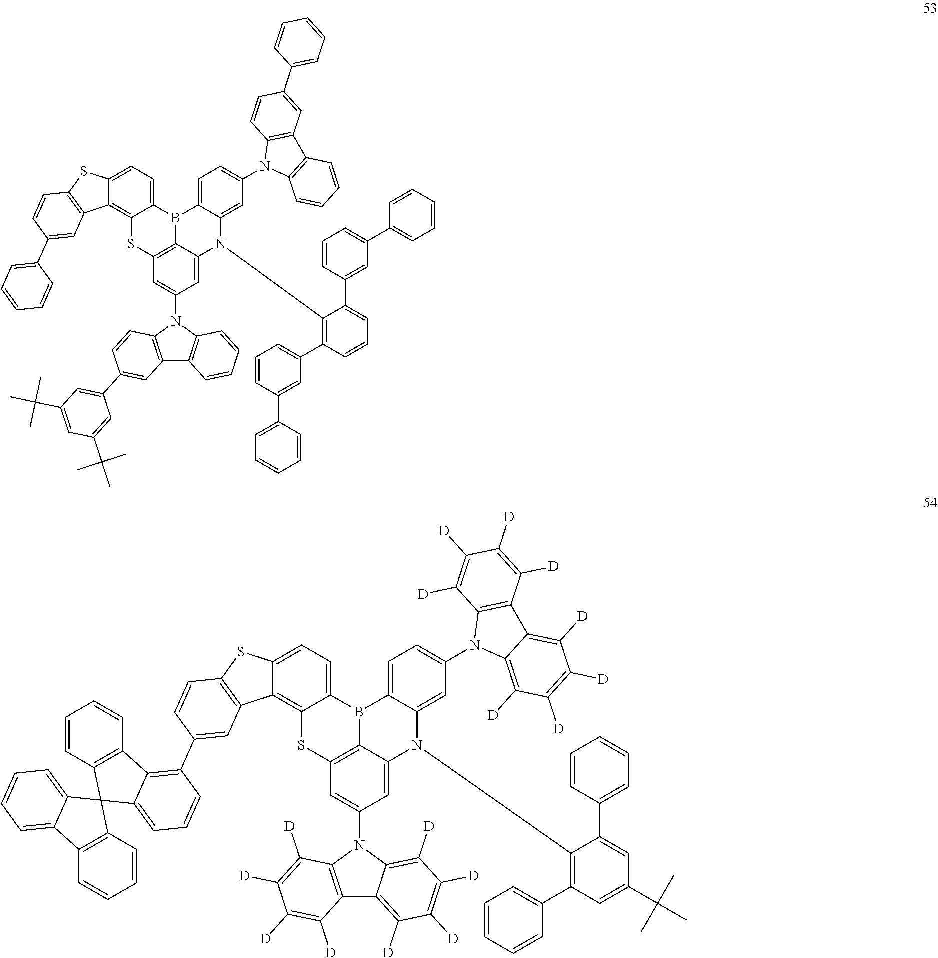 [SMILES: CC(C)(C)c1cc(-c2ccc3c(c2)c2ccccc2n3-c2cc3c4c(c2)N(c2c(-c5cccc(-c6ccccc6)c5)cccc2-c2cccc(-c5ccccc5)c2)c2cc(-n5c6ccccc6c6cc(-c7ccccc7)ccc65)ccc2B4c2ccc4sc5ccc(-c6ccccc6)cc5c4c2S3)cc(C(C)(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c([2H])c([2H])c([2H])c43)cc3c1B2c1ccc2sc4ccc(-c5cccc6c5-c5ccccc5C65c6ccccc6-c6ccccc65)cc4c2c1S3]

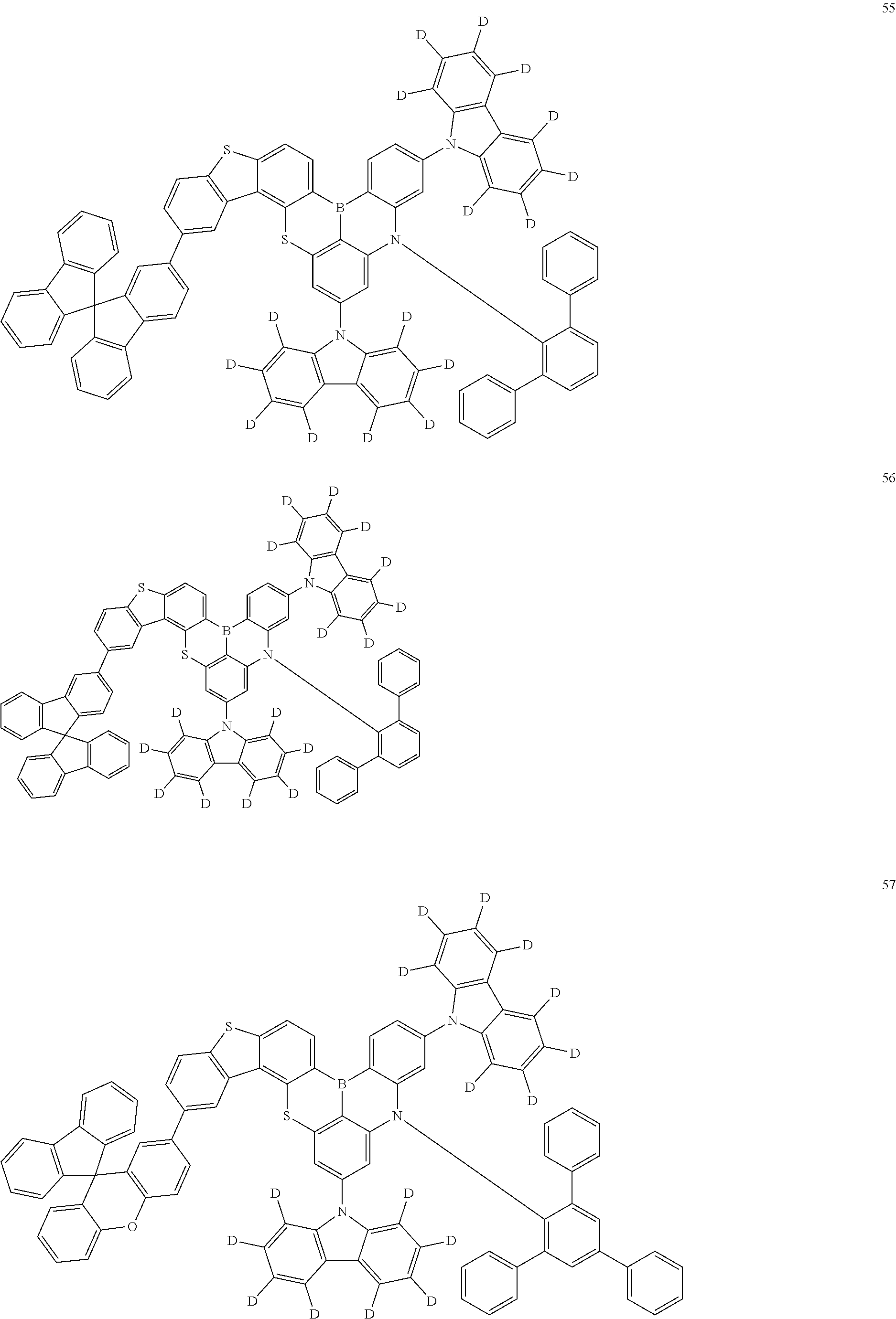

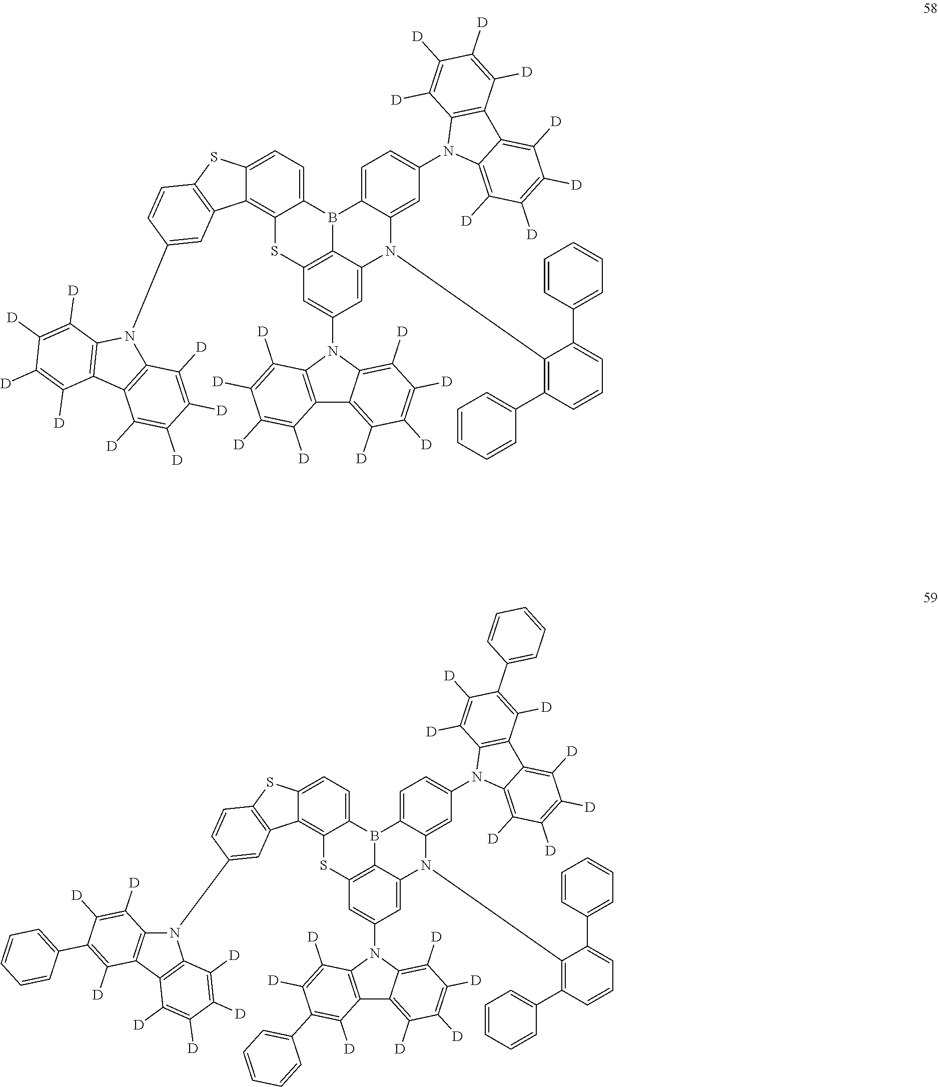

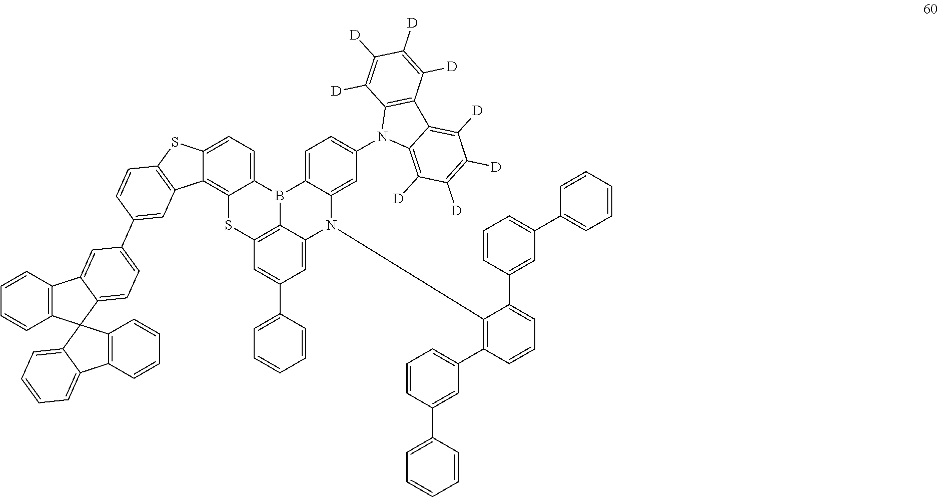 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2sc4ccc(-c5ccc6c(c5)-c5ccccc5C65c6ccccc6-c6ccccc65)cc4c2c1S3]

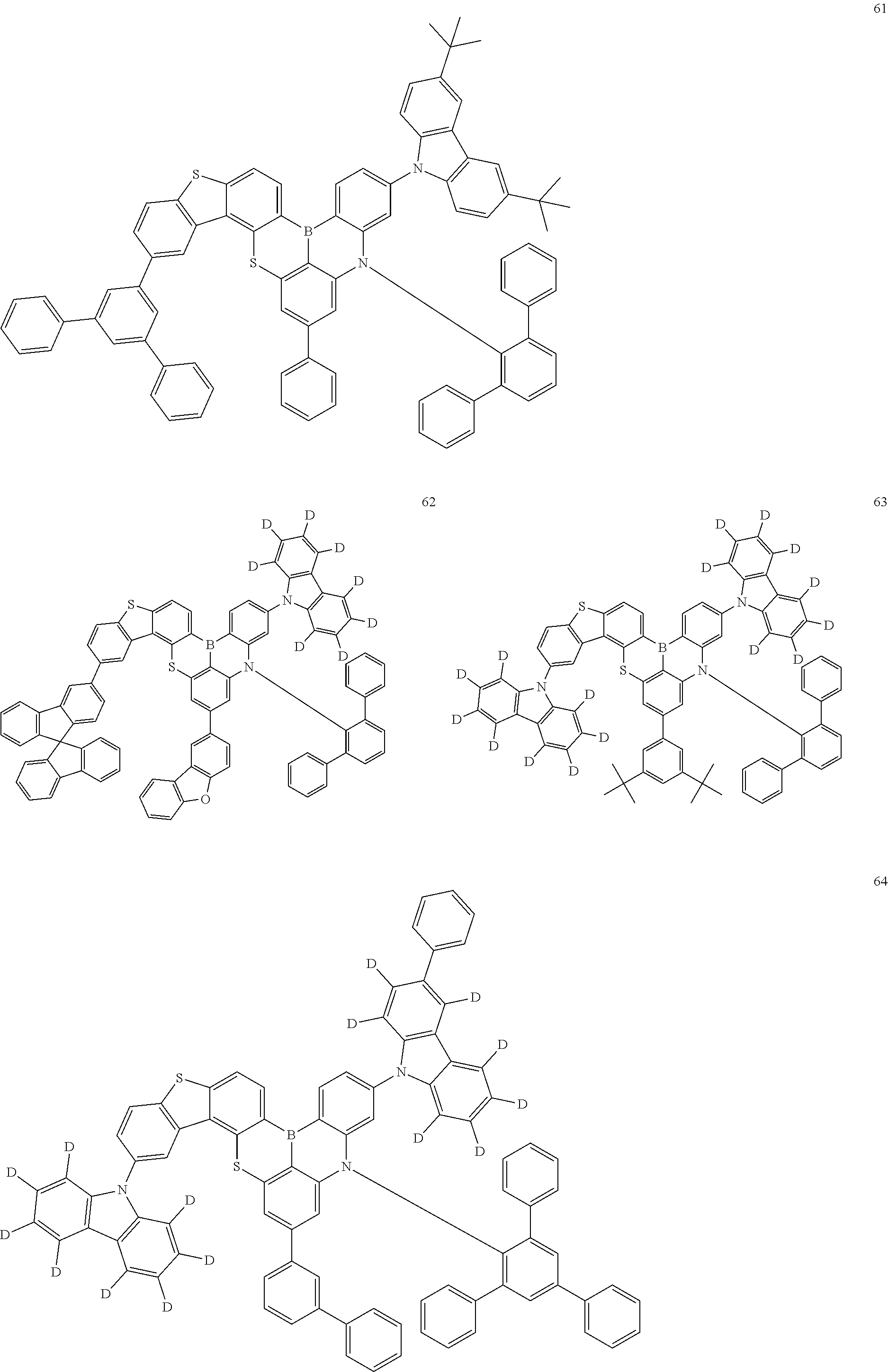

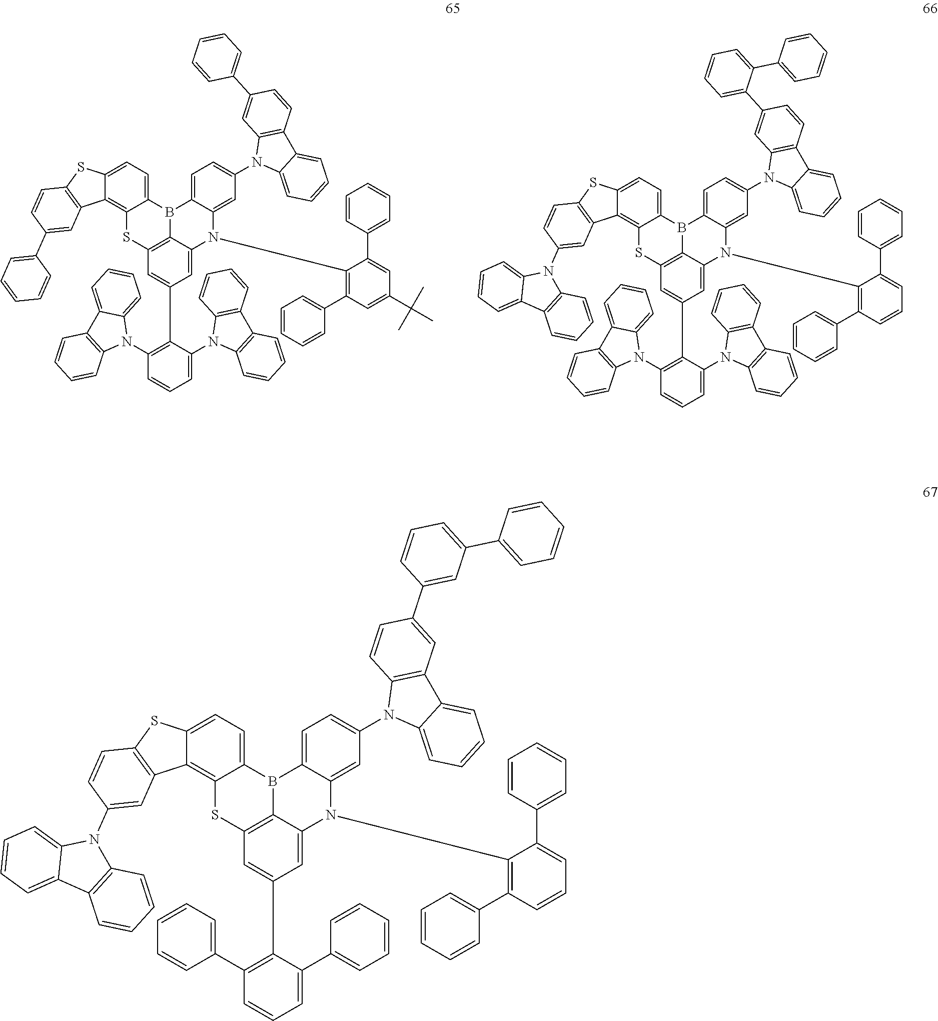

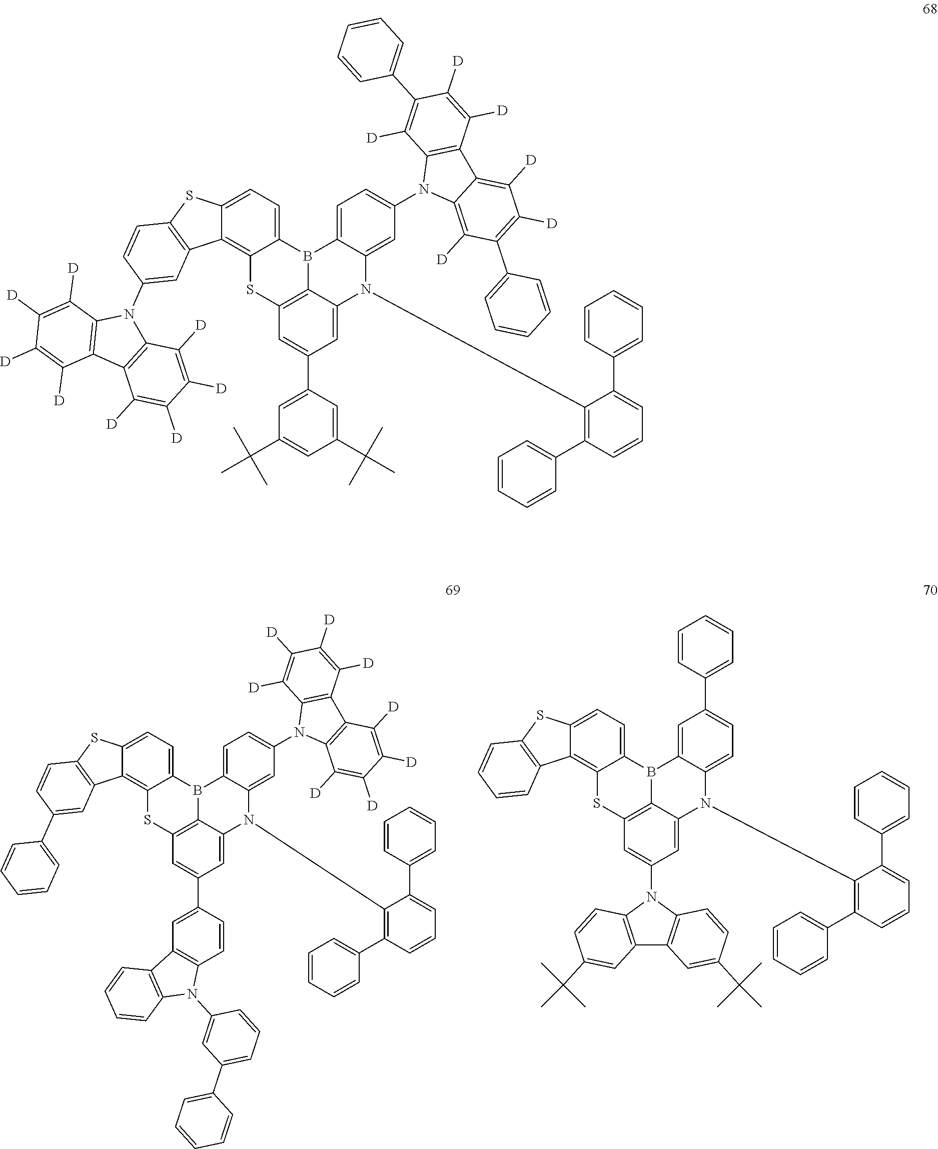

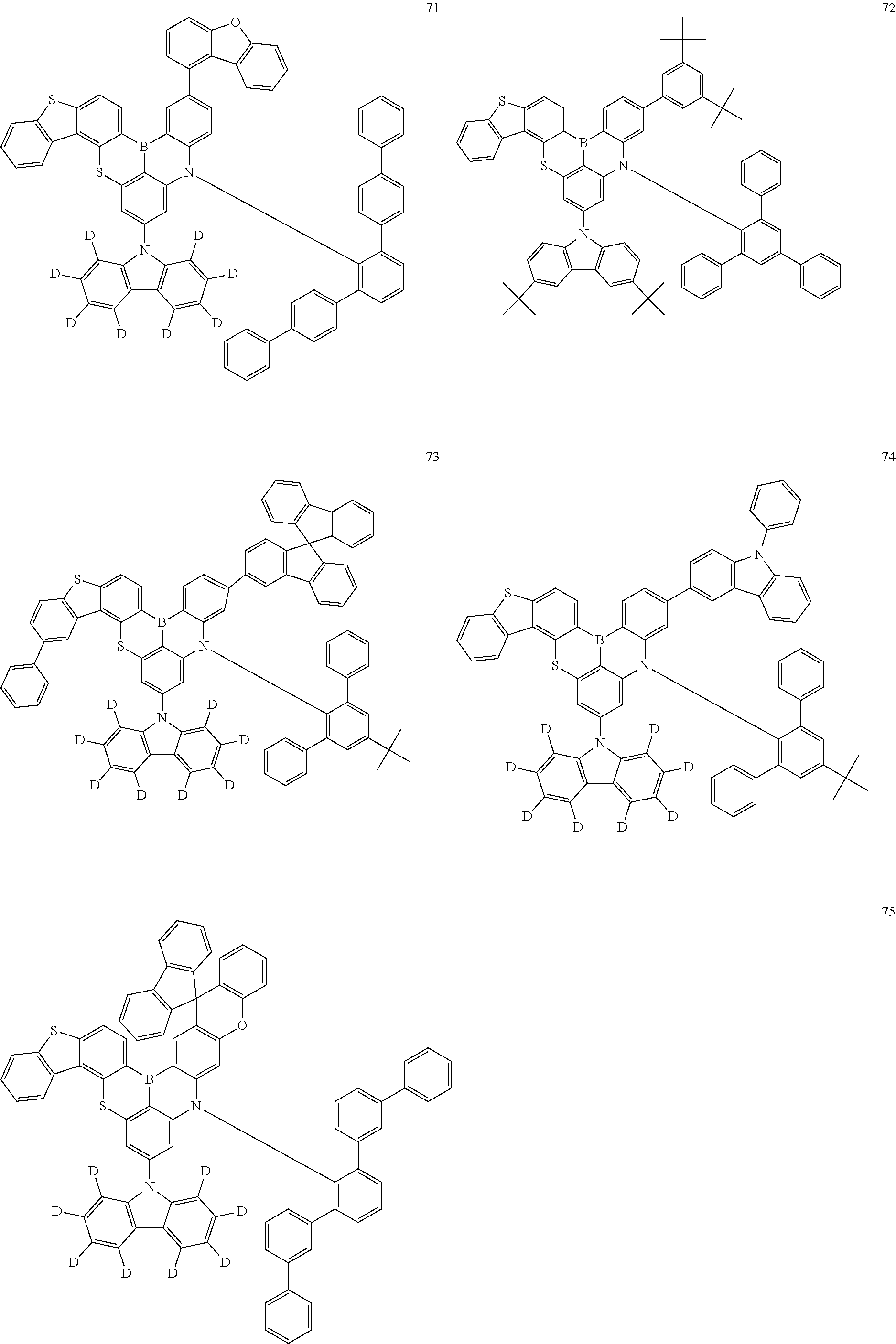

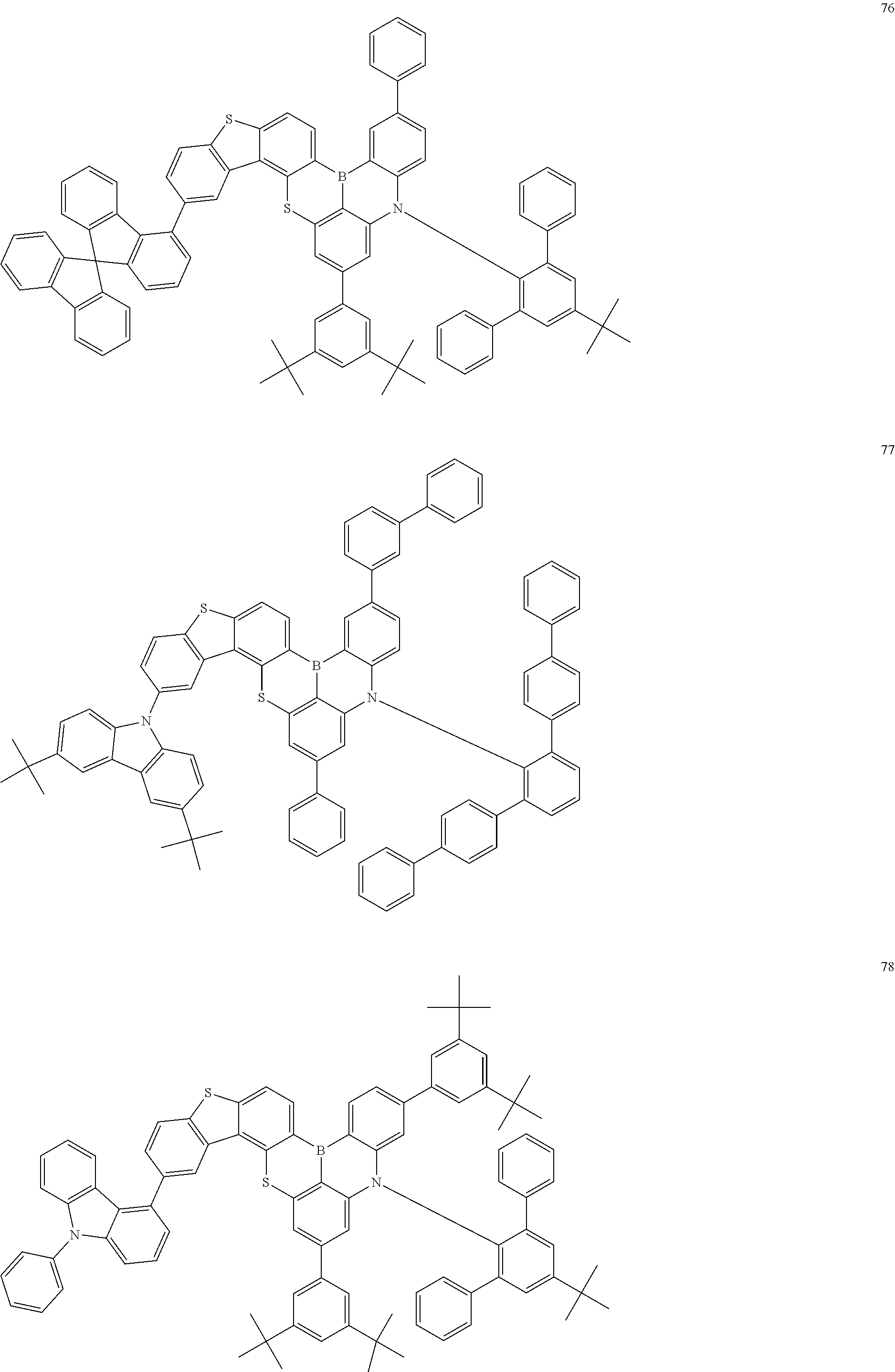

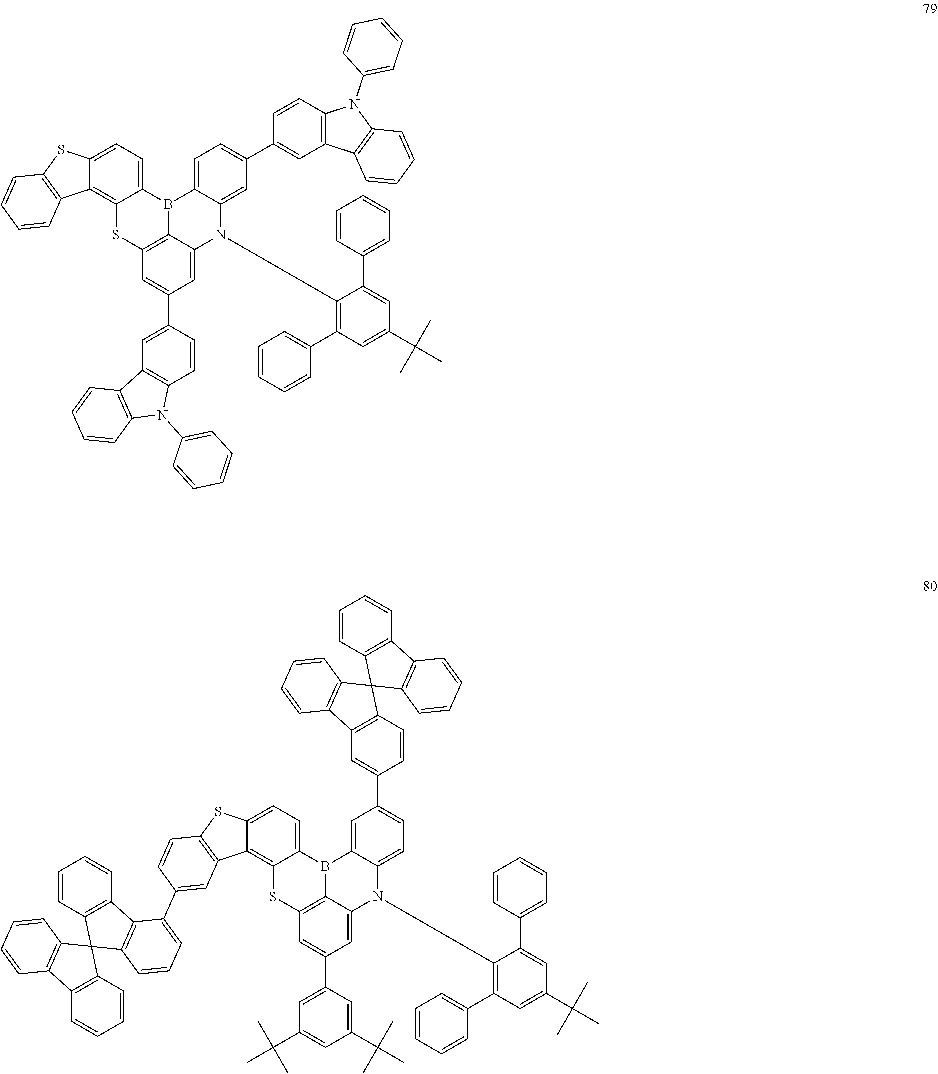 [SMILES: CC(C)(C)c1cc(-c2ccccc2)c(N2c3cc(-c4ccc5c(c4)c4ccccc4n5-c4ccccc4)ccc3B3c4ccc5sc6ccccc6c5c4Sc4cc(-c5ccc6c(c5)c5ccccc5n6-c5ccccc5)cc2c43)c(-c2ccccc2)c1 ; CC(C)(C)c1cc(-c2cc3c4c(c2)N(c2c(-c5ccccc5)cc(C(C)(C)C)cc2-c2ccccc2)c2ccc(-c5ccc6c(c5)-c5ccccc5C65c6ccccc6-c6ccccc65)cc2B4c2ccc4sc5ccc(-c6cccc7c6-c6ccccc6C76c7ccccc7-c7ccccc76)cc5c4c2S3)cc(C(C)(C)C)c1]

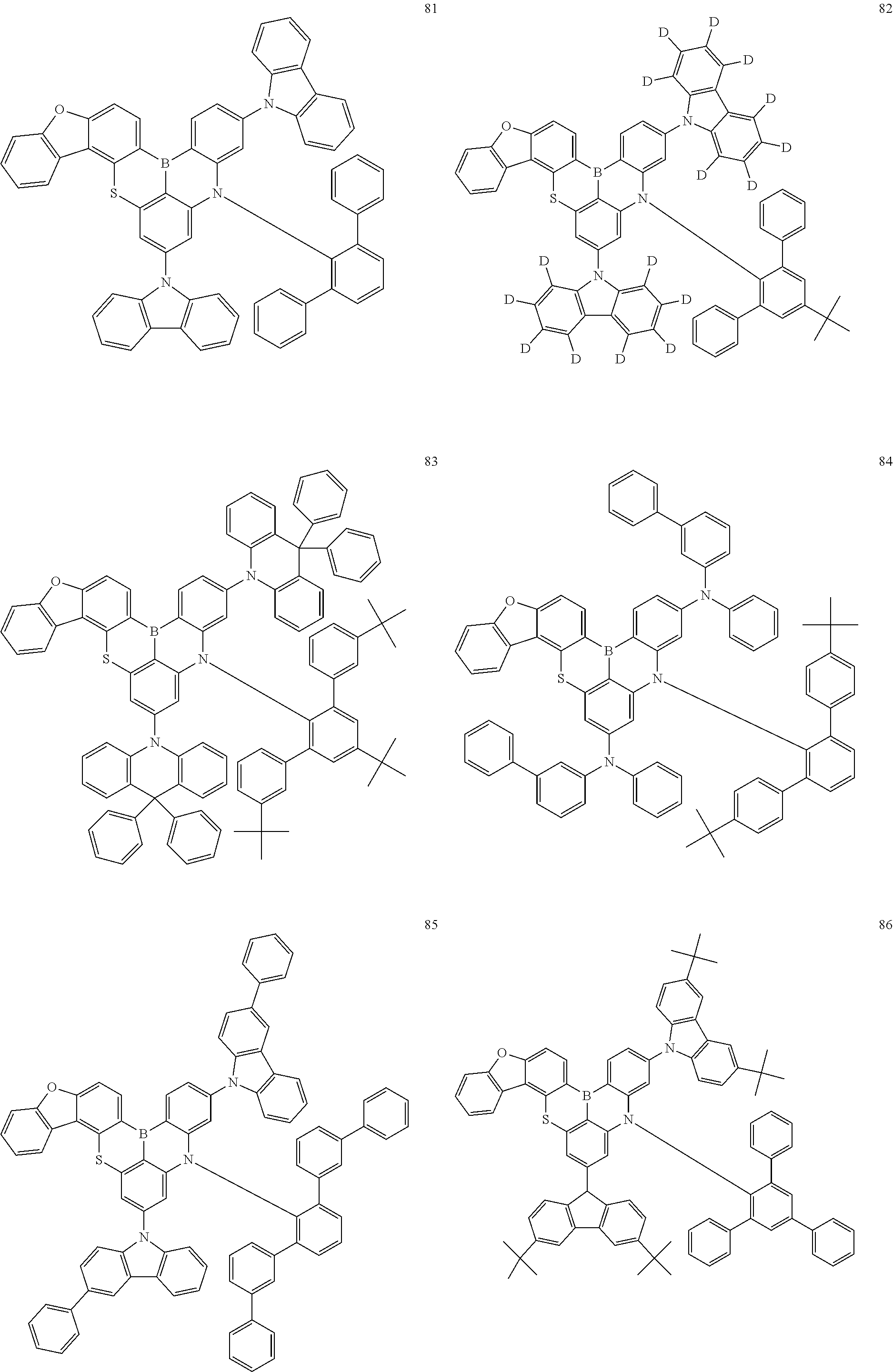

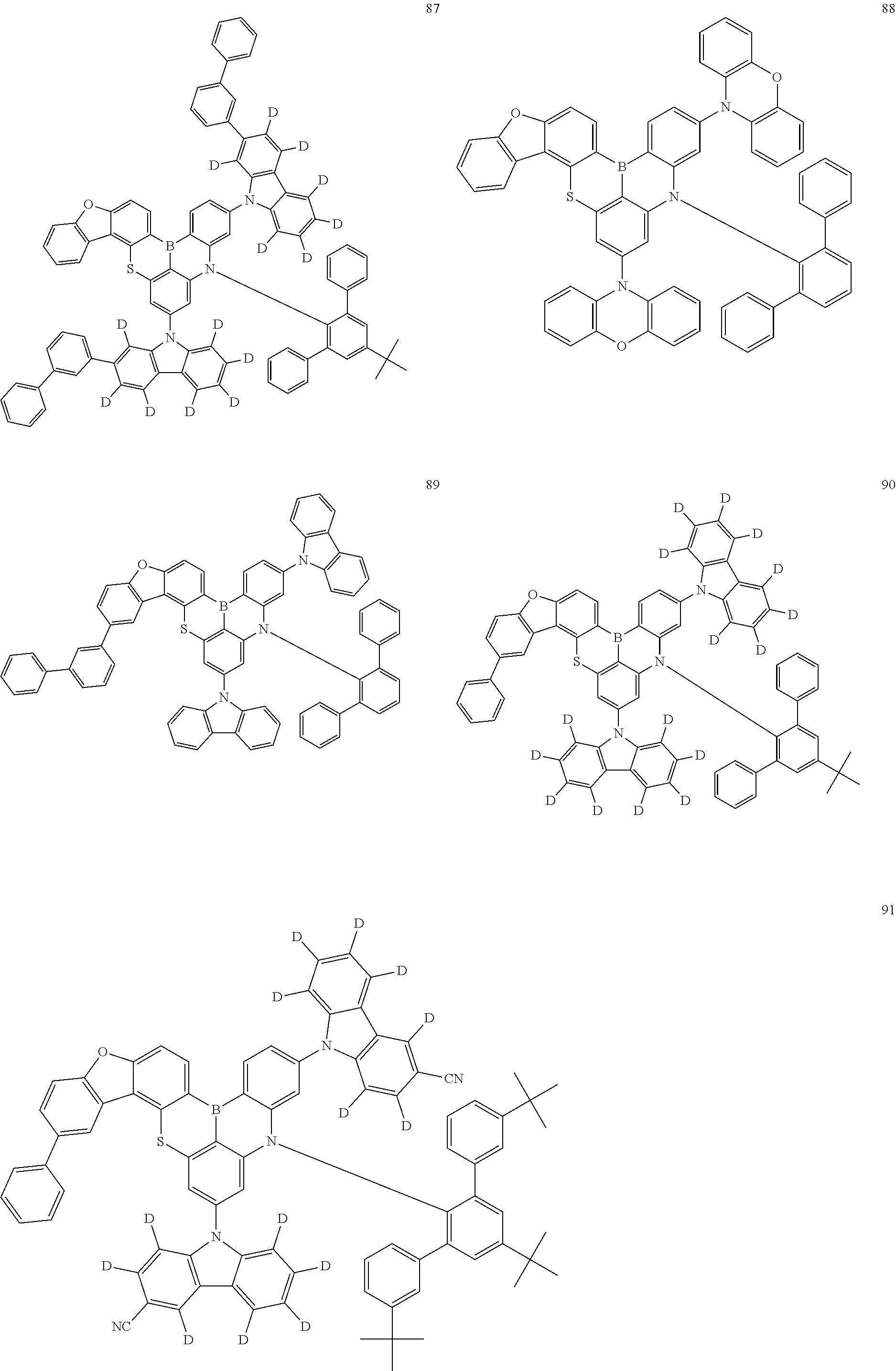

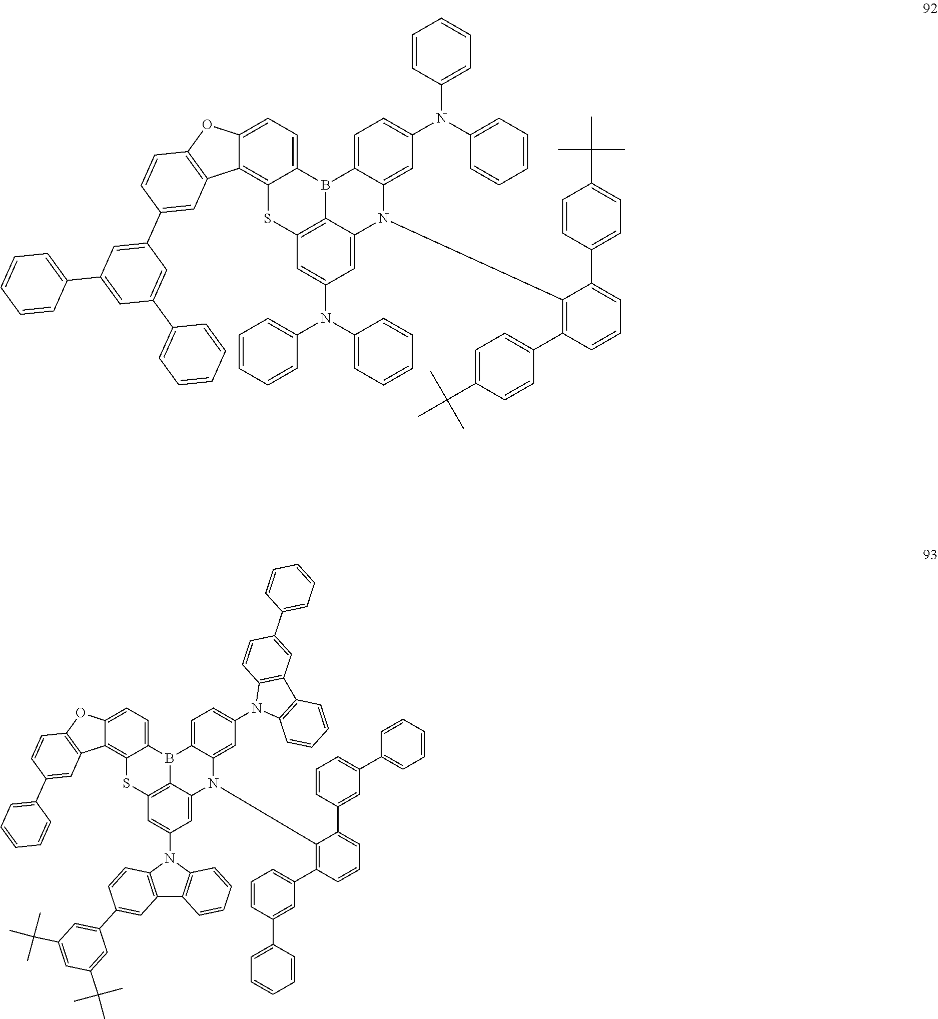 [SMILES: CC(C)(C)c1ccc(-c2cccc(-c3ccc(C(C)(C)C)cc3)c2N2c3cc(N(c4ccccc4)c4ccccc4)ccc3B3c4ccc5oc6ccc(-c7cc(-c8ccccc8)cc(-c8ccccc8)c7)cc6c5c4Sc4cc(N(c5ccccc5)c5ccccc5)cc2c43)cc1 ; CC(C)(C)c1cc(-c2ccc3c(c2)c2ccccc2n3-c2cc3c4c(c2)N(c2c(-c5cccc(-c6ccccc6)c5)cccc2-c2cccc(-c5ccccc5)c2)c2cc(-n5c6ccccc6c6cc(-c7ccccc7)ccc65)ccc2B4c2ccc4oc5ccc(-c6ccccc6)cc5c4c2S3)cc(C(C)(C)C)c1]

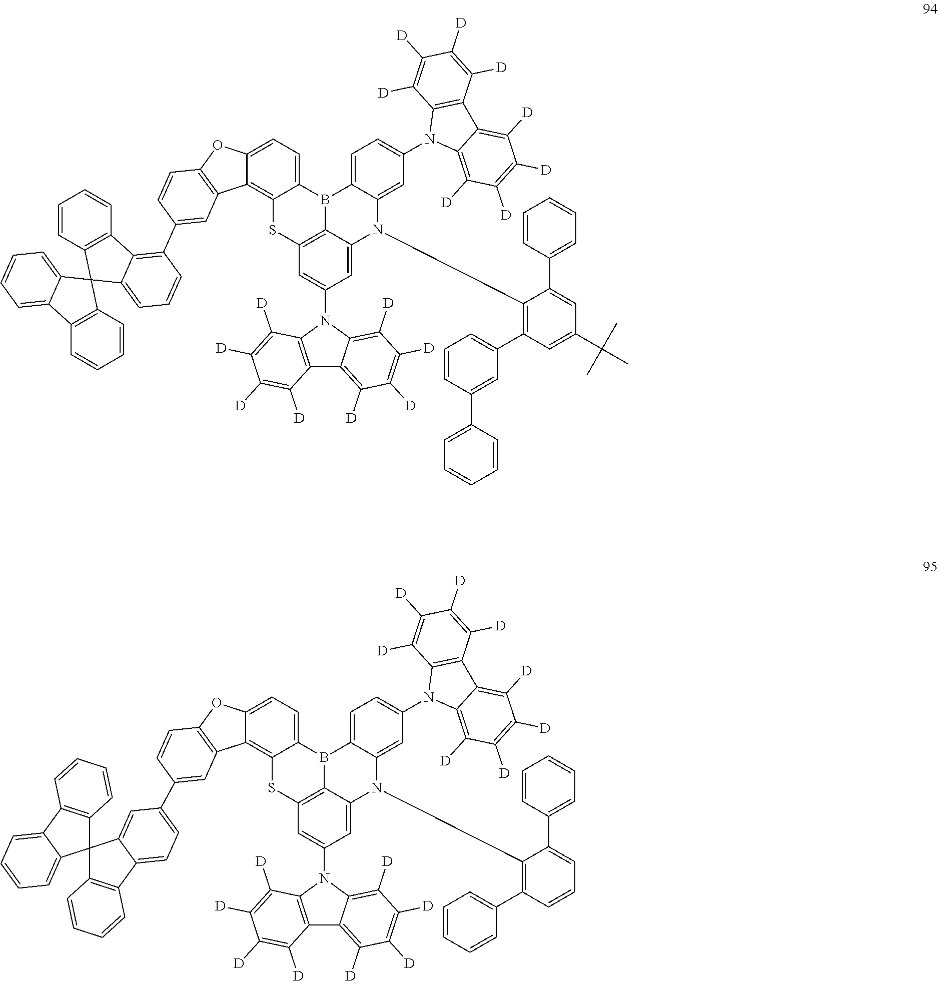

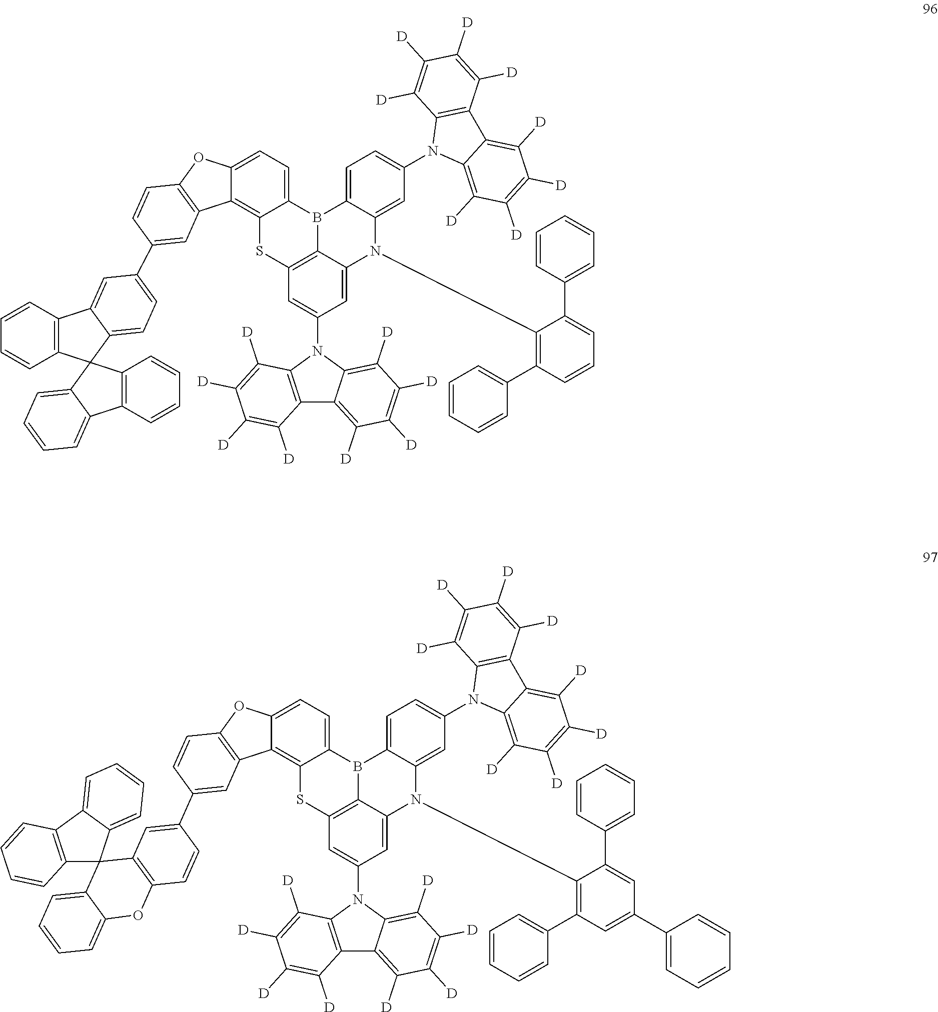

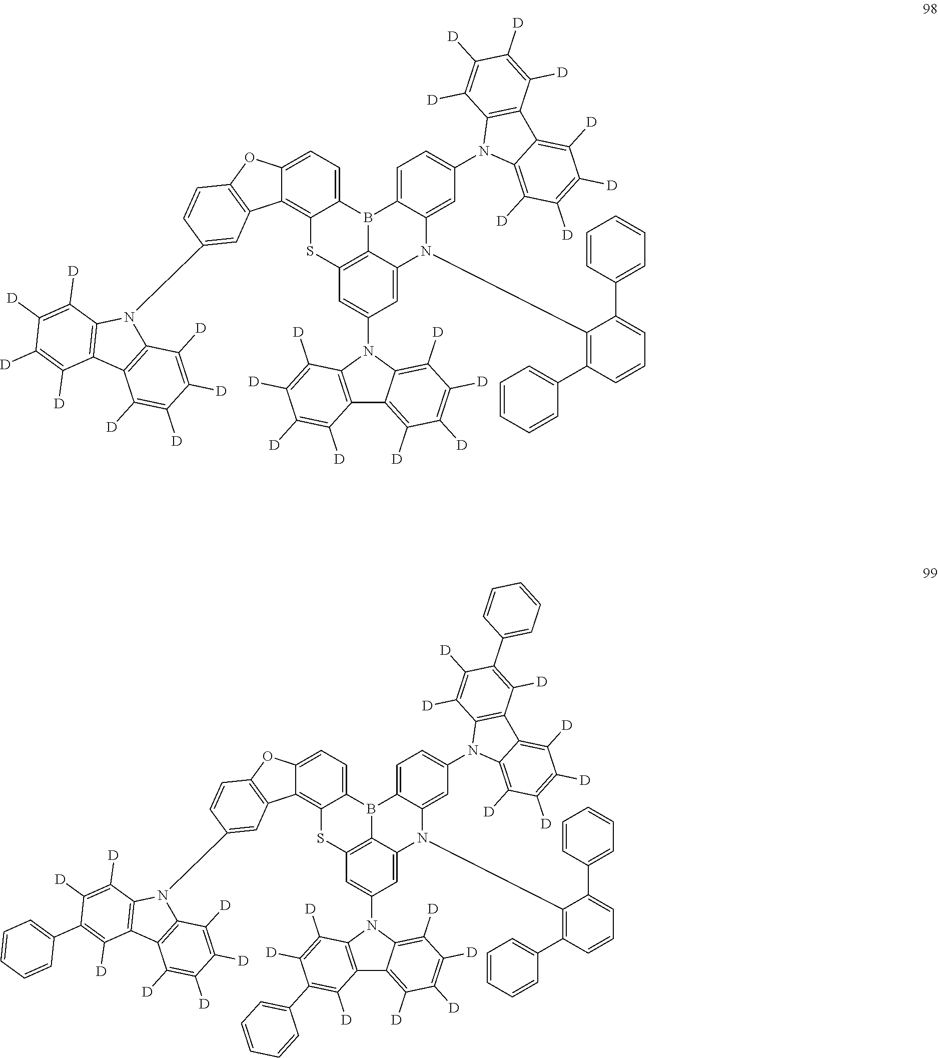

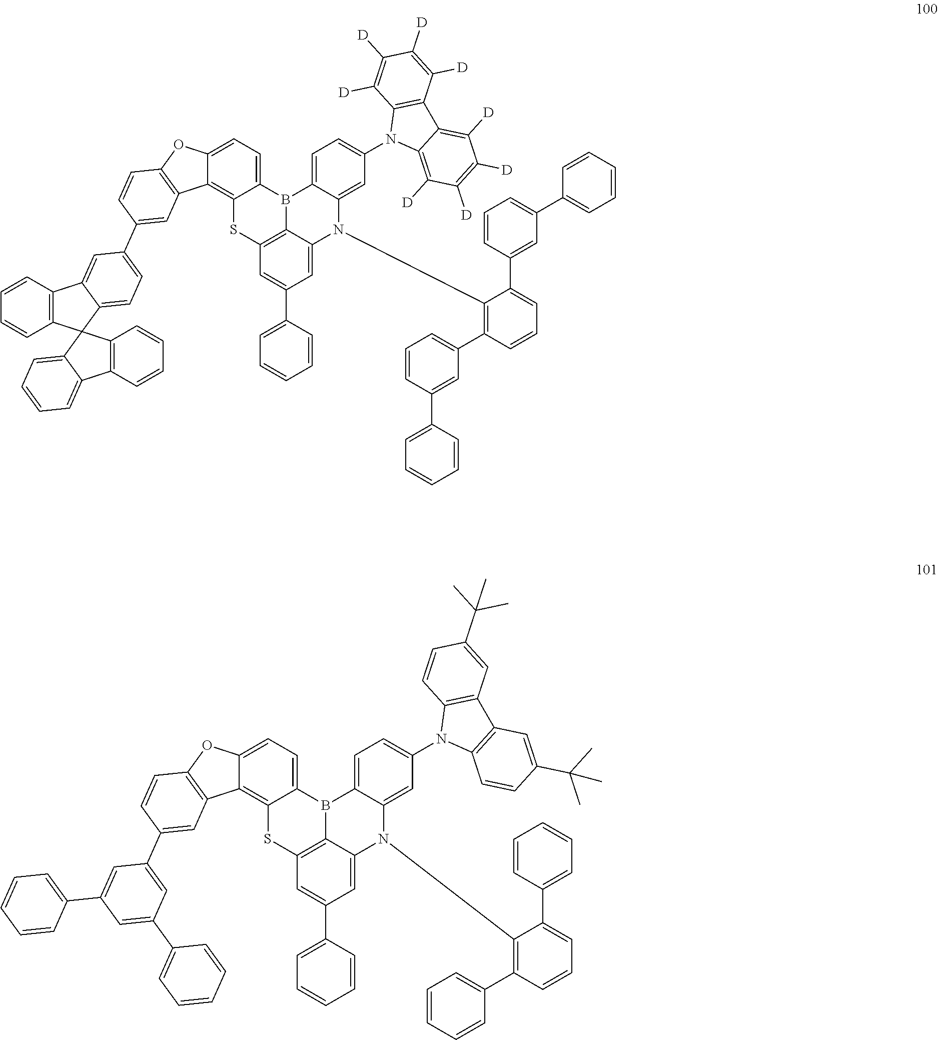 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2oc4ccc(-c5ccc6c(c5)-c5ccccc5C65c6ccccc6-c6ccccc65)cc4c2c1S3 ; CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc2oc4ccc(-c5cc(-c6ccccc6)cc(-c6ccccc6)c5)cc4c2c1S3]

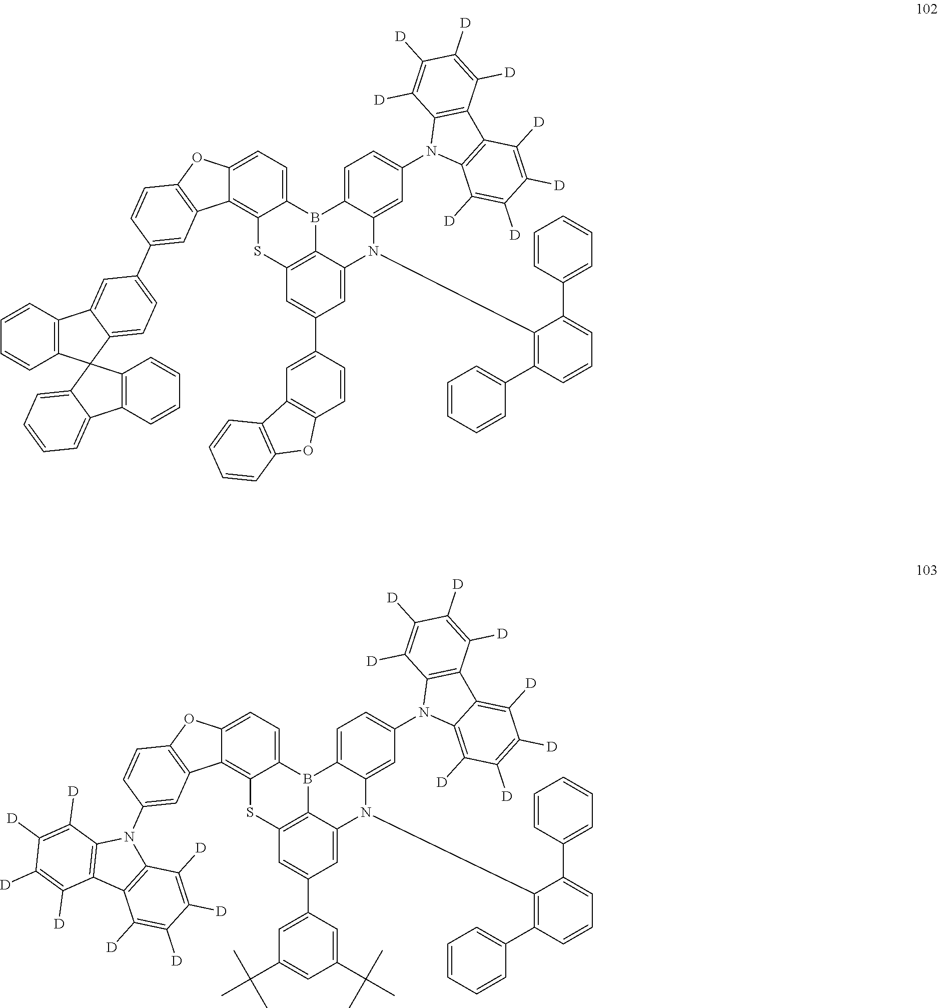 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc2oc4ccc(-c5ccc6c(c5)-c5ccccc5C65c6ccccc6-c6ccccc65)cc4c2c1S3 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(C(C)(C)C)cc(C(C)(C)C)c3)cc3c1B2c1ccc2oc4ccc(-n5c6c([2H])c([2H])c([2H])c([2H])c6c6c([2H])c([2H])c([2H])c([2H])c65)cc4c2c1S3]

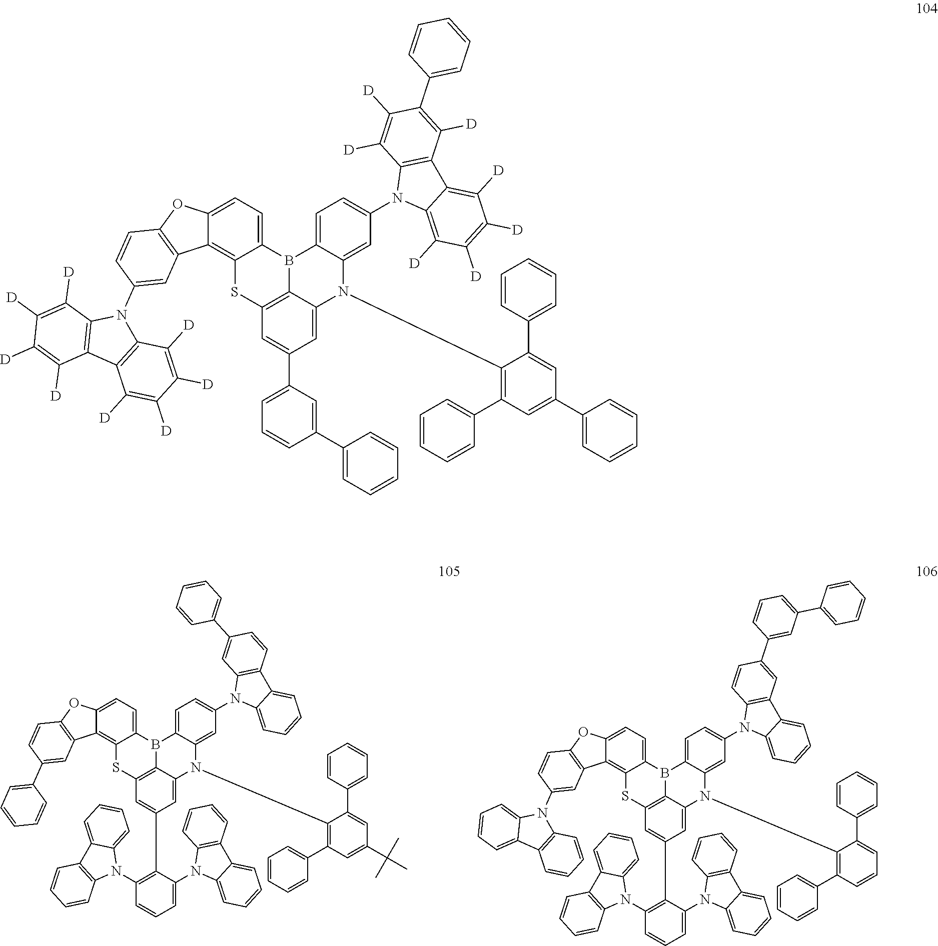

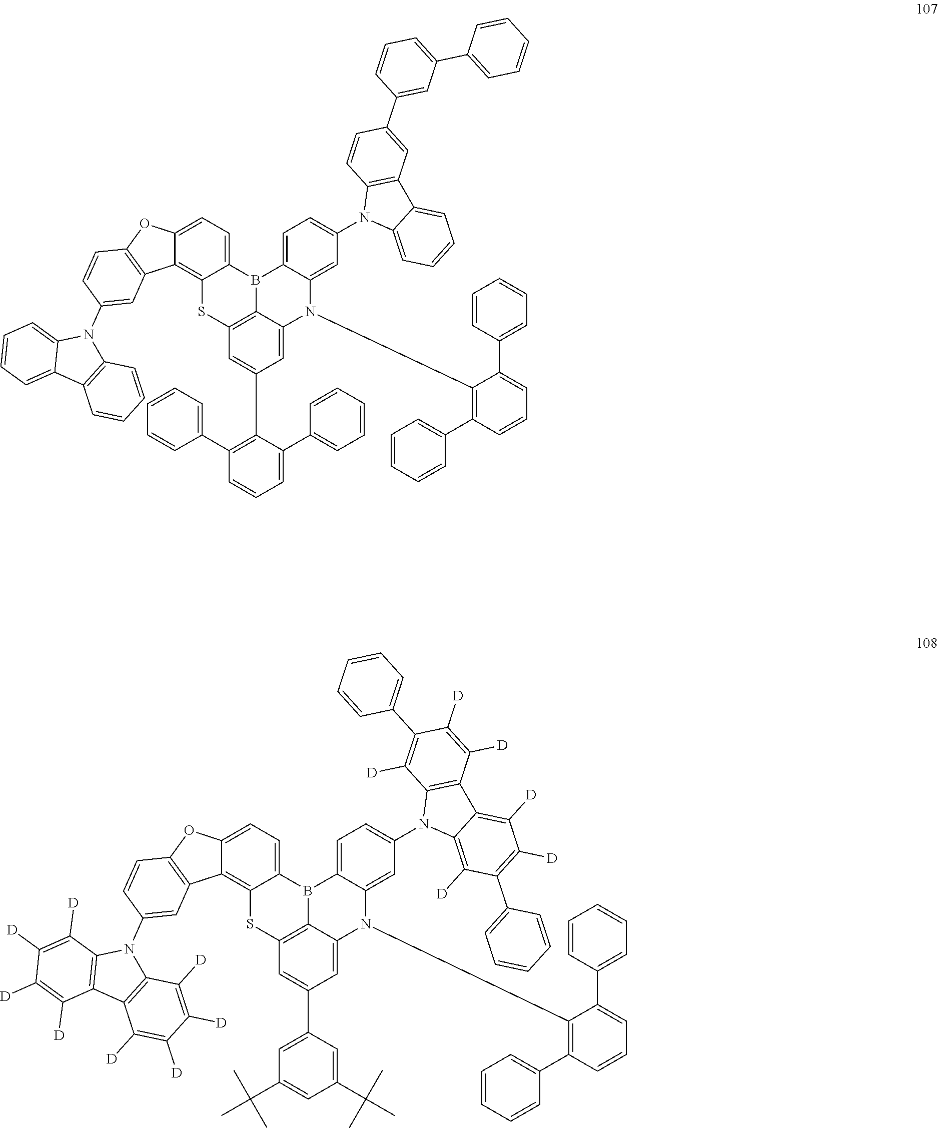 [SMILES: c1ccc(-c2cccc(-c3ccc4c(c3)c3ccccc3n4-c3ccc4c(c3)N(c3c(-c5ccccc5)cccc3-c3ccccc3)c3cc(-c5c(-c6ccccc6)cccc5-c5ccccc5)cc5c3B4c3ccc4oc6ccc(-n7c8ccccc8c8ccccc87)cc6c4c3S5)c2)cc1 ; [2H]c1c([2H])c([2H])c2c(c1[2H])c1c([2H])c([2H])c([2H])c([2H])c1n2-c1ccc2oc3ccc4c(c3c2c1)Sc1cc(-c2cc(C(C)(C)C)cc(C(C)(C)C)c2)cc2c1B4c1ccc(-n3c4c([2H])c(-c5ccccc5)c([2H])c([2H])c4c4c([2H])c([2H])c(-c5ccccc5)c([2H])c43)cc1N2c1c(-c2ccccc2)cccc1-c1ccccc1]

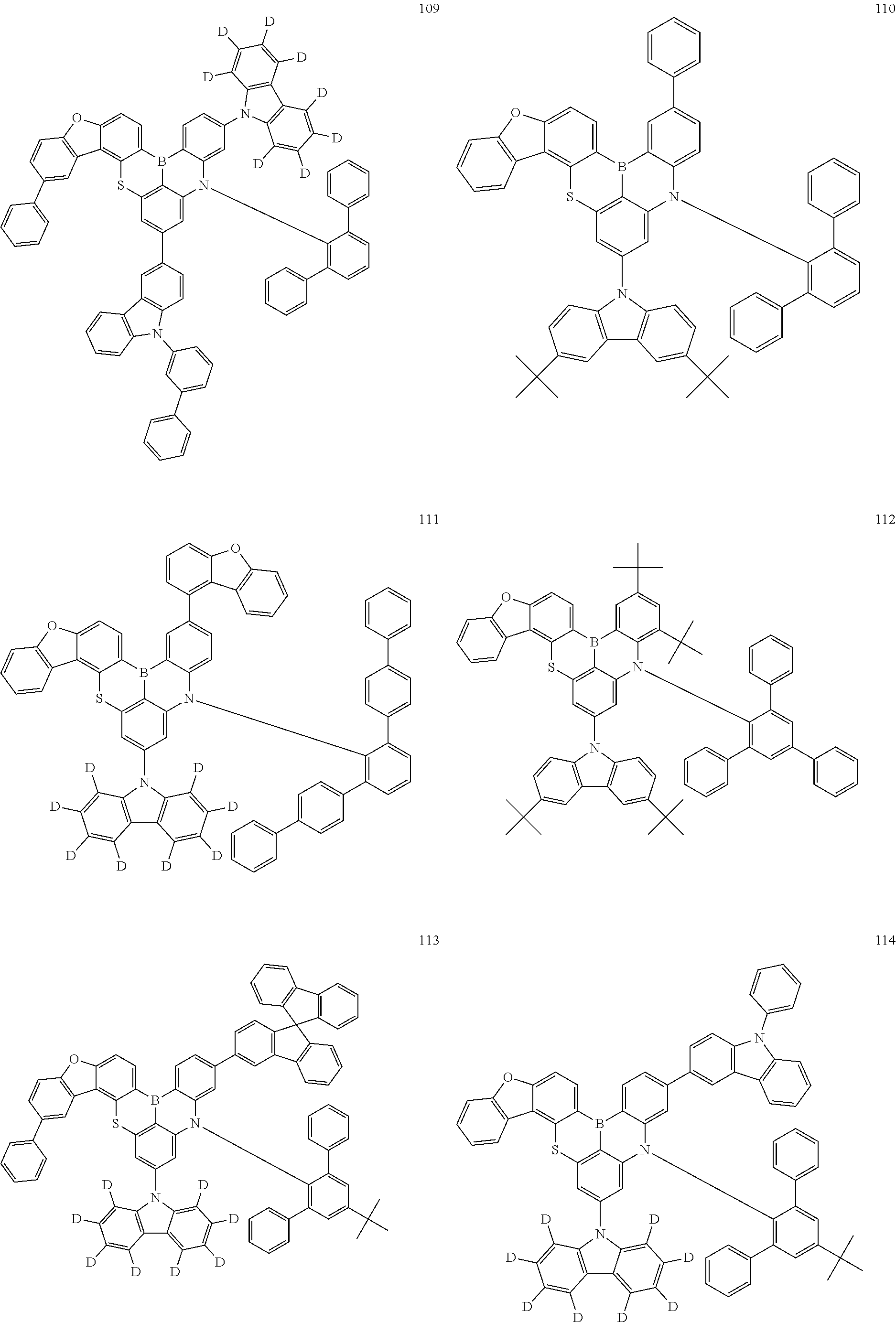

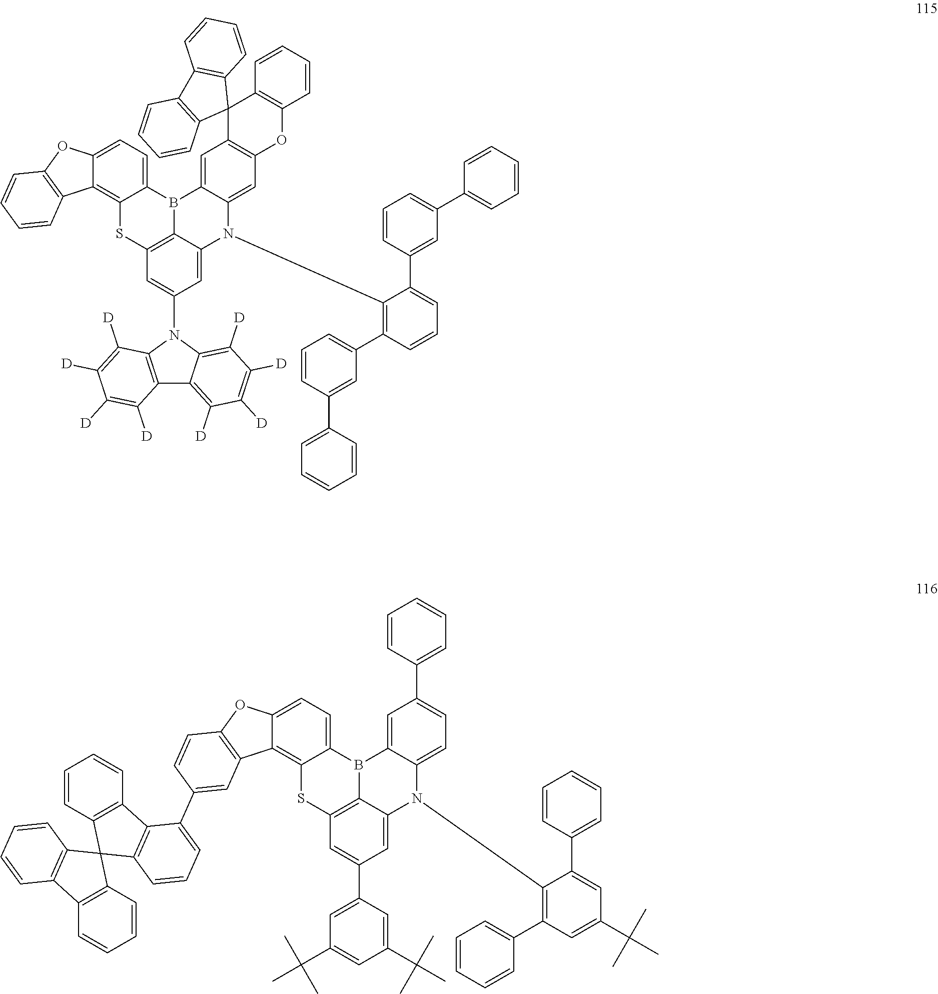 [SMILES: [2H]c1c([2H])c([2H])c2c(c1[2H])c1c([2H])c([2H])c([2H])c([2H])c1n2-c1cc2c3c(c1)N(c1c(-c4cccc(-c5ccccc5)c4)cccc1-c1cccc(-c4ccccc4)c1)c1cc4c(cc1B3c1ccc3oc5ccccc5c3c1S2)C1(c2ccccc2O4)c2ccccc2-c2ccccc21 ; CC(C)(C)c1cc(-c2cc3c4c(c2)N(c2c(-c5ccccc5)cc(C(C)(C)C)cc2-c2ccccc2)c2ccc(-c5ccccc5)cc2B4c2ccc4oc5ccc(-c6cccc7c6-c6ccccc6C76c7ccccc7-c7ccccc76)cc5c4c2S3)cc(C(C)(C)C)c1]

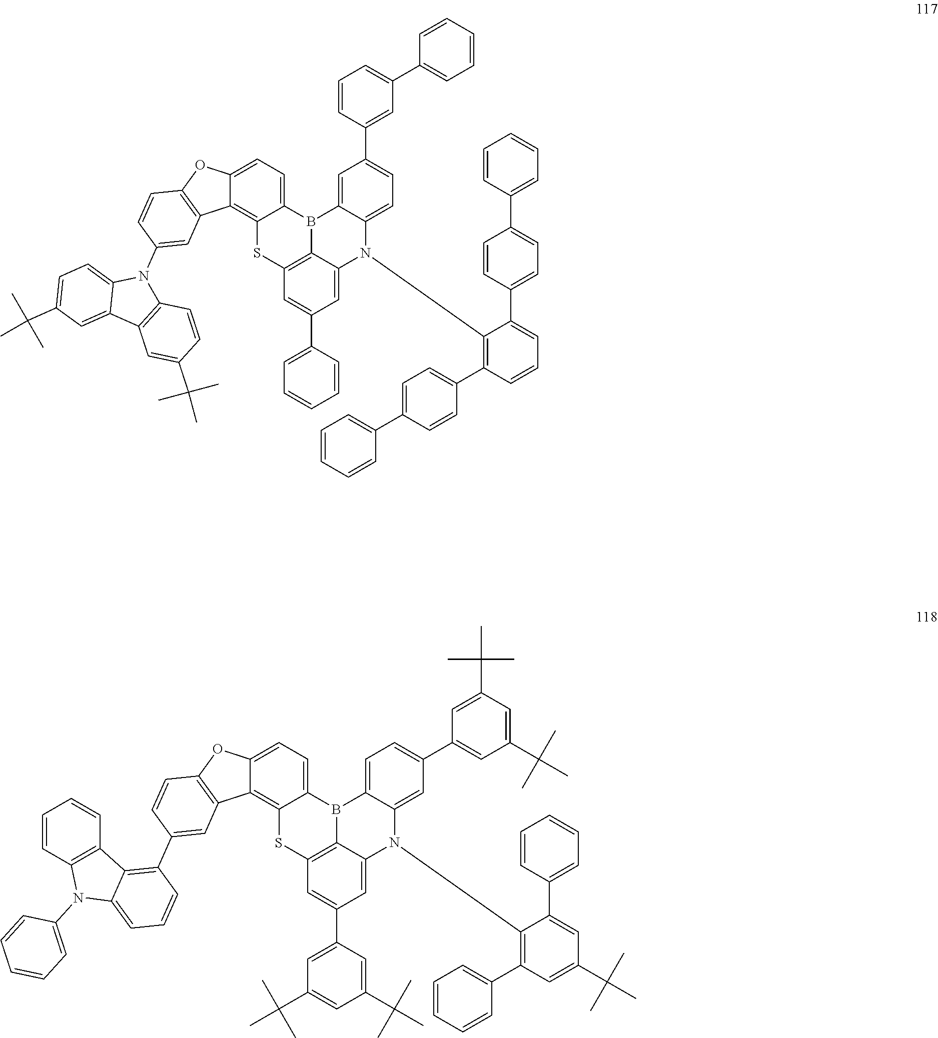 [SMILES: CC(C)(C)c1ccc2c(c1)c1cc(C(C)(C)C)ccc1n2-c1ccc2oc3ccc4c(c3c2c1)Sc1cc(-c2ccccc2)cc2c1B4c1cc(-c3cccc(-c4ccccc4)c3)ccc1N2c1c(-c2ccc(-c3ccccc3)cc2)cccc1-c1ccc(-c2ccccc2)cc1 ; CC(C)(C)c1cc(-c2ccc3c(c2)N(c2c(-c4ccccc4)cc(C(C)(C)C)cc2-c2ccccc2)c2cc(-c4cc(C(C)(C)C)cc(C(C)(C)C)c4)cc4c2B3c2ccc3oc5ccc(-c6cccc7c6c6ccccc6n7-c6ccccc6)cc5c3c2S4)cc(C(C)(C)C)c1]

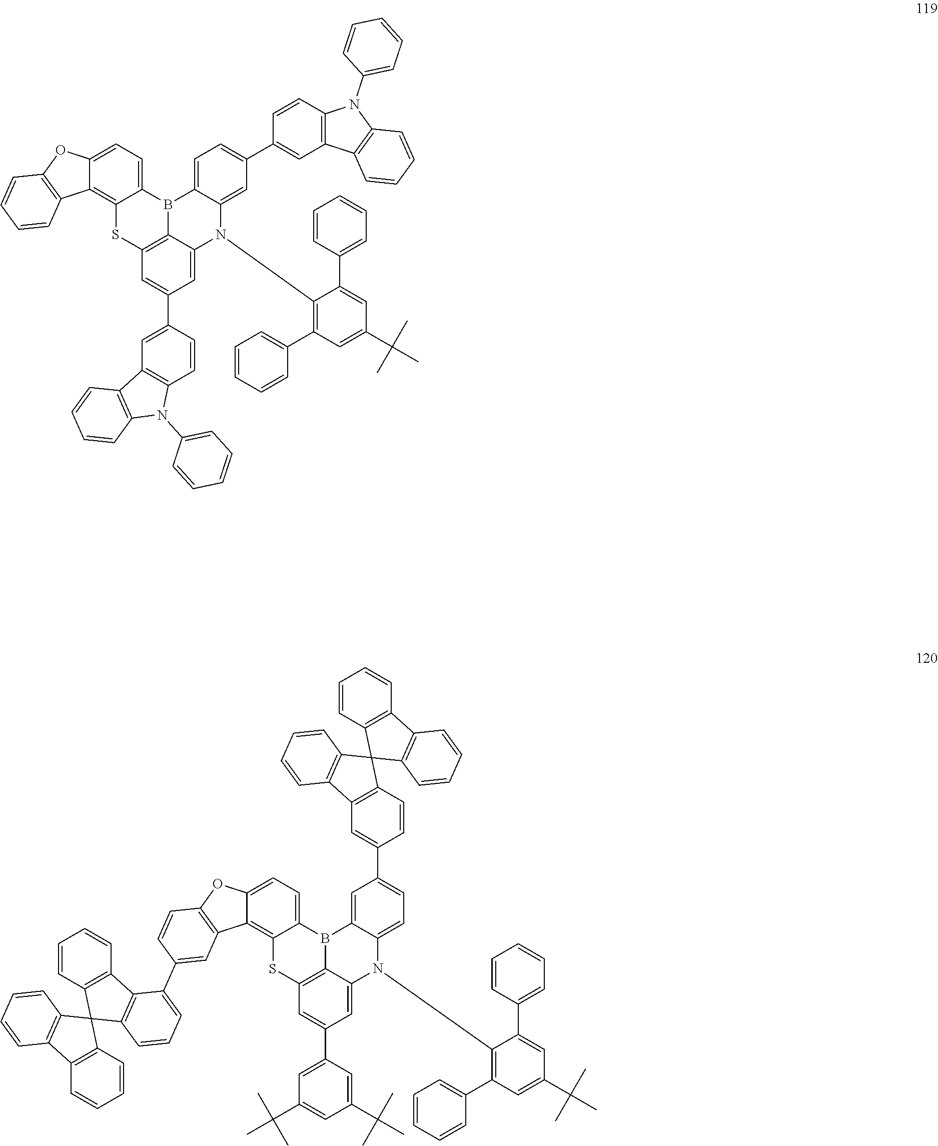 [SMILES: CC(C)(C)c1cc(-c2ccccc2)c(N2c3cc(-c4ccc5c(c4)c4ccccc4n5-c4ccccc4)ccc3B3c4ccc5oc6ccccc6c5c4Sc4cc(-c5ccc6c(c5)c5ccccc5n6-c5ccccc5)cc2c43)c(-c2ccccc2)c1 ; CC(C)(C)c1cc(-c2cc3c4c(c2)N(c2c(-c5ccccc5)cc(C(C)(C)C)cc2-c2ccccc2)c2ccc(-c5ccc6c(c5)-c5ccccc5C65c6ccccc6-c6ccccc65)cc2B4c2ccc4oc5ccc(-c6cccc7c6-c6ccccc6C76c7ccccc7-c7ccccc76)cc5c4c2S3)cc(C(C)(C)C)c1]

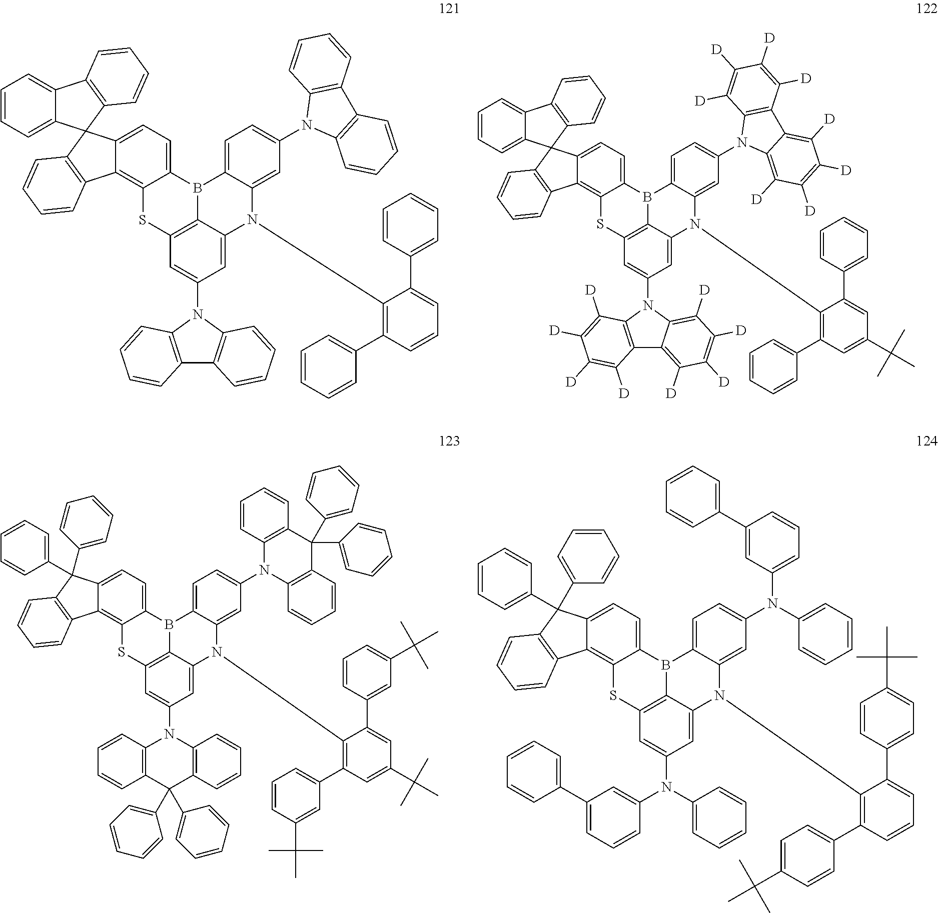

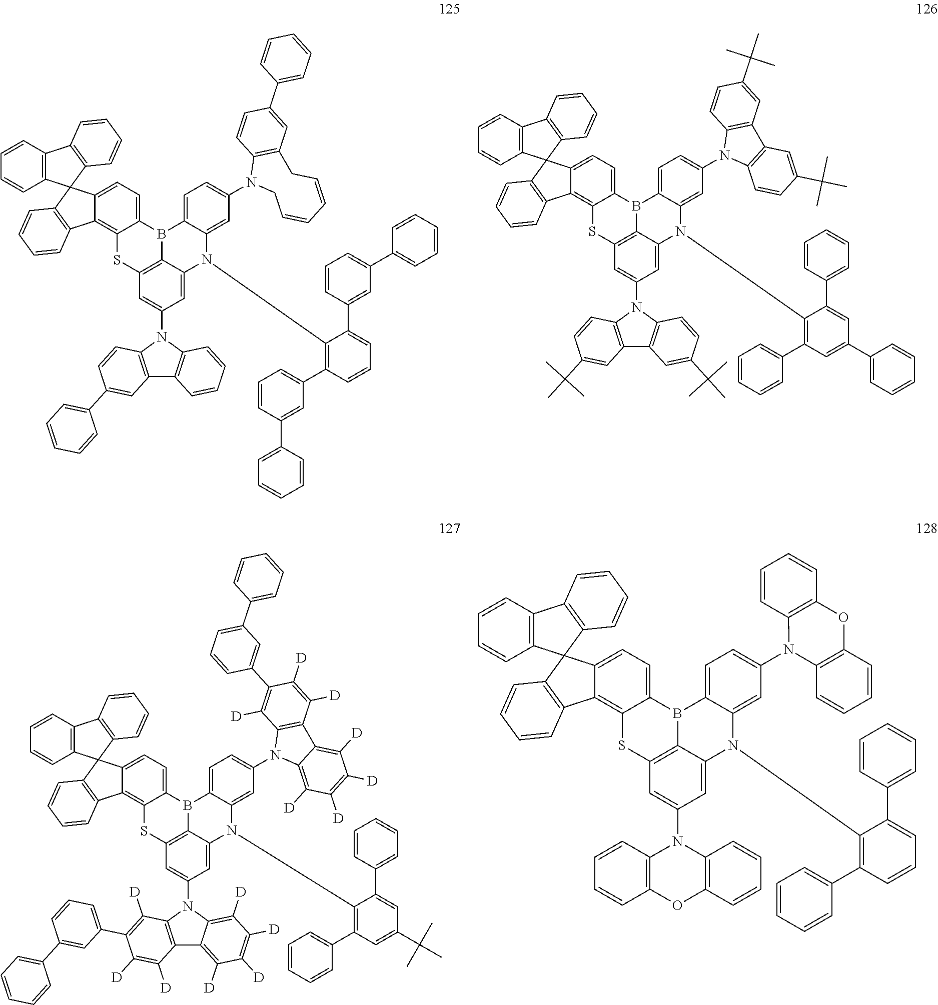

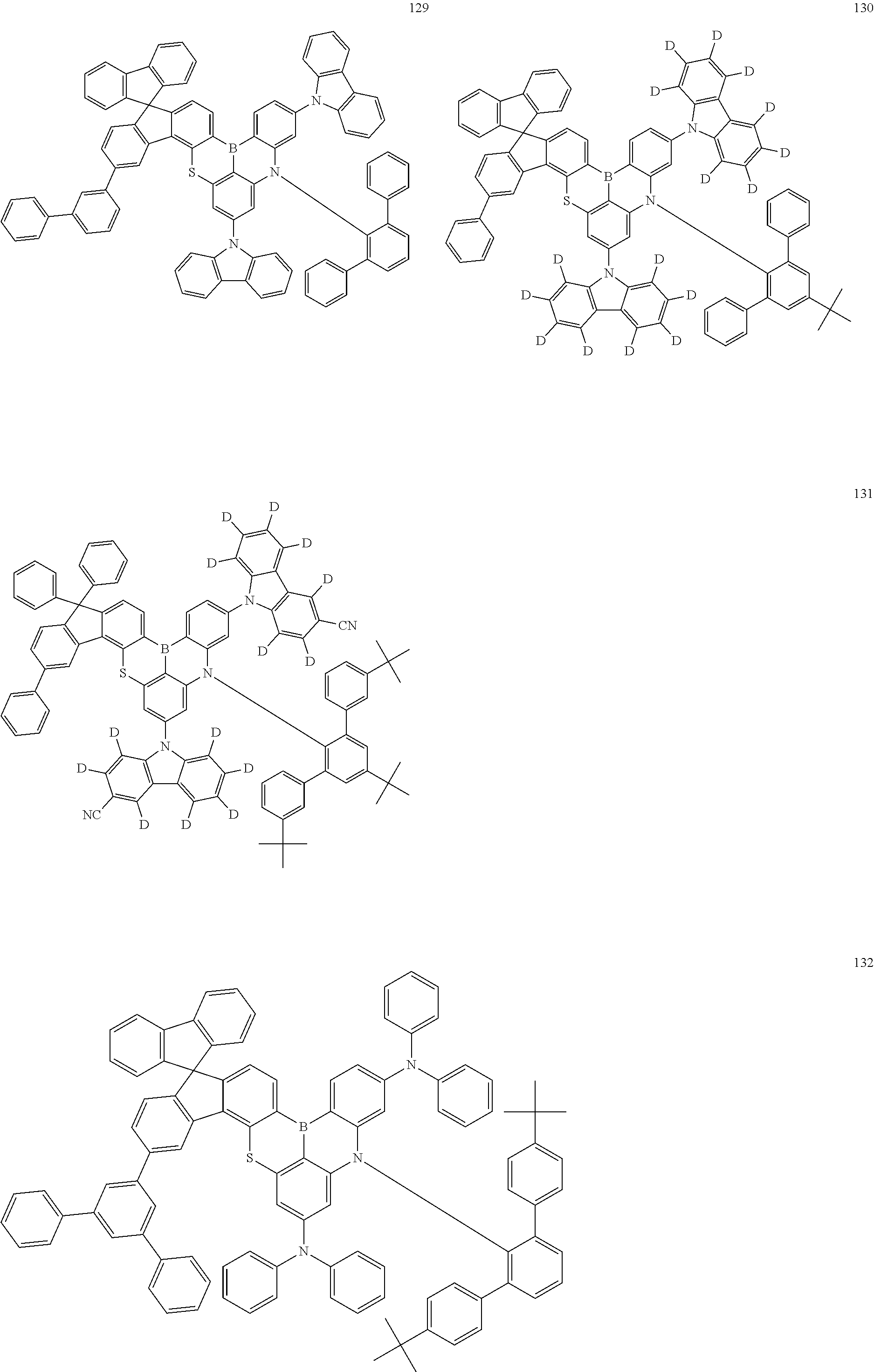

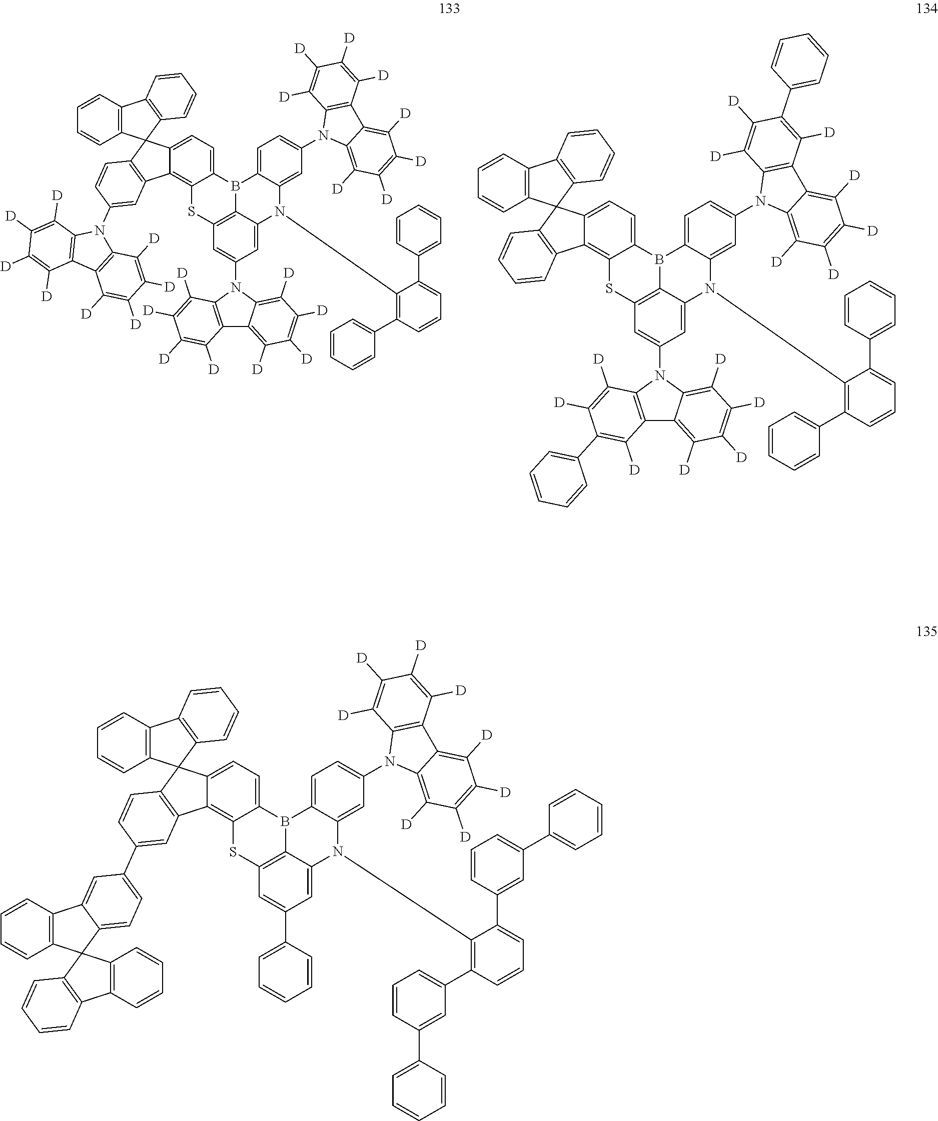

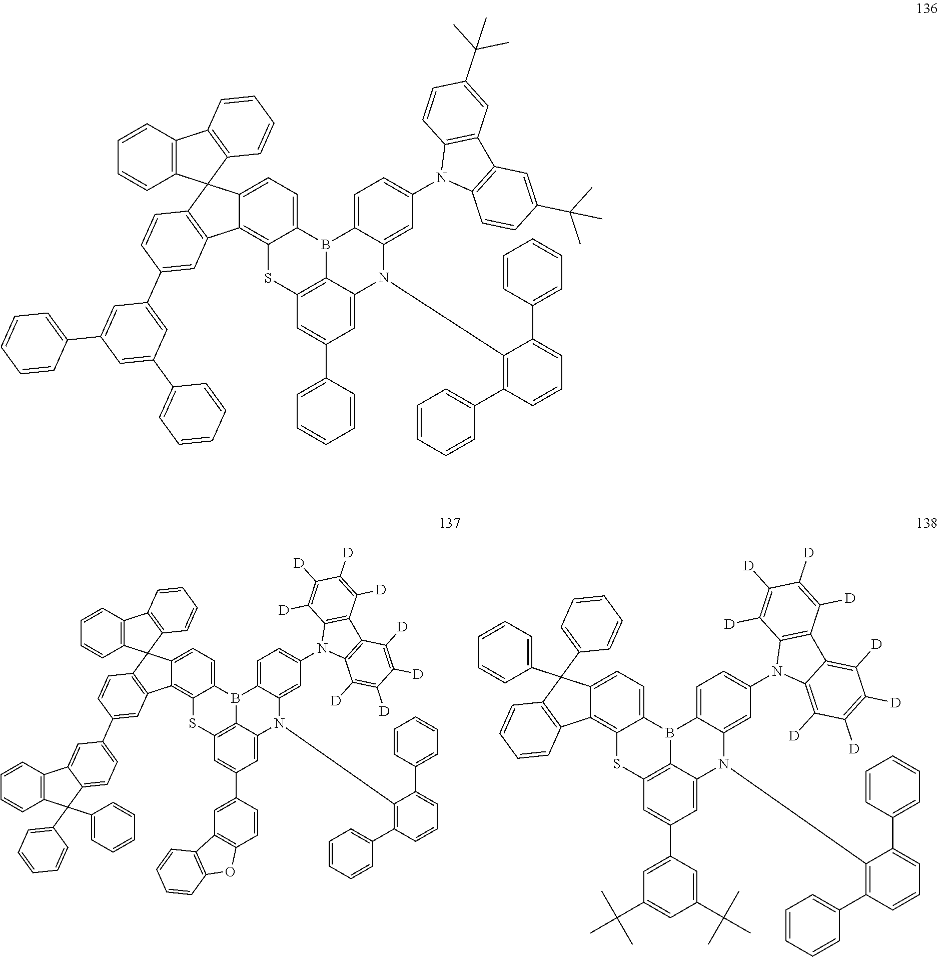

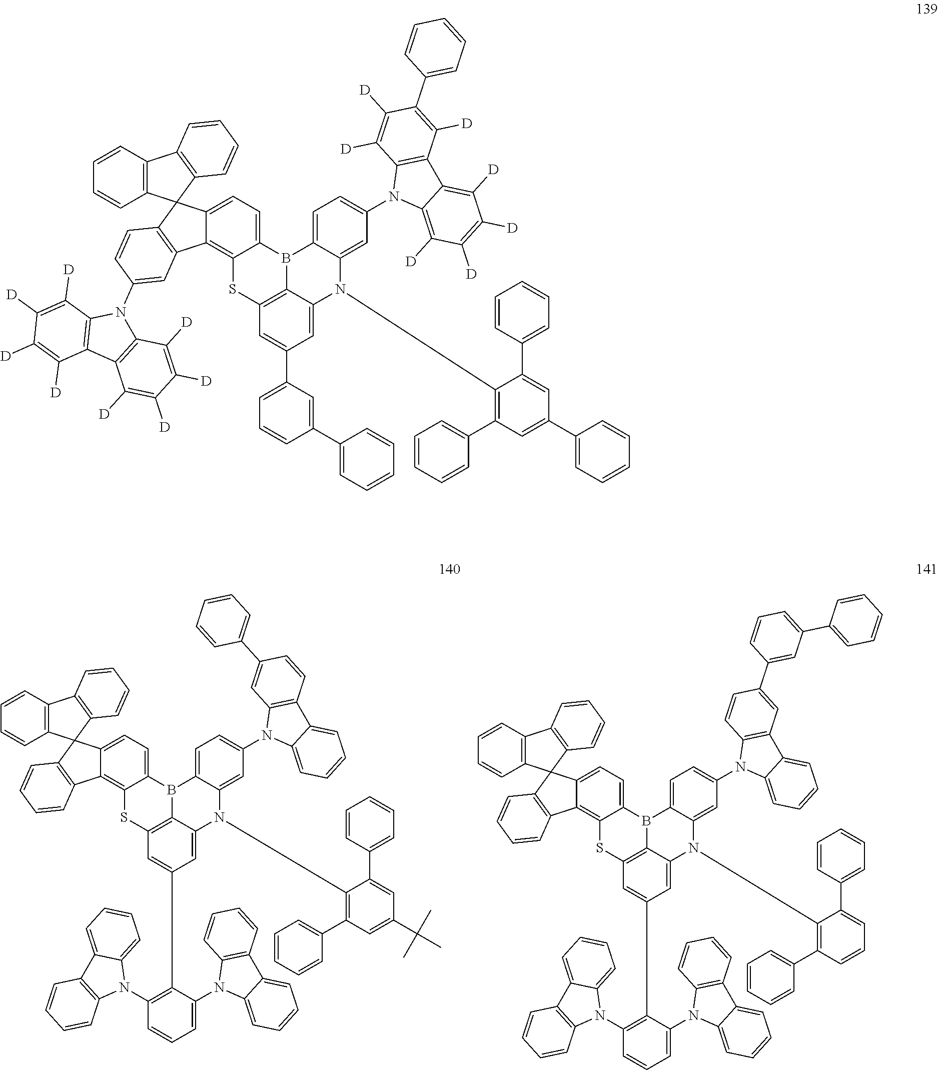

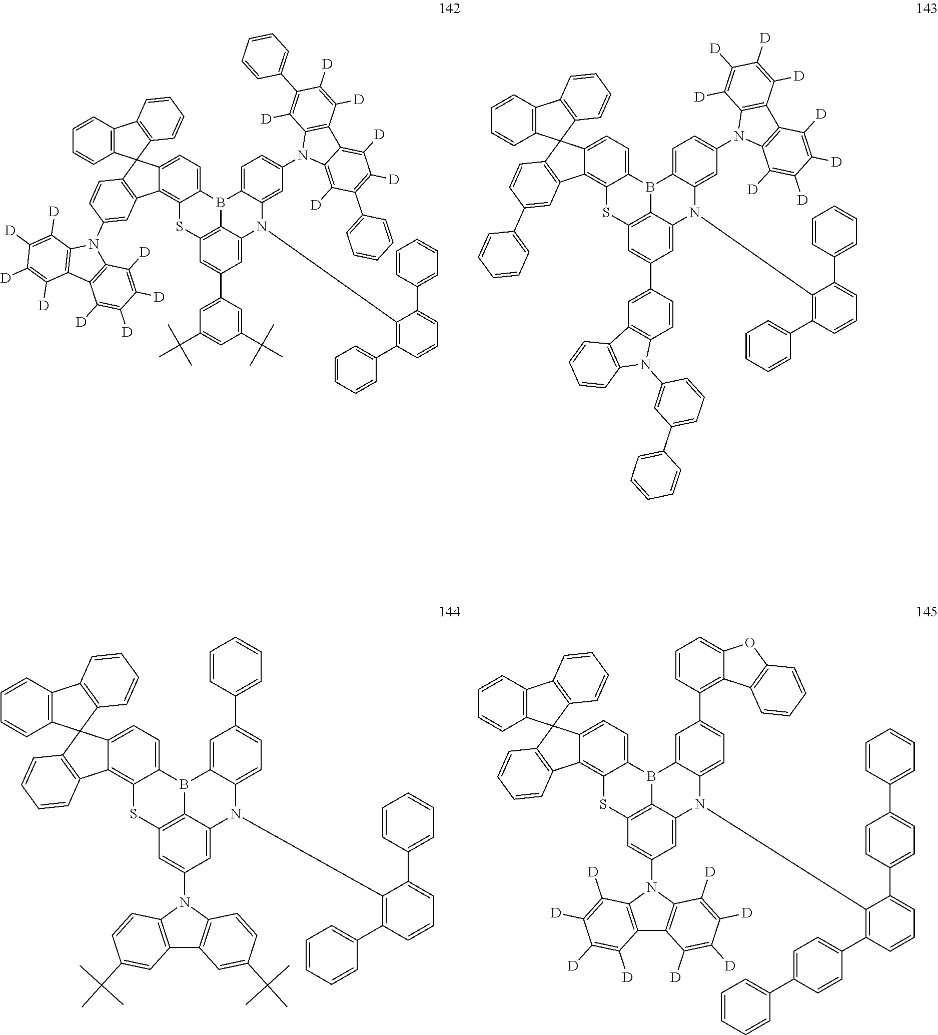

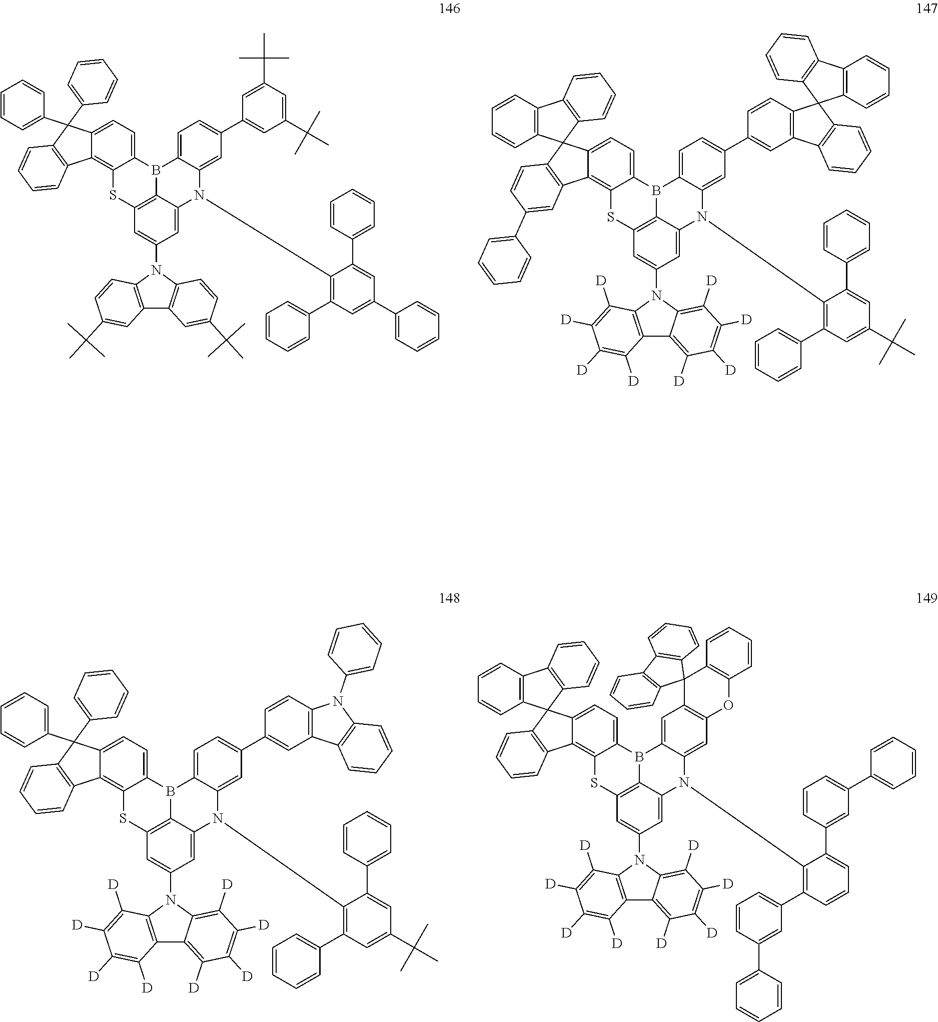

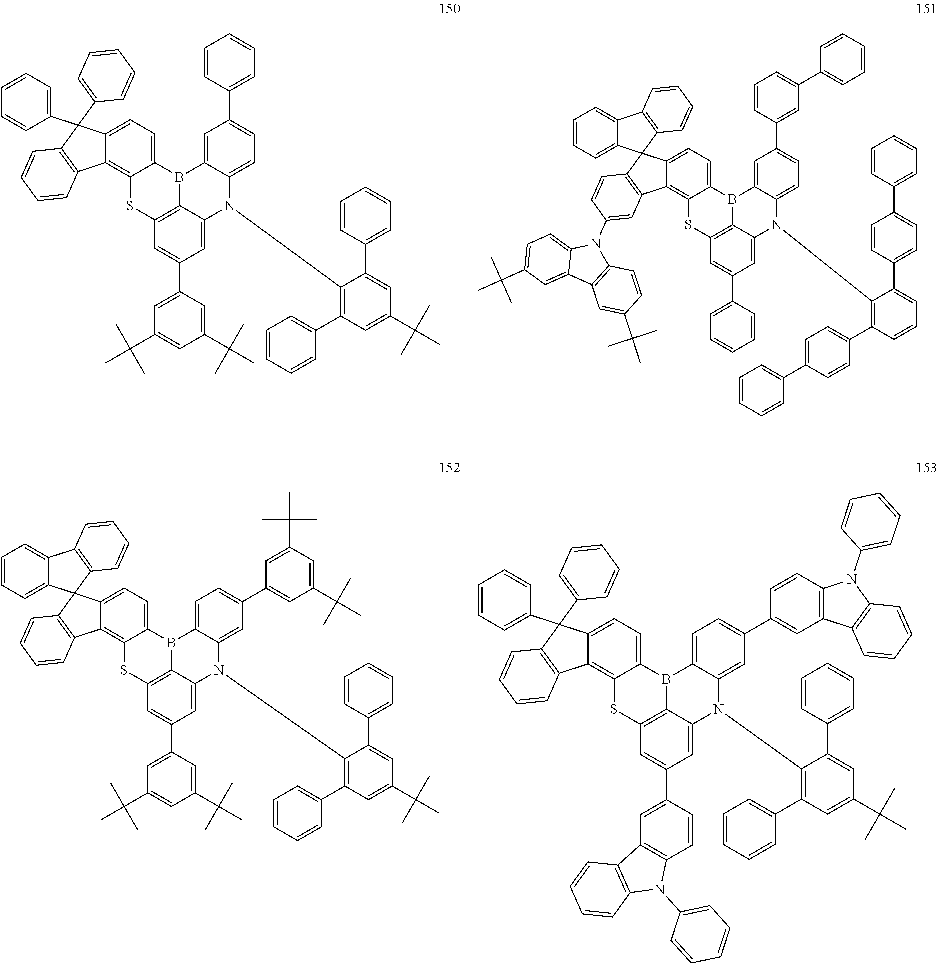

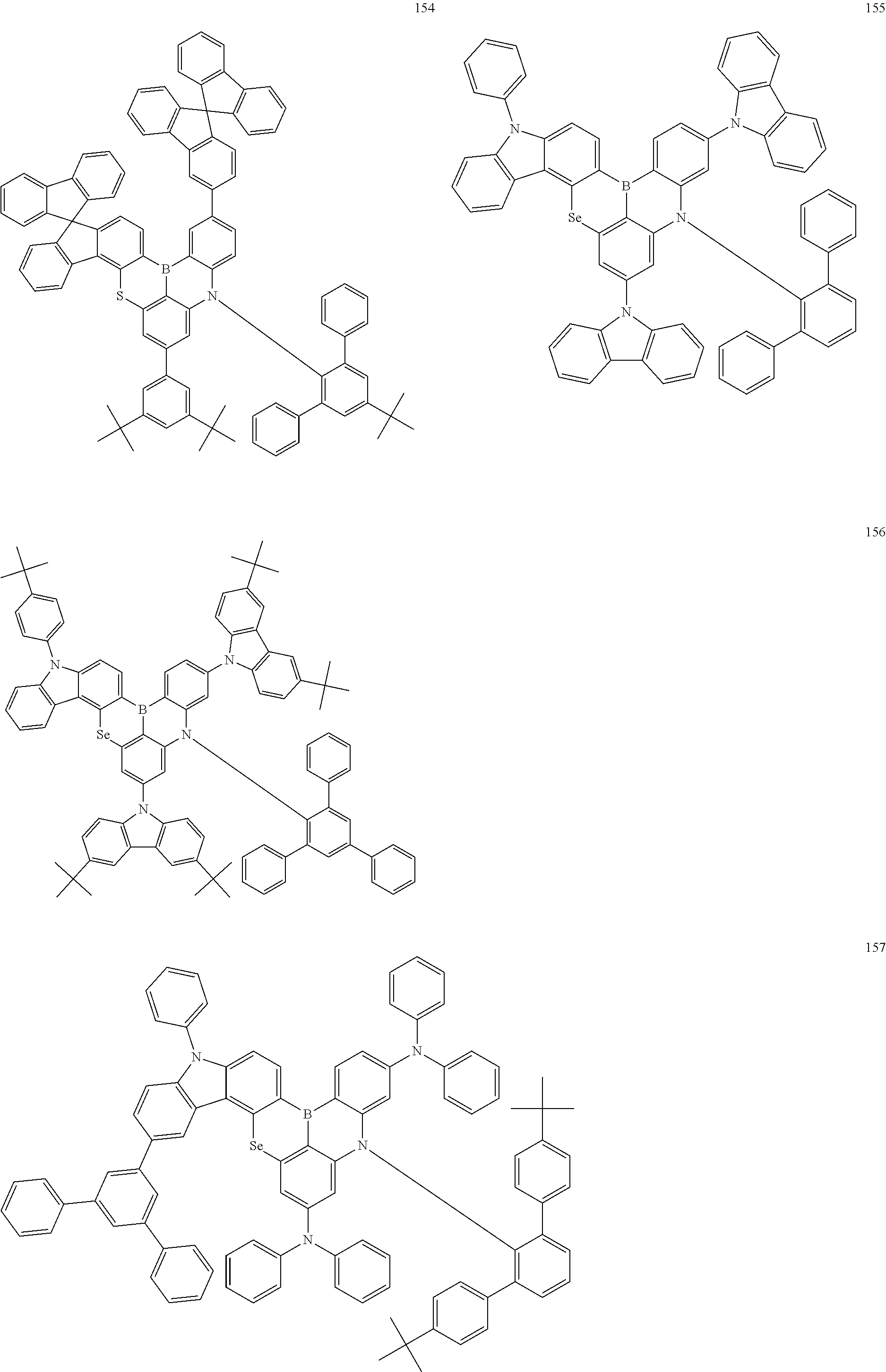

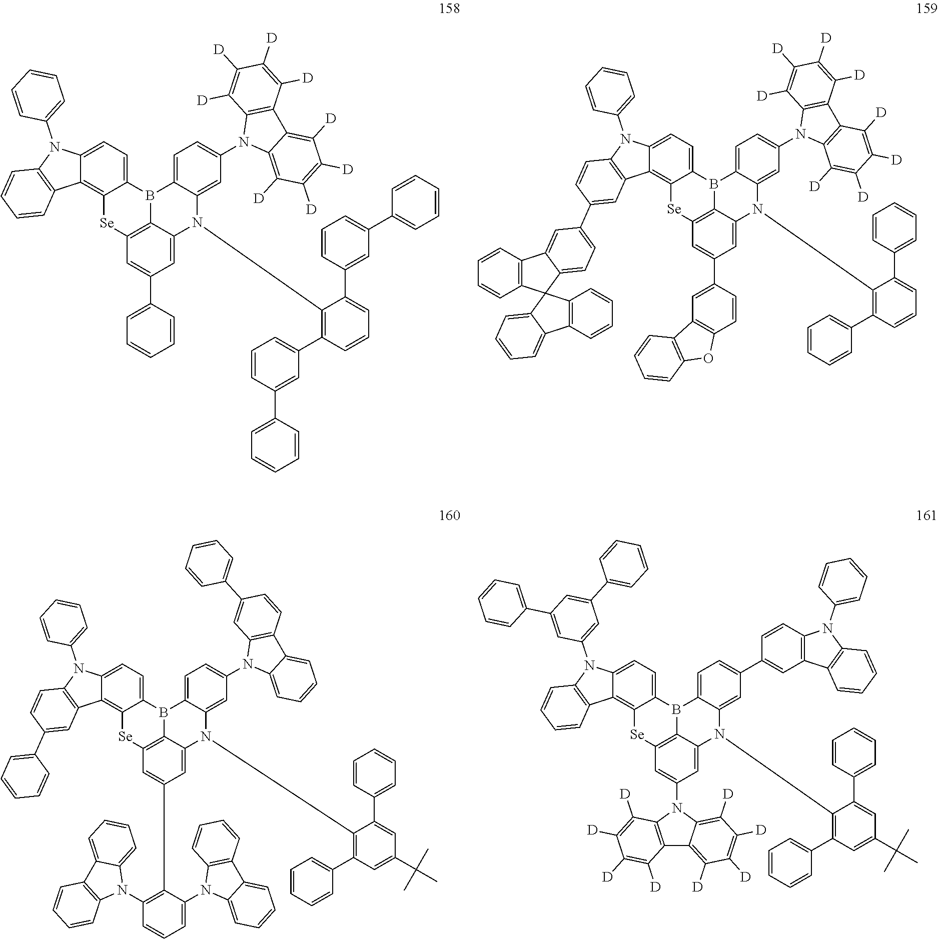

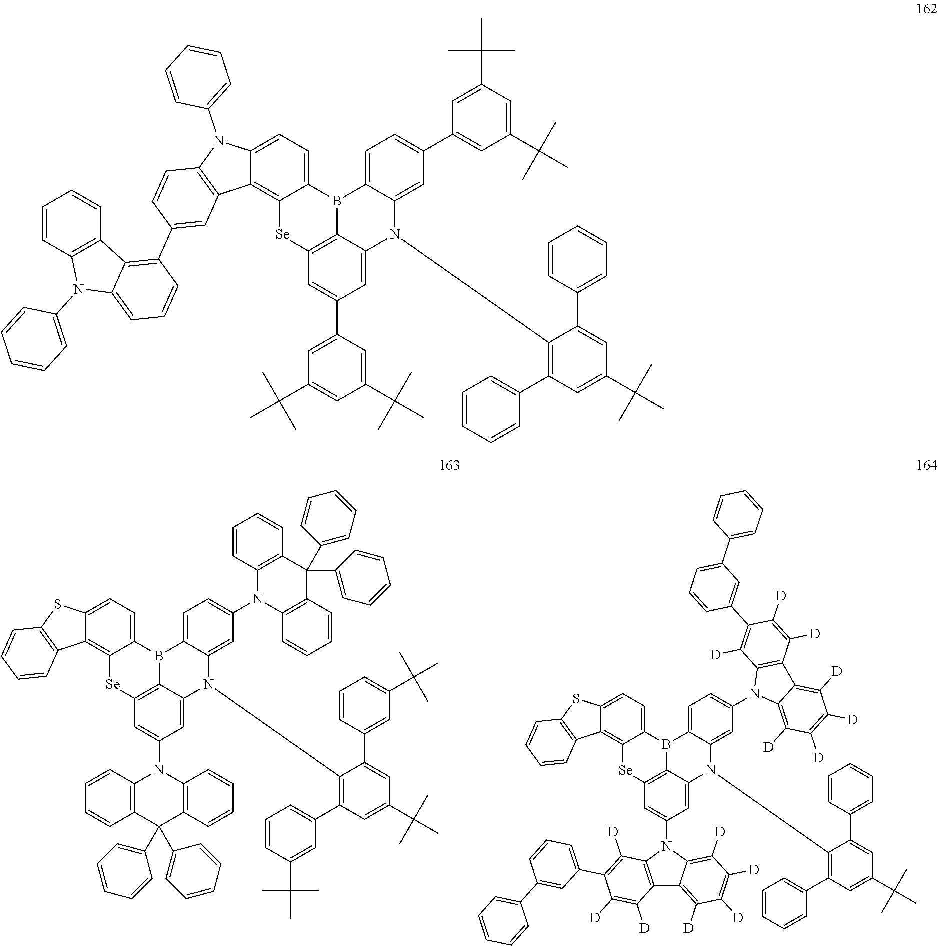

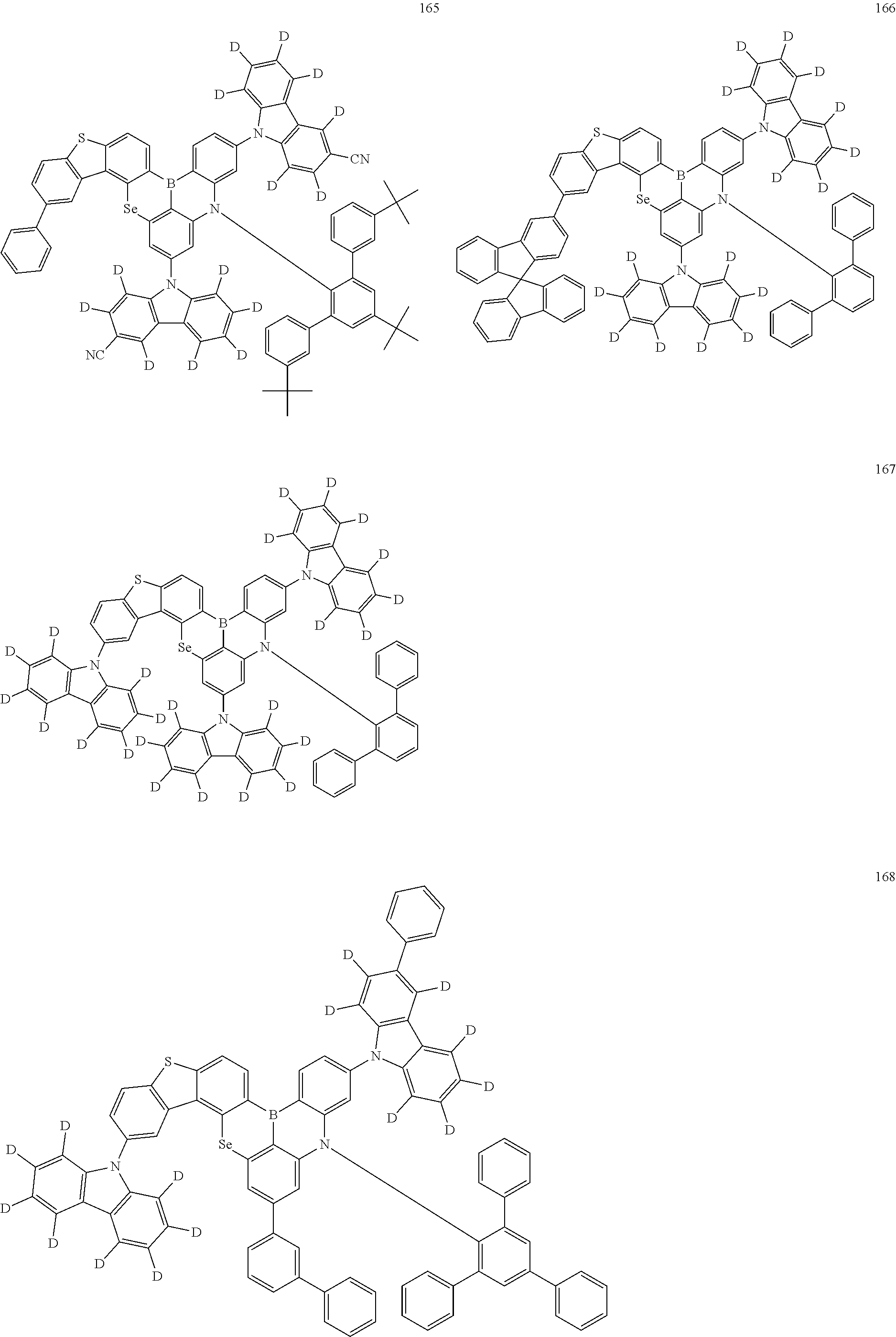

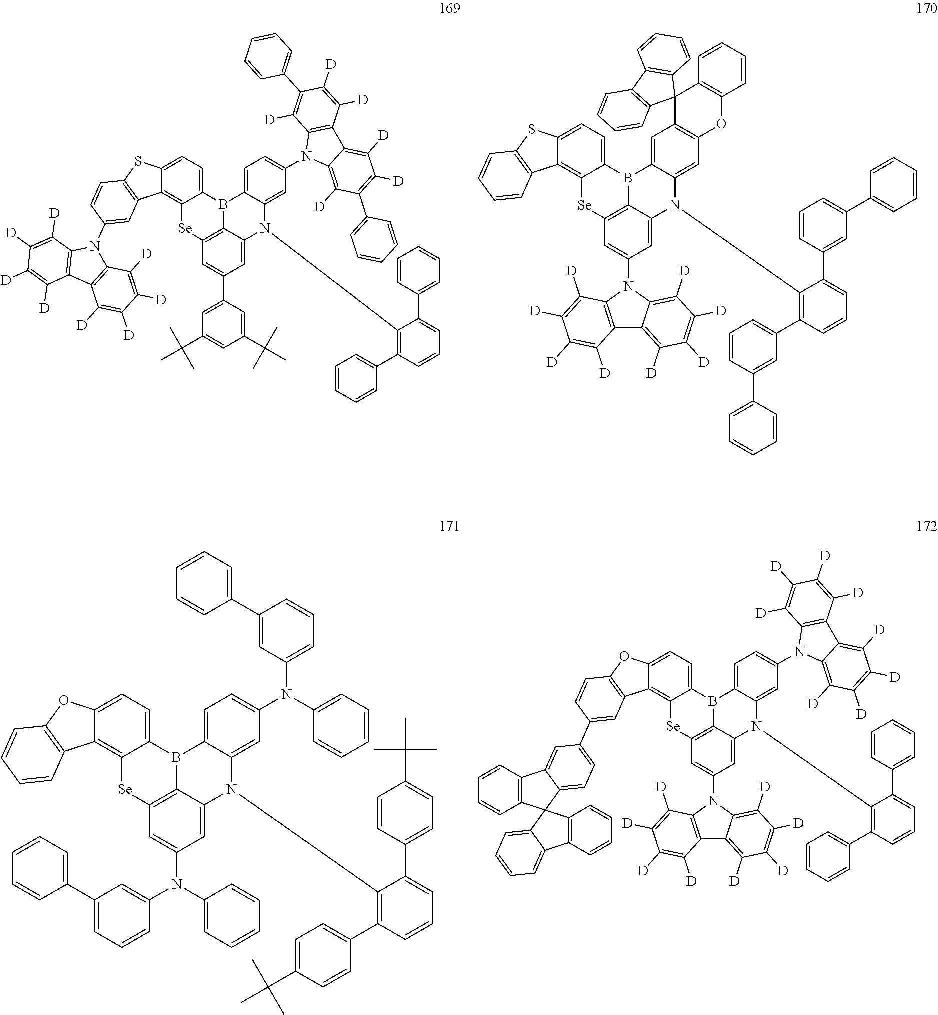

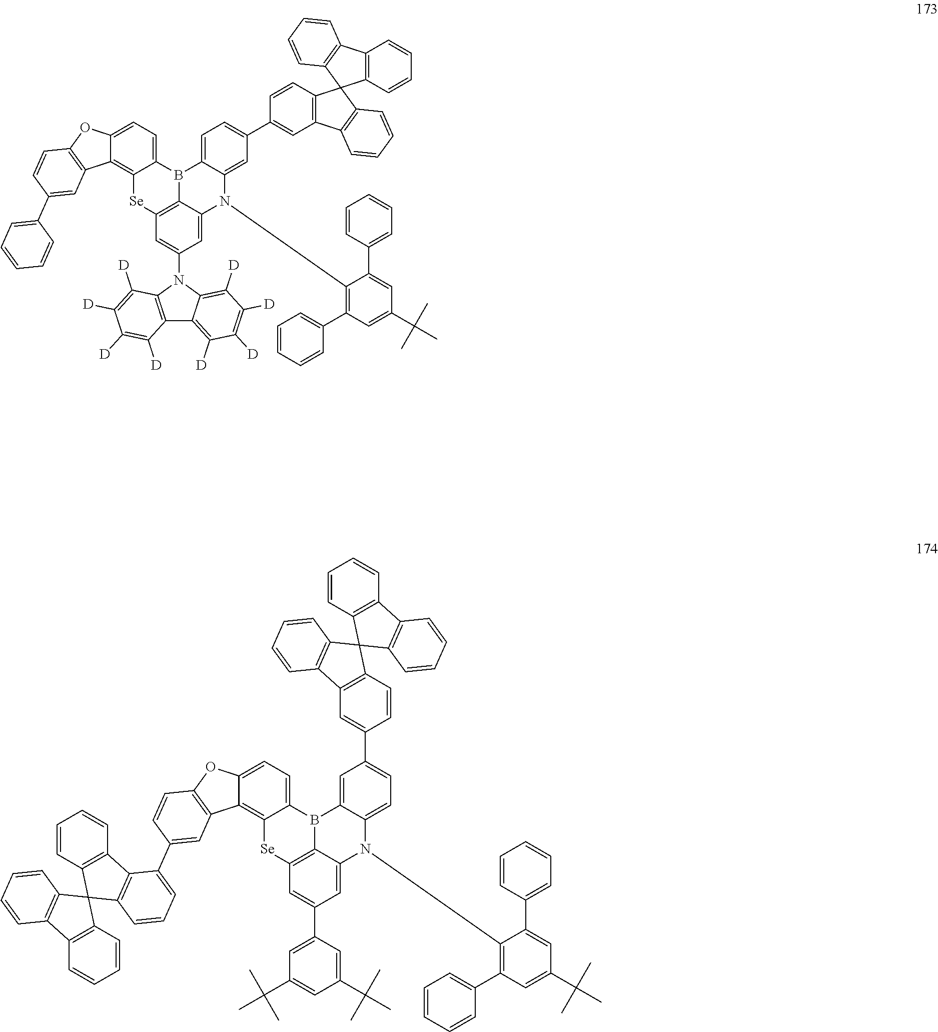 [SMILES: [2H]c1c([2H])c([2H])c2c(c1[2H])c1c([2H])c([2H])c([2H])c([2H])c1n2-c1cc2c3c(c1)N(c1c(-c4ccccc4)cc(C(C)(C)C)cc1-c1ccccc1)c1cc(-c4ccc5c(c4)-c4ccccc4C54c5ccccc5-c5ccccc54)ccc1B3c1ccc3oc4ccc(-c5ccccc5)cc4c3c1[Se]2 ; CC(C)(C)c1cc(-c2cc3c4c(c2)N(c2c(-c5ccccc5)cc(C(C)(C)C)cc2-c2ccccc2)c2ccc(-c5ccc6c(c5)-c5ccccc5C65c6ccccc6-c6ccccc65)cc2B4c2ccc4oc5ccc(-c6cccc7c6-c6ccccc6C76c7ccccc7-c7ccccc76)cc5c4c2[Se]3)cc(C(C)(C)C)c1]

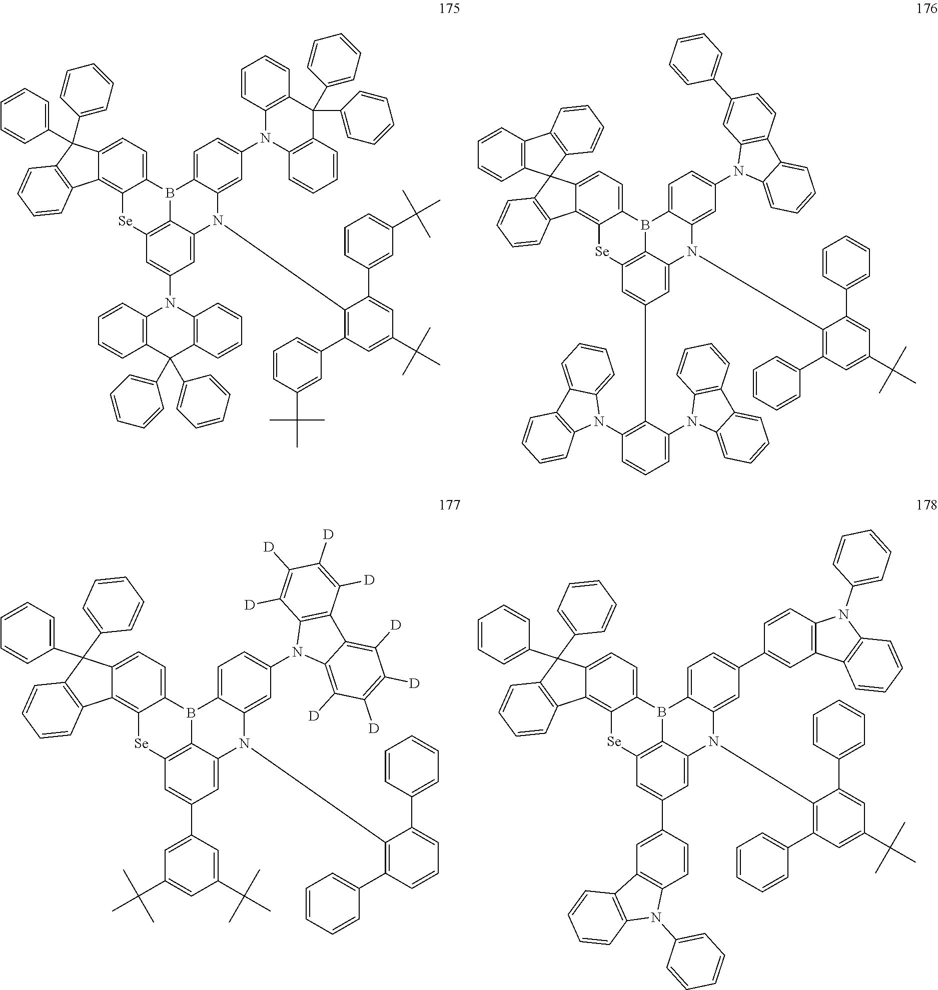

In the polycyclic compound of an embodiment, the emission spectrum may show a full width at half maximum of about 10 to 50 nm, or for example, a full width at half maximum of about 20 to 40 nm. The emission spectrum of the polycyclic compound of an embodiment of the present disclosure may have the above-described range of the full width at half maximum, and excellent optical characteristics may be shown. For example, if the polycyclic compound of an embodiment is used as a dopant material for a light emitting element, the emission efficiency and lifetime of the light emitting element may be improved.

The polycyclic compound of an embodiment may be used as a material for delayed fluorescence. For example, the polycyclic compound of an embodiment may be used as a material for thermally activated delayed fluorescence. The polycyclic compound of an embodiment may be used as a material for thermally activated delayed fluorescence, having a difference (ΔE_{ST}) between the lowest triplet energy level (T1) and the lowest singlet energy level (S1) of about 0.2 eV or less. Due to such (ΔE_{ST}) properties, RISC may occur rapidly in the polycyclic compound of an embodiment, and accordingly, material deterioration by excitons may be reduced, and excellent material stability may be shown.

The light emitting element of an embodiment, including the polycyclic compound according to an embodiment may show high efficiency and long-life characteristics. I light emitting element of an embodiment, including the polycyclic compound of an embodiment, has improved material stability in an emission layer and may show excellent lifetime characteristics.

In the light emitting element according to an embodiment, the emission layer EML may be a delayed fluorescence emission layer including a host and a dopant. In some embodiments, the emission layer EML may emit thermally activated delayed fluorescence (TADF). The polycyclic compound of an embodiment may be a thermally activated delayed fluorescence dopant.

The emission layer EML may include the polycyclic compound of an embodiment as a dopant. The polycyclic compound of an embodiment may emit blue light. For example, the polycyclic compound of an embodiment may be a light-emitting material having an emission center wavelength in a wavelength region of about 430 nm to about 490 nm. The polycyclic compound of an embodiment may be a light-emitting material having an emission center wavelength in a wavelength region of about 450 nm to about 470 nm.

In an embodiment, the emission layer EML includes the polycyclic compound of an embodiment and may include at least one among the second to fourth compounds. In an embodiment, the emission layer EML may include the second compound represented by Formula HT-1. For example, the second compound may be used as the hole transporting host material of the emission layer EML.

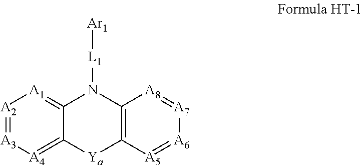

In Formula HT-1, A₁ to A₈ may be each independently N or CR₅₁. For example, all of A₁ to A₈ may be CR₅₁. In some embodiments, any one among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments of the present disclosure are not limited thereto.

In Formula HT-1, Yₐ may be a direct linkage, CR₅₂R₅₃, or SiR₅₄R₅₅. In some embodiments, it may mean that the two benzene rings linked to the nitrogen atom in Formula HT-1 are linked via a direct linkage,

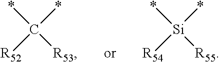

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments of the present disclosure are not limited thereto.

In Formula HT-1, R₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₅ may be bonded to an adjacent group to form a ring. For example, R₅₁ to R₅₅ may be each independently a hydrogen atom or a deuterium atom. R₅₁ to R₅₅ may be each independently an unsubstituted methyl group or an unsubstituted phenyl group.

In an embodiment, the second compound represented by Formula HT-1 may be represented by any one among the compounds represented by Compound Group 2 below. The emission layer EML may include at least one among the compounds represented by Compound Group 2 as a hole transporting host material.

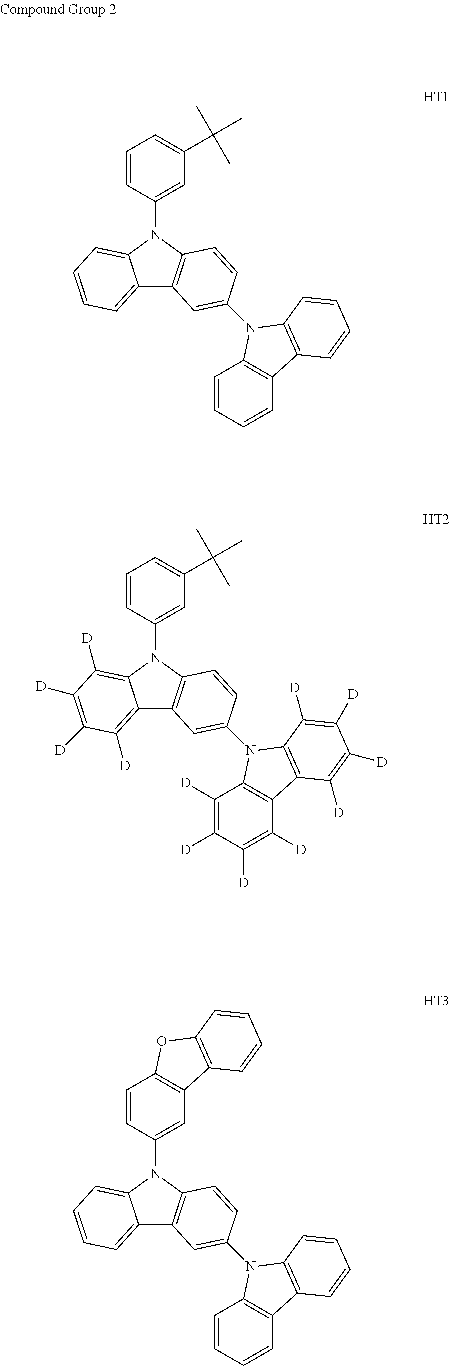 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

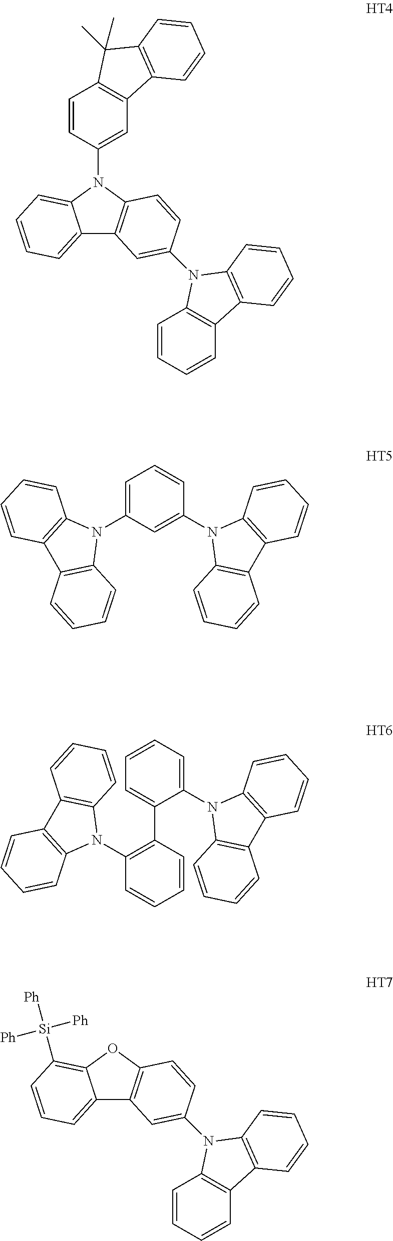 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

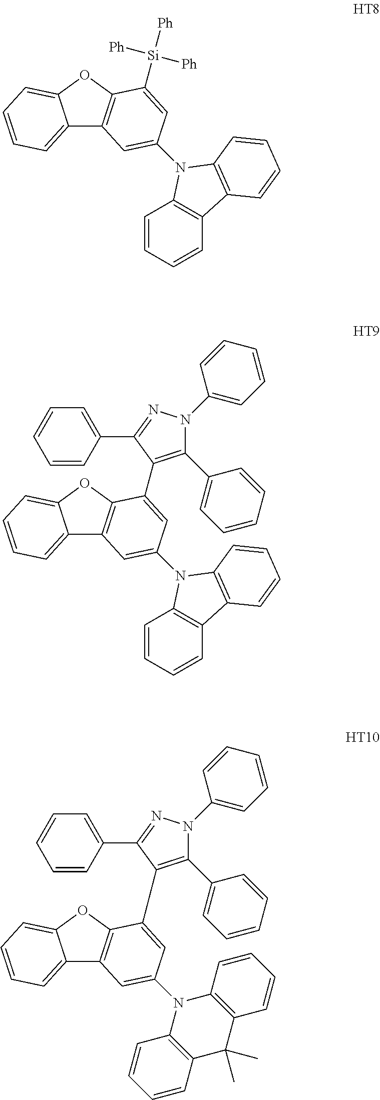 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

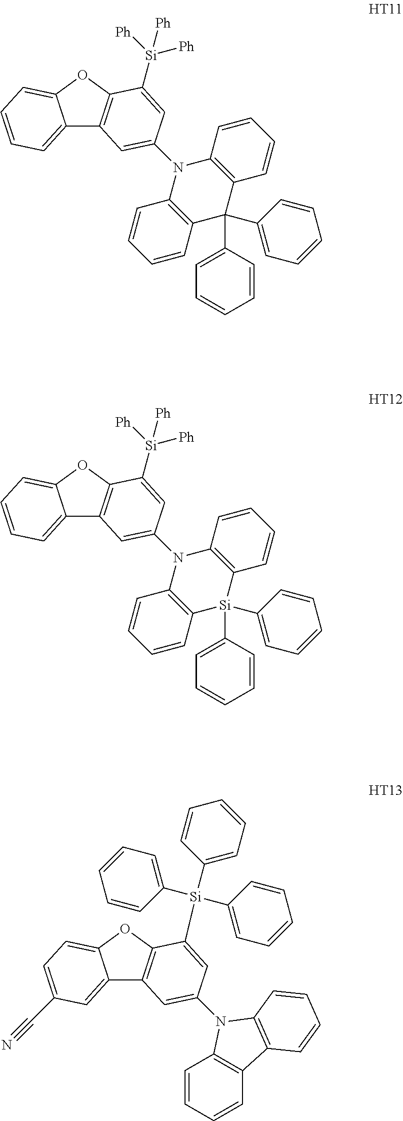 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

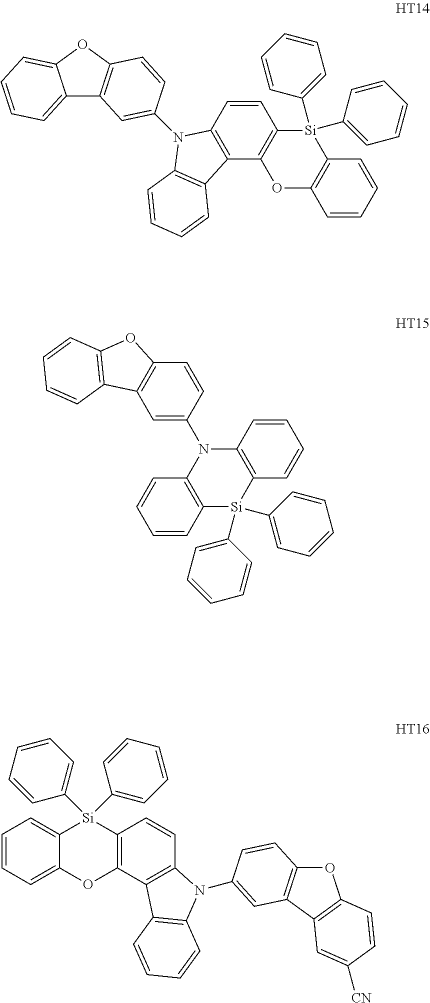 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

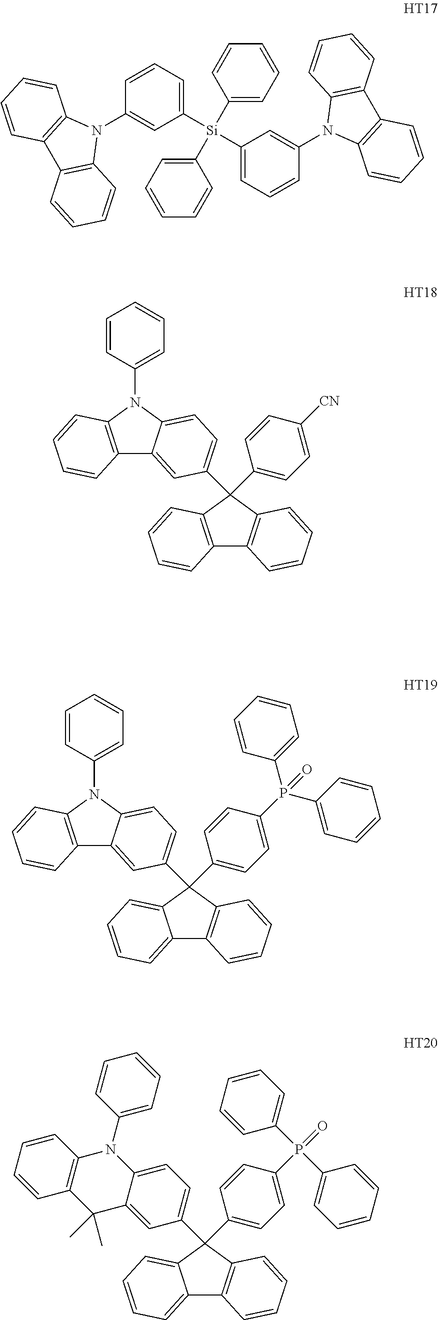 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

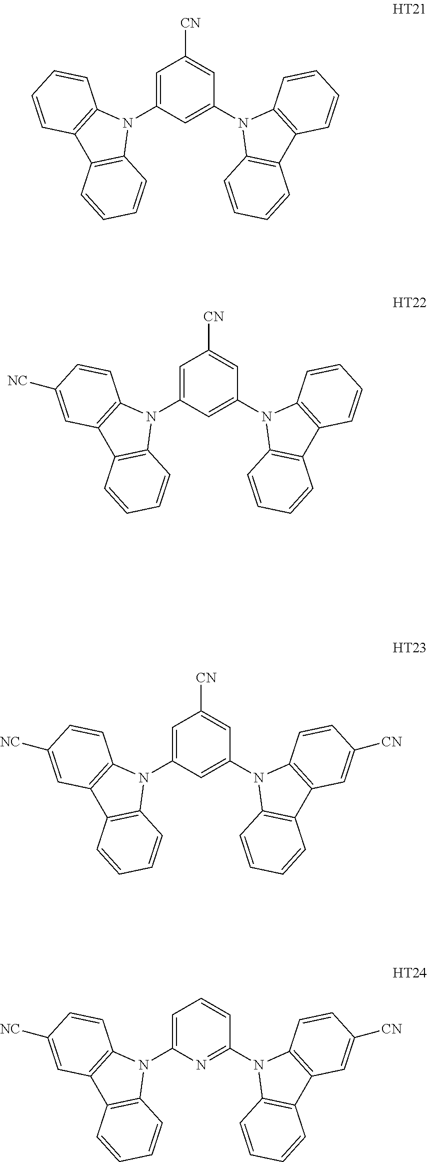 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

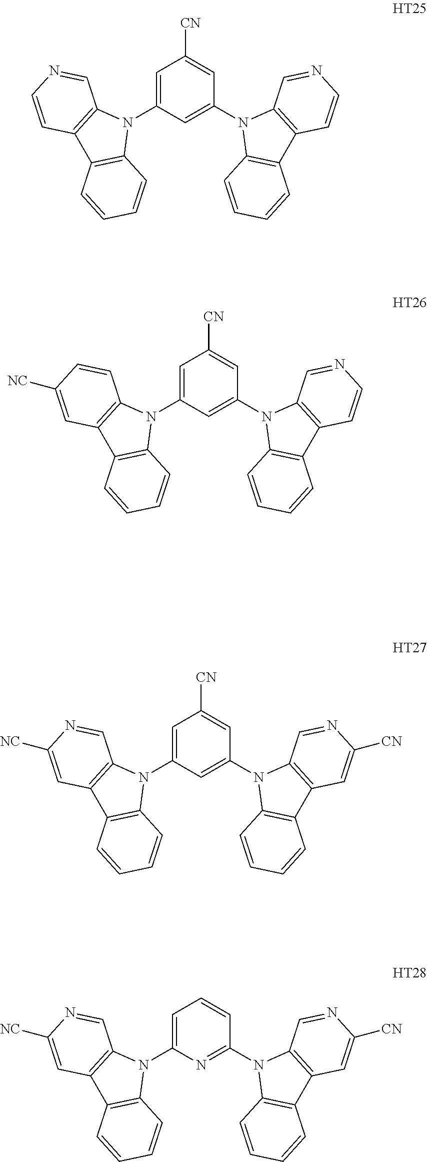 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

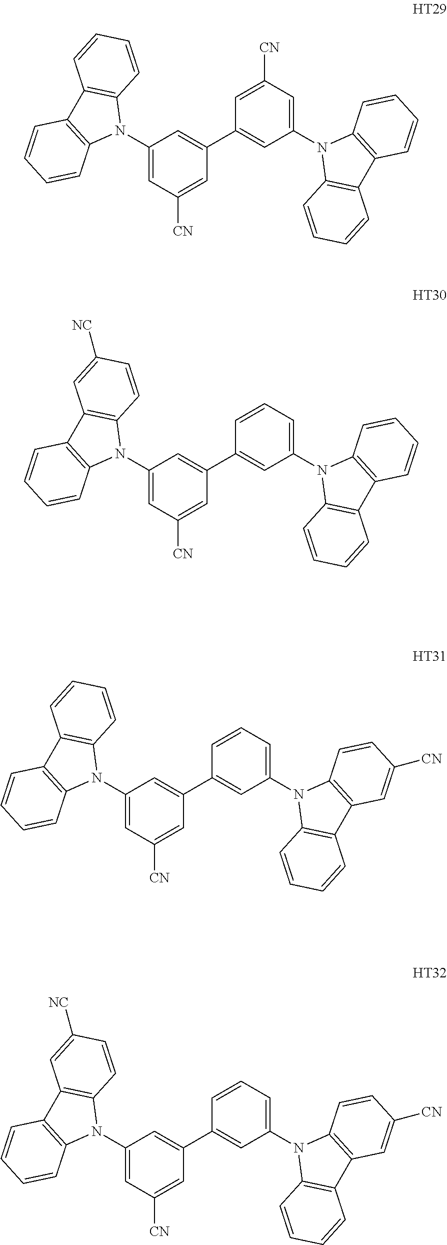 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

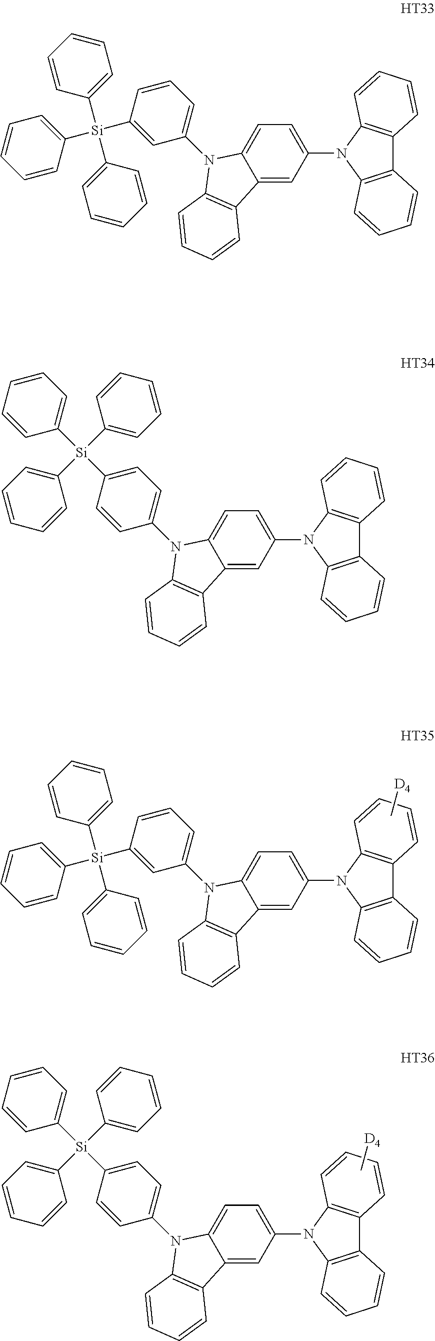

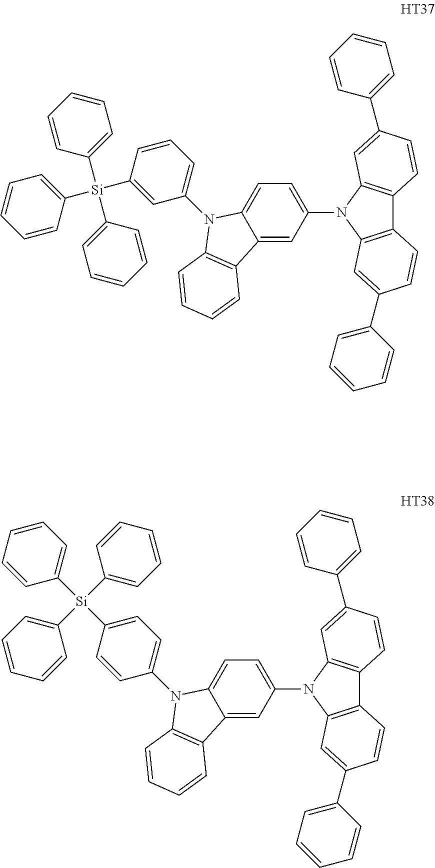 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

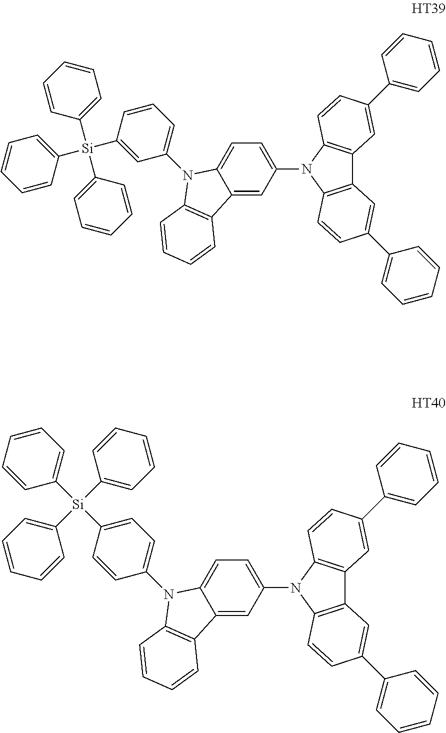 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

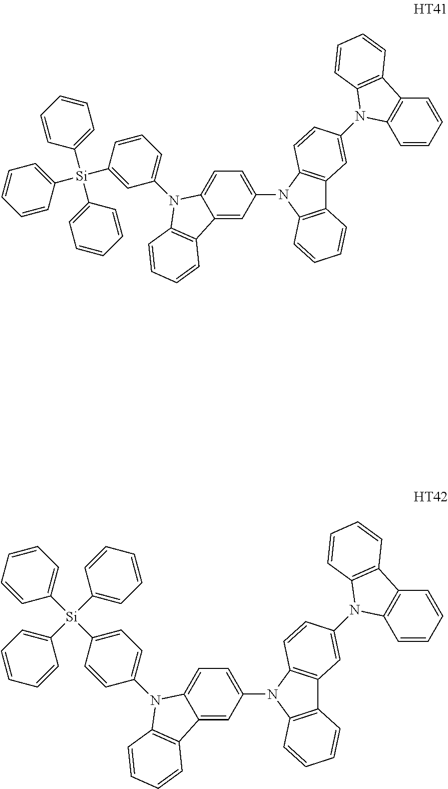 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

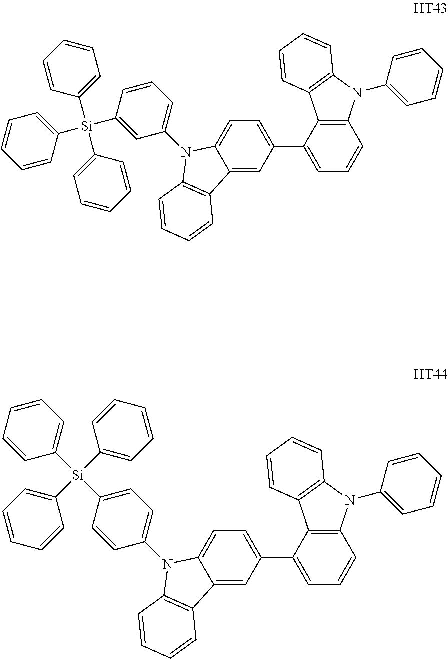 [SMILES: c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

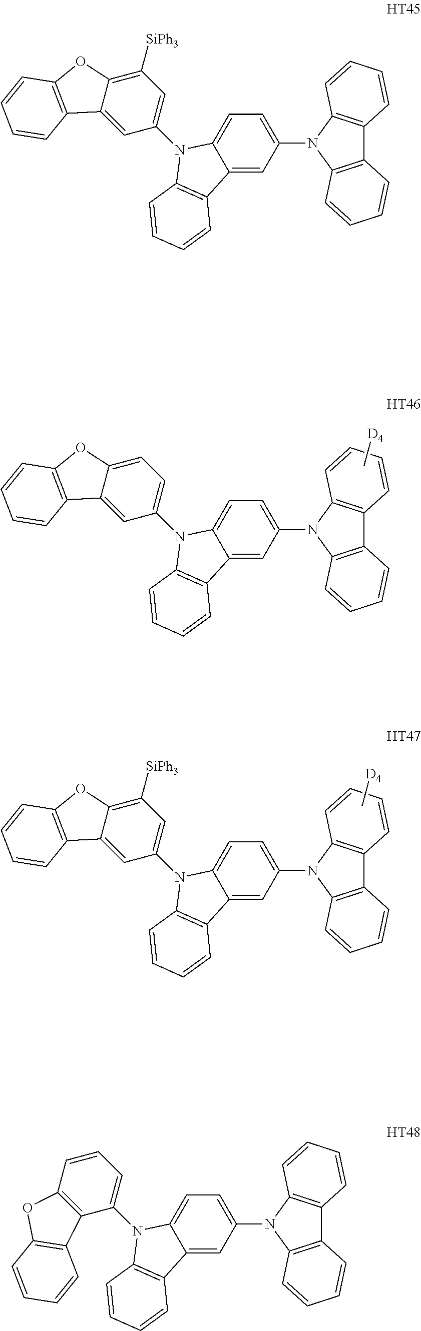

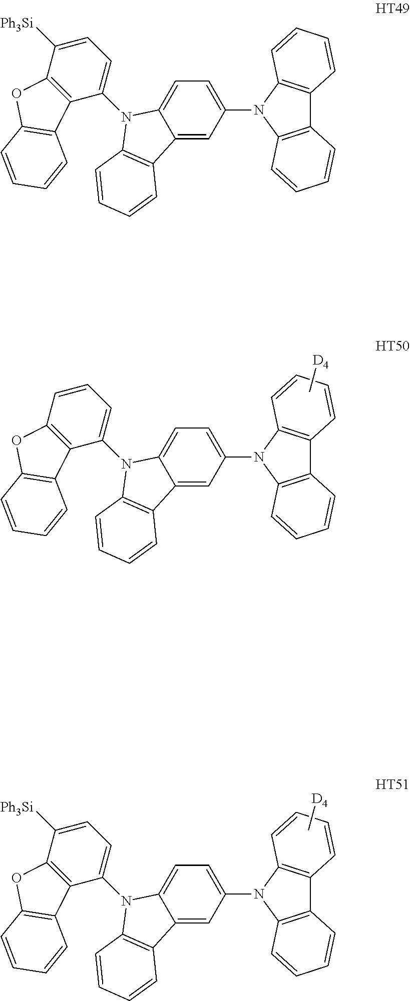

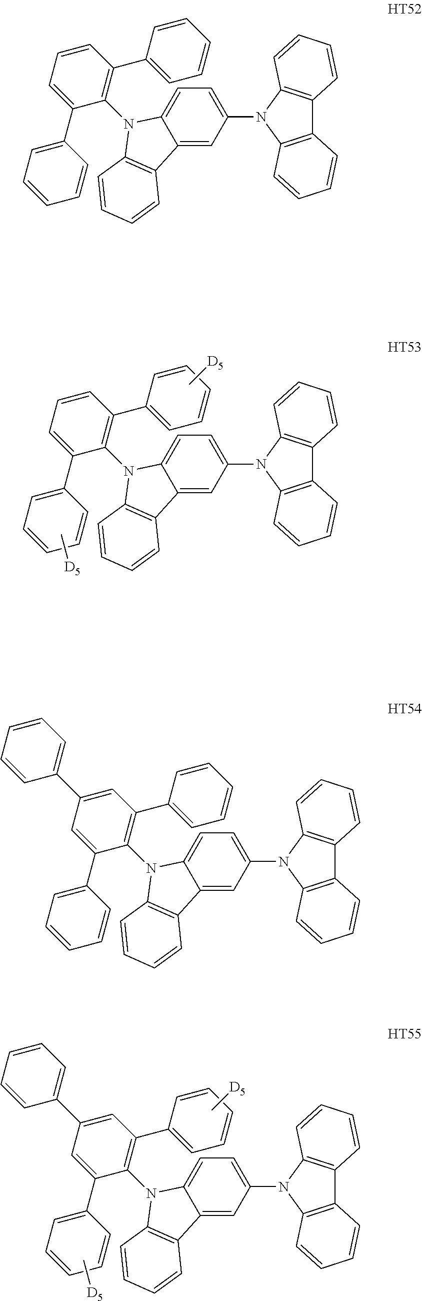

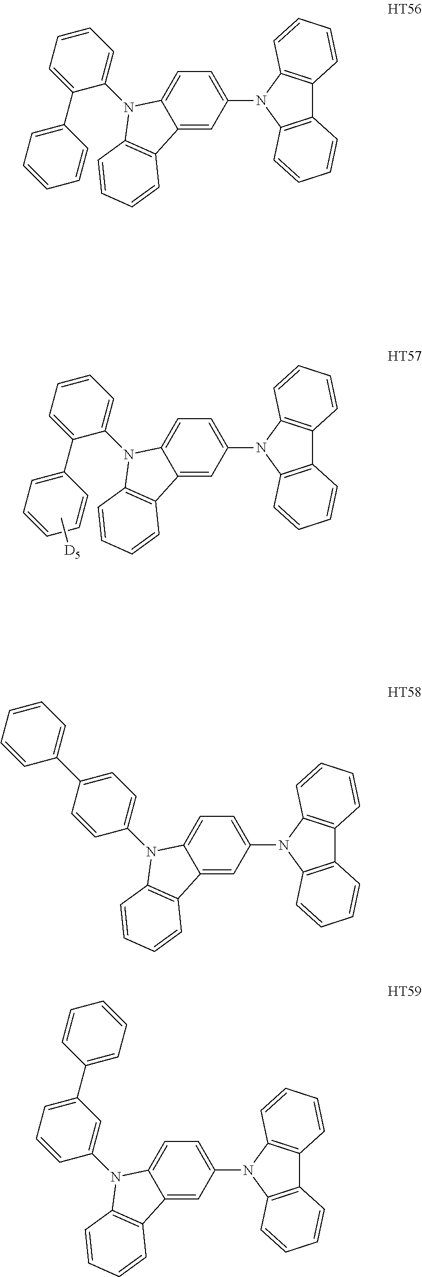

In embodiment compounds presented in Compound Group 2, “D” may mean a deuterium atom, and “Ph” may mean a substituted or unsubstituted phenyl group. For example, in embodiment compounds presented in Compound Group 2, “Ph” may mean an unsubstituted phenyl group.

In an embodiment, the emission layer EML may include the third compound represented by Formula ET-1 below. For example, the third compound may be used as an electron transporting host material for the emission layer EML.

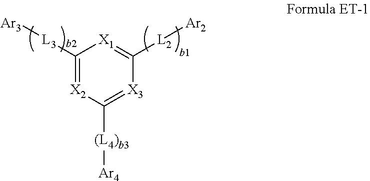

In Formula ET-1, at least one among X₁ to X₃ is N, and the rest are CR₅₆. For example, any one among X₁ to X₃ may be N, and the rest may be each independently CR₅₆. In some embodiments, the third compound represented by Formula ET-1 may include a pyridine moiety. In some embodiments, two among X₁ to X₃ may be N, and the rest may be CR₅₆. In some embodiments, the third compound represented by Formula ET-1 may include a pyrimidine moiety. In some embodiments, X₁ to X₃ may all be N. In some embodiments, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may be each independently an integer of 0 to 10.

In Formula ET-1, Ar₂ to Ar₄ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may be each independently a substituted or unsubstituted phenyl group, or a substituted or unsubstituted carbazole group.

In Formula ET-1, L₂ to L₄ may be each independently a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or greater, L₂ to L₄ may be each independently a substituted or unsubstituted arylene group having 6 to 30 ring-forming carbon atoms, or a substituted or unsubstituted heteroarylene group having 2 to 30 ring-forming carbon atoms.

In an embodiment, the third compound may be represented by any one among compounds in Compound Group 3 below. The light emitting element ED of an embodiment may include any one among the compounds in Compound Group 3 below.

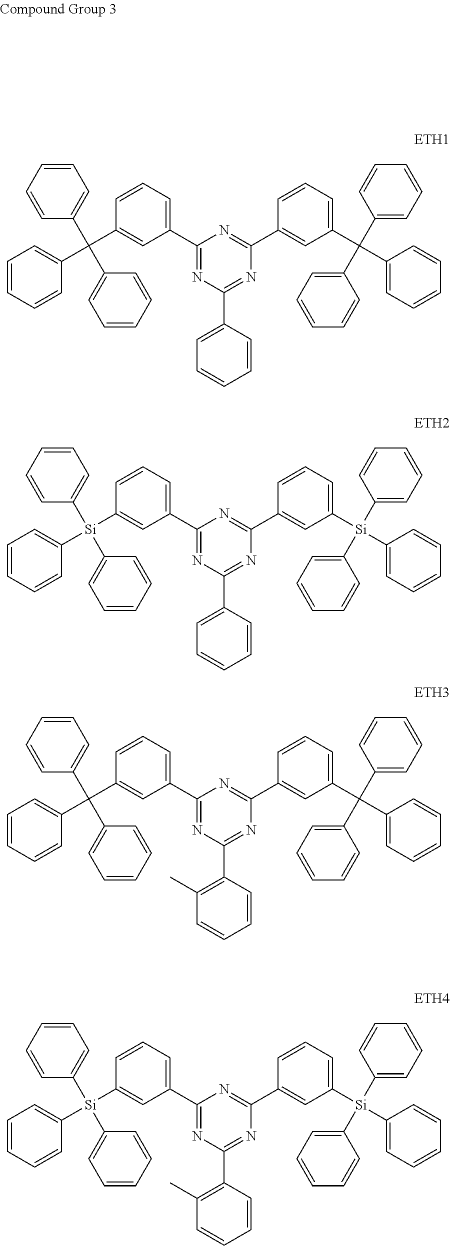 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

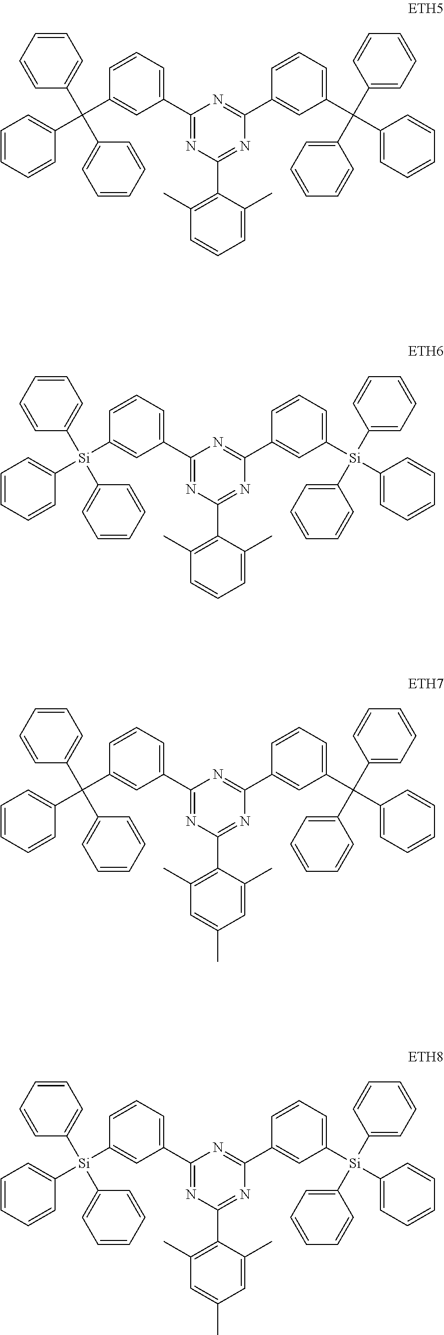 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

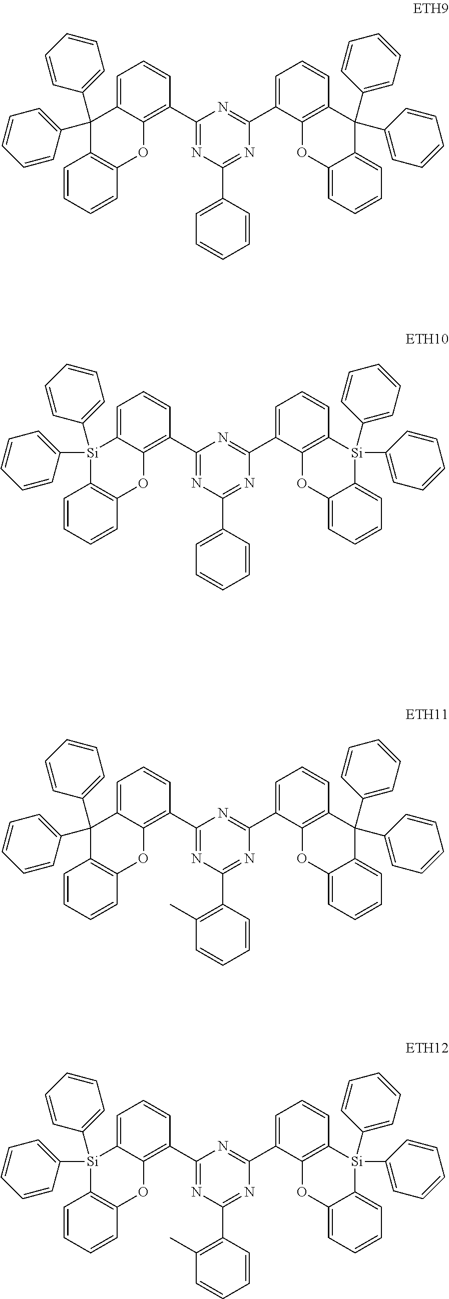 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

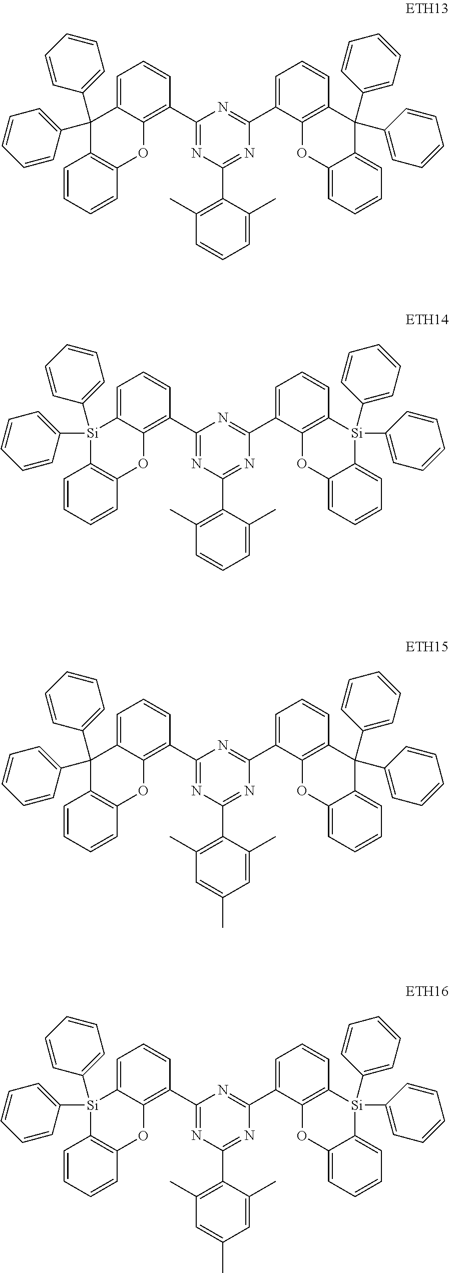 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

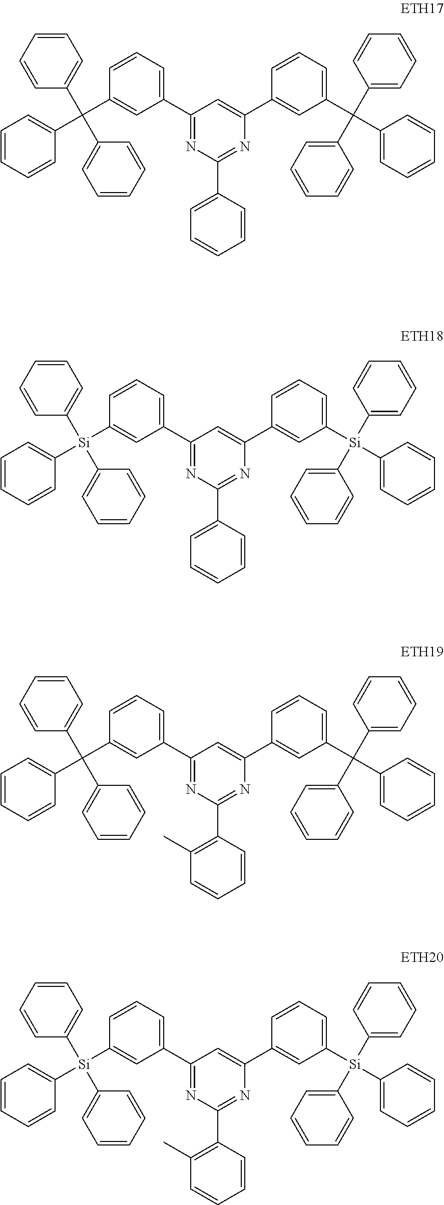 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

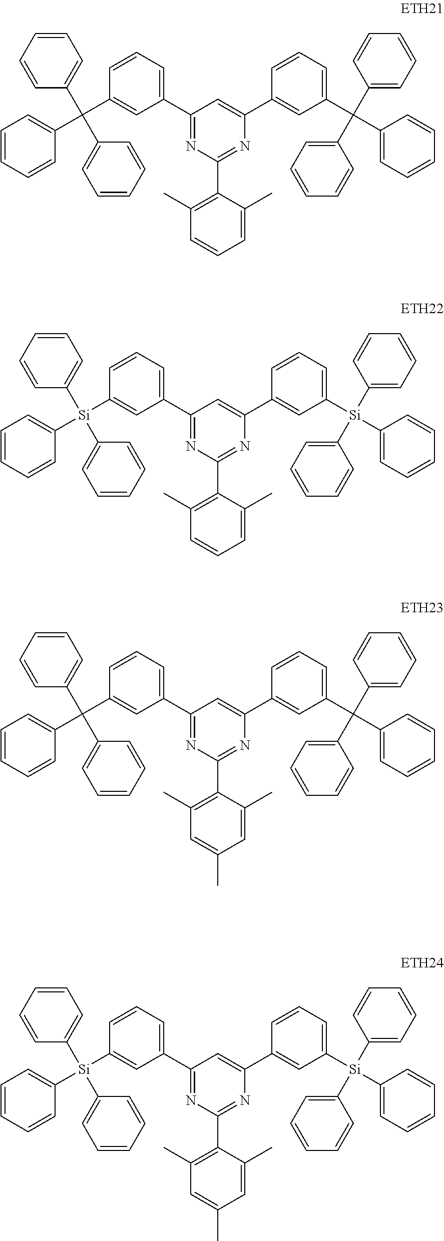 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

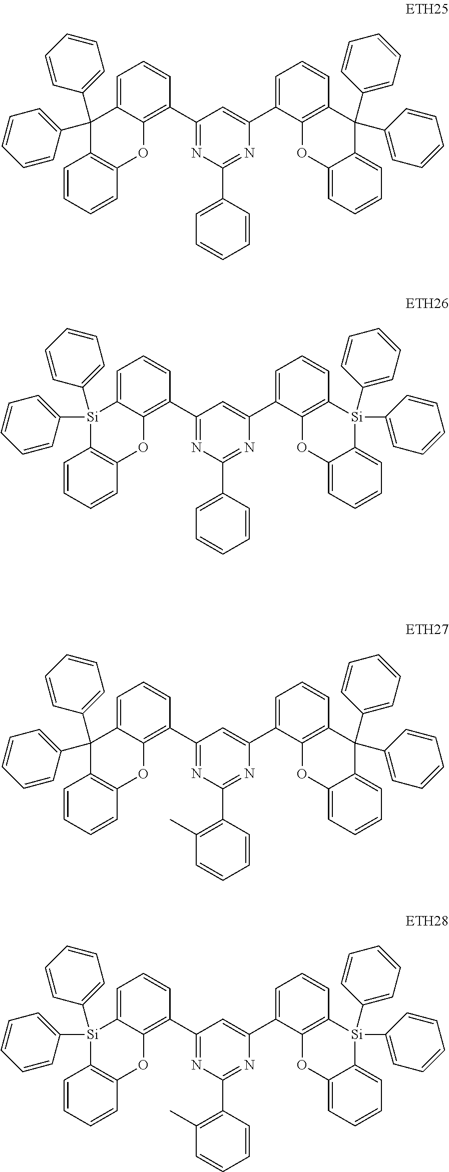 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

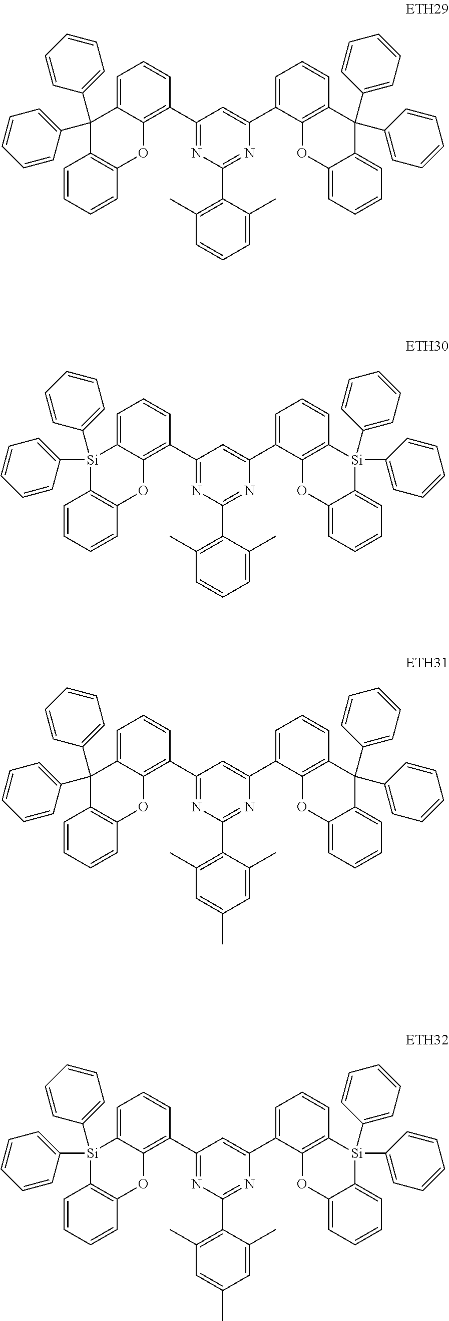 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

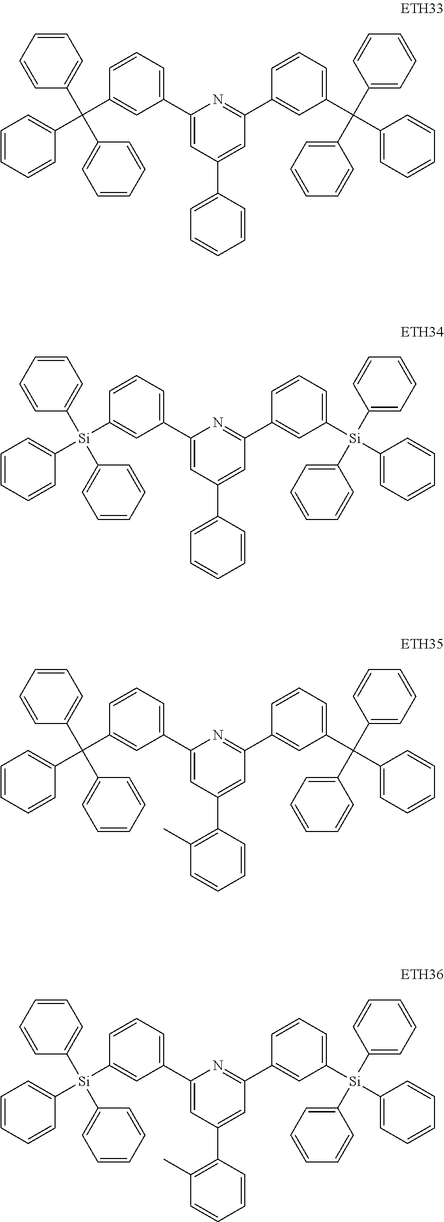 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

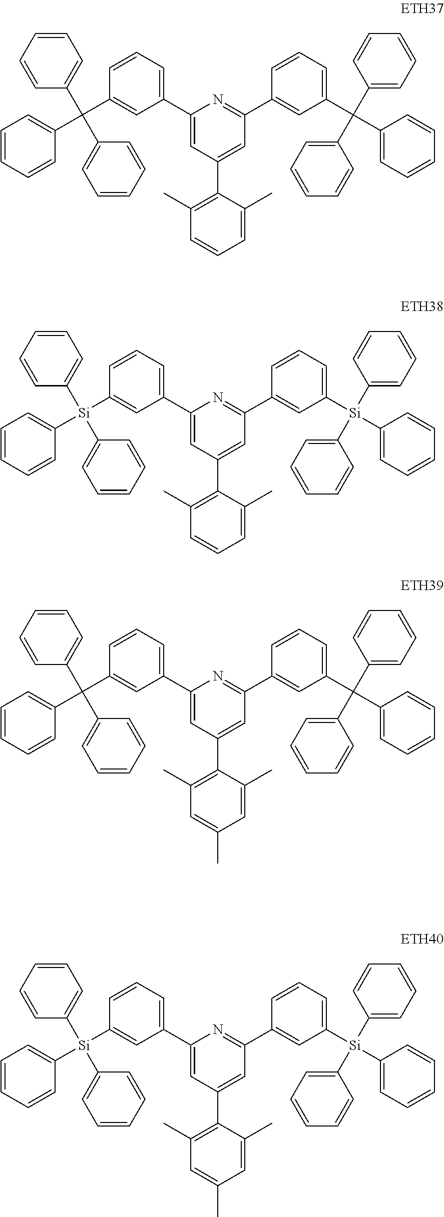 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

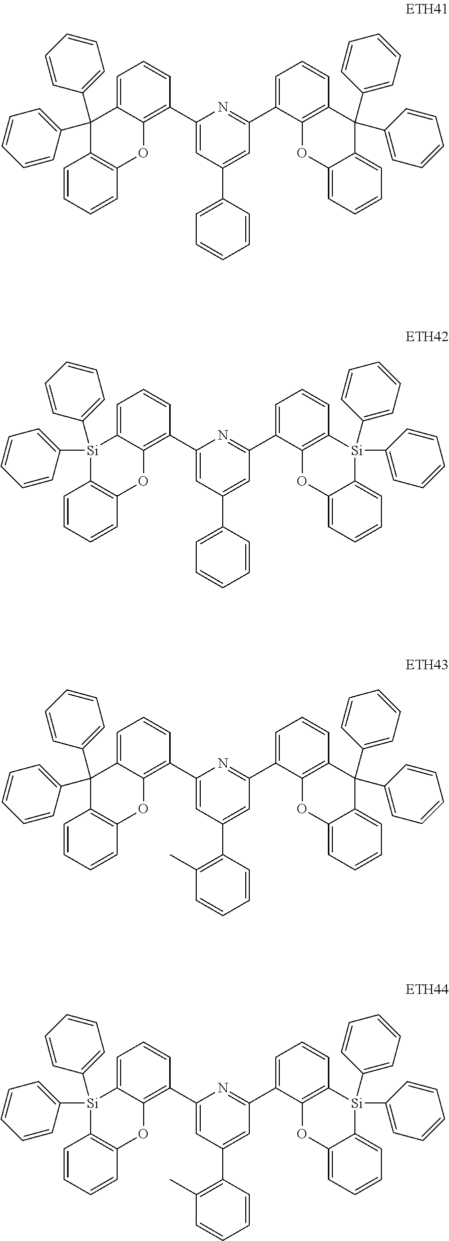 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

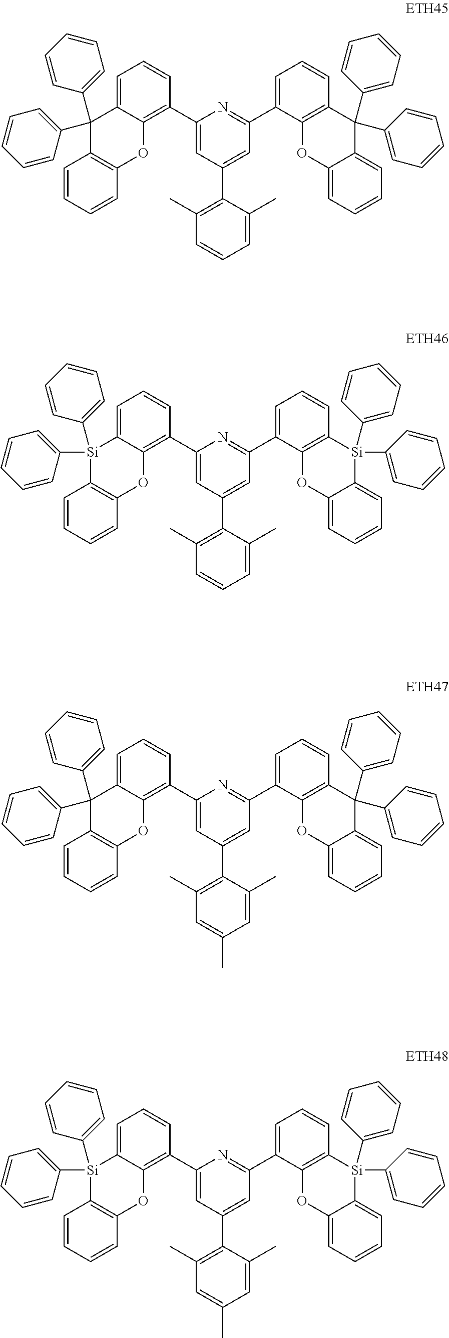 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

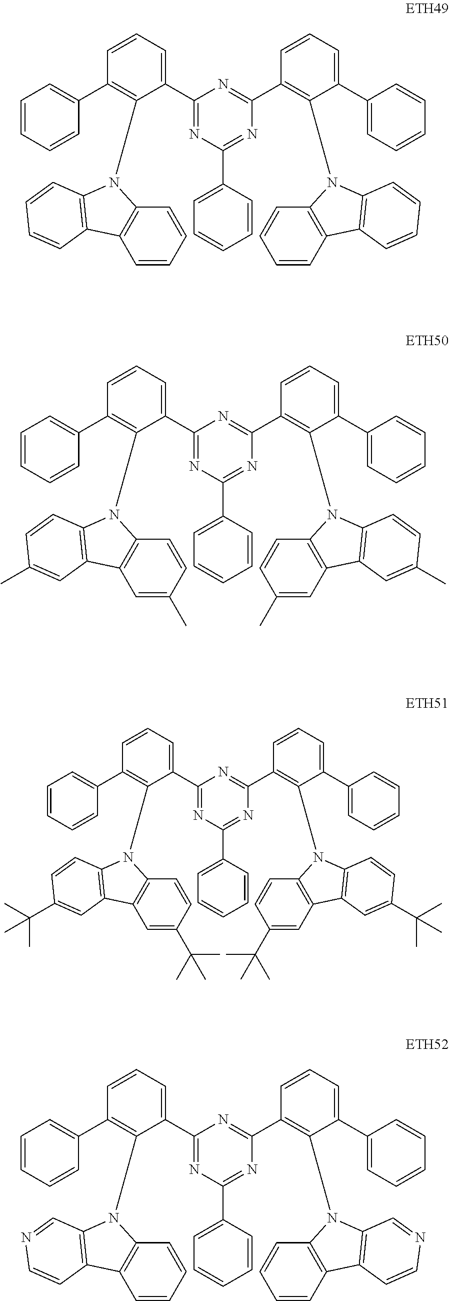

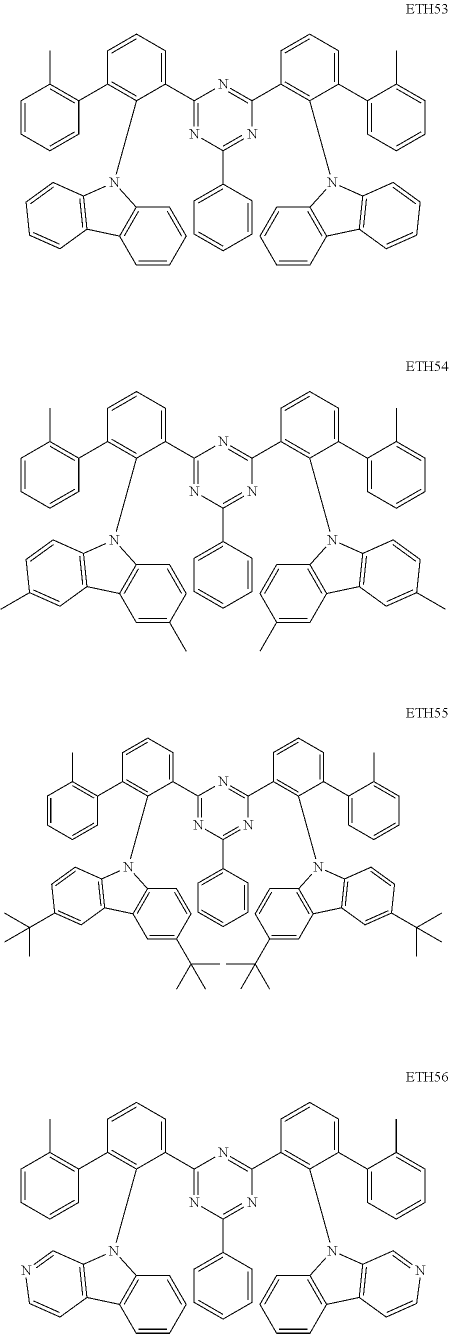

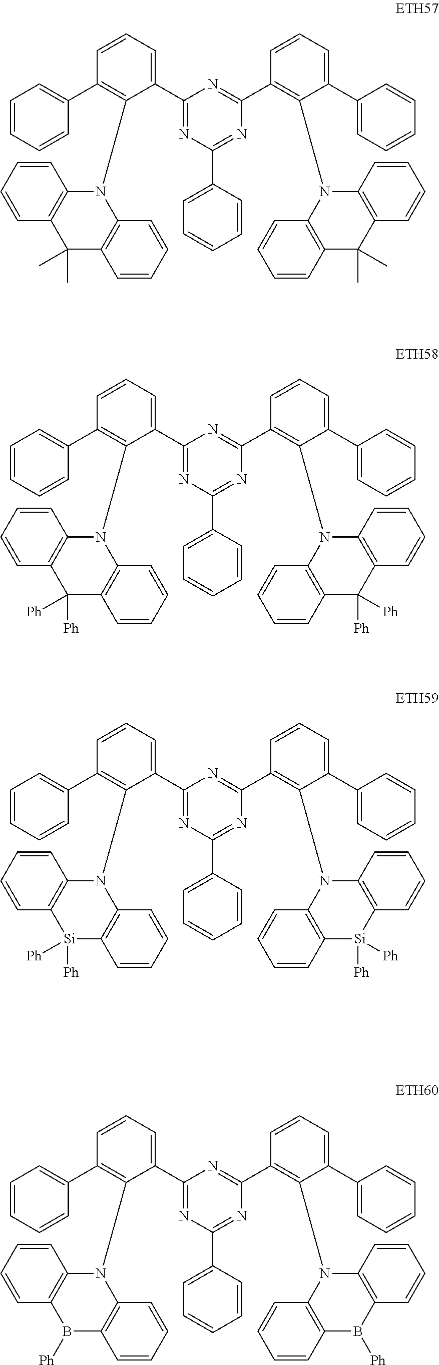

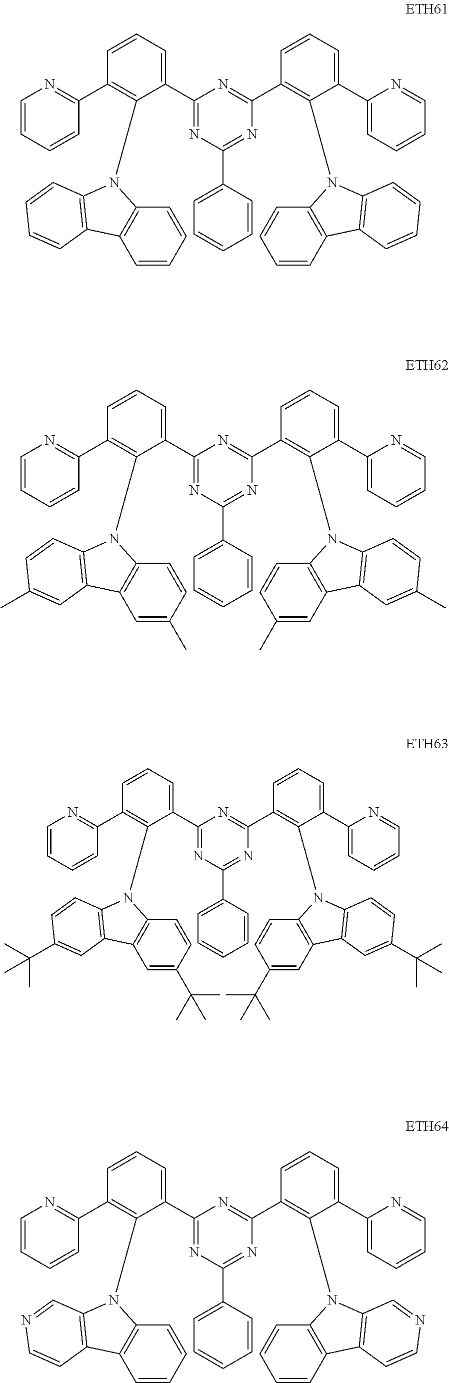

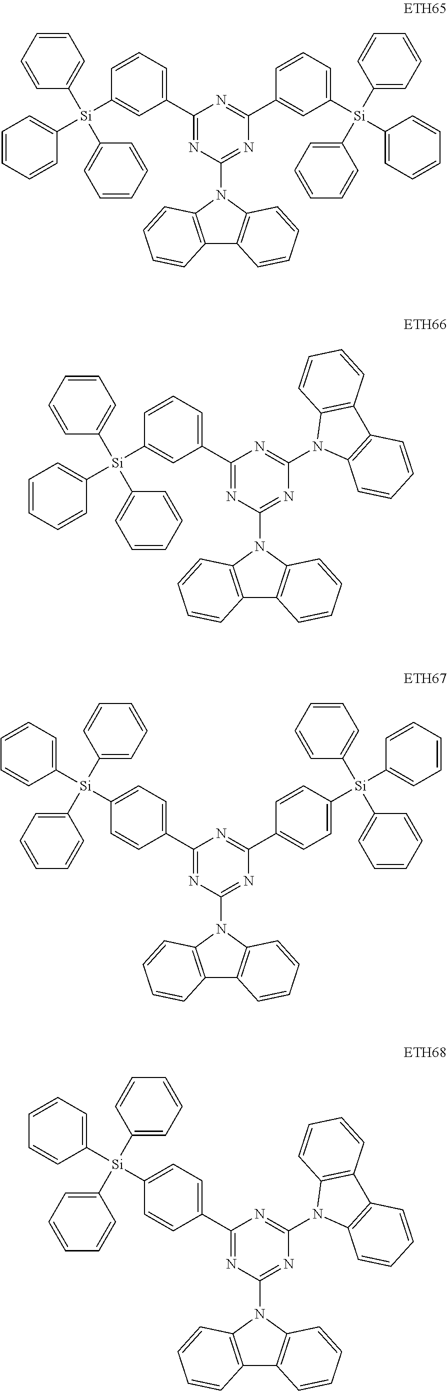 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

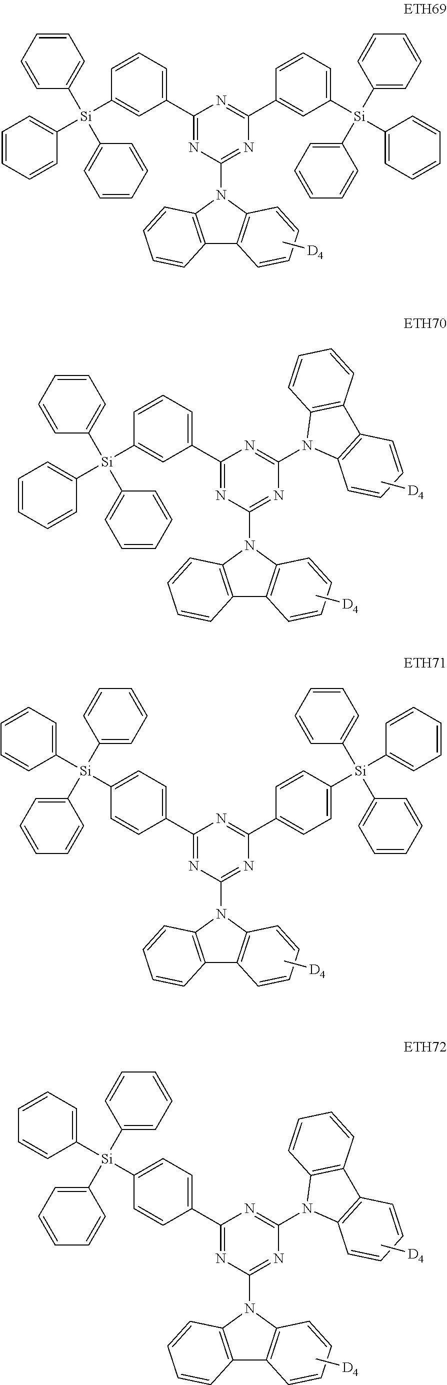

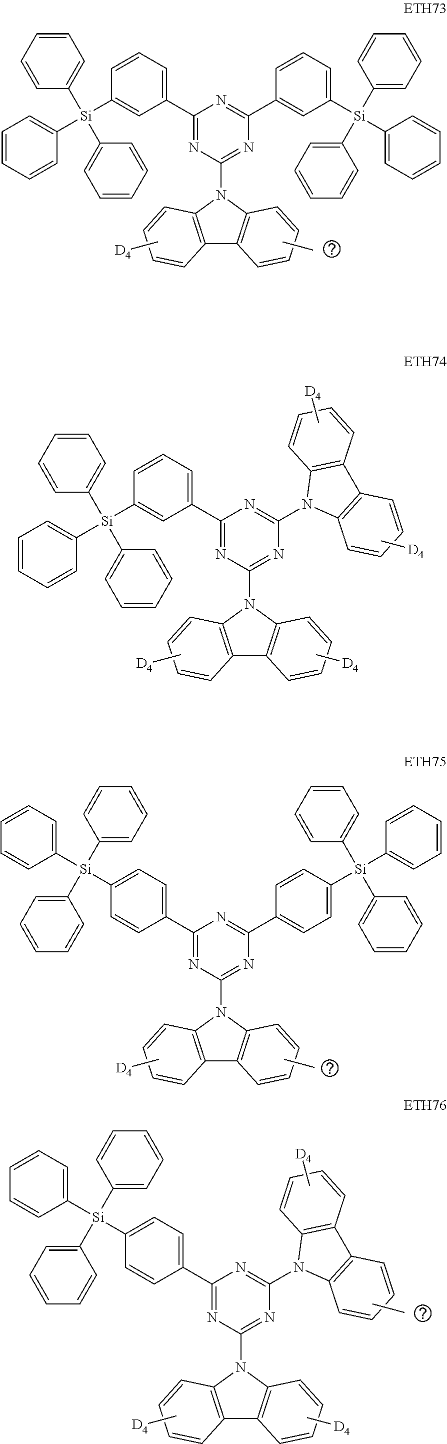

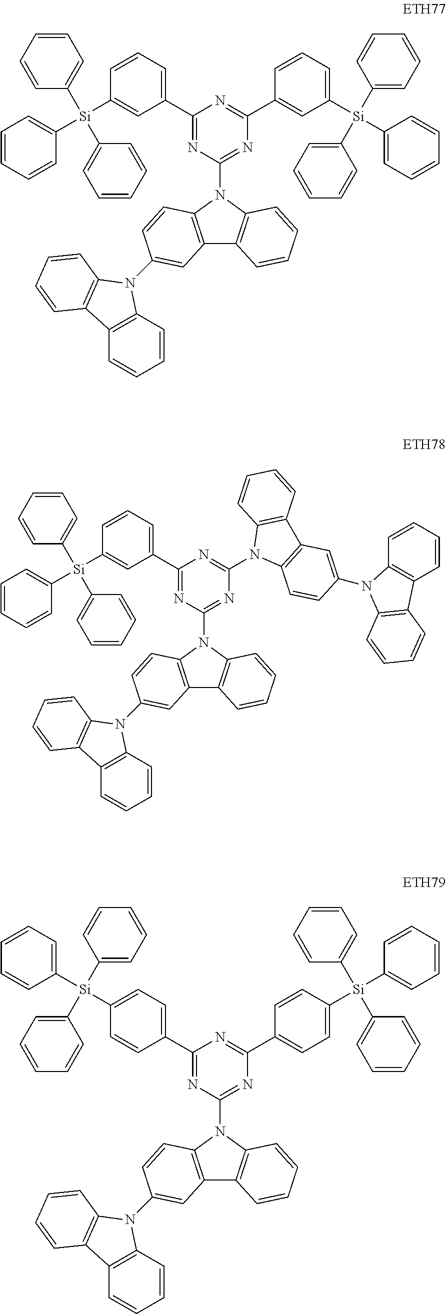 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

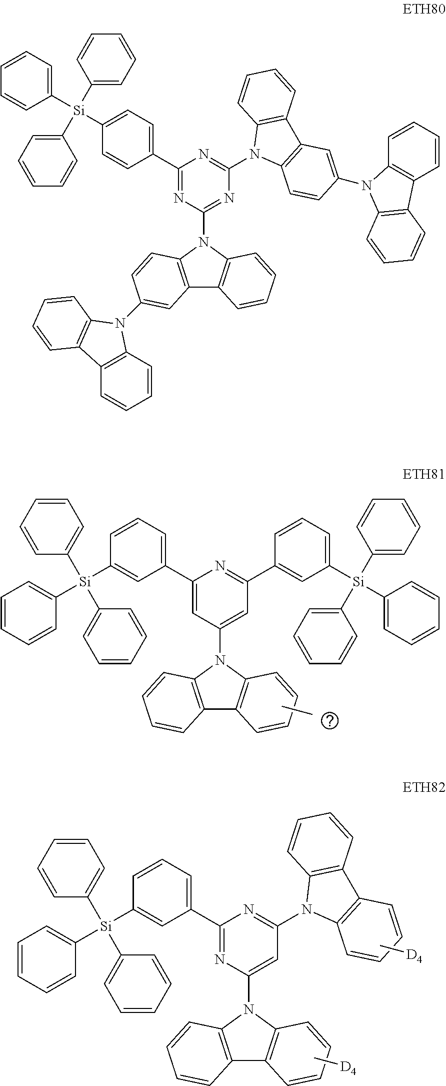

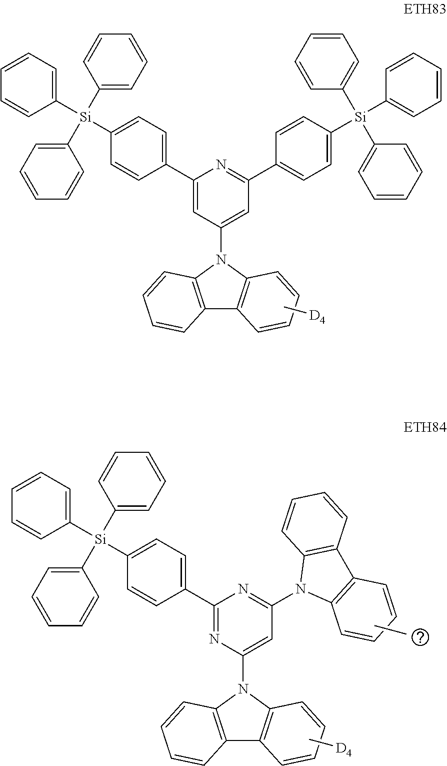

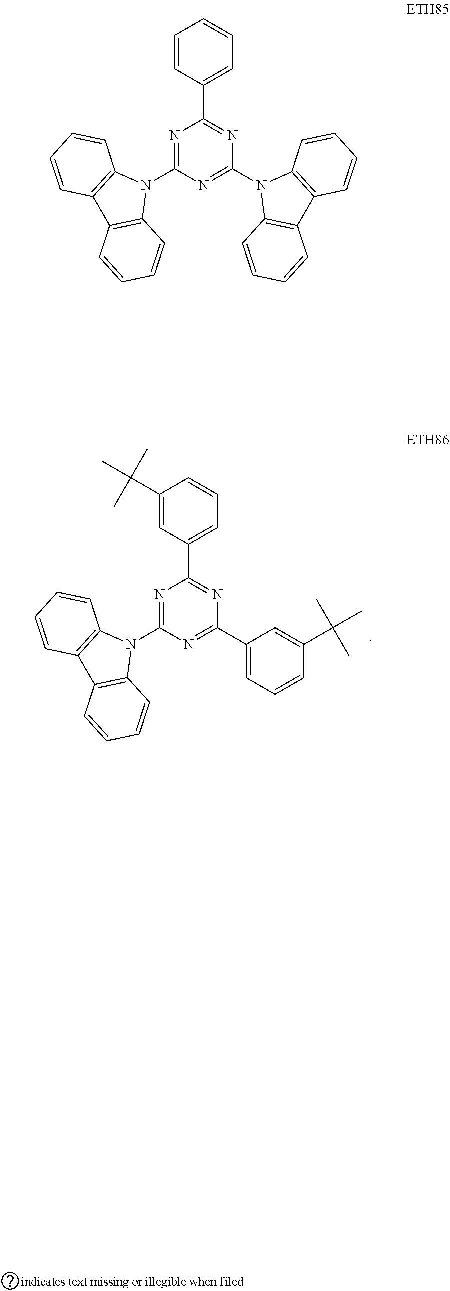 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

An exciplex may be formed by the hole transporting host and the electron transporting host. In some embodiments, a triplet energy level of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy level (Ti) of the exciplex formed by the hole transporting host and the electron transporting host may be about 2.4 eV to about 3.0 eV. In some embodiments, the triplet energy level of the exciplex may be a value smaller than an energy gap of each host material. The exciplex may have a triplet energy of about 3.0 eV or less that is an energy gap between the hole transporting host and the electron transporting host.

In an embodiment, the emission layer EML may include a fourth compound in addition to the first compound to the third compound as described above. The fourth compound may be used as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting element ED of an embodiment may include, as the fourth compound, a compound represented by Formula D-1 below:

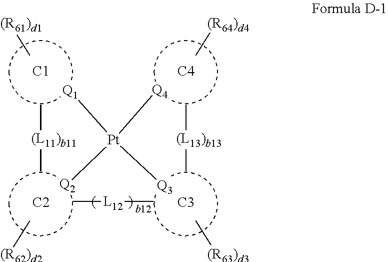

In Formula D-1, Q₁ to 04 may be each independently C or N.

In Formula D-1, C1 to C4 may be each independently a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may be each independently a direct linkage, *—O—*, *—S—*,

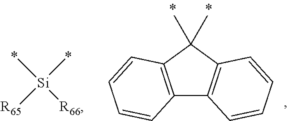

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “—*—” means a site linked to C1 to C4.

In Formula D-1, b1 to b3 may be each independently 0 or 1. If b1 is 0, C1 and C2 may not be linked to each other. If b2 is 0, C2 and C3 may not be linked to each other. If b3 is 0, C3 and C4 may not be linked to each other.

In Formula D-1, R₆₁ to R₆₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. R₆₁ to R₆₆ may be each independently a substituted or unsubstituted methyl group, or a substituted or unsubstituted t-butyl group.

In Formula D-1, d1 to d4 are each independently an integer of 0 to 4. In Formula D-1, if each of d1 to d4 is 0, the fourth compound may not be substituted with each of R₆₁ to R₆₄. In embodiments where each of d1 to d4 is 4 and R₆₁'s to R₆₄'s are each hydrogen atoms may be the same as embodiments where each of d1 to d4 is 0. When each of d1 to d4 is an integer of 2 or more, a plurality of R₆₁'s to R₆₄'s may each be the same or at least one among the plurality of R₆₁'s to R₆₄'s may be different from the others.

In Formula D-1, C1 to C4 may be each independently a substituted or unsubstituted hydrocarbon ring or a substituted or unsubstituted heterocycle represented by any one among C-1 to C-4 below:

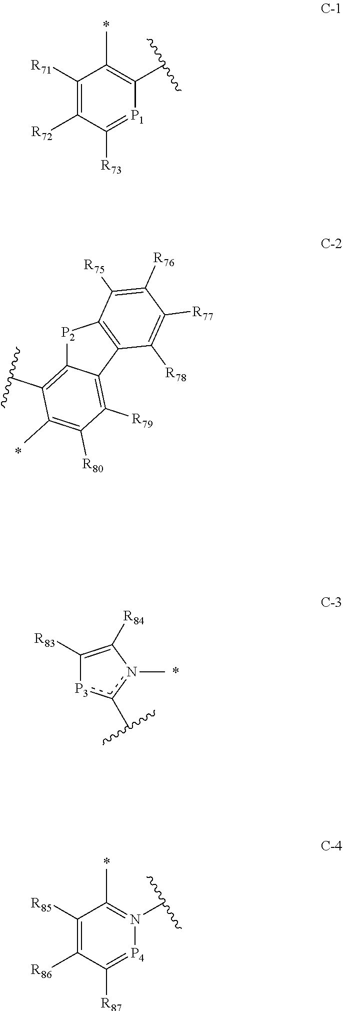

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may be each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In some embodiments, in C-1 to C-4,

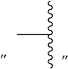

corresponds to a part linked to Pt that is a central metal atom, and “—*” corresponds to a part linked to a neighboring cyclic group (C1 to C4) or a linker (L₁₁ to L₁₃).

The emission layer EML of an embodiment may include the first compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby resulting in the emission of light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In an embodiment, the fourth compound may be a sensitizer. The fourth compound included in the emission layer EML in the light emitting element ED of an embodiment may serve as a sensitizer to deliver energy from the host to the first compound that is a light emitting dopant. In some embodiments, the fourth compound serving as an auxiliary dopant accelerates energy delivery to the first compound that is a light emitting dopant, thereby increasing the emission ratio of the first compound. Therefore, the emission layer EML of an embodiment may improve luminous efficiency. In some embodiments, when the energy delivery to the first compound is increased, an exciton formed in the emission layer EML is not accumulated inside the emission layer EML and emits light rapidly, and thus deterioration of the device may be reduced. Therefore, the service life of the light emitting element ED of an embodiment may increase.

The light emitting element ED of an embodiment may include all of the first compound, the second compound, the third compound, and the fourth compound, and the emission layer EML may include the combination of two host materials and two dopant materials. In the light emitting element ED of an embodiment, the emission layer EML may concurrently (e.g., simultaneously) include the second compound and the third compound, which are two different hosts, the first compound that emits a delayed fluorescence, and the fourth compound including an organometallic complex, thereby exhibiting excellent luminous efficiency characteristics.

In an embodiment, the fourth compound represented by Formula D-1 may be represented by at least one among the compounds represented by Compound Group 4 below. The emission layer EML may include at least one among the compounds represented by Compound Group 4 as a sensitizer material.

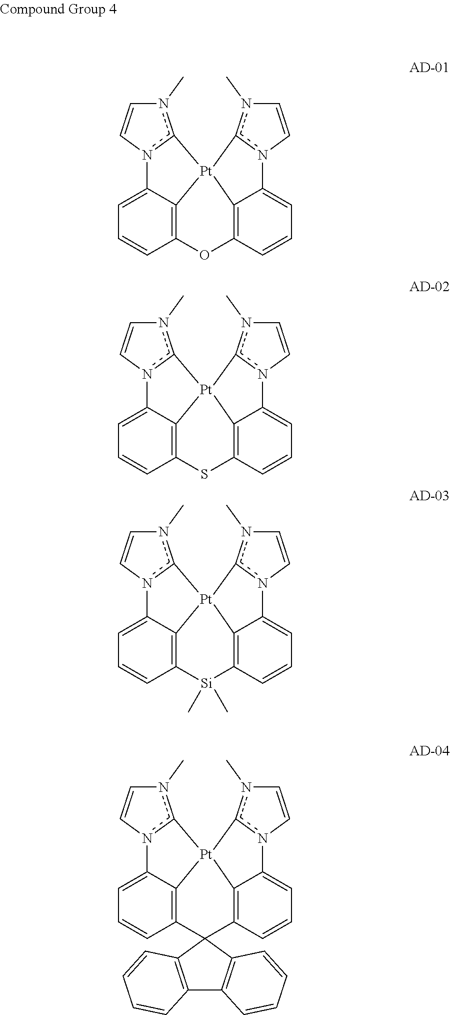

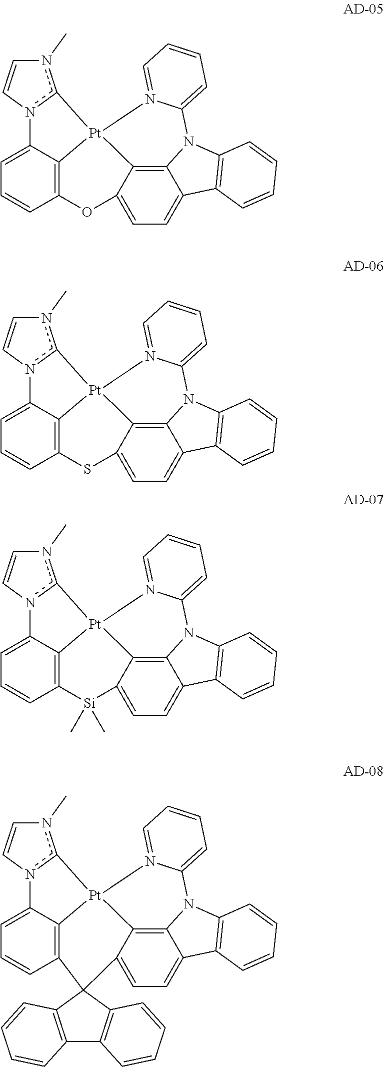

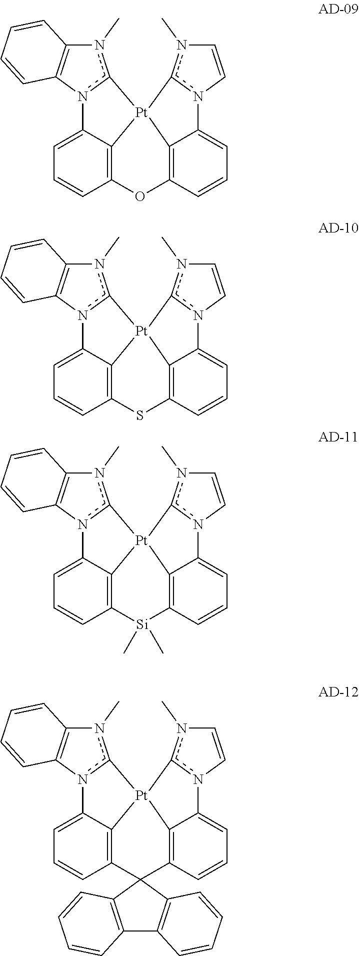

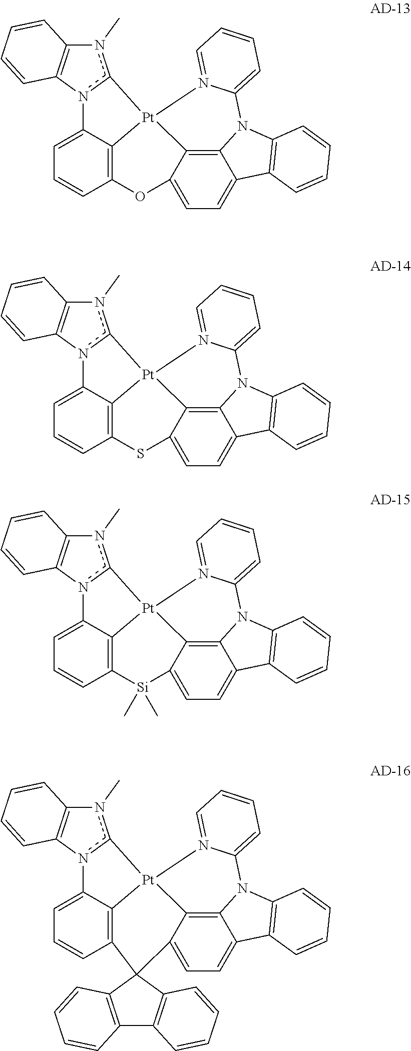

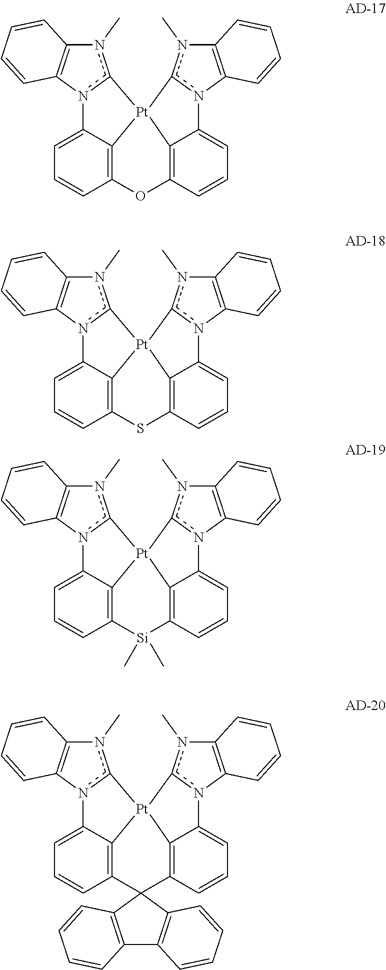

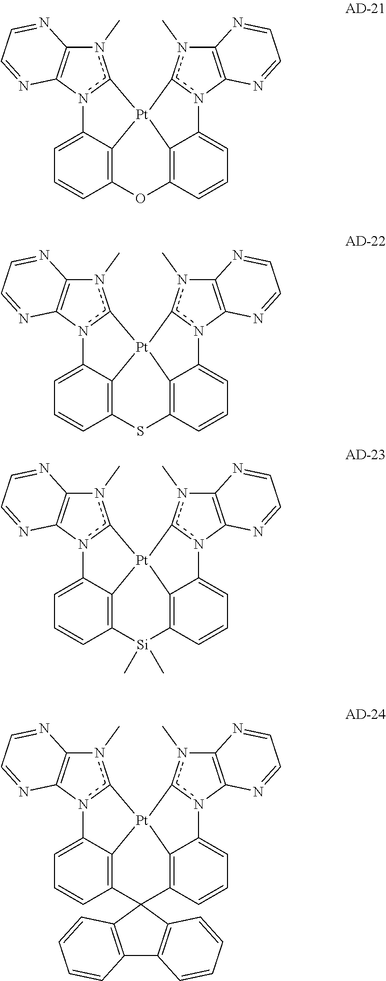

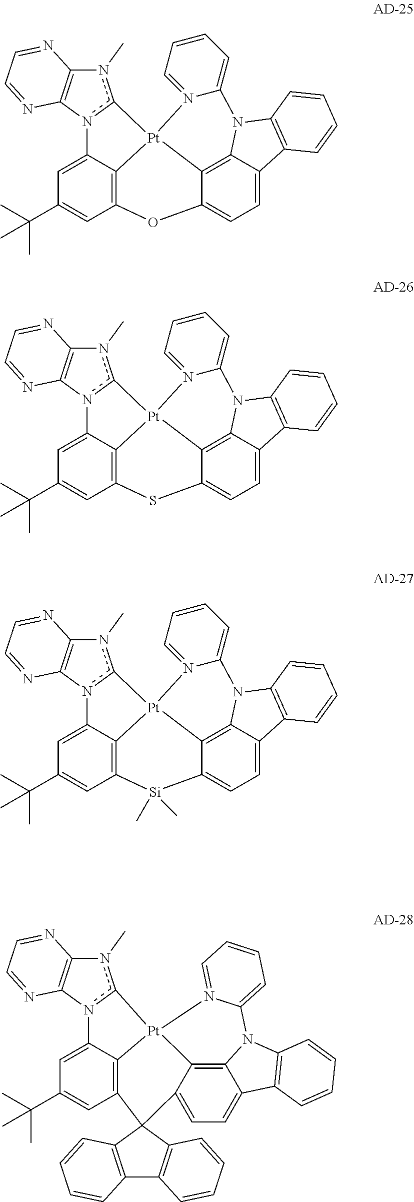

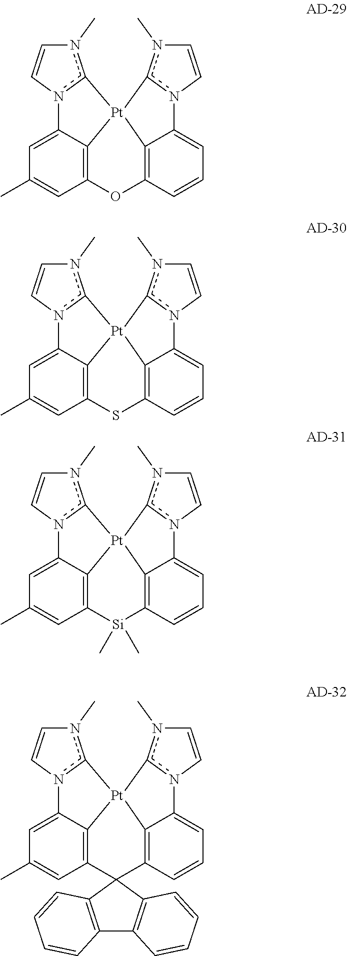

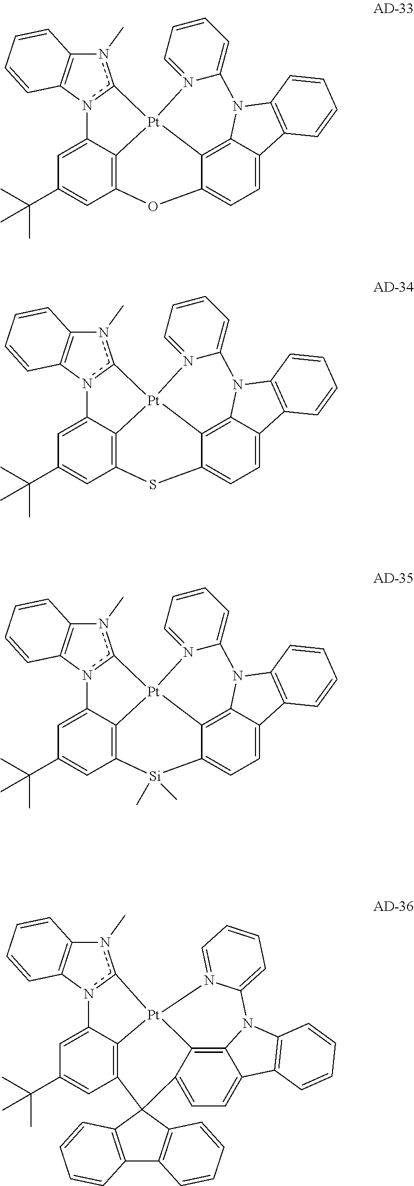

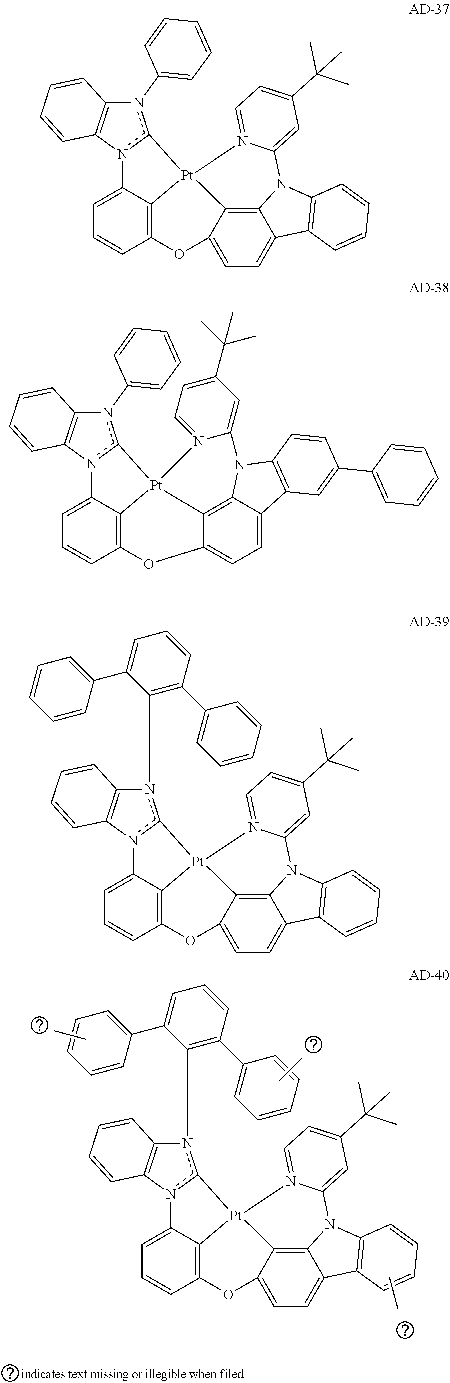

In the embodiment compounds presented in Compound Group 4, “D” means a deuterium atom.

When the emission layer EML in the light emitting element ED of an embodiment includes all of the first compound, the second compound, and the third compound, with respect to the total weight of the first compound, the second compound, and the third compound, the content of the first compound may be about 0.1 wt % to about 5 wt %. However, embodiments of the present disclosure are not limited thereto. When the content of the first compound satisfy the above-described proportion, the energy transfer from the second compound and the third compound to the first compound may increase, and thus the luminous efficiency and device service life may increase.

The contents of the second compound and the third compound in the emission layer EML may be the remainder excluding the weight of the first compound. For example, the contents of the second compound and the third compound in the emission layer EML may be about 65 wt % to about 95 wt % with respect to the total weight of 100 wt % the first compound, the second compound, and the third compound.

In the total weight of the second compound and the third compound, the weight ratio of the second compound and the third compound may be about 3:7 to about 7:3.

When the contents of the second compound and the third compound satisfy the above-described ratio, a charge balance characteristic in the emission layer EML are improved, and thus the luminous efficiency and device service life may increase. When the contents of the second compound and the third compound deviate from the above-described ratio range, a charge balance in the emission layer EML is broken, and thus the luminous efficiency may be reduced and the device may be easily deteriorated.

When the emission layer EML includes the fourth compound, the content of the fourth compound in the emission layer EML may be about 4 wt % to about 30 wt % with respect to the total weight of the first compound, the second compound, the third compound, and the fourth compound. However, embodiments of the present disclosure are not limited thereto. When the content of the fourth compound satisfies the above-described content, the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content ratio range, excellent luminous efficiency and long service life may be achieved.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting elements ED of embodiments, shown in FIG. 3 to FIG. 7, the emission layer EML may include the polycyclic compound of an embodiment as a dopant. The light emitting elements ED of embodiments, shown in FIG. 3 to FIG. 7, the emission layer EML may include the first compound, which is the polycyclic compound of an embodiment, and may include at least one among the second compound represented by Formula HT-1 and the third compound represented by Formula ET-1. In the light emitting elements ED of embodiments, shown in FIG. 3 to FIG. 7, the emission layer EML may include the first compound, which is the polycyclic compound of an embodiment, and may include at least one among the second compound represented by Formula HT-1, the third compound represented by Formula ET-1, and the fourth compound represented by Formula D-1.

In the light emitting element ED of an embodiment, the emission layer EML may include an anthracene derivative, a pyrene derivative, a fluoranthene derivative, a chrysene derivative, a dihydrobenzanthracene derivative, and/or a triphenylene derivative. In some embodiments, the emission layer EML may include the anthracene derivative and/or the pyrene derivative.

In each light emitting element ED of embodiments illustrated in FIGS. 3-7, the emission layer EML may further include any suitable host and dopant used in the art besides the above-described host and dopant, and for example the emission layer EML may include a compound represented by Formula E-1 below. The compound represented by Formula E-1 below may be used as a fluorescent host material.

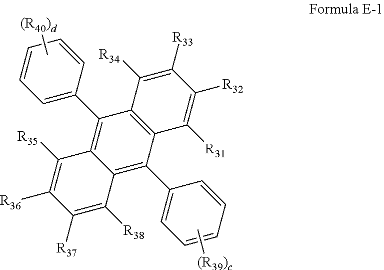

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may be each independently an integer of 0 to 5.

Formula E-1 may be represented by any one among Compound E1 to Compound E19 below:

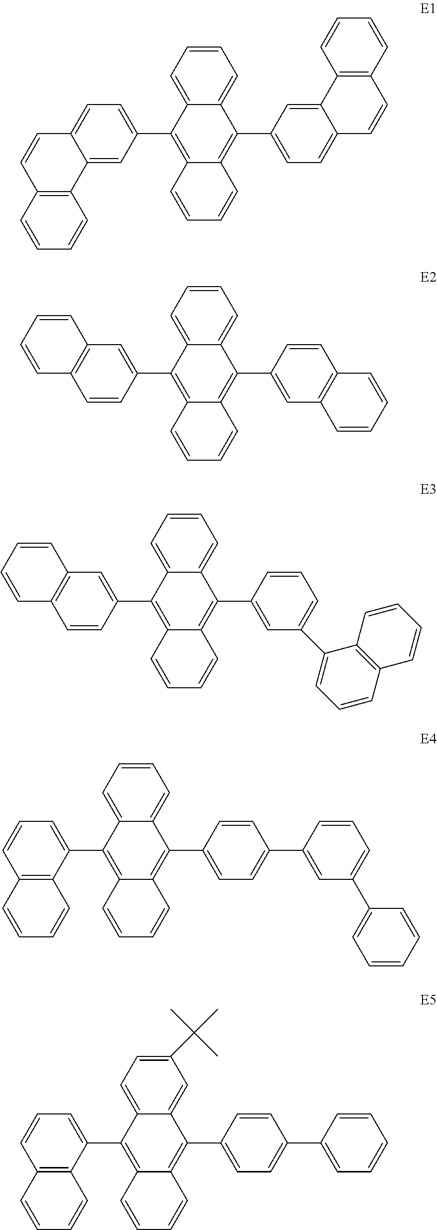

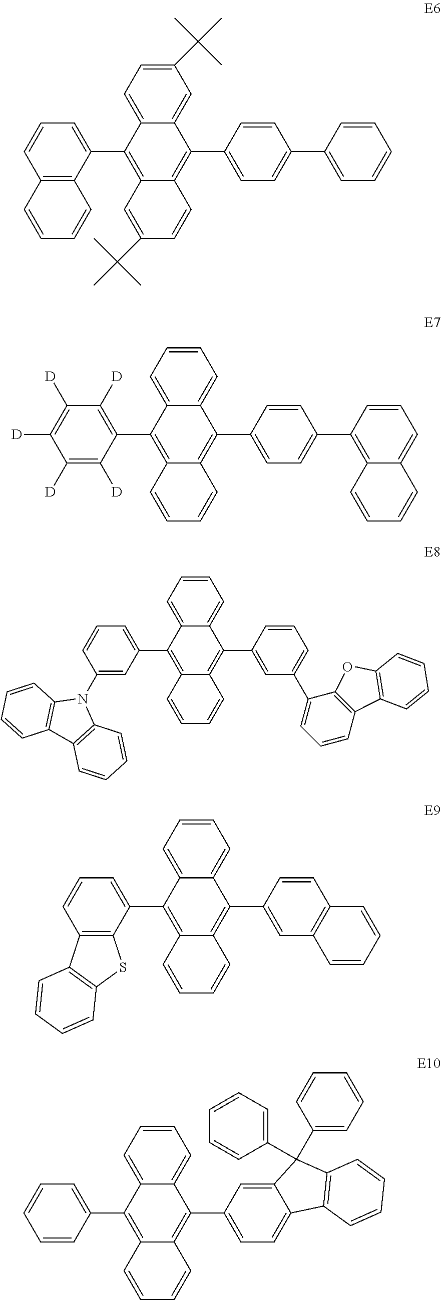

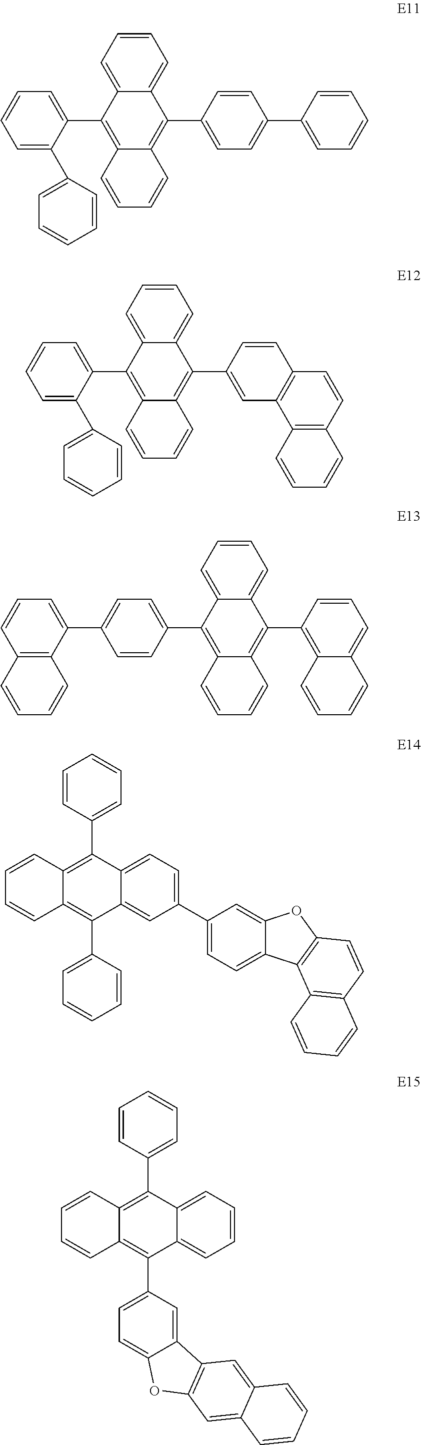

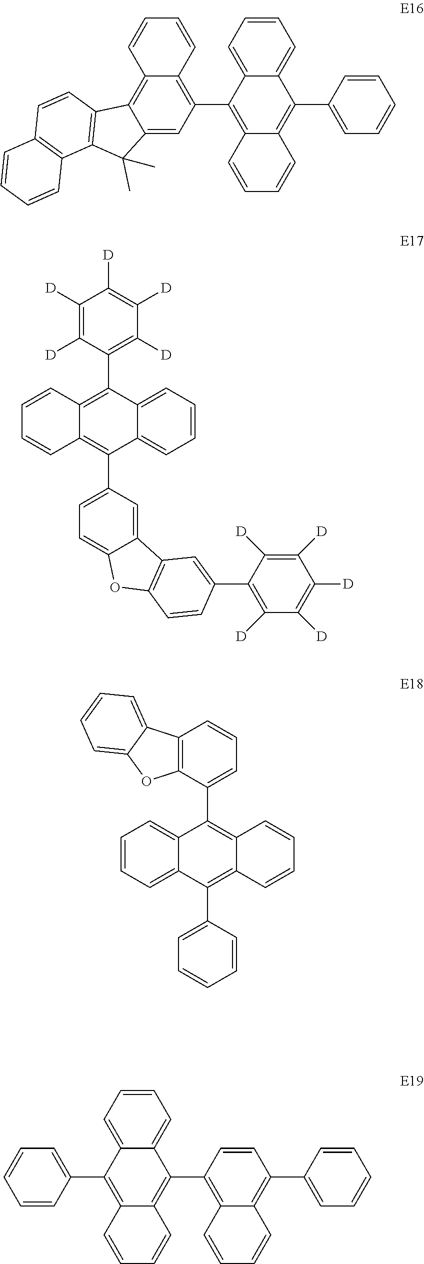

In an embodiment, the emission layer EML may include a compound represented by Formula E-2a or Formula E-2b below. The compound represented by Formula E-2a or Formula E-2b below may be used as a phosphorescent host material.

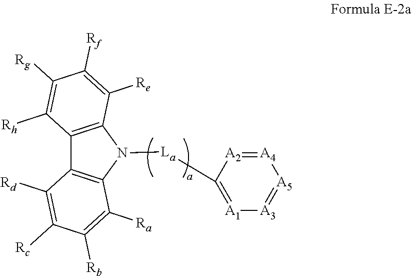

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may be each independently a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, etc., as a ring-forming atom.

In some embodiments, in Formula E-2a, two or three selected from among A₁ to A₅ may be N, and the rest may be CRᵢ.

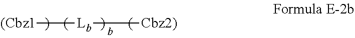

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2 below. However, the compounds listed in Compound Group E-2 below are examples, and the compound represented by Formula E-2a or Formula E-2b is not limited to those represented in Compound Group E-2 below.

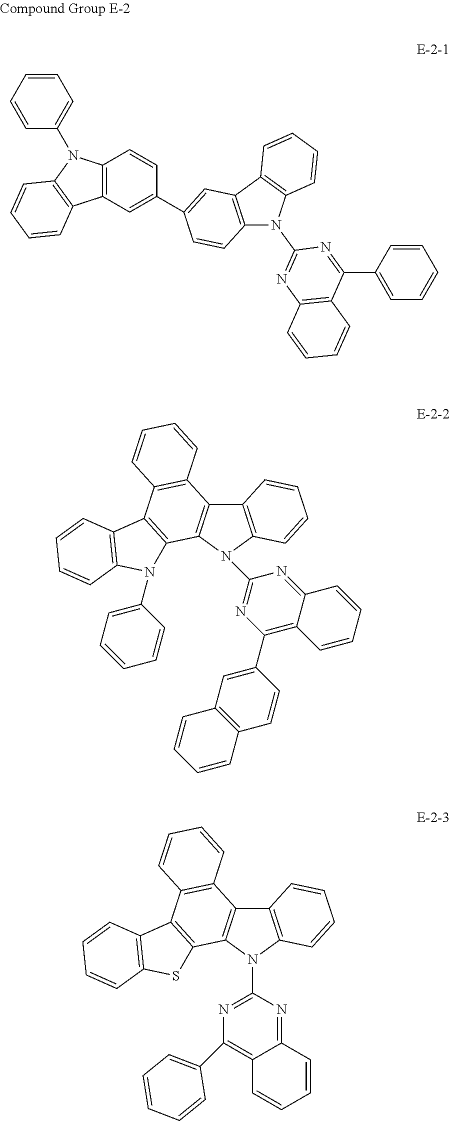 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

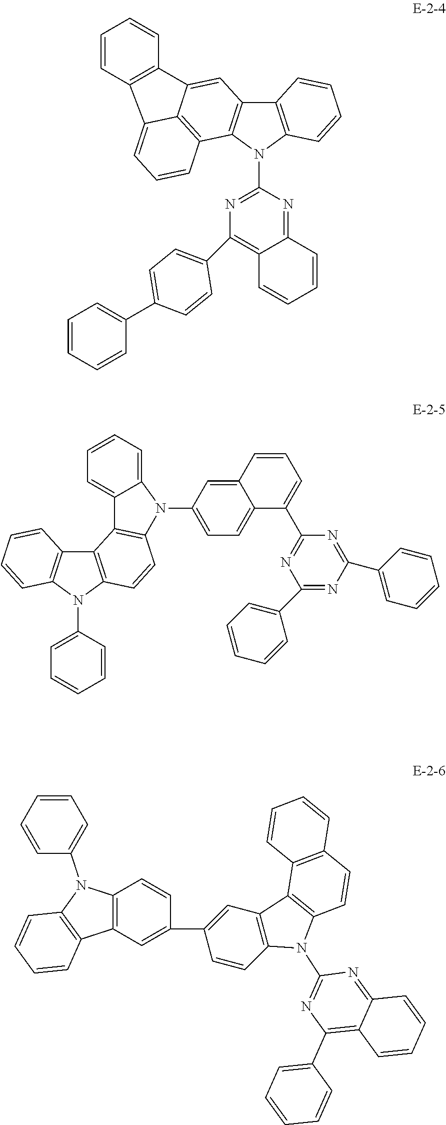 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

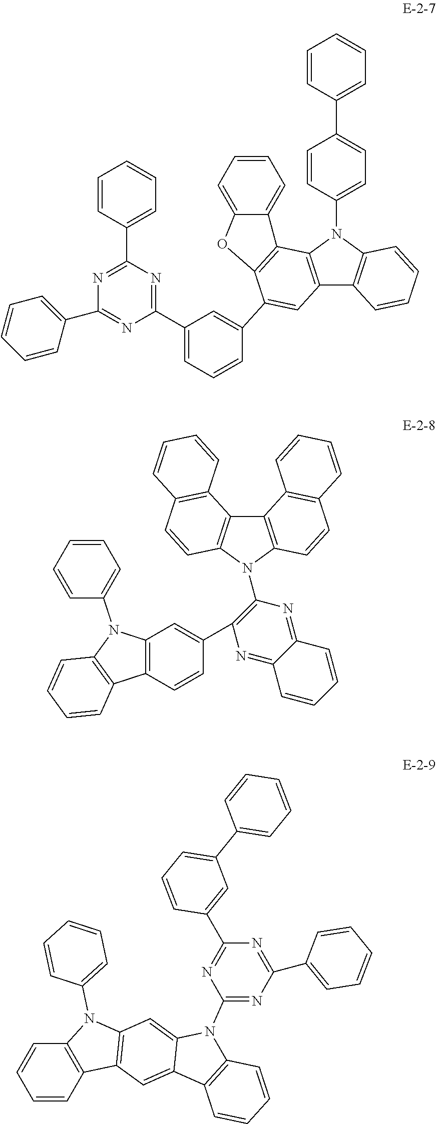 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

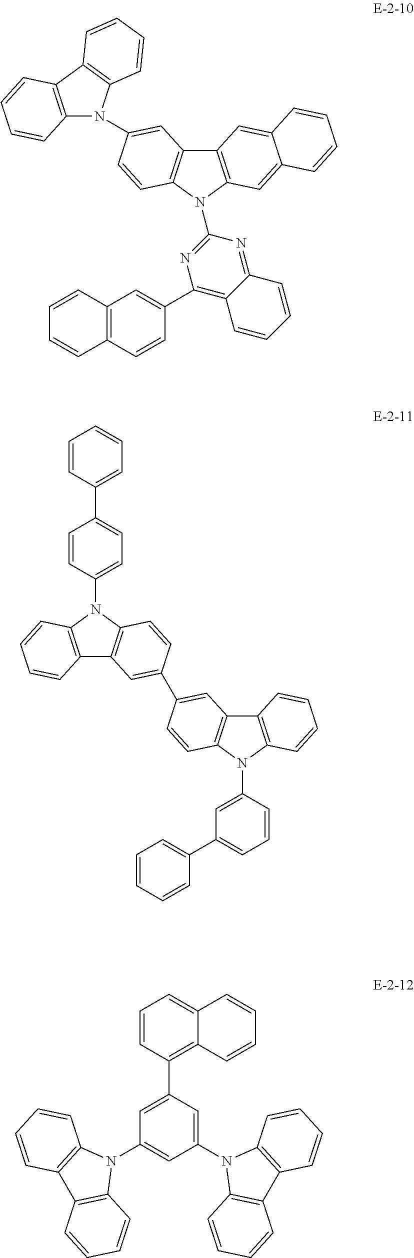 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

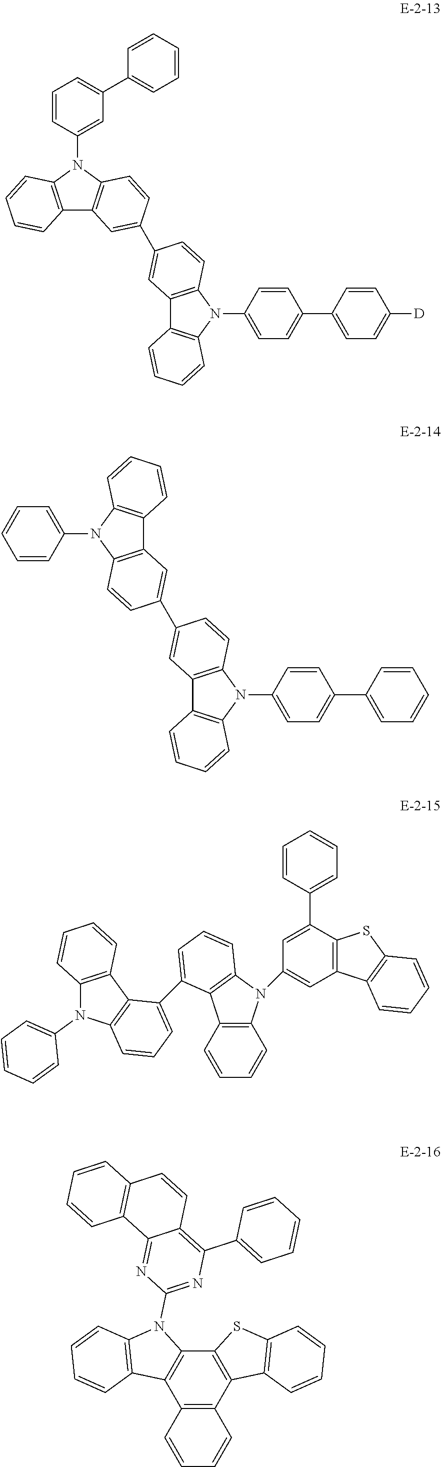 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

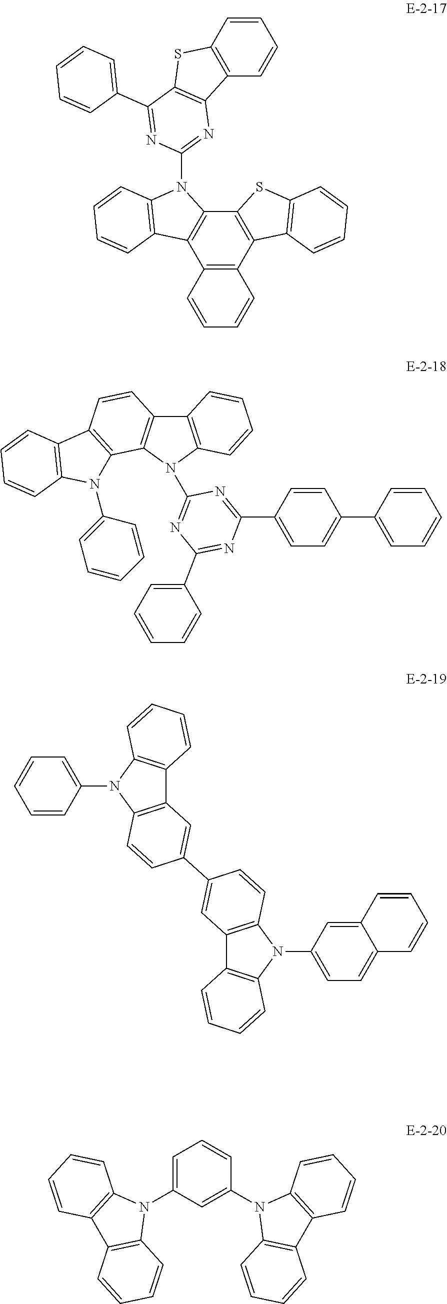 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

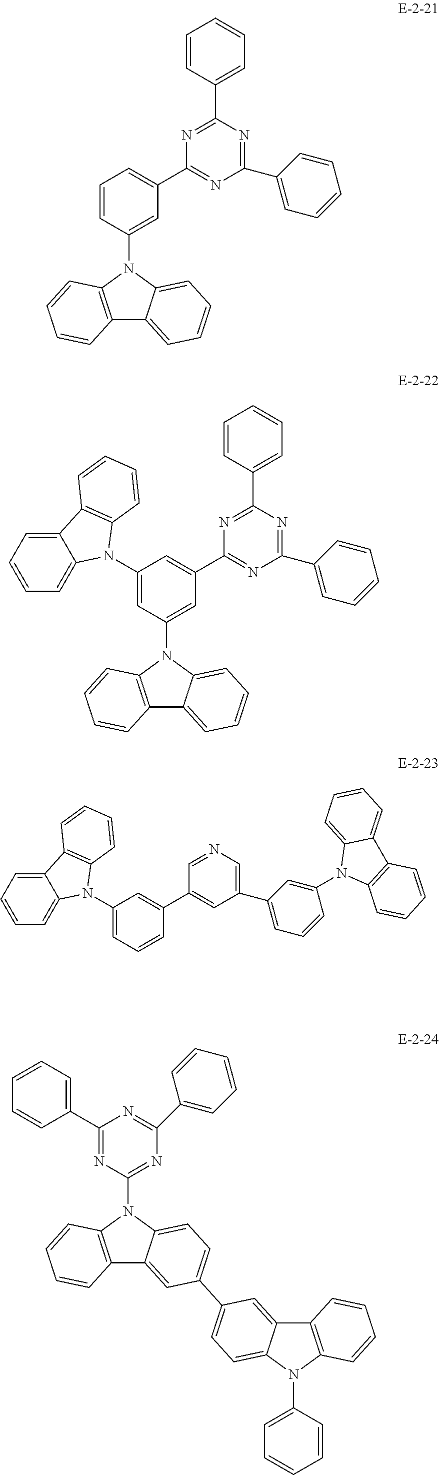 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include any suitable material generally used in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto, for example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

The emission layer EML may include the compound represented by Formula M-a below. The compound represented by Formula M-a below may be used as a phosphorescent dopant material.

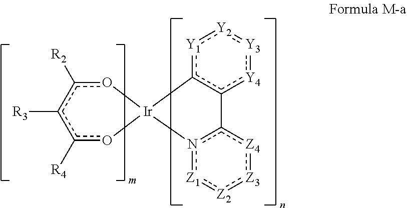

In Formula M-a above, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescent dopant.

The compound represented by Formula M-a may be represented by any one among Compound M-a1 to Compound M-a25 below. However, Compounds M-a1 to M-a25 below are examples, and the compound represented by Formula M-a is not limited to those represented by Compounds M-a1 to M-a25 below.

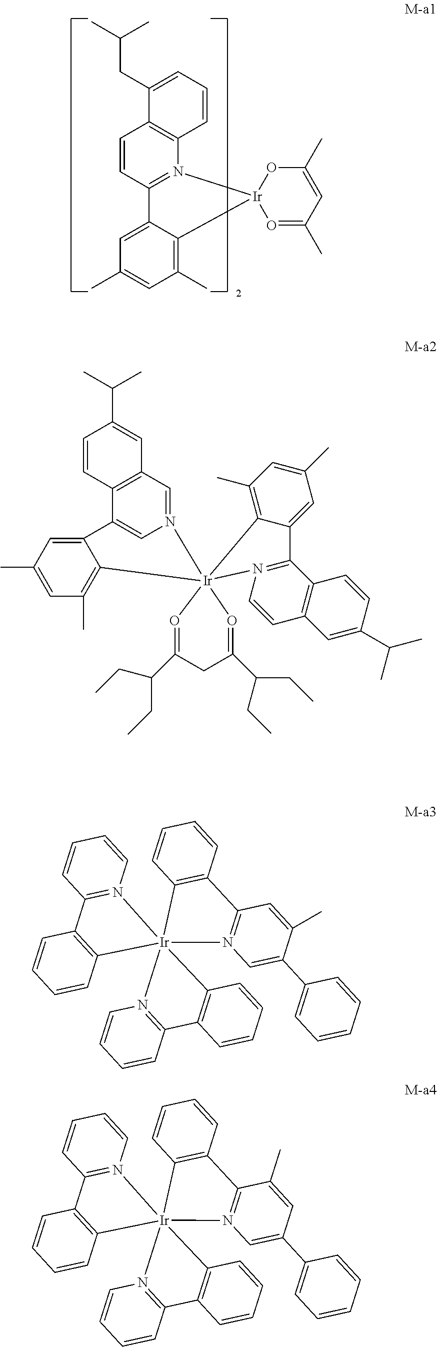

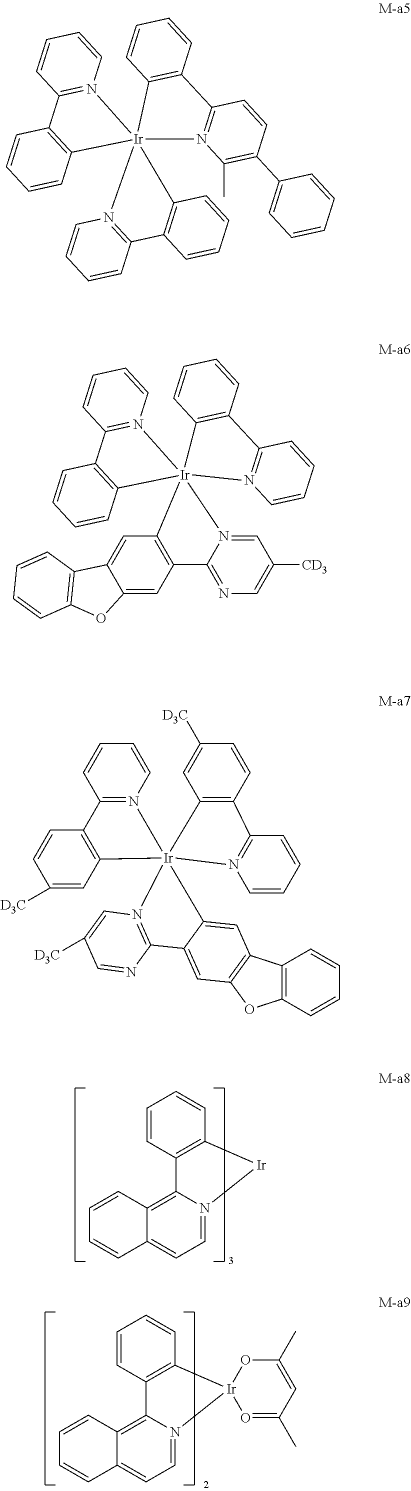

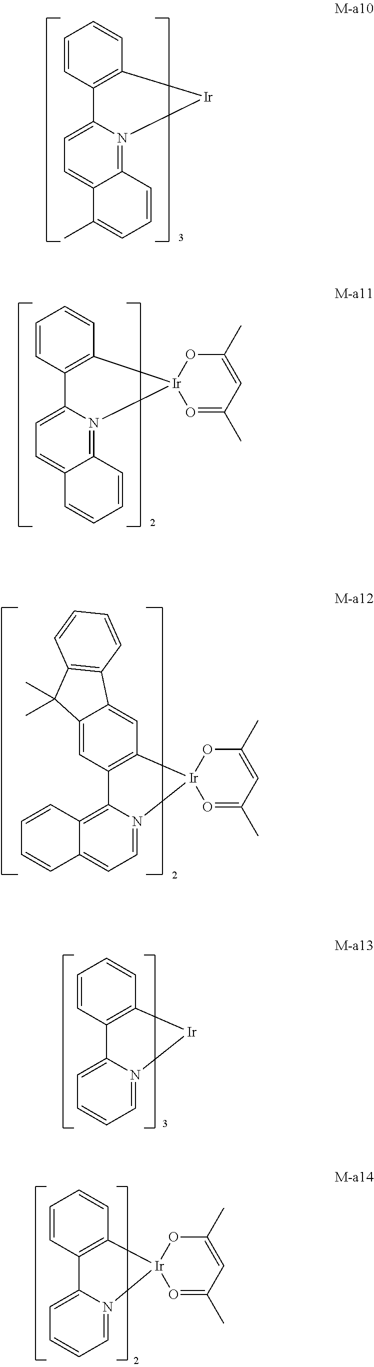

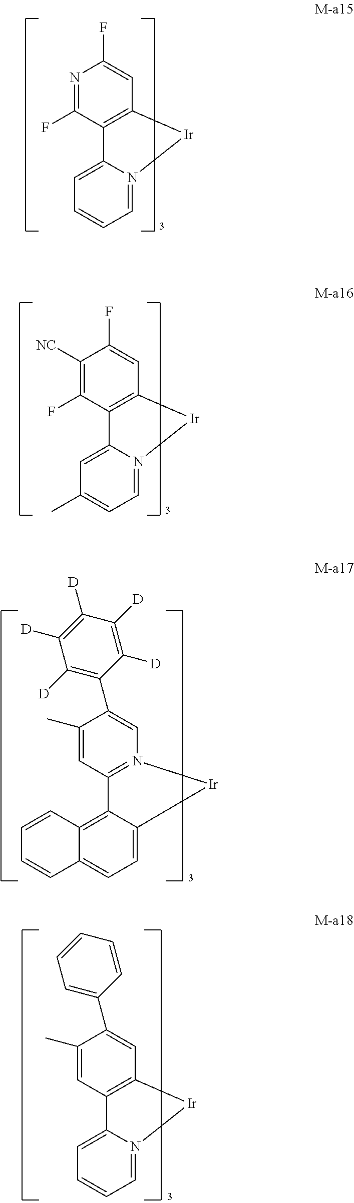

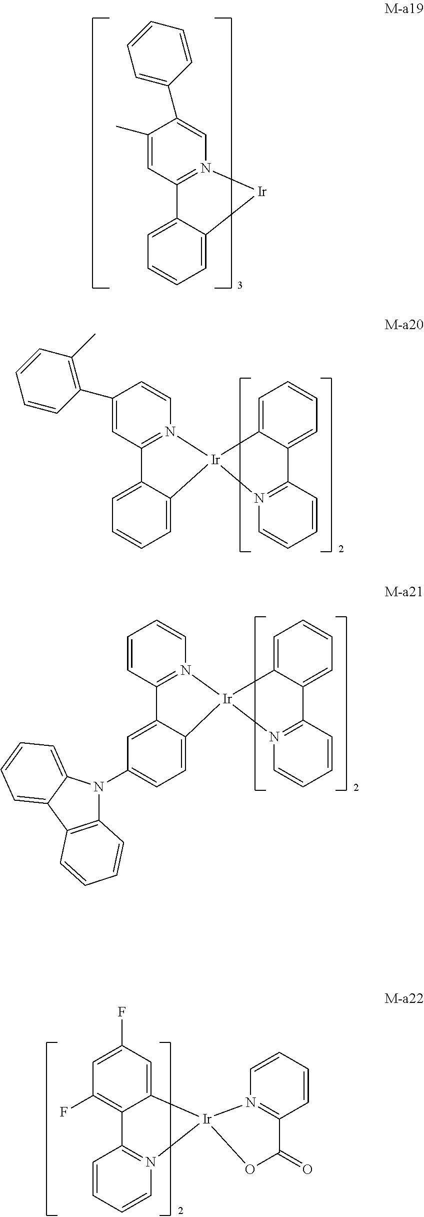

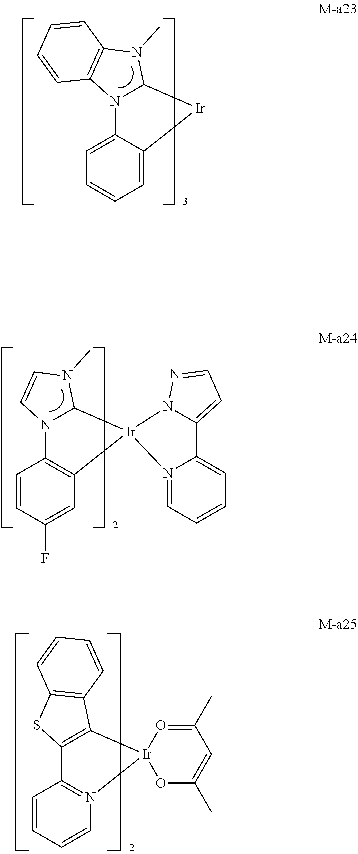

The emission layer EML may include a compound represented by any one among Formula F-a to Formula F-c below. The compound represented by Formula F-a to Formula F-c below may be used as a fluorescence dopant material.

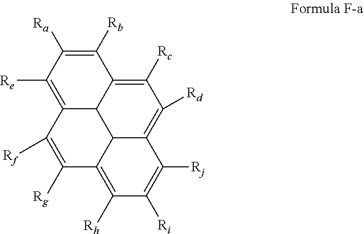

In Formula F-a above, two selected from among Rₐ to Rⱼ may each independently be substituted with *—NAr₁Ar₂. The others, which are not substituted with *—NAr₁Ar₂, among Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O and/or S as a ring-forming atom.

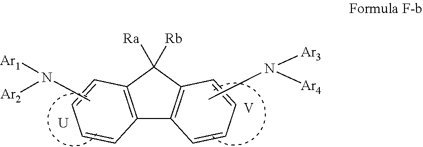

In Formula F-b above, Rₐ and Rb may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may be each independently a substituted or unsubstituted aryl group having 6 to 30 ring-forming carbon atoms, or a substituted or unsubstituted heteroaryl group having 2 to ring-forming carbon atoms.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may be each independently 0 or 1. For example, in Formula F-b, it means that when the number of U or V is 1, one ring constitutes a fused ring at a portion indicated by U or V, and when the number of U or V is 0, a ring indicated by U or V does not exist. In some embodiments, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

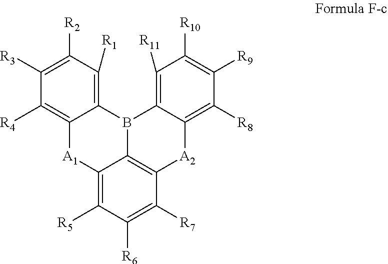

In Formula F-c, A₁ and A₂ may be each independently O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, when A₁ and A₂ are each independently NRₘ, A₁ may be bonded to R₄ or R₅ to form a ring. In some embodiments, A₂ may be bonded to R₇ or R₅ to form a ring.

In an embodiment, the emission layer EML may further include, as a dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and/or a derivative thereof (e.g., 2,5,8,11-tetra-t-butylperylene (TBP)), pyrene and/or a derivative thereof (e.g., 1,1-dipyrene, 1,4-dipyrenylbenzene, 1,4-bis(N,N-diphenylamino)pyrene), etc.

The emission layer EML may further include any suitable phosphorescence dopant material used in the art. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. In some embodiments, iridium(III) bis(4,6-difluorophenylpyridinato-N, C2′)picolinate (Flrpic), bis(2,4-difluorophenylpyridinato)-tetrakis(1-pyrazolyl)borate iridium(III) (Flr6), and/or platinum octaethyl porphyrin (PtOEP) may be used as a phosphorescent dopant. However, embodiments of the present disclosure are not limited thereto.

The emission layer EML may include a quantum dot material. The core of the quantum dot may be selected from a Group II-VI compound, a Group Ill-VI compound, a Group 1-Ill-IV compound, a Group Ill-V compound, a Group Ill-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂, and a mixture thereof, and/or a quaternary compound such as AgInGaS₂ and/or CulnGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GalnPSb, InAlNP, InAlNAs, InAlNSb, InAlPAs, InAlPSb, and a mixture thereof. In some embodiments, the Group Ill-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, and/or the quaternary compound may be present in a particle with a uniform or non-uniform concentration distribution. In some embodiments, the formulae mean the types (or kinds) of elements included in the compounds, and the elemental ratio in the compound may be different. For example, AgInGaS₂ may mean AgInₓGa₁₋ₓS₂ (where x is a real number of 0 to 1).

In some embodiments, the quantum dot may have a single structure or a double structure of core-shell in which the concentration of each element included in the quantum dot is uniform (e.g., substantially uniform). For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or a plurality of layers. An interface between the core and the shell may have a concentration gradient in which the concentration of an element present in the shell becomes lower along a direction towards the center of the core.

In some embodiments, the quantum dot may have the above-described core/shell structure including a core containing nanocrystals and a shell surrounding the core. An example of the shell of the quantum dots may include a metal and/or non-metal oxide, a semiconductor compound, or a combination thereof.

For example, the metal and/or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, etc., but embodiments of the present disclosure are not limited thereto.

Each element included in a polynary compound such as the binary compound, and/or the ternary compound may be present in a particle with a uniform or non-uniform concentration distribution. For example, the formulae mean the types (or kinds) of elements included in the compounds, and the elemental ratio in the compound may be different.

The quantum dot may have a full width of half maximum (FWHM) of a light emitting wavelength spectrum of about 45 nm or less, about 40 nm or less, or, for example, about 30 nm or less, and color purity and/or color reproducibility may be improved in the above range. In some embodiments, light emitted through such quantum dot is emitted in all (e.g., substantially all) directions so that a wide viewing angle may be improved.

and form of the quantum dot is not particularly limited and may be any suitable form generally used in the art, and for example, a quantum dot in a form of spherical, pyramidal, multi-arm, and/or cubic nanoparticles, nanotubes, nanowires, nanofibers, nanoplate particles, etc. may be used.

As the size of the quantum dot is adjusted or the elemental ratio in the quantum dot compound is adjusted, it is possible to control the energy band gap, and thus light in various suitable wavelength ranges may be obtained in the quantum dot emission layer. Therefore, the quantum dot as above (using different sizes of quantum dots or different elemental ratios in the quantum dot compound) is used, and thus the light emitting element, which emits light in various suitable wavelengths, may be implemented. In some embodiments, the adjustment of the size of the quantum dot and/or the elemental ratio in the quantum dot compound may be selected to emit red, green, and/or blue light. In some embodiments, the quantum dots may be configured to emit white light by combining various suitable colors of light.

In each of the light emitting elements ED of embodiments illustrated in FIGS. 3-7, the electron transport region ETR is provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but embodiments of the present disclosure are not limited thereto. The electron transport region ETR may have a thickness, for example, from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2 below:

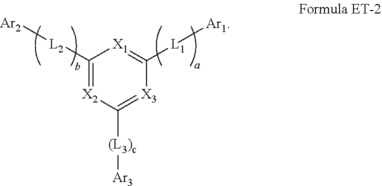

In Formula ET-2, at least one among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may be each independently an integer of 0 to 10. In Formula ET-2, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each independently an integer of 2 or more, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments of the present disclosure are not limited thereto, but the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (Balq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or mixtures thereof.

The electron transport region ETR may include at least one among Compounds ET1 to ET36 below.

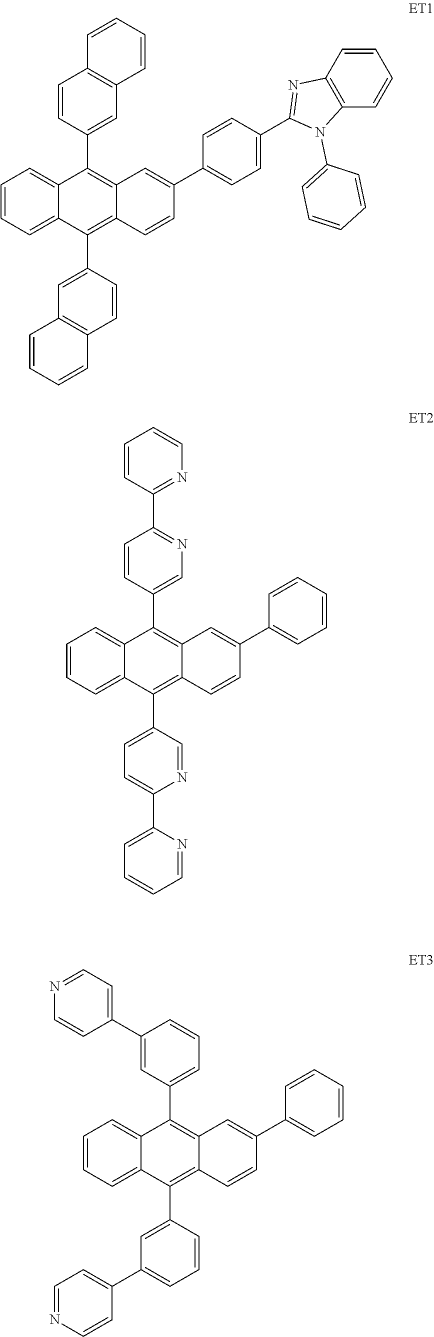

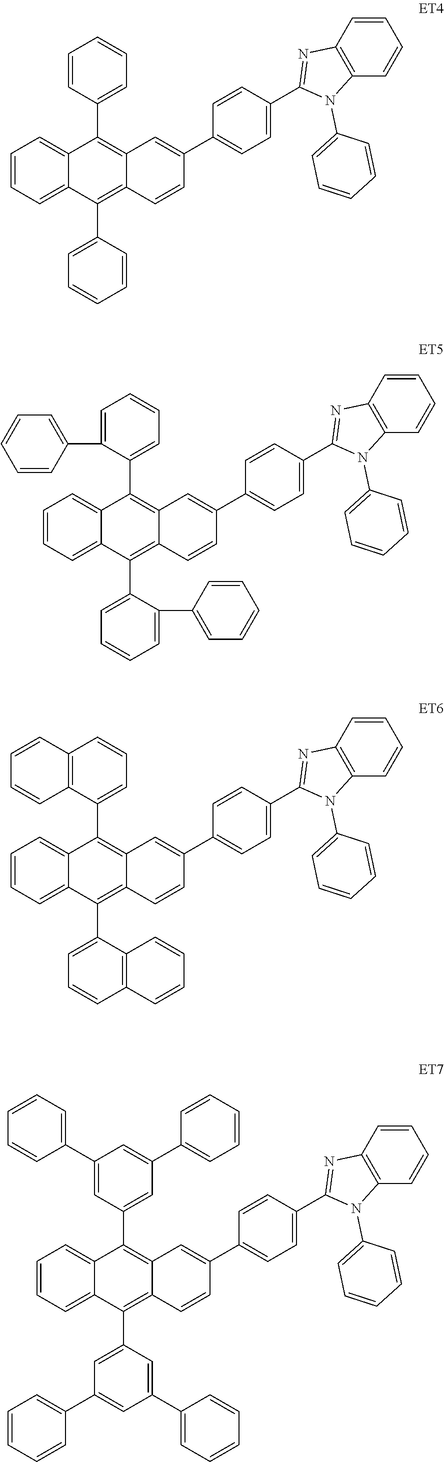 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

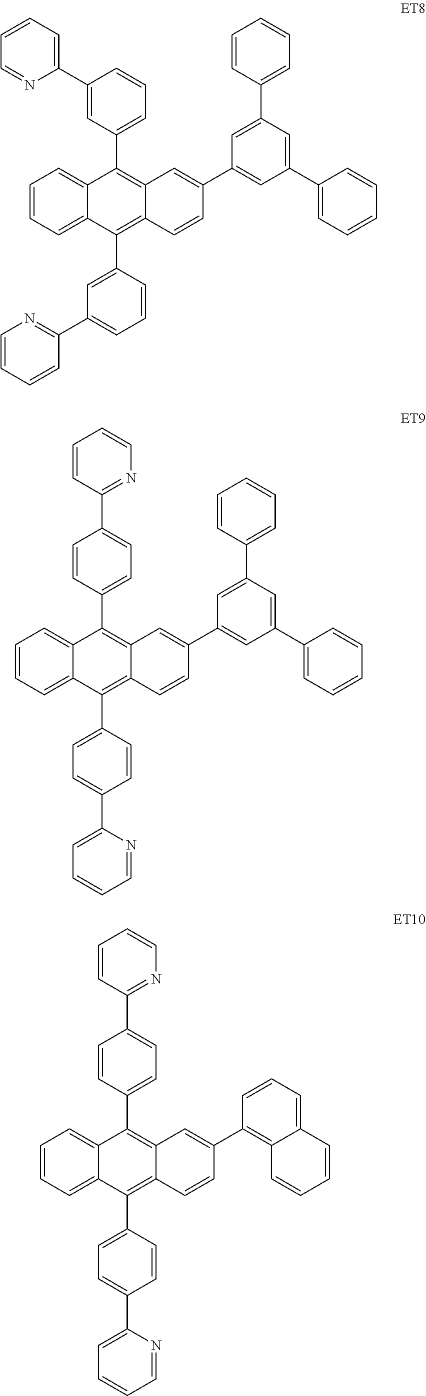

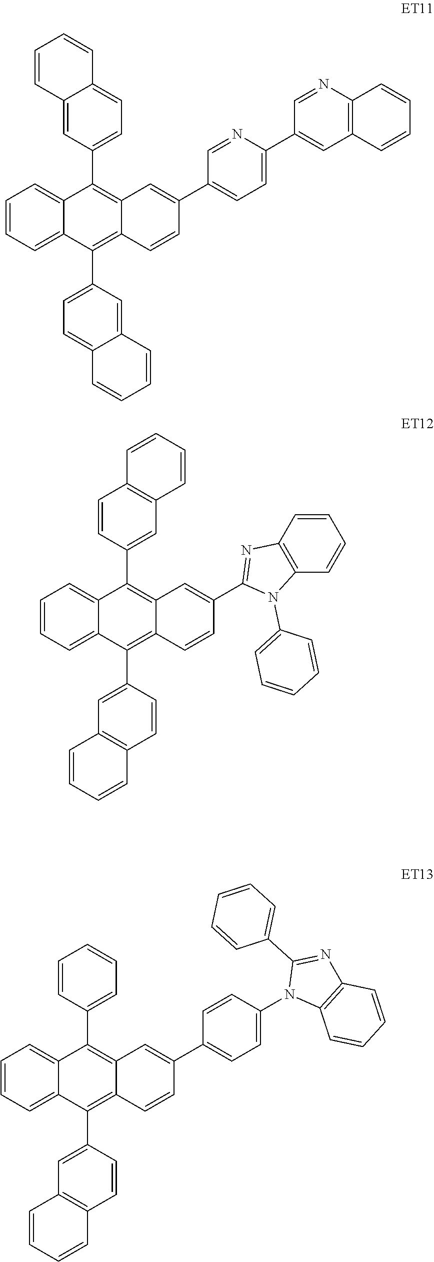 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

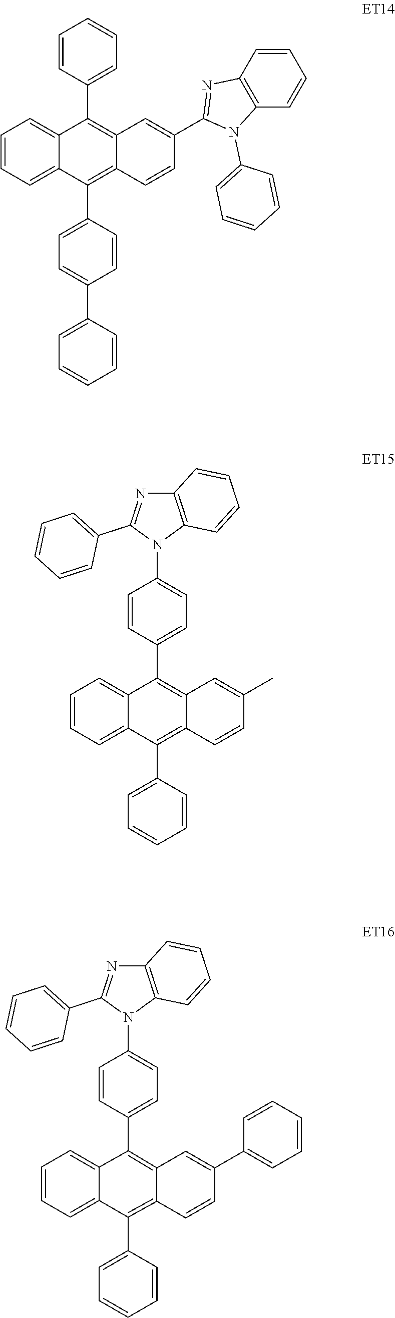 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

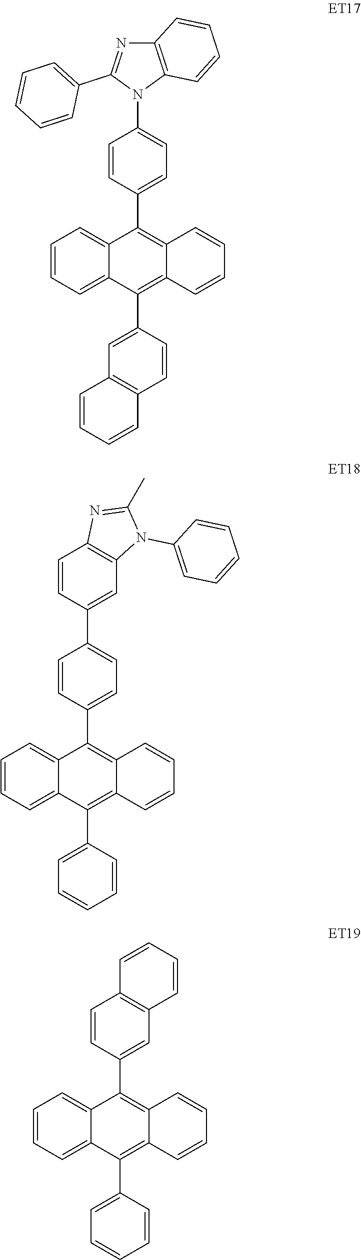

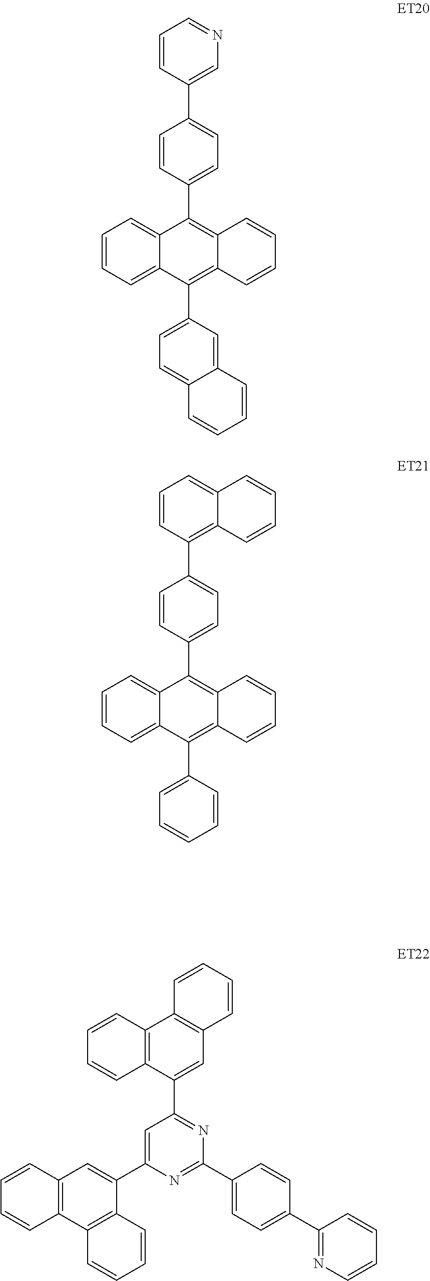

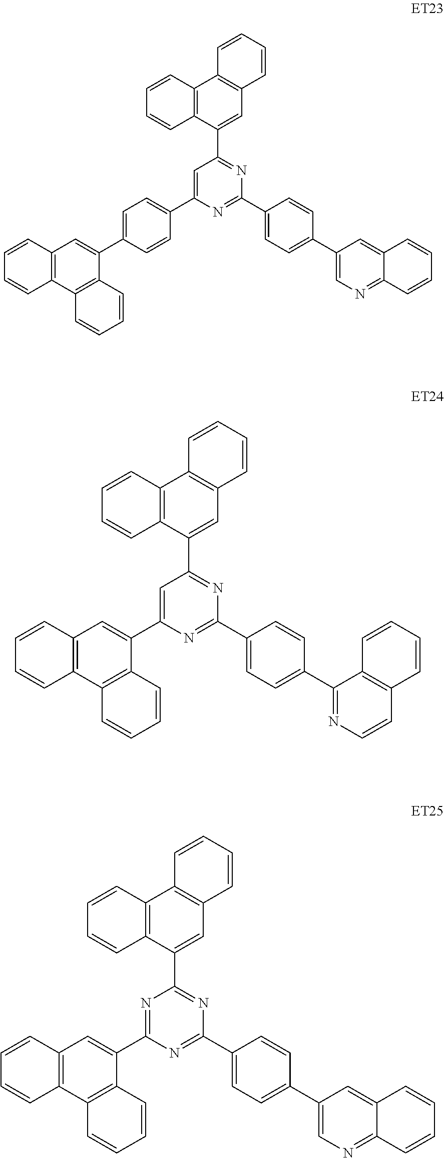 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

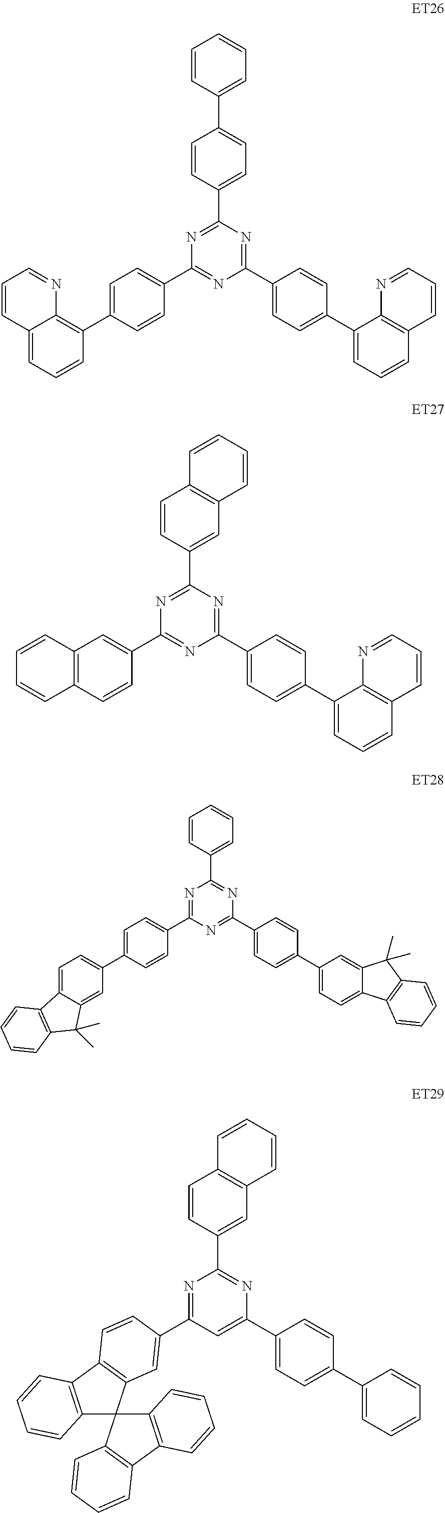 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

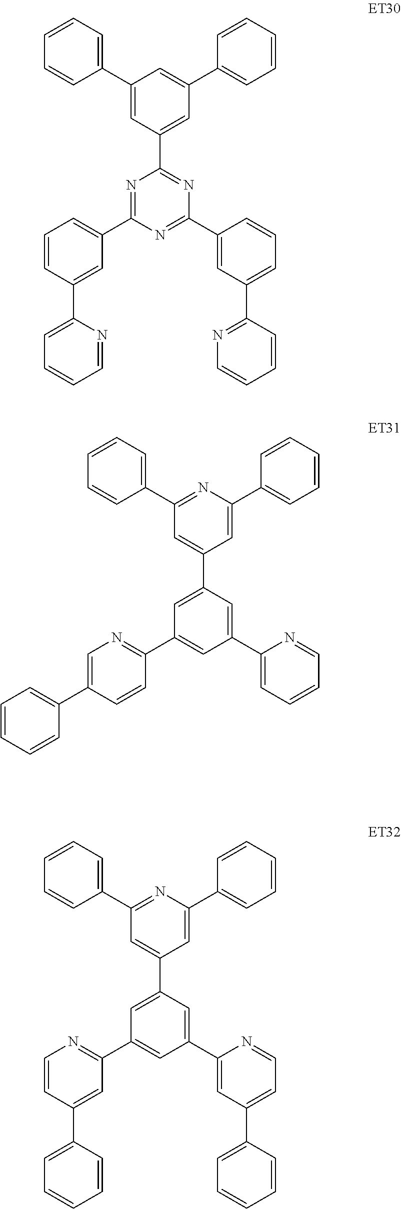 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

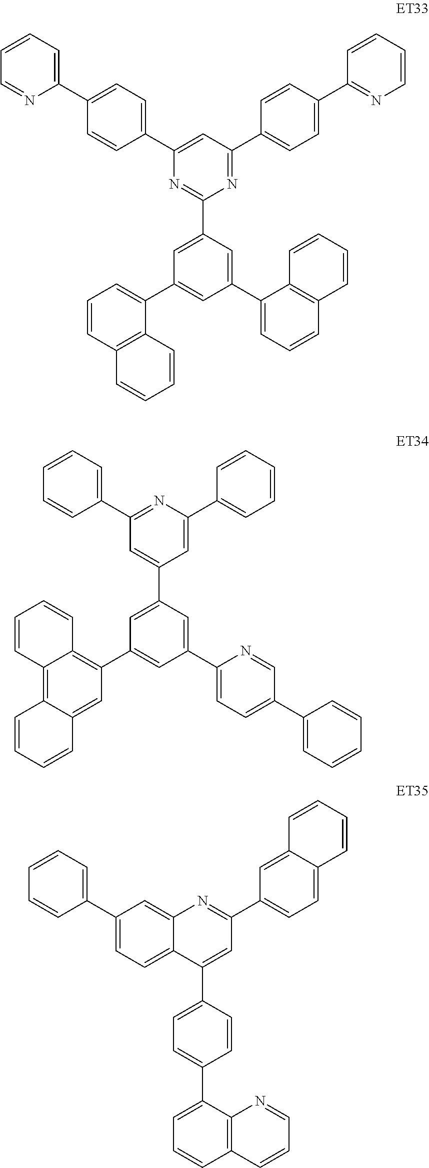

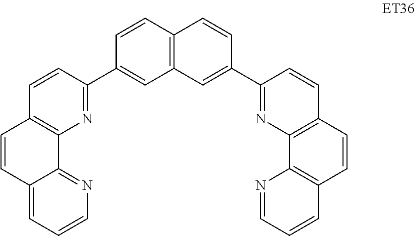 [SMILES: c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI, and/or KI, a lanthanide metal such as Yb, and a co-deposited material of the metal halide and the lanthanide metal. For example, the electron transport region ETR may include KI:Yb, RbI:Yb, LiF:Yb, etc., as a co-deposited material. In some embodiments, the electron transport region ETR may be formed using a metal oxide such as Li₂O and/or BaO, and/or 8-hydroxyl-lithium quinolate (Liq), etc., but embodiments of the present disclosure are not limited thereto. The electron transport region ETR may also be formed of a mixture material of an electron transport material and an insulating organometallic salt (e.g., an electrically insulating organometallic salt). The organometallic salt may be a material having an energy band gap of about 4 eV or more. In some embodiments, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments of the present disclosure are not limited thereto.

The electron transport region ETR may include the above-described compounds of the electron transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, suitable or satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, suitable or satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, and/or a compound or mixture thereof (e.g., AgMg, AgYb, and/or MgYb). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, and/or the like.

In some embodiments, the second electrode EL2 may be connected with an auxiliary electrode. If the second electrode EL2 is connected with the auxiliary electrode, the resistance of the second electrode EL2 may be decreased.

In some embodiments, a capping layer CPL may further be on the second electrode EL2 of the light emitting element ED of an embodiment. The capping layer CPL may include a multilayer or a single layer.

In an embodiment, the capping layer CPL may be an organic layer and/or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq3, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., and/or an epoxy resin, and/or acrylate such as methacrylate. However, embodiments of the present disclosure are not limited thereto, and the capping layer CPL may include at least one among Compounds P₁ to P₅ below:

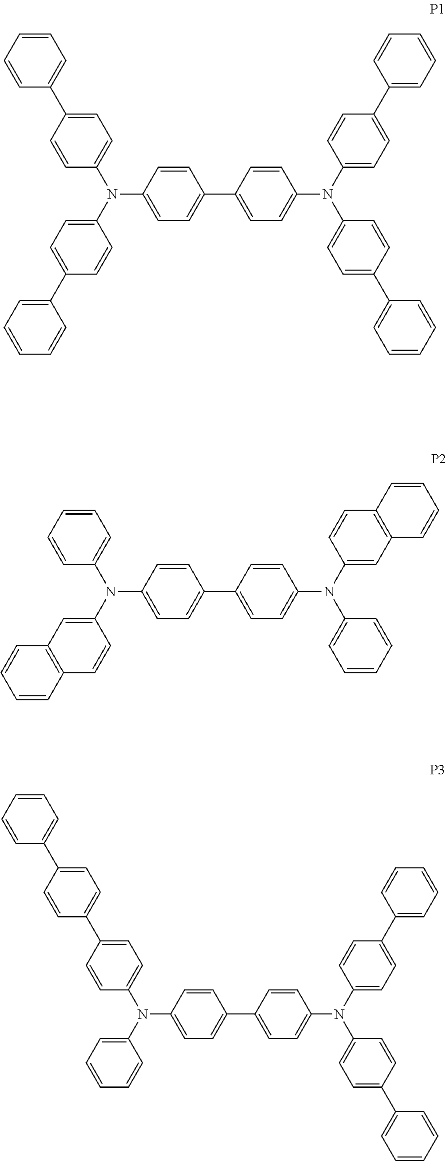 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

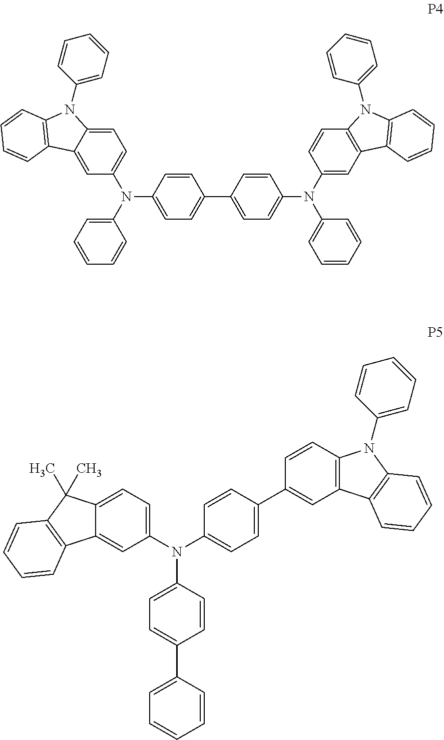 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

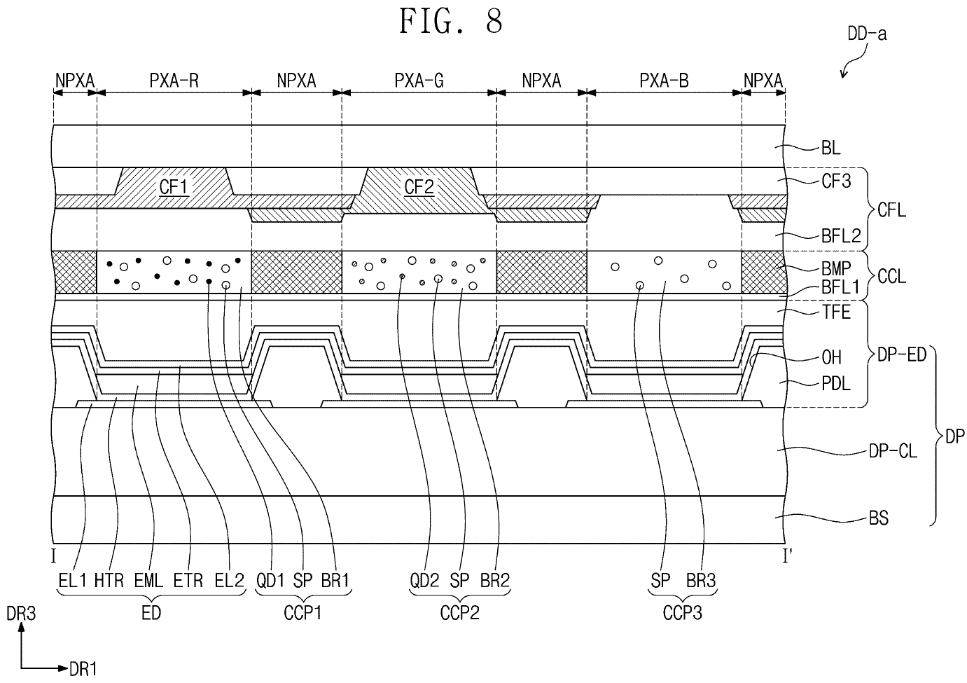

Each of FIGS. 8-11 is a cross-sectional view of a display device according to an embodiment of the present disclosure. Hereinafter, in describing the display devices of embodiments with reference to FIGS. 8-11, the duplicated features which have been described in FIGS. 1-7 are not described again, but their differences will be mainly described.

Referring to FIG. 8, the display device DD-a according to an embodiment may include a display panel DP including a display device layer DP-ED, a light control layer CCL on the display panel DP, and a color filter layer CFL. In an embodiment illustrated in FIG. 8, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In some embodiments, the structures of the light emitting elements of FIGS. 3-7 as described above may be equally applied to the structure of the light emitting element ED illustrated in FIG. 8. The light emitting element ED, shown in FIG. 8 may include the polycyclic compound of an embodiment and at least one among the second to fourth compounds. Accordingly, the light emitting element ED may show high efficiency and long-life characteristics.

Referring to FIG. 8, the emission layer EML may be in an opening OH defined in a pixel defining film PDL. For example, the emission layer EML which is divided by the pixel defining film PDL and provided corresponding to each light emitting regions PXA-R, PXA-G, and PXA-B may emit light in the same wavelength range. In the display device DD-a of an embodiment, the emission layer EML may emit blue light. In some embodiments, the emission layer EML may be provided as a common layer in the entire light emitting regions PXA-R, PXA-G, and PXA-B.

The light control layer CCL may be on the display panel DP. The light control layer CCL may include a light conversion body. The light conversion body may be a quantum dot, a phosphor, and/or the like. The light conversion body may emit provided light by converting the wavelength thereof. In some embodiments, the light control layer CCL may a layer containing the quantum dot and/or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 8, divided patterns BMP may be between the light control parts CCP1, CCP2 and CCP3 which are spaced apart from each other, but embodiments of the present disclosure are not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts a first color light provided from the light emitting element ED into a second color light, a second light control part CCP2 containing a second quantum dot QD2 which converts the first color light into a third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described above may be applied with respect to the quantum dots QD1 and QD2.

In some embodiments, the light control layer CCL may further include a scatterer SP (e.g., a light scatterer SP). The first light control part CCP1 may include the first quantum dot QD1 and the scatterer SP, the second light control part CCP2 may include the second quantum dot QD2 and the scatterer SP, and the third light control part CCP3 may not include any quantum dot but include the scatterer SP.

The scatterer SP may be inorganic particles. For example, the scatterer SP may include at least one of TiO₂, ZnO, Al₂O₃, SiO₂, and/or hollow sphere silica. The scatterer SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce exposure of the light control parts CCP1, CCP2 and CCP3 to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. In some embodiments, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be on the light control layer CCL. For example, the color filter layer CFL may be directly on the light control layer CCL. In some embodiments, the barrier layer BFL2 may be omitted.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye.

Embodiments of the present disclosure, however, are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated (e.g., spaced apart from each other) but be provided as one filter.

In some embodiments, the color filter layer CFL may further include alight shielding part. The light shielding part may be a black matrix. The light shielding part may include an organic light shielding material and/or an inorganic light shielding material containing a black pigment and/or dye. The light shielding part may prevent or reduce light leakage, and may separate boundaries between the adjacent filters CF1, CF2, and CF3.

The first to third filters CF1, CF2, and CF3 may correspond to the red light emitting region PXA-R, the green light emitting region PXA-G, and the blue light emitting region PXA-B, respectively.

A base substrate BL may be on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, etc. However, embodiments of the present disclosure are not limited thereto, and the base substrate BL may be an inorganic layer, an organic layer, or a composite material layer (e.g., including an inorganic layer and an organic layer). In some embodiments, the base substrate BL may be omitted.

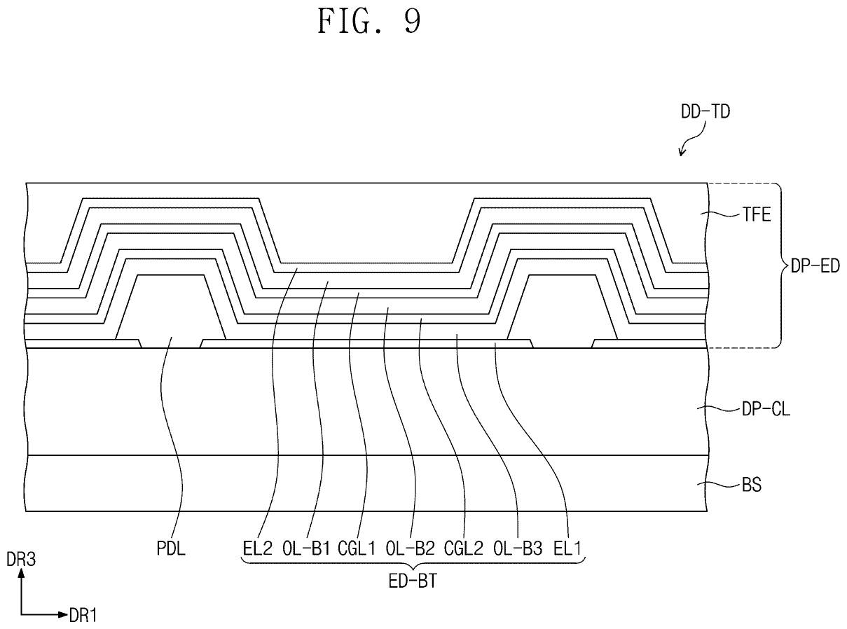

FIG. 9 is a cross-sectional view illustrating a portion of a display device according to an embodiment. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 8) and a hole transport region HTR and an electron transport region ETR with the emission layer EML (FIG. 8) therebetween.

In some embodiments, the light emitting element ED-BT included in the display device DD-TD of an embodiment may be a light emitting element having a tandem structure and including a plurality of emission layers.

In an embodiment illustrated in FIG. 8, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may emit white light.

Charge generation layers CGL1 and CGL2 may be respectively between two of the neighboring light emitting structures OL-B1, OL-B2, and OL-B3. The charge generation layers CGL1 and CGL2 may include a p-type charge generation layer and/or an n-type charge generation layer.

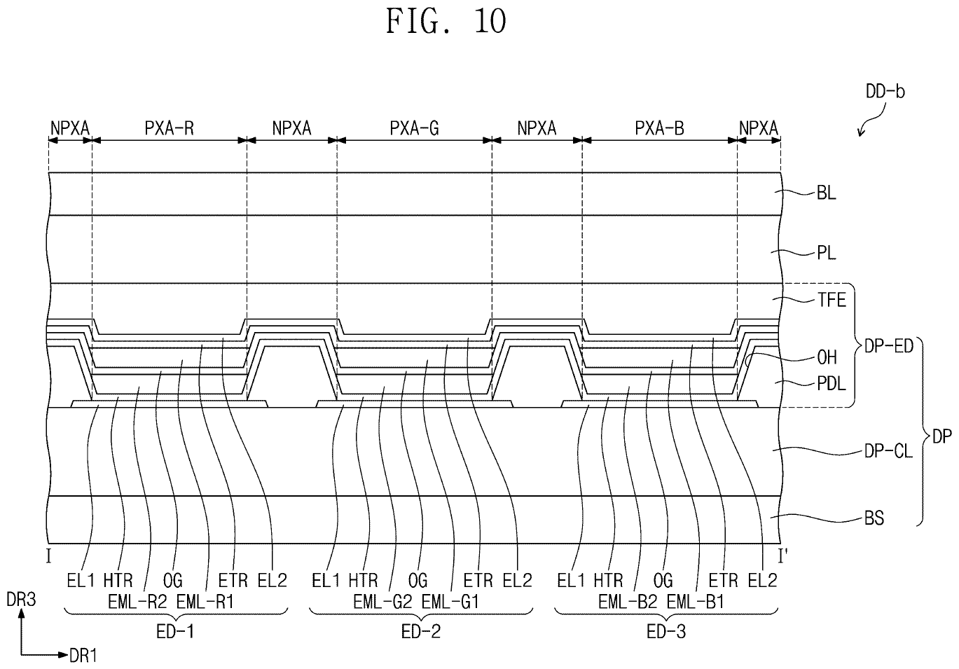

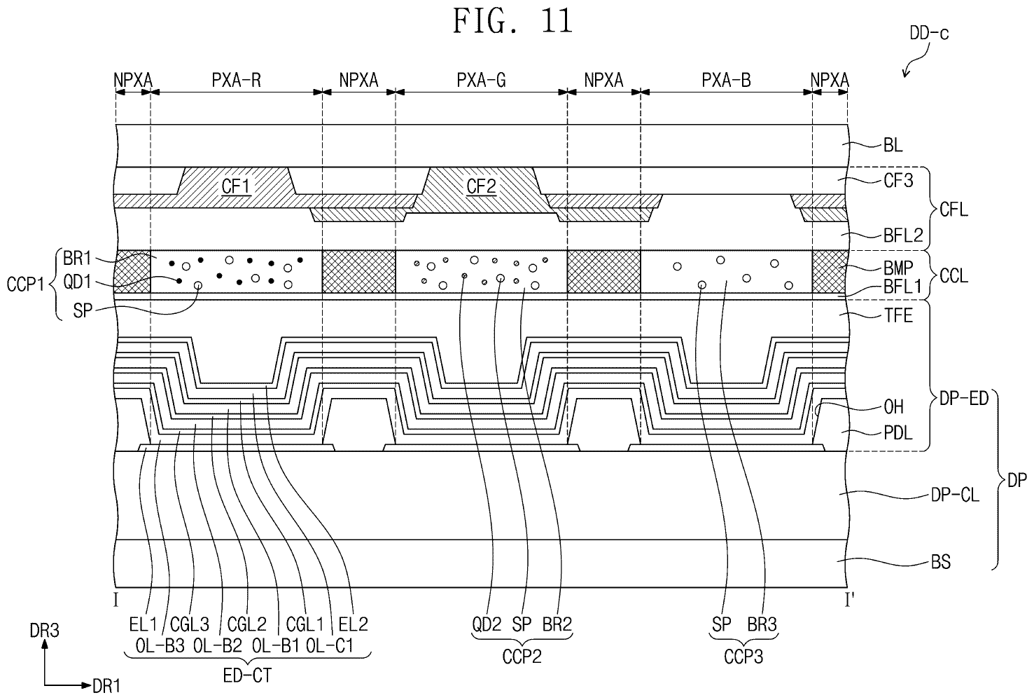

Referring to FIG. 10, the display device DD-b according to an embodiment may include light emitting elements ED-1, ED-2, and ED-3 in which two emission layers are stacked. Compared with the display device DD of an embodiment illustrated in FIG. 2, an embodiment illustrated in FIG. 10 has a difference in that the first to third light emitting elements ED-1, ED-2, and ED-3 each include two emission layers stacked in the thickness direction. In each of the first to third light emitting elements ED-1, ED-2, and ED-3, the two emission layers may emit light in the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. In some embodiments, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be between the emission auxiliary part OG and the electron transport region ETR. The second red emission layer EML-R2, the second green emission layer EML-G2, and the second blue emission layer EML-B2 may be between the hole transport region HTR and the emission auxiliary part OG.

In some embodiments, the first light emitting element ED-1 may include the first electrode EL1, the hole transport region HTR, the second red emission layer EML-R₂, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be on the display device layer DP-ED. The optical auxiliary layer PL may include a polarizing layer. The optical auxiliary layer PL may be on the display panel DP and control reflected light in the display panel DP due to external light. Unlike the configuration illustrated, the optical auxiliary layer PL in the display device according to an embodiment may be omitted.

Unlike FIGS. 9-10, FIG. 11 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, embodiments of the present disclosure are not limited thereto, and the first to fourth light emitting structures OL-B1, OL-B2, OL-B3, and OL-C1 may emit light beams in different wavelength regions.

The charge generation layers CGL1, CGL2, and CGL3 between adjacent light emitting structures OL-B1, OL-B2, OL-B3, and OL-C1 may include a p-type charge generation layer and/or an n-type charge generation layer.

In an embodiment, the electronic apparatus may include a display device including a plurality of light emitting elements, and a control part which controls the display device. The electronic apparatus of an embodiment may be a device that is activated according to an electrical signal. The electronic apparatus may include display devices of various embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

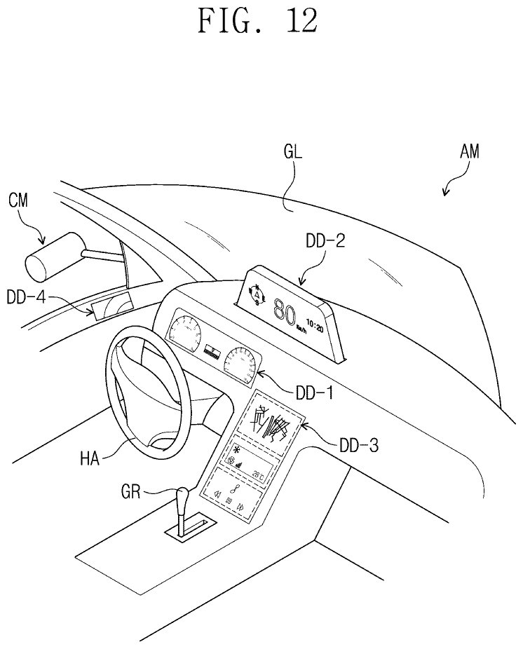

FIG. 12 is a view illustrating a vehicle AM in which first to fourth display devices DD-1, DD-2, DD-3, and DD-4 are provided. At least one among the first to fourth display devices DD-1, DD-2, DD-3, and DD-4 may include the same configuration as the display devices DD, DD-TD, DD-a, DD-b, and DD-c as described with reference to FIGS. 1-2, and 8-11.

FIG. 12 illustrates a vehicle AM, but this is an example, and the first to fourth display devices DD-1, DD-2, DD-3, and DD-4 may be in another transportation means such as bicycles, motorcycles, trains, ships, and airplanes. In some embodiments, at least one among the first to fourth display devices DD-1, DD-2, DD-3, and DD-4 including the same configuration as the display devices DD, DD-TD, DD-a, DD-b, and DD-c of an embodiment may be employed in a personal computer, a laptop computer, a personal digital terminal, a game console, a portable electronic device, a television, a monitor, an outdoor billboard, and/or the like. The foregoing are merely provided as embodiments, and thus may be employed in other electronic apparatuses unless departing from the present disclosure.

At least one among the first to fourth display devices DD-1, DD-2, DD-3, and DD-4 may include the light emitting element ED of an embodiment as described with reference to FIGS. 3-7. At least one among the first to fourth display devices DD-1, DD-2, DD-3 and DD-4 may include the polycyclic compound of an embodiment and at least one among the second to fourth compounds. Accordingly, the first to fourth display devices DD-1, DD-2, DD-3 and DD-4 including the polycyclic compound of an embodiment and at least one among the second to fourth compounds may have improved display efficiency and display lifetime.

Referring to FIG. 12, the vehicle AM may include a steering wheel HA and a gear GR for driving the vehicle AM. In some embodiments, the vehicle AM may include a front window GL provided so as to face the driver.

The first display device DD-1 may be in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (e.g., revolutions per minute (RPM)), an image which indicates a fuel state, etc. A first scale and a second scale may be indicated as a digital image.

The second display device DD-2 may be in a second region facing the driver's seat and overlapping the front window GL. The driver's seat may be a seat in which the steering wheel HA is provided. For example, the second display device DD-2 may be a head up display (HUD) which displays second information of the vehicle AM. The second display device DD-2 may be optically transparent. The second information may include digital numbers which indicate a driving speed, and may further include information such as the current time. Unlike the configuration illustrated, the second information of the second display device DD-2 may be projected to the front window GL to be displayed.

The third display device DD-3 may be in a third region adjacent to the gear GR. For example, the third display device DD-3 may be between the driver's seat and the passenger seat and may be a center information display (CID) for a vehicle for displaying third information. The passenger seat may be a seat spaced apart from the driver's seat with the gear GR therebetween. The third information may include information about traffic (e.g., navigation information), playing music and/or radio and/or a video (and/or an image), temperatures inside the vehicle AM, etc.

The fourth display device DD-4 may be spaced apart from the steering wheel HA and the gear GR, and may be in a fourth region adjacent to the side of the vehicle AM. For example, the fourth display device DD-4 may be a digital side-view mirror which displays fourth information. The fourth display device DD-4 may display an image outside the vehicle AM taken by a camera module CM outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may include different information. However, embodiments of the present disclosure are not limited thereto, and a part of the first to fourth information may include the same information as one another.

Hereinafter, the polycyclic compound according to an embodiment and the light emitting element according to an embodiment of the present disclosure will be further explained referring to embodiments and comparative embodiments. The embodiments below are only illustrations to assist the understanding of the subject matter of the present disclosure, and the scope of the present disclosure is not limited thereto.

### Examples

### 1. Synthesis of Polycyclic Compound of an Embodiment

The synthetic method of the polycyclic compound according to an embodiment will be explained by referring to example synthetic methods of Compounds 2, 19, 20, 62, 119 and 175. The synthetic methods of the polycyclic compounds explained hereinafter are example embodiments, and the synthetic method of the polycyclic compound according to an embodiment of the present disclosure is not limited to the embodiments below.

### 1 Synthesis of Compound 2

Compound 2 according to an embodiment may be synthesized, for example, by the steps in Reaction 1.

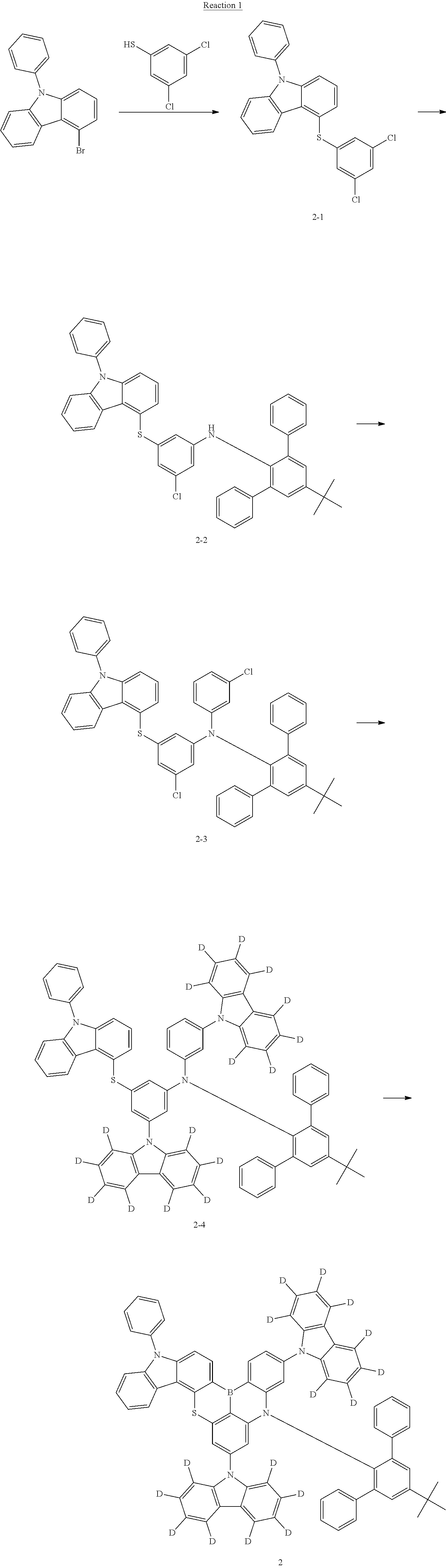

### Synthesis of Intermediate 2-1

4-Bromo-9-phenyl-9H-carbazole (1 eq), 3,5-dichlorobenzenethiol (2 eq), and K₃PO₄ (2 eq) were dissolved in dimethylformamide (DMF) and stirred at about 160 degrees centigrade for about 12 hours. After cooling, the solvent was removed under a reduced pressure, and the resultant was washed with ethyl acetate and water three times. Liquid layers were separated, and an organic layer obtained therefrom was dried over MgSO₄, and then, dried under a reduced pressure. Through purification by column chromatography using methylene chloride (MC) and n-hexane, Intermediate 2-1 was obtained (yield: 73%).

### Synthesis of Intermediate 2-2

Intermediate 2-1 (1 eq), 5′-(tert-butyl)-[1,1′:3′,1″-terphenyl]-2′-amine (0.8 eq), tris(dibenzylideneacetone)dipalladium(0) (0.05 eq), BINAP (0.1 eq), and sodium tert-butoxide (3 eq) were dissolved in toluene and stirred at about 100 degrees centigrade for about 12 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 2-2 was obtained (yield: 57%).

### Synthesis of Intermediate 2-3

Intermediate 2-2 (1 eq), 1-chloro-3-iodobenzene (3 eq), tris(dibenzylideneacetone)dipalladium(0) (0.15 eq), tri-tert-butylphosphine (0.3 eq), and sodium tert-butoxide (3 eq) were dissolved in o-xylene and stirred at about 150 degrees centigrade for about 48 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 2-3 was obtained (yield: 51%).

### Synthesis of Intermediate 2-4

Intermediate 2-3 (1 eq), 9H-carbazole-1,2,3,4,5,6,7,8-d8 (3 eq), tris(dibenzylideneacetone)dipalladium(0) (0.05 eq), tri-tert-butylphosphine (0.1 eq), and sodium tert-butoxide (3 eq) were dissolved in o-xylene and stirred at about 140 degrees centigrade for about 12 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 2-4 was obtained (yield: 64%).

### Synthesis of Compound 2

Intermediate 2-4 (1 eq) was dissolved in o-dichlorobenzene and cooled to about 0 degrees centigrade. Under a nitrogen atmosphere, BBr₃ (3 eq) was slowly injected thereto. After finishing the dropwise addition, the temperature was raised to about 180 degrees centigrade and stirring was performed for about 24 hours. After cooling, triethylamine was slowly added dropwisely to a flask containing the reactant to terminate the reaction, and ethyl alcohol was added to the reactant to precipitate. The precipitate was filtered to obtain a reaction product. The solid content thus obtained was purified by column chromatography using MC and n-hexane, and recrystallized using toluene and acetone to obtain Compound 2 (yield: 4%).

### 2 Synthesis of Compound 19

Compound 19 according to an embodiment may be synthesized, for example, by the steps in Reaction 2.

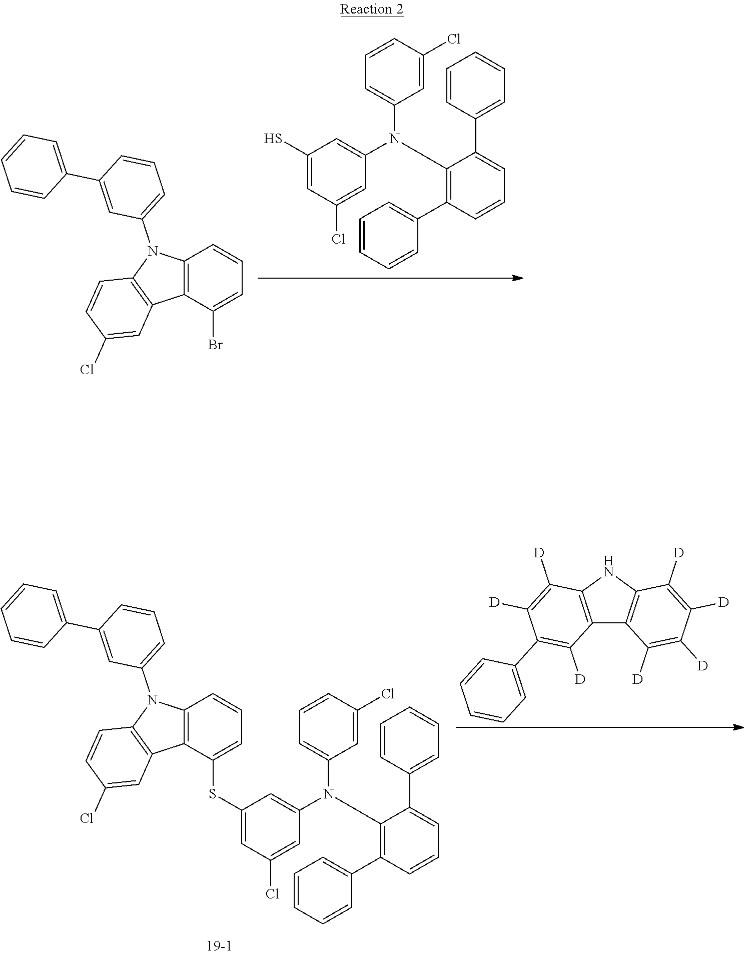

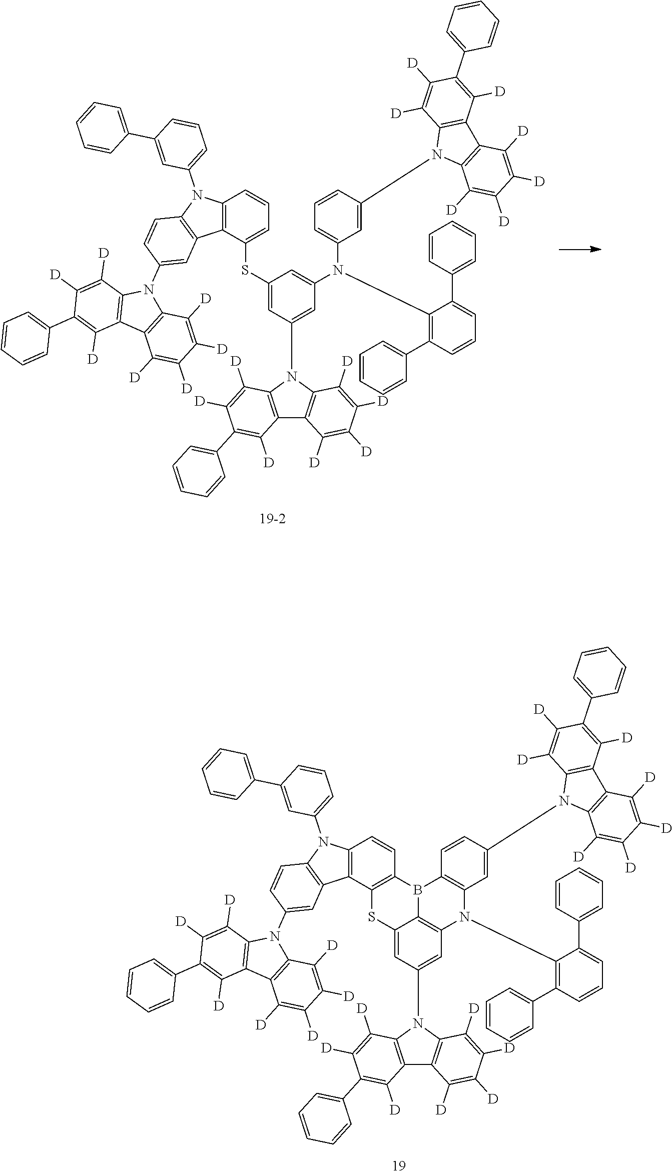

### Synthesis of Intermediate 19-1

9-([1,1′-Biphenyl]-3-yl)-5-bromo-3-chloro-9H-carbazole (1 eq), 3-([1,1′:3′,1″-terphenyl]-2′-yl-(3-chlorophenyl)amino)-5-chlorobenzenethiol (1 eq), and K₃PO₄ (2 eq) were dissolved in DMF and stirred at about 160 degrees centigrade for about 24 hours. After cooling, the solvent was removed under a reduced pressure, and the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 19-1 was obtained (yield: 49%).

### Synthesis of Intermediate 19-2

Intermediate 19-1 (1 eq), 3-phenyl-9H-carbazole-1,2,4,5,6,7,8-d7 (4 eq), tris(dibenzylideneacetone)dipalladium(0) (0.15 eq), tri-tert-butylphosphine (0.3 eq), and sodium tert-butoxide (3 eq) were dissolved in o-xylene and stirred at about 150 degrees centigrade for about 24 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 19-2 was obtained (yield: 52%).

### Synthesis of Compound 19

Intermediate 19-2 (1 eq) was dissolved in o-dichlorobenzene and cooled to about 0 degrees centigrade. Under a nitrogen atmosphere, BBr₃ (3 eq) was slowly injected thereto. After finishing the dropwise addition, the temperature was raised to about 180 degrees centigrade and stirring was performed for about 24 hours. After cooling, triethylamine was slowly added dropwisely to a flask containing the reactant to terminate the reaction, and ethyl alcohol was added to the reactant to precipitate. The precipitate was filtered to obtain a reaction product. The solid content thus obtained was purified by column chromatography using MC and n-hexane, and recrystallized using toluene and acetone to obtain Compound 19 (yield: 5%).

### 3 Synthesis of Compound 20

Compound 20 according to an embodiment may be synthesized, for example, by the steps in Reaction 3.

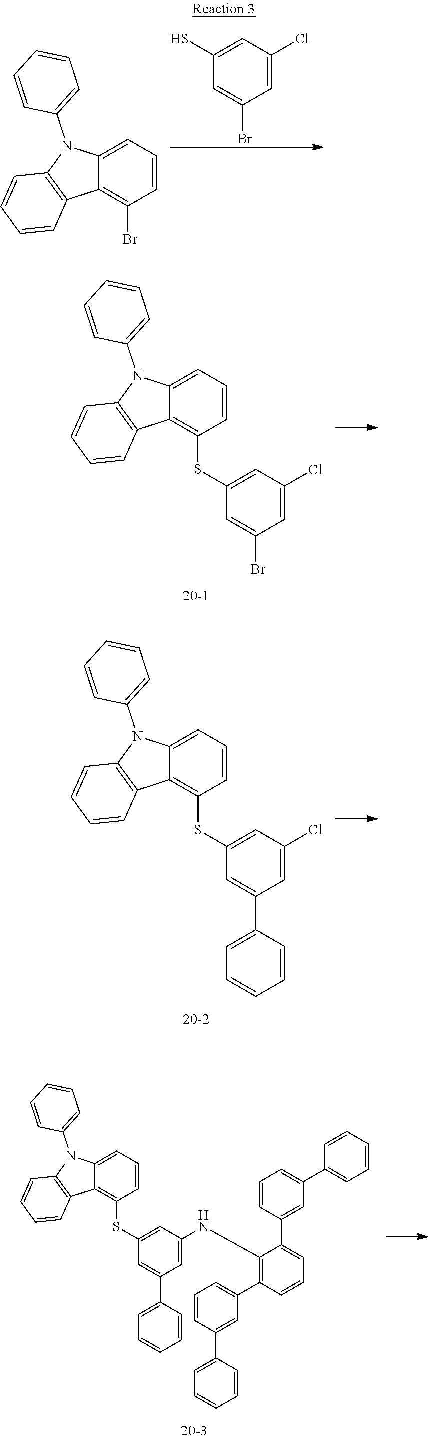

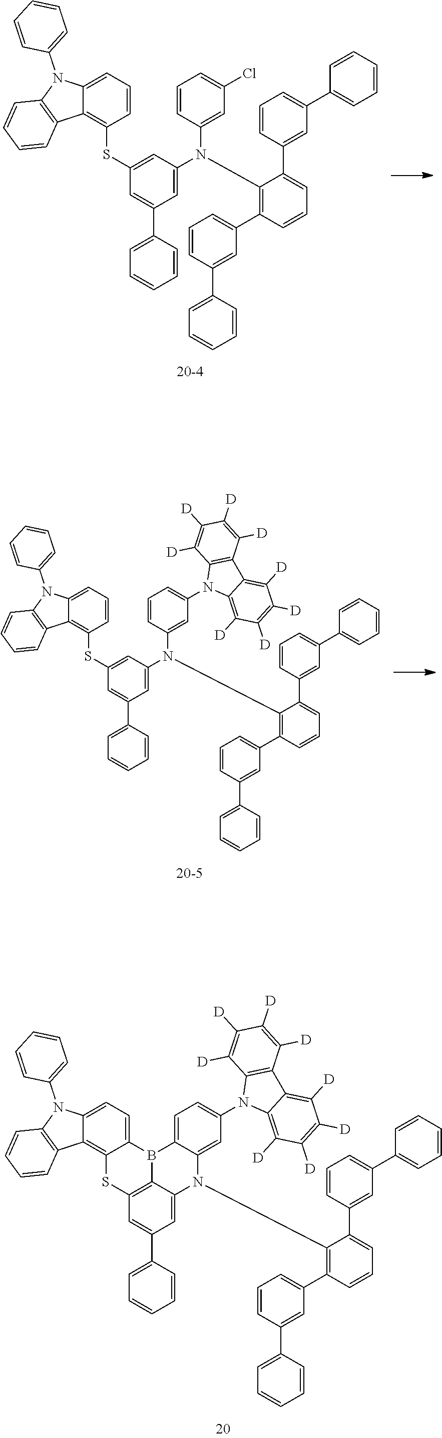 [SMILES: Clc1cccc(N(c2cc(Sc3cccc4c3c3ccccc3n4-c3ccccc3)cc(-c3ccccc3)c2)c2c(-c3cccc(-c4ccccc4)c3)cccc2-c2cccc(-c3ccccc3)c2)c1 ; [2H]c1c([2H])c([2H])c2c(c1[2H])c1c([2H])c([2H])c([2H])c([2H])c1n2-c1cccc(N(c2cc(Sc3cccc4c3c3ccccc3n4-c3ccccc3)cc(-c3ccccc3)c2)c2c(-c3cccc(-c4ccccc4)c3)cccc2-c2cccc(-c3ccccc3)c2)c1 ; [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2c(c1S3)c1ccccc1n2-c1ccccc1]

### Synthesis of Intermediate 20-1

4-Bromo-9-phenyl-9H-carbazole (1 eq), 3-bromo-5-chlorobenzenethiol (0.7 eq), and K₃PO₄ (2 eq) were dissolved in DMF and stirred at about 160 degrees centigrade for about 12 hours. After cooling, the solvent was removed under a reduced pressure, and the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 20-1 was obtained (yield: 38%).

### Synthesis of Intermediate 20-2

Intermediate 20-1 (1 eq), phenylboronic acid (1.6 eq), Pd(PPh₃)₄ (0.05 eq), and K₂CO₃ (3 eq) were dissolved in a mixture solution of water and THE in a ratio of about 2:1 and stirred at about 80 degrees centigrade for about 12 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 20-2 was obtained (yield: 78%).

### Synthesis of Intermediate 20-3

Intermediate 20-2 (1 eq), [1,1′:3′,1″:3″,1′″:3′″,1″″-quinquephenyl]-2″-amine (1 eq), tris(dibenzylideneacetone)dipalladium(0) (0.05 eq), SPhos (0.1 eq), and sodium tert-butoxide (3 eq) were dissolved in o-xylene and stirred at about 140 degrees centigrade for about 12 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 20-3 was obtained (yield: 81%).

### Synthesis of Intermediate 20-4

Intermediate 20-3 (1 eq), 1-chloro-3-iodobenzene (3 eq), tris(dibenzylideneacetone)dipalladium(0) (0.15 eq), tri-tert-butylphosphine (0.3 eq), and sodium tert-butoxide (3 eq) were dissolved in o-xylene and stirred at about 150 degrees centigrade for about 48 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 20-4 was obtained (yield: 37%).

### Synthesis of Intermediate 20-5

Intermediate 20-4 (1 eq), 9H-carbazole-1,2,3,4,5,6,7,8-d8 (1.3 eq), tris(dibenzylideneacetone)dipalladium(0) (0.05 eq), tri-tert-butylphosphine (0.1 eq), and sodium tert-butoxide (3 eq) were dissolved in o-xylene and stirred at about 140 degrees centigrade for about 6 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 20-5 was obtained (yield: 74%).

### Synthesis of Compound 20

Intermediate 20-5 (1 eq) was dissolved in o-dichlorobenzene and cooled to about 0 degrees centigrade. Under a nitrogen atmosphere, BBr₃ (3 eq) was slowly injected thereto. After finishing the dropwise addition, the temperature was raised to about 180 degrees centigrade and stirring was performed for about 24 hours. After cooling, triethylamine was slowly added dropwisely to a flask containing the reactant to terminate the reaction, and ethyl alcohol was added to the reactant to precipitate. The precipitate was filtered to obtain a reaction product. The solid content thus obtained was purified by column chromatography using MC and n-hexane, and recrystallized using toluene and acetone to obtain Compound 20 (yield: 5%).

### 4 Synthesis of Compound 62

Compound 62 according to an embodiment may be synthesized, for example, by the steps in Reaction 4.

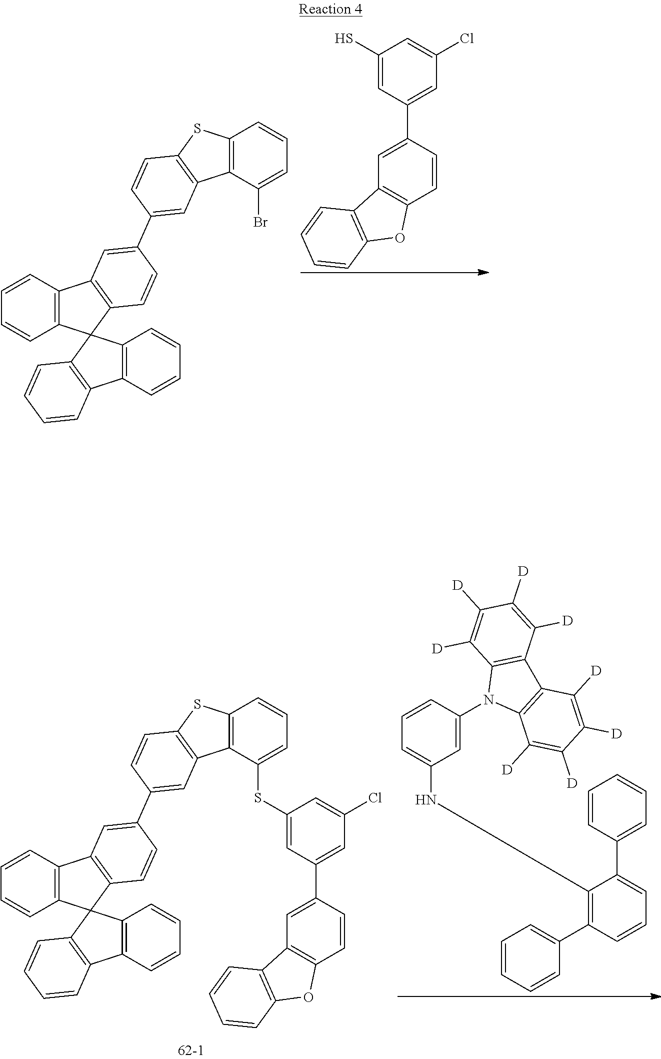

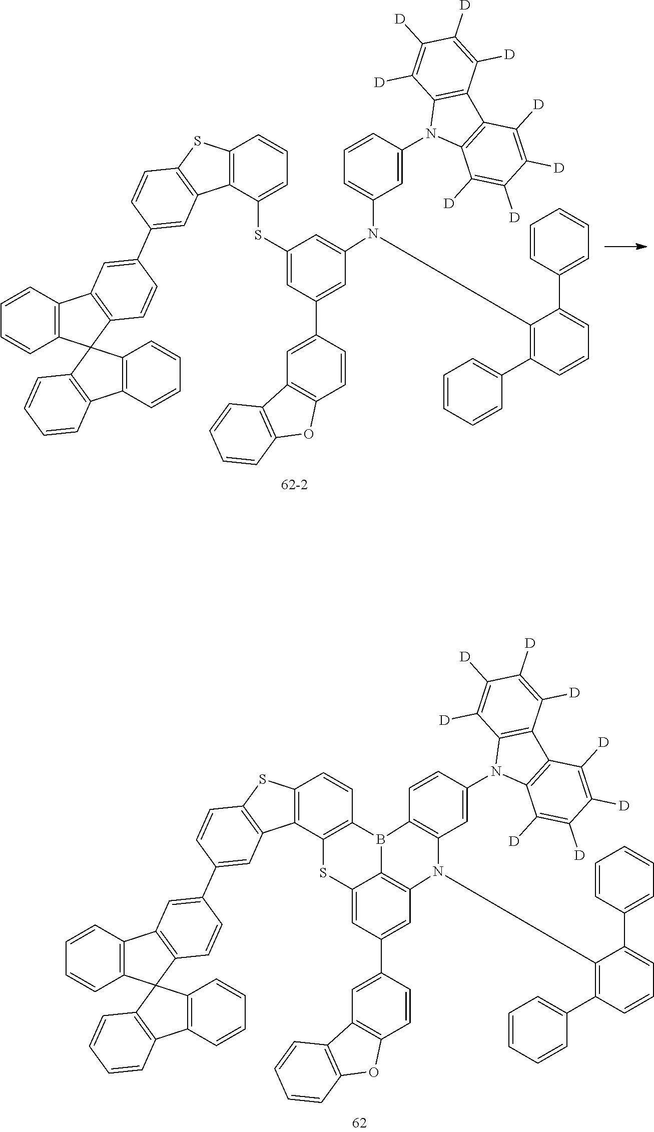 [SMILES: [2H]c1c([2H])c([2H])c2c(c1[2H])c1c([2H])c([2H])c([2H])c([2H])c1n2-c1cccc(N(c2cc(Sc3cccc4sc5ccc(-c6ccc7c(c6)-c6ccccc6C76c7ccccc7-c7ccccc76)cc5c34)cc(-c3ccc4oc5ccccc5c4c3)c2)c2c(-c3ccccc3)cccc2-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc2sc4ccc(-c5ccc6c(c5)-c5ccccc5C65c6ccccc6-c6ccccc65)cc4c2c1S3]

### Synthesis of Intermediate 62-1

8-(9,9′-Spirobi[fluoren]-3-yl)-1-bromodibenzo[b,d]thiophene (1 eq), 3-chloro-5-(dibenzo[b,d]furan-2-yl)benzenethiol (1 eq), and K₃PO₄ (2 eq) were dissolved in DMF and stirred at about 160 degrees centigrade for about 24 hours. After cooling, the solvent was removed under a reduced pressure, and the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 62-1 was obtained (yield: 56%).

### Synthesis of Intermediate 62-2

Intermediate 62-1 (1 eq), N-(3-(9H-carbazol-9-yl-d8)phenyl)-[1,1′:3′,1″-terphenyl]-2′-amine (1 eq), tris(dibenzylideneacetone)dipalladium(0) (0.15 eq), tri-tert-butylphosphine (0.3 eq), and Sodium tert-butoxide (3 eq) were dissolved in o-xylene and stirred at about 150 degrees centigrade for about 24 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 62-2 was obtained (yield: 46%).

### Synthesis of Compound 62

Intermediate 62-2 (1 eq) was dissolved in o-dichlorobenzene and cooled to about 0 degrees centigrade. Under a nitrogen atmosphere, BBr₃ (3 eq) was slowly injected thereto. After finishing the dropwise addition, the temperature was raised to about 180 degrees centigrade and stirring was performed for about 24 hours. After cooling, triethylamine was slowly added dropwisely to a flask containing the reactant to terminate the reaction, and ethyl alcohol was added to the reactant to precipitate. The precipitate was filtered to obtain a reaction product. The solid content thus obtained was purified by column chromatography using MC and n-hexane, and recrystallized using toluene and acetone to obtain Compound 62 (yield: 5%).

### 5 Synthesis of Compound 119

Compound 119 according to an embodiment may be synthesized, for example, by the steps in Reaction 5.

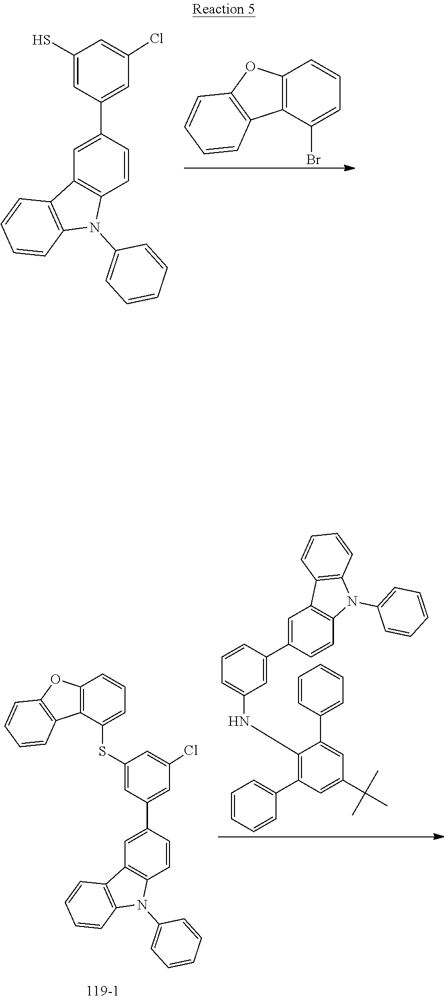 [SMILES: Sc1cc(Cl)cc(-c2ccc3c(c2)c2ccccc2n3-c2ccccc2)c1 ; Brc1cccc2oc3ccccc3c12 ; Clc1cc(Sc2cccc3oc4ccccc4c23)cc(-c2ccc3c(c2)c2ccccc2n3-c2ccccc2)c1 ; CC(C)(C)c1cc(-c2ccccc2)c(Nc2cccc(-c3ccc4c(c3)c3ccccc3n4-c3ccccc3)c2)c(-c2ccccc2)c1]

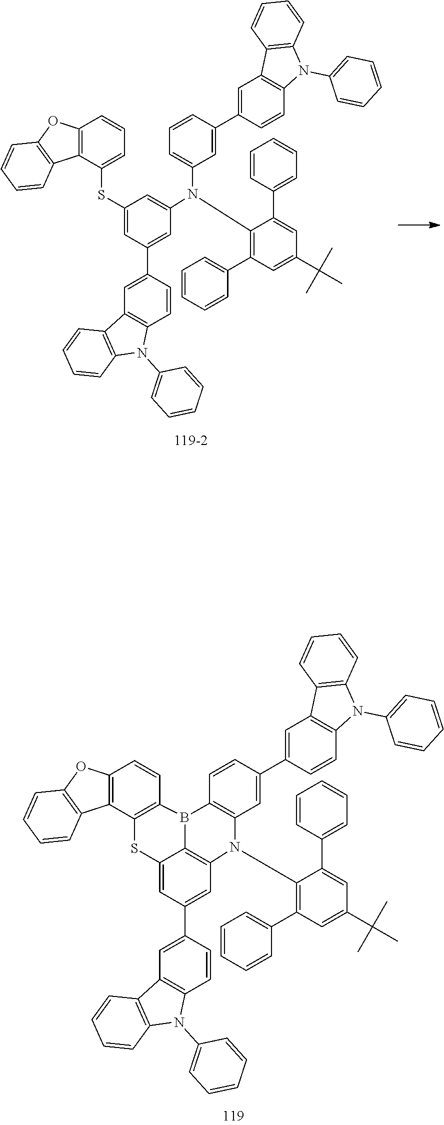 [SMILES: CC(C)(C)c1cc(-c2ccccc2)c(N(c2cccc(-c3ccc4c(c3)c3ccccc3n4-c3ccccc3)c2)c2cc(Sc3cccc4oc5ccccc5c34)cc(-c3ccc4c(c3)c3ccccc3n4-c3ccccc3)c2)c(-c2ccccc2)c1 ; CC(C)(C)c1cc(-c2ccccc2)c(N2c3cc(-c4ccc5c(c4)c4ccccc4n5-c4ccccc4)ccc3B3c4ccc5oc6ccccc6c5c4Sc4cc(-c5ccc6c(c5)c5ccccc5n6-c5ccccc5)cc2c43)c(-c2ccccc2)c1]

### Synthesis of Intermediate 119-1

3-Chloro-5-(9-phenyl-9H-carbazol-3-yl)benzenethiol (1 eq), 1-bromodibenzo[b,d]furan (1 eq), and K₃PO₄ (2 eq) were dissolved in DMF and stirred at about 160 degrees centigrade for about 24 hours. After cooling, the solvent was removed under a reduced pressure, and the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 119-1 was obtained (yield: 82%).

### Synthesis of Intermediate 119-2

Intermediate 119-1 (1 eq), 5′-(tert-butyl)-N-(3-(9-phenyl-9H-carbazol-3-yl)phenyl)-[1,1′:3′,1″-terphenyl]-2′-amine (1 eq), tris(dibenzylideneacetone)dipalladium(0) (0.15 eq), tri-tert-butylphosphine (0.3 eq), and sodium tert-butoxide (3 eq) were dissolved in o-xylene and stirred at about 150 degrees centigrade for about 24 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 119-2 was obtained (yield: 55%).

### Synthesis of Compound 119

Intermediate 119-2 (1 eq) was dissolved in o-dichlorobenzene and cooled to about 0 degrees centigrade. Under a nitrogen atmosphere, BBr₃ (3 eq) was slowly injected thereto. After finishing the dropwise addition, the temperature was raised to about 180 degrees centigrade and stirring was performed for about 24 hours. After cooling, triethylamine was slowly added dropwisely to a flask containing the reactant to terminate the reaction, and ethyl alcohol was added to the reactant to precipitate. The precipitate was filtered to obtain a reaction product. The solid content thus obtained was purified by column chromatography using MC and n-hexane, and recrystallized using toluene and acetone to obtain Compound 119 (yield: 4%).

### 6 Synthesis of Compound 175

Compound 175 according to an embodiment may be synthesized, for example, by the steps in Reaction 6.

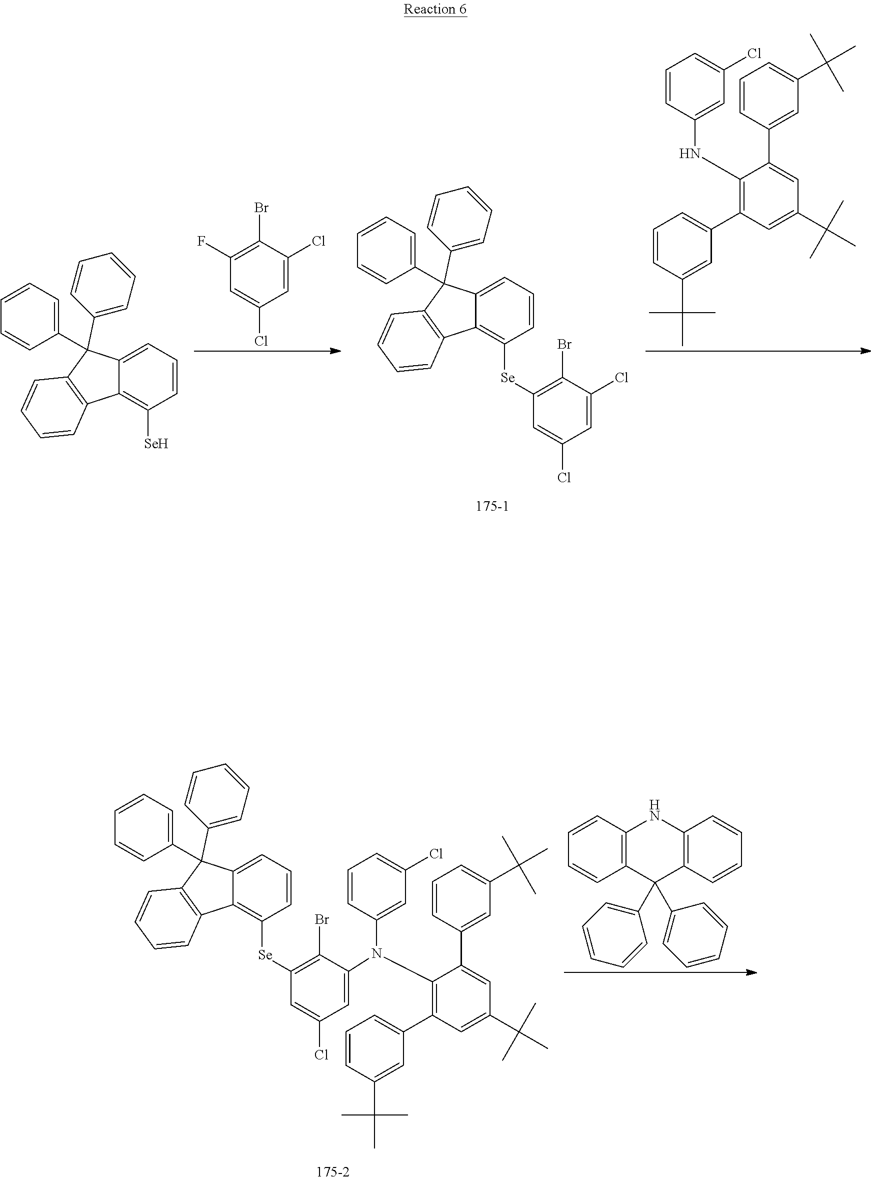

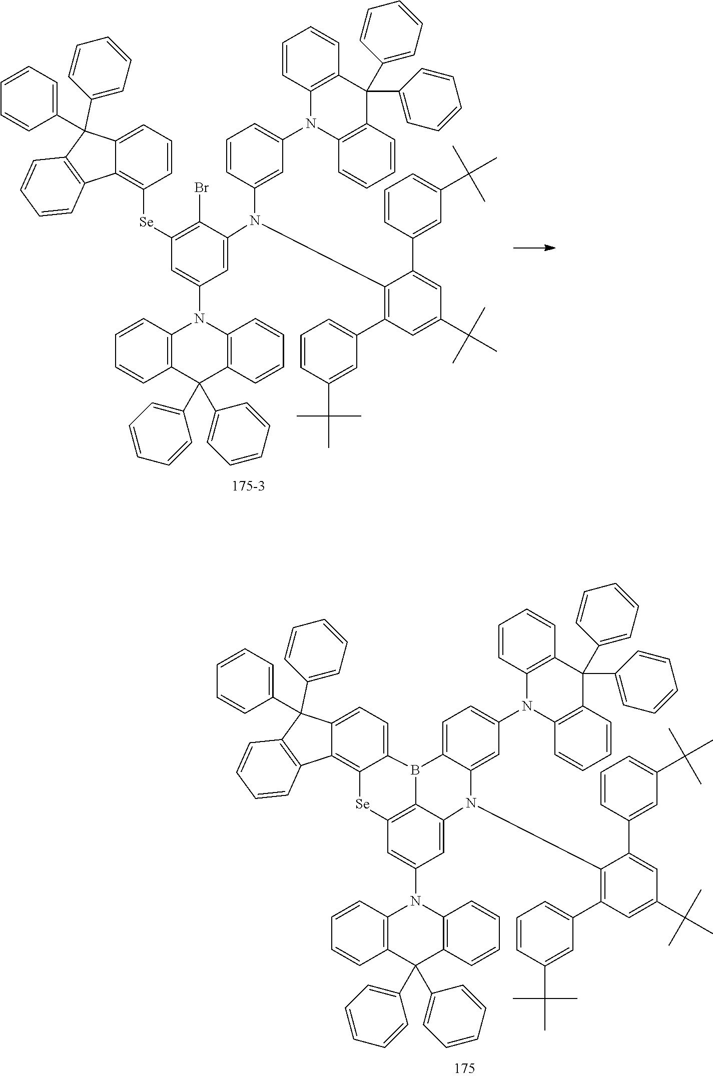 [SMILES: CC(C)(C)c1cccc(-c2cc(C(C)(C)C)cc(-c3cccc(C(C)(C)C)c3)c2N(c2cccc(N3c4ccccc4C(c4ccccc4)(c4ccccc4)c4ccccc43)c2)c2cc(N3c4ccccc4C(c4ccccc4)(c4ccccc4)c4ccccc43)cc([Se]c3cccc4c3-c3ccccc3C4(c3ccccc3)c3ccccc3)c2Br)c1 ; CC(C)(C)c1cccc(-c2cc(C(C)(C)C)cc(-c3cccc(C(C)(C)C)c3)c2N2c3cc(N4c5ccccc5C(c5ccccc5)(c5ccccc5)c5ccccc54)ccc3B3c4ccc5c(c4[Se]c4cc(N6c7ccccc7C(c7ccccc7)(c7ccccc7)c7ccccc76)cc2c43)-c2ccccc2C5(c2ccccc2)c2ccccc2)c1]

### Synthesis of Intermediate 175-1

9,9-Diphenyl-9H-fluorene-4-selenol (1 eq), 2-bromo-1,5-dichloro-3-fluorobenzene (1 eq), and K₃PO₄ (2 eq) were dissolved in NMP and stirred at about 130 degrees centigrade for about 12 hours. After cooling, the solvent was removed under a reduced pressure, and the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 175-1 was obtained (yield: 69%).

### Synthesis of Intermediate 175-2

Intermediate 175-1 (1 eq), 3,3″,5′-tri-tert-butyl-N-(3-chlorophenyl)-[1,1′:3′,1″-terphenyl]-2′-amine (1 eq), tris(dibenzylideneacetone)dipalladium(0) (0.05 eq), BINAP (0.1 eq), and sodium tert-butoxide (3 eq) were dissolved in toluene and stirred at about 120 degrees centigrade for about 36 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 175-2 was obtained (yield: 28%).

### Synthesis of Intermediate 175-3

Intermediate 175-2 (1 eq), 9,9-diphenyl-9,10-dihydroacridine (2 eq), tris(dibenzylideneacetone)dipalladium(0) (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate and water three times. Liquid layers were separated, and an organic layer obtained therefrom was dried over MgSO₄, and then, dried under a reduced pressure. Through purification by column chromatography using MC and n-hexane, Intermediate 175-3 was obtained (yield: 51%).

### Synthesis of Compound 175

Intermediate 175-3 (1 eq) was dissolved in o-xylene and cooled to about 0 degrees centigrade under a nitrogen atmosphere. n-BuLi (4 eq) was slowly injected thereto, and the temperature was raised to about 70 degrees centigrade, stirring was performed for about 2 hours, and then, the temperature was raised to about 120 degrees centigrade, stirring was performed for about 2 hours. After cooling the temperature of the reactor to about 0 degrees centigrade, BBr₃ (5 eq) was slowly injected thereto. After finishing the dropwise addition, stirring was performed at room temperature for about 1 hour. After cooling to 0 degrees centigrade, triethylamine (6 eq) was injected, and the temperature was raised to about 140 degrees, followed by stirring for about 12 hours. After cooling, triethylamine was slowly added dropwisely to a flask containing the reactant to terminate the reaction, and ethyl alcohol was added to the reactant to precipitate. The precipitate was filtered to obtain a reaction product. The solid content thus obtained was purified by column chromatography to obtain Compound 175 (yield: 19%).

### 2. Evaluation of Polycyclic Compound

In Table 1, the polycyclic compounds used in the Examples and Comparative Examples are shown.

TABLE 1

| Division | Compound |
|---|---|
| Example 1 | 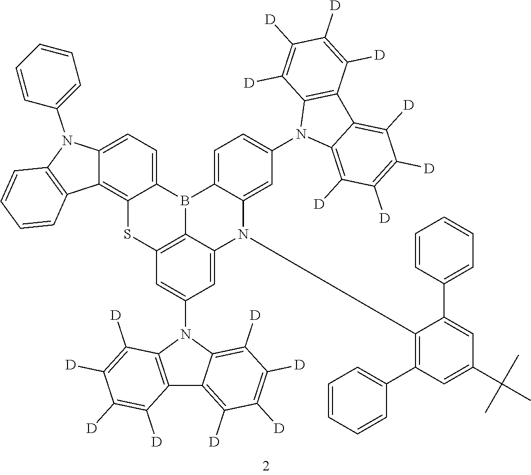 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c([2H])c([2H])c([2H])c43)cc3c1B2c1ccc2c(c1S3)c1ccccc1n2-c1ccccc1] |
| Example 2 | 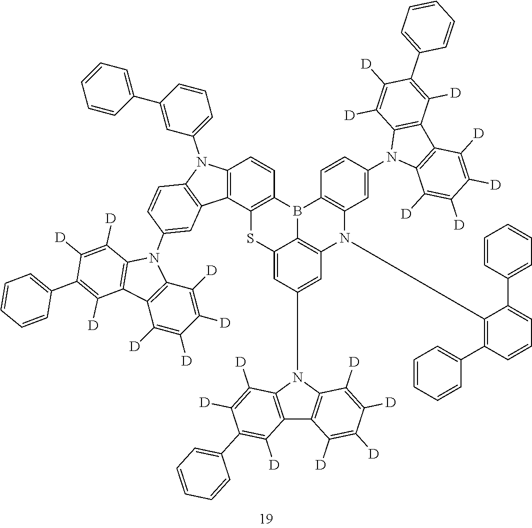 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1ccccc1)c1cc(-n3c4c([2H])c([2H])c([2H])c([2H])c4c4c([2H])c(-c5ccccc5)c([2H])c([2H])c43)cc3c1B2c1ccc2c(c1S3)c1cc(-n3c4c([2H])c([2H])c([2H])c([2H])c4c4c([2H])c(-c5ccccc5)c([2H])c([2H])c43)ccc1n2-c1cccc(-c2ccccc2)c1] |
| Example 3 | 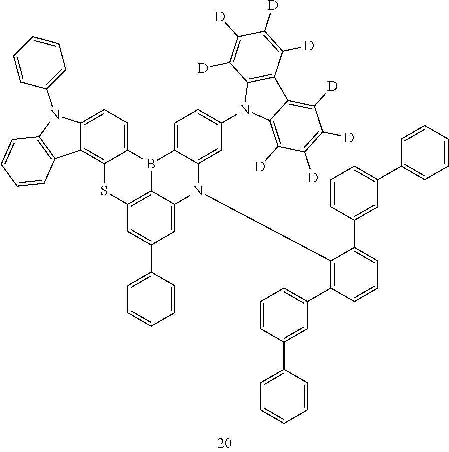 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2c(c1S3)c1ccccc1n2-c1ccccc1] |
| Example 4 | 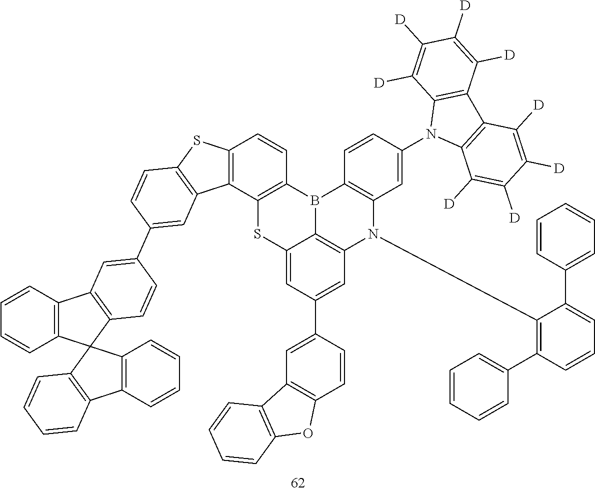 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc2sc4ccc(-c5ccc6c(c5)-c5ccccc5C65c6ccccc6-c6ccccc65)cc4c2c1S3] |
| Example 5 | 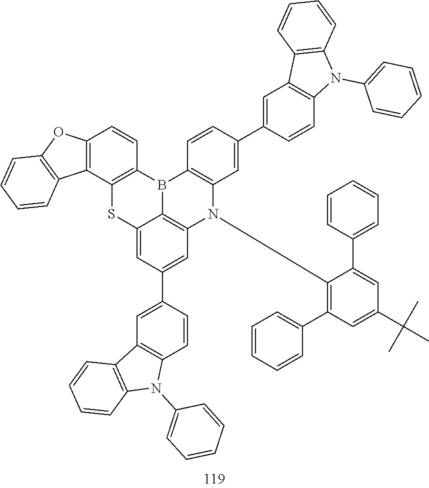 [SMILES: CC(C)(C)c1cc(-c2ccccc2)c(N2c3cc(-c4ccc5c(c4)c4ccccc4n5-c4ccccc4)ccc3B3c4ccc5oc6ccccc6c5c4Sc4cc(-c5ccc6c(c5)c5ccccc5n6-c5ccccc5)cc2c43)c(-c2ccccc2)c1] |
| Example 6 | 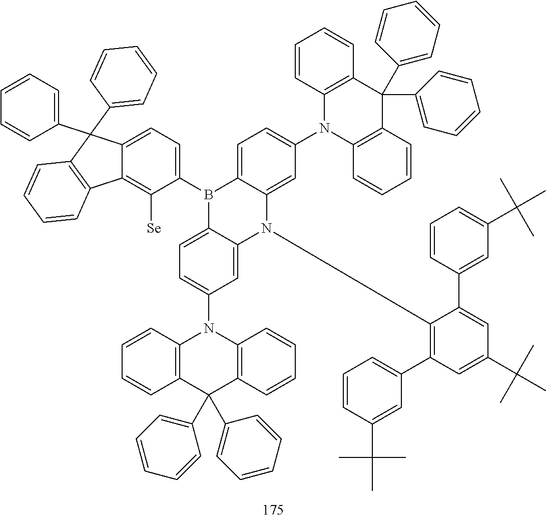 |
| Comparative Example 1 | 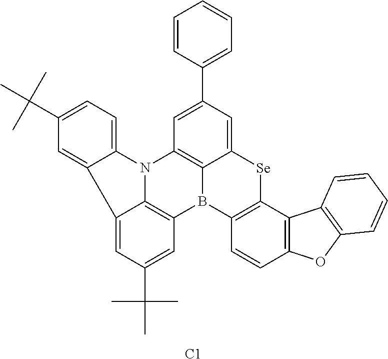 [SMILES: CC(C)(C)c1ccc2c(c1)c1cc(C(C)(C)C)cc3c1n2-c1cc(-c2ccccc2)cc2c1B3c1ccc3oc4ccccc4c3c1[Se]2 ; "C1"] |
| Comparative Example 2 | 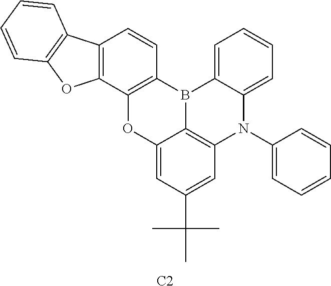 |
| Comparative Example 3 | 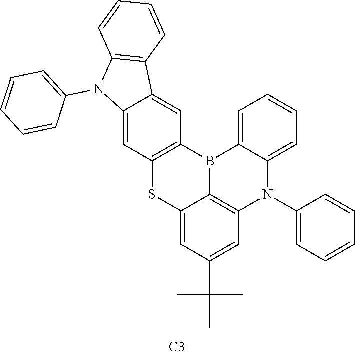 [SMILES: CC(C)(C)c1cc2c3c(c1)N(c1ccccc1)c1ccccc1B3c1cc3c4ccccc4n(-c4ccccc4)c3cc1S2 ; "C3"] |
| Comparative Example 4 | 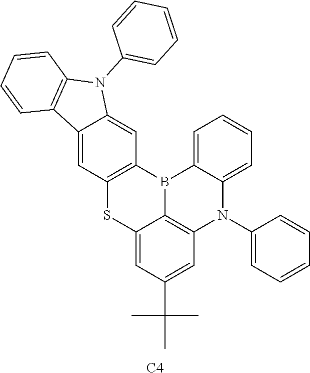 [SMILES: CC(C)(C)c1cc2c3c(c1)N(c1ccccc1)c1ccccc1B3c1cc3c(cc1S2)c1ccccc1n3-c1ccccc1 ; "C4"] |

### 3. Manufacture and Evaluation of Light Emitting Element

### 1 Manufacture of light emitting elements

The light emitting element including the polycyclic compound of an embodiment or the Comparative Compound in an emission layer was manufactured by a method below. Light emitting elements of Example 1 to Example 6 were manufactured using the polycyclic compounds of the Examples as the dopant materials of an emission layer. The light emitting elements of Comparative Example 1 to Comparative Example 4 were manufactured using Comparative Compounds C1 to C4 as the dopant materials of an emission layer.

As a first electrode, a glass substrate on which an ITO electrode of 15 Ω/cm² (1200 Å) was formed, was cut into 50 mm×50 mm×0.7 mm, and then, undergone ultrasonic cleansing using isopropyl alcohol and pure water for about 5 minutes each, exposed to ultraviolet for about 30 minutes, cleansed by exposing to ozone, and installed in a vacuum deposition apparatus.

On the first electrode, NPD was deposited to form a hole injection layer having a thickness of about 300 Å, and on the hole injection layer, Compound H-1-1 was deposited to form a hole transport layer having a thickness of about 200 Å. Then, on the hole transport layer, CzSi was deposited to form an emission auxiliary layer having a thickness of about 100 Å.

On the emission auxiliary layer, a host mixture, a phosphorescence sensitizer and a dopant were co-deposited in a weight ratio of about 85:14:1 to form an emission layer having a thickness of about 350 Å. The host mixture was provided by mixing together the hole transporting host of Compound HT35 and the electron transporting host of Compound ETH66 in a weight ratio of about 5:5. As the phosphorescence sensitizer, Compound AD-38 was used. As the dopant material, the Example Compound or Comparative Compound was used.

On the emission layer, HBL-1 was deposited to form a hole blocking layer having a thickness of about 50 Å. Then, on the hole blocking layer, CNNPTRZ and Liq were co-deposited in a weight ratio of about 4.0:6.0 to form an electron transport layer having a thickness of about 310 Å, and on the electron transport layer, Yb was deposited to a thickness of about 15 Å to form an electron injection layer. After that, on the electron injection layer, Mg was deposited to form a second electrode having a thickness of about 800 Å to manufacture a light emitting element.

The compounds used for the manufacture of the light emitting element are as follows.

Materials used for the manufacture of light emitting elements

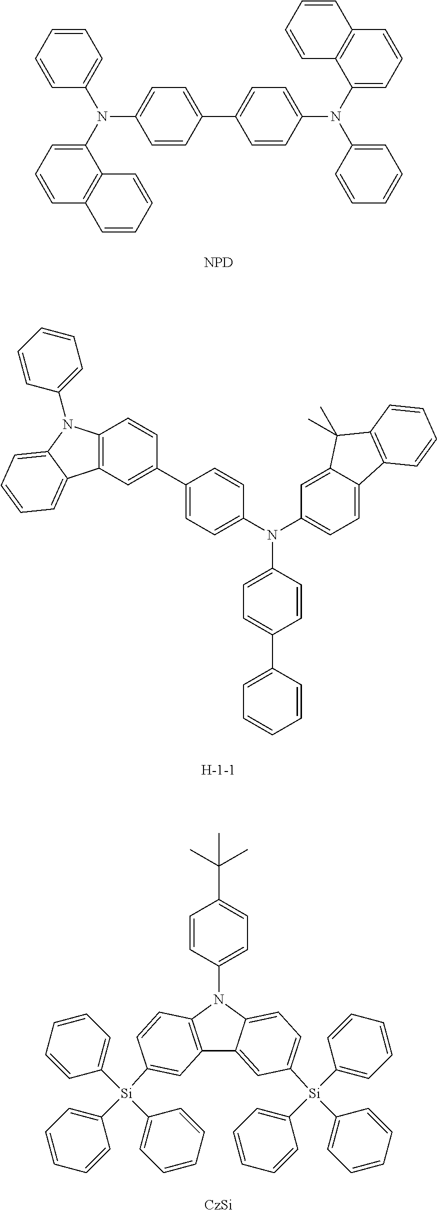 [SMILES: c1ccc(N(c2ccc(-c3ccc(N(c4ccccc4)c4cccc5ccccc45)cc3)cc2)c2cccc3ccccc23)cc1 ; "NPD" ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

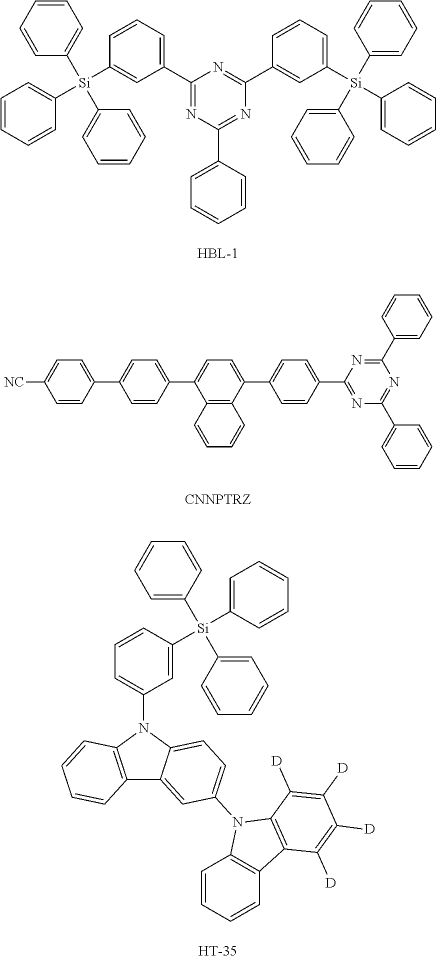

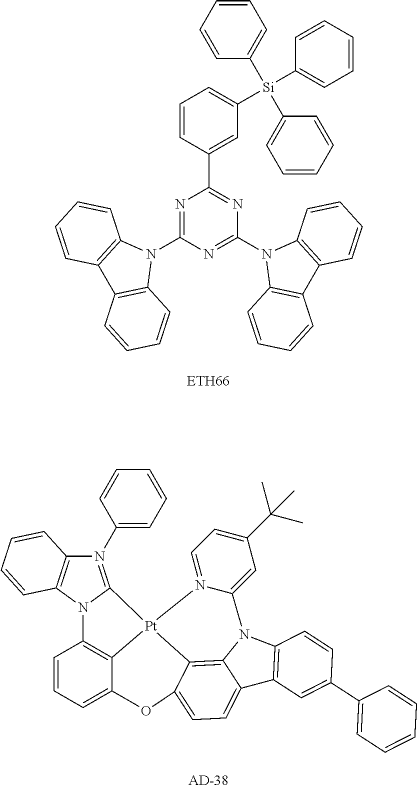

### 2 Evaluation of Light Emitting Element

The light emitting elements of the Examples and Comparative Examples were evaluated and the results are shown in Table 2. In the light emitting elements of the Examples and Comparative Examples, the driving voltage (V) at a current density of about 10 mA/cm², the top surface efficiency (cd/A/y), and the emission wavelength (nm) were measured using a Keithley MU 236 and a luminance meter PR650 and shown. The lifetime is represented by relative element lifetime by measuring time taken for reducing to 95% in contrast to an initial luminance, and by a numerical compared to Comparative Example 1.

TABLE 2

| | | | Boron | Driving | | Emission | Lifetime |
|---|---|---|---|---|---|---|---|
| | | Fourth | Dopant | voltage | Efficiency | wavelength | ratio |
| Division | Host mixture | compound | (Formula 1) | (V) | (cd/A) | (nm) | (T95) |
| Example 1 | HT35/ETH66 | AD-38 | Compound | 4.6 | 26.7 | 459 | 5.3 |
| | | | 2 | | | | |
| Example 2 | HT35/ETH66 | AD-38 | Compound | 4.5 | 26.1 | 459 | 5.8 |
| | | | 19 | | | | |
| Example 3 | HT35/ETH66 | AD-38 | Compound | 4.5 | 26.9 | 462 | 6.2 |
| | | | 20 | | | | |
| Example 4 | HT35/ETH66 | AD-38 | Compound | 4.5 | 26.6 | 463 | 6.4 |
| | | | 62 | | | | |
| Example 5 | HT35/ETH66 | AD-38 | Compound | 4.4 | 25.7 | 464 | 5.6 |
| | | | 119 | | | | |
| Example 6 | HT35/ETH66 | AD-38 | Compound | 4.6 | 24.8 | 459 | 4.7 |
| | | | 175 | | | | |
| Comparative | HT35/ETH66 | AD-38 | Compound | 5.1 | 21.7 | 466 | 1 |
| Example 1 | | | C1 | | | | |
| Comparative | HT35/ETH66 | AD-38 | Compound | 5.4 | 17.7 | 440 | 0.5 |
| Example 2 | | | C2 | | | | |
| Comparative | HT35/ETH66 | AD-38 | Compound | 5.1 | 19.5 | 463 | 2.9 |
| Example 3 | | | C3 | | | | |
| Comparative | HT35/ETH66 | AD-38 | Compound | 5.2 | 18.8 | 483 | 1.9 |
| Example 4 | | | C4 | | | | |

Referring to the results of Table 2, it could be confirmed that the light emitting elements of the Examples used the polycyclic compounds according to embodiments as light-emitting materials and showed lower driving voltages and improved emission efficiency and life-characteristics in contrast to the Comparative Examples.

Particularly, Comparative Example 1 and Comparative Example 3, using Comparative Compound C1 and Comparative Compound C3 as light-emitting materials, showed blue light emitting properties, but showed lower driving voltage properties and deteriorated results of emission efficiency and life-characteristics when compared to the light emitting elements of the Examples.

In addition, Comparative Compound C2 showed relatively very short wavelength in contrast to the polycyclic compounds of Examples, and Comparative Example 2 using Comparative Compound C2 as a light-emitting material showed markedly deteriorated emission efficiency results. Comparative Compound C2 used as the light-emitting material of Comparative Example 2 had an emission wavelength of about 440 nm, and energy transfer was not performed well, and it was confirmed that light emission of a metal complex, which is the fourth compound, was mainly shown and was markedly deteriorated.

Regarding Comparative Compound C4, the binding angle of a carbazole moiety sharing a benzene ring with the first aromatic ring of the core part violates multi resonance substitution standard. In order to show multi resonance effects by alternately positioning HOMO and LUMO, two nitrogen (N) atoms of the core part are required to face in para direction, and a nitrogen (N) atom and a sulfur (S) atom connected with the same benzene ring are not required to be connected at facing positions in a para direction or position. Comparative Compound C4 has a broken arrangement of HOMO/LUMO alternation, an orbital is not put in an atom but in a bond, and increased wavelength properties are shown in contrast to the compounds of the Examples. Accordingly, Comparative Example 4 using Comparative Compound C4 as a light-emitting material showed markedly deteriorated results of emission efficiency and life-characteristics in contrast to the Examples.

The light emitting element of an embodiment includes the polycyclic compound of an embodiment in an emission layer and may show high efficiency and long-life characteristics.

The polycyclic compound of an embodiment may contribute to the improvement of the efficiency and the increase of the lifetime of the light emitting element.

In addition, the display device of an embodiment includes the light emitting element showing the above-described effects, and may show improved quality of images and display efficiency.

Although example embodiments of the present disclosure have been described, it is understood that the present disclosure should not be limited to these embodiments, but various changes and modifications can be made by one ordinary skilled in the art within the spirit and scope of the present disclosure as hereinafter claimed.

What is claimed is:

1. A light emitting element, comprising:
a first electrode;
a second electrode on the first electrode; and
an emission layer between the first electrode and the second electrode, wherein:
the emission layer comprises a first compound represented by the following Formula 1: 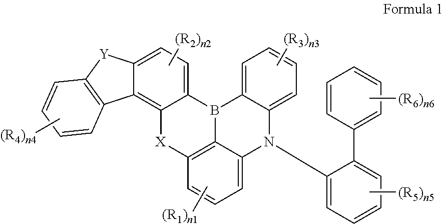
in Formula 1,
X is S, O, or Se,
Y is NR₇, S, O, or CR₈R₉,
R₁ to R₆ are each independently a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, or R₃ is combined with an adjacent group to form a ring,
R₇ to R₉ are each independently a substituted or unsubstituted aryl group of 6 to 30 ring-forming carbon atoms, or a substituted or unsubstituted heteroaryl group of 2 to 30 ring-forming carbon atoms, or R₈ and R₉ are combined with each other to form a ring,
n1 is an integer of 0 to 3,
n2 is an integer of 0 to 2,
n3, n4 and n5 are each independently an integer of 0 to 4, and
n6 is an integer of 0 to 5.

2. The light emitting element of claim 1, wherein the emission layer further comprises at least one among a second compound represented by the following Formula HT-1, and a third compound represented by the following Formula ET-1: 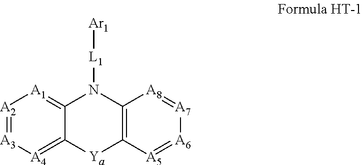
in Formula HT-1,
A₁ to A₈ are each independently N or CR₅₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₅₂R₅₃, or SiR₅₄R₅₅,
Ar₁ is a substituted or unsubstituted aryl group of 6 to 30 ring-forming carbon atoms, or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring: 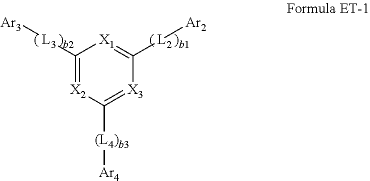
in Formula ET-1,
at least one among X₁ to X₃ is N, and the remainder are CR₅₆,
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms.

3. The light emitting element of claim 2, wherein the emission layer further comprises a fourth compound represented by the following Formula D-1: 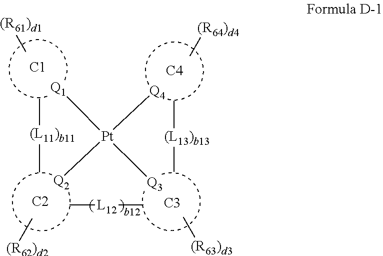
in Formula D-1,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₁₁ to L₁₃ are each independently a direct linkage, *—O—*, *—S—*, 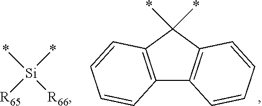
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and
d1 to d4 are each independently an integer of 0 to 4.

4. The light emitting element of claim 3, wherein the emission layer comprises the first compound, the second compound, the third compound, and the fourth compound.

5. The light emitting element of claim 1, wherein the emission layer emits delayed fluorescence.

6. The light emitting element of claim 1, wherein the first compound represented by Formula 1 is represented by the following Formula 2: 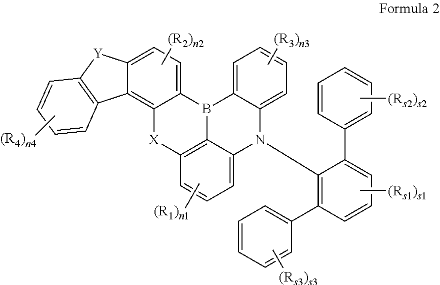
in Formula 2,
Rₛ₁, Rₛ₂, and Rₛ₃ are each independently a hydrogen atom, a deuterium atom, a substituted or unsubstituted alkyl group of 1 to 30 carbon atoms, or a substituted or unsubstituted aryl group of 6 to 30 ring-forming carbon atoms,
s1 is an integer of 0 to 3,
s2 and s3 are each independently an integer of 0 to 5, and
X, Y, R₁ to R₄, and n1 to n4 are the same as defined with respect to Formula 1.

7. The light emitting element of claim 1, wherein the first compound represented by Formula 1 is represented by the following Formula 3: 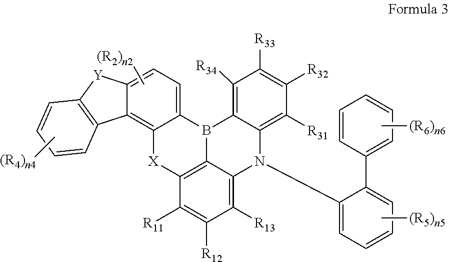
in Formula 3,
R₁₁, R₁₃, R₃₁, and R₃₄ are each independently a hydrogen atom or a deuterium atom,
R₁₂ is a substituted or unsubstituted amine group, a substituted or unsubstituted aryl group of 6 to 30 ring-forming carbon atoms, or a substituted or unsubstituted heteroaryl group of 2 to 30 ring-forming carbon atoms,
R₃₂ and R₃₃ are each independently a substituted or unsubstituted amine group, a substituted or unsubstituted aryl group of 6 to 30 ring-forming carbon atoms, or a substituted or unsubstituted heteroaryl group of 2 to 30 ring-forming carbon atoms, or R₃₂ and R₃₃ are combined with each other to form a ring, and
X, Y, R₂, R₄ to R₆, n2, and n4 to n6 are the same as defined with respect to Formula 1.

8. The light emitting element of claim 1, wherein the first compound represented by Formula 1 is represented by the following Formula 4: 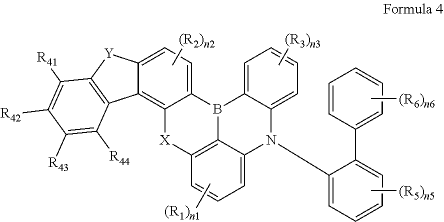
in Formula 4,
R₄₁, R₄₂, and R₄₄ are each independently a hydrogen atom or a deuterium atom,
R₄₃ is a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and
X, Y, R₁ to R₃, R₅, R₆, n1 to n3, n5 and n6 are the same as defined with respect to Formula 1.

9. The light emitting element of claim 1, wherein, the first compound represented by Formula 1 is represented by any one among the following Formula 5-1 to Formula 5-4: 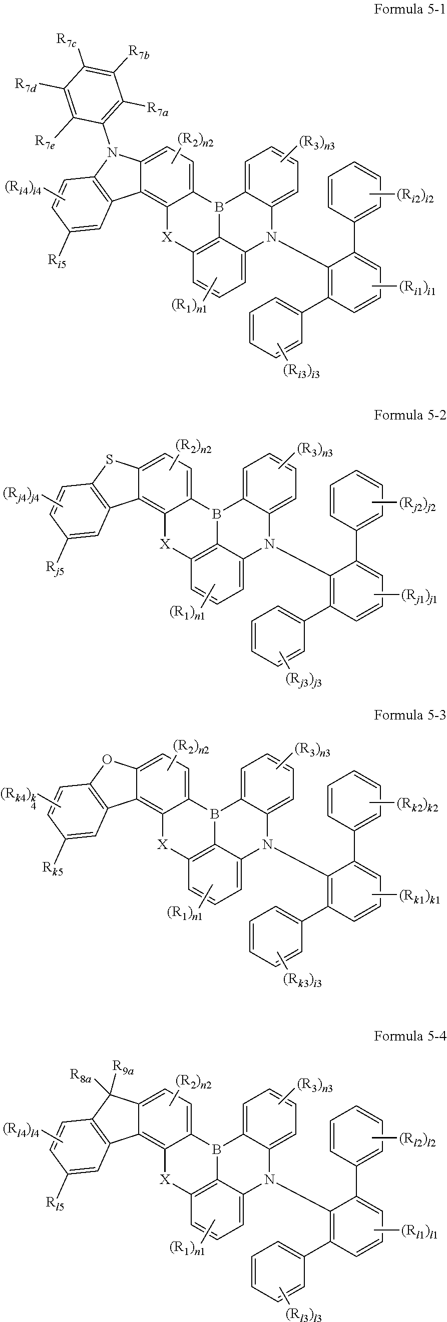
in Formula 5-1 to Formula 5-4,
Rᵢ₁ to Rᵢ₃, Rⱼ₁ to Rⱼ₃, Rₖ₁ to Rₖ₃, and Rₗ₁ to Rₗ₃ are each independently a hydrogen atom, a deuterium atom, a substituted or unsubstituted alkyl group of 1 to 30 carbon atoms, or a substituted or unsubstituted aryl group of 6 to 30 ring-forming carbon atoms,
Rᵢ₄, Rⱼ₄, Rₖ₄, and Rₗ₄ are each independently a hydrogen atom or a deuterium atom,
Rᵢ₅, Rⱼ₅, Rₖ₅, and Rₗ₅ are each independently a hydrogen atom, a deuterium atom, a substituted or unsubstituted aryl group of 6 to 30 ring-forming carbon atoms, or a substituted or unsubstituted heteroaryl group of 2 to 30 ring-forming carbon atoms,
R₇ₐ to R₇ₑ are each independently a hydrogen atom, a deuterium atom, a substituted or unsubstituted alkyl group of 1 to 10 carbon atoms, or a substituted or unsubstituted aryl group of 6 to 15 ring-forming carbon atoms,
R₈ₐ and R₉ₐ are each independently a substituted or unsubstituted aryl group of 6 to 30 ring-forming carbon atoms, or R₈ₐ and R₉ₐ are combined with each other to form a ring,
i1, i4, j1, j4, k1, k4, l1, and l4 are each independently an integer of 0 to 3,
i2, i3, j2, j3, k2, k3, l2, and l3 are each independently an integer of 0 to 5, and
X, R₁ to R₃, and n1 to n3 are the same as defined with respect to Formula 1.

10. The light emitting element of claim 1, wherein, n1 of Formula 1 is 1, and R₁ is represented by any one among SG1-1 to SG1-24 in the following Substituent Group 1, and
n3 of Formula 1 is 1 or 2, and R₃ is represented by any one among SG1-1 to SG1-25 in the following Substituent Group 1: 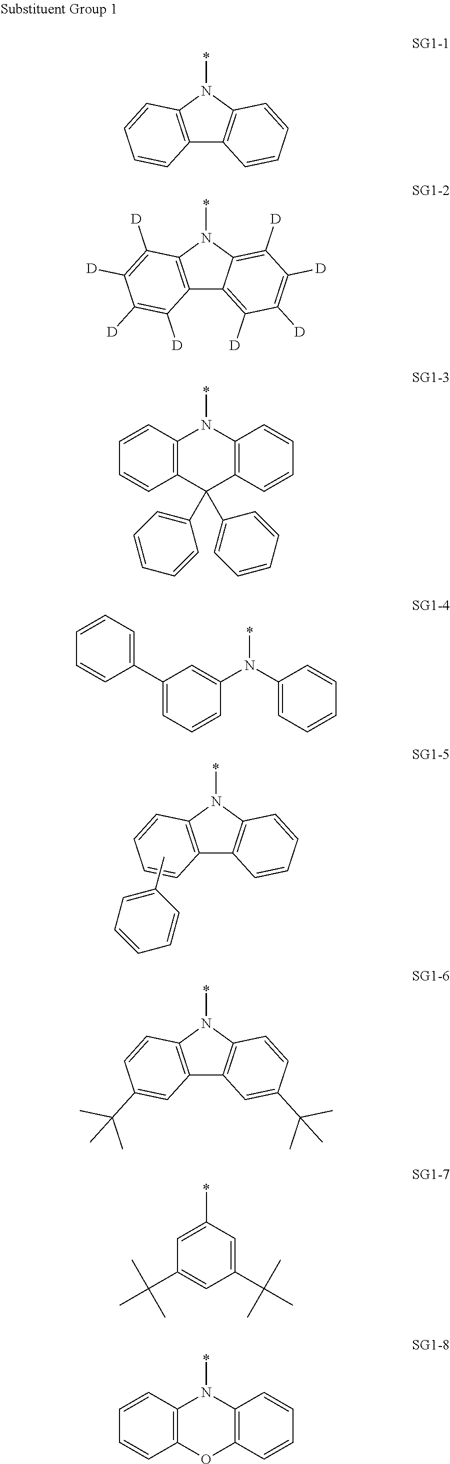 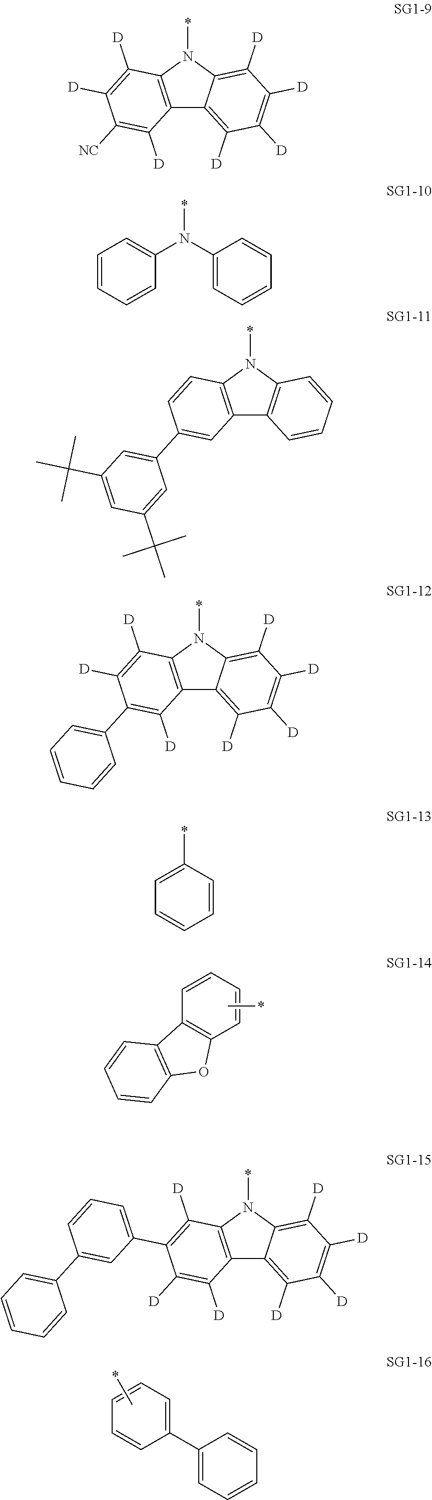 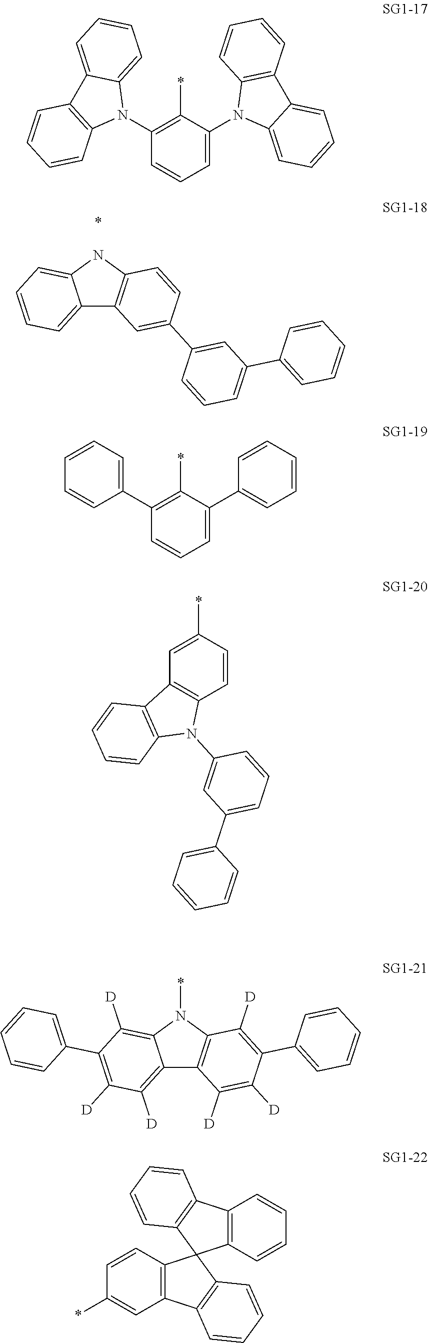 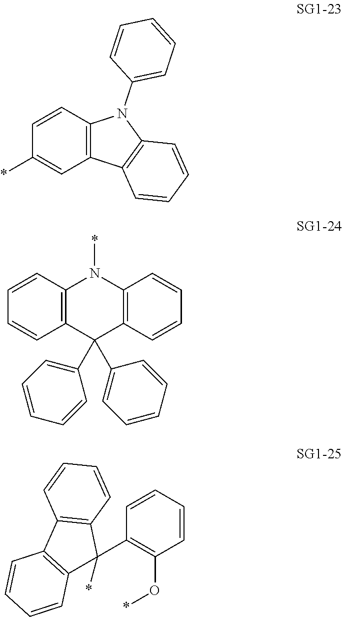
in Substituent Group 1, *— is a position connected with Formula 1, and “D” is a deuterium atom.

11. The light emitting element of claim 1, wherein R₄ of Formula 1 is a hydrogen atom or a deuterium atom, or represented by any one among SG2-1 to SG2-10 in the following Substituent Group 2: 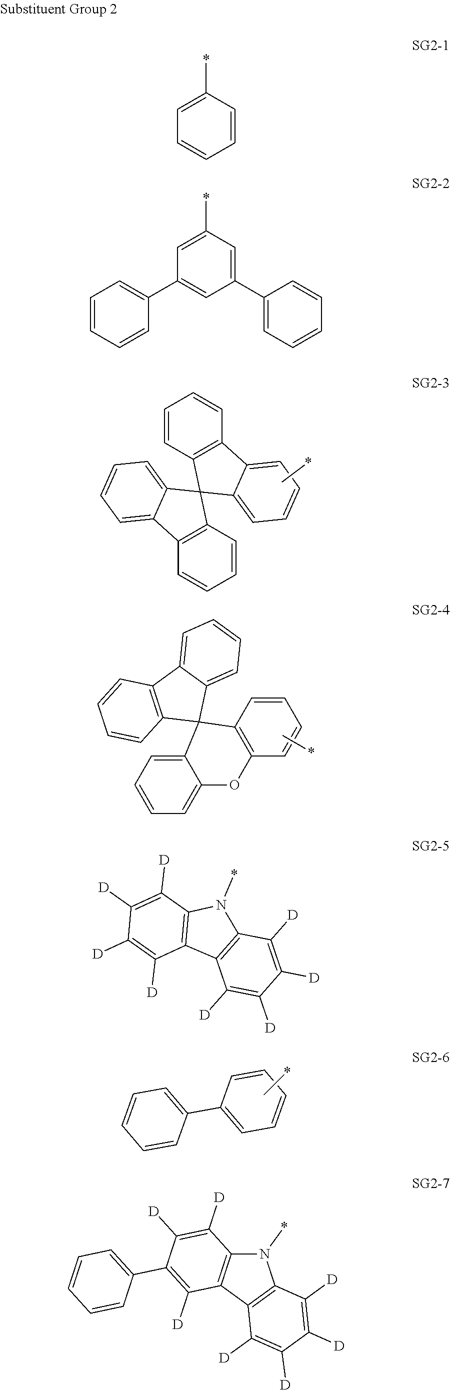 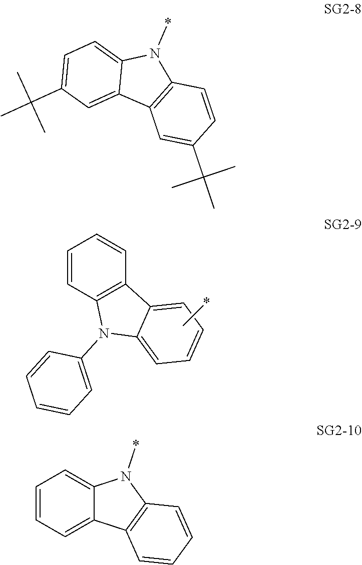
in Substituent Group 2, *— is a position connected with Formula 1, and D is a deuterium atom.

12. The light emitting element of claim 1, wherein the first compound is represented by any one among compounds in the following Compound Group 1: 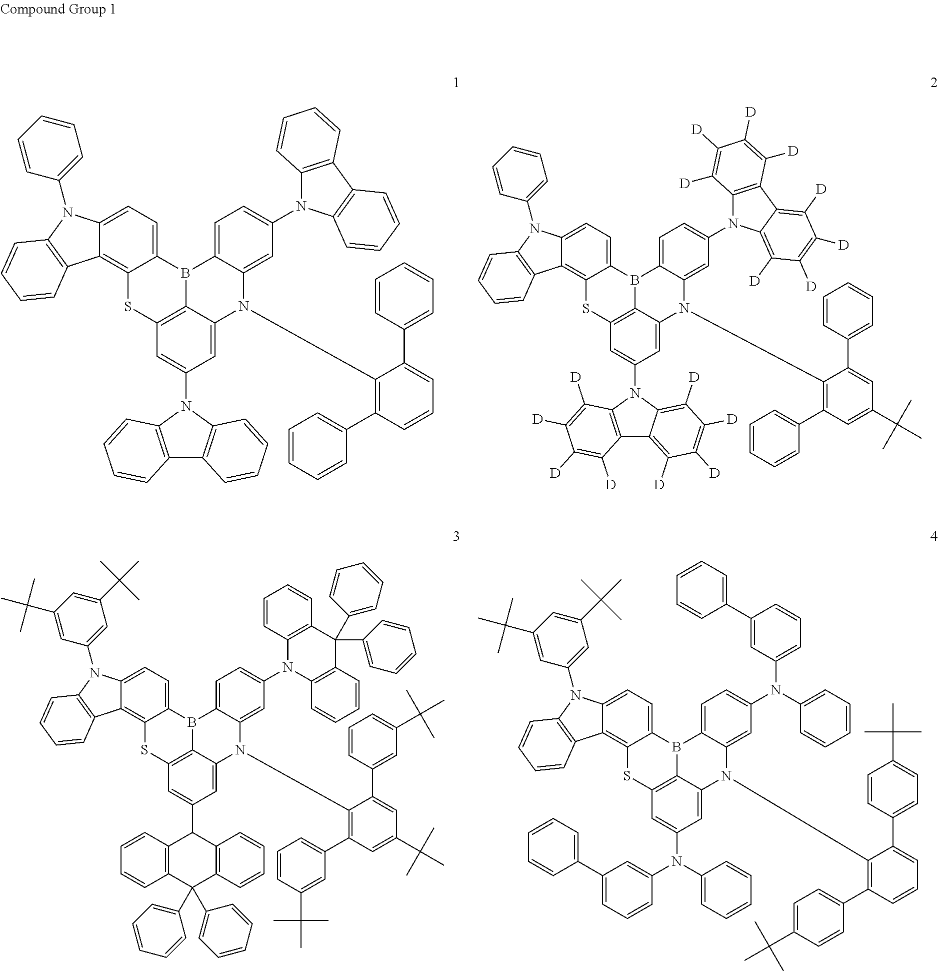 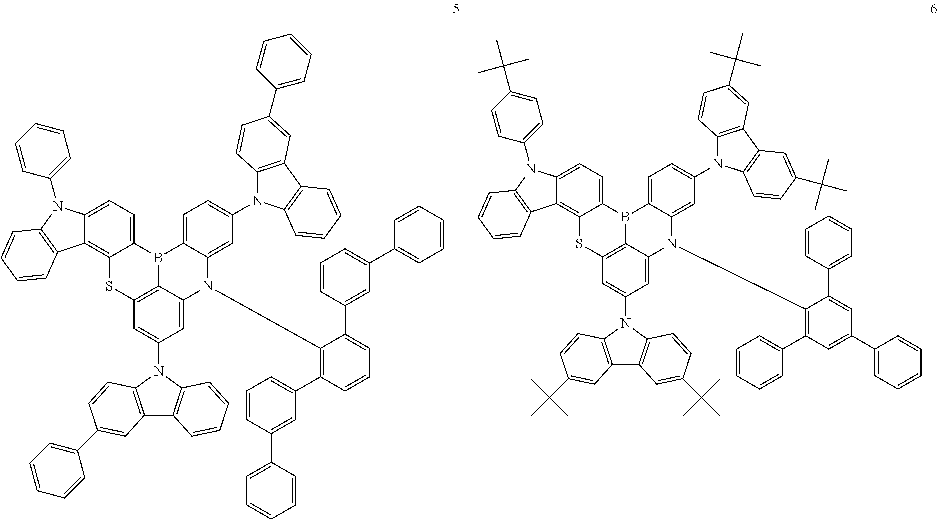 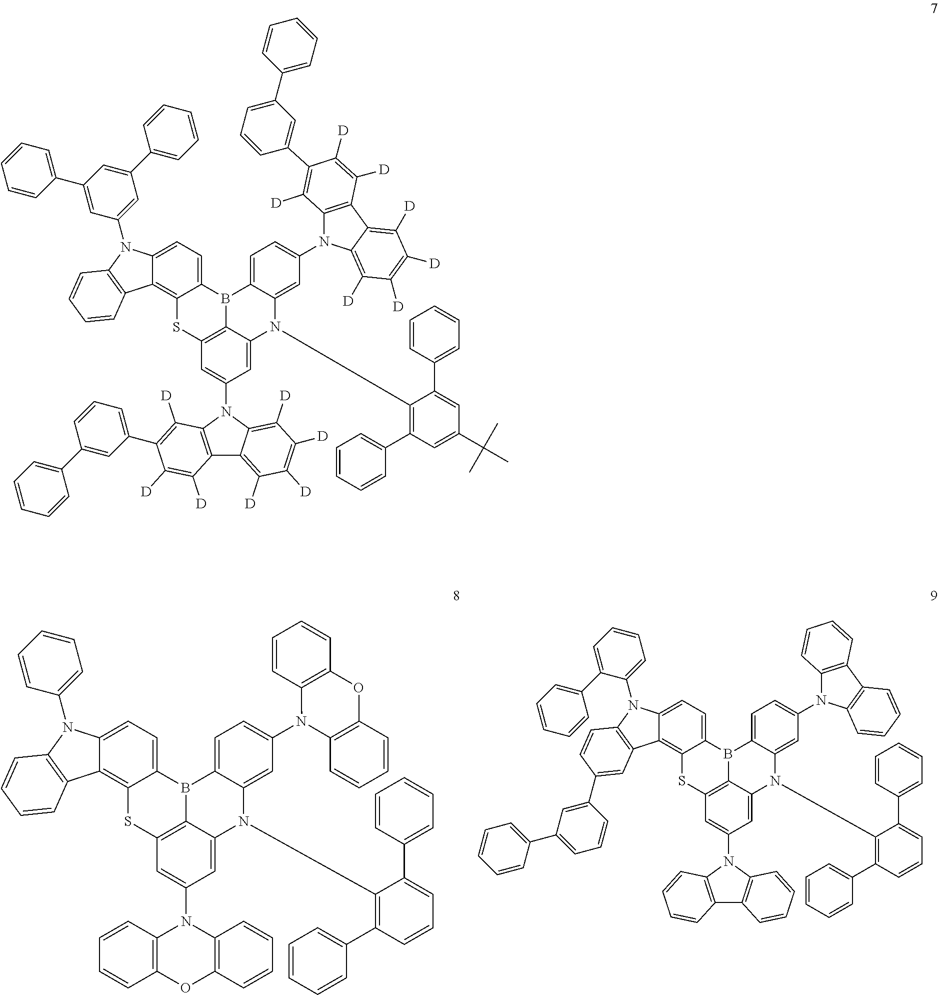 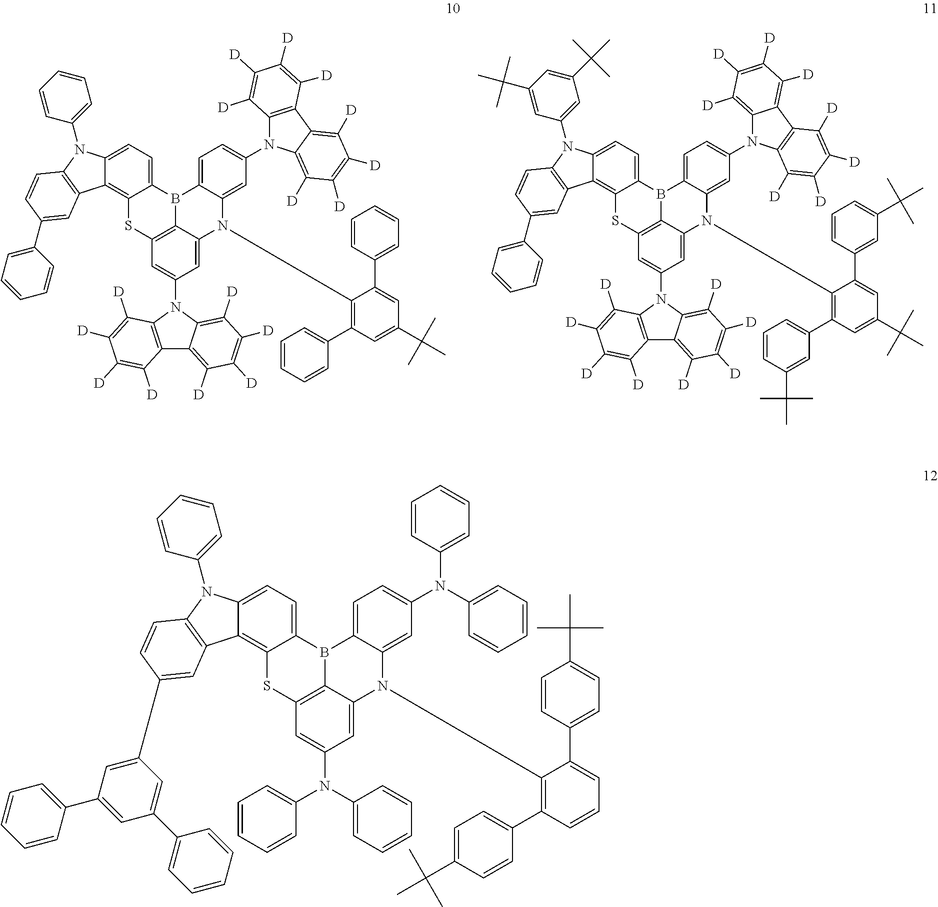 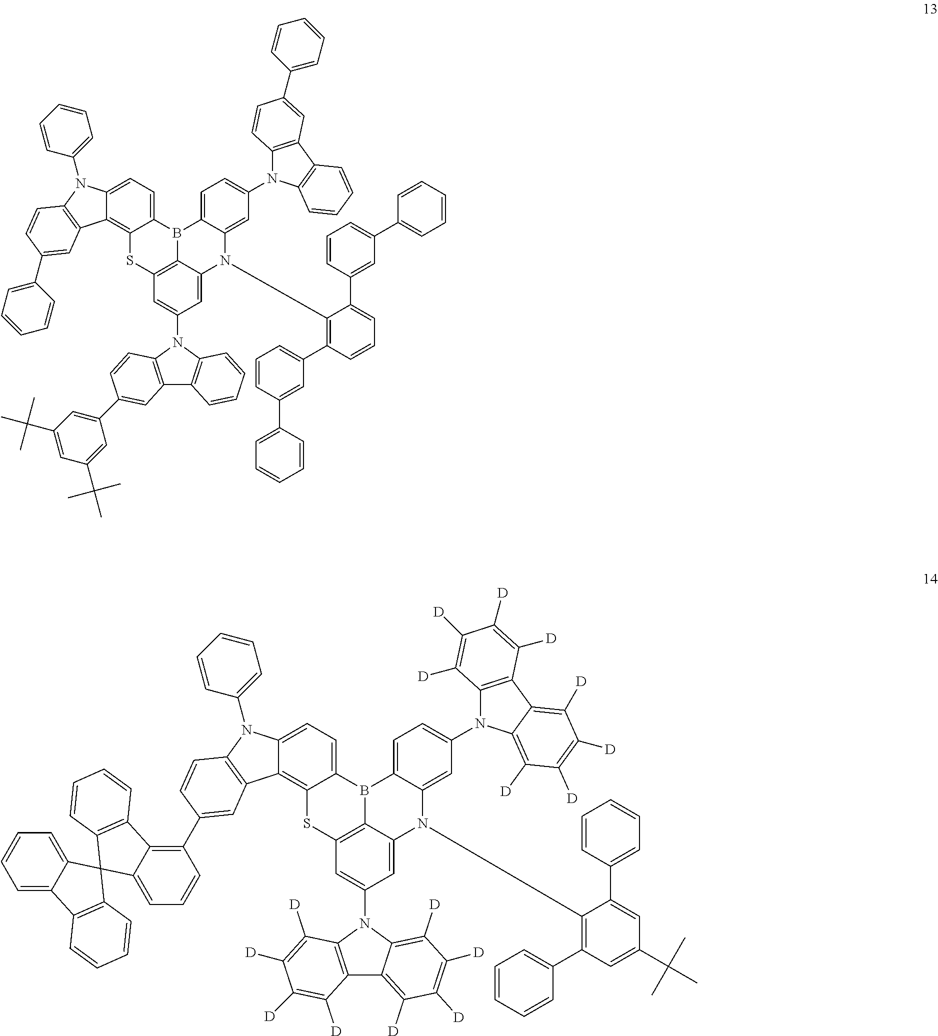 [SMILES: CC(C)(C)c1cc(-c2ccc3c(c2)c2ccccc2n3-c2cc3c4c(c2)N(c2c(-c5cccc(-c6ccccc6)c5)cccc2-c2cccc(-c5ccccc5)c2)c2cc(-n5c6ccccc6c6cc(-c7ccccc7)ccc65)ccc2B4c2ccc4c(c2S3)c2cc(-c3ccccc3)ccc2n4-c2ccccc2)cc(C(C)(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c([2H])c([2H])c([2H])c43)cc3c1B2c1ccc2c(c1S3)c1cc(-c3cccc4c3-c3ccccc3C43c4ccccc4-c4ccccc43)ccc1n2-c1ccccc1] 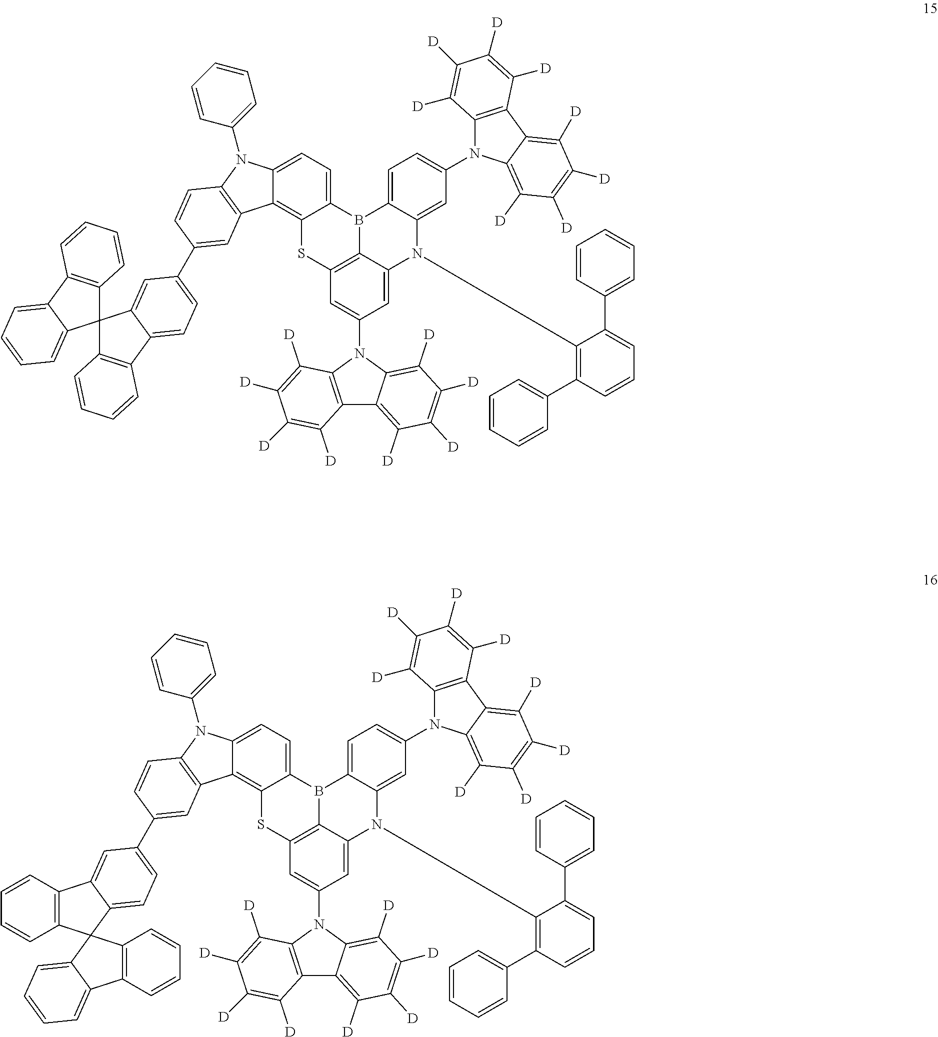 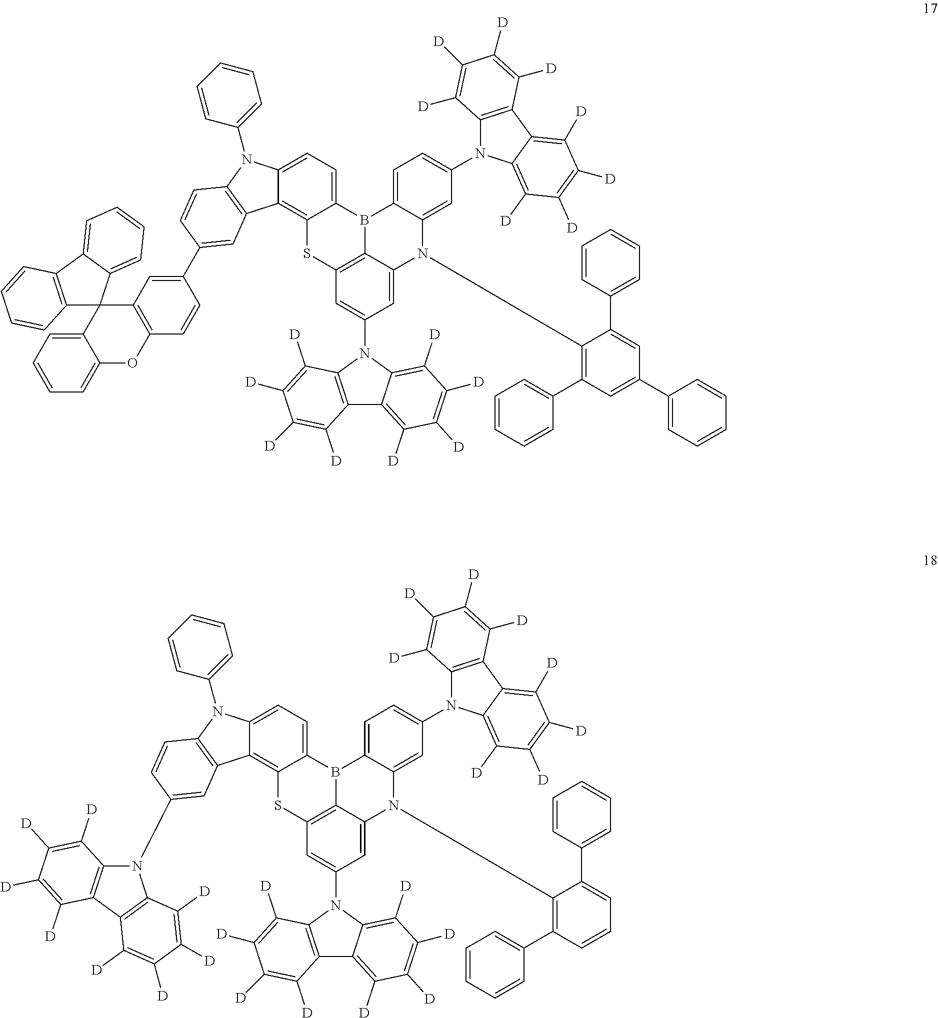 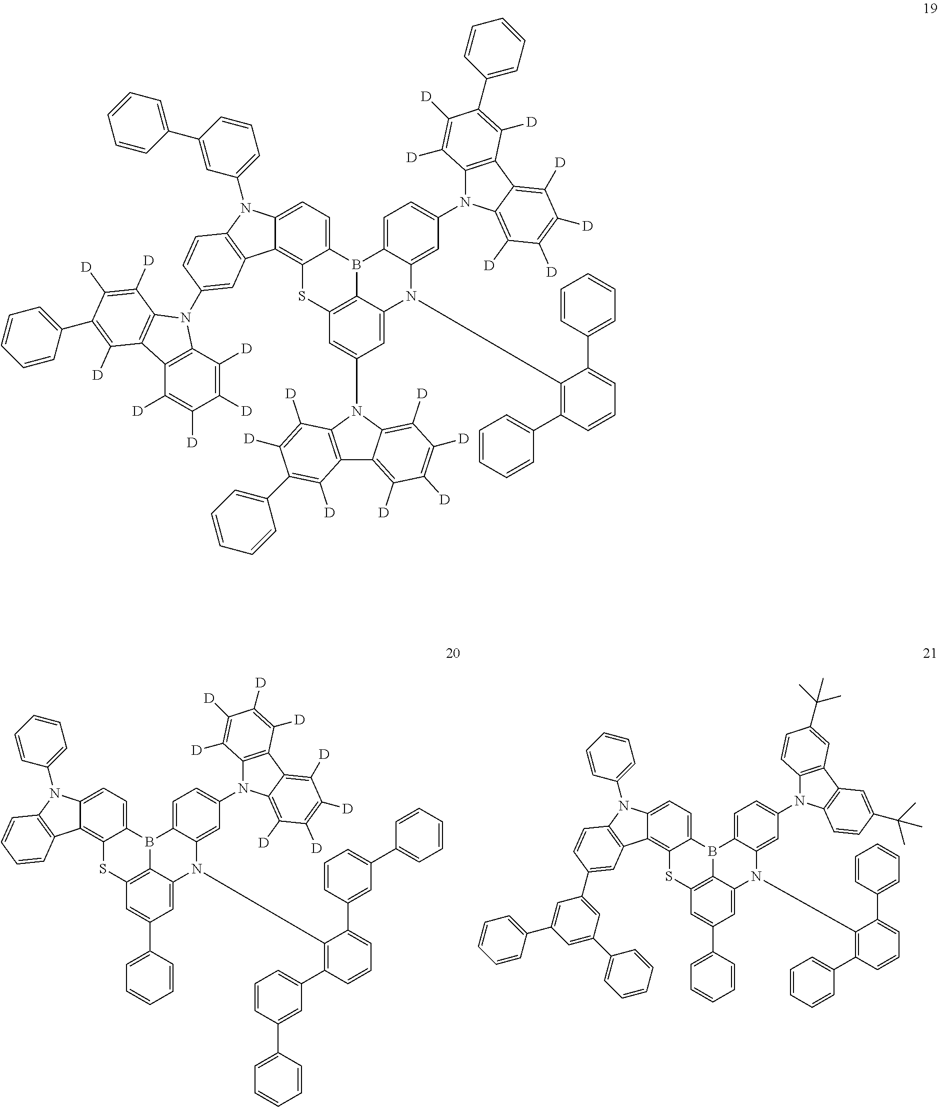 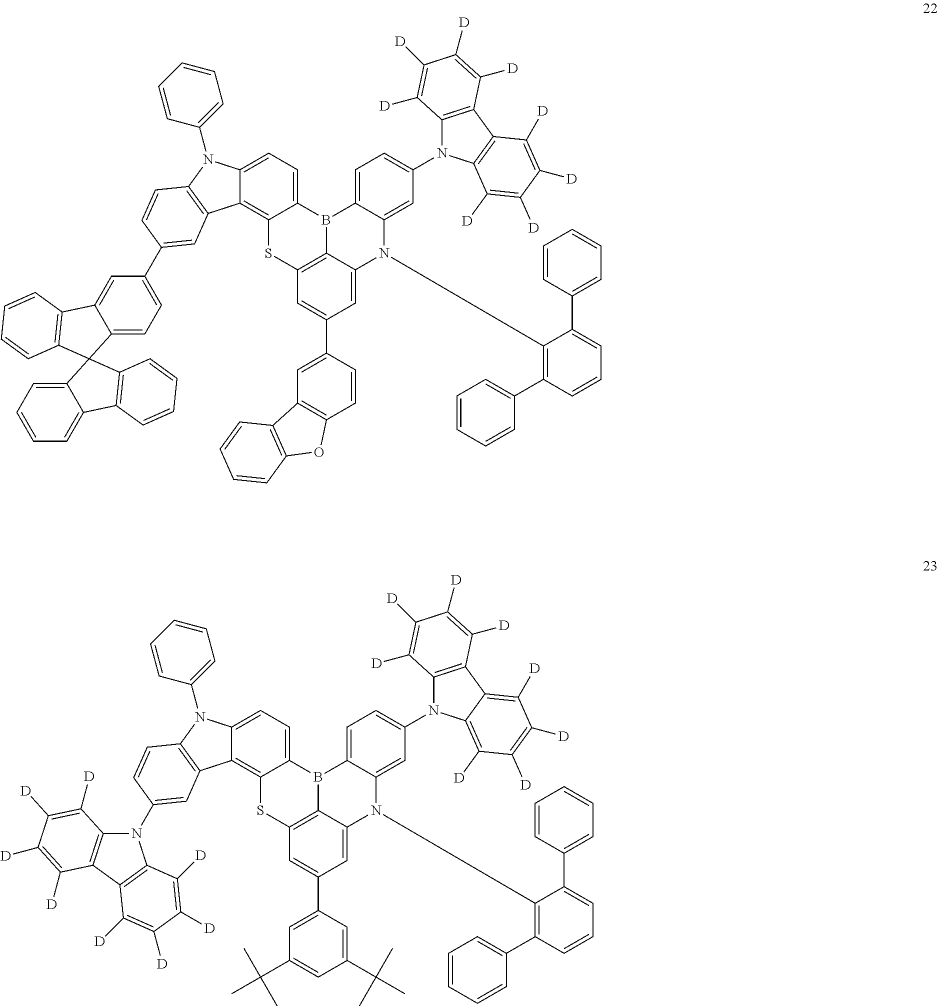 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc2c(c1S3)c1cc(-c3ccc4c(c3)-c3ccccc3C43c4ccccc4-c4ccccc43)ccc1n2-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(C(C)(C)C)cc(C(C)(C)C)c3)cc3c1B2c1ccc2c(c1S3)c1cc(-n3c4c([2H])c([2H])c([2H])c([2H])c4c4c([2H])c([2H])c([2H])c([2H])c43)ccc1n2-c1ccccc1] 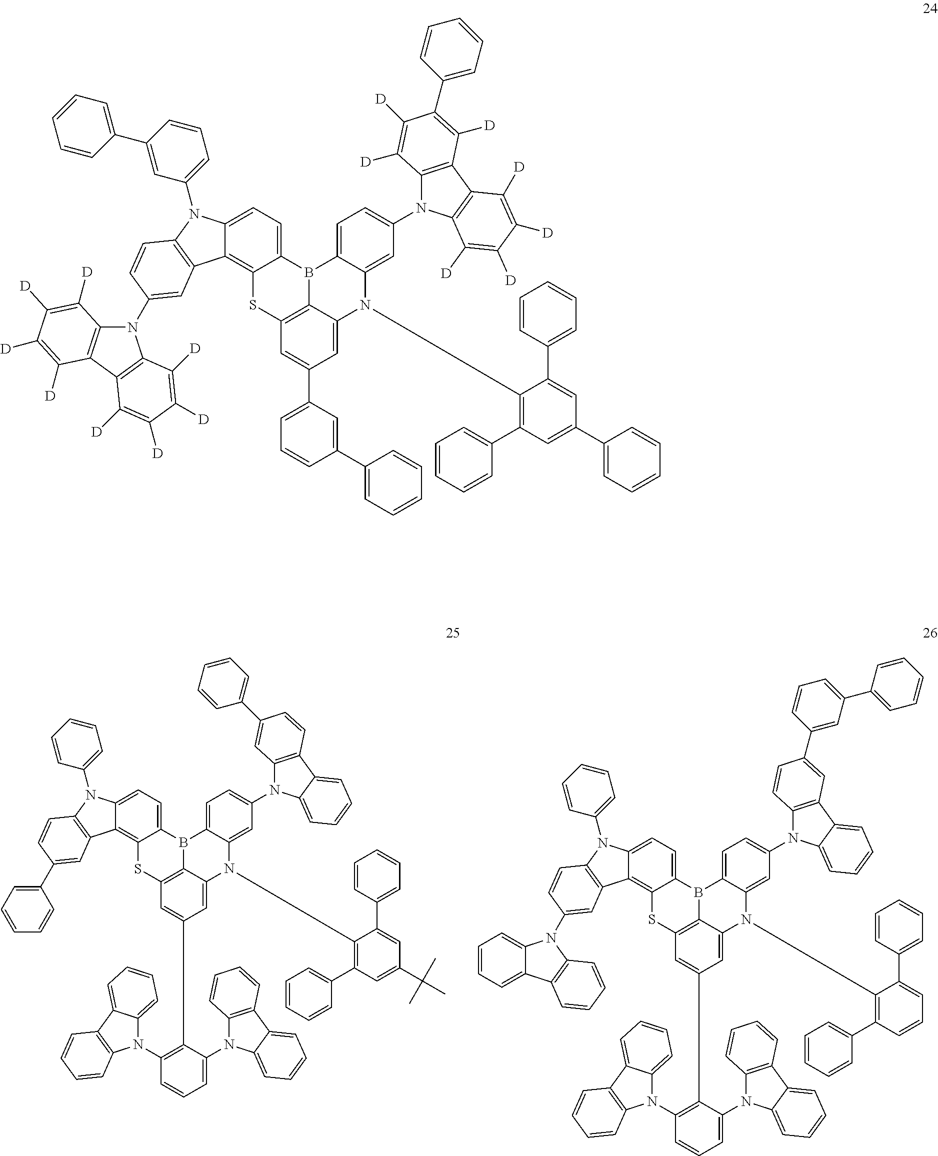 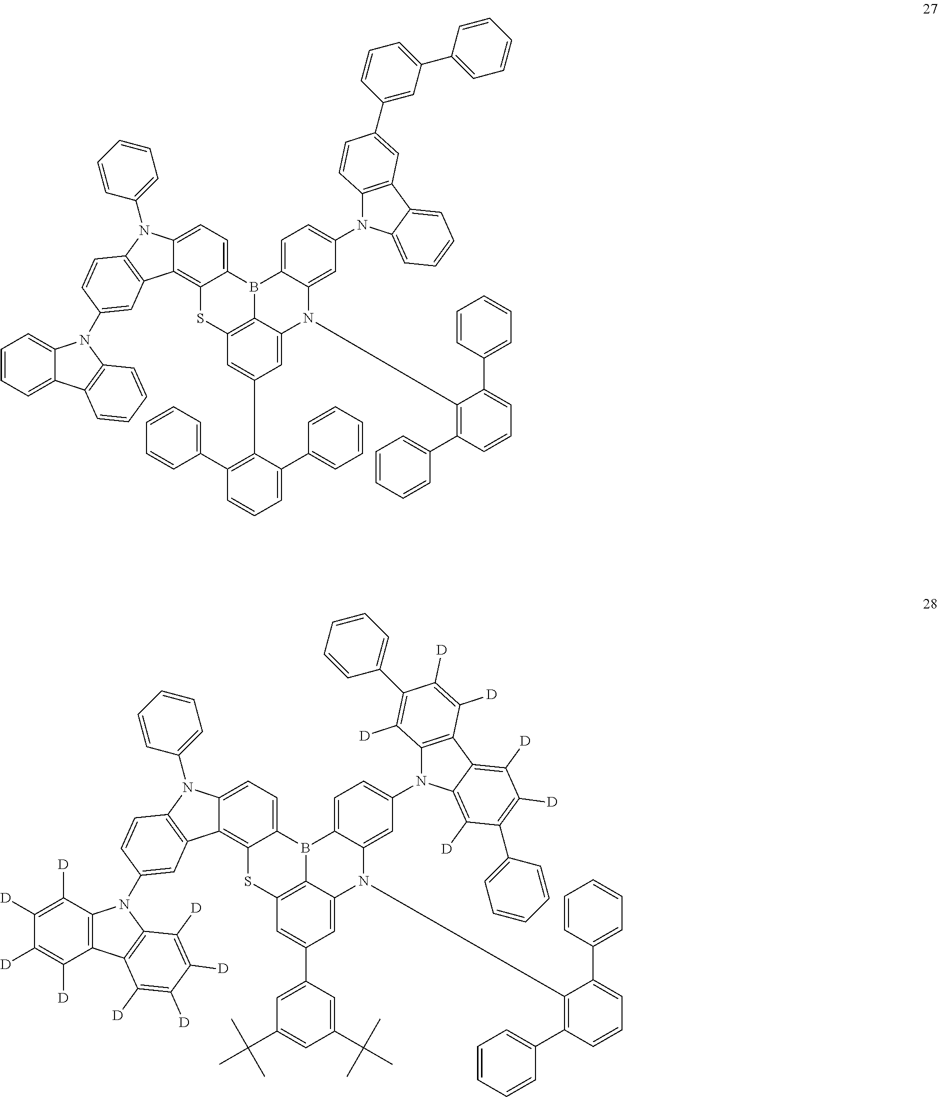 [SMILES: c1ccc(-c2cccc(-c3ccc4c(c3)c3ccccc3n4-c3ccc4c(c3)N(c3c(-c5ccccc5)cccc3-c3ccccc3)c3cc(-c5c(-c6ccccc6)cccc5-c5ccccc5)cc5c3B4c3ccc4c(c3S5)c3cc(-n5c6ccccc6c6ccccc65)ccc3n4-c3ccccc3)c2)cc1 ; [2H]c1c([2H])c([2H])c2c(c1[2H])c1c([2H])c([2H])c([2H])c([2H])c1n2-c1ccc2c(c1)c1c3c(ccc1n2-c1ccccc1)B1c2ccc(-n4c5c([2H])c(-c6ccccc6)c([2H])c([2H])c5c5c([2H])c([2H])c(-c6ccccc6)c([2H])c54)cc2N(c2c(-c4ccccc4)cccc2-c2ccccc2)c2cc(-c4cc(C(C)(C)C)cc(C(C)(C)C)c4)cc(c21)S3] 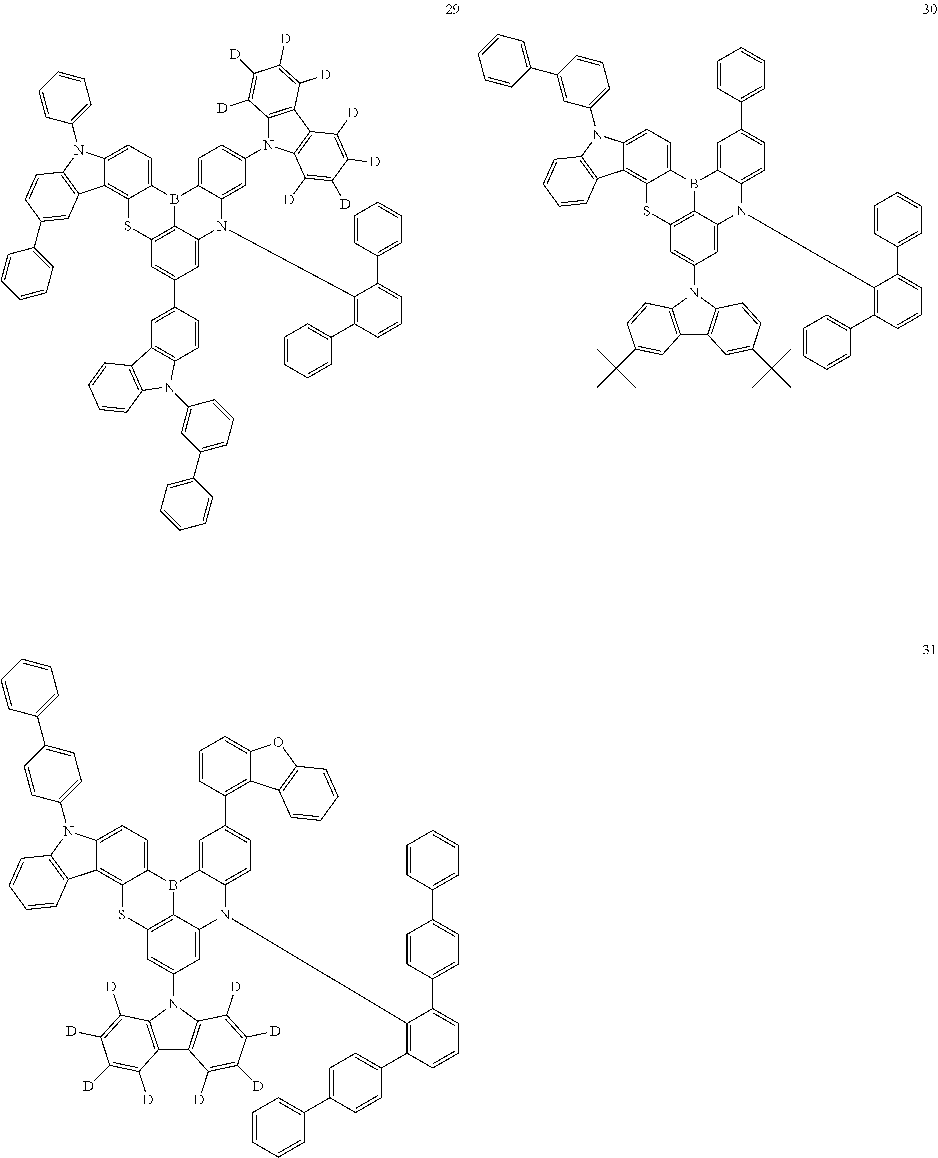 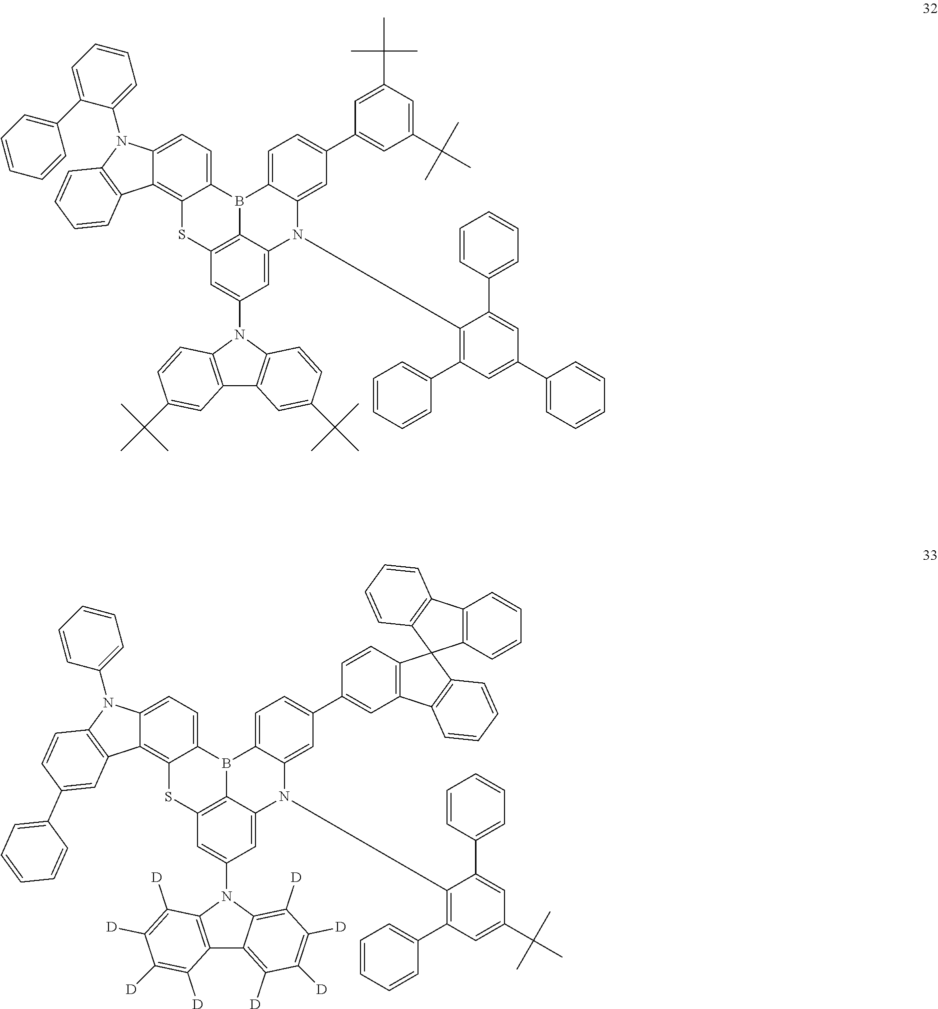 [SMILES: CC(C)(C)c1cc(-c2ccc3c(c2)N(c2c(-c4ccccc4)cc(-c4ccccc4)cc2-c2ccccc2)c2cc(-n4c5ccc(C(C)(C)C)cc5c5cc(C(C)(C)C)ccc54)cc4c2B3c2ccc3c(c2S4)c2ccccc2n3-c2ccccc2-c2ccccc2)cc(C(C)(C)C)c1 ; [2H]c1c([2H])c([2H])c2c(c1[2H])c1c([2H])c([2H])c([2H])c([2H])c1n2-c1cc2c3c(c1)N(c1c(-c4ccccc4)cc(C(C)(C)C)cc1-c1ccccc1)c1cc(-c4ccc5c(c4)-c4ccccc4C54c5ccccc5-c5ccccc54)ccc1B3c1ccc3c(c1S2)c1cc(-c2ccccc2)ccc1n3-c1ccccc1] 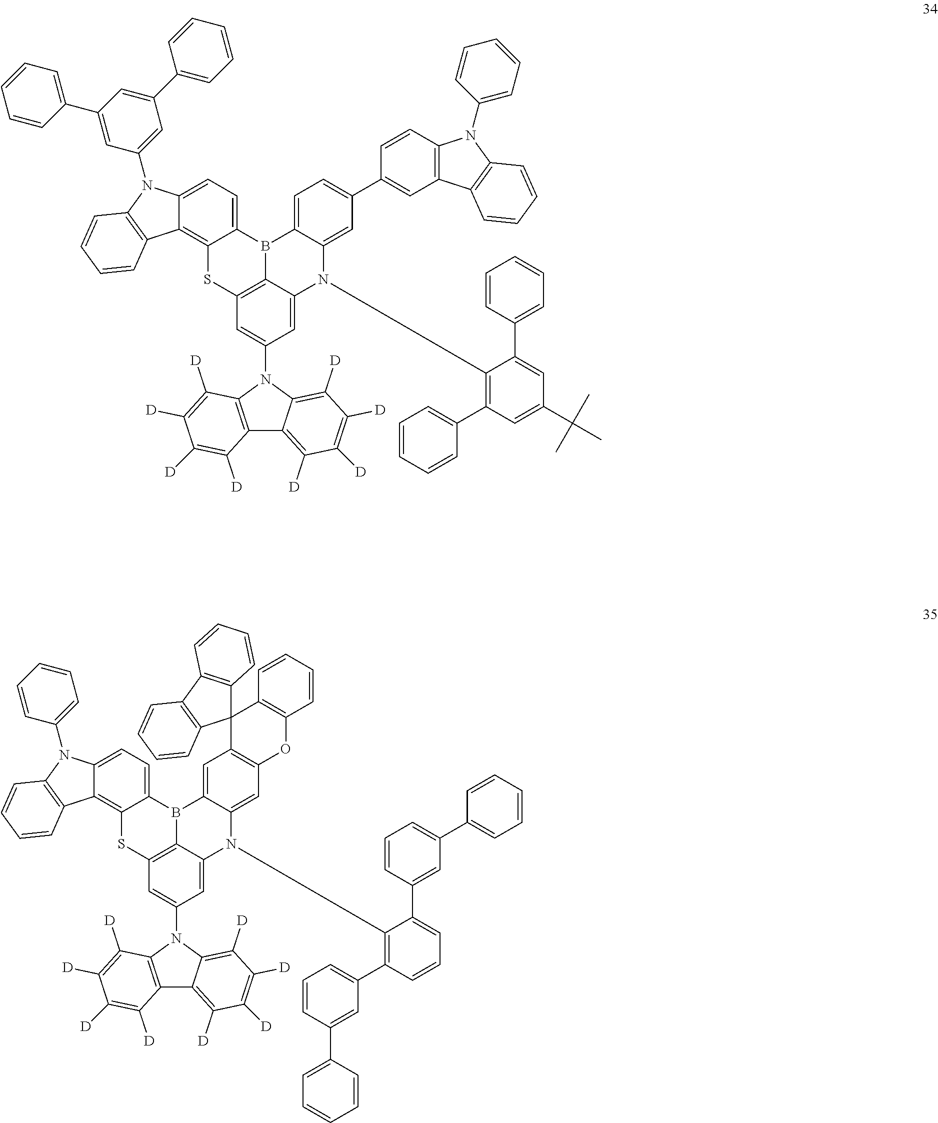 [SMILES: [2H]c1c([2H])c([2H])c2c(c1[2H])c1c([2H])c([2H])c([2H])c([2H])c1n2-c1cc2c3c(c1)N(c1c(-c4ccccc4)cc(C(C)(C)C)cc1-c1ccccc1)c1cc(-c4ccc5c(c4)c4ccccc4n5-c4ccccc4)ccc1B3c1ccc3c(c1S2)c1ccccc1n3-c1cc(-c2ccccc2)cc(-c2ccccc2)c1 ; [2H]c1c([2H])c([2H])c2c(c1[2H])c1c([2H])c([2H])c([2H])c([2H])c1n2-c1cc2c3c(c1)N(c1c(-c4cccc(-c5ccccc5)c4)cccc1-c1cccc(-c4ccccc4)c1)c1cc4c(cc1B3c1ccc3c(c1S2)c1ccccc1n3-c1ccccc1)C1(c2ccccc2O4)c2ccccc2-c2ccccc21] 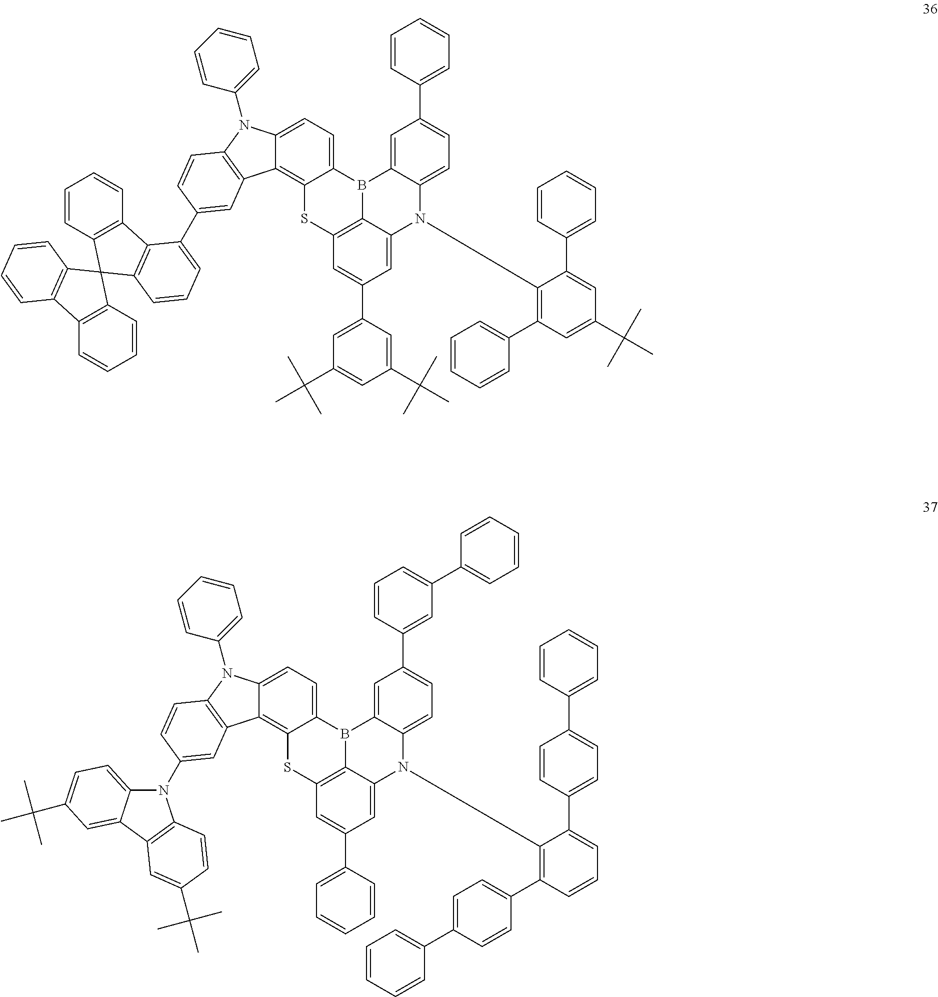 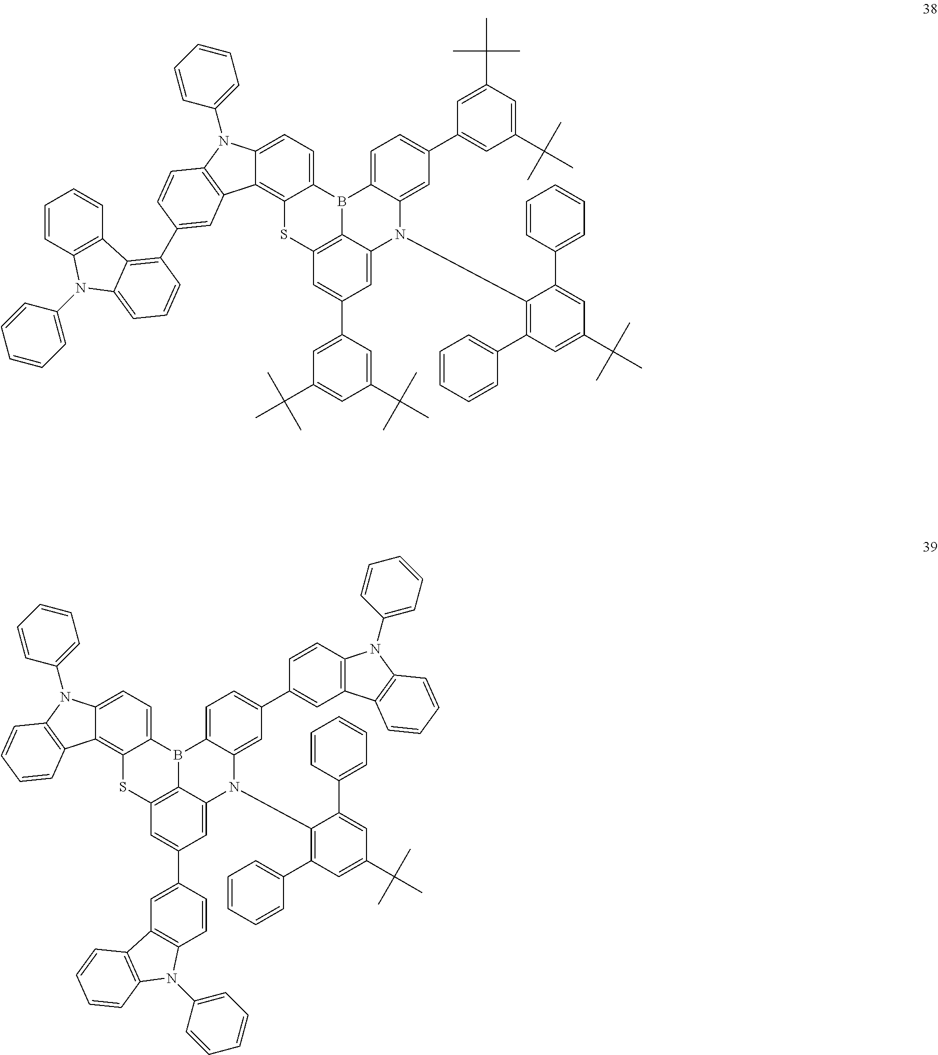 [SMILES: CC(C)(C)c1cc(-c2ccc3c(c2)N(c2c(-c4ccccc4)cc(C(C)(C)C)cc2-c2ccccc2)c2cc(-c4cc(C(C)(C)C)cc(C(C)(C)C)c4)cc4c2B3c2ccc3c(c2S4)c2cc(-c4cccc5c4c4ccccc4n5-c4ccccc4)ccc2n3-c2ccccc2)cc(C(C)(C)C)c1 ; CC(C)(C)c1cc(-c2ccccc2)c(N2c3cc(-c4ccc5c(c4)c4ccccc4n5-c4ccccc4)ccc3B3c4ccc5c(c4Sc4cc(-c6ccc7c(c6)c6ccccc6n7-c6ccccc6)cc2c43)c2ccccc2n5-c2ccccc2)c(-c2ccccc2)c1] 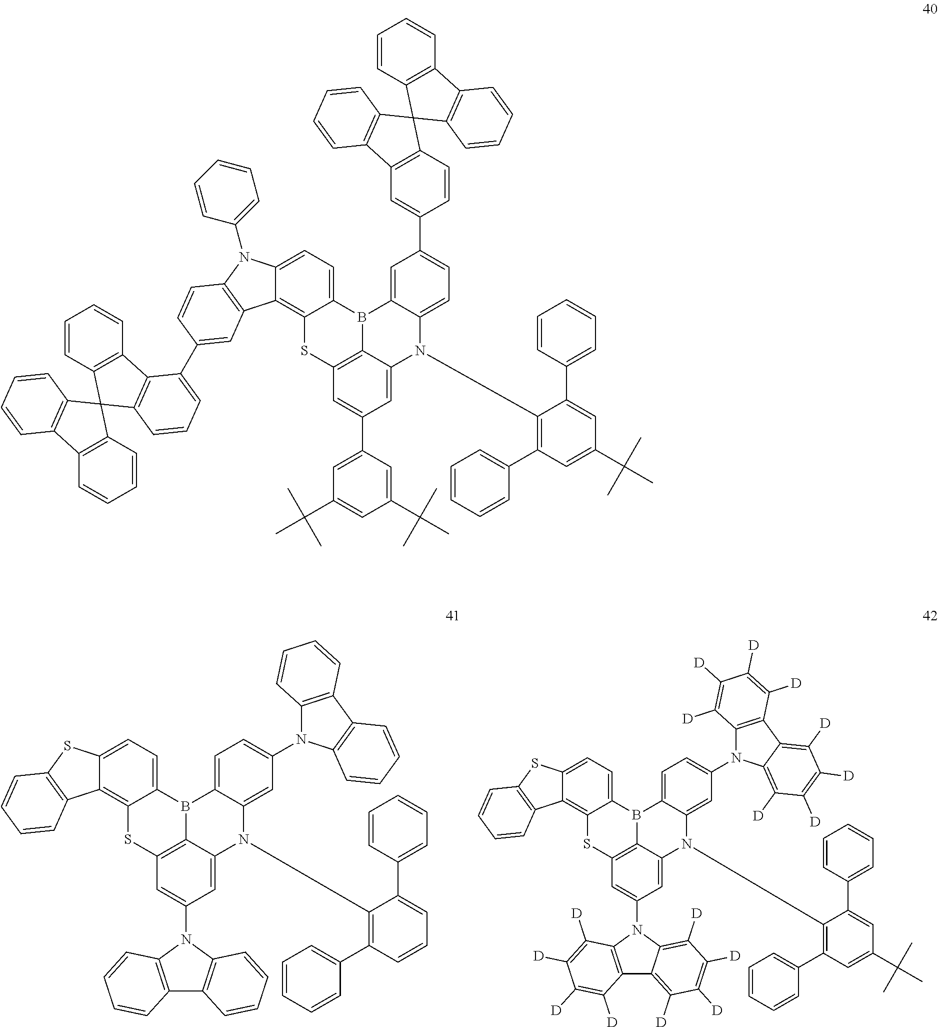 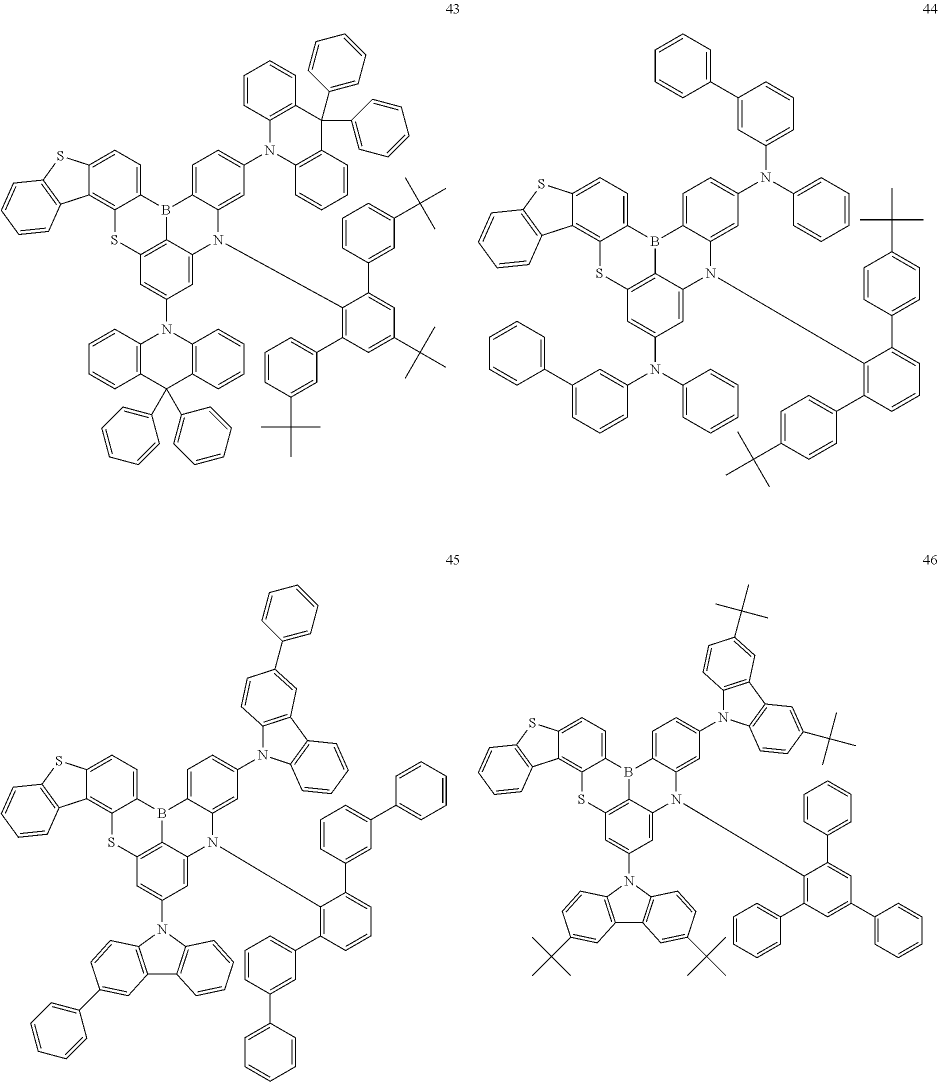 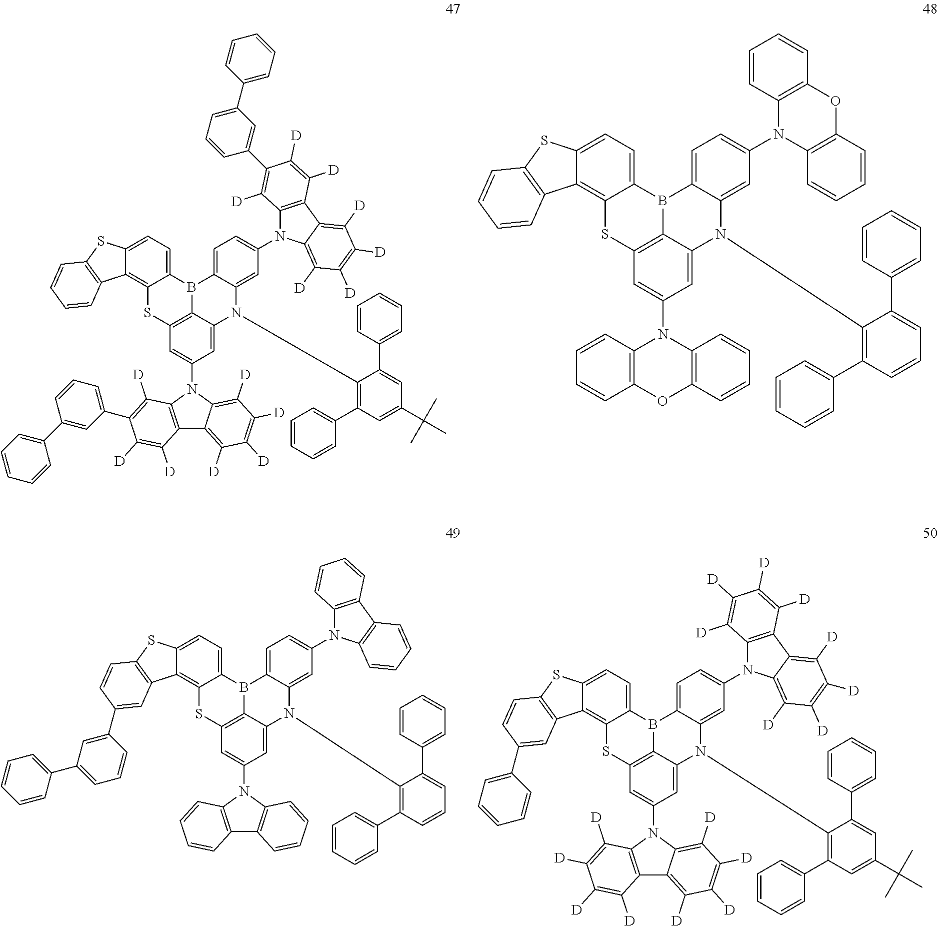 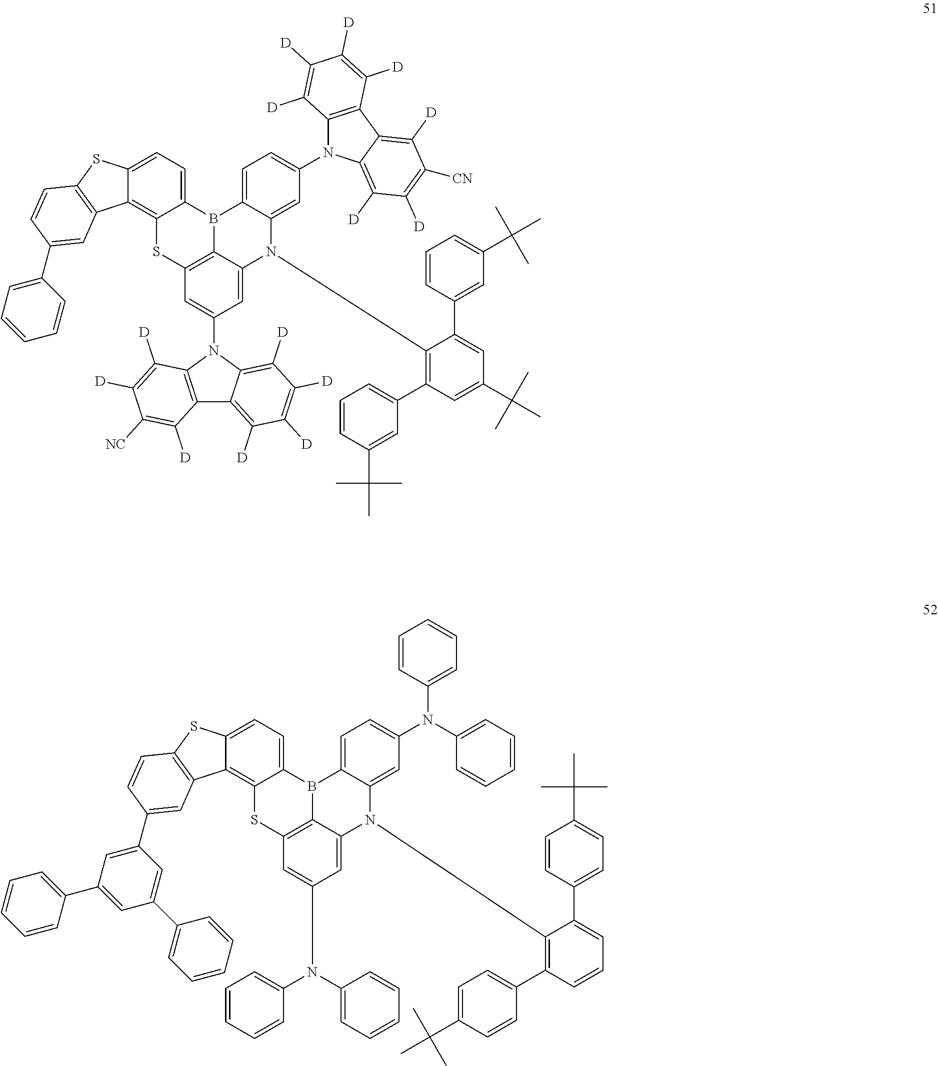 [SMILES: [2H]c1c([2H])c([2H])c2c(c1[2H])c1c([2H])c(C#N)c([2H])c([2H])c1n2-c1ccc2c(c1)N(c1c(-c3cccc(C(C)(C)C)c3)cc(C(C)(C)C)cc1-c1cccc(C(C)(C)C)c1)c1cc(-n3c4c([2H])c([2H])c([2H])c([2H])c4c4c([2H])c(C#N)c([2H])c([2H])c43)cc3c1B2c1ccc2sc4ccc(-c5ccccc5)cc4c2c1S3 ; CC(C)(C)c1ccc(-c2cccc(-c3ccc(C(C)(C)C)cc3)c2N2c3cc(N(c4ccccc4)c4ccccc4)ccc3B3c4ccc5sc6ccc(-c7cc(-c8ccccc8)cc(-c8ccccc8)c7)cc6c5c4Sc4cc(N(c5ccccc5)c5ccccc5)cc2c43)cc1] 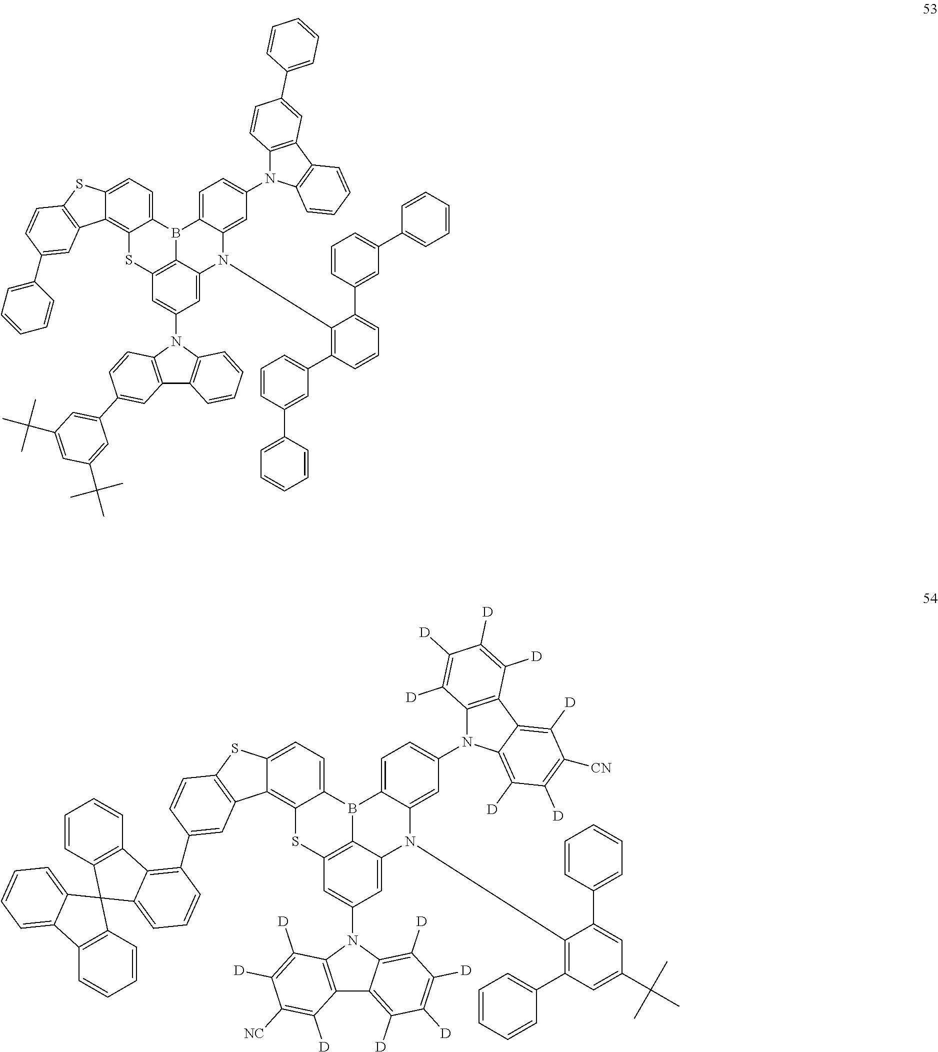 [SMILES: CC(C)(C)c1cc(-c2ccc3c(c2)c2ccccc2n3-c2cc3c4c(c2)N(c2c(-c5cccc(-c6ccccc6)c5)cccc2-c2cccc(-c5ccccc5)c2)c2cc(-n5c6ccccc6c6cc(-c7ccccc7)ccc65)ccc2B4c2ccc4sc5ccc(-c6ccccc6)cc5c4c2S3)cc(C(C)(C)C)c1 ; [2H]c1c([2H])c([2H])c2c(c1[2H])c1c([2H])c(C#N)c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c(C#N)c([2H])c([2H])c43)cc3c1B2c1ccc2sc4ccc(-c5cccc6c5-c5ccccc5C65c6ccccc6-c6ccccc65)cc4c2c1S3] 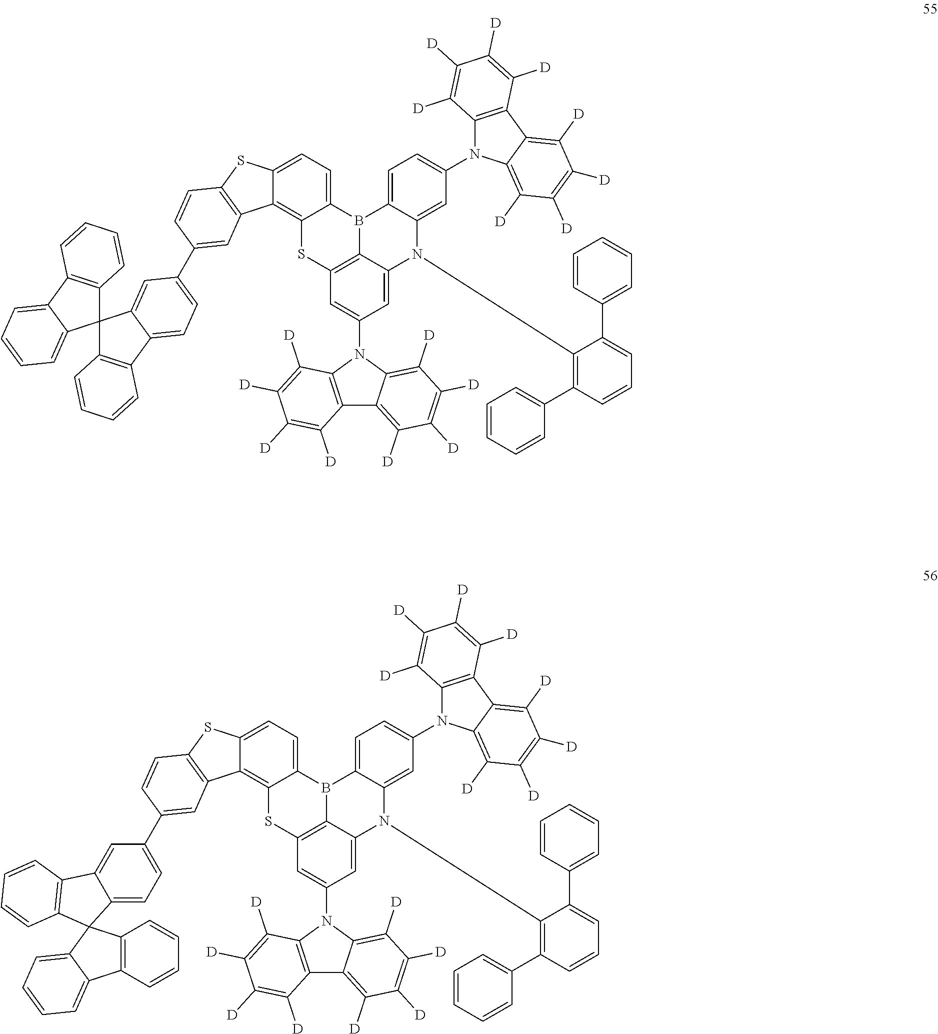 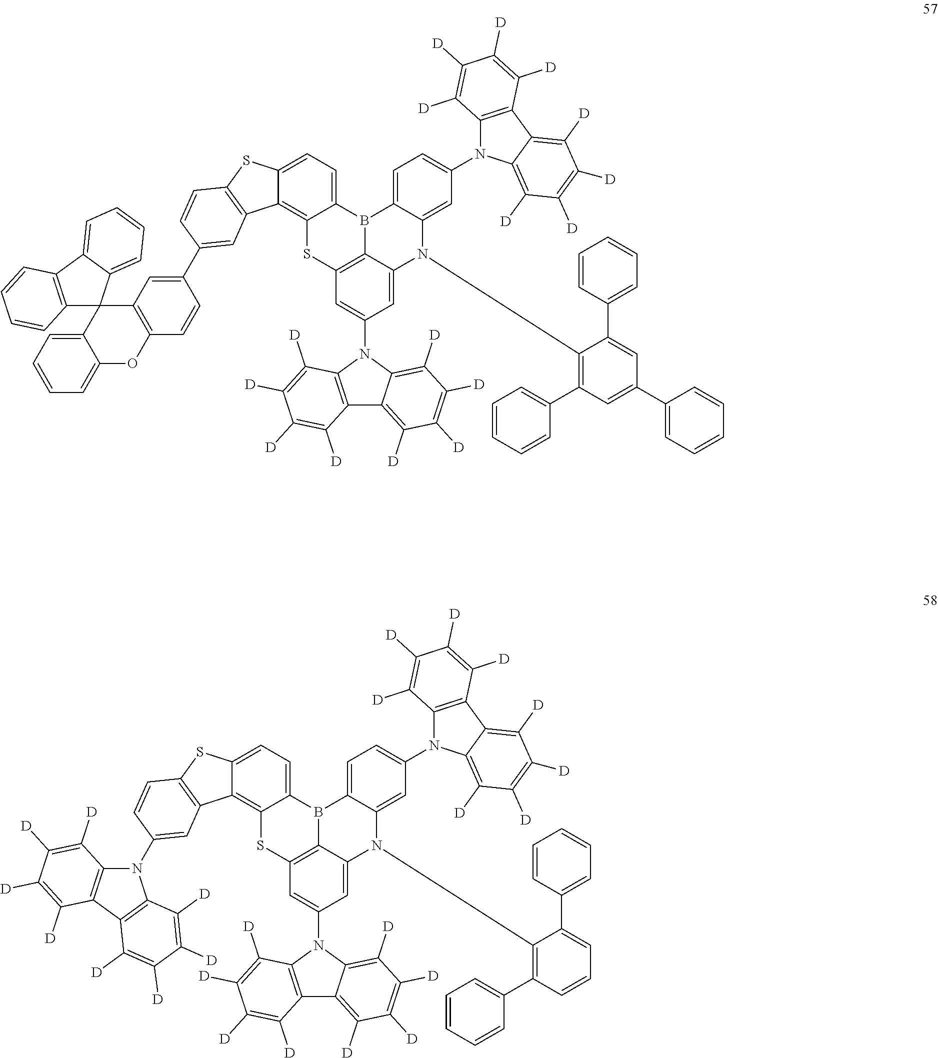 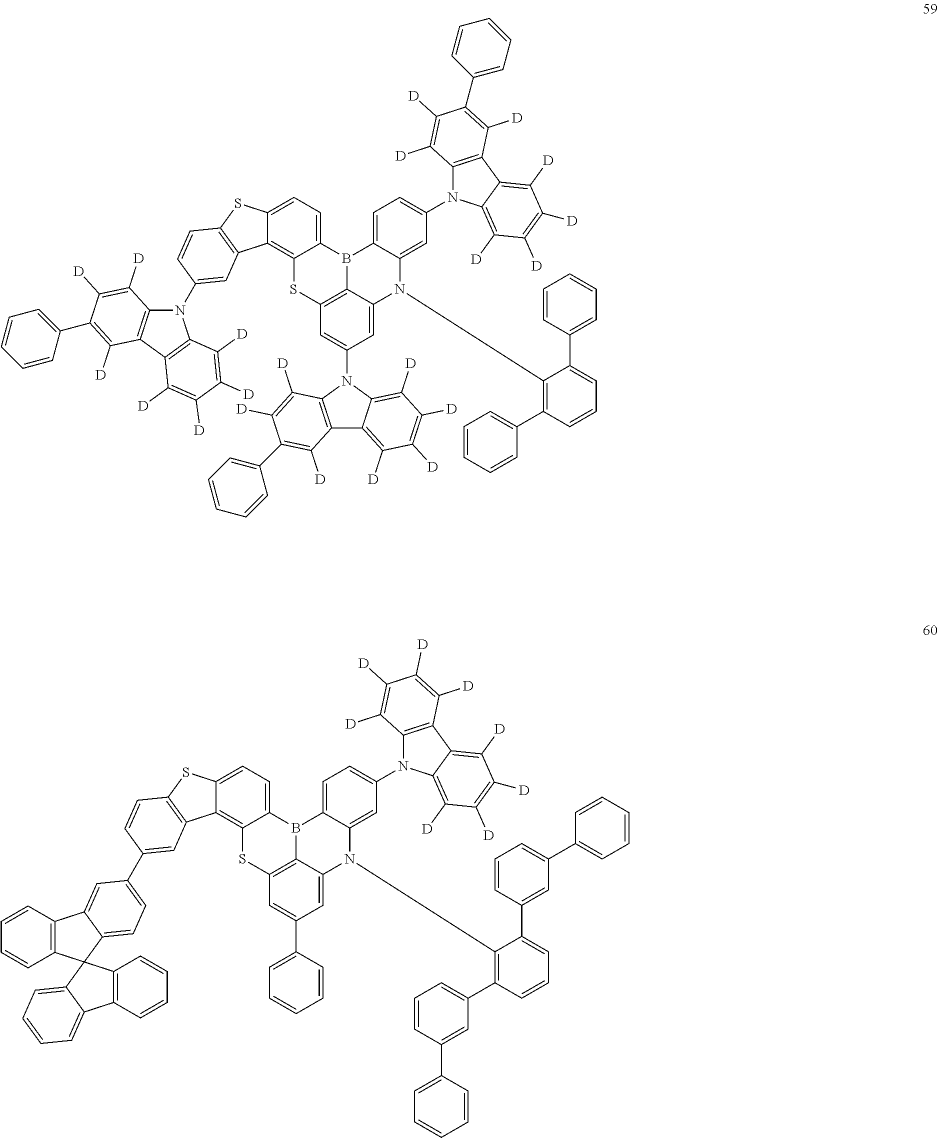 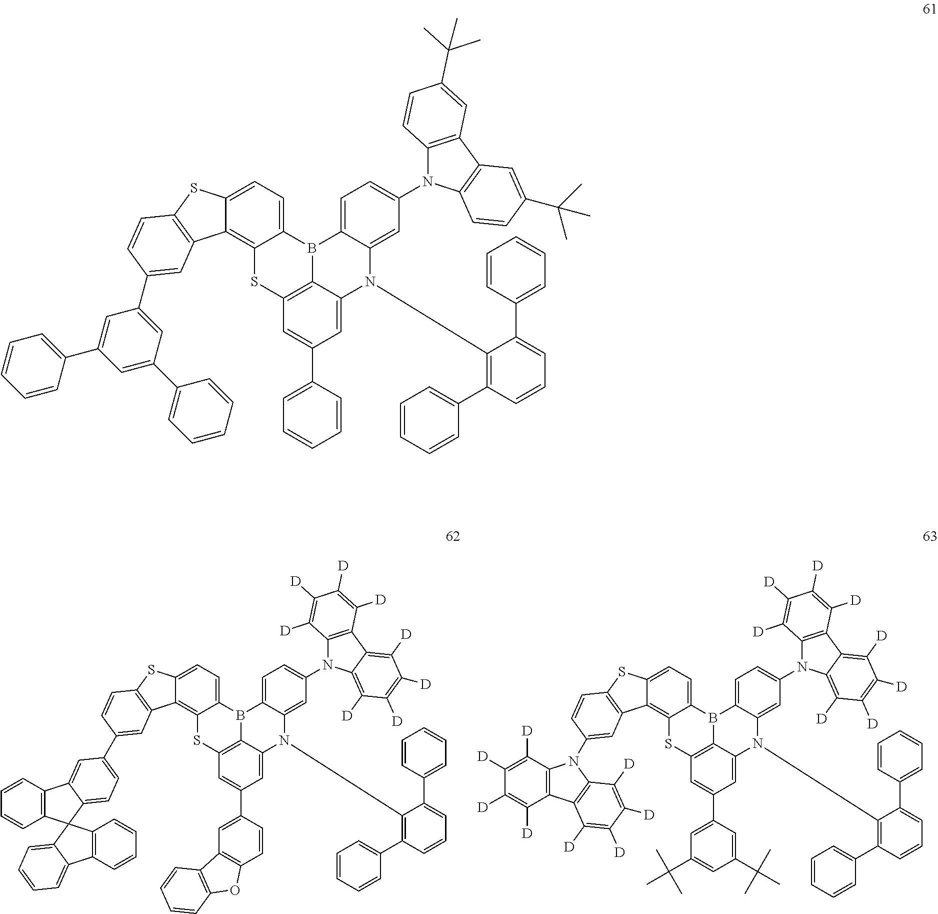 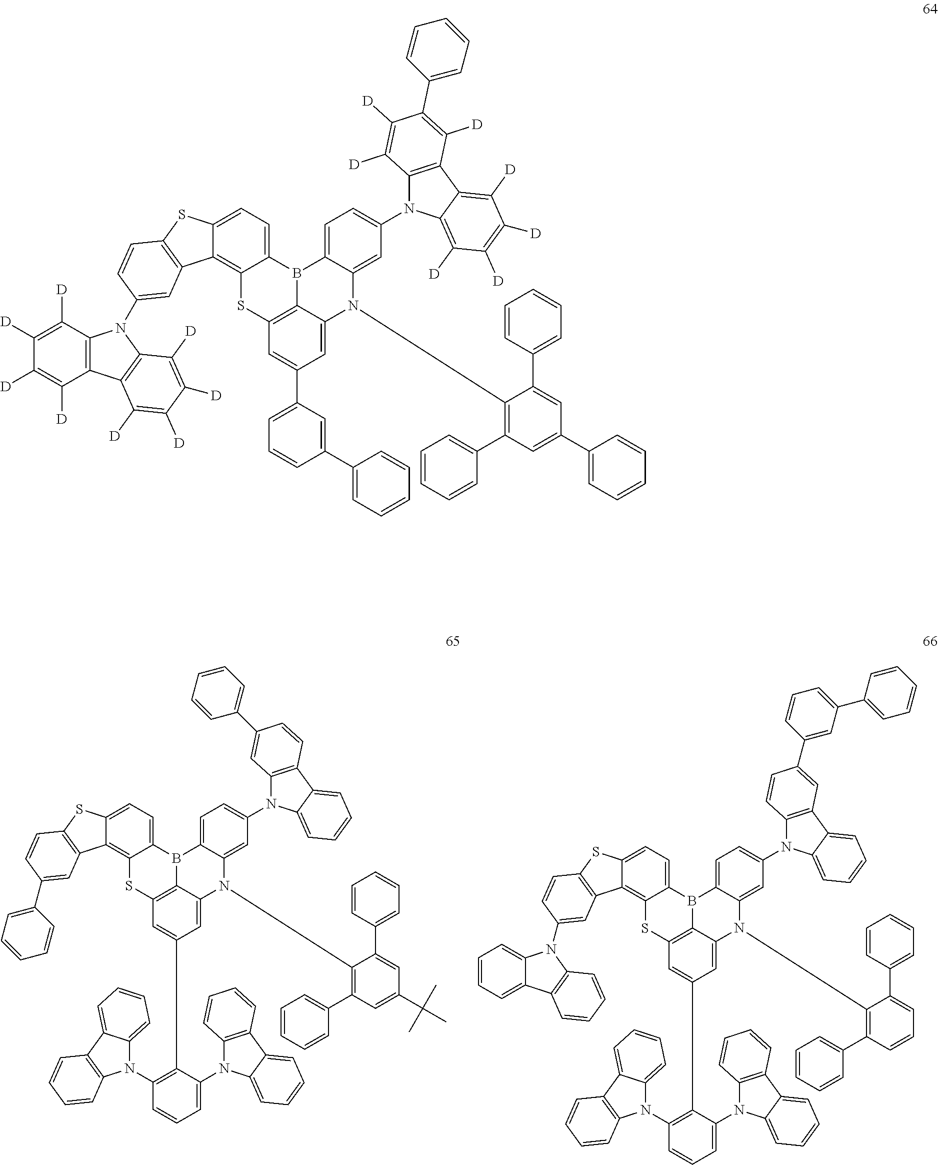 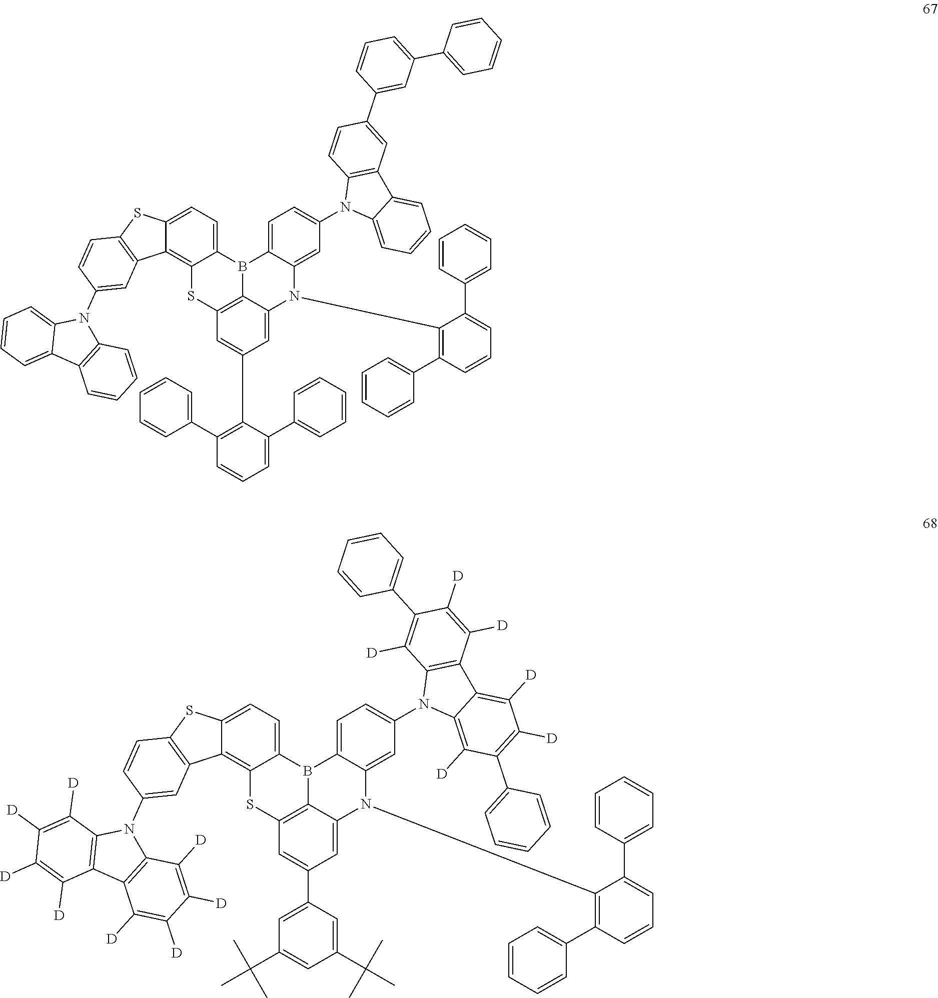 [SMILES: c1ccc(-c2cccc(-c3ccc4c(c3)c3ccccc3n4-c3ccc4c(c3)N(c3c(-c5ccccc5)cccc3-c3ccccc3)c3cc(-c5c(-c6ccccc6)cccc5-c5ccccc5)cc5c3B4c3ccc4sc6ccc(-n7c8ccccc8c8ccccc87)cc6c4c3S5)c2)cc1 ; [2H]c1c([2H])c([2H])c2c(c1[2H])c1c([2H])c([2H])c([2H])c([2H])c1n2-c1ccc2sc3ccc4c(c3c2c1)Sc1cc(-c2cc(C(C)(C)C)cc(C(C)(C)C)c2)cc2c1B4c1ccc(-n3c4c([2H])c(-c5ccccc5)c([2H])c([2H])c4c4c([2H])c([2H])c(-c5ccccc5)c([2H])c43)cc1N2c1c(-c2ccccc2)cccc1-c1ccccc1] 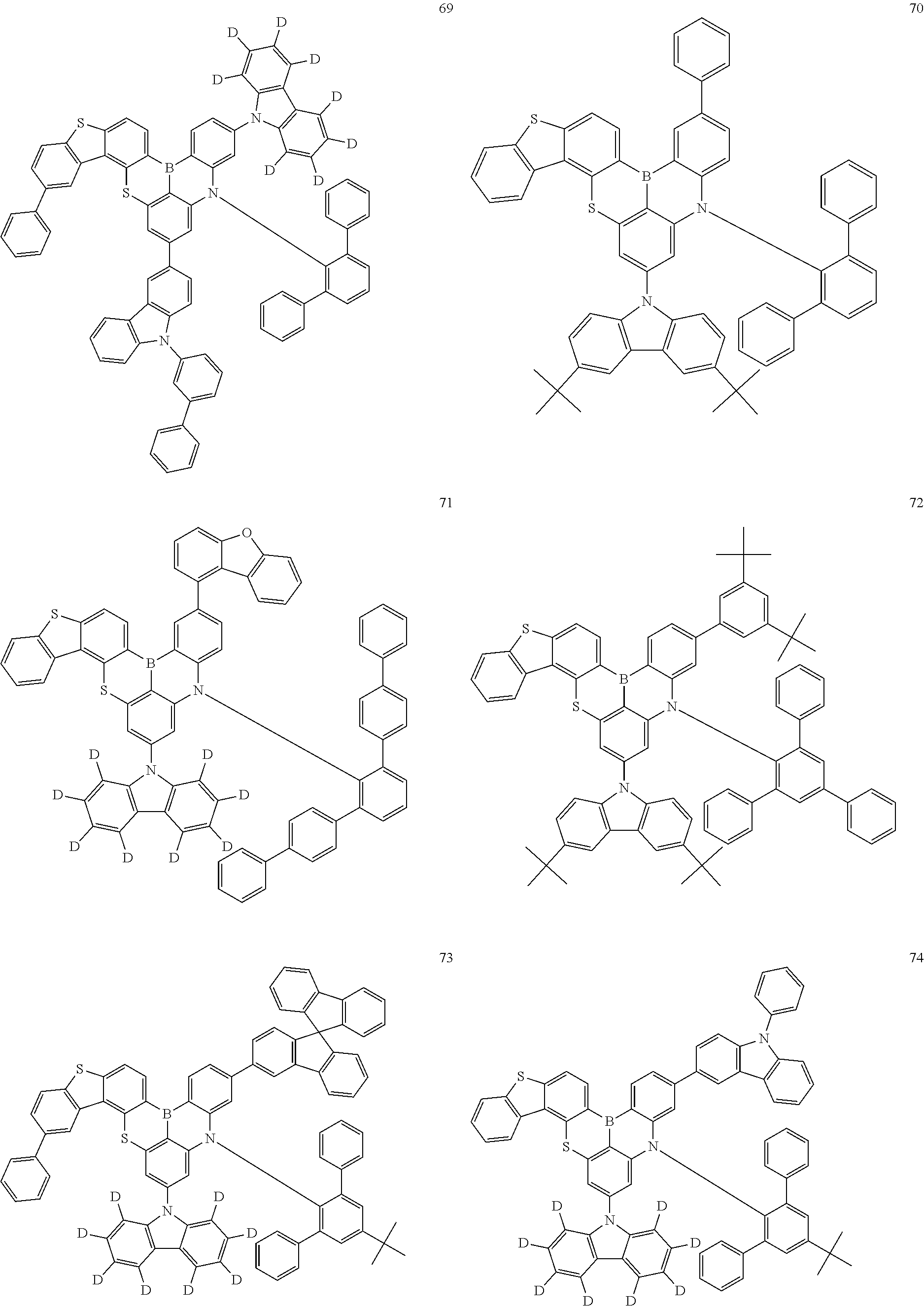 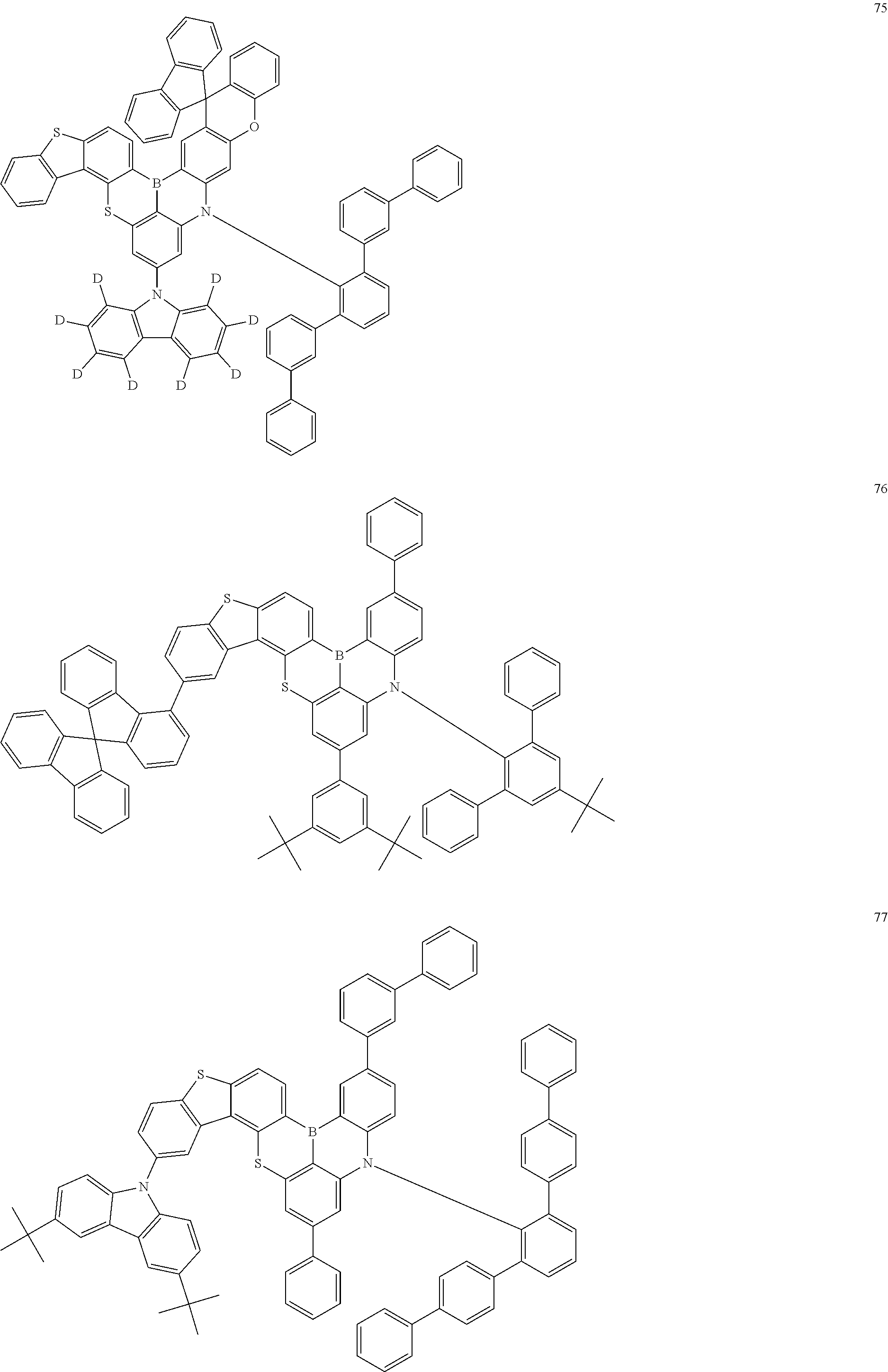 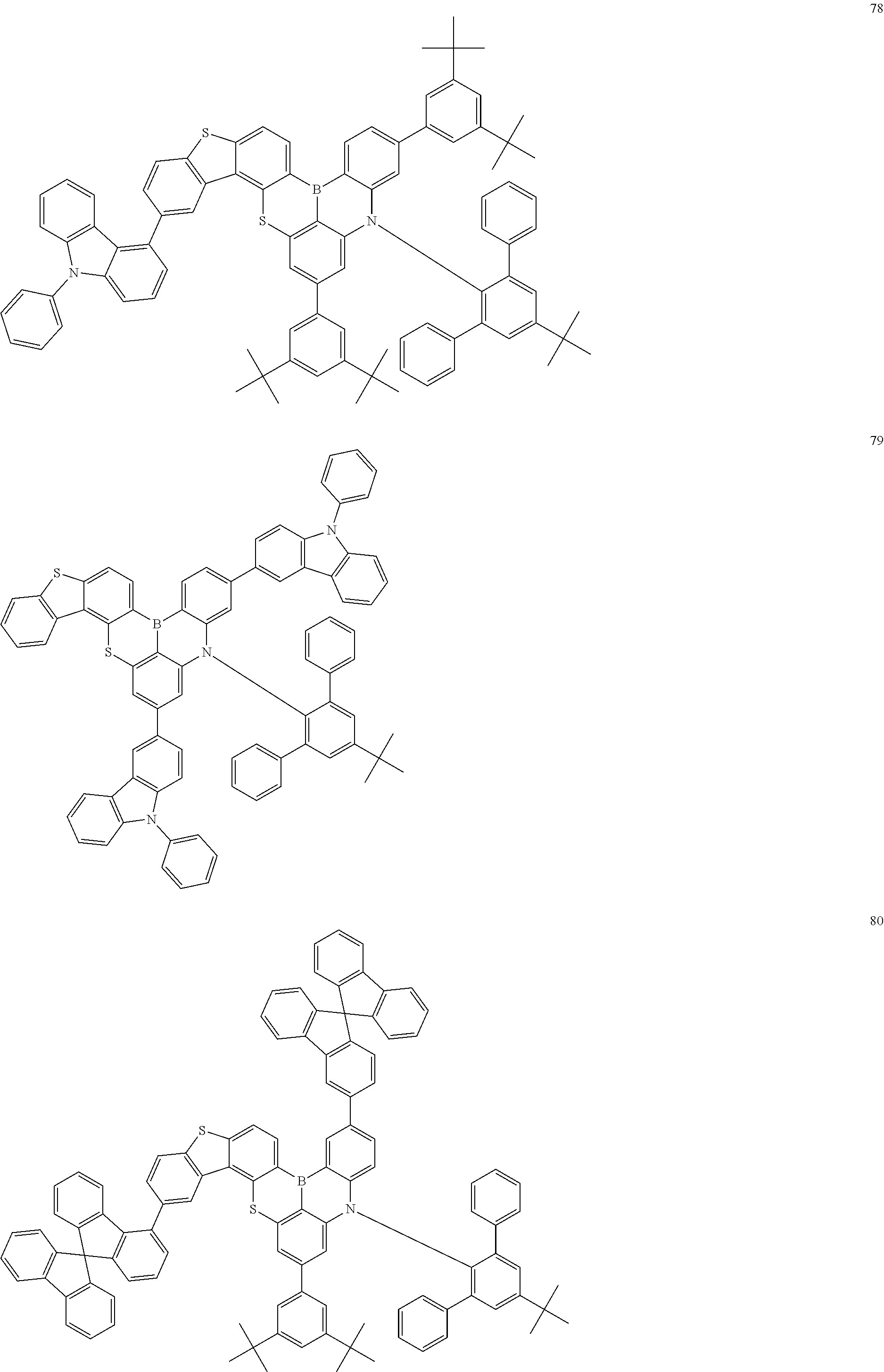 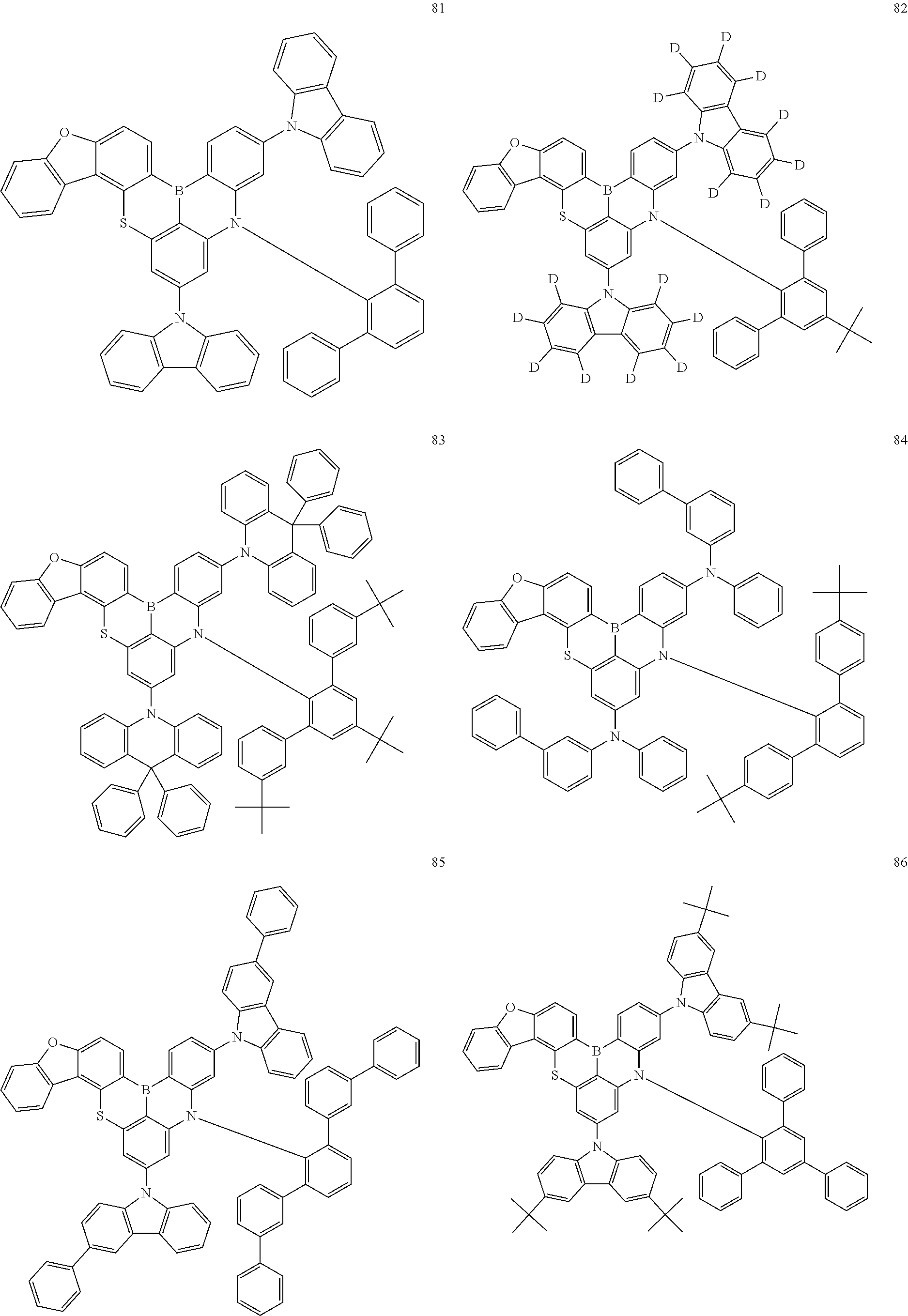 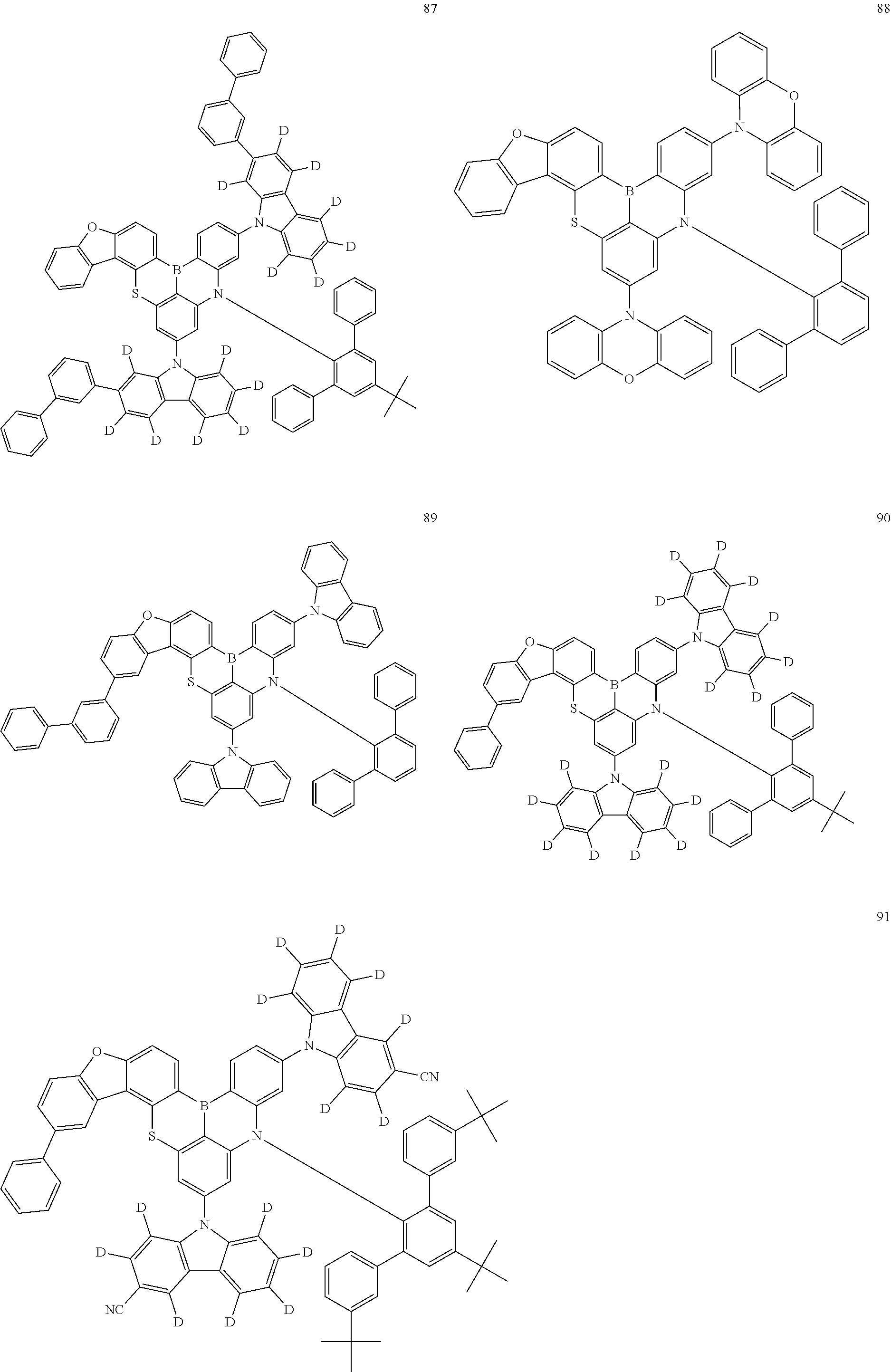 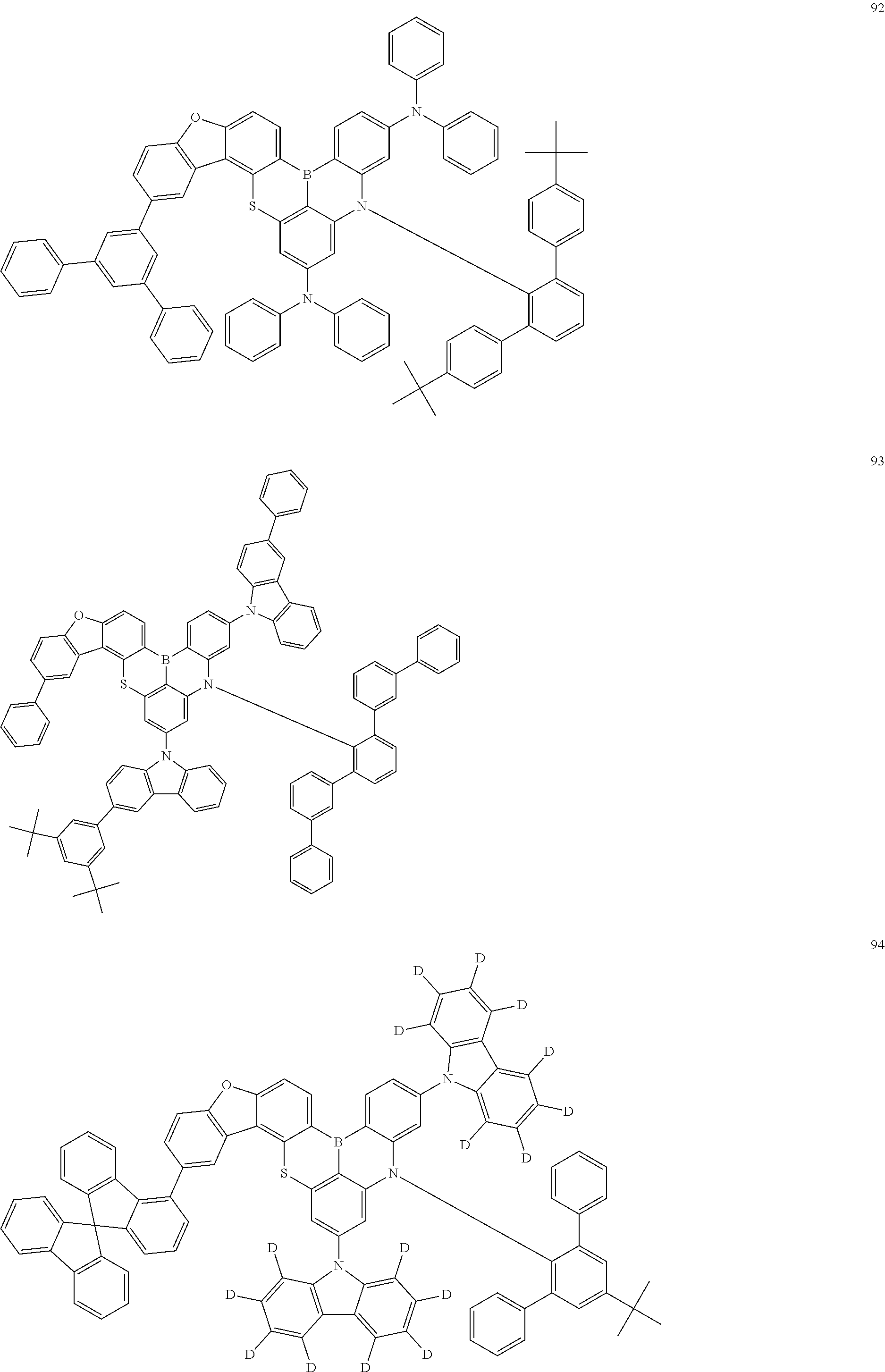 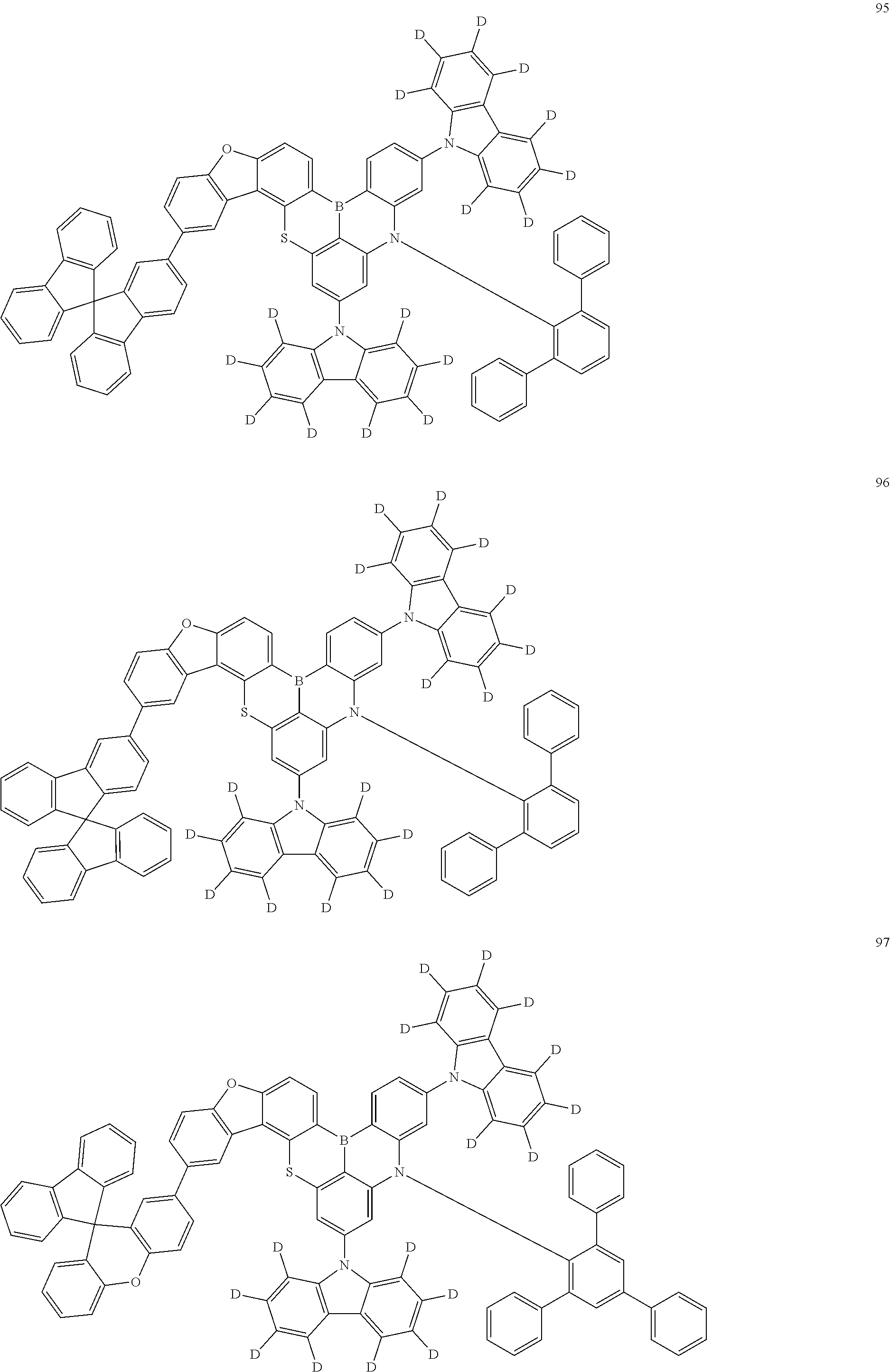 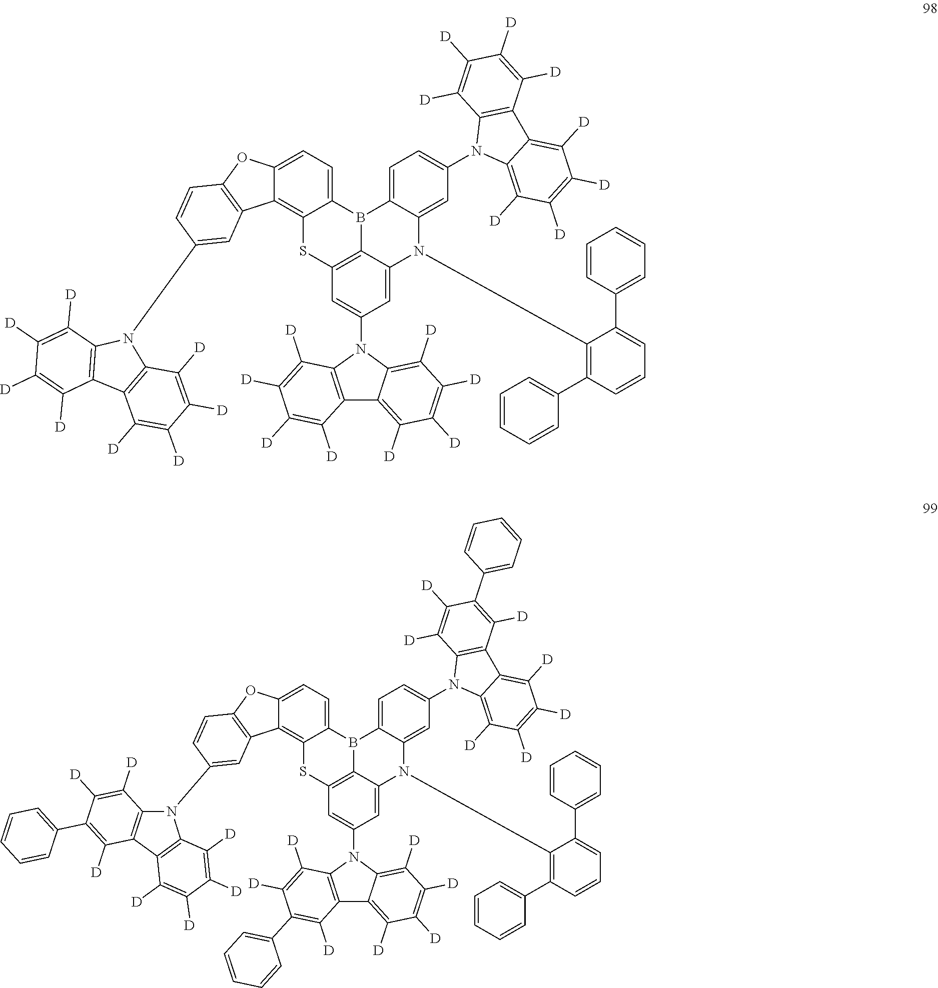 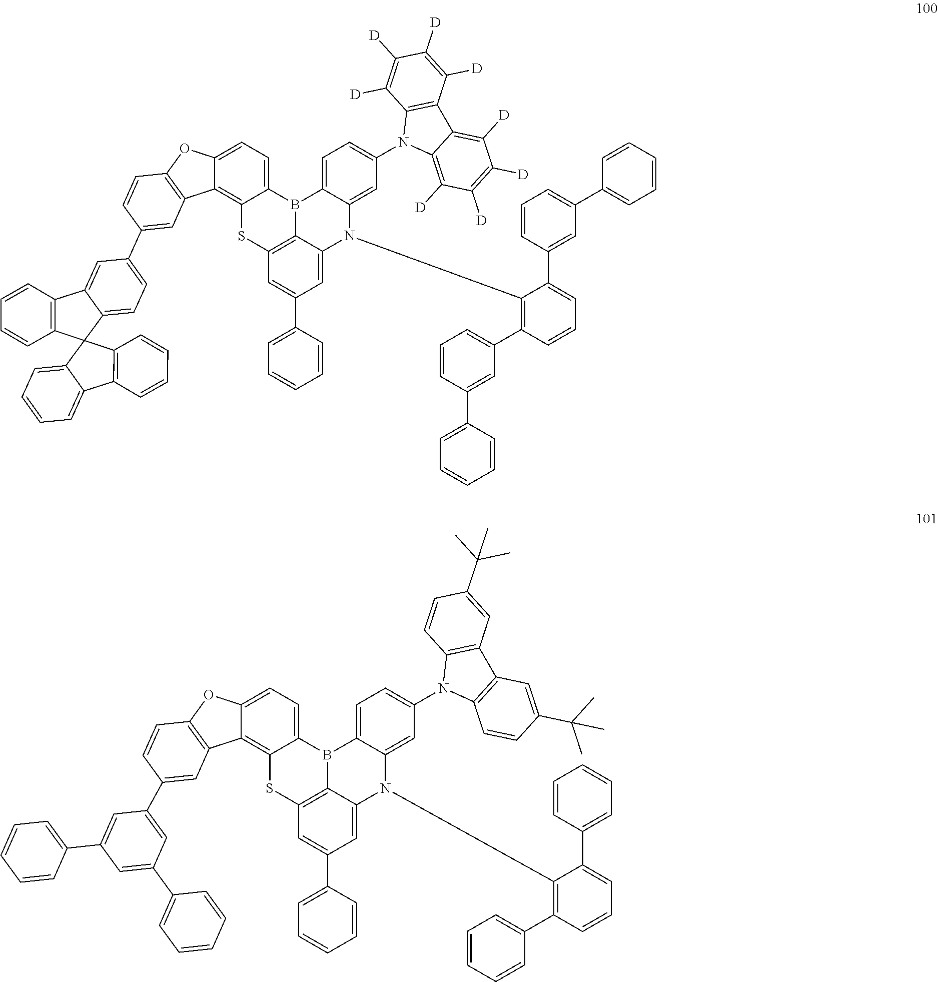 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2oc4ccc(-c5ccc6c(c5)-c5ccccc5C65c6ccccc6-c6ccccc65)cc4c2c1S3 ; CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc2oc4ccc(-c5cc(-c6ccccc6)cc(-c6ccccc6)c5)cc4c2c1S3] 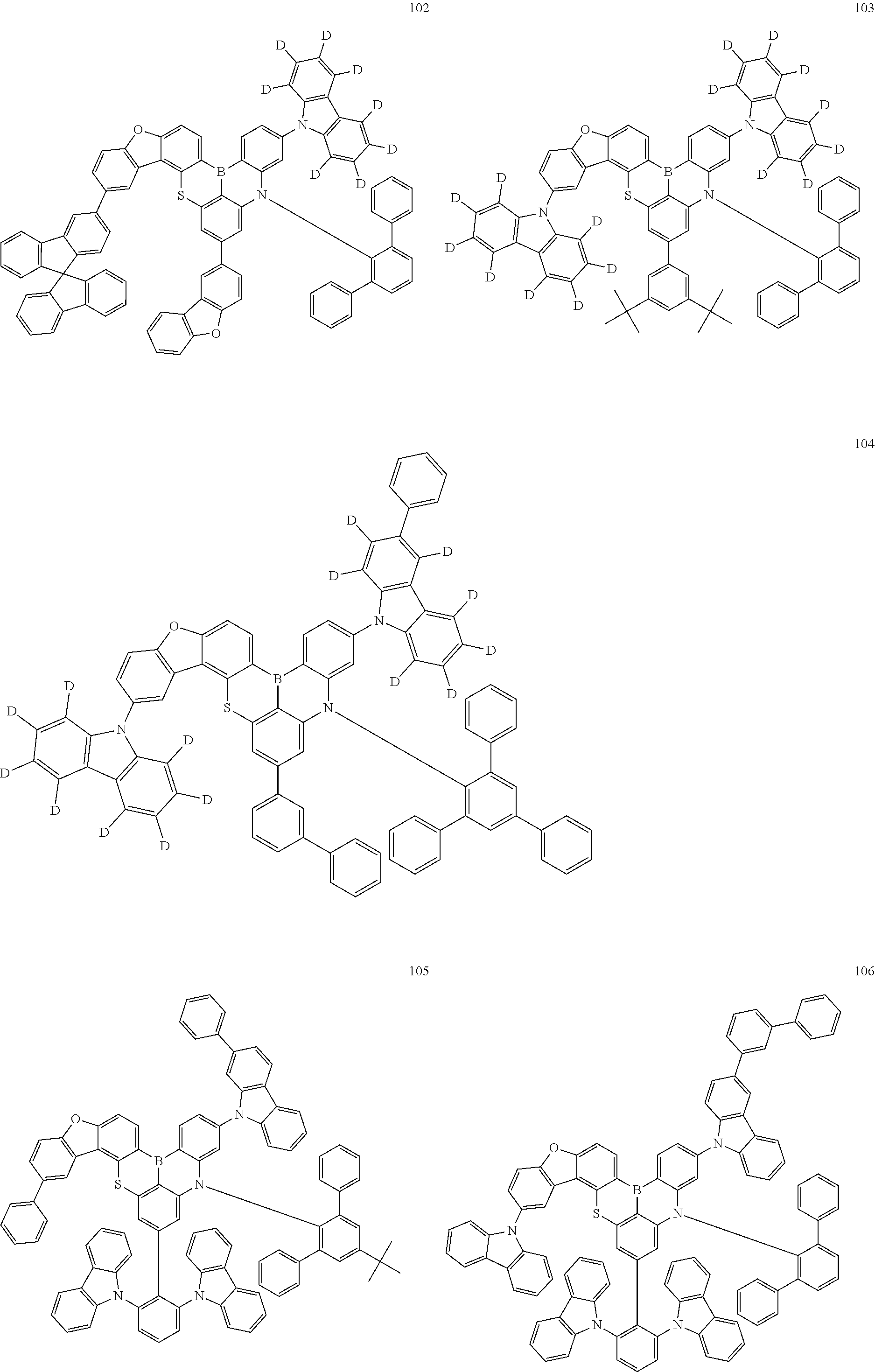 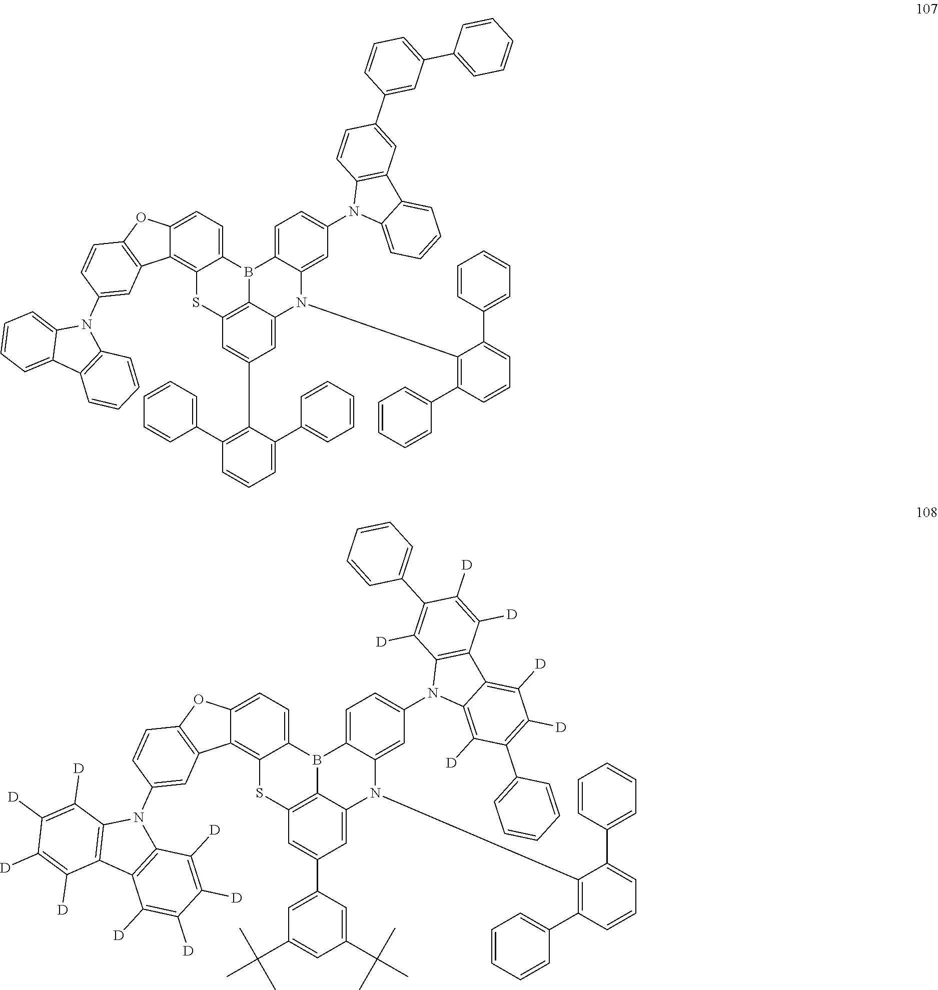 [SMILES: c1ccc(-c2cccc(-c3ccc4c(c3)c3ccccc3n4-c3ccc4c(c3)N(c3c(-c5ccccc5)cccc3-c3ccccc3)c3cc(-c5c(-c6ccccc6)cccc5-c5ccccc5)cc5c3B4c3ccc4oc6ccc(-n7c8ccccc8c8ccccc87)cc6c4c3S5)c2)cc1 ; [2H]c1c([2H])c([2H])c2c(c1[2H])c1c([2H])c([2H])c([2H])c([2H])c1n2-c1ccc2oc3ccc4c(c3c2c1)Sc1cc(-c2cc(C(C)(C)C)cc(C(C)(C)C)c2)cc2c1B4c1ccc(-n3c4c([2H])c(-c5ccccc5)c([2H])c([2H])c4c4c([2H])c([2H])c(-c5ccccc5)c([2H])c43)cc1N2c1c(-c2ccccc2)cccc1-c1ccccc1] 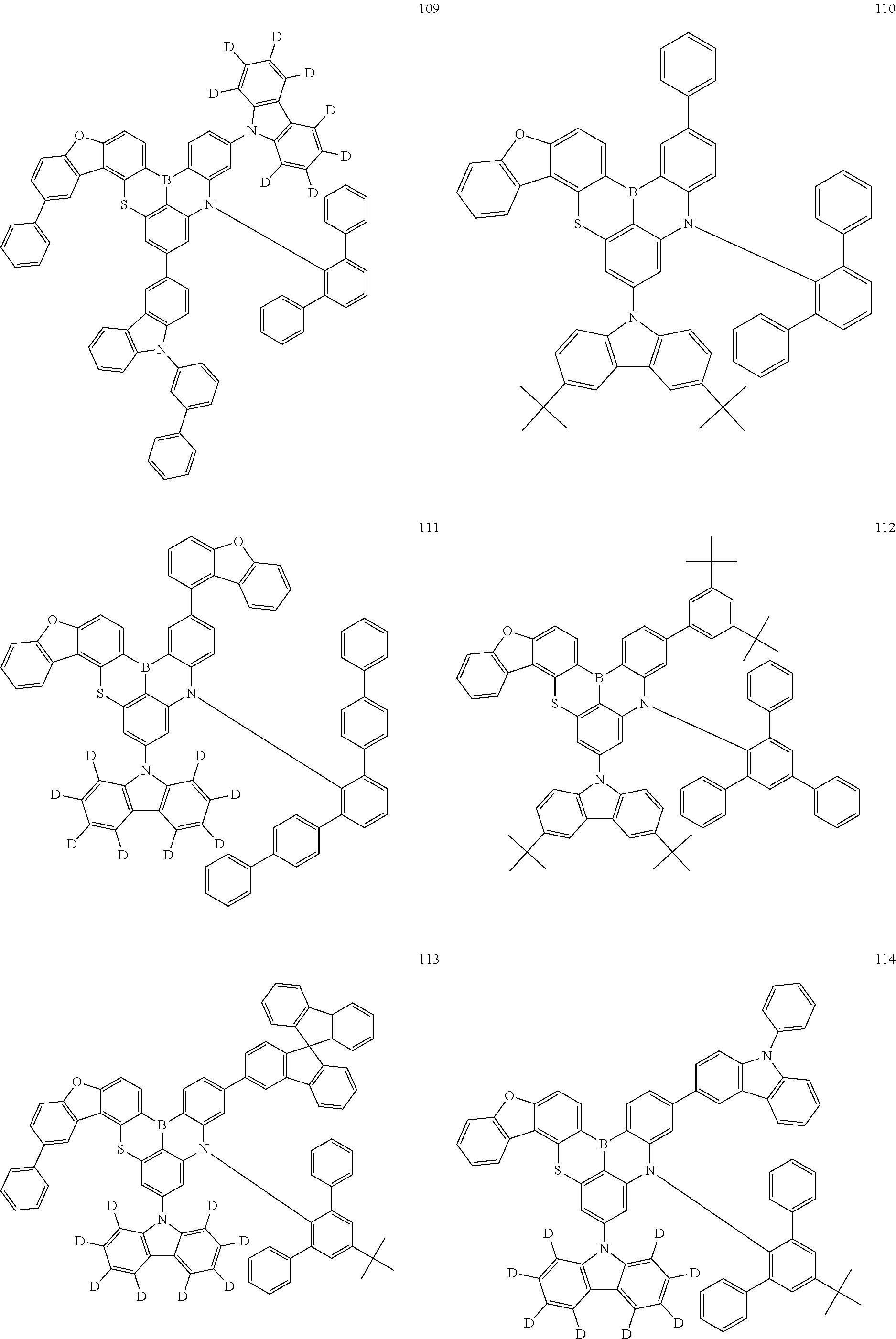 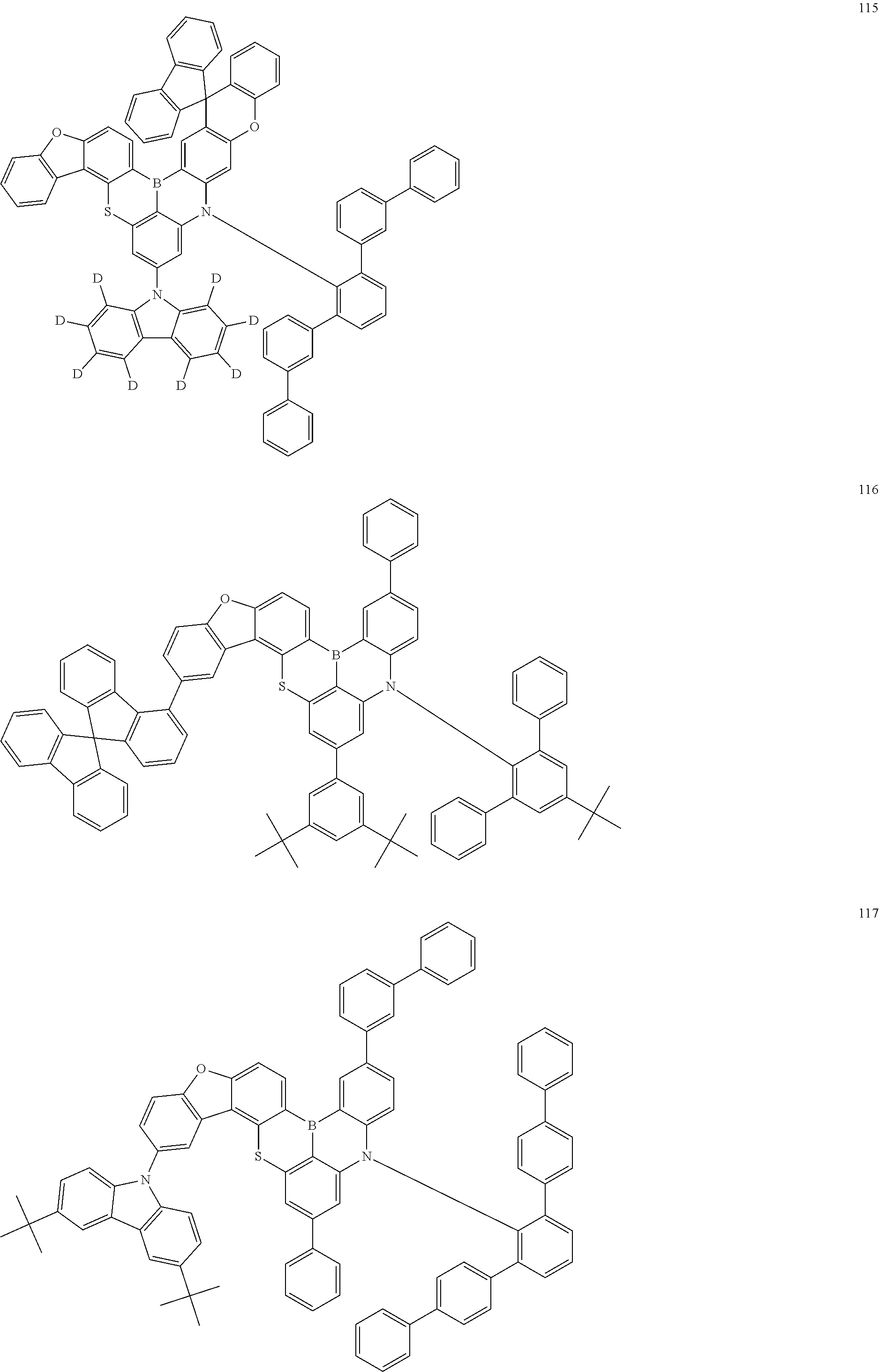 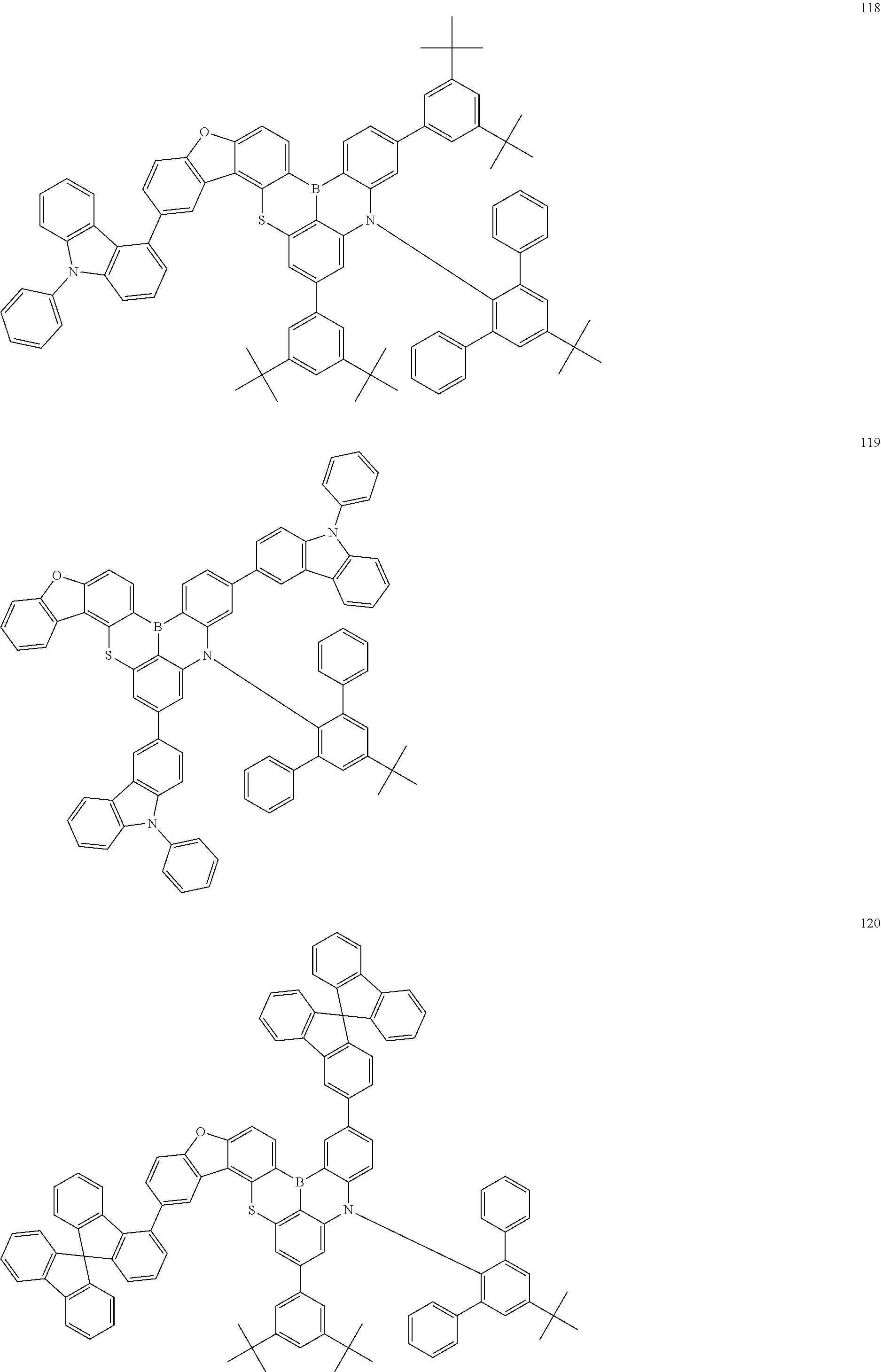 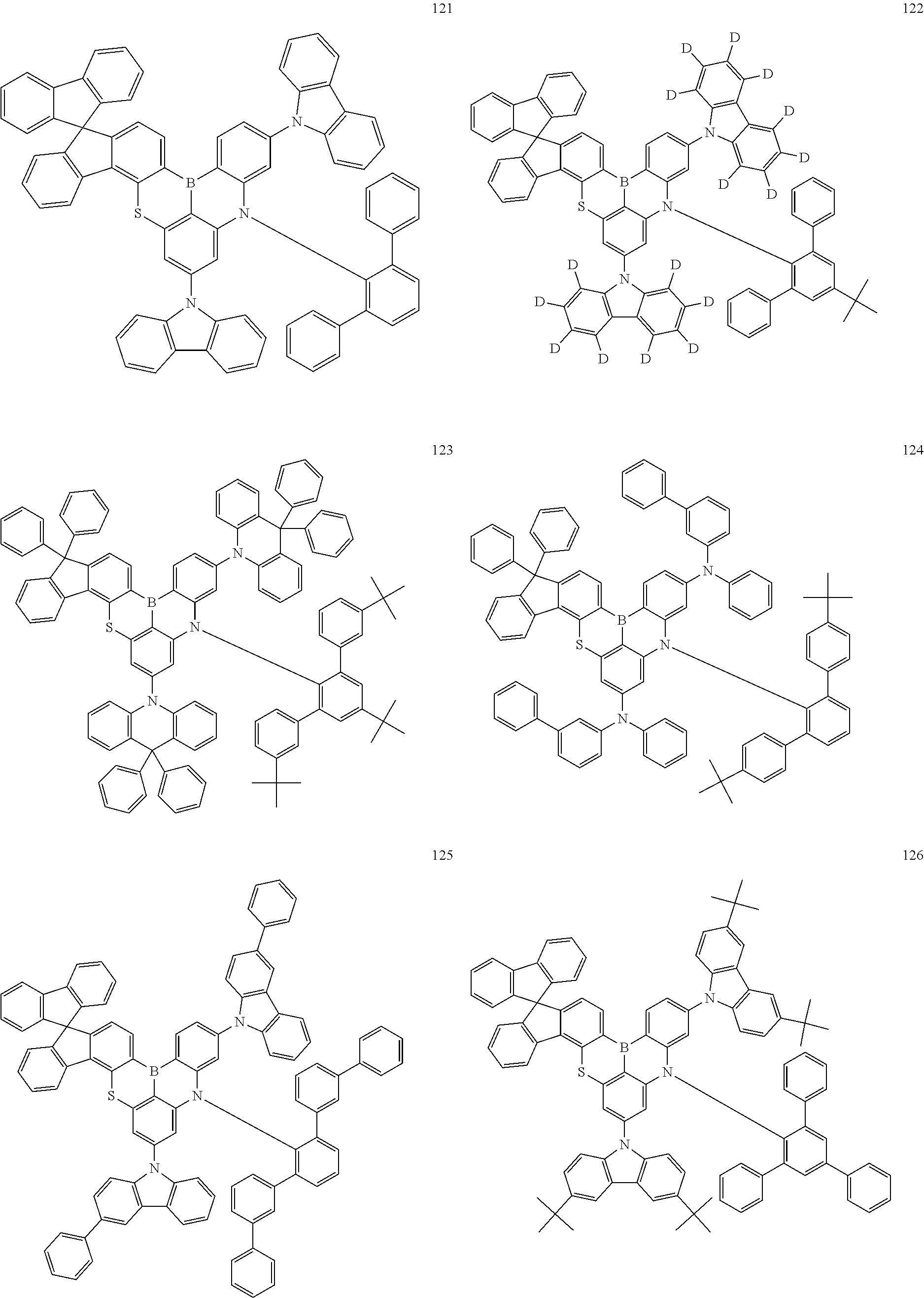 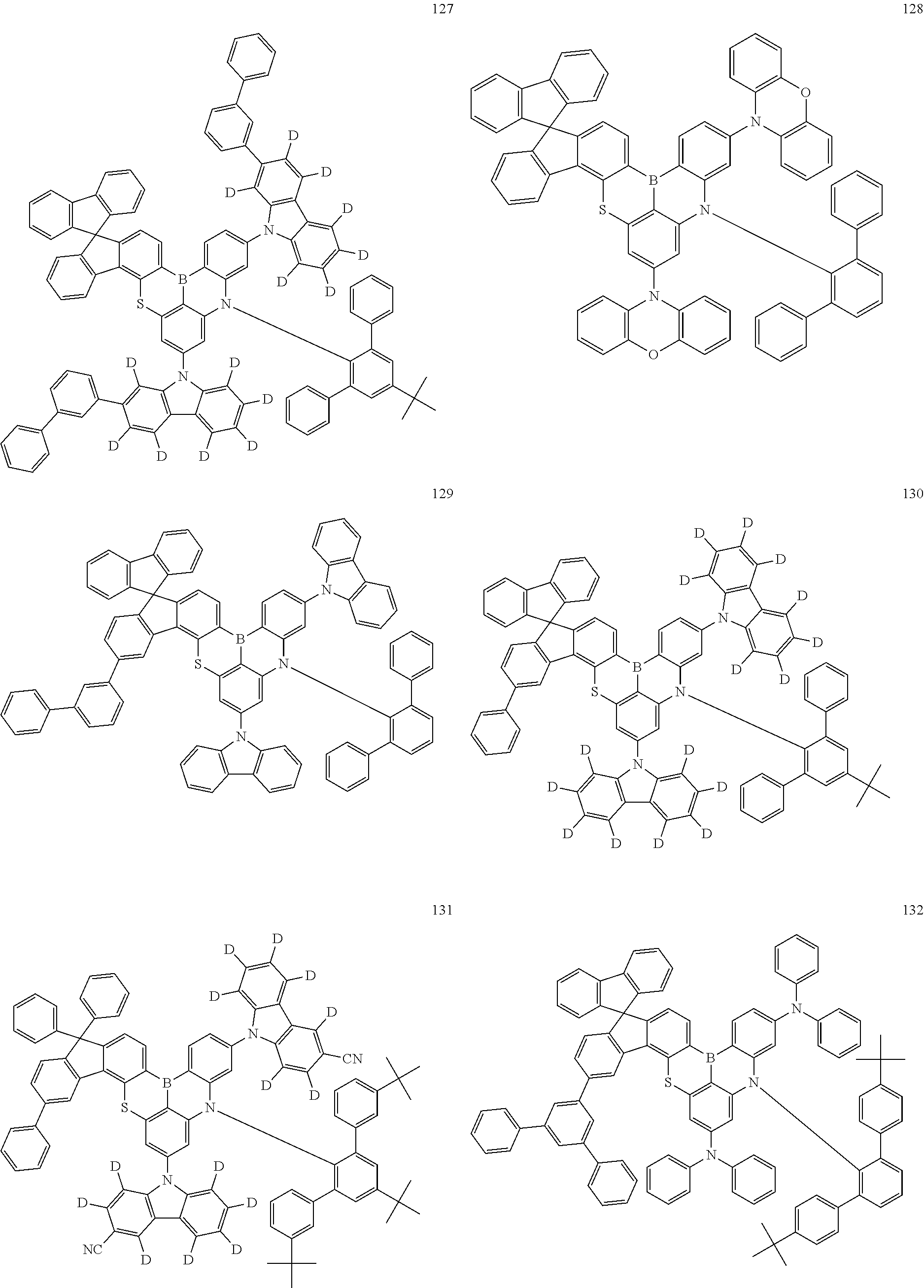 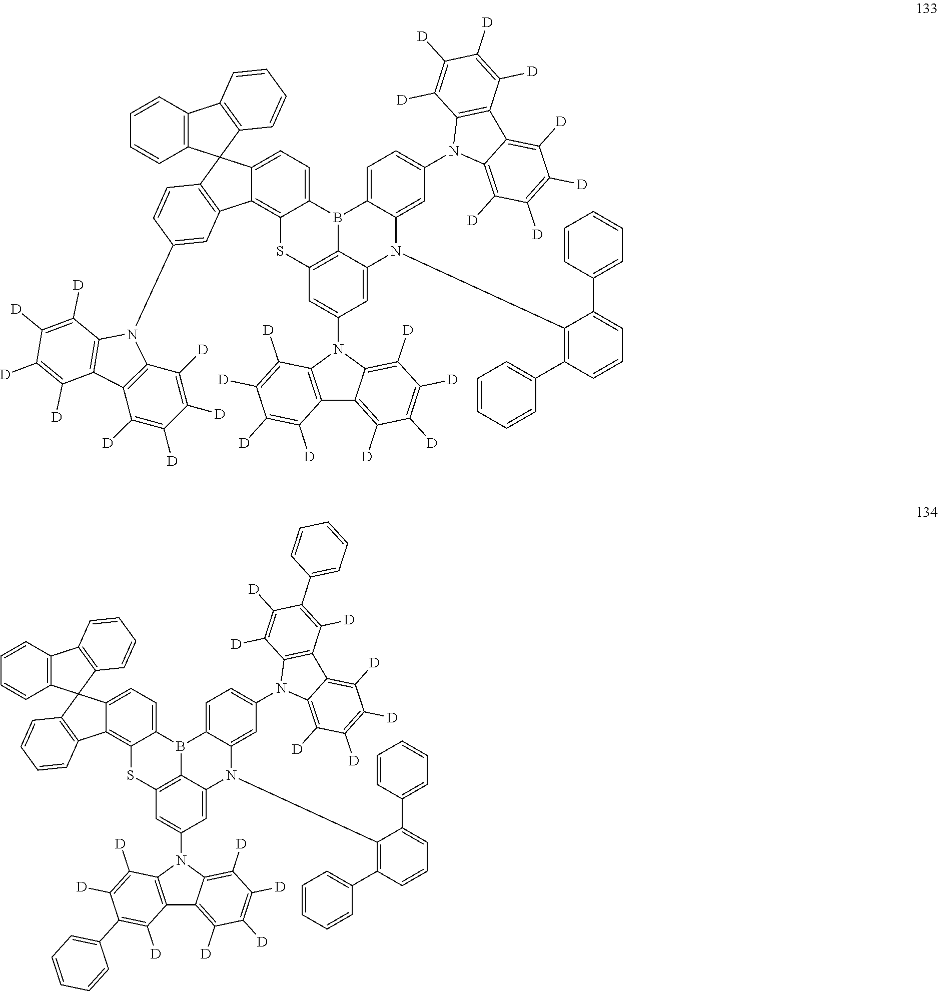 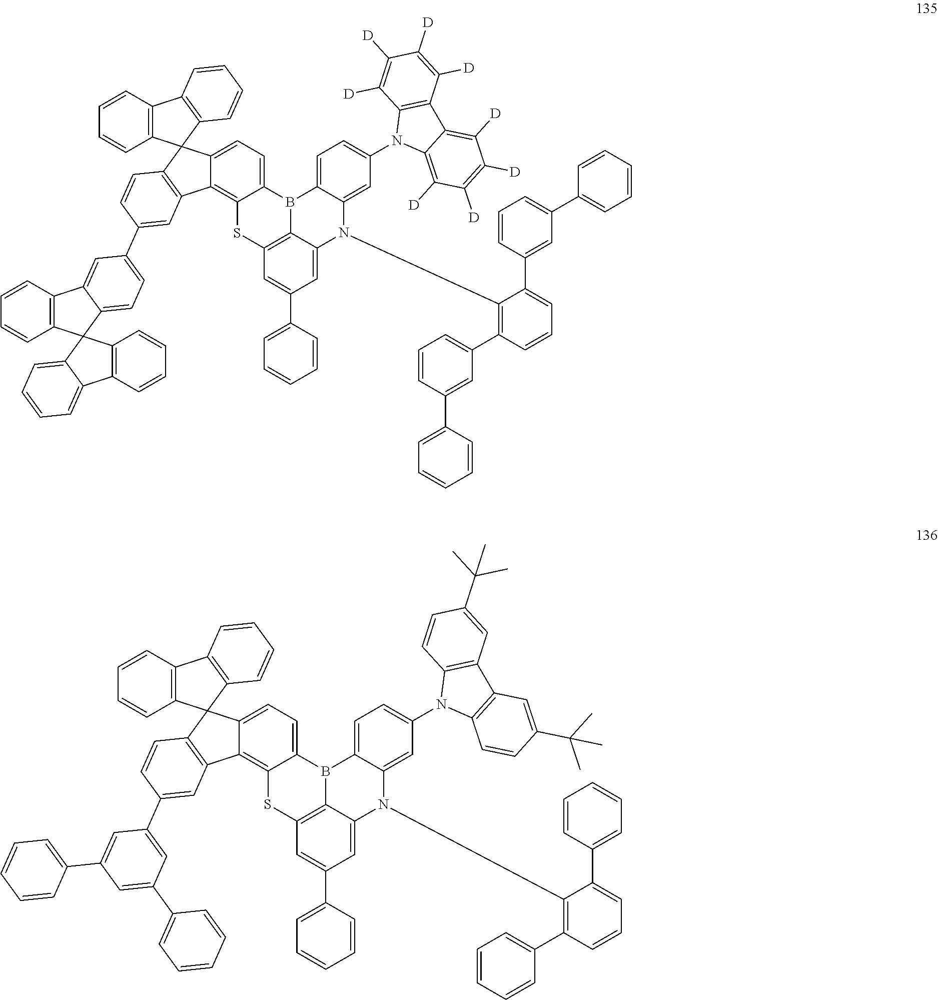 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2c(c1S3)-c1cc(-c3ccc4c(c3)-c3ccccc3C43c4ccccc4-c4ccccc43)ccc1C21c2ccccc2-c2ccccc21 ; CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc2c(c1S3)-c1cc(-c3cc(-c4ccccc4)cc(-c4ccccc4)c3)ccc1C21c2ccccc2-c2ccccc21] 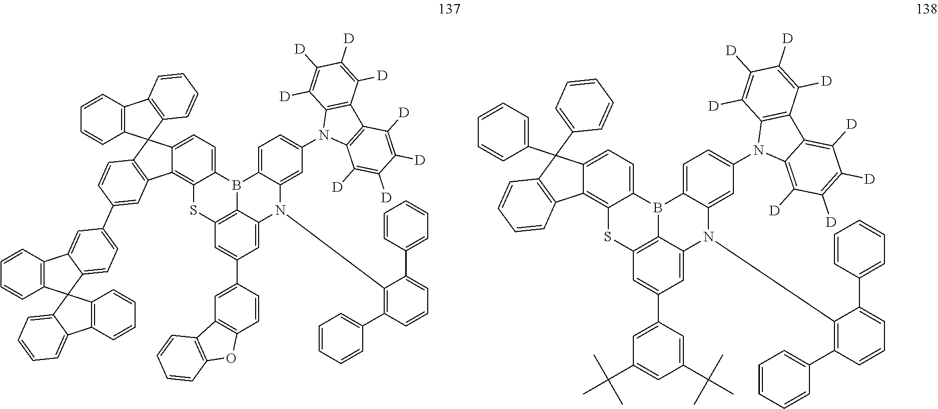 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc2c(c1S3)-c1cc(-c3ccc4c(c3)-c3ccccc3C43c4ccccc4-c4ccccc43)ccc1C21c2ccccc2-c2ccccc21 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(C(C)(C)C)cc(C(C)(C)C)c3)cc3c1B2c1ccc2c(c1S3)-c1ccccc1C2(c1ccccc1)c1ccccc1] 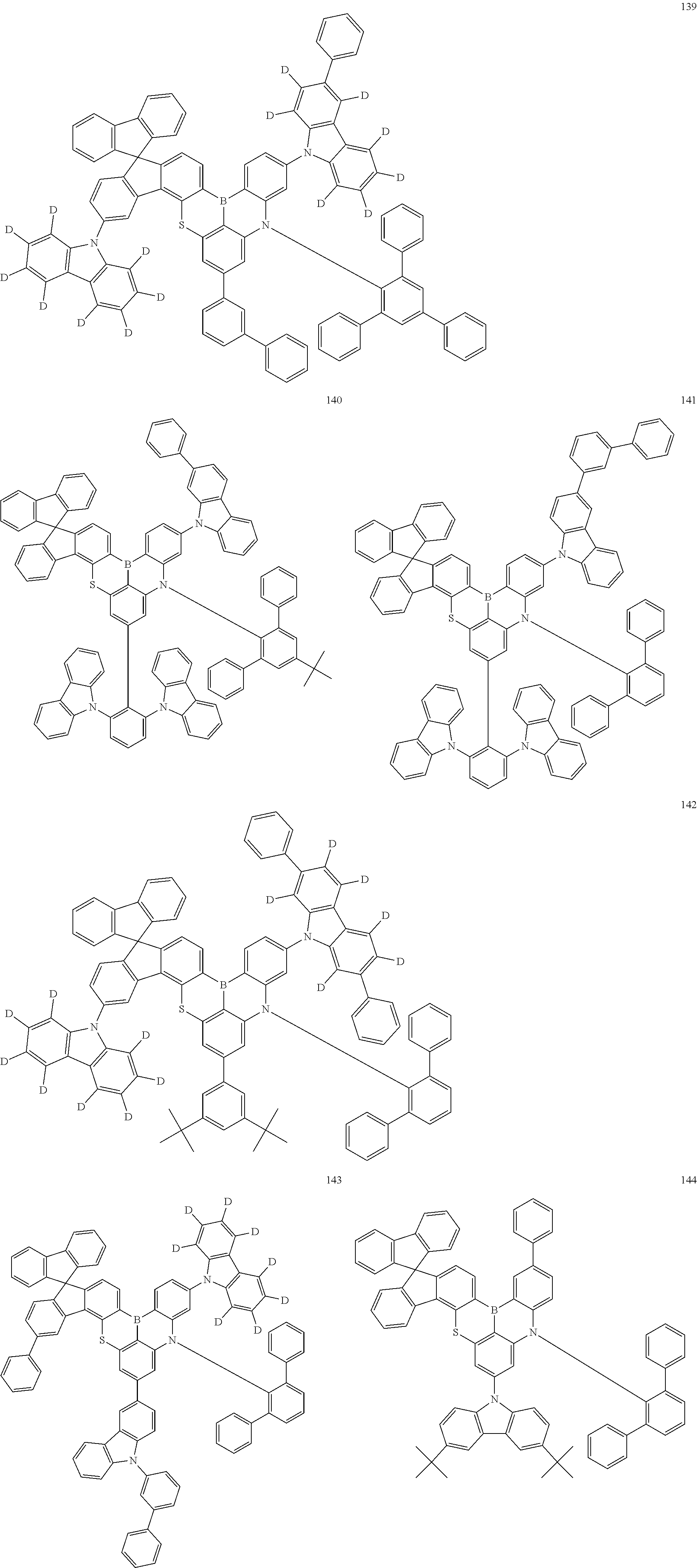 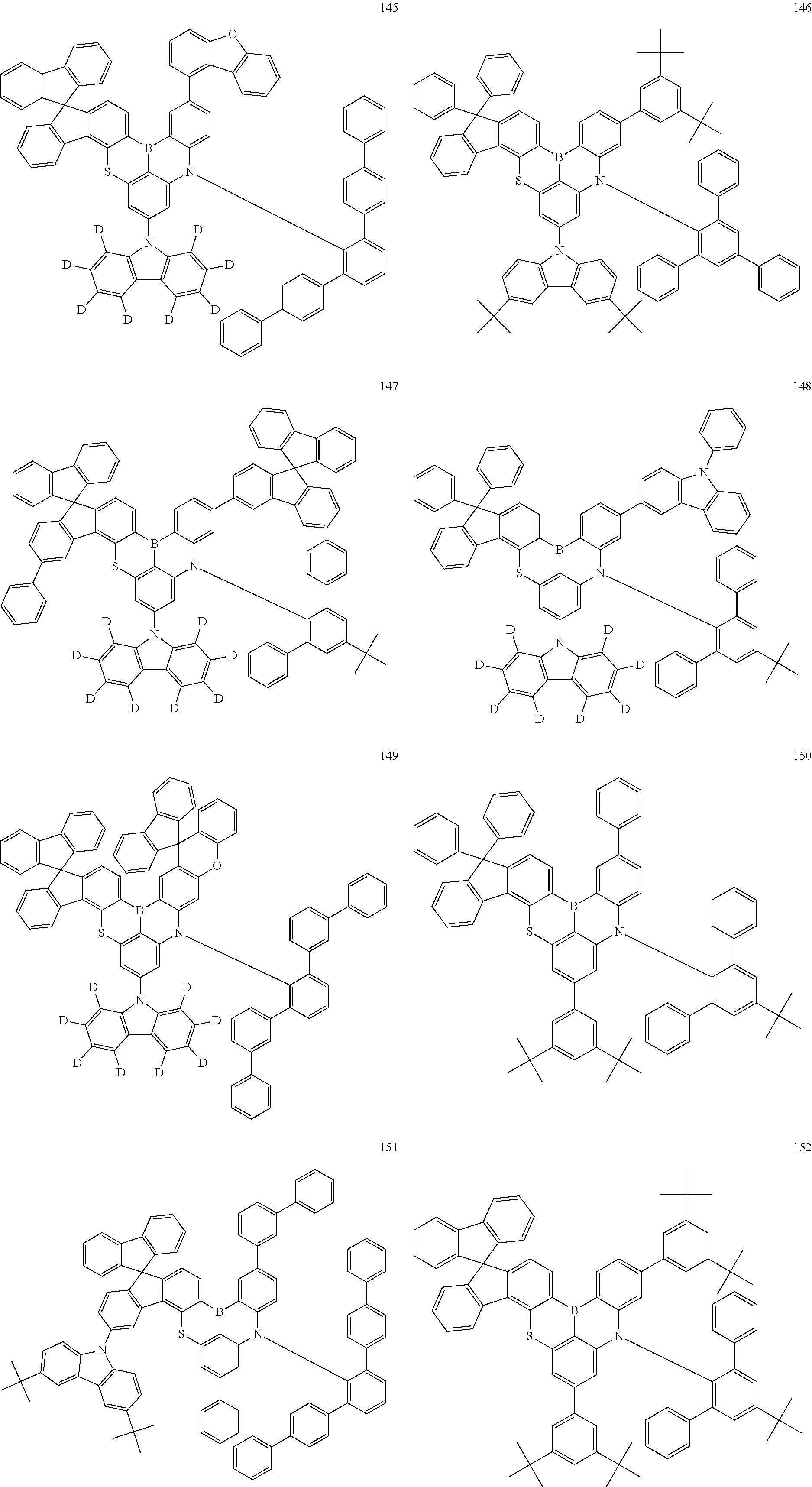 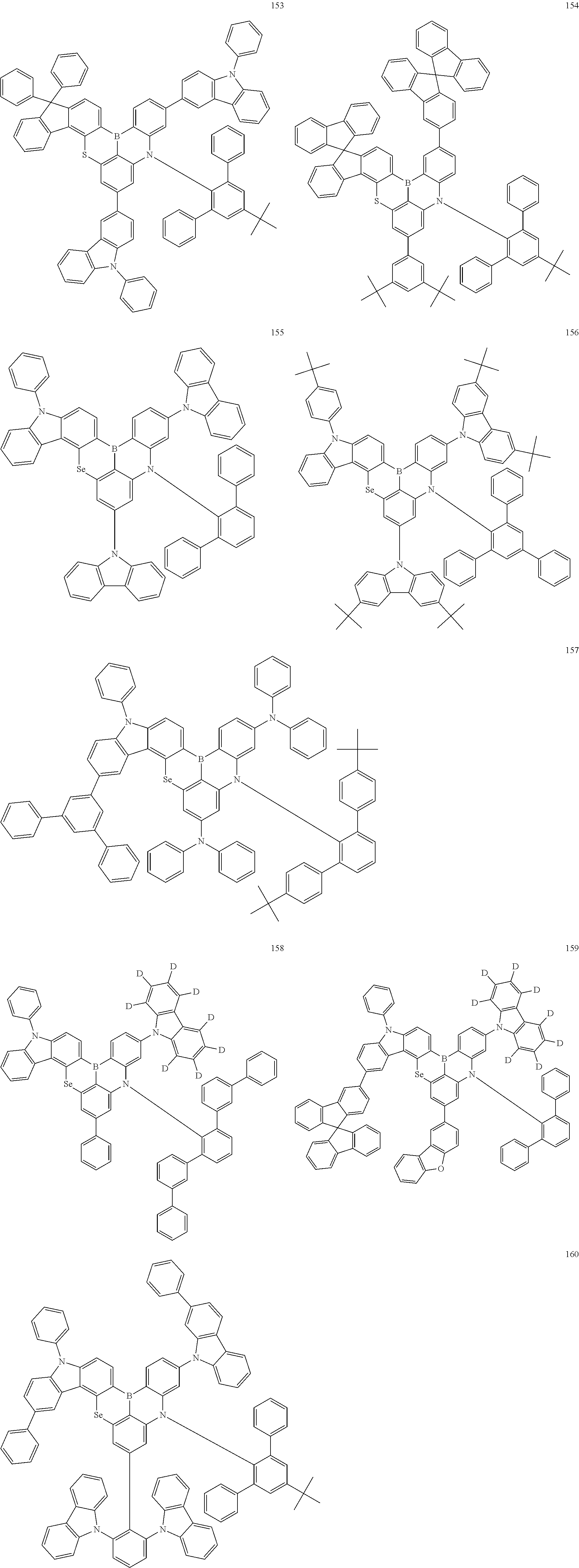 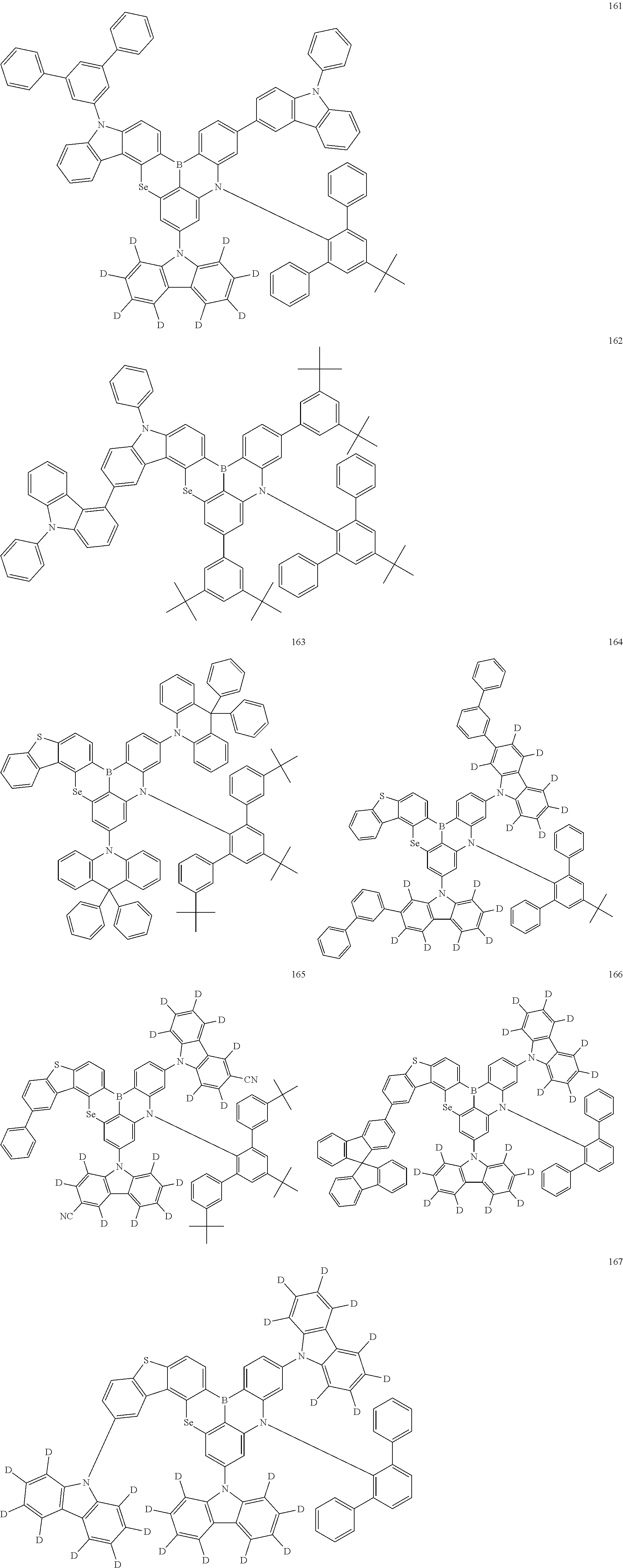 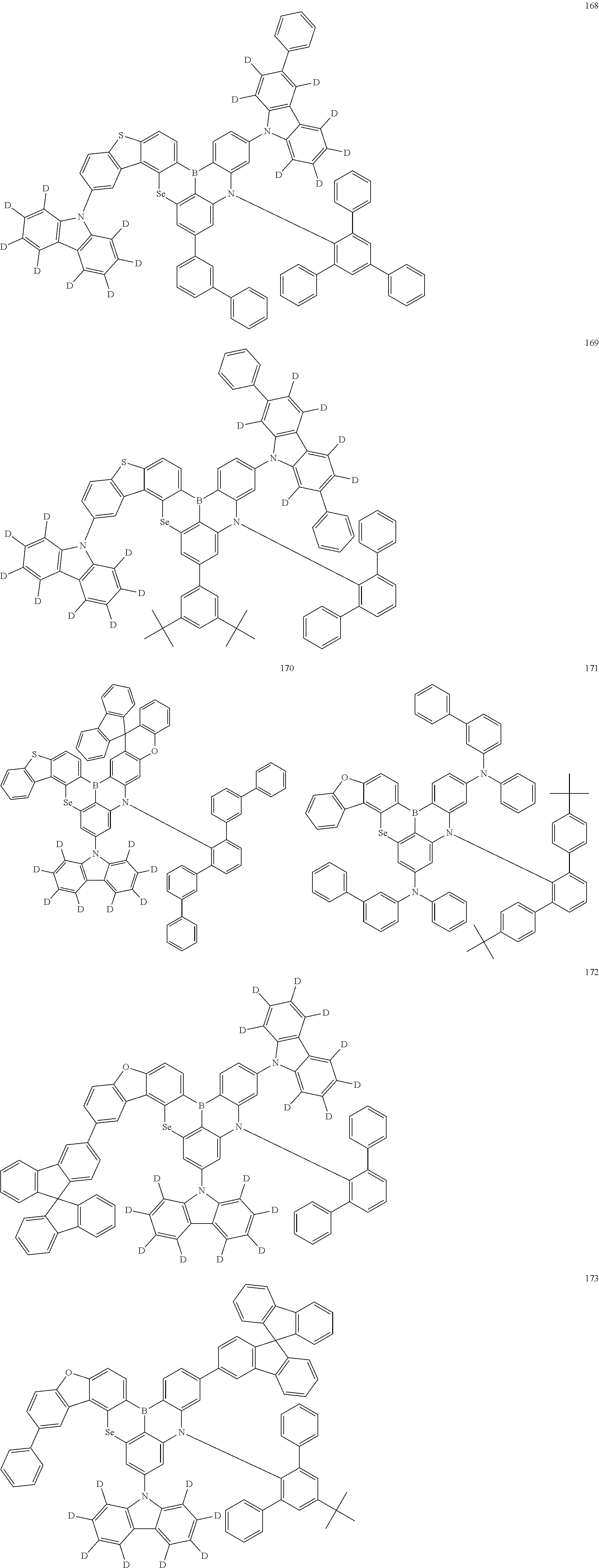 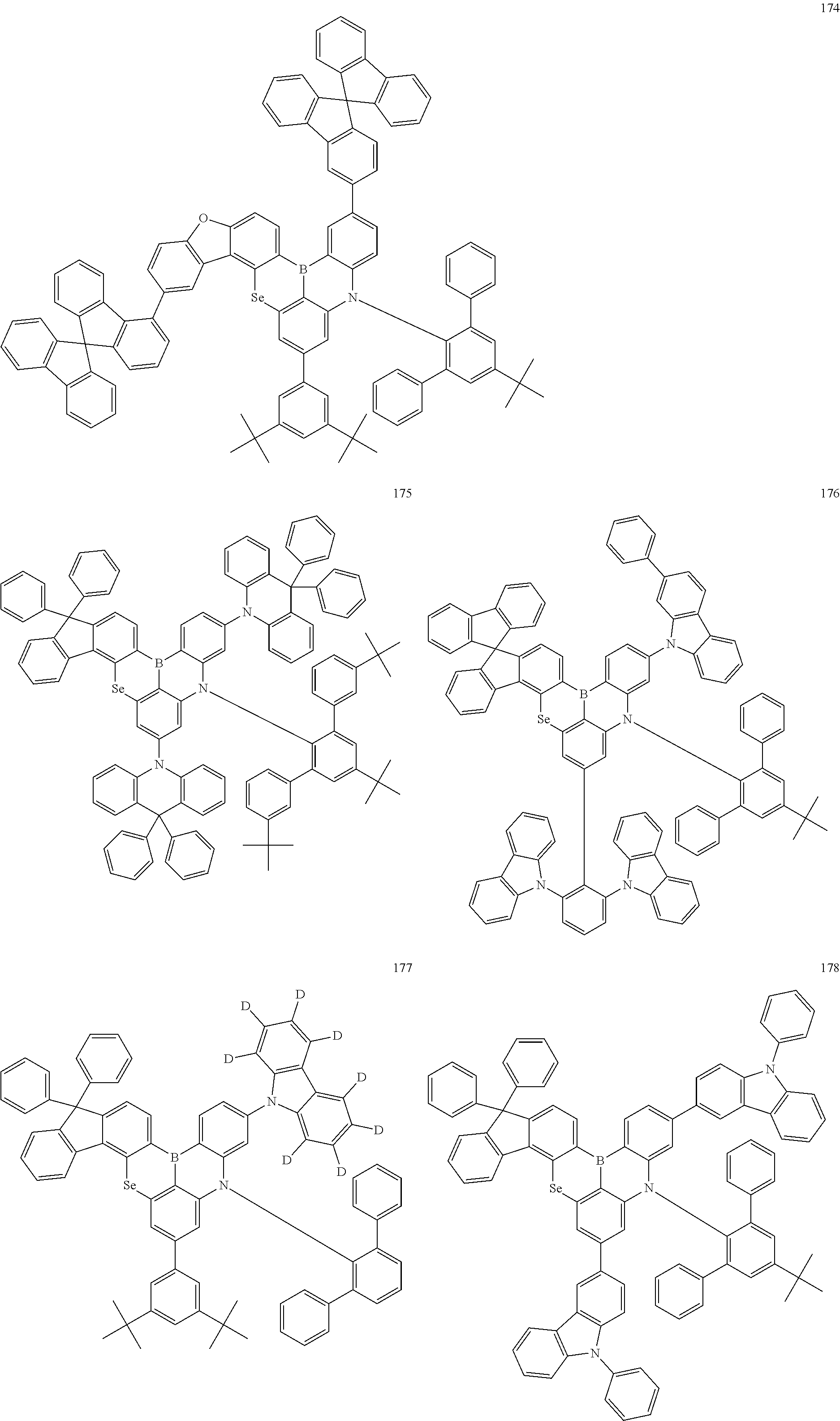
in Compound Group 1, D is a deuterium atom.

13. A polycyclic compound represented by the following Formula 1: 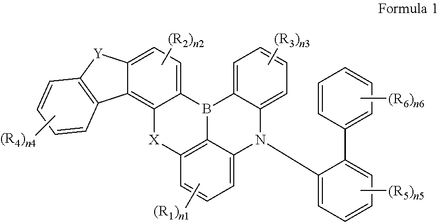
in Formula 1,
X is S, O, or Se,
Y is NR₇, S, O, or CR₈R₉,
R₁ to R₆ are each independently a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, or R₃ is combined with an adjacent group to form a ring,
R₇ to R₉ are each independently a substituted or unsubstituted aryl group of 6 to 30 ring-forming carbon atoms, or a substituted or unsubstituted heteroaryl group of 2 to 30 ring-forming carbon atoms, or R₈ and R₉ are combined with each other to form a ring,
n1 is an integer of 0 to 3,
n2 is an integer of 0 to 2,
n3, n4 and n5 are each independently an integer of 0 to 4, and
n6 is an integer of 0 to 5.

14. The polycyclic compound of claim 13, wherein at least one hydrogen atom in R₁ to R₆ of Formula 1 is substituted with a deuterium atom, or at least one among R₁ to R₆ comprises a substituent substituted with a deuterium atom.

15. The polycyclic compound of claim 13, wherein Formula 1 is represented by the following Formula 2: 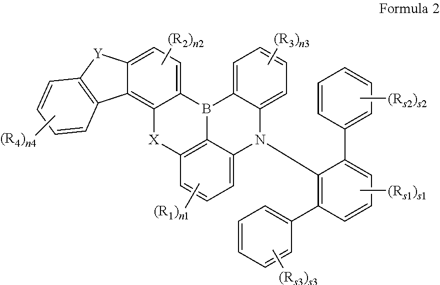
in Formula 2,
Rₛ₁, Rₛ₂, and Rₛ₃ are each independently a hydrogen atom, a deuterium atom, a substituted or unsubstituted alkyl group of 1 to 30 carbon atoms, or a substituted or unsubstituted aryl group of 6 to 30 ring-forming carbon atoms,
s1 is an integer of 0 to 3,
s2 and s3 are each independently an integer of 0 to 5, and
X, Y, R₁ to R₄, and n1 to n4 are the same as defined with respect to Formula 1.

16. The polycyclic compound of claim 13, wherein Formula 1 is represented by the following Formula 3: 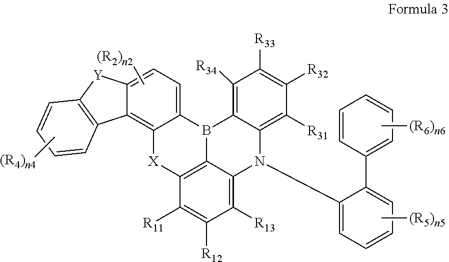
in Formula 3,
R₁₁, R₁₃, R₃₁, and R₃₄ are each independently a hydrogen atom or a deuterium atom,
R₁₂ is a substituted or unsubstituted amine group, a substituted or unsubstituted aryl group of 6 to 30 ring-forming carbon atoms, or a substituted or unsubstituted heteroaryl group of 2 to 30 ring-forming carbon atoms,
R₃₂ and R₃₃ are each independently a substituted or unsubstituted amine group, a substituted or unsubstituted aryl group of 6 to 30 ring-forming carbon atoms, or a substituted or unsubstituted heteroaryl group of 2 to 30 ring-forming carbon atoms, or R₃₂ and R₃₃ are combined with each other to form a ring, and
X, Y, R₂, R₄ to R₆, n2, and n4 to n6 are the same as defined with respect to Formula 1.

17. The polycyclic compound of claim 13, wherein Formula 1 is represented by the following Formula 4: 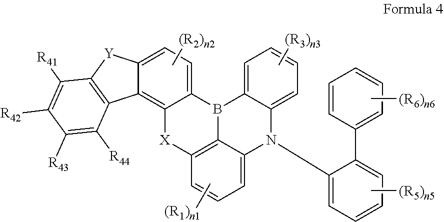
in Formula 4,
R₄₁, R₄₂, and R₄₄ are each independently a hydrogen atom or a deuterium atom,
R₄₃ is a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and
X, Y, R₁ to R₃, R₅, R₆, n1 to n3, n5 and n6 are the same as defined with respect to Formula 1.

18. The polycyclic compound of claim 13, wherein Formula 1 is represented by any one among the following Formula 5-1 to Formula 5-4: 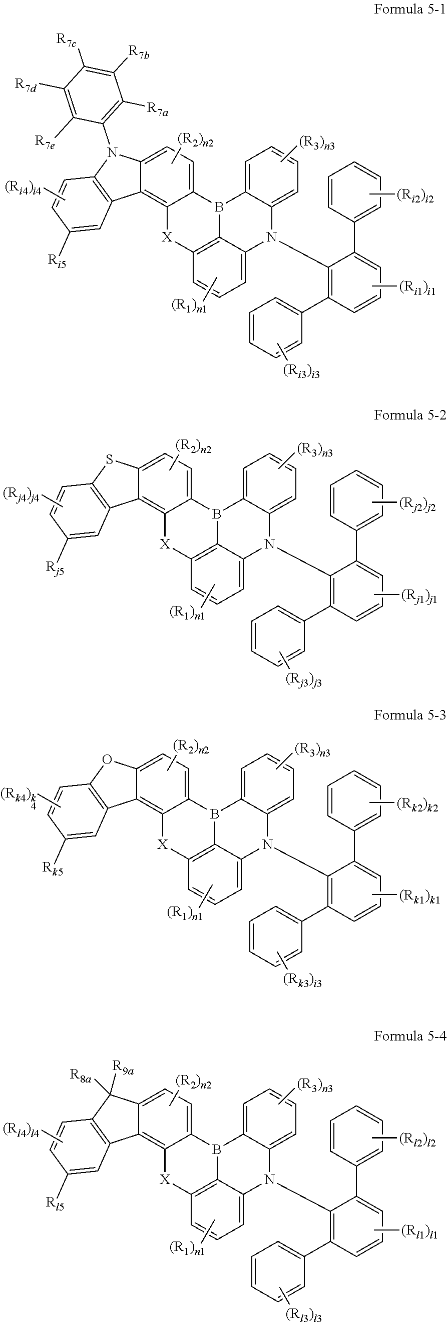
in Formula 5-1 to Formula 5-4,
Rᵢ₁ to Rᵢ₃, Rⱼ₁ to Rⱼ₃, Rₖ₁ to Rₖ₃, and Rₗ₁ to Rₗ₃ are each independently a hydrogen atom, a deuterium atom, a substituted or unsubstituted alkyl group of 1 to 30 carbon atoms, or a substituted or unsubstituted aryl group of 6 to 30 ring-forming carbon atoms,
Rᵢ₄, Rⱼ₄, Rₖ₄, and Rₗ₄ are each independently a hydrogen atom or a deuterium atom,
Rᵢ₅, Rⱼ₅, Rₖ₅, and Rₗ₅ are each independently a hydrogen atom, a deuterium atom, a substituted or unsubstituted aryl group of 6 to 30 ring-forming carbon atoms, or a substituted or unsubstituted heteroaryl group of 2 to 30 ring-forming carbon atoms,
R₇ₐ to R₇ₑ are each independently a hydrogen atom, a deuterium atom, a substituted or unsubstituted alkyl group of 1 to 10 carbon atoms, or a substituted or unsubstituted aryl group of 6 to 15 ring-forming carbon atoms,
R₈ₐ and R₉ₐ are each independently a substituted or unsubstituted aryl group of 6 to 30 ring-forming carbon atoms, or R₈ₐ and R₉ₐ are combined with each other to form a ring,
i1, i4, j1, j4, k1, k4, l1, and l4 are each independently an integer of 0 to 3,
i2, i3, j2, j3, k2, k3, l2, and l3 are each independently an integer of 0 to 5, and
X, R₁ to R₃, and n1 to n3 are the same as defined with respect to Formula 1.

19. The polycyclic compound of claim 13, wherein n1 is 1, R₁ is represented by any one among SG1-1 to SG1-24 in the following Substituent Group 1, and
n3 is 1 or 2, and R₃ is represented by any one among SG1-1 to SG1-25 in the following Substituent Group 1: 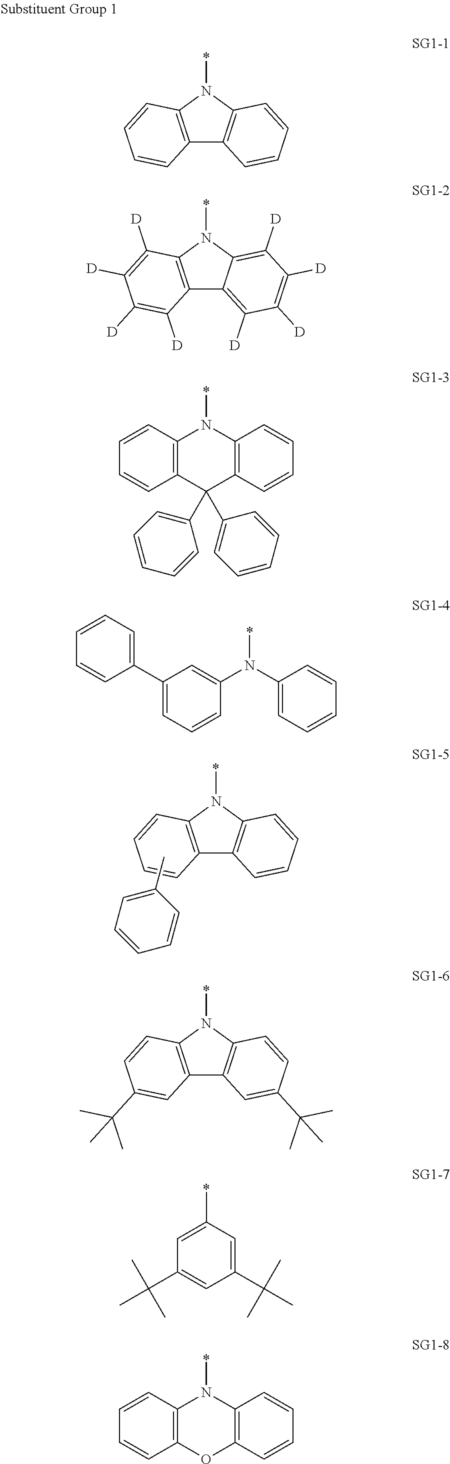 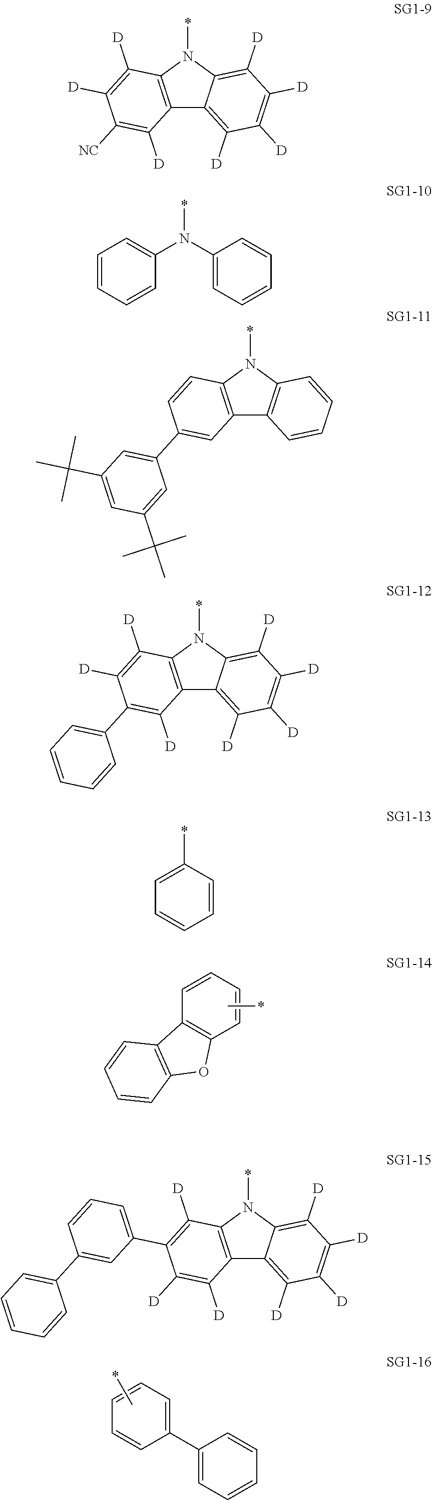 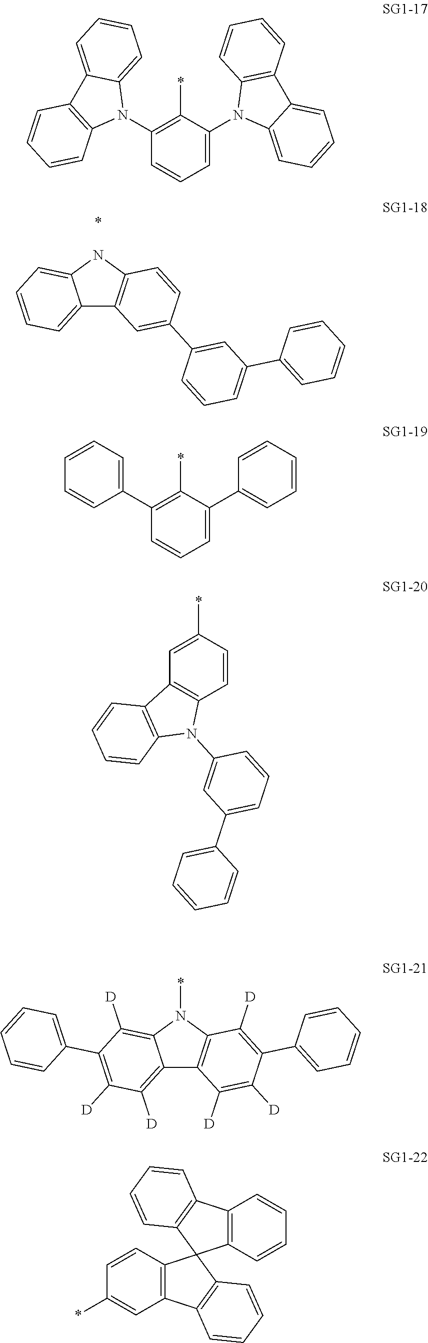 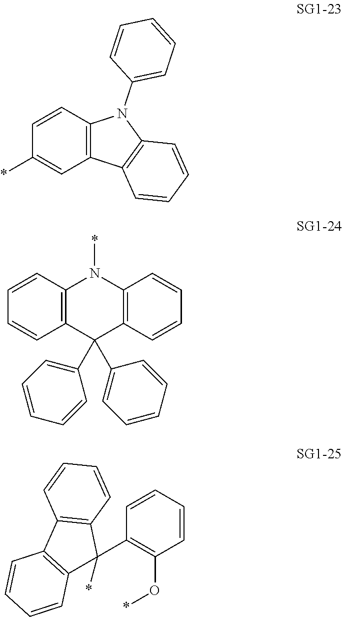
in Substituent Group 1, *— is a position connected with Formula 1, and “D” is a deuterium atom.

20. The polycyclic compound of claim 13, wherein R₄ of Formula 1 is a hydrogen atom or a deuterium atom, or represented by any one among SG2-1 to SG2-10 in the following Substituent Group 2: 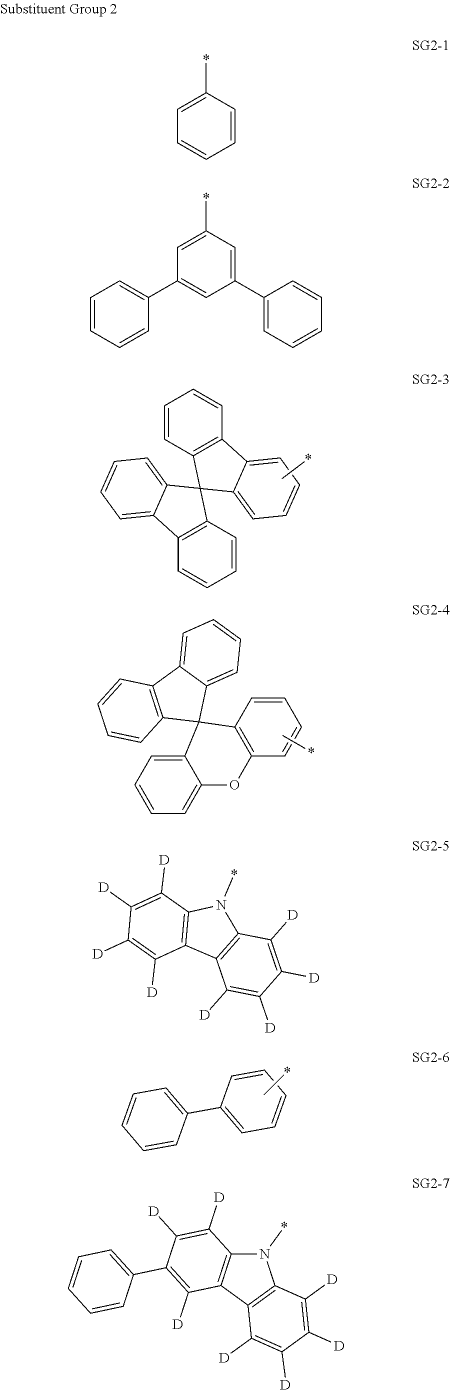 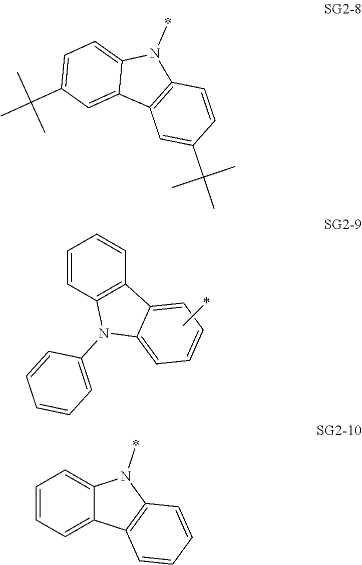
in Substituent Group 2, *— is a position connected with Formula 1, and D is a deuterium atom.

21. The polycyclic compound of claim 13, wherein the first compound is represented by any one among compounds in the following Compound Group 1: 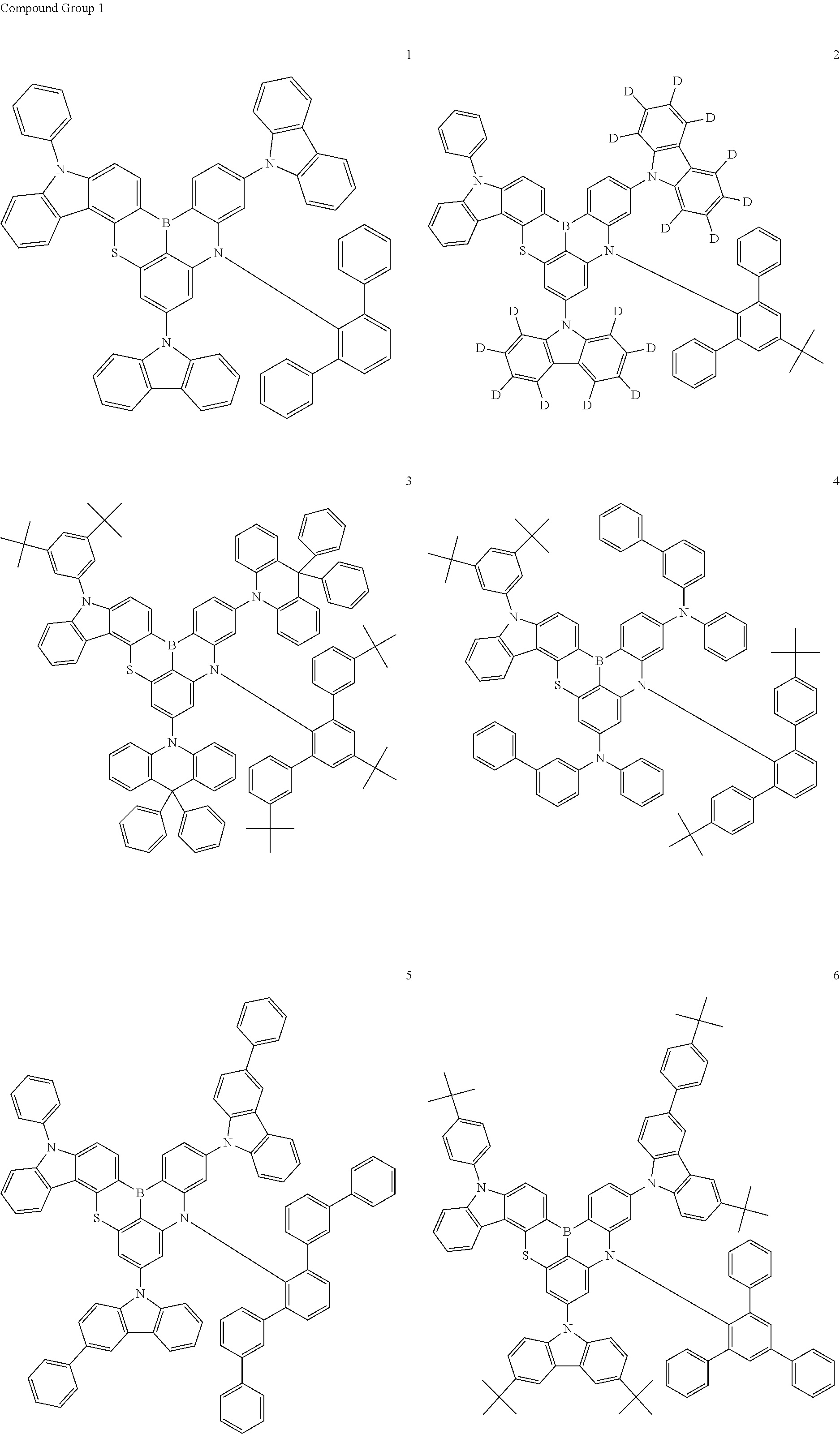 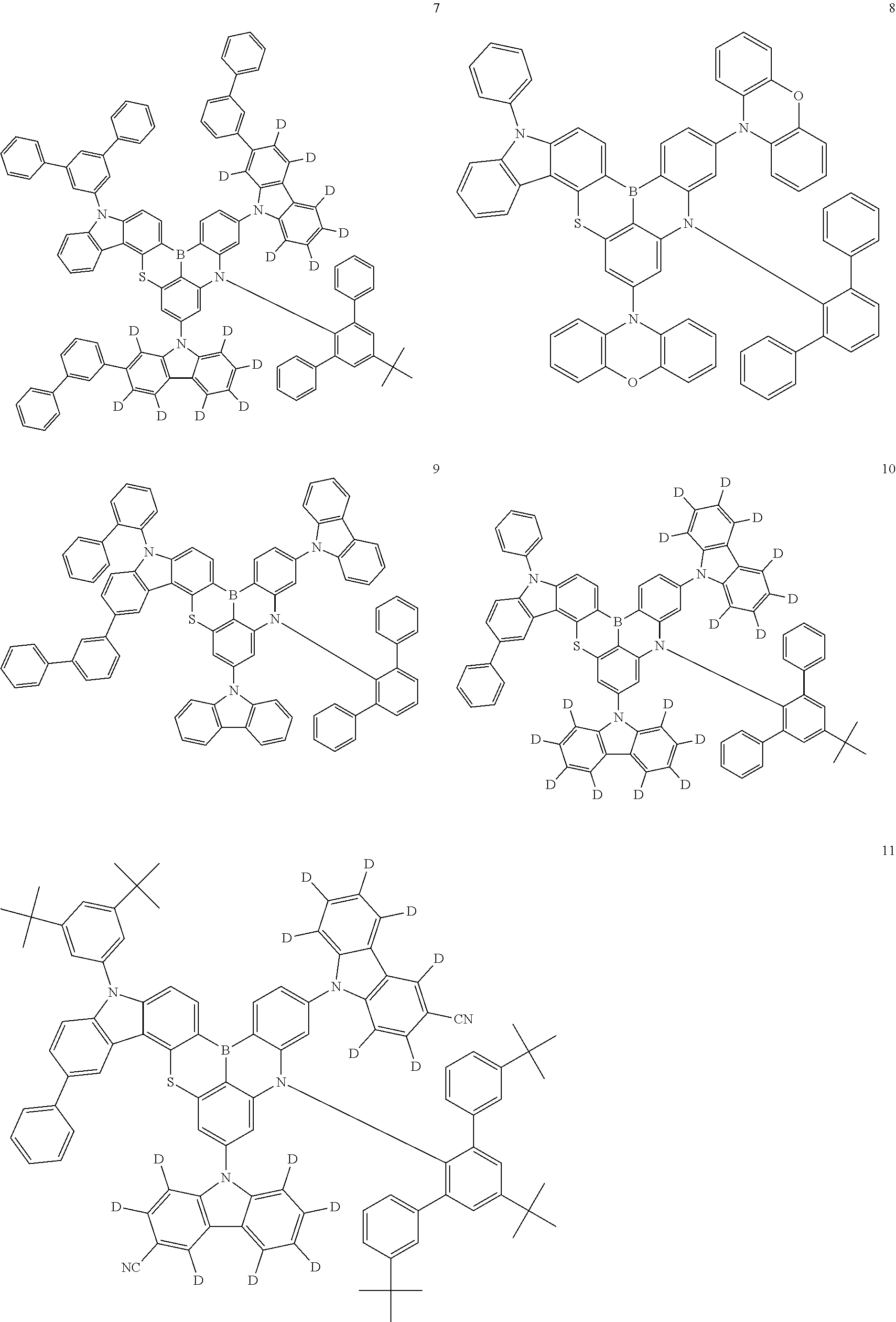 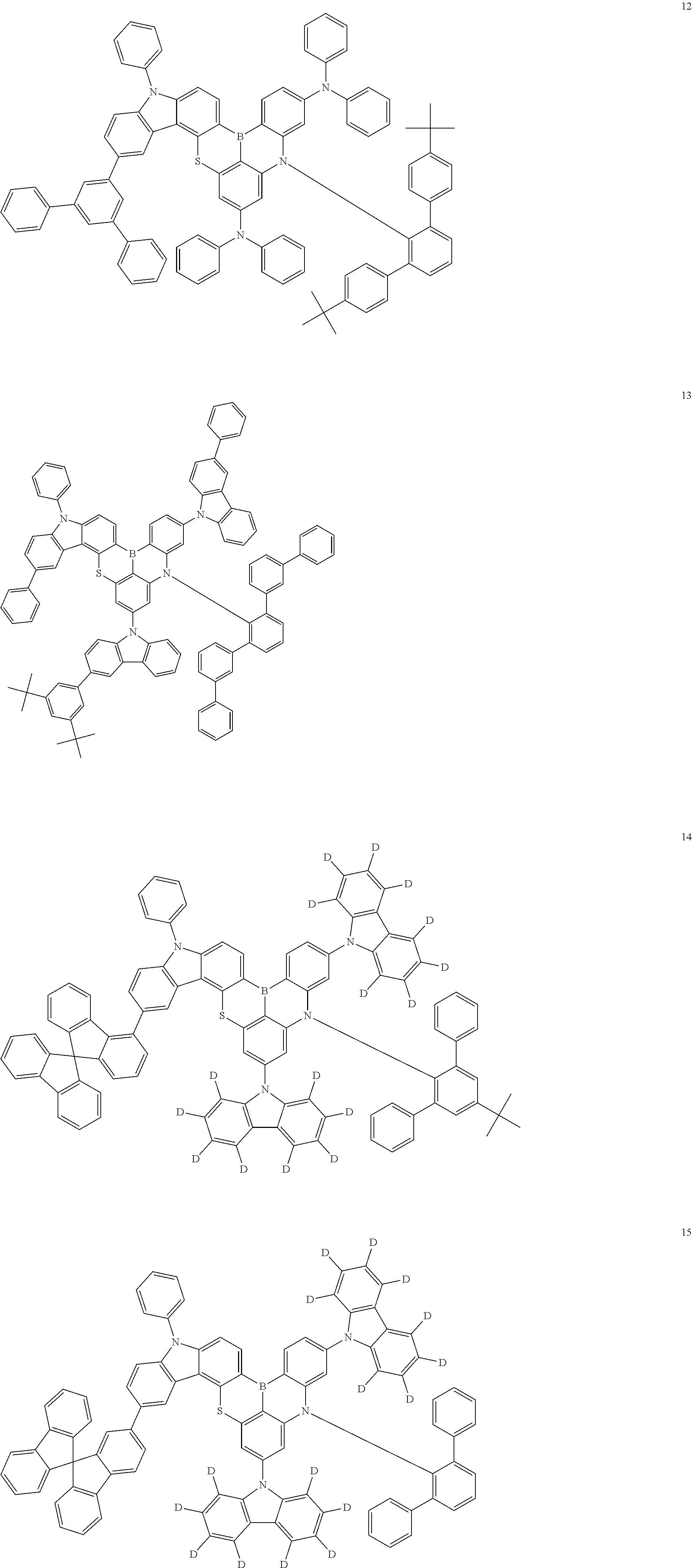 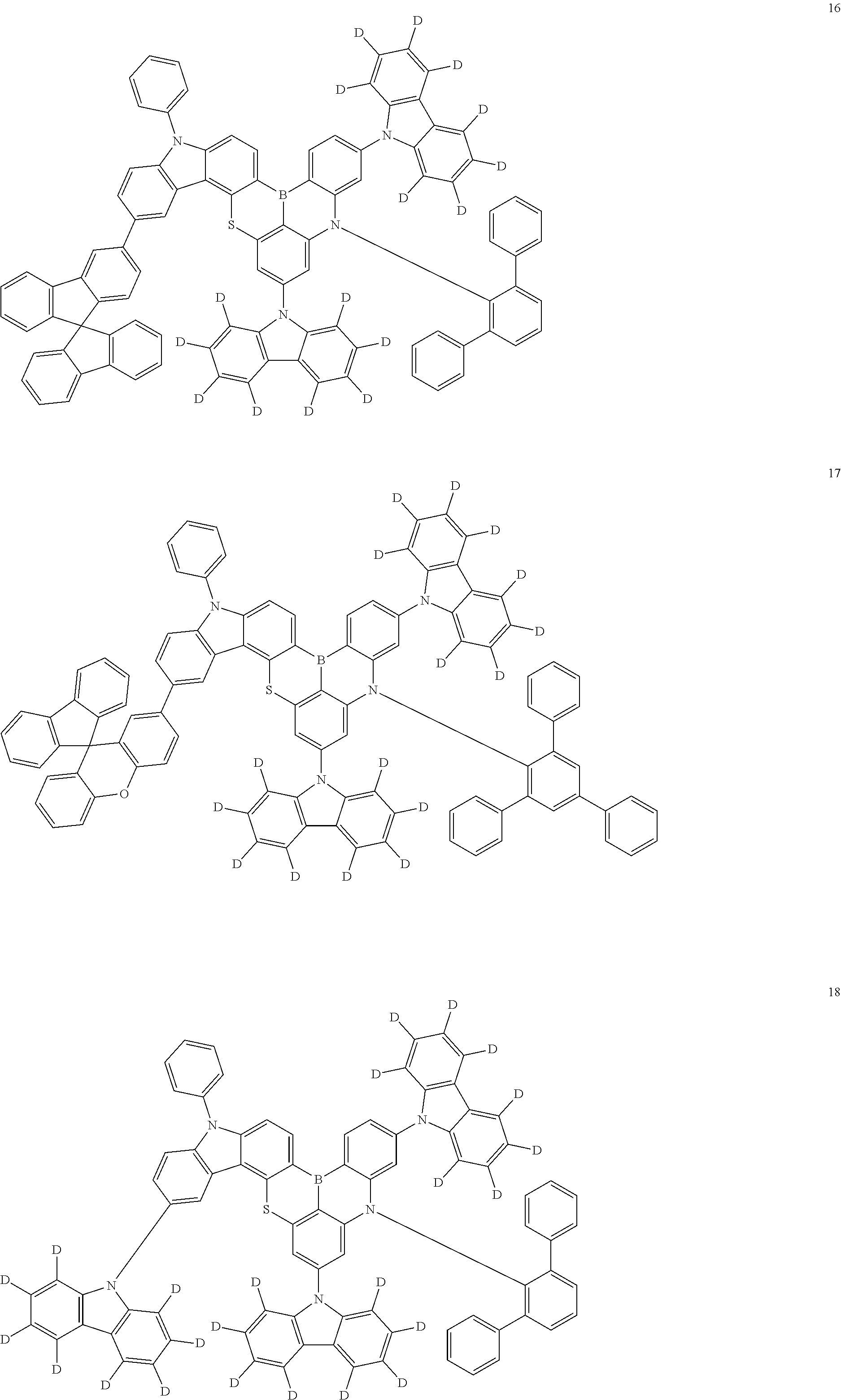 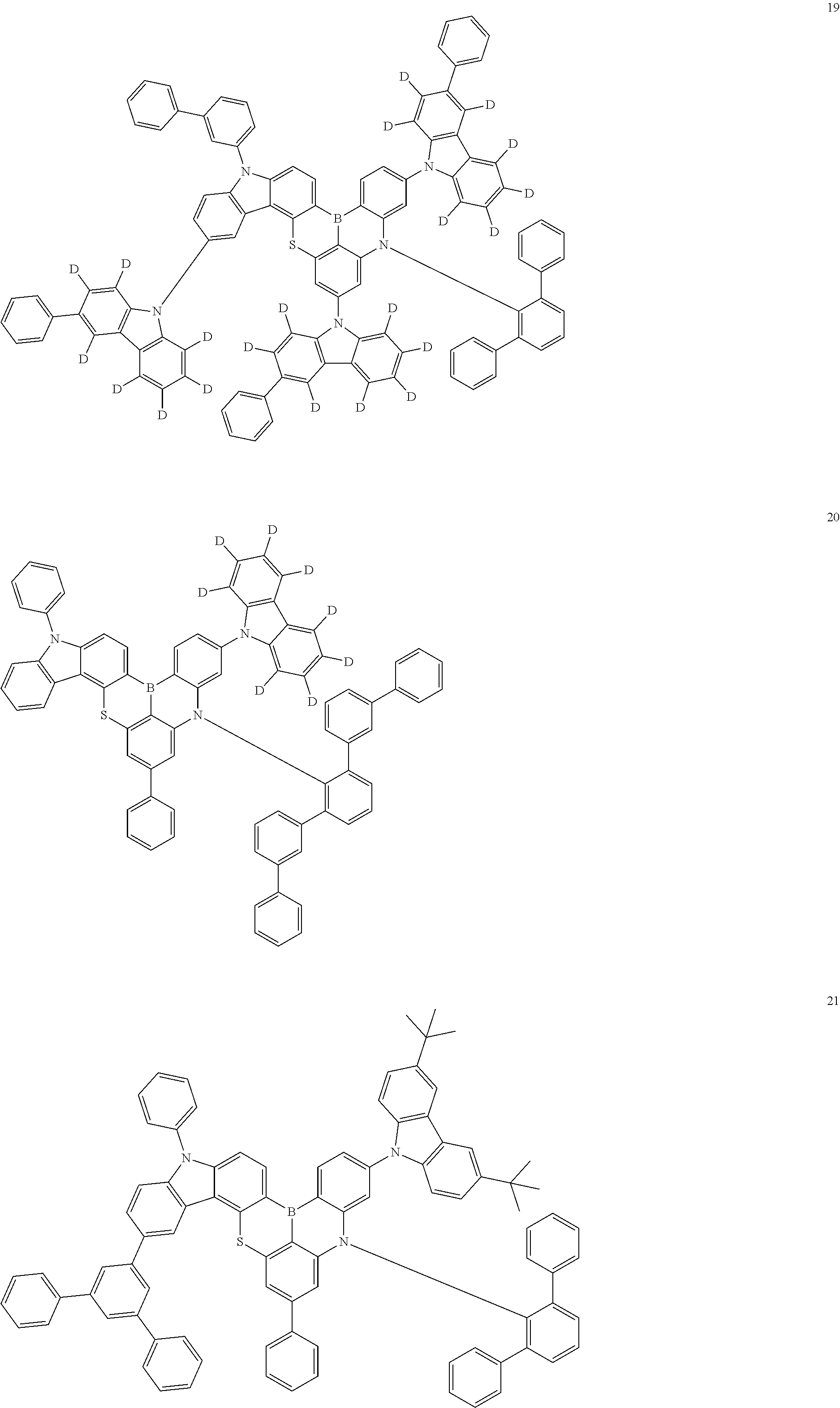 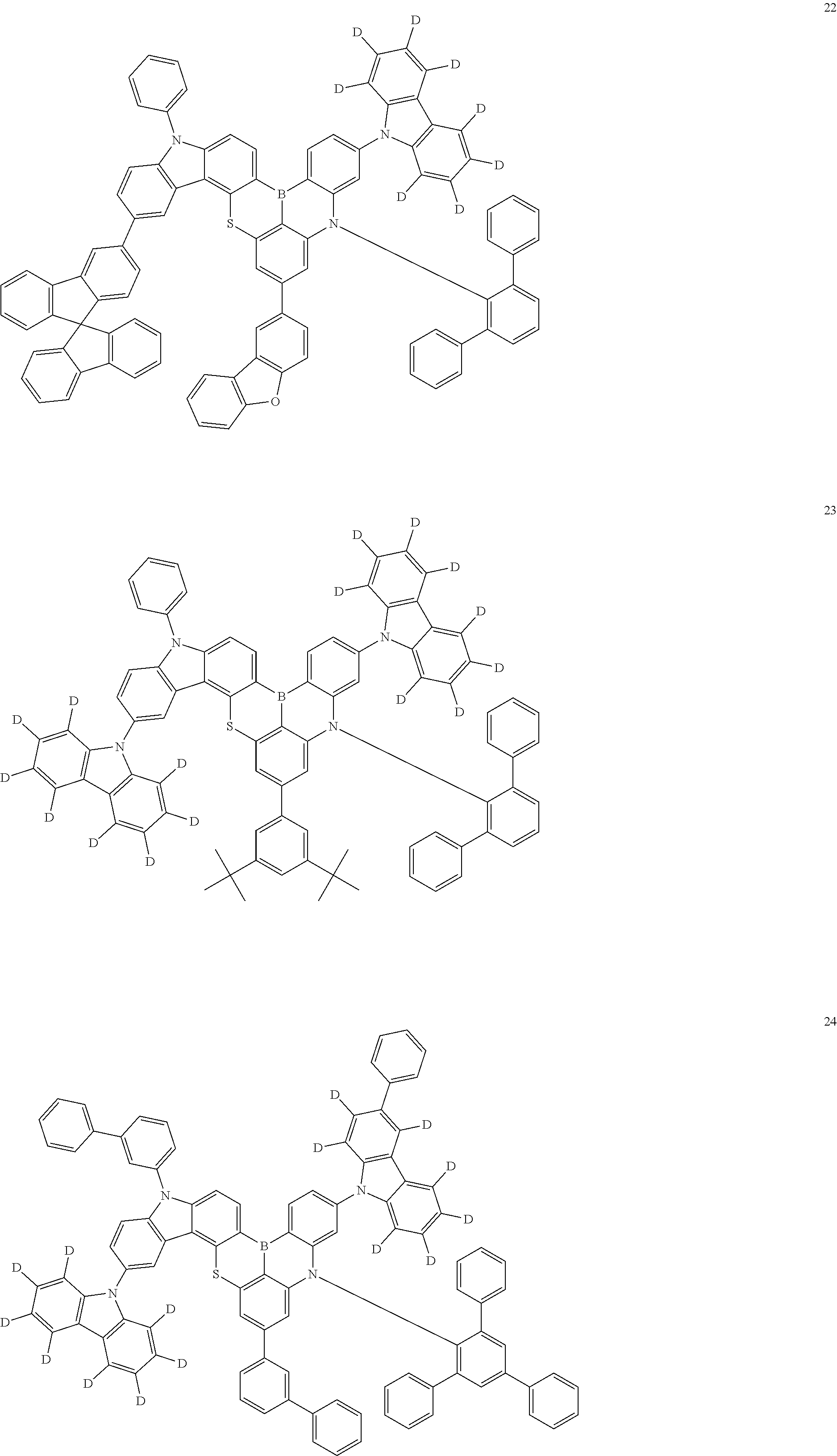 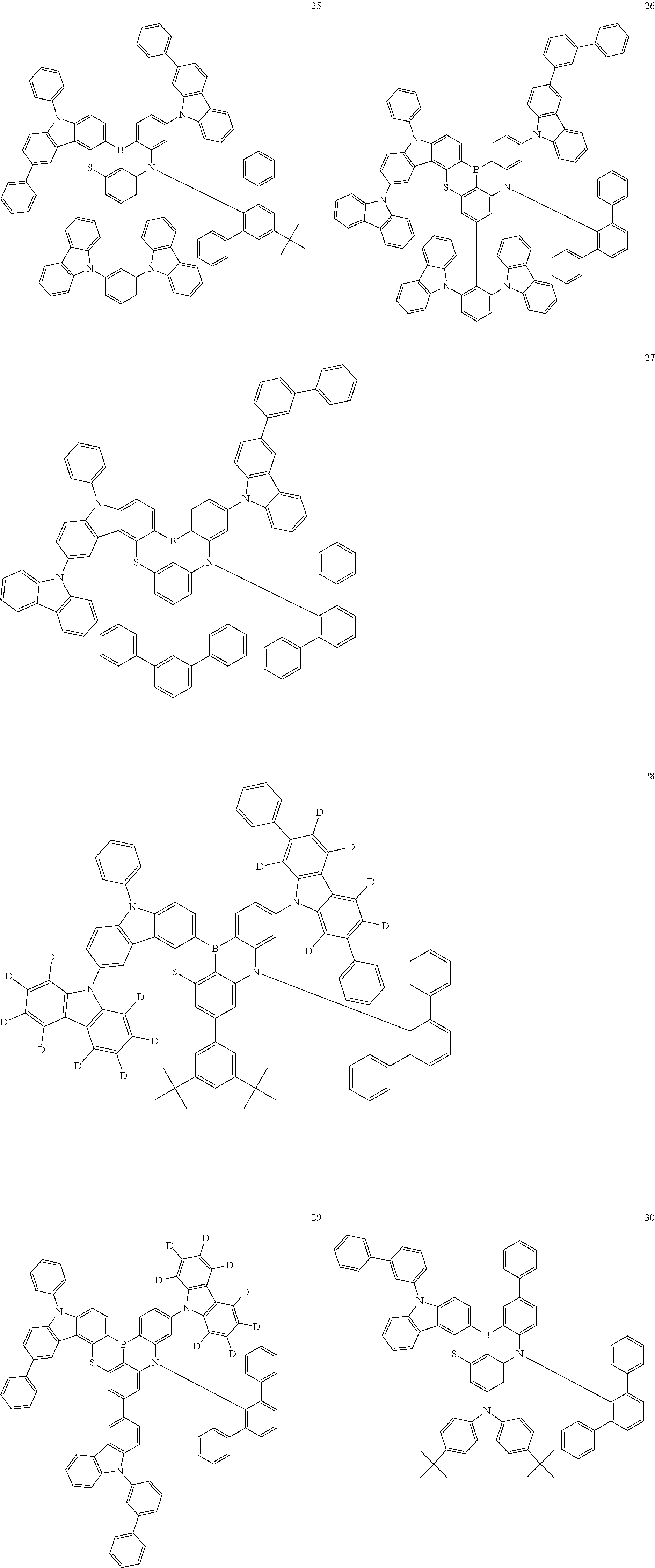 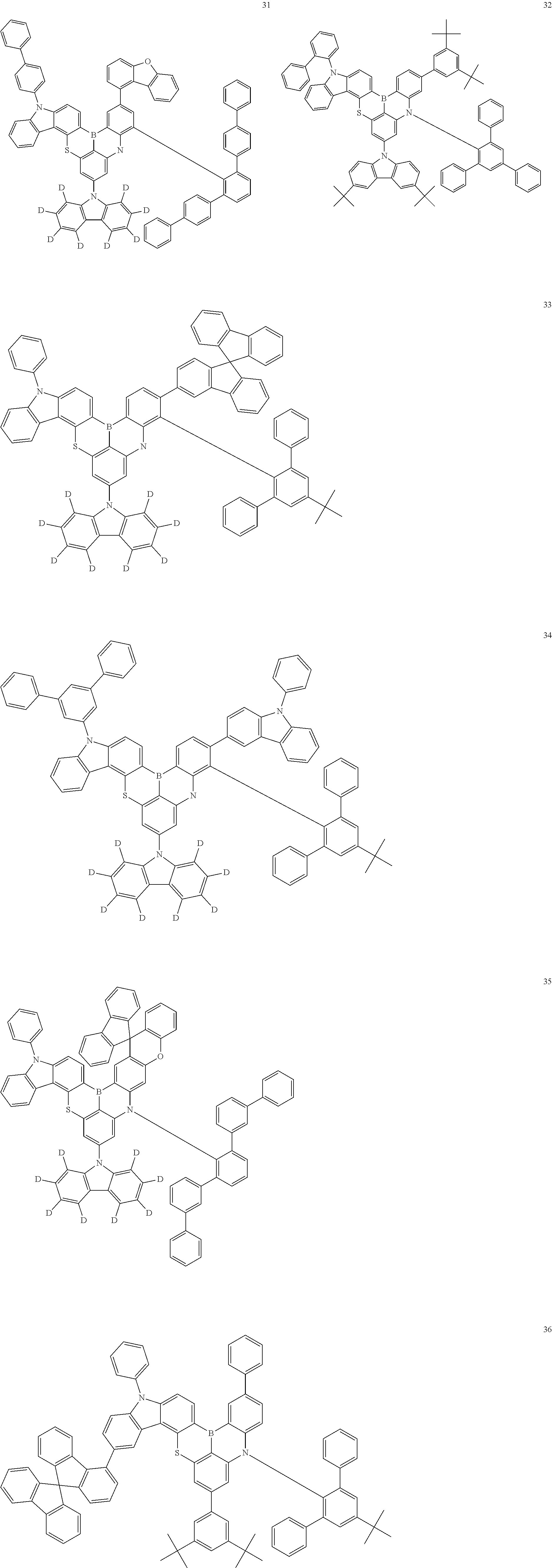 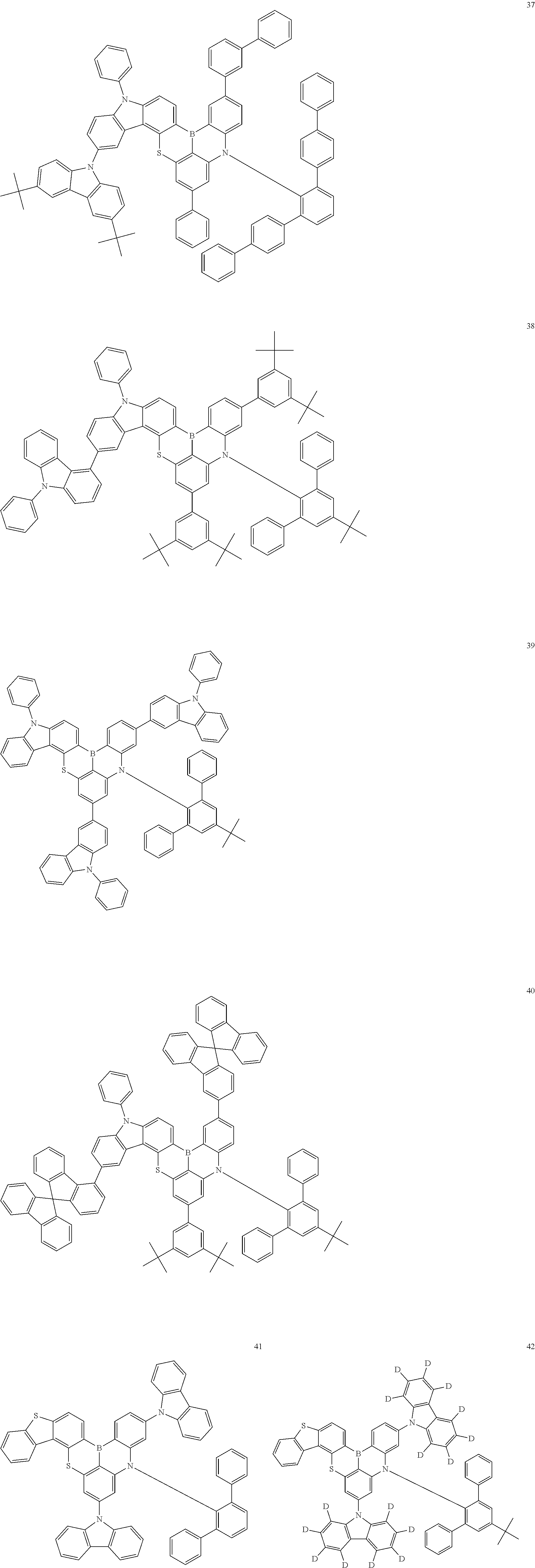 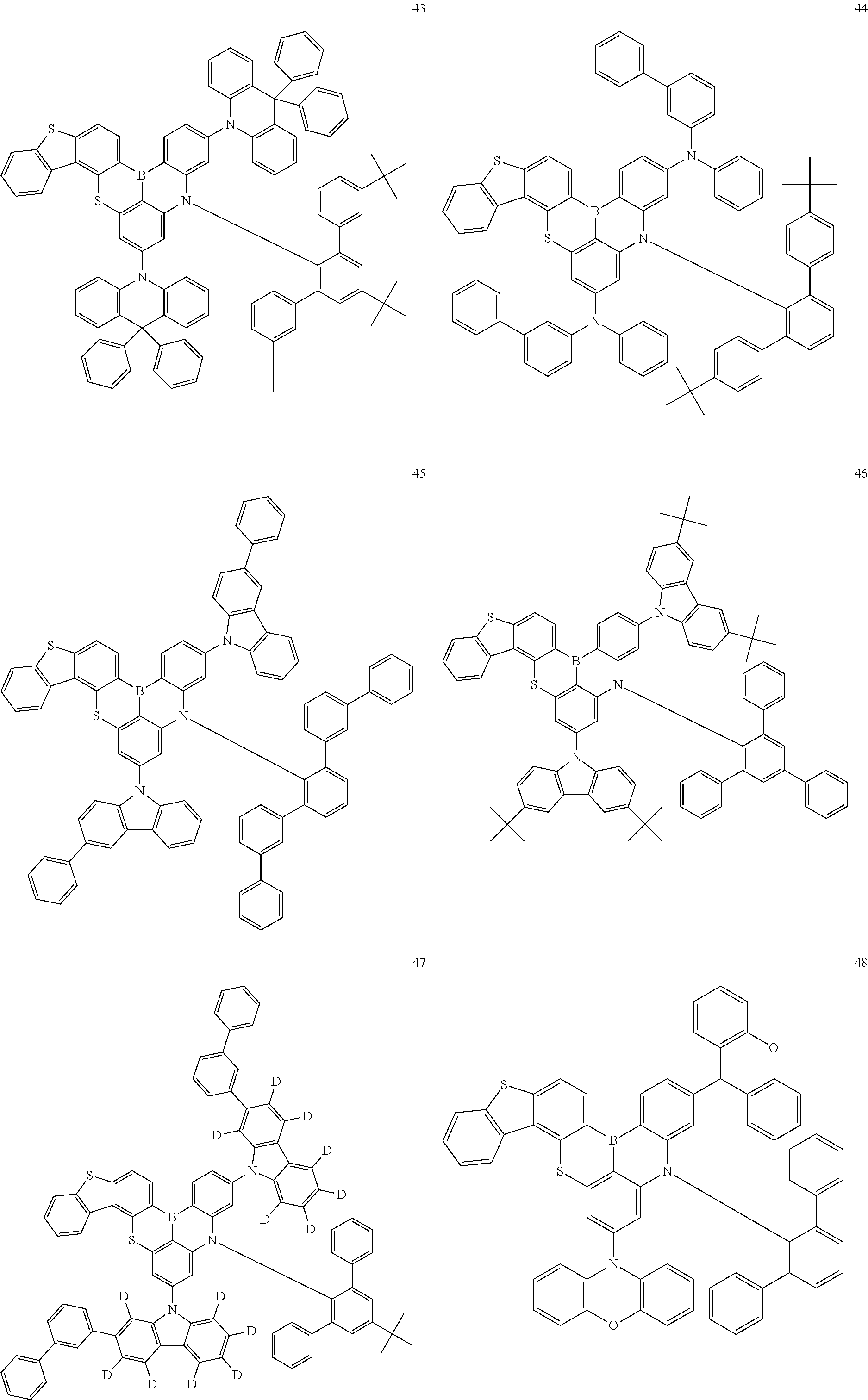 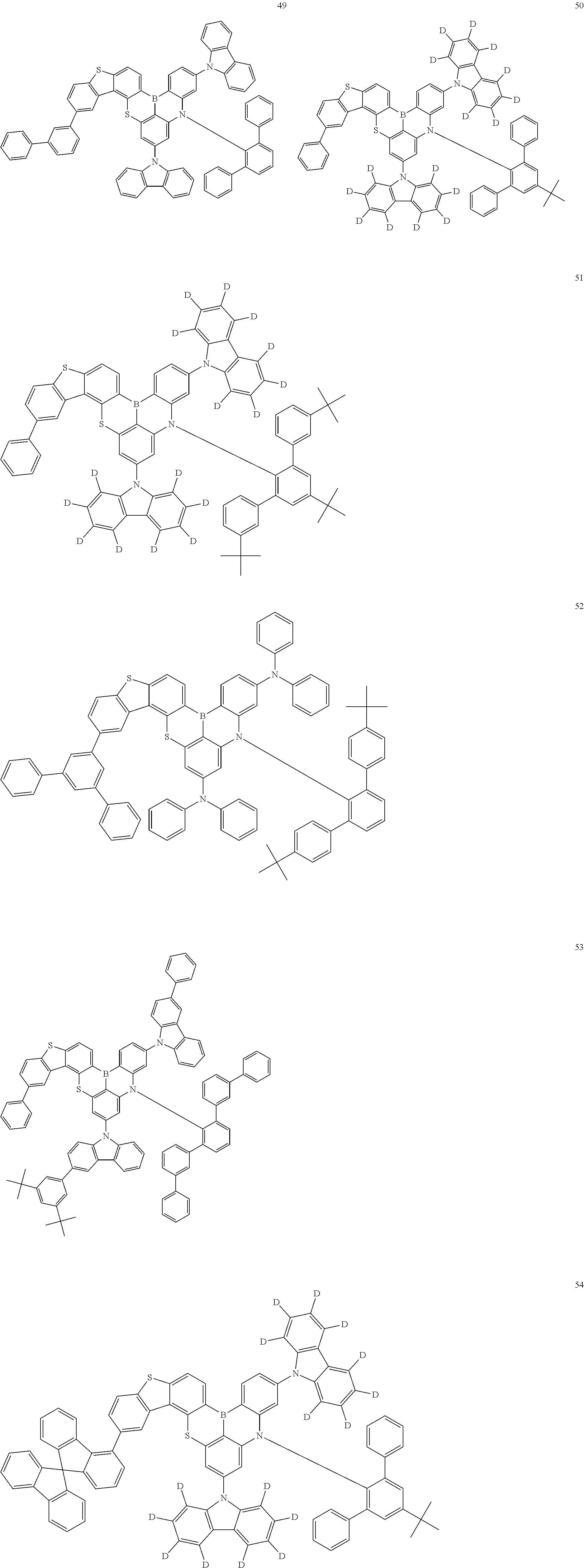 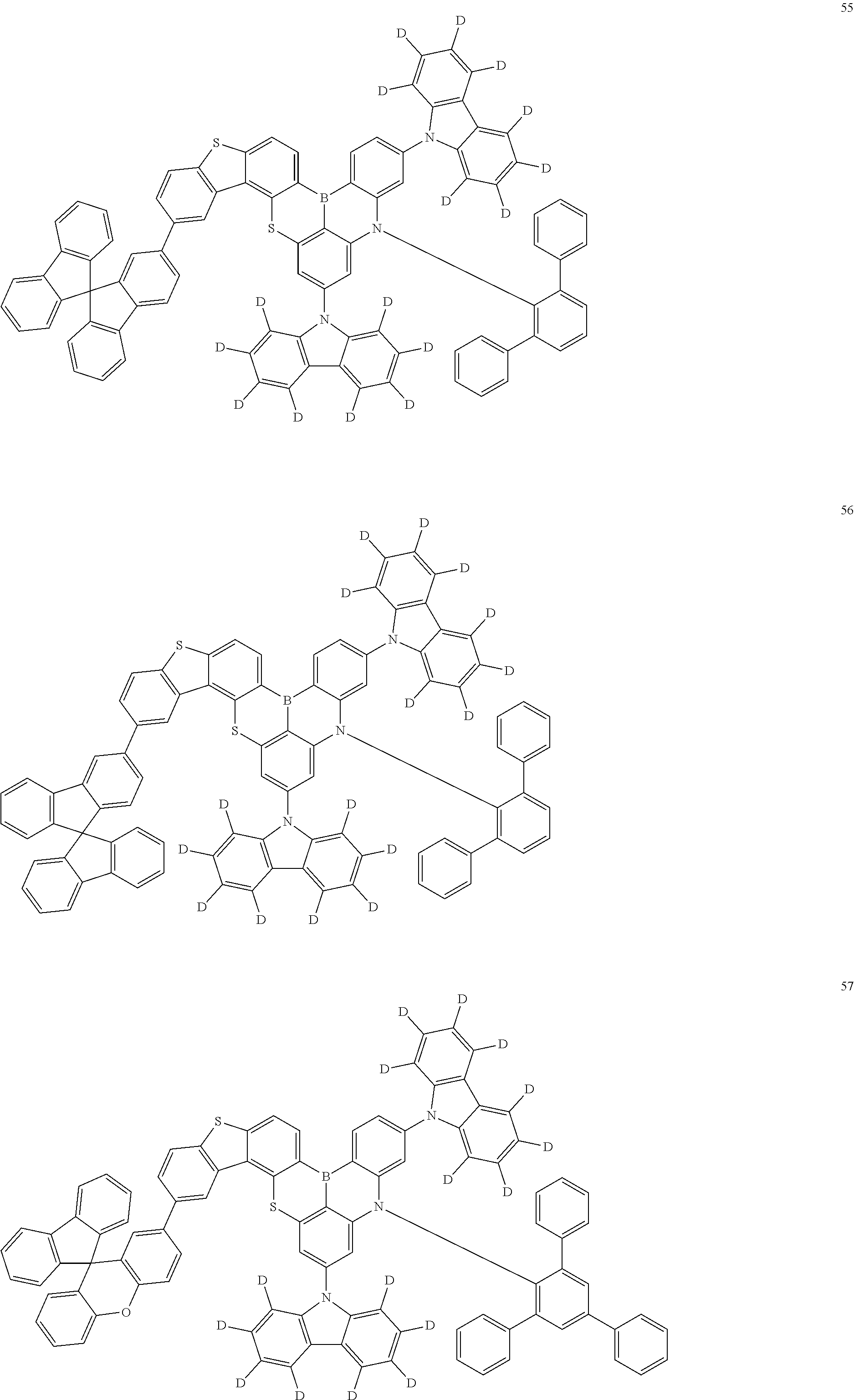 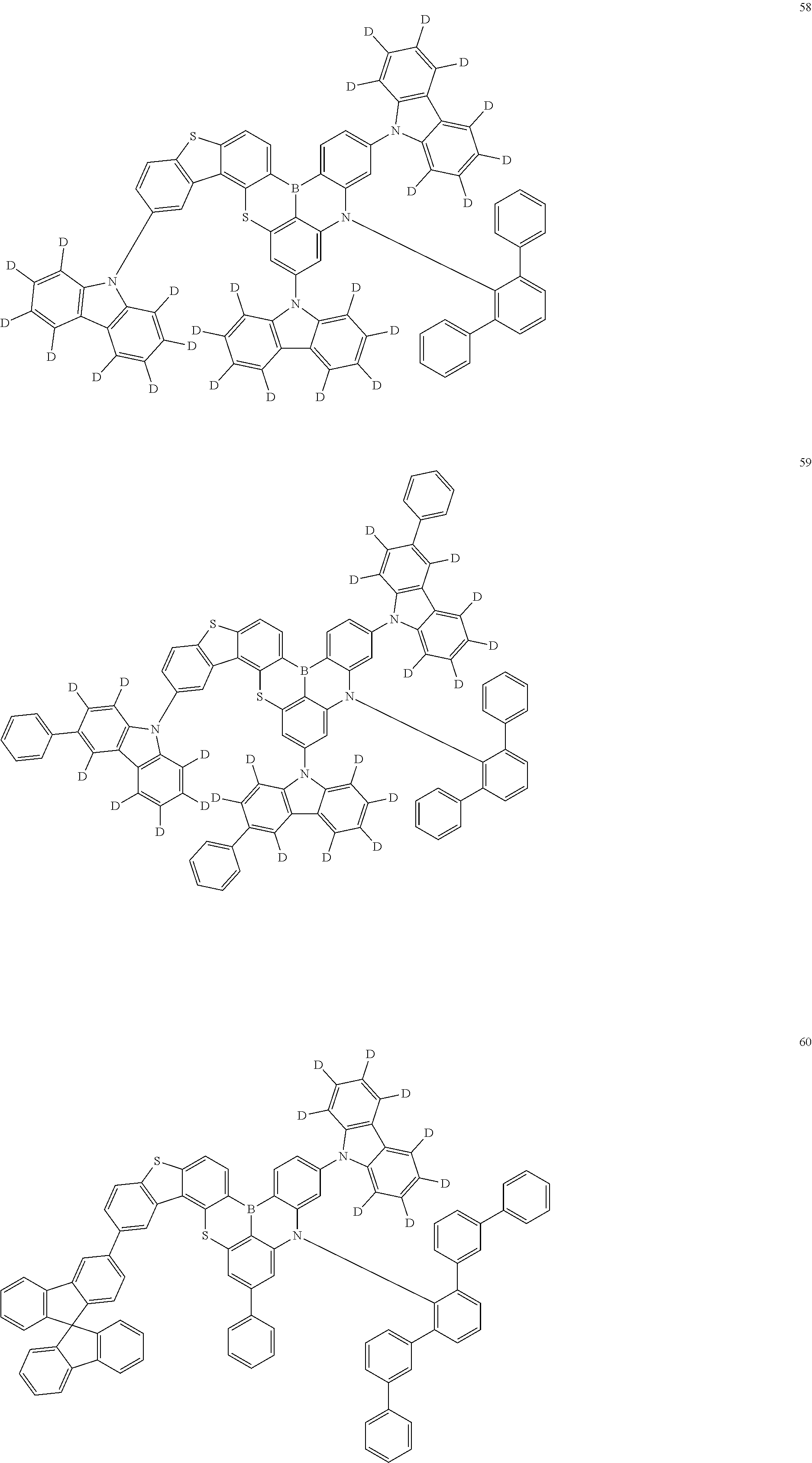 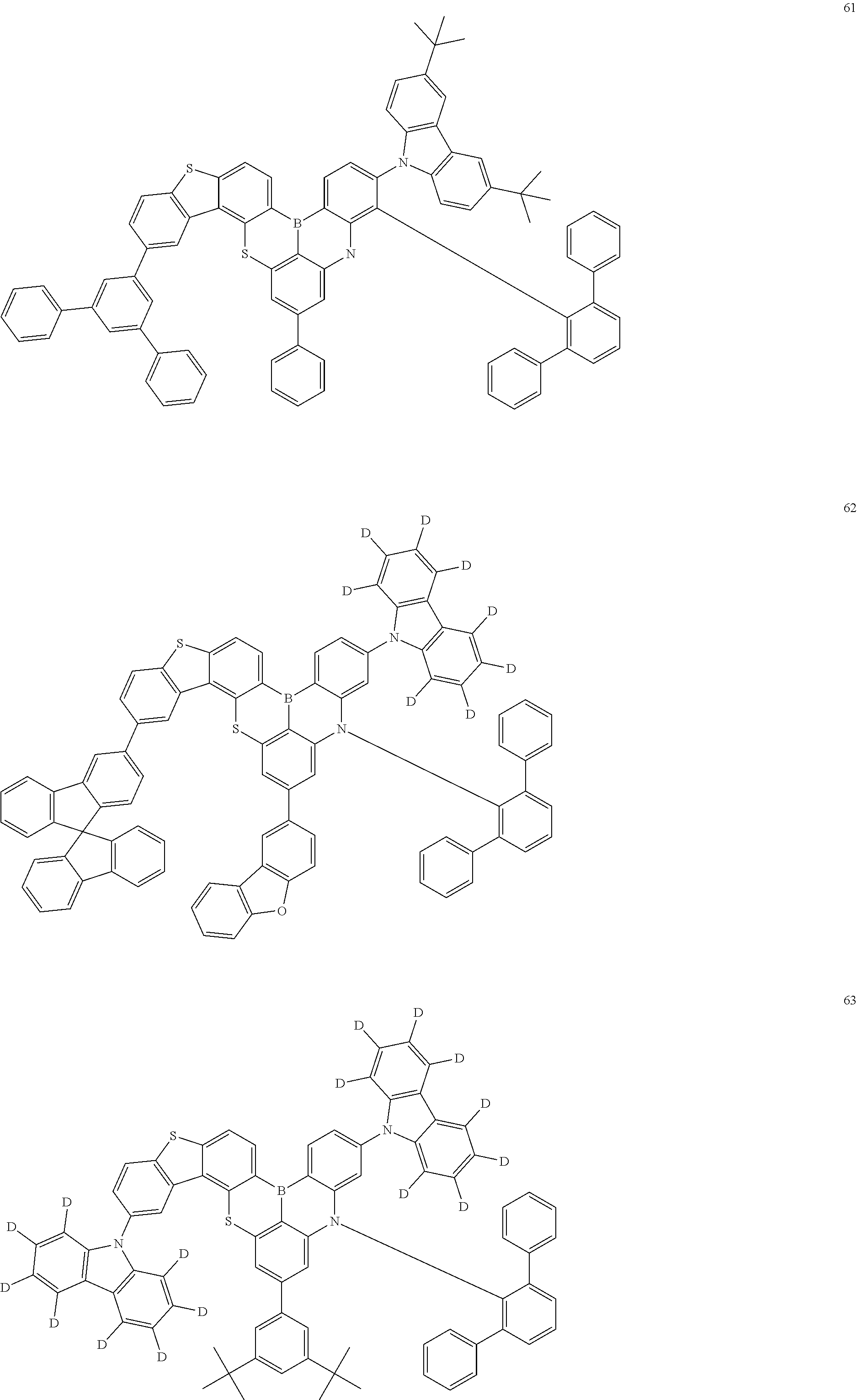 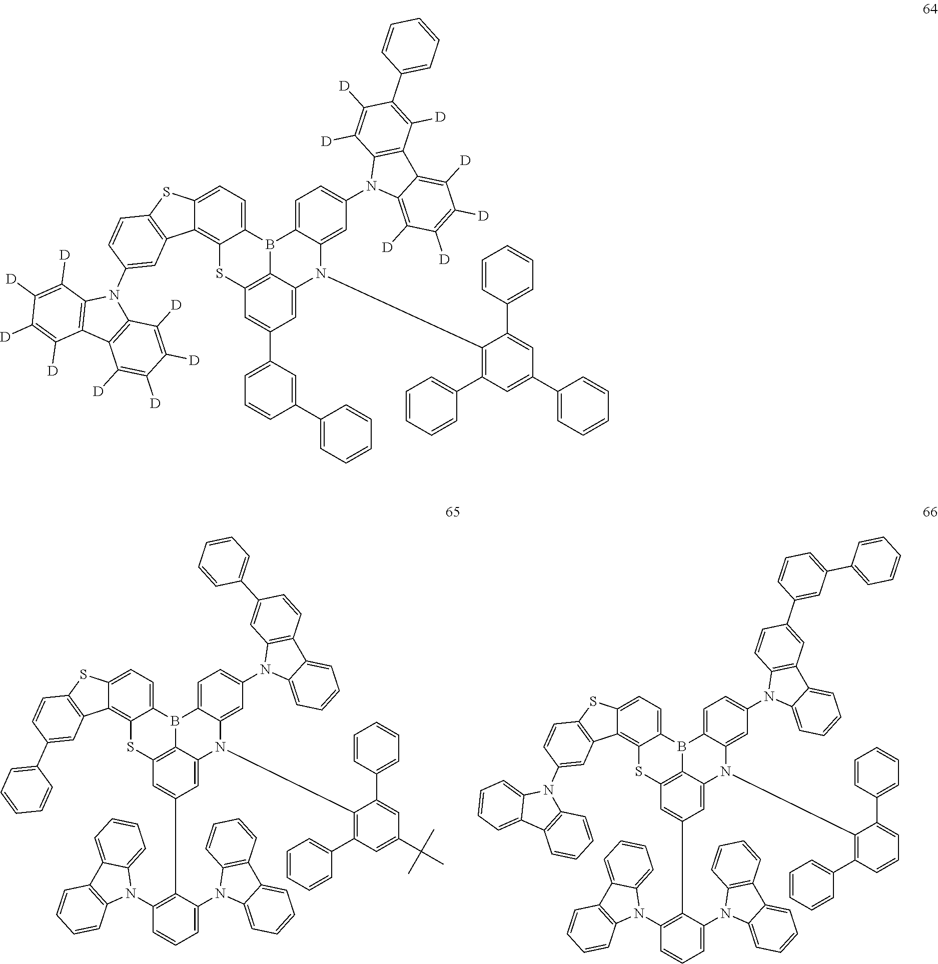 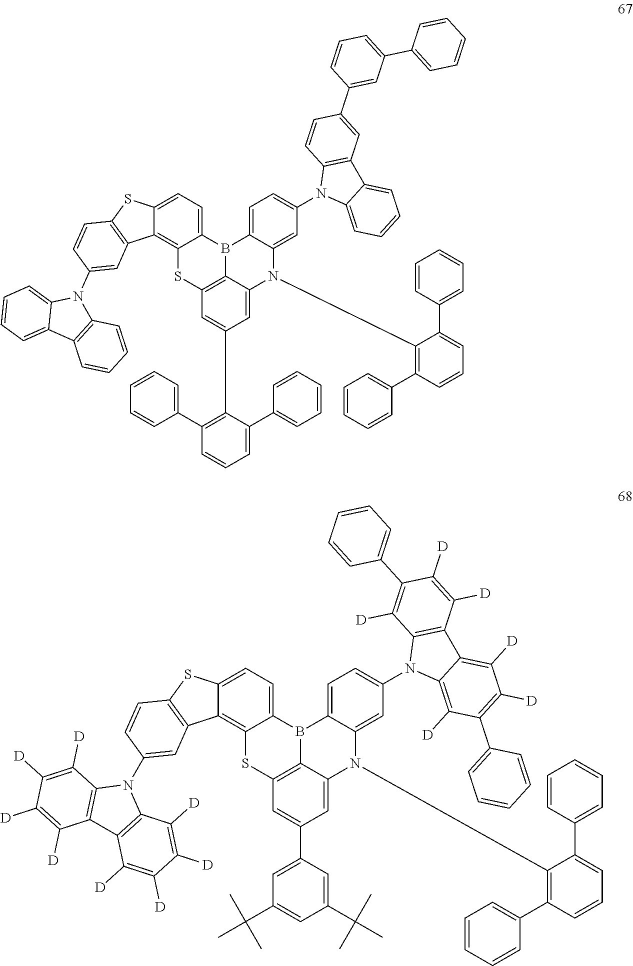 [SMILES: c1ccc(-c2cccc(-c3ccc4c(c3)c3ccccc3n4-c3ccc4c(c3)N(c3c(-c5ccccc5)cccc3-c3ccccc3)c3cc(-c5c(-c6ccccc6)cccc5-c5ccccc5)cc5c3B4c3ccc4sc6ccc(-n7c8ccccc8c8ccccc87)cc6c4c3S5)c2)cc1 ; [2H]c1c([2H])c([2H])c2c(c1[2H])c1c([2H])c([2H])c([2H])c([2H])c1n2-c1ccc2sc3ccc4c(c3c2c1)Sc1cc(-c2cc(C(C)(C)C)cc(C(C)(C)C)c2)cc2c1B4c1ccc(-n3c4c([2H])c(-c5ccccc5)c([2H])c([2H])c4c4c([2H])c([2H])c(-c5ccccc5)c([2H])c43)cc1N2c1c(-c2ccccc2)cccc1-c1ccccc1] 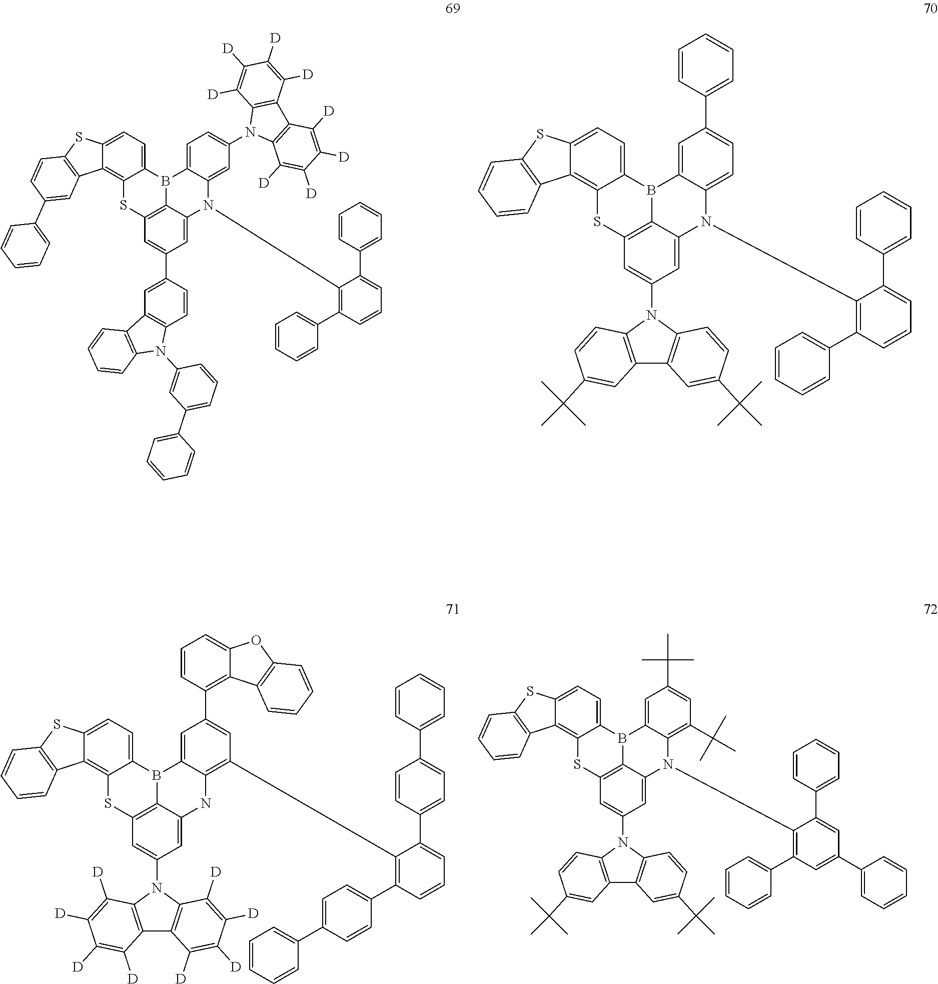 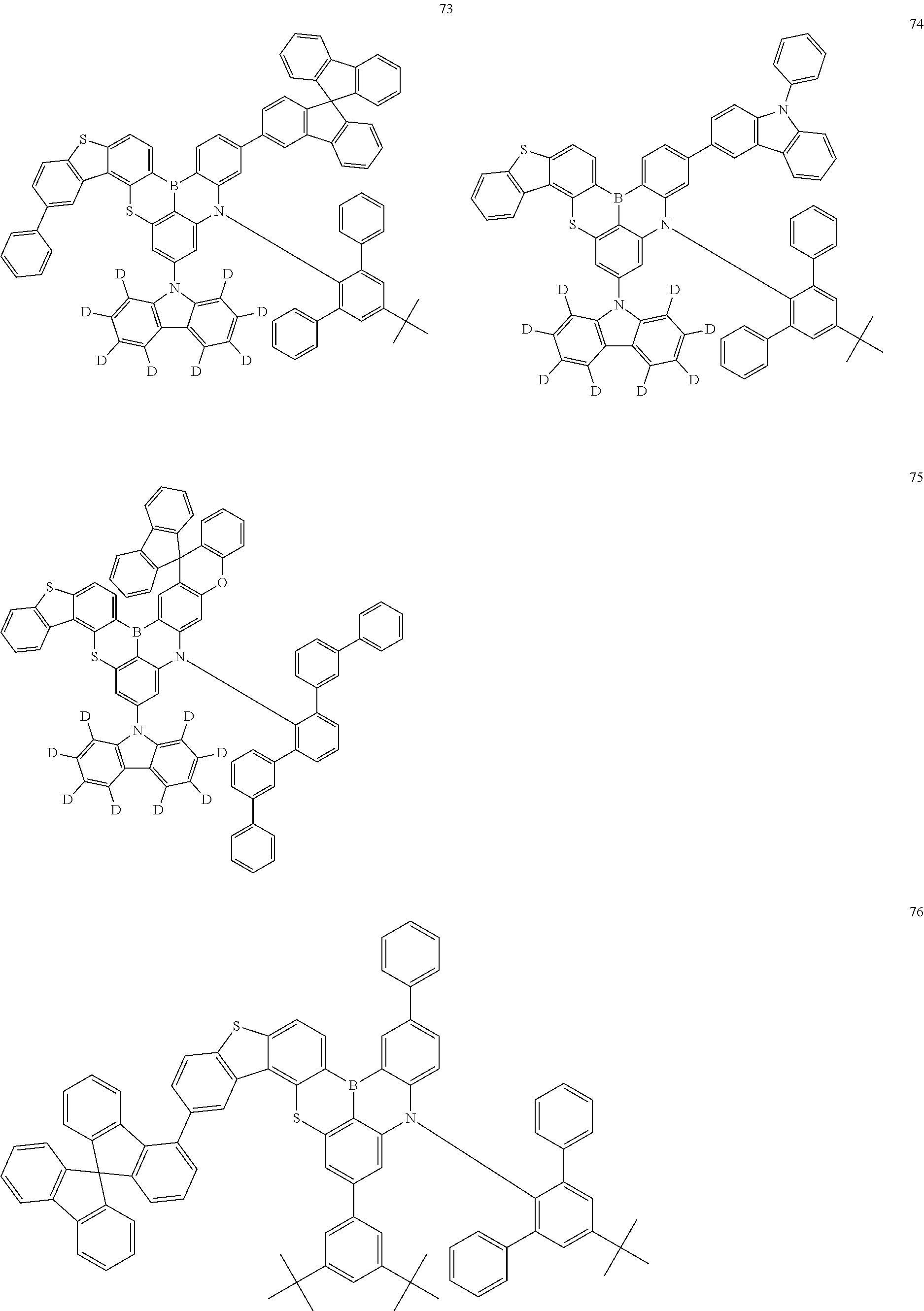 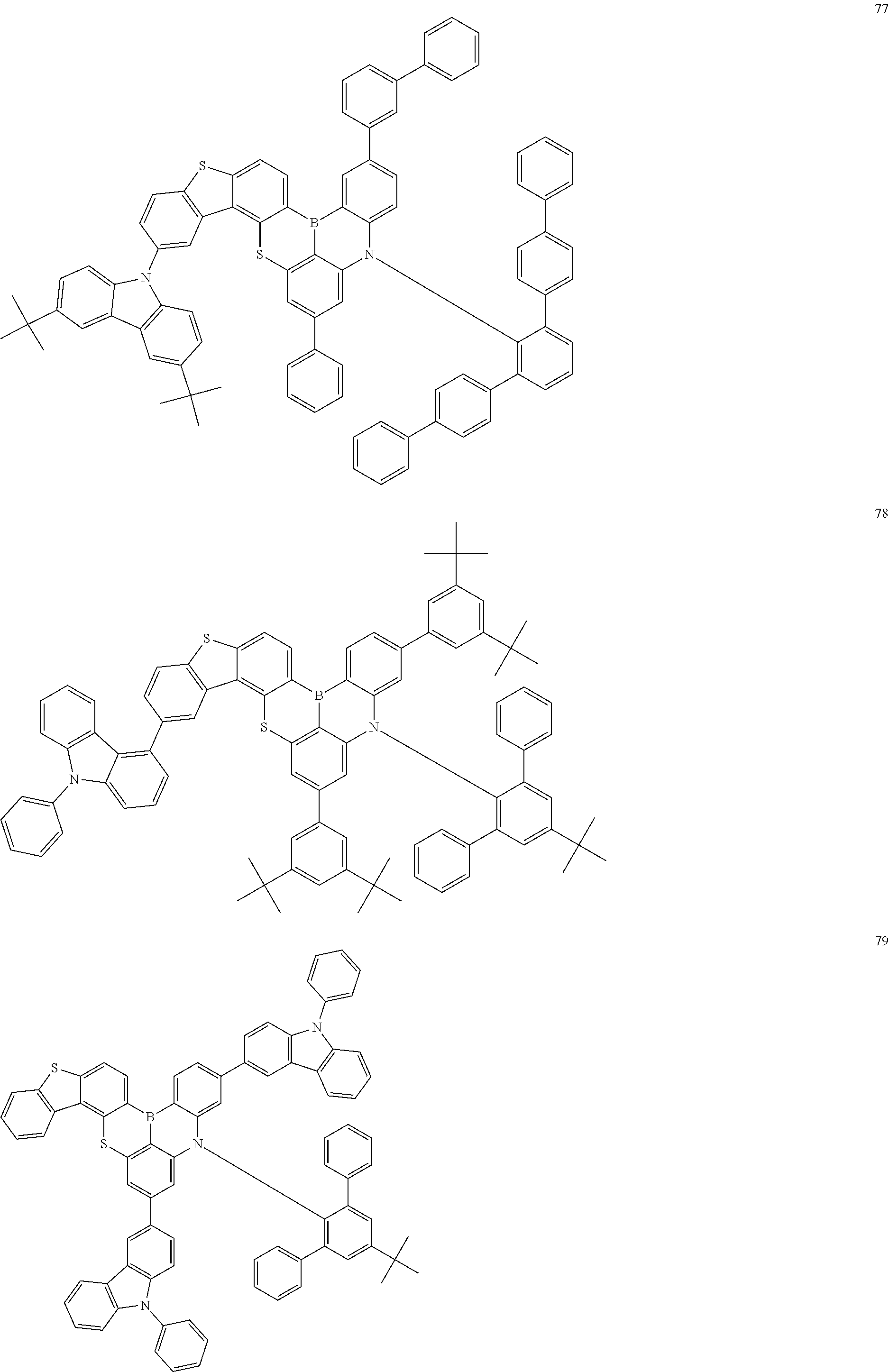 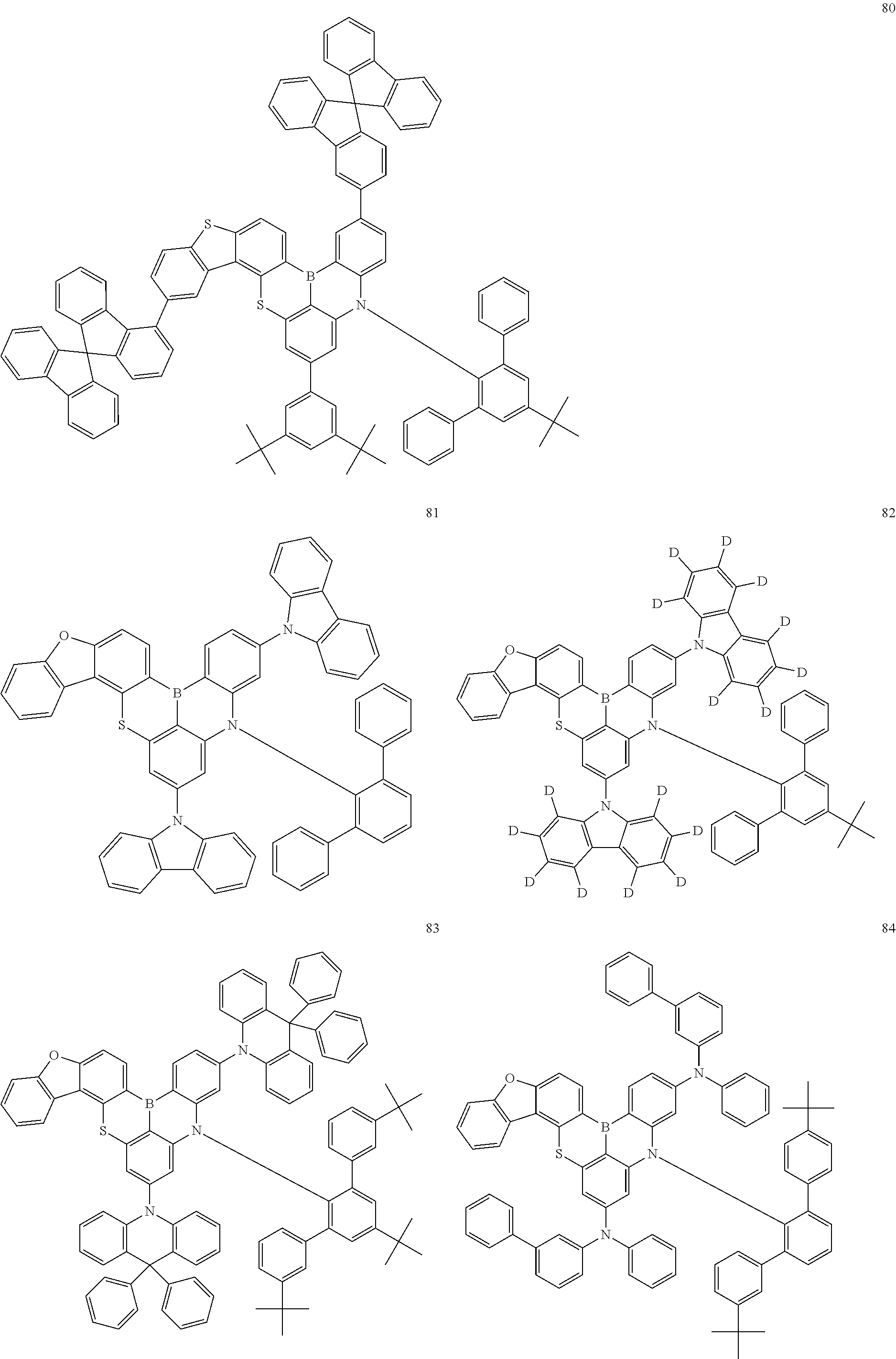 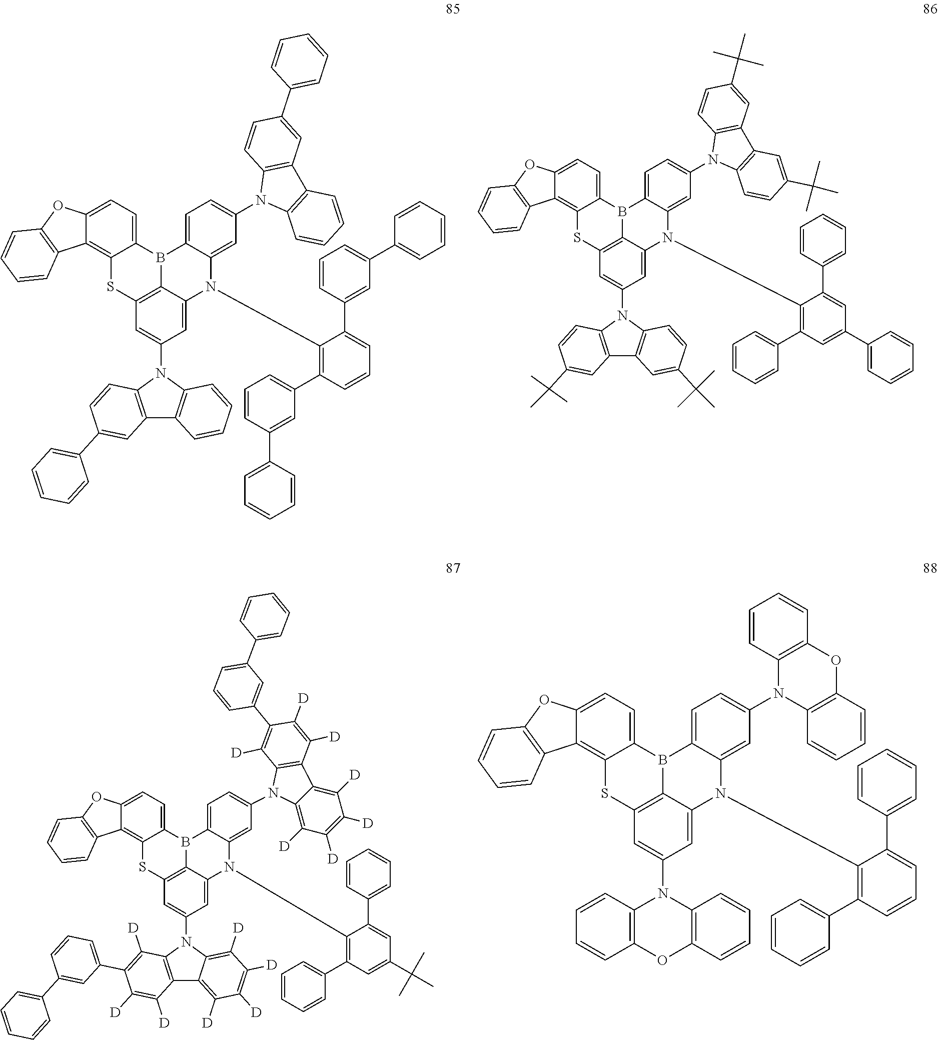 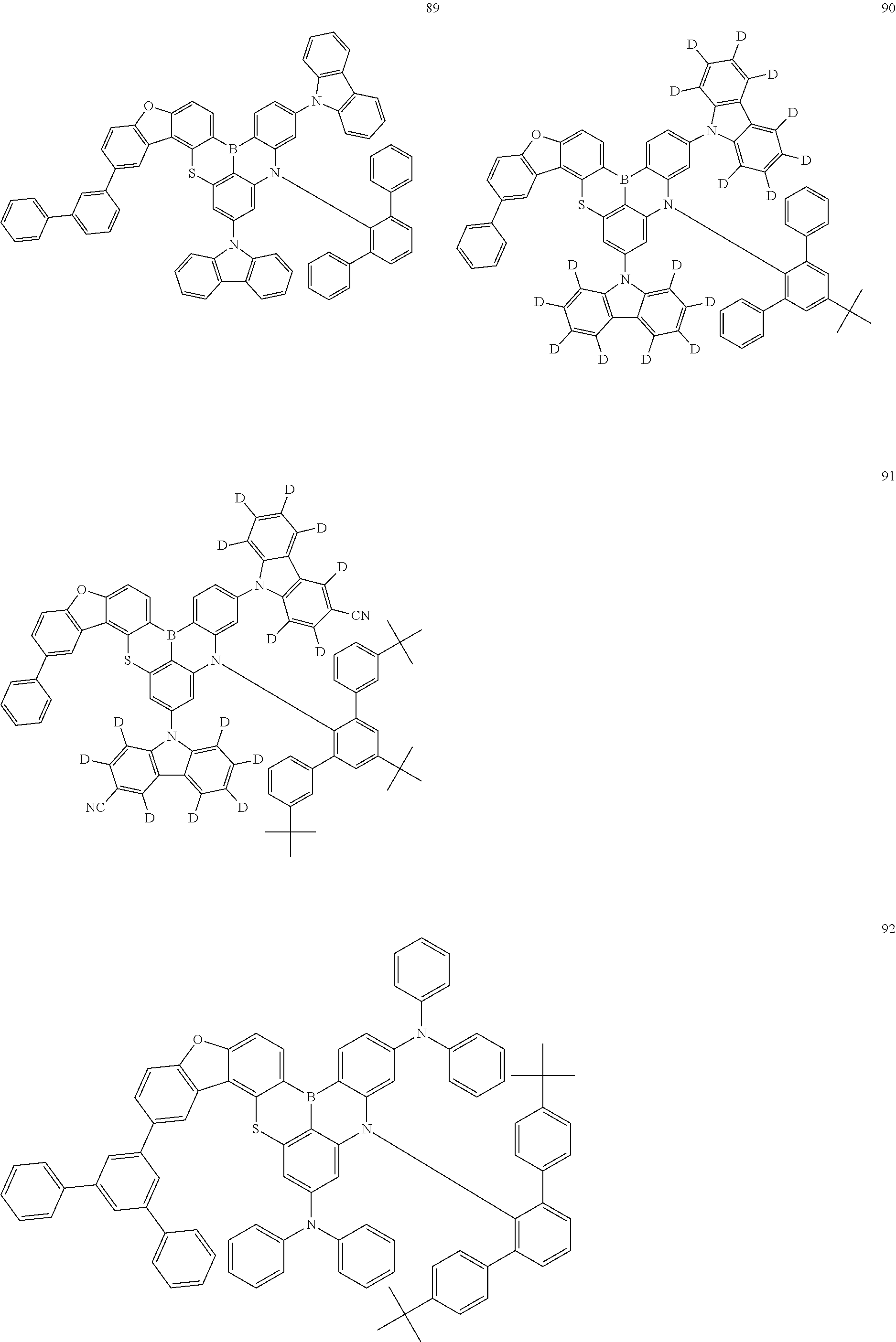 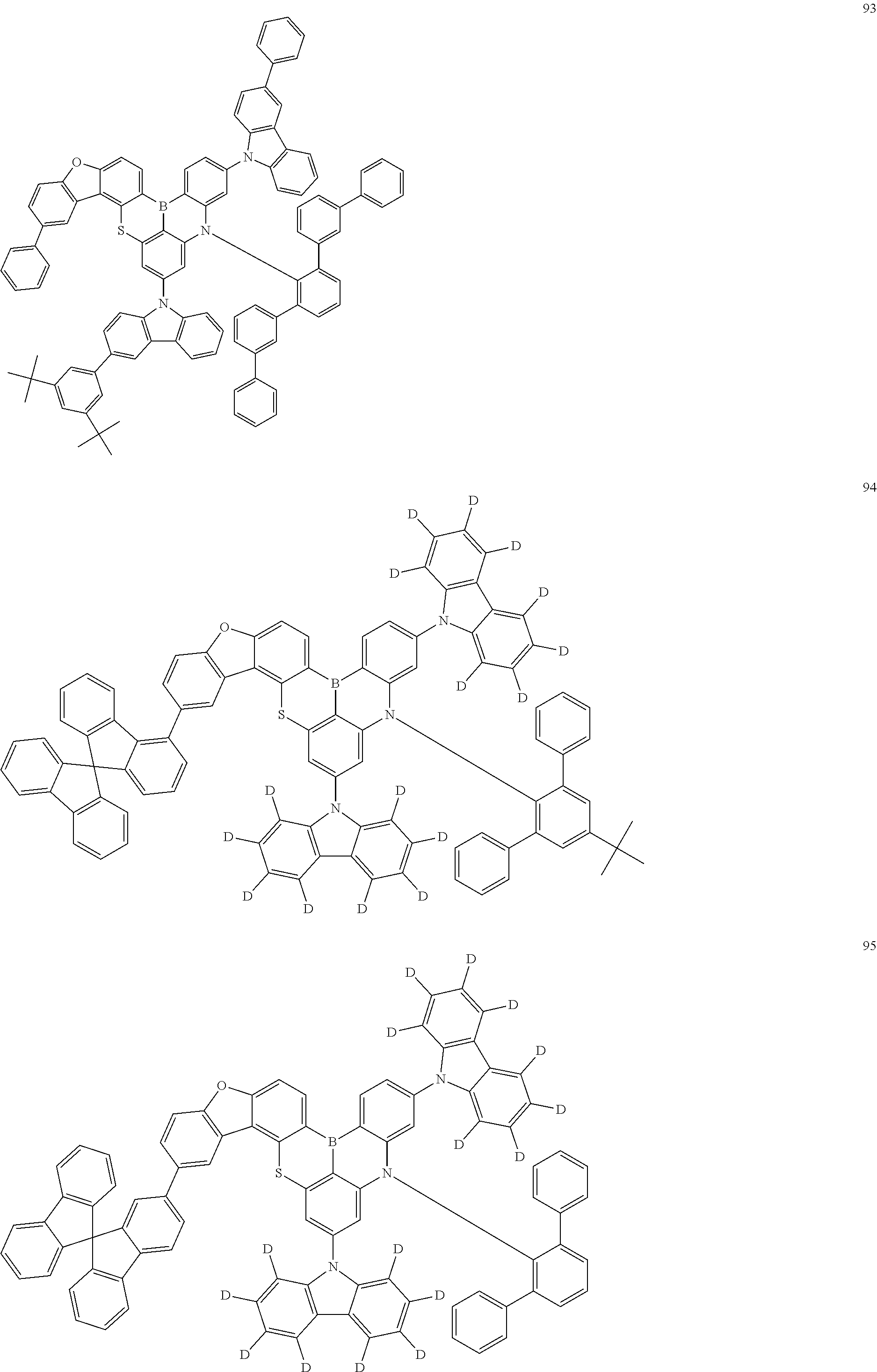 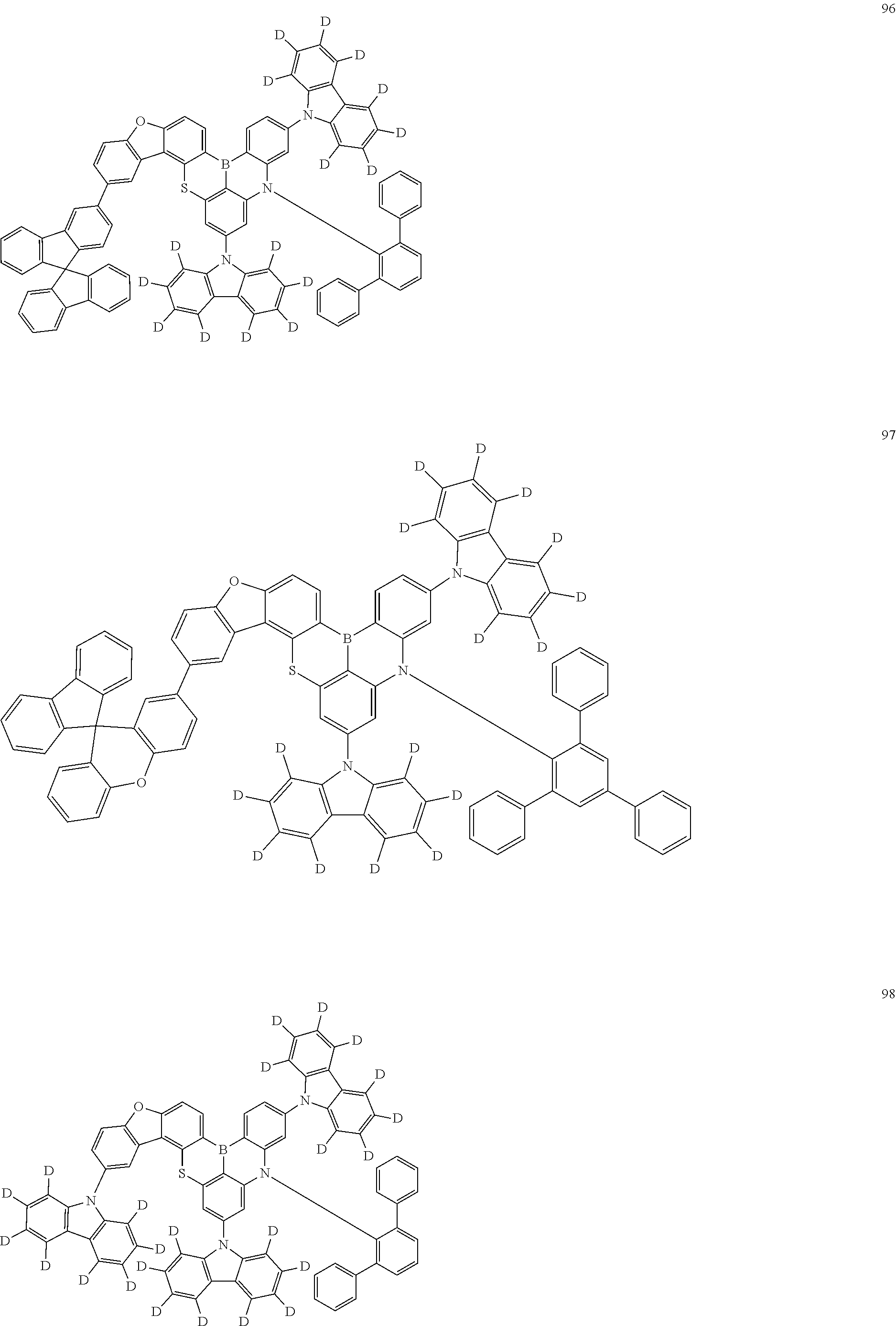 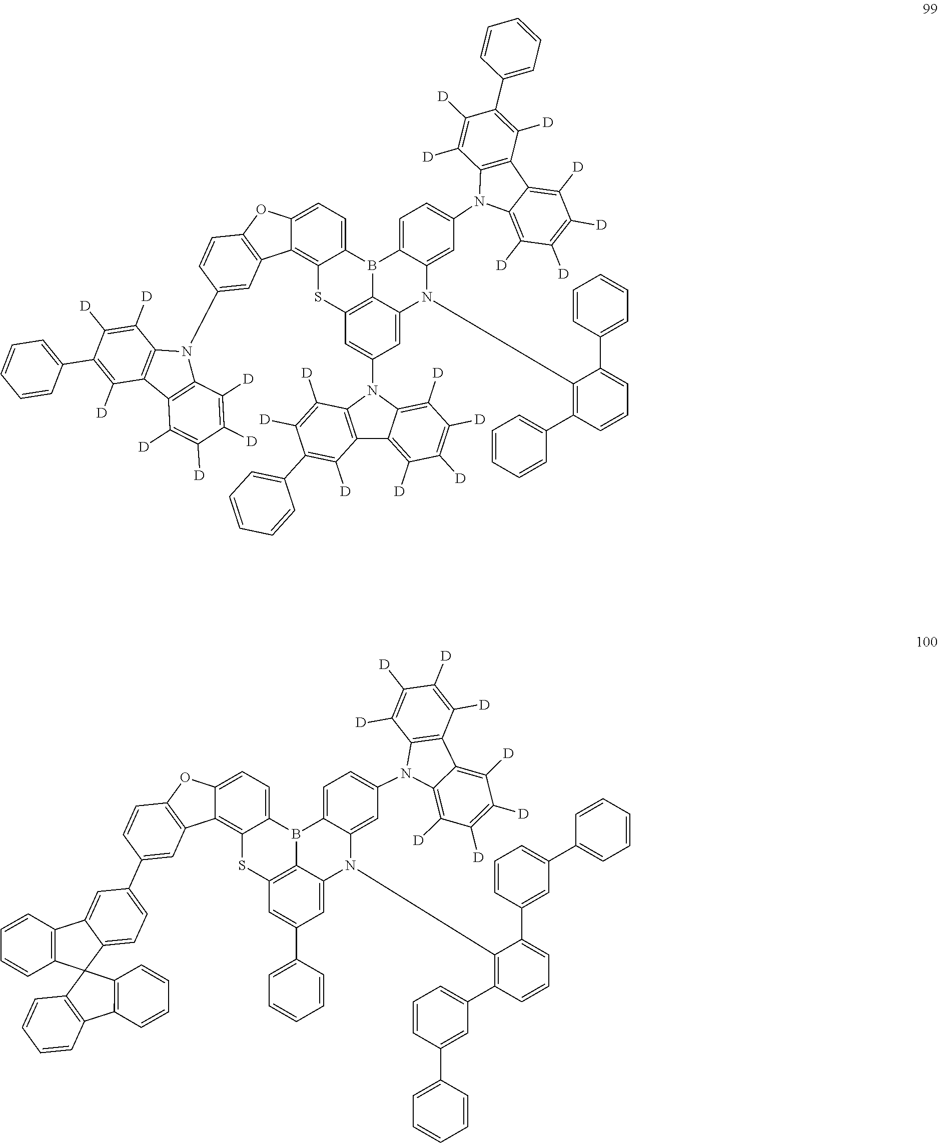 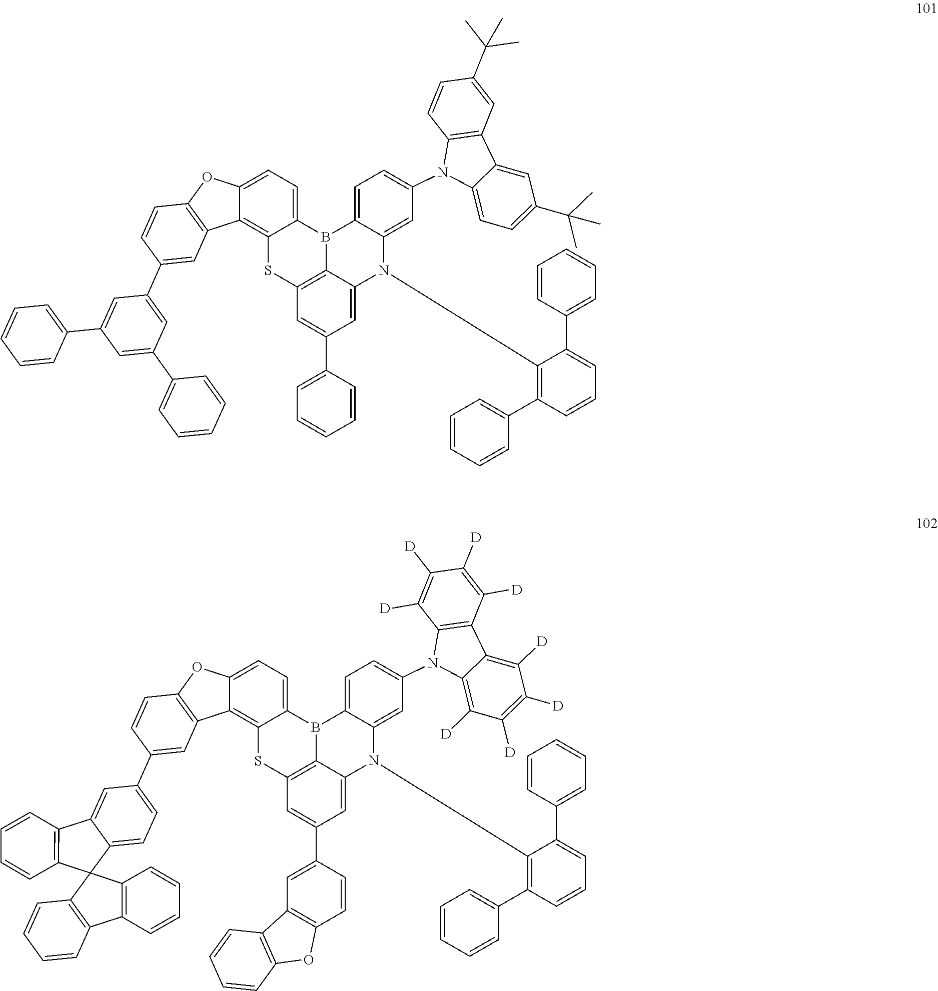 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc2oc4ccc(-c5cc(-c6ccccc6)cc(-c6ccccc6)c5)cc4c2c1S3 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc2oc4ccc(-c5ccc6c(c5)-c5ccccc5C65c6ccccc6-c6ccccc65)cc4c2c1S3] 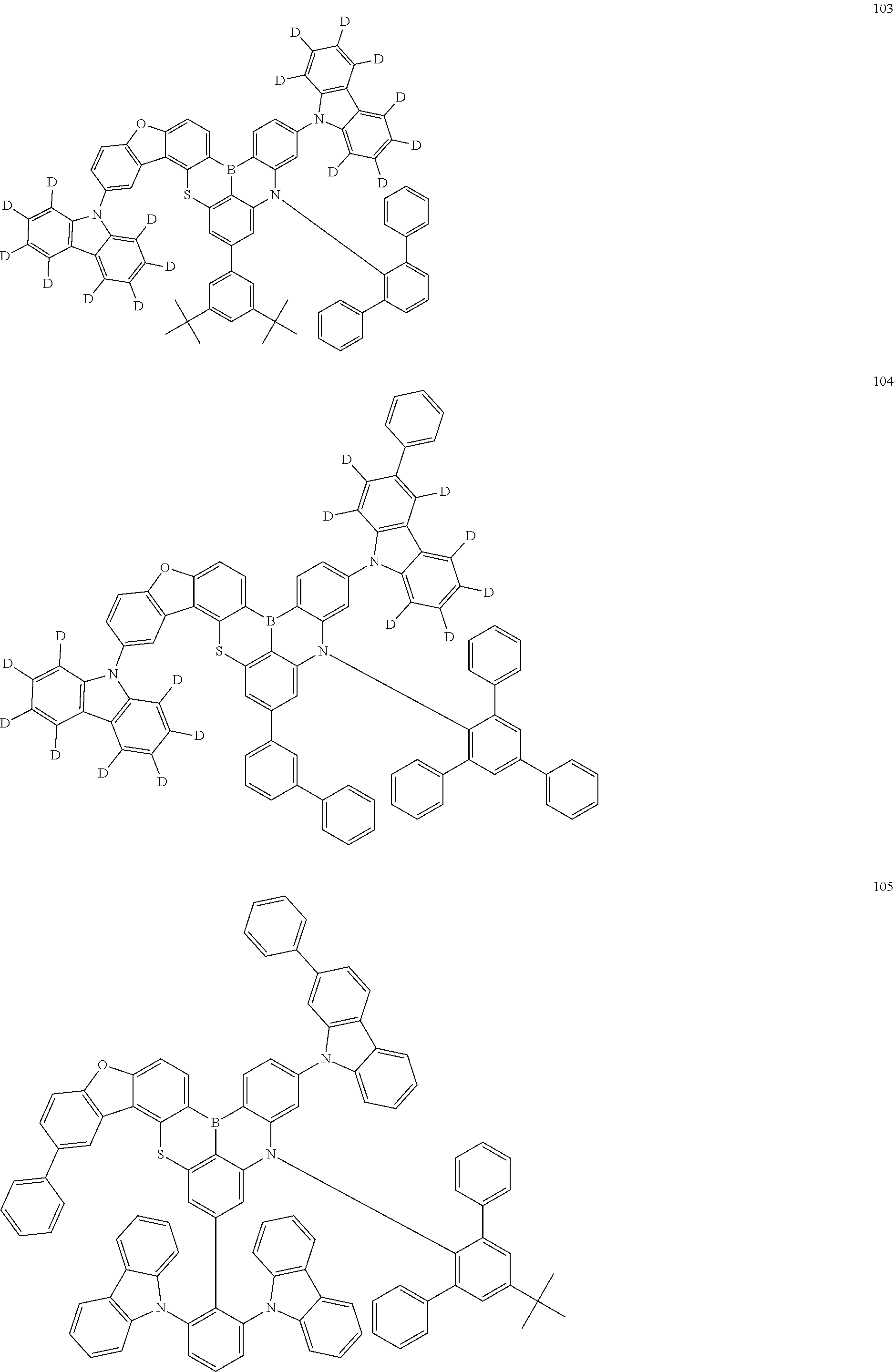 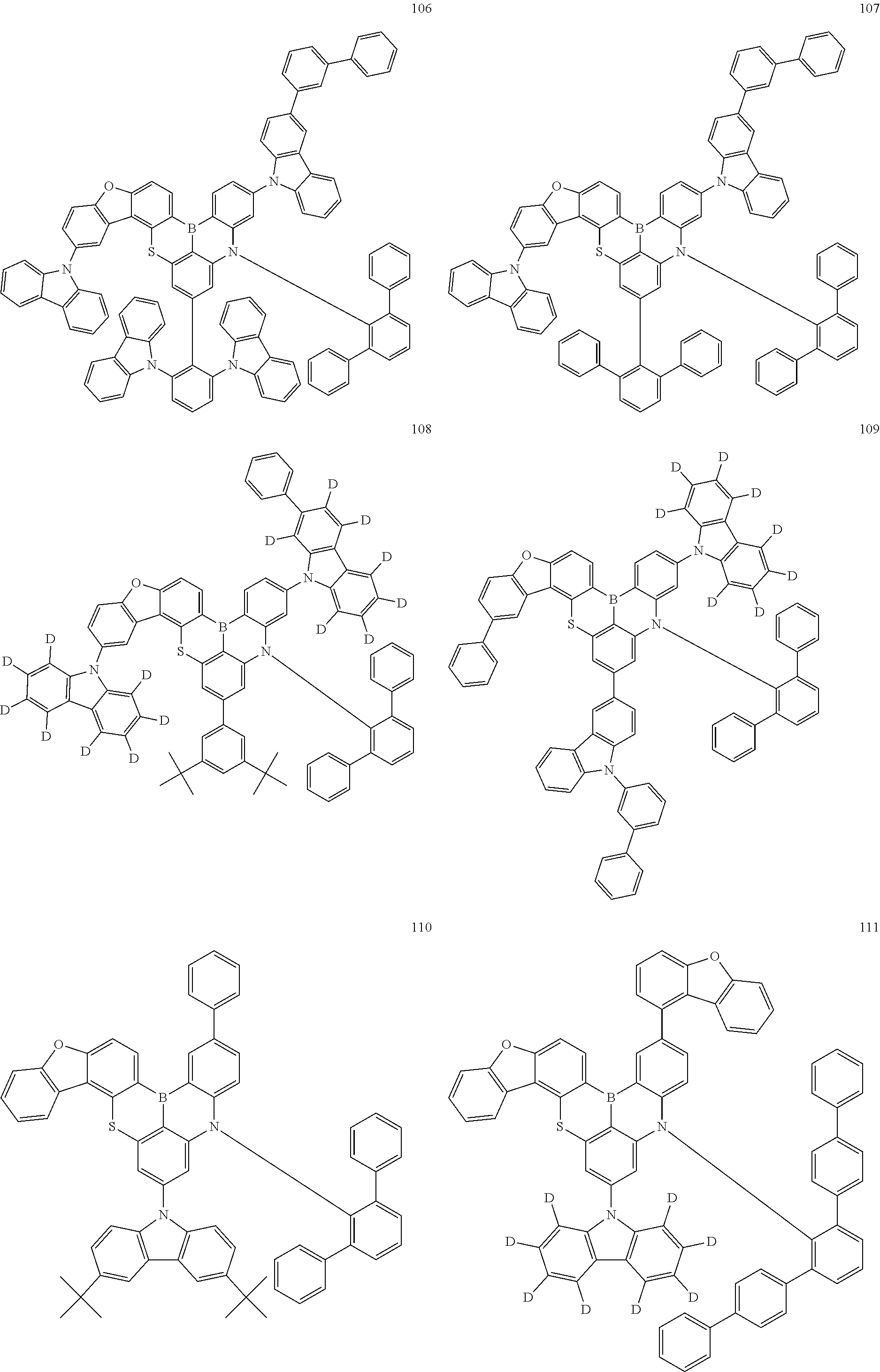 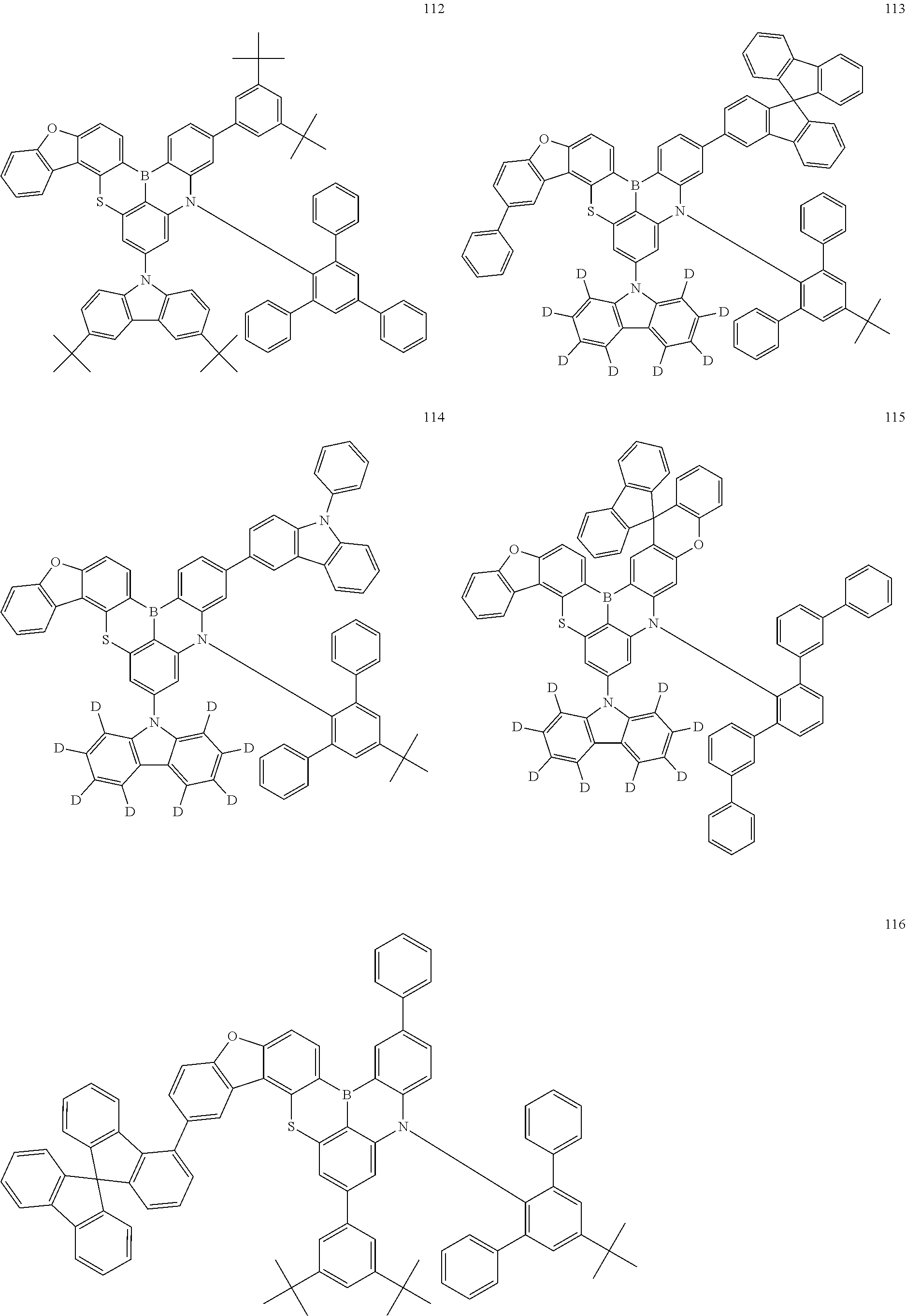 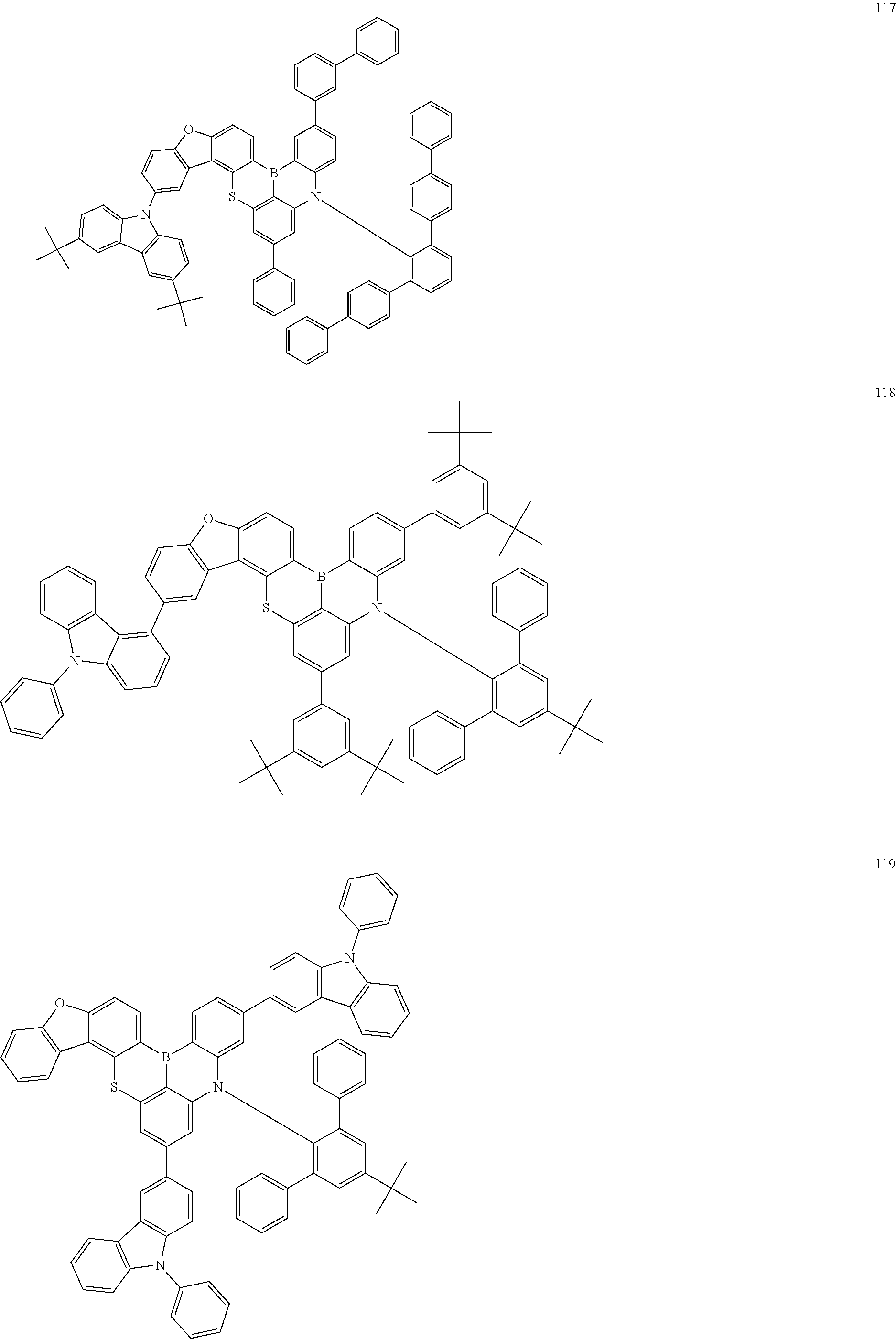 [SMILES: CC(C)(C)c1ccc2c(c1)c1cc(C(C)(C)C)ccc1n2-c1ccc2oc3ccc4c(c3c2c1)Sc1cc(-c2ccccc2)cc2c1B4c1cc(-c3cccc(-c4ccccc4)c3)ccc1N2c1c(-c2ccc(-c3ccccc3)cc2)cccc1-c1ccc(-c2ccccc2)cc1 ; CC(C)(C)c1cc(-c2ccc3c(c2)N(c2c(-c4ccccc4)cc(C(C)(C)C)cc2-c2ccccc2)c2cc(-c4cc(C(C)(C)C)cc(C(C)(C)C)c4)cc4c2B3c2ccc3oc5ccc(-c6cccc7c6c6ccccc6n7-c6ccccc6)cc5c3c2S4)cc(C(C)(C)C)c1 ; CC(C)(C)c1cc(-c2ccccc2)c(N2c3cc(-c4ccc5c(c4)c4ccccc4n5-c4ccccc4)ccc3B3c4ccc5oc6ccccc6c5c4Sc4cc(-c5ccc6c(c5)c5ccccc5n6-c5ccccc5)cc2c43)c(-c2ccccc2)c1] 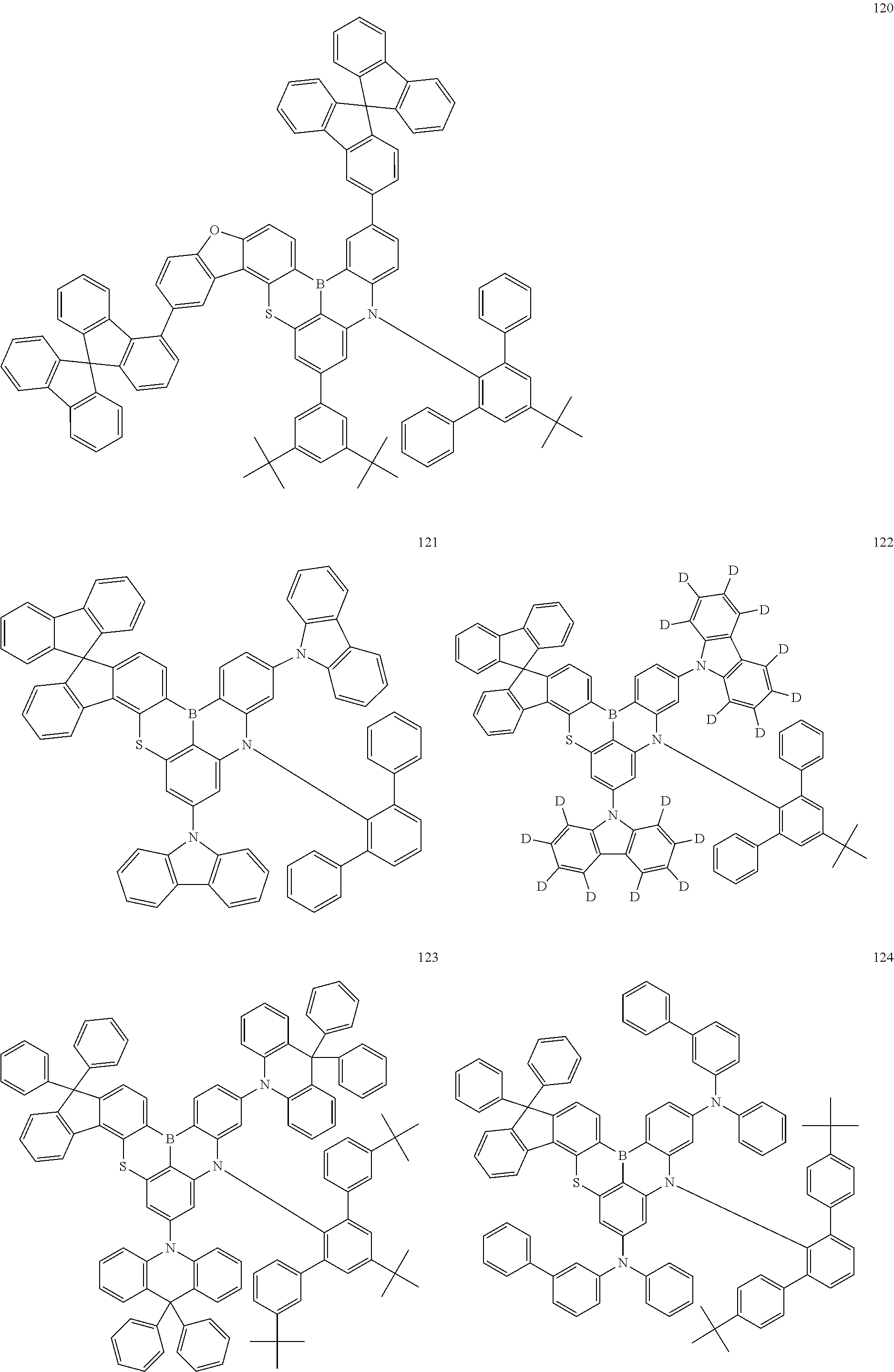 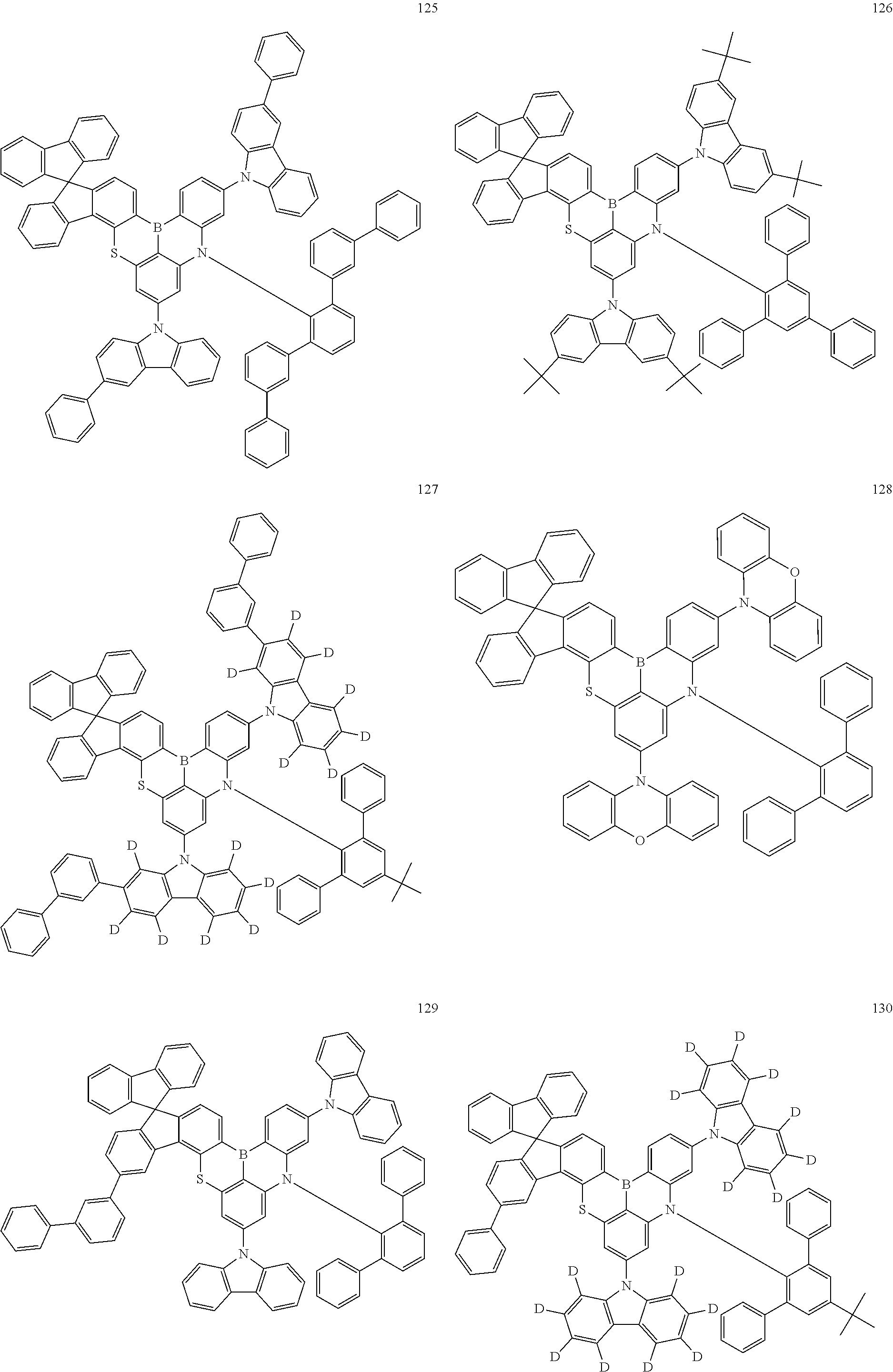 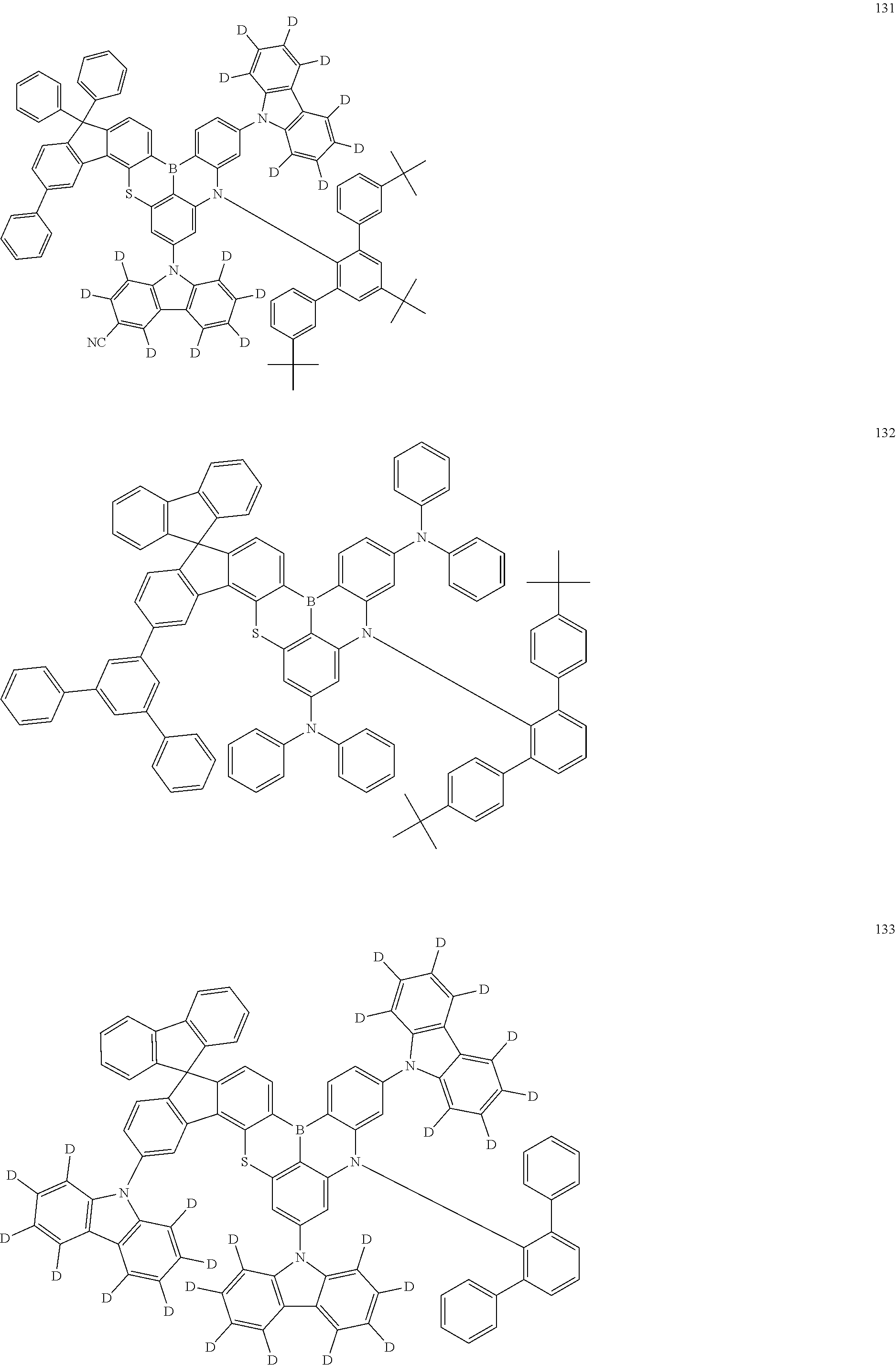 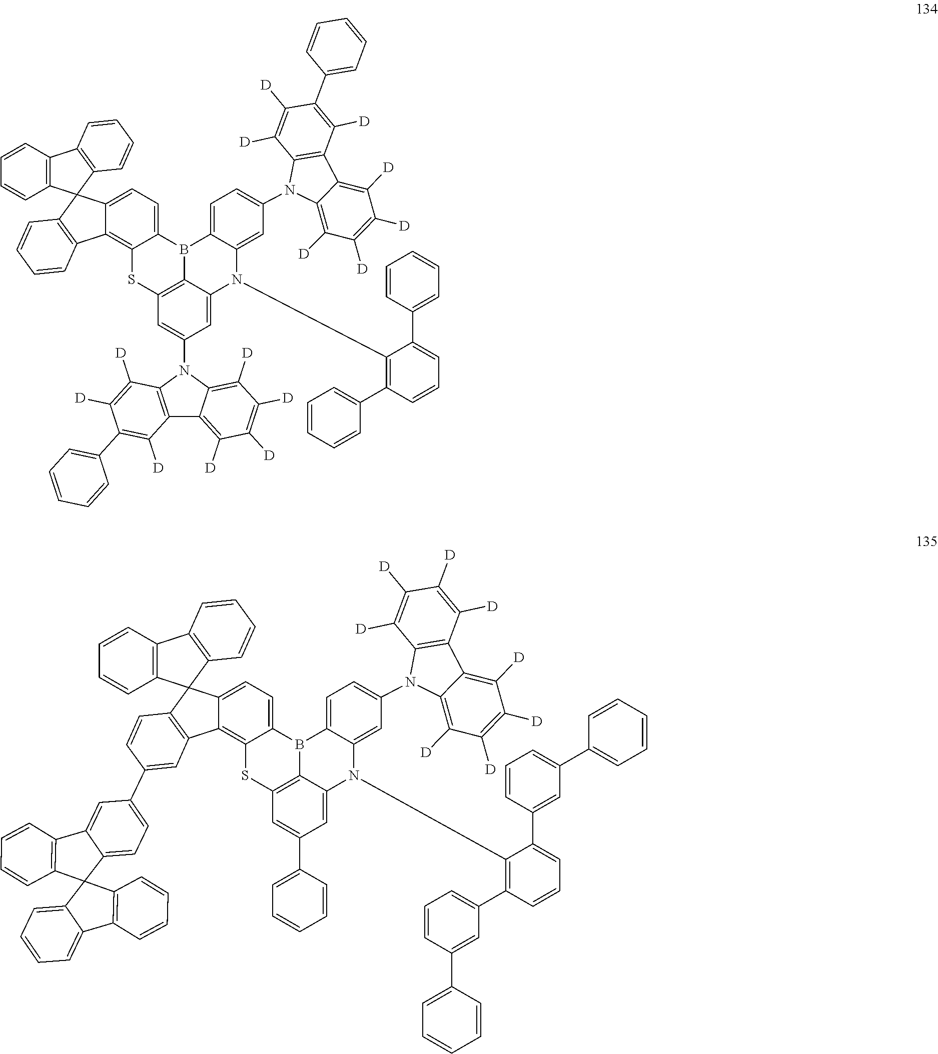 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1ccccc1)c1cc(-n3c4c([2H])c([2H])c([2H])c([2H])c4c4c([2H])c(-c5ccccc5)c([2H])c([2H])c43)cc3c1B2c1ccc2c(c1S3)-c1ccccc1C21c2ccccc2-c2ccccc21 ; [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2c(c1S3)-c1cc(-c3ccc4c(c3)-c3ccccc3C43c4ccccc4-c4ccccc43)ccc1C21c2ccccc2-c2ccccc21] 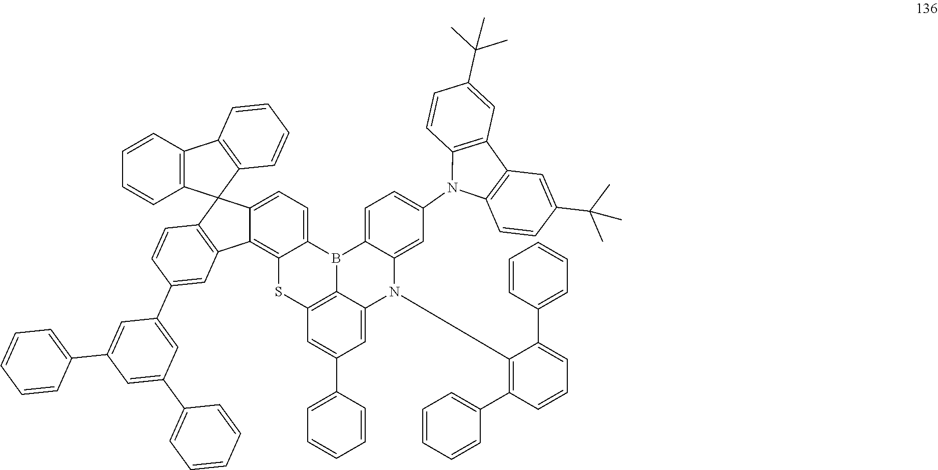 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc2c(c1S3)-c1cc(-c3cc(-c4ccccc4)cc(-c4ccccc4)c3)ccc1C21c2ccccc2-c2ccccc21] 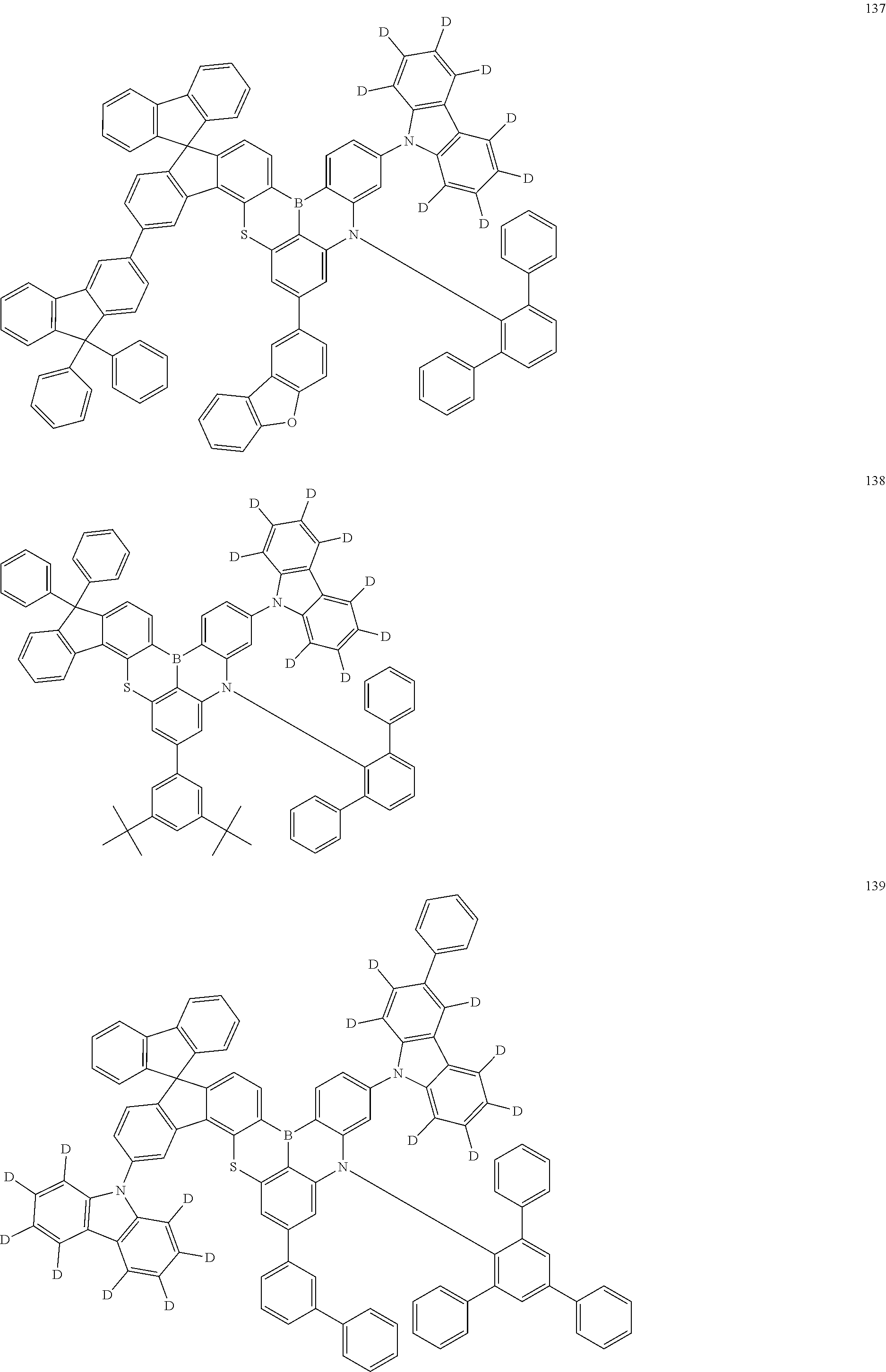 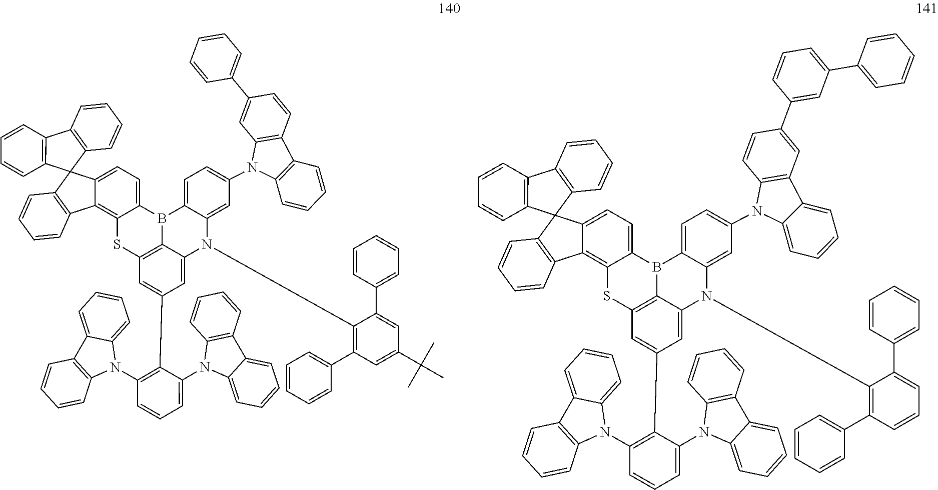 [SMILES: CC(C)(C)c1cc(-c2ccccc2)c(N2c3cc(-n4c5ccccc5c5ccc(-c6ccccc6)cc54)ccc3B3c4ccc5c(c4Sc4cc(-c6c(-n7c8ccccc8c8ccccc87)cccc6-n6c7ccccc7c7ccccc76)cc2c43)-c2ccccc2C52c3ccccc3-c3ccccc32)c(-c2ccccc2)c1 ; c1ccc(-c2cccc(-c3ccc4c(c3)c3ccccc3n4-c3ccc4c(c3)N(c3c(-c5ccccc5)cccc3-c3ccccc3)c3cc(-c5c(-n6c7ccccc7c7ccccc76)cccc5-n5c6ccccc6c6ccccc65)cc5c3B4c3ccc4c(c3S5)-c3ccccc3C43c4ccccc4-c4ccccc43)c2)cc1] 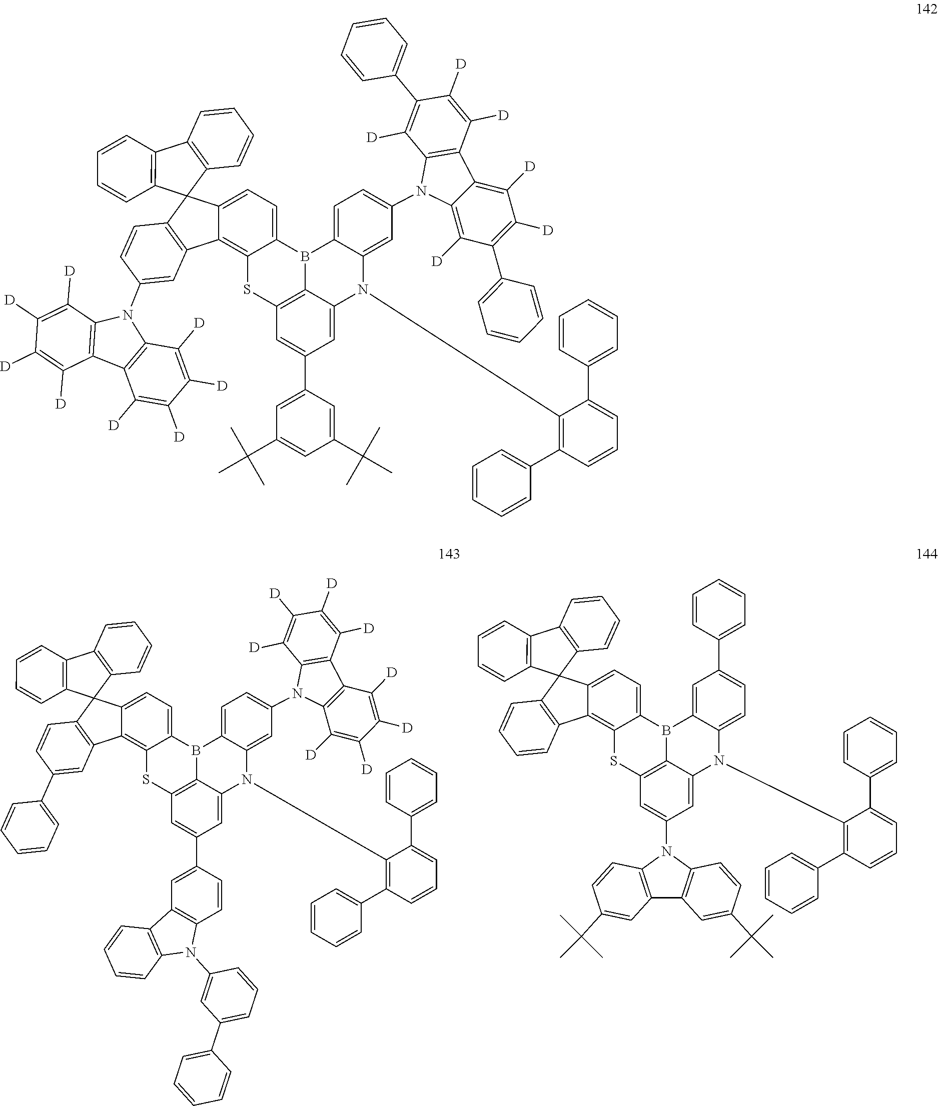 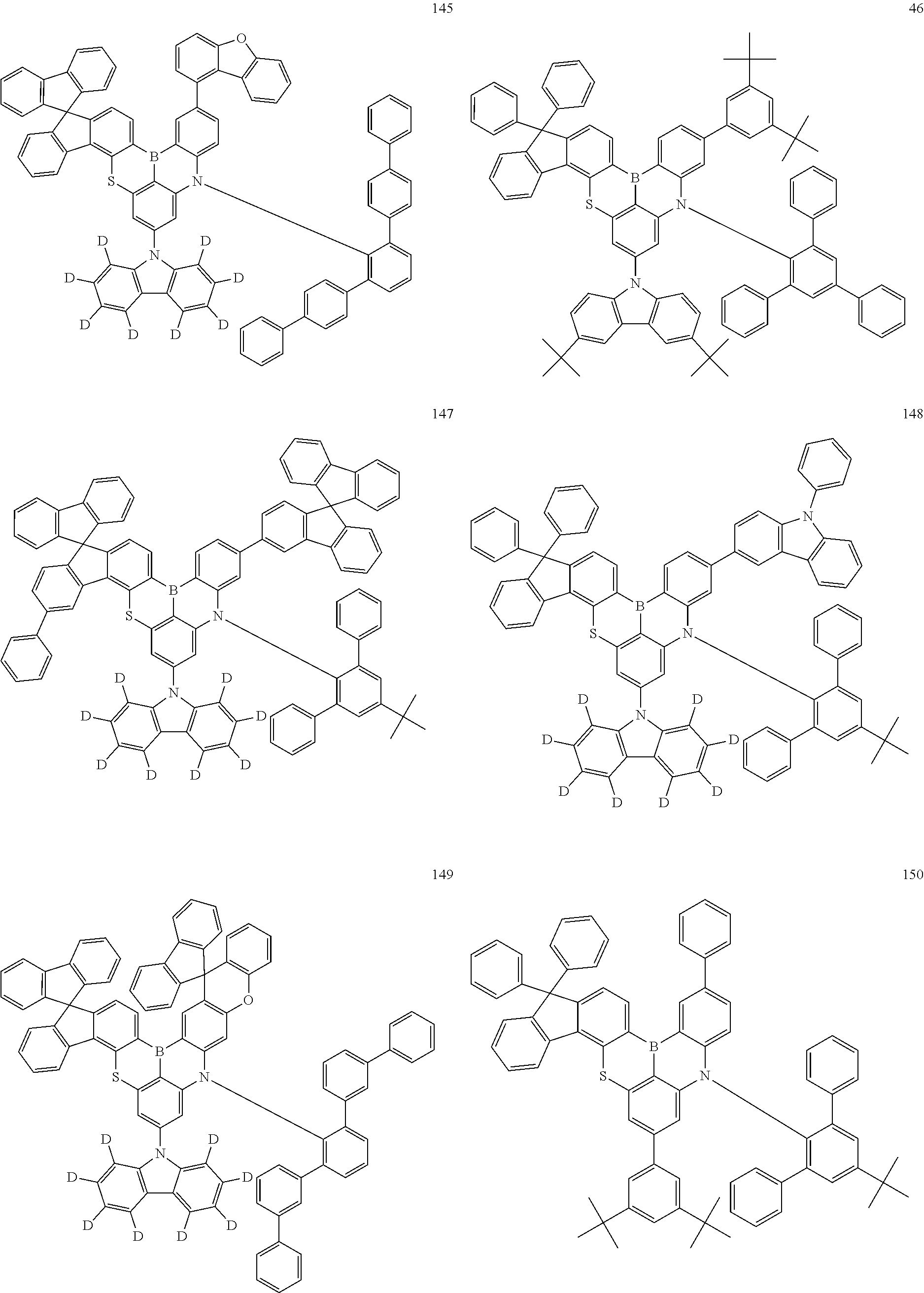 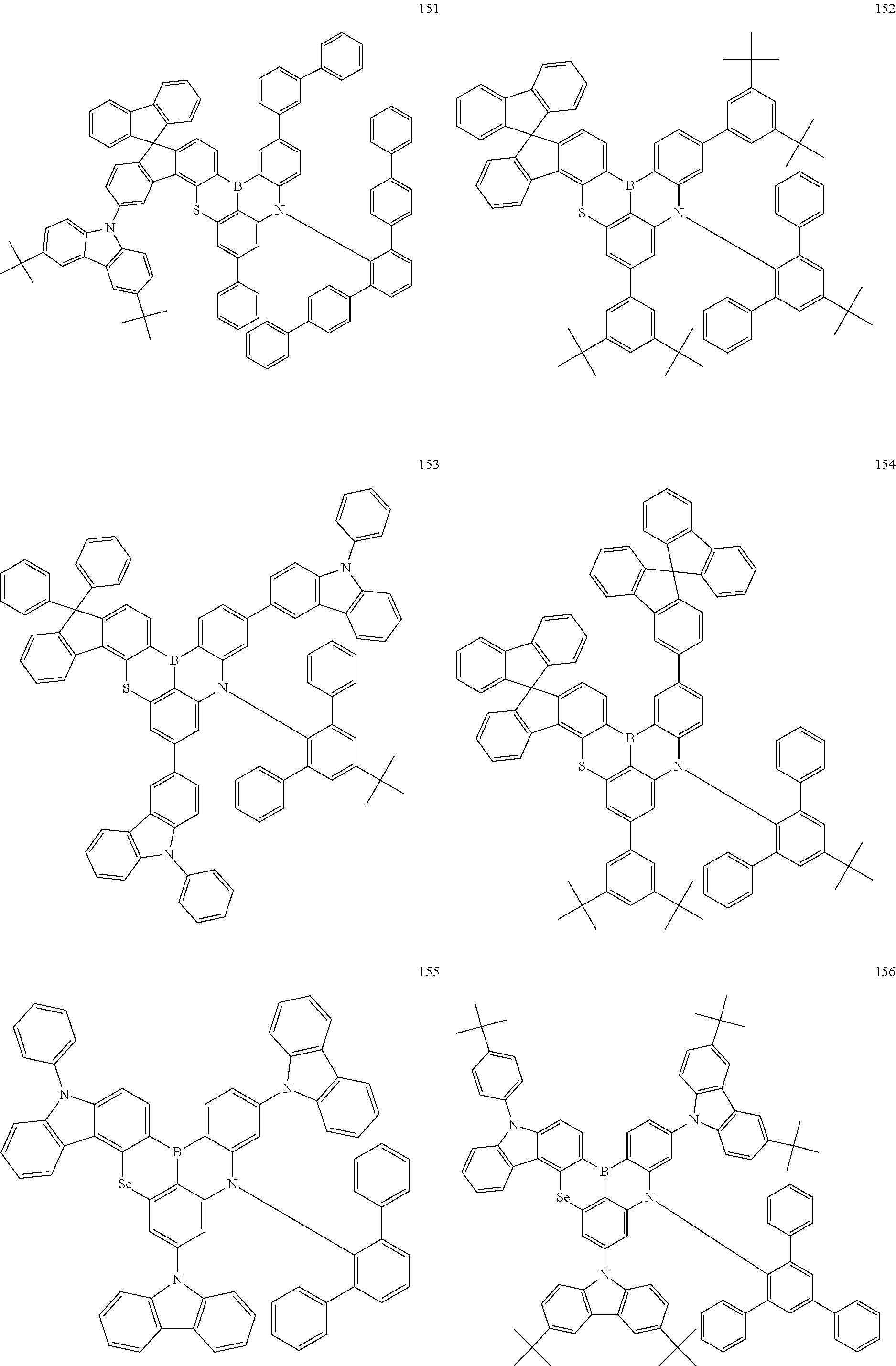 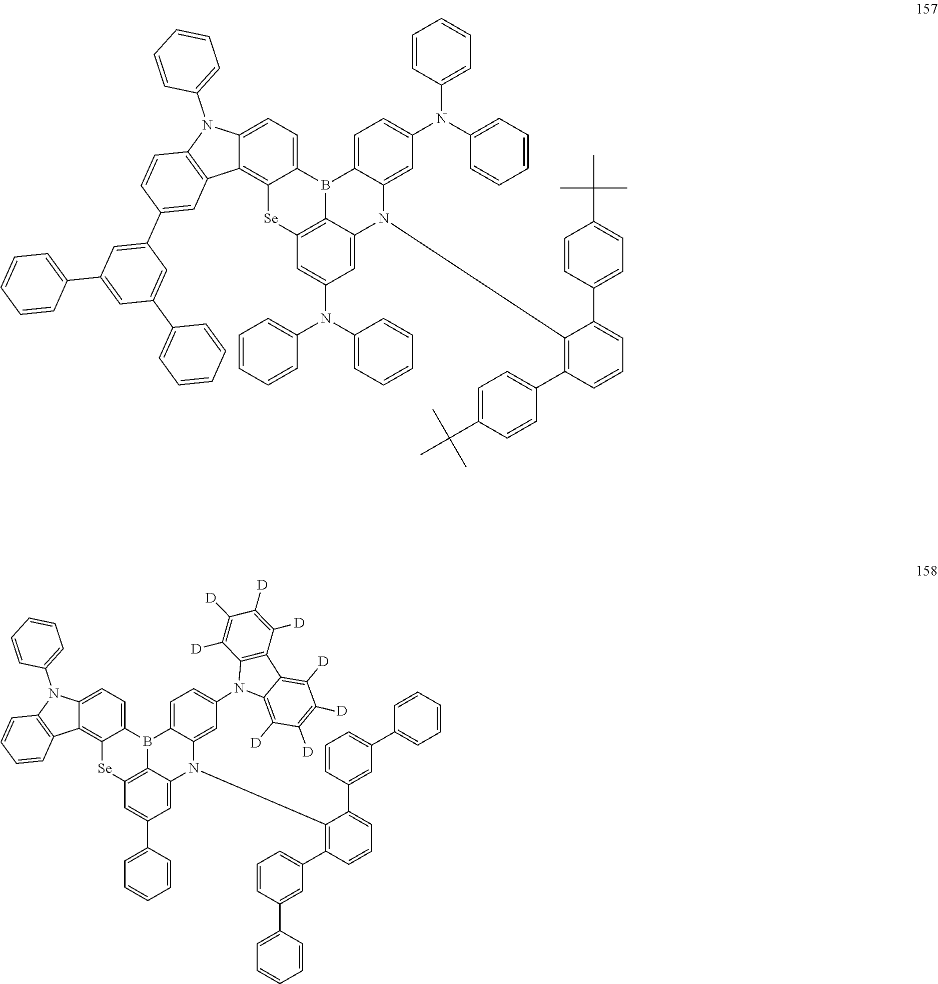 [SMILES: CC(C)(C)c1ccc(-c2cccc(-c3ccc(C(C)(C)C)cc3)c2N2c3cc(N(c4ccccc4)c4ccccc4)ccc3B3c4ccc5c(c4[Se]c4cc(N(c6ccccc6)c6ccccc6)cc2c43)c2cc(-c3cc(-c4ccccc4)cc(-c4ccccc4)c3)ccc2n5-c2ccccc2)cc1 ; [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc(-c3ccccc3)c1)c1cc(-c3ccccc3)cc3c1B2c1ccc2c(c1[Se]3)c1ccccc1n2-c1ccccc1] 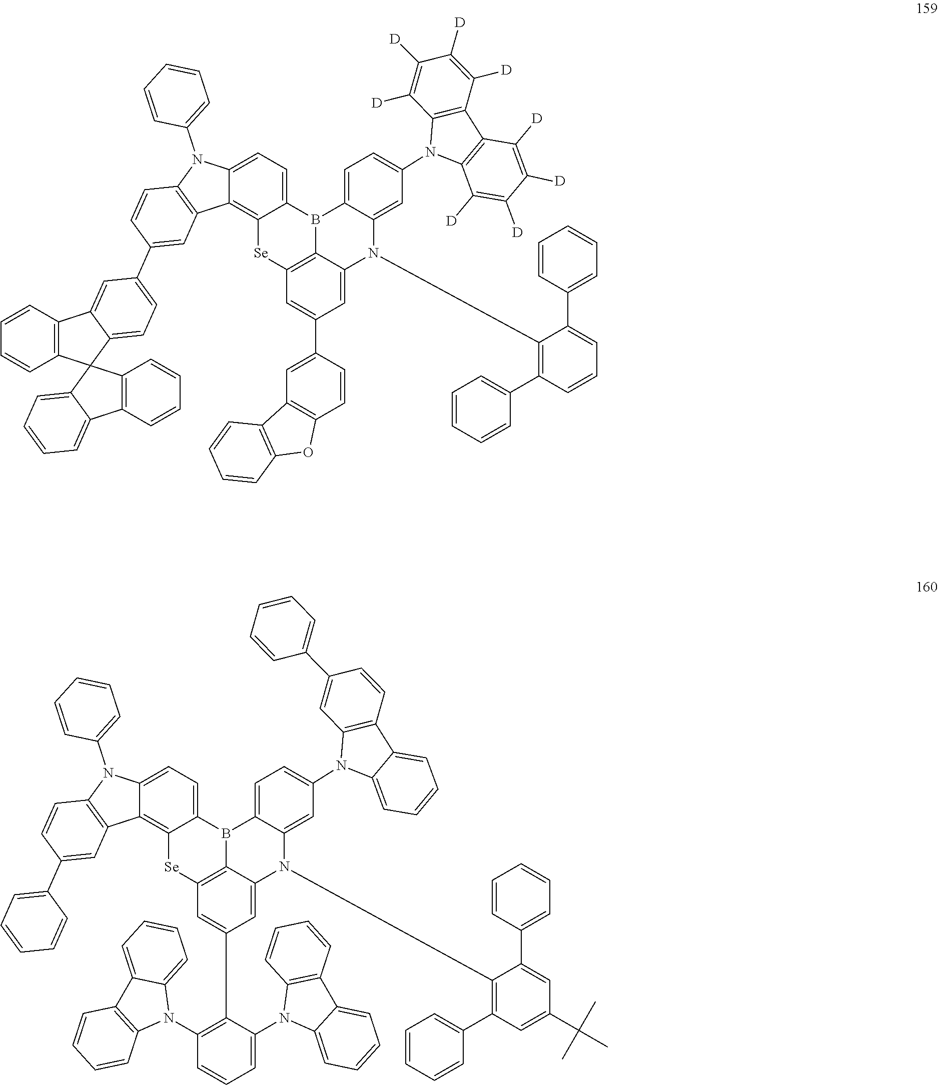 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc2c(c1[Se]3)c1cc(-c3ccc4c(c3)-c3ccccc3C43c4ccccc4-c4ccccc43)ccc1n2-c1ccccc1 ; CC(C)(C)c1cc(-c2ccccc2)c(N2c3cc(-n4c5ccccc5c5ccc(-c6ccccc6)cc54)ccc3B3c4ccc5c(c4[Se]c4cc(-c6c(-n7c8ccccc8c8ccccc87)cccc6-n6c7ccccc7c7ccccc76)cc2c43)c2cc(-c3ccccc3)ccc2n5-c2ccccc2)c(-c2ccccc2)c1] 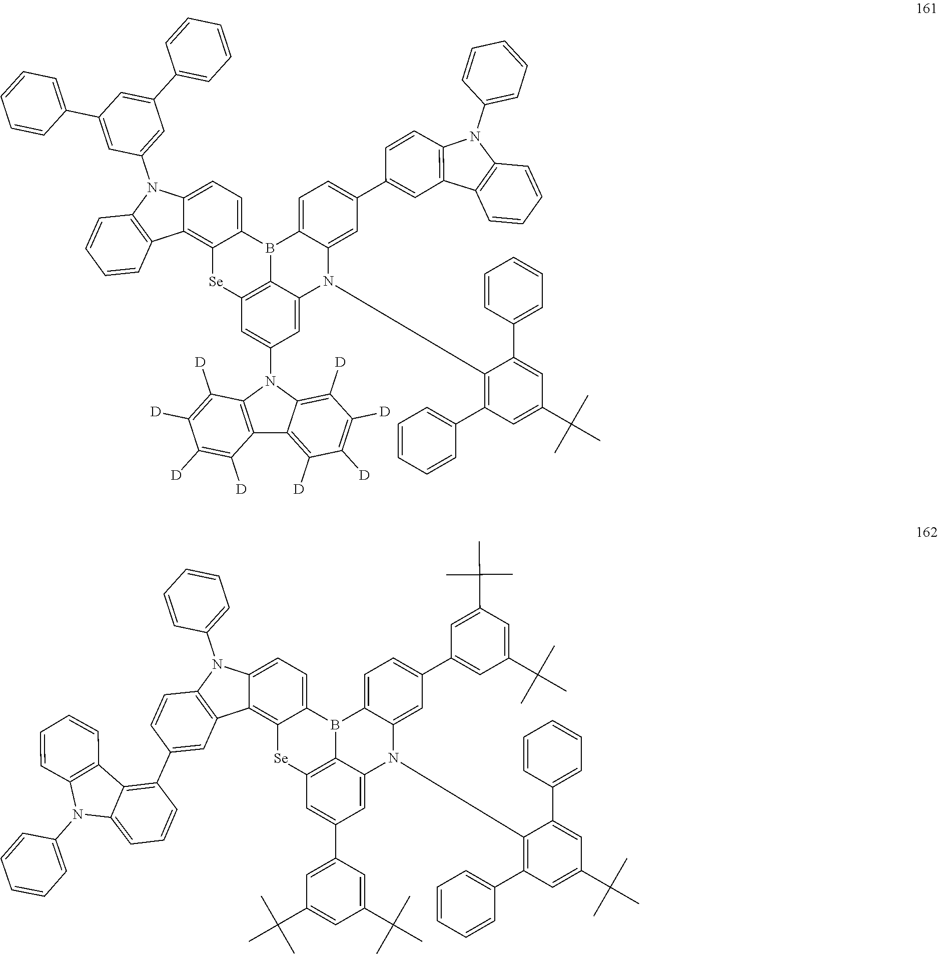 [SMILES: [2H]c1c([2H])c([2H])c2c(c1[2H])c1c([2H])c([2H])c([2H])c([2H])c1n2-c1cc2c3c(c1)N(c1c(-c4ccccc4)cc(C(C)(C)C)cc1-c1ccccc1)c1cc(-c4ccc5c(c4)c4ccccc4n5-c4ccccc4)ccc1B3c1ccc3c(c1[Se]2)c1ccccc1n3-c1cc(-c2ccccc2)cc(-c2ccccc2)c1 ; CC(C)(C)c1cc(-c2ccc3c(c2)N(c2c(-c4ccccc4)cc(C(C)(C)C)cc2-c2ccccc2)c2cc(-c4cc(C(C)(C)C)cc(C(C)(C)C)c4)cc4c2B3c2ccc3c(c2[Se]4)c2cc(-c4cccc5c4c4ccccc4n5-c4ccccc4)ccc2n3-c2ccccc2)cc(C(C)(C)C)c1] 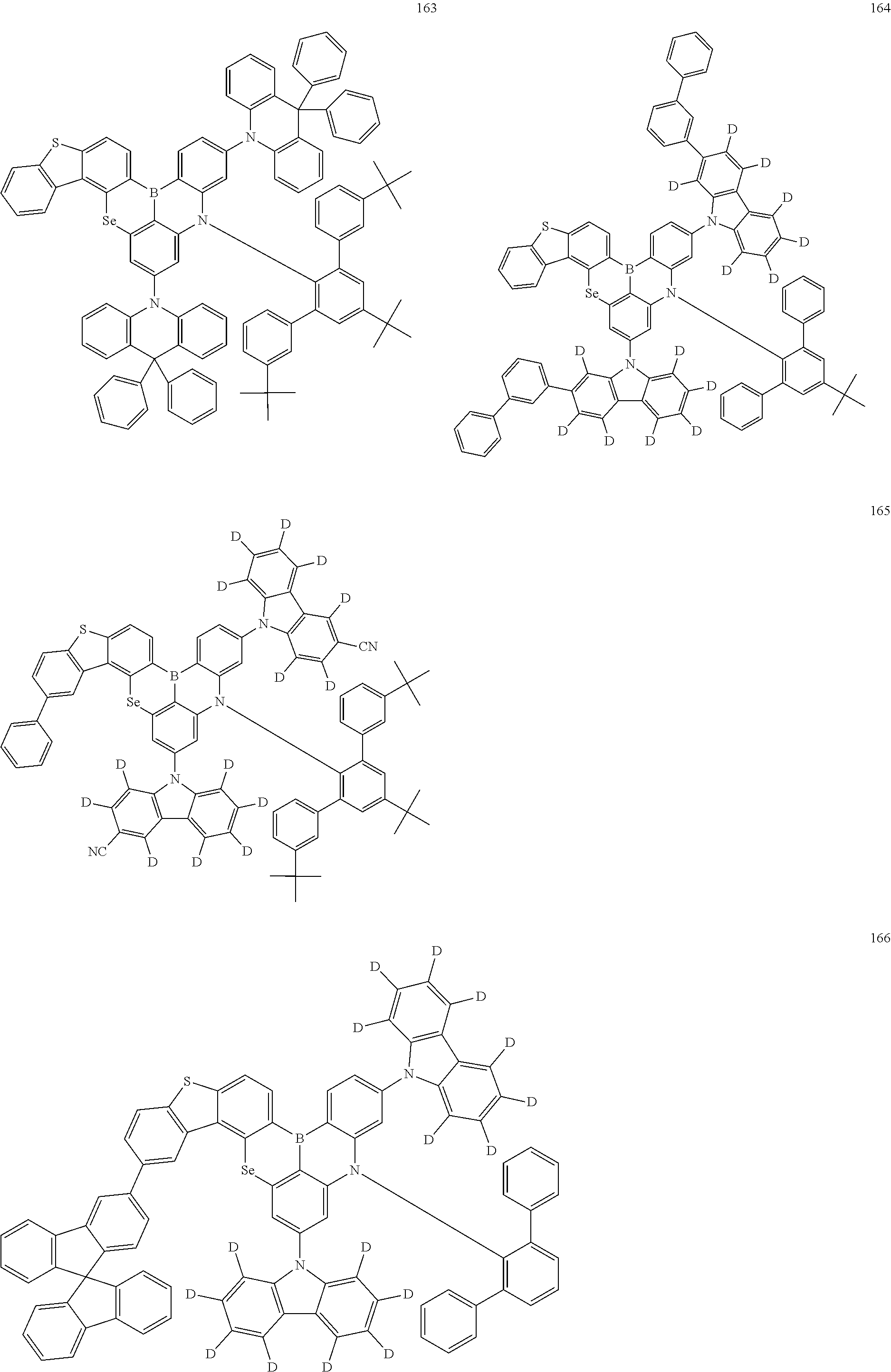 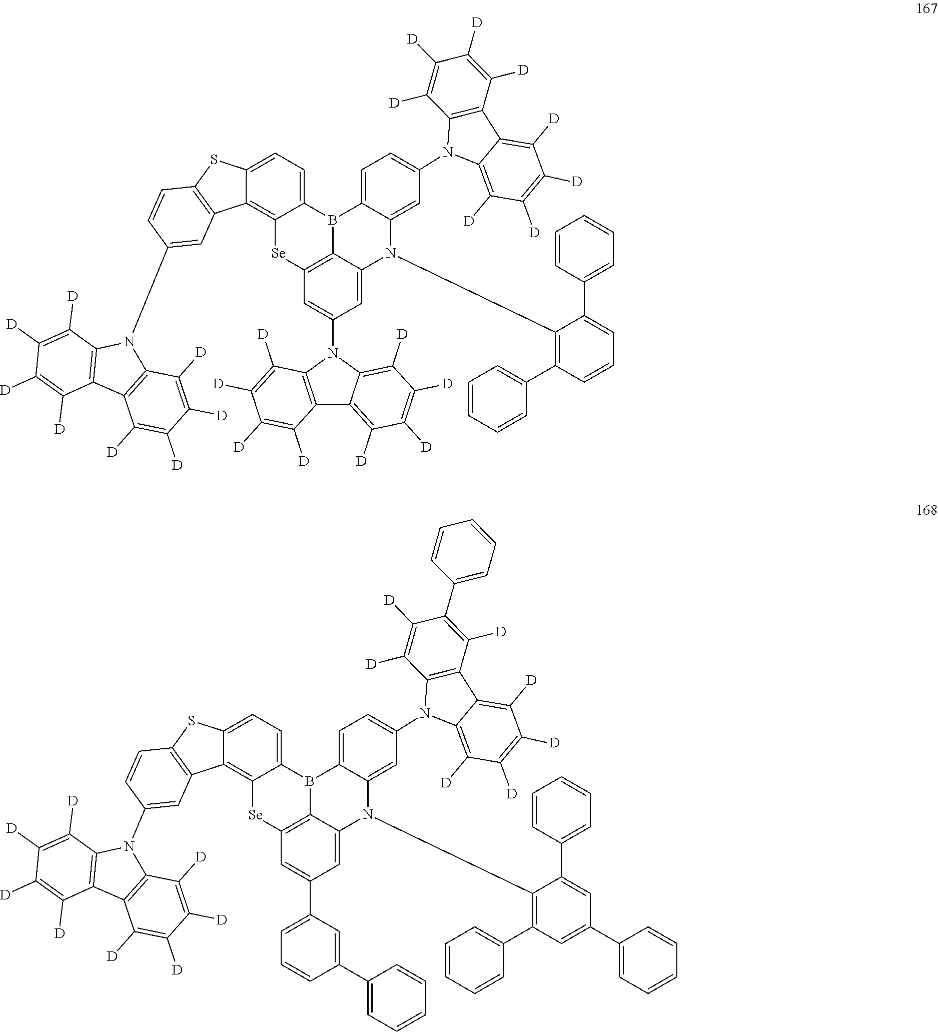 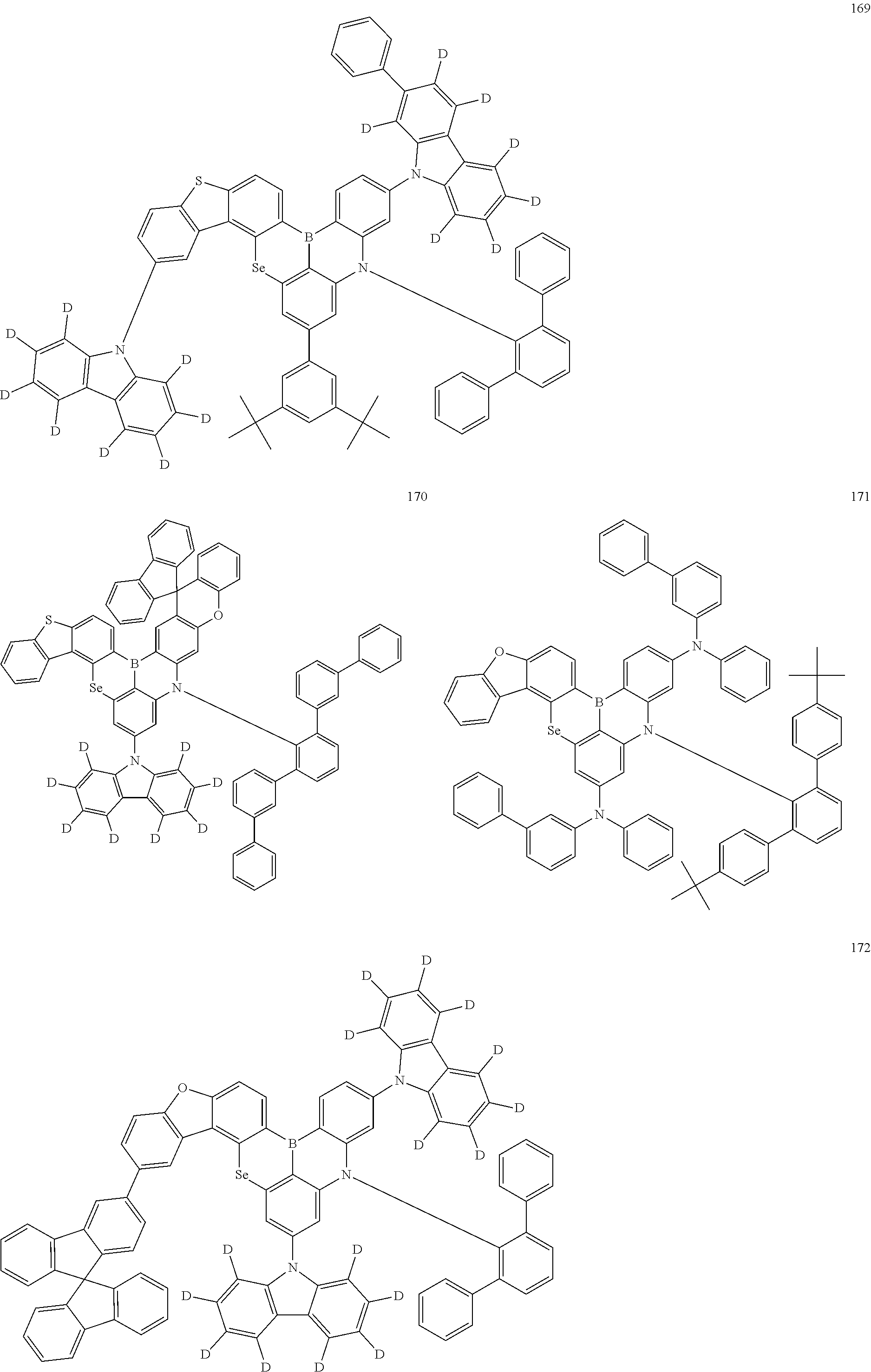 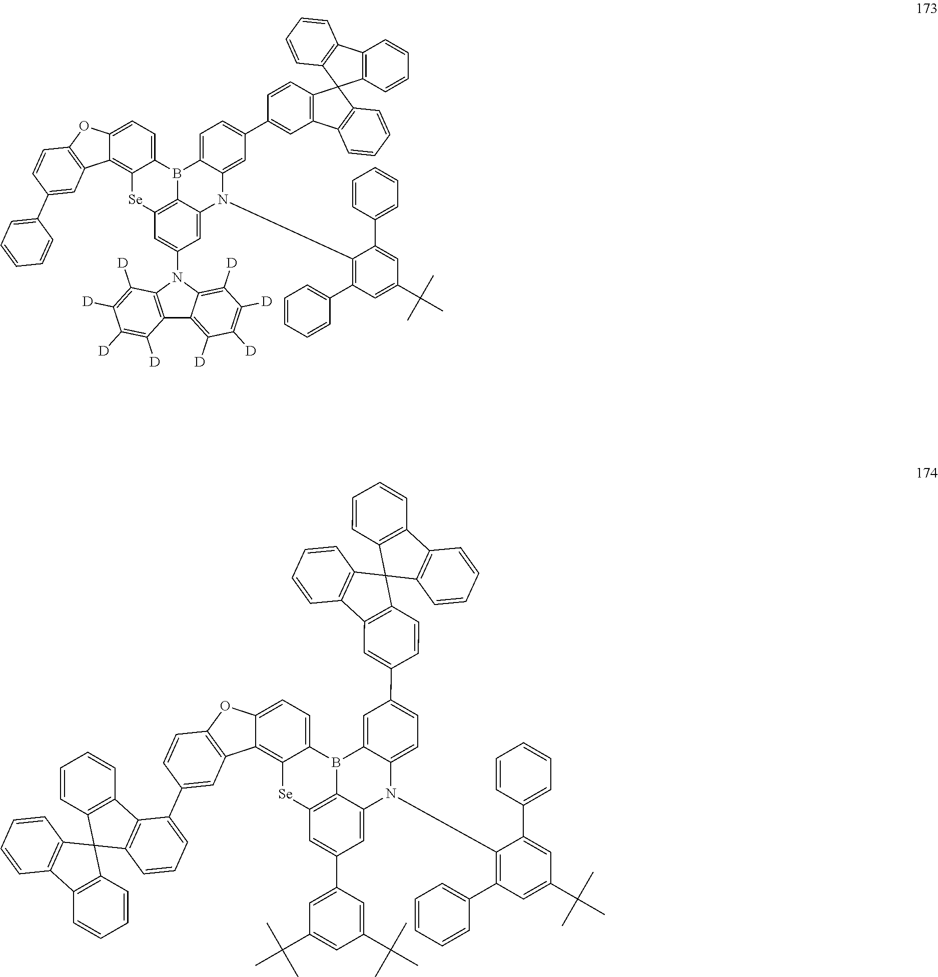 [SMILES: [2H]c1c([2H])c([2H])c2c(c1[2H])c1c([2H])c([2H])c([2H])c([2H])c1n2-c1cc2c3c(c1)N(c1c(-c4ccccc4)cc(C(C)(C)C)cc1-c1ccccc1)c1cc(-c4ccc5c(c4)-c4ccccc4C54c5ccccc5-c5ccccc54)ccc1B3c1ccc3oc4ccc(-c5ccccc5)cc4c3c1[Se]2 ; CC(C)(C)c1cc(-c2cc3c4c(c2)N(c2c(-c5ccccc5)cc(C(C)(C)C)cc2-c2ccccc2)c2ccc(-c5ccc6c(c5)-c5ccccc5C65c6ccccc6-c6ccccc65)cc2B4c2ccc4oc5ccc(-c6cccc7c6-c6ccccc6C76c7ccccc7-c7ccccc76)cc5c4c2[Se]3)cc(C(C)(C)C)c1] 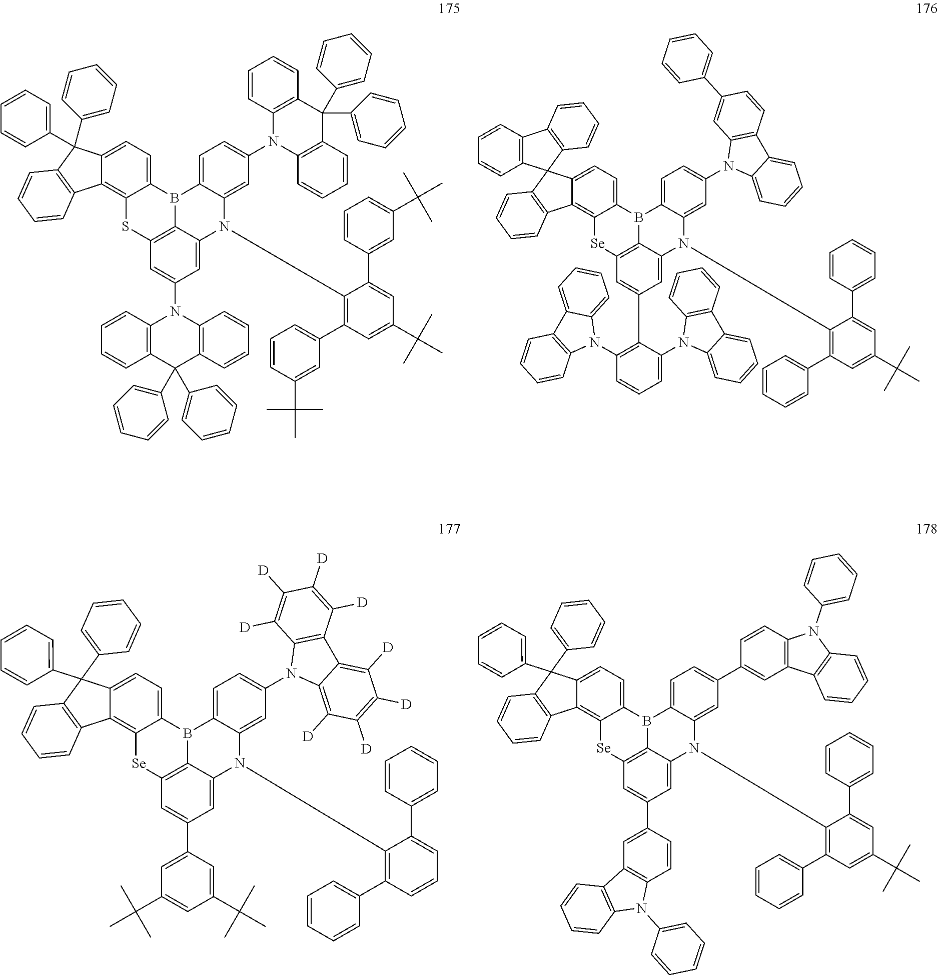
in Compound Group 1, D is a deuterium atom.

22. A display device, comprising:
a base layer;
a circuit layer on the base layer; and
a display device layer on the circuit layer and comprising a light emitting element,
wherein the light emitting element comprises a first electrode, a second electrode on the first electrode, and an emission layer between the first electrode and the second electrode, and
the emission layer comprises:
a first compound represented by the following Formula 1; and
at least one among a second compound represented by the following Formula HT-1, a third compound represented by the following Formula ET-1, and a fourth compound represented by the following Formula D-1: 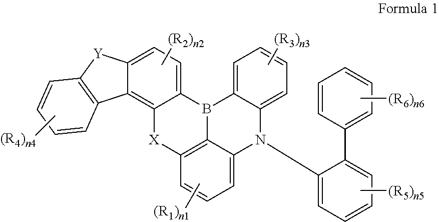
in Formula 1,
X is S, O, or Se,
Y is NR₇, S, O, or CR₈R₉,
R₁ to R₆ are each independently a hydrogen atom, a deuterium atom, a cyano group, a substituted or unsubstituted amine group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, or R₃ is combined with an adjacent group to form a ring,
R₇ to R₉ are each independently a substituted or unsubstituted aryl group of 6 to 30 ring-forming carbon atoms, or a substituted or unsubstituted heteroaryl group of 2 to 30 ring-forming carbon atoms, or R₈ and R₉ are combined with each other to form a ring,
n1 is an integer of 0 to 3,
n2 is an integer of 0 to 2,
n3, n4 and n5 are each independently an integer of 0 to 4, and
n6 is an integer of 0 to 5: 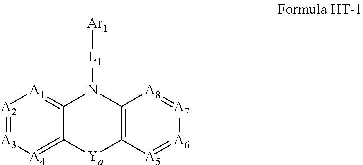
in Formula HT-1,
A₁ to A₈ are each independently N or CR₅₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₅₂R₅₃, or SiR₅₄R₅₅,
Ar₁ is a substituted or unsubstituted aryl group of 6 to 30 ring-forming carbon atoms, or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring: 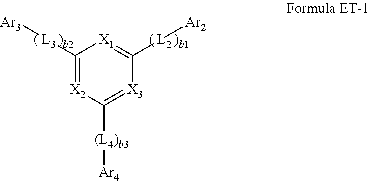
in Formula ET-1,
at least one among X₁ to X₃ is N, and the remainder are CR₅₆,
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms: 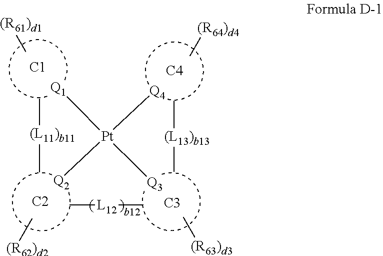
in Formula D-1,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₁₁ to L₁₃ are each independently a direct linkage, *—O—*, *—S—*, 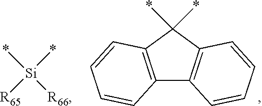
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and
d1 to d4 are each independently an integer of 0 to 4.

23. The display device of claim 22, wherein the light emitting element emits blue light.

24. The display device of claim 22, further comprising a light controlling layer comprising a quantum dot.
